(19) United States
(12) Patent Application Publication
(10) Pub. No.: US 2025/0072285 A1
(43) Pub. Date: Feb. 27, 2025

(54) LIGHT EMITTING ELEMENT, POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: MUN-KI SIM, Yongin-si (KR); TAEIL KIM, Yongin-si (KR); SUN YOUNG PAK, Yongin-si (KR); JUNHA PARK, Yongin-si (KR); CHANSEOK OH, Yongin-si (KR); CHANGWOONG CHU, Yongin-si (KR); Giwoong HAN, Yongin-si (KR)

(21) Appl. No.: 18/806,238

(22) Filed: Aug. 15, 2024

(30) Foreign Application Priority Data
Aug. 16, 2023 (KR) 10-2023-0107200

(51) Int. Cl. H10K 85/60; C07F 5/02; C09K 11/02; C09K 11/06; H10K 50/12; H10K 85/30; H10K 85/40

(52) U.S. Cl. CPC H10K 85/658; C07F 5/027; C09K 11/02; C09K 11/06; H10K 85/346; H10K 85/40; C09K 2211/1007; C09K 2211/1011; C09K 2211/1014; C09K 2211/1022; C09K 2211/1029; C09K 2211/1044; C09K 2211/185; H10K 50/12

(57) ABSTRACT

A light emitting element that may include a first electrode, a second electrode provided on the first electrode, and an emission layer provided between the first electrode and the second electrode is provided. The emission layer includes a first polycyclic compound and may also include second to fourth compounds. The polycyclic compound has a pentacyclic core including aromatic groups fused to heteroatoms and has a sterically-bulky, first substituent linked to the core. Steric bulk of the polycyclic compound may increase intermolecular distances and prevent or reduce intermolecular interactions that could impede multi-resonance characteristics of the pentacyclic core.

### CROSS-REFERENCE TO RELATED APPLICATION

This application claims priority to and the benefit of Korean Patent Application No. 10-2023-0107200, filed on Aug. 16, 2023, in the Korean Intellectual Property Office, the entire content of which is incorporated herein by reference.

### BACKGROUND

### 1. Field

The present disclosure herein relates to a light emitting element, a polycyclic compound for the light emitting element, and a display device including the light emitting element.

### 2. Description of the Related Art

As image display devices, organic electroluminescence display devices and/or the like have been actively developed recently. The organic electroluminescence display devices and/or the like are display devices including so-called “self-luminescent” light emitting elements in which holes and electrons injected from a first electrode and a second electrode, respectively, combine in an emission layer of the display device. Subsequently, a luminescent material in the emission layer (e.g., light emitting layer) emits light to implement (e.g., accomplish) display (e.g., of an image).

The application of light emitting elements to display devices requires, or there is a desire or demand for, a light emitting element having improved light efficiency and improved service life and/or the like. Therefore, the need exists for research and development of materials, e.g., for light emitting elements, capable of stably attaining such characteristics or desires, and such development is being continuously pursued.

In recent years, two areas of research being conducted to obtain a highly efficient light emitting element, include technologies pertaining to phosphorescence emission, utilizing triplet state energy and delayed fluorescence, utilizing triplet-triplet annihilation (TTA) (e.g., in which singlet excitons are generated through the collision of triplet excitons). Another area of research being developed is thermally activated delayed fluorescence (TADF) materials utilizing a delayed fluorescence phenomenon.

### SUMMARY

One or more aspects of embodiments of the present disclosure are directed toward a light emitting element having improved luminous efficiency and service life.

One or more aspects of embodiments of the present disclosure are directed toward a polycyclic compound as a material for a light emitting element, which improves luminous efficiency and service life.

One or more aspects of embodiments of the present disclosure are directed toward a display device including a light emitting element having improved luminous efficiency and element service life.

Additional aspects will be set forth in part in the description which follows and, in part, will be apparent from the description, or may be learned by practice of the presented embodiments.

One or more embodiments of the present disclosure provides a light emitting element including a first electrode, a second electrode provided on the first electrode, and an emission layer provided between the first electrode and the second electrode, wherein the emission layer includes a first compound represented by Formula 1.

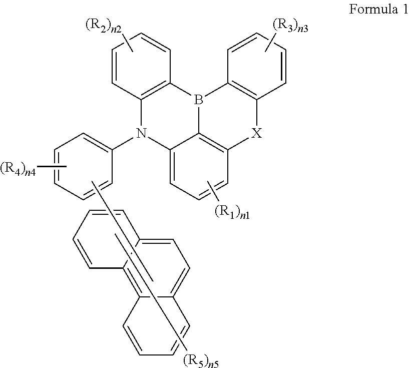

In Formula 1, X may be NR₆, S, O, or Se, R₁ to R₅ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms, R₆ may be a substituted or unsubstituted aryl group having 6 to 30 ring-forming carbon atoms, or a substituted or unsubstituted heteroaryl group having 5 to 30 ring-forming carbon atoms. In Formula 1, n1 may be an integer of 0 to 3, n2 to n4 may each independently be an integer of 0 to 4, and n5 may be an integer of 0 to 9.

In one or more embodiments, the first compound represented by Formula 1 may be represented by Formula 2.

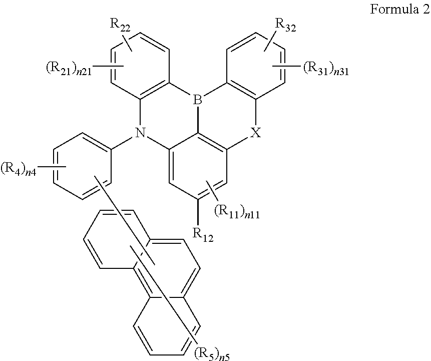

In Formula 2, R₁₁, R₂₁, and R₃₁ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms, R₁₂, R₂₂, and R₃₂ may each independently be a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. In Formula 2, n11 may be an integer of 0 to 2, n21 and n31 may each independently be an integer of 0 to 3, and X, R₄, R₅, n4, and n5 may be as defined for Formula 1.

In one or more embodiments, at least one of R₁₂, R₂₂, or R₃₂ may be positioned para to boron atoms of Formula 2.

In one or more embodiments, the first compound represented by Formula 1 may be represented by Formula 3.

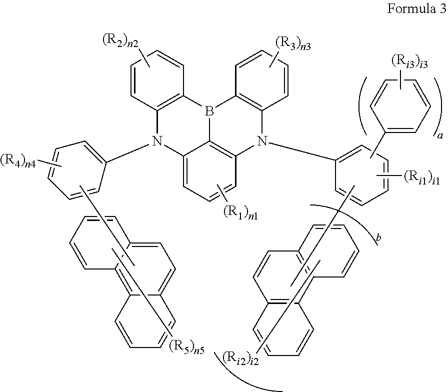

In Formula 3, Rᵢ₁, Rᵢ₂, and Rᵢ₃ may each independently be a hydrogen atom, a deuterium atom, a substituted or unsubstituted alkyl group having 1 to 20 carbon atoms, or a substituted or unsubstituted aryl group having 6 to 20 ring-forming carbon atoms. In Formula 3, i1 may be an integer of 0 to 3, i2 may be an integer of 0 to 9, and i3 may be an integer of 0 to 5. In Formula 3, a and b may each independently be an integer of 0 to 2, and a+b equals 2 or 3, and R₁ to R₅, and n1 to n5 may be as defined for Formula 1.

In one or more embodiments, the first compound represented by Formula 1 may be represented by Formula 4.

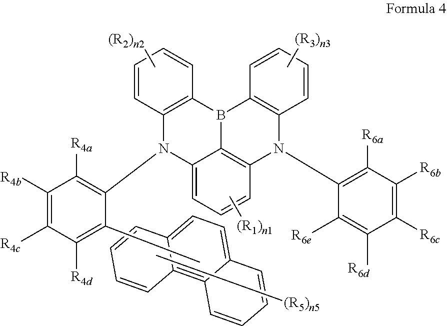

In Formula 4, at least one of (e.g., selected from among) R₄ₐ to R_{4d} and at least two of (e.g., selected from among) R₆ₐ to R₆ₑ may each independently be a substituted or unsubstituted phenyl group, or a substituted or unsubstituted phenanthryl group. In Formula 4, any remaining selected from among (e.g., the others of) R₄ₐ to R_{4d}, and any remaining selected from among (e.g., the others of) R₆ₐ to R₆ₑ may each independently be a hydrogen atom, a deuterium atom, a substituted or unsubstituted alkyl group having 1 to 6 carbon atoms, a substituted or unsubstituted aryl group having 6 to 30 ring-forming carbon atoms. In Formula 4, R₁ to R₃, R₅, n1 to n3, and n5 may be as defined for Formula 1.

In one or more embodiments, R₄ₐ, R₆ₐ, and R₆ₑ may each independently be a substituted or unsubstituted phenyl group, or a substituted or unsubstituted phenanthryl group, and R_{4b} to R_{4d}, and R_{6b} to R_{6d} may each independently be a hydrogen atom, a deuterium atom, a substituted or unsubstituted alkyl group having 1 to 30 carbon atoms, a substituted or unsubstituted aryl group having 6 to 30 ring-forming carbon atoms.

In one or more embodiments, R₁ to R₃ may each independently be a hydrogen atom, a deuterium atom, or represented by any one selected from among the substituents of Substituent Group 1, as described in more detail herein.

In one or more embodiments, at least one of (e.g., selected from among) R₁ to R₆ in Formula 1 may be a deuterium atom or include (e.g., comprise) a substituent including (e.g., containing) a deuterium atom.

In one or more embodiments, the emission layer may further include at least one of (e.g., selected from among) a second compound represented by Formula HT-1, a third compound represented by Formula ET-1, or a fourth compound represented by Formula D-1.

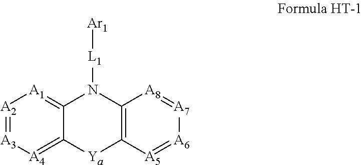

In Formula HT-1, A₁ to A₈ may each independently be N or CR₅₁, and L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Ar₁ may be a substituted or unsubstituted aryl group having 6 to 30 ring-forming carbon atoms, or a substituted or unsubstituted heteroaryl group having 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring.

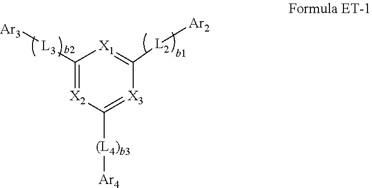

In Formula ET-1, at least one of (e.g., selected from among) X₁ to X₃ is N and any remaining selected from among X₁ to X₃ (e.g., the others) may be CR₅₆, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

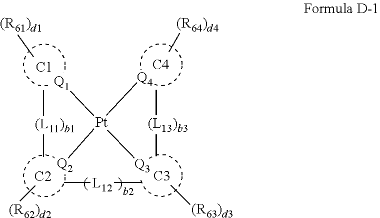

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

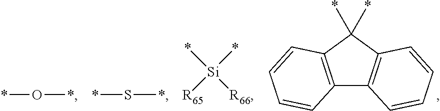

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the emission layer may include the first compound, the second compound, the third compound, and the fourth compound.

In one or more embodiments, the first compound represented by Formula 1 may include at least one of (e.g., selected from among) the compounds of Compound Group 1, which will be described later.

In one or more embodiments of the present disclosure, a polycyclic compound of one or more embodiments may be represented by Formula 1 described herein.

In one or more embodiments of the present disclosure, a display device may include a base layer, a circuit layer provided on the base layer, and a display element layer provided on the circuit layer and including a light emitting element, wherein the light emitting element includes a first electrode, a second electrode provided on the first electrode, and an emission layer provided between the first electrode and the second electrode, and the emission layer includes a polycyclic compound represented by Formula 1 as described herein.

In one or more embodiments, the light emitting element may further include a capping layer provided on the second electrode.

In one or more embodiments, the display device may further include a light control layer or a color filter.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view showing a display device according to one or more embodiments;

FIG. 2 is a cross-sectional view showing a portion corresponding to line I-I′ of FIG. 1;

FIG. 3 is a cross-sectional view schematically showing a light emitting element according to one or more embodiments;

FIG. 4 is a cross-sectional view schematically showing a light emitting element according to one or more embodiments;

FIG. 5 is a cross-sectional view schematically showing a light emitting element according to one or more embodiments;

FIG. 6 is a cross-sectional view schematically showing a light emitting element according to one or more embodiments;

FIG. 7 is a cross-sectional view schematically showing a light emitting element according to one or more embodiments;

FIG. 8 is a cross-sectional view showing a display device according to one or more embodiments;

FIG. 9 is a cross-sectional view showing a display device according to one or more embodiments;

FIG. 10 is a cross-sectional view showing a display device according to one or more embodiments;

FIG. 11 is a cross-sectional view showing a display device according to one or more embodiments; and

FIG. 12 is a view showing the inside of a vehicle in which a display device of one or more embodiments is provided.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements, and duplicative descriptions thereof may not be provided. In the accompanying drawings, the dimensions of each structure are exaggeratingly illustrated for clarity of the present disclosure.

It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an” and “the” are intended to include the plural forms as well, unless the context clearly indicates otherwise.

In the present application, it will be understood that the terms “include,” “includes,” “including,” “comprise,” “comprises”, “comprising,” “has,” “having,” and/or “have,” and/or the like, specify the presence of features, numbers, steps, operations, component, parts, or combinations thereof disclosed in the specification, but do not exclude the possibility of presence or addition of one or more other features, numbers, steps, operations, component, parts, or combinations thereof.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

The terms, such as “lower”, “above”, “upper” and/or the like, are utilized herein for ease of description to describe one element's relation to another element(s) as illustrated in the drawings. The terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation for example to the orientation depicted in the drawings. For example, when the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same refer toing as commonly understood by one of ordinary skill in the art to which this present disclosure belongs. It will be further understood that terms, such as those defined in commonly utilized dictionaries, should be interpreted as having a refer toing that is consistent with their refer toing in the context of the relevant art and will not be interpreted in an idealized or overly formal sense unless expressly so defined herein.

As utilized herein, the phrase “consisting essentially of” refers to that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” refers to viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition, but the “component” of less than a suitable amount may still be included due to other impurities and/or external factor.

### Definitions

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. For example, it will be understood that when a part is referred to as being “on” another part, it can be provided above the other part, or provided under the other part as well.

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. For example, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. For example, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

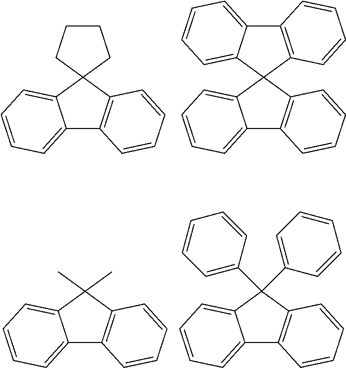

The heterocyclic group herein refers to any functional group or substituent derived from a ring containing at least one of B, O, N, P, S, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, Se or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, Se or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, Se or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyidimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

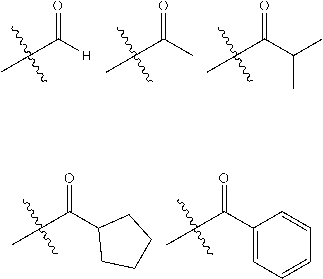

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a imethylboron group, a t-butylmethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In the specification,

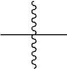

and “—*” refer to a position to be connected.

Hereinafter, embodiments of the present disclosure will be described with reference to the accompanying drawings.

### Display Device

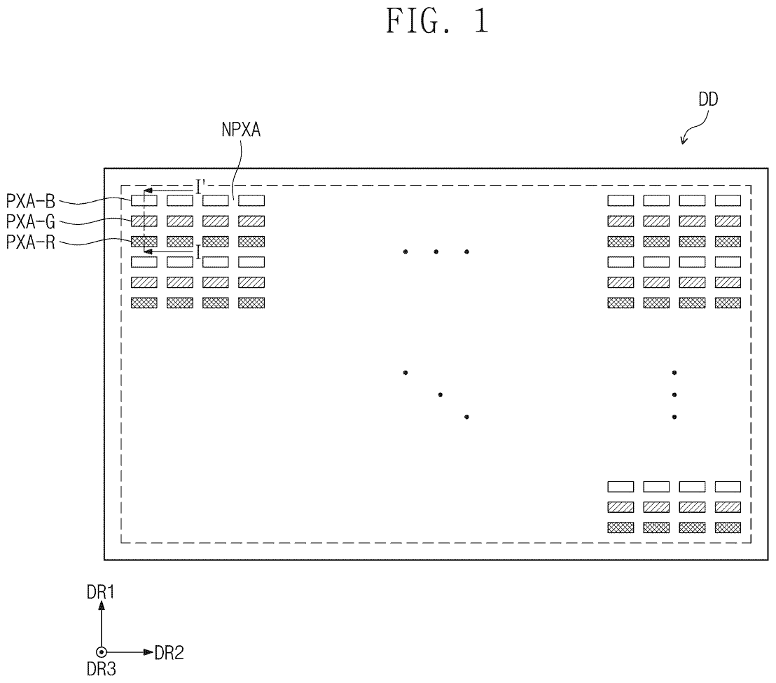

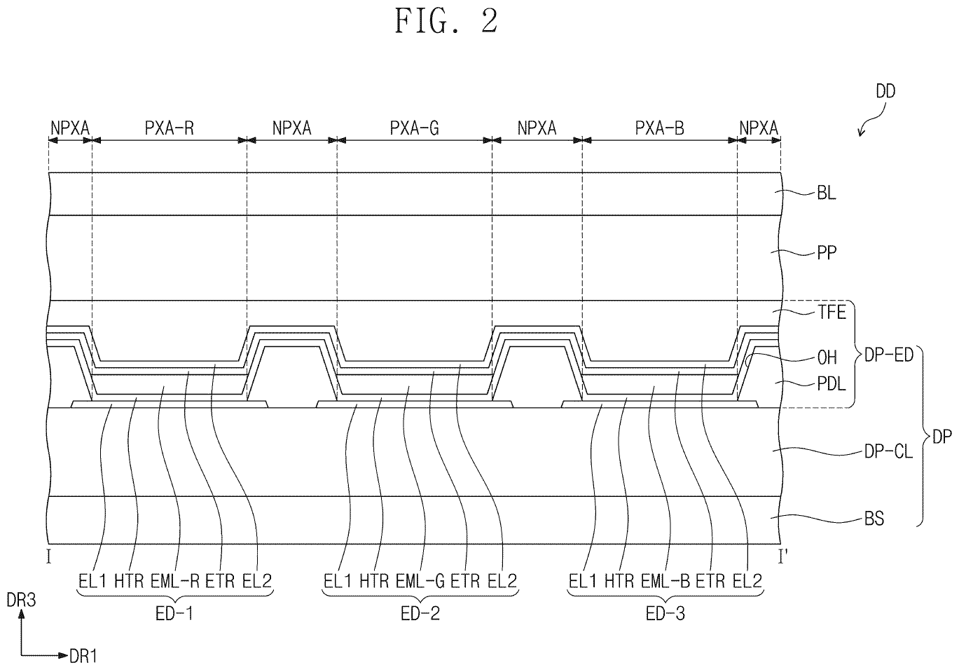

FIG. 1 is a plan view illustrating one or more embodiments of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP provided on the display panel DP. The display panel DP includes light emitting elements ED-1, ED-2, and ED-3. The display device DD may include a plurality of light emitting elements ED-1, ED-2, and ED-3. The optical layer PP may be provided on the display panel DP to control reflected light in the display panel DP due to external light. The optical layer PP may include, for example, a polarization layer or a color filter layer. In one or more embodiments, unlike the configuration illustrated in the drawing, the optical layer PP may not be provided in the display device DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. For example, unlike the configuration illustrated, in one or more embodiments, the base substrate BL may not be provided.

The display device DD according to one or more embodiments may further include a filling layer. The filling layer may be provided between a display element layer DP-ED and the base substrate BL. The filling layer may be an organic material layer. The filling layer may include at least one of an acrylic-based resin, a silicone-based resin, or an epoxy-based resin (e.g., at least one selected from among an acrylic-based resin, a silicone-based resin, and an epoxy-based resin).

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 provided between portions of the pixel defining film PDL, and an encapsulation layer TFE provided on the light emitting elements ED-1, ED-2, and ED-3.

The base layer BS may be a member which provides a base surface on which the display element layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

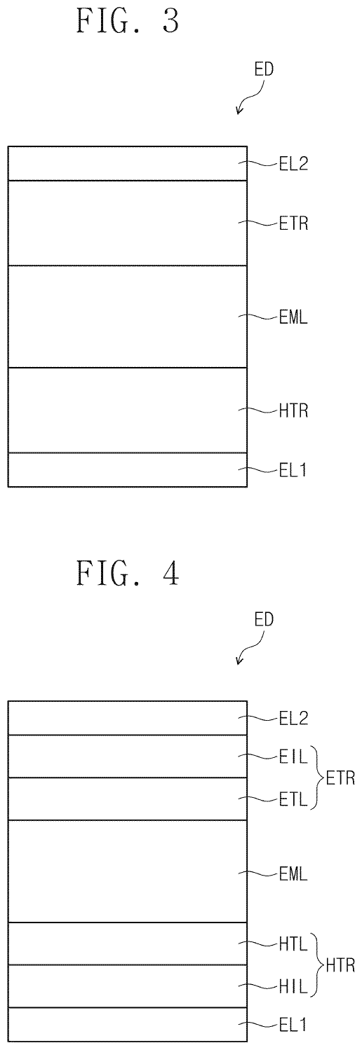

Each of the light emitting elements ED-1, ED-2, and ED-3 may have a structure of the (e.g., each) light emitting element ED of embodiments according to FIGS. 3 to 7, as described in more detail elsewhere herein. Each of the light emitting elements ED-1, ED-2, and ED-3 may include a first electrode EL1, a hole transport region HTR, a layer selected from emission layers EML-R, EML-G, and EML-B, an electron transport region ETR, and a second electrode EL2.

FIG. 2 illustrates one or more embodiments in which the emission layers EML-R, EML-G, and EML-B of the light emitting elements ED-1, ED-2, and ED-3 are provided in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the light emitting elements ED-1, ED-2, and ED-3. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the light emitting elements ED-1, ED-2, and ED-3 from moisture and/or oxygen, and the encapsulation-organic film protects the light emitting elements ED-1, ED-2, and ED-3 from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting elements ED-1, ED-2, and ED-3 are emitted. The light emitting regions PXA-R, PXA-G, and PXA-B may be spaced and/or apart from each other on a plane (e.g., in a plan view).

Each of the light emitting regions PXA-R, PXA-G, and PXA-B may be a region divided (i.e., defined) by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be provided in openings OH defined in the pixel defining film PDL and separated from each other.

The light emitting regions PXA-R, PXA-G, and PXA-B may be divided (e.g., defined) into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. For example, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a pentile (PENTILE™) arrangement form or a diamond (Diamond Pixel™) arrangement form, (PENTILE™ and Diamond Pixel™ are registered trademarks owned by Samsung Display Co., Ltd.).

For example, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 7 are cross-sectional views schematically showing light emitting elements according to one or more embodiments. The light emitting element ED of one or more embodiments may include a first electrode EL1, a hole transport region HTR, an emission layer EML, an electron transport region ETR, and a second electrode EL2 stacked in order.

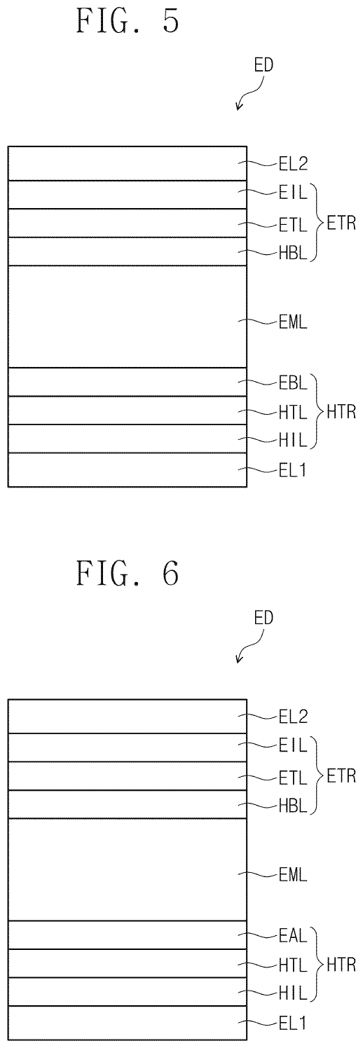

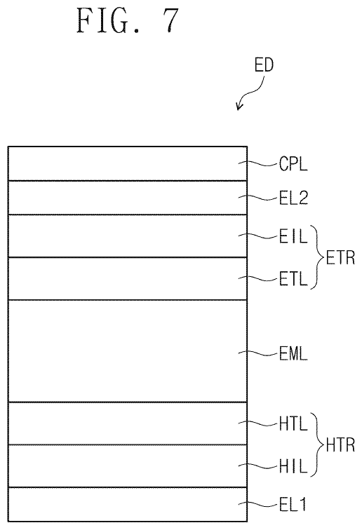

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. For example, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. For example, compared with FIG. 3, FIG. 6 illustrates a cross-sectional view of a light emitting element ED of one or more embodiments, in which a hole transport region HTR includes a hole injection layer HIL, a hole transport layer HTL, and a light emitting auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light emitting element ED of one or more embodiments including a capping layer CPL provided on a second electrode EL2.

The first electrode EL1 has conductivity (e.g., is a conductor). The first electrode EL1 may include (e.g., be formed of) a metal material, a metal alloy, or a conductive compound. The first electrode EL1 may be an anode or a cathode. However, the embodiment of the present disclosure is not limited thereto. For example, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film including (e.g., formed of) the herein-described materials, and a transparent conductive film including (e.g., formed of) ITO, IZO, ZnO, ITZO, and/or the like. For example, the first electrode EL1 may have a three-layer structure of ITO/Ag/ITO, but the embodiment of the present disclosure is not limited thereto. For example, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (A) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a light emitting auxiliary layer EAL, or an electron blocking layer EBL. The thickness of the hole transport region HTR may be, for example, from about 50 Å to about 15,000 Å. The light emitting auxiliary layer EAL may also be referred to as a buffer layer.

The hole transport region HTR may have a single layer including (e.g., formed of) a single material, a single layer including (e.g., formed of) a plurality of different materials, or a multilayer structure including a plurality of layers including (e.g., formed of) a plurality of different materials.

For example, the hole transport region HTR may have a single layer structure of the hole injection layer HIL or the hole transport layer HTL, or may have a single layer structure including (e.g., formed of) a hole injection material and a hole transport material. For example, the hole transport region HTR may have a single layer structure including (e.g., formed of) a plurality of different materials, or a structure in which a hole injection layer HIL/hole transport layer HTL, a hole injection layer HIL/hole transport layer HTL/light emitting auxiliary layer EAL, a hole injection layer HIL/light emitting auxiliary layer EAL, a hole transport layer HTL/light emitting auxiliary layer EAL, a hole injection layer HIL/hole transport layer HTL/electron blocking layer EBL or a hole injection layer HIL/hole transport layer HTL/light emitting auxiliary layer EAL are stacked in order from the first electrode EL1, but the embodiment of the present disclosure is not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and a laser induced thermal imaging (LITI) method.

The hole transport region HTR may include a compound represented by Formula H-1:

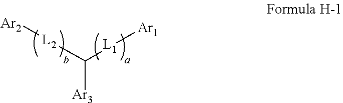

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes the amine group as a substituent. For example, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are merely examples, and the compounds represented by Formula H-1 are not limited to those represented by Compound Group H:

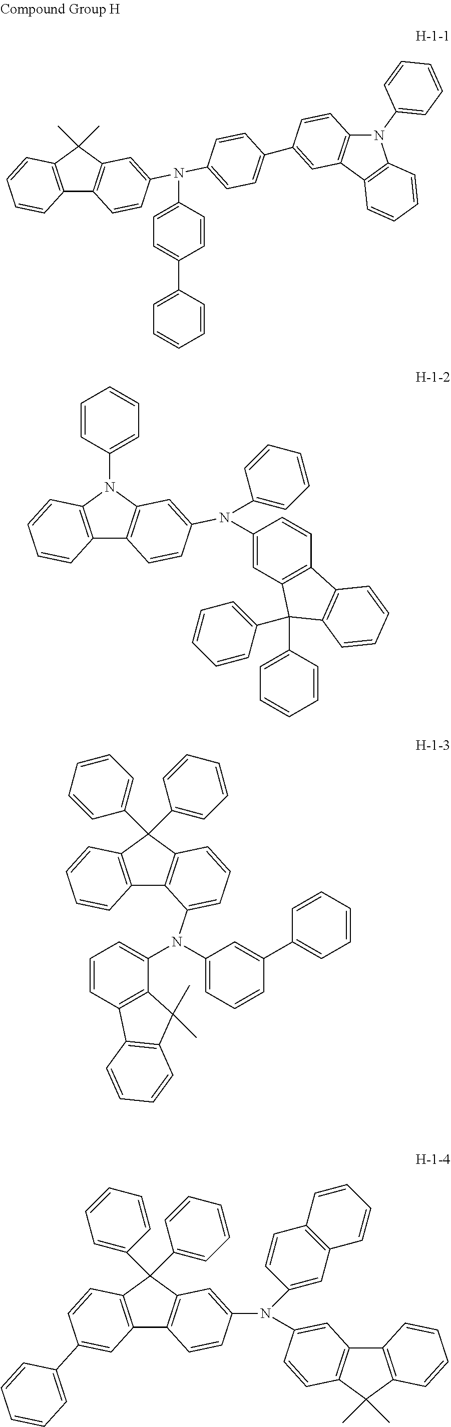 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

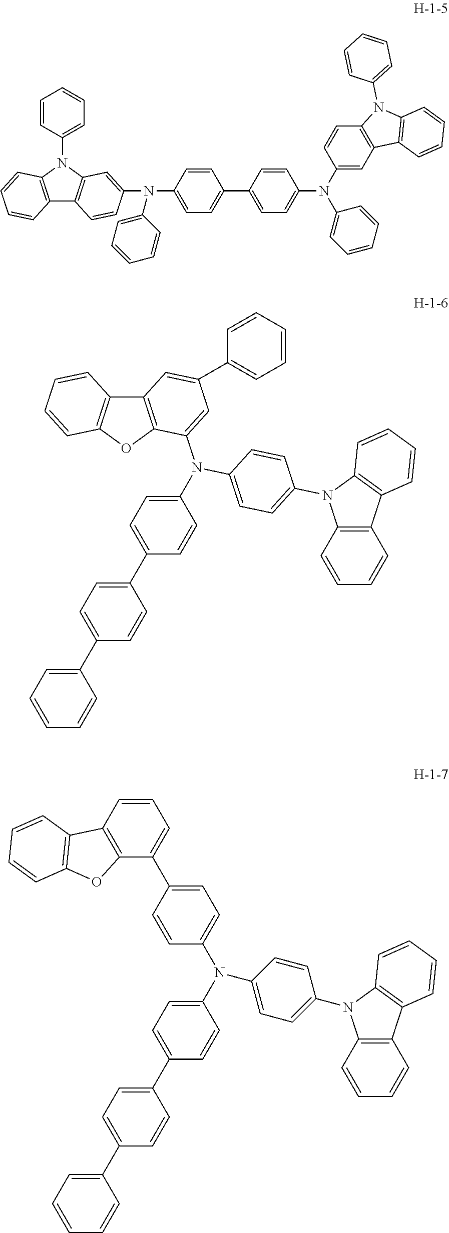 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

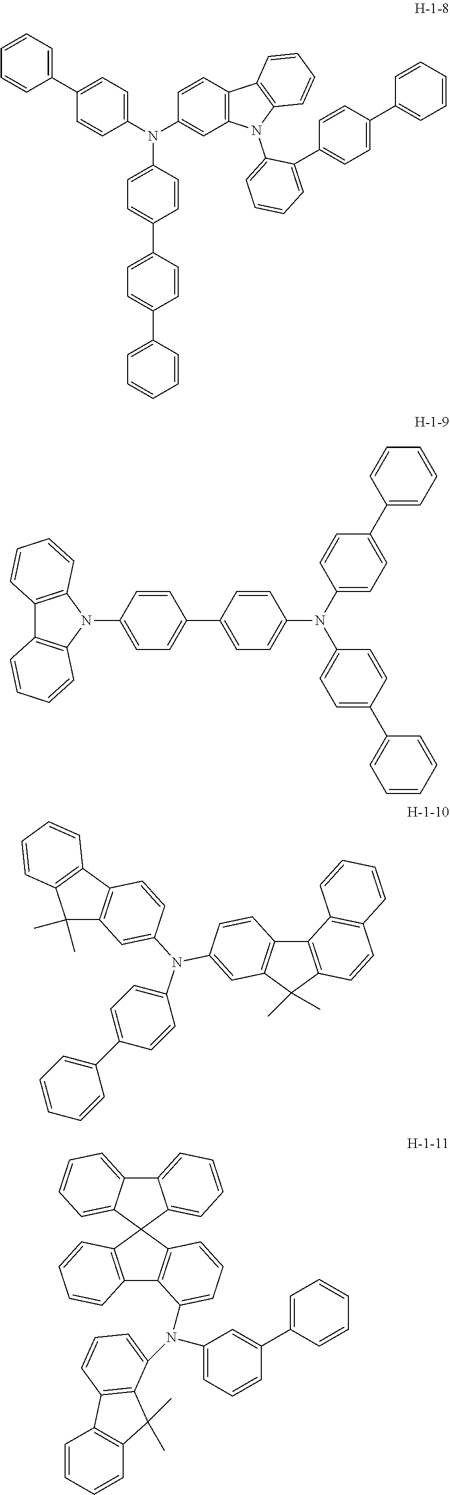

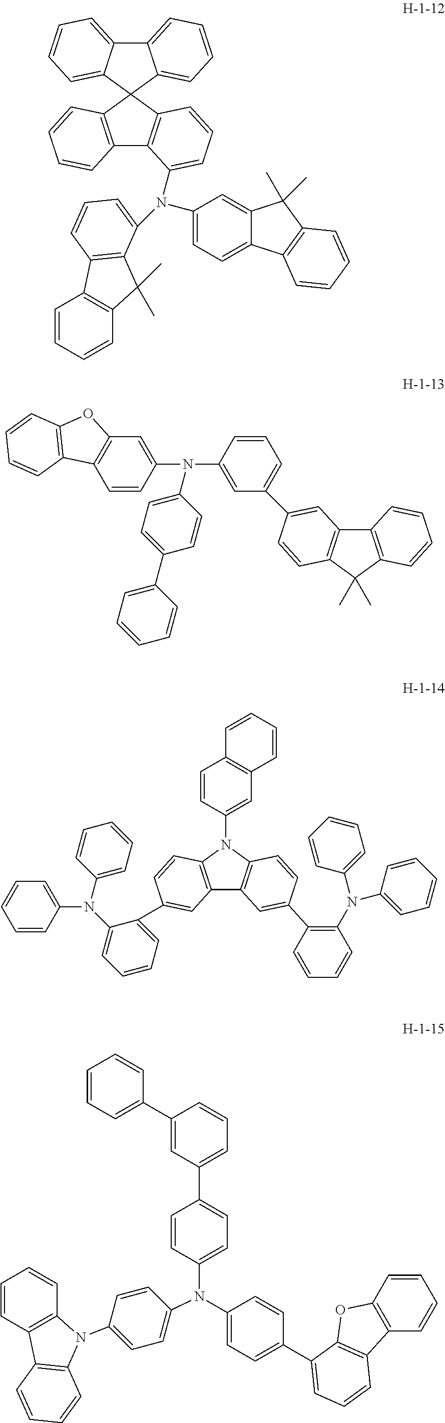 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

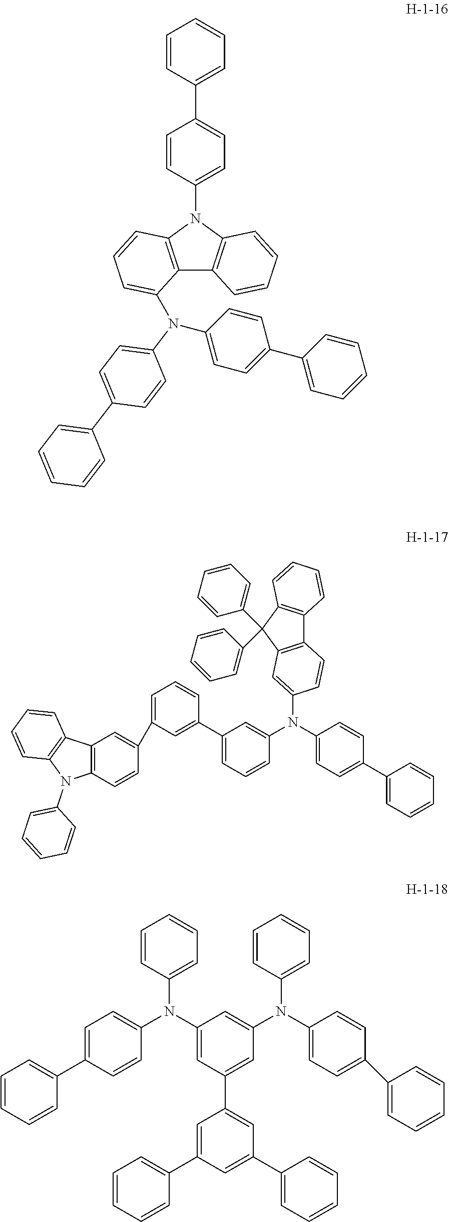 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

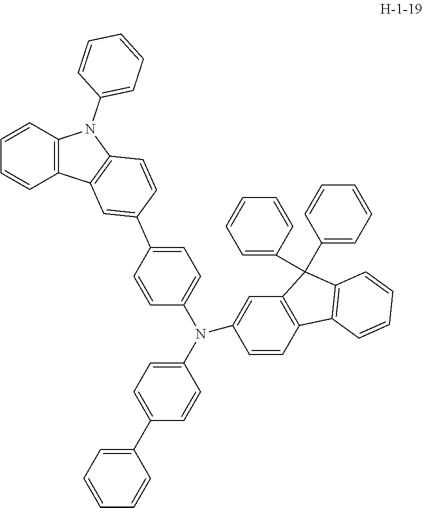 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

For example, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region HTR in at least one of a hole injection layer HIL, a hole transport layer HTL, a light emitting auxiliary layer EAL or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the light emitting auxiliary layer EAL or the electron blocking layer EBL for example to the hole injection layer HIL and the hole transport layer HTL. The light emitting auxiliary layer EAL may compensate for a resonance distance according to the wavelength of light emitted from the emission layer EML and may thus increase light emission efficiency. For example, the light emitting auxiliary layer EAL may also serve to prevent electron injection into the hole transport region HTR. A material that may be included in the hole transport region HTR may be utilized as a material to be included in the light emitting auxiliary layer EAL. The electron blocking layer EBL is a layer that serves to prevent the electron injection from the electron transport region ETR to the hole transport region HTR.

In the light emitting element ED of one or more embodiments, the emission layer EML may include a polycyclic compound according to one or more embodiments. In the light emitting element ED of one or more embodiments, the emission layer EML may include a first compound, and at least one of a second compound or a third compound. For example, in the light emitting element ED of one or more embodiments, the emission layer EML may further include a fourth compound. The second compound may include a fused ring of three rings, which contains a nitrogen atom as a ring-forming atom. The third compound may include a hexagonal ring group containing at least one nitrogen atom as a ring-forming atom. The fourth compound may include an organometallic complex. The second to fourth compounds are described in more detail elsewhere herein.

### Polycyclic Compound

Herein, the first compound may be referred to as a polycyclic compound of one or more embodiments. The polycyclic compound of one or more embodiments includes a 5-ring fused ring containing one nitrogen (N) atom, one hetero atom, and one boron (B) atom as ring-forming atoms, as a central structure. Herein, the central structure of the 5-ring fused ring may be referred to as a “ore”. For example, the hetero atom included in the core may be a nitrogen atom (N), a sulfur (S) atom, an oxygen (O) atom, or a selenium (Se) atom.

The polycyclic compound of one or more embodiments may include a structure in which first to third aromatic rings are fused through the first nitrogen atom, the first hetero atom, and the boron atom. The first aromatic ring may be linked to each (e.g., all) of the first nitrogen atom, the first hetero atom, and the boron atom. The second aromatic ring may be linked to the first aromatic ring through the boron atom and the first nitrogen atom. The first aromatic ring may be linked to the third aromatic ring through the boron atom and the first hetero atom. For example, the first to third aromatic rings may each be linked to the boron atom.

In one or more embodiments of the polycyclic compound, a portion of the core where the nitrogen atom is located may be a site having high electron density. Accordingly, the polycyclic compound of one or more embodiments may include a first substituent that is linked to the first nitrogen atom of the core to protect the core and suppress dexter energy transfer. For example, when the core contains two nitrogen atoms as ring-forming atoms, the polycyclic compound of one or more embodiments may further include a first substituent linked to the first nitrogen atom of the core, and also, the second nitrogen atom.

The first substituent may include a phenanthrene moiety. The polycyclic compound of one or more embodiments includes the phenanthrene moiety as the first substituent, and may thus better protect the core exhibiting multi-resonance characteristics and reduce exciton decay to other (e.g., energetic) pathways (e.g., sub-pathways), thereby contributing to improving efficiency of the light emitting element ED. For example, the first substituent may be linked to the first nitrogen atom of the core through a first linker. In one or more embodiments, the first linker may include a benzene moiety. For example, the first linker may be a substituted or unsubstituted phenylene linker.

The light emitting element ED of one or more embodiments may include a polycyclic compound of one or more embodiments. The polycyclic compound of one or more embodiments may be represented by Formula 1. In the polycyclic compound represented by Formula 1, a benzene ring to which R₁ is linked may correspond to the first aromatic ring described herein, a benzene ring to which R₂ is linked may correspond to the second aromatic ring described herein, a benzene ring to which R₃ is linked may correspond to the third aromatic ring described herein.

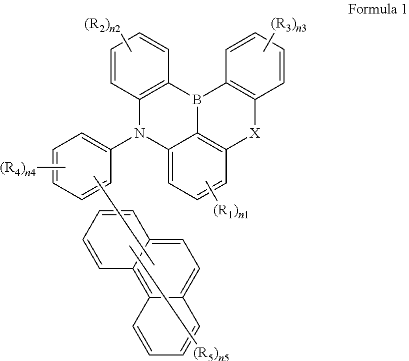

In Formula 1, X may be NR₆, S, O, or Se. For example, X may be NR₆. When X is NR₆ in the polycyclic compound of one or more embodiments, a steric hindrance effect, in which other materials are hardly available to access the core, may be greater. Accordingly, the polycyclic compound of one or more embodiments may maximize the suppression of dexter energy transfer and further improve material stability in the light emitting element ED.

In Formula 1, R₁ to R₅ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms.

For example, R₁ to R₃ may each independently be a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. In one or more embodiments, R₁ to R₃ may each independently be a hydrogen atom, a deuterium atom, a substituted or unsubstituted amine group, a substituted or unsubstituted t-butyl group, a substituted or unsubstituted phenyl group, a substituted or unsubstituted biphenyl group, a substituted or unsubstituted terphenyl group, a substituted or unsubstituted dibenzofuran group, a substituted or unsubstituted dibenzothiophene group, a substituted or unsubstituted carbazole group, a substituted or unsubstituted fluorenyl group, a substituted or unsubstituted dihydroacridine group, a substituted or unsubstituted xanthene group, a substituted or unsubstituted phenoxazine group, or a substituted or unsubstituted indolocarbazole group. When R₁ to R₃ are each substituted with different substituents, R₁ to R₃ may be substituted with a deuterium atom, a cyano group, a substituted or unsubstituted alkyl group, or a substituted or unsubstituted aryl group. For example, R₁ to R₃ may each be substituted with a deuterium atom, a cyano group, an unsubstituted methyl group, an unsubstituted t-butyl group, an unsubstituted phenyl group, an unsubstituted biphenyl group, and/or the like, but the embodiment of the present disclosure is limited thereto.

In one or more embodiments, R₁ to R₃ may each independently be represented by a hydrogen atom, a deuterium atom, or any one selected from among the substituents of Substituent Group 1.

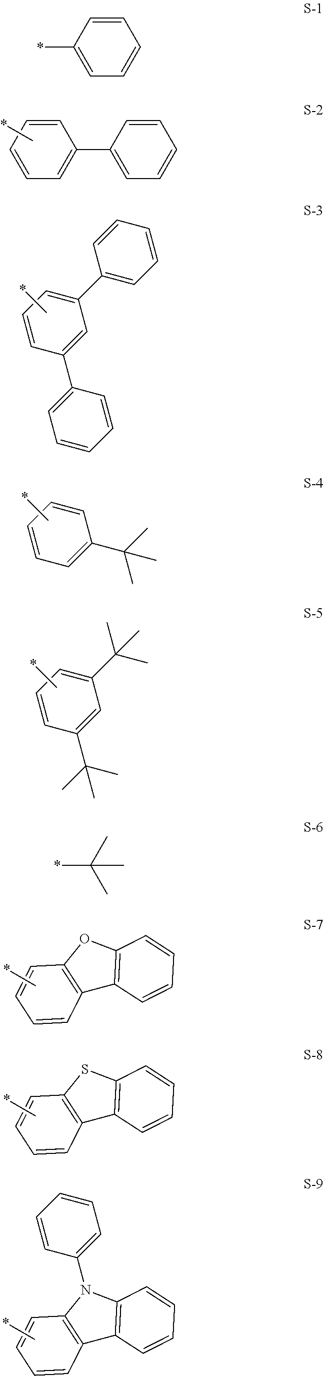

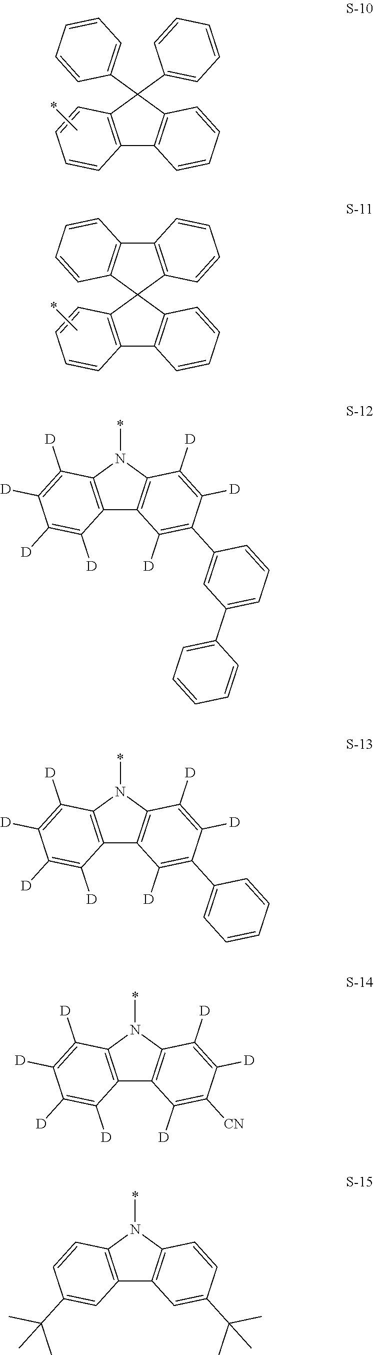

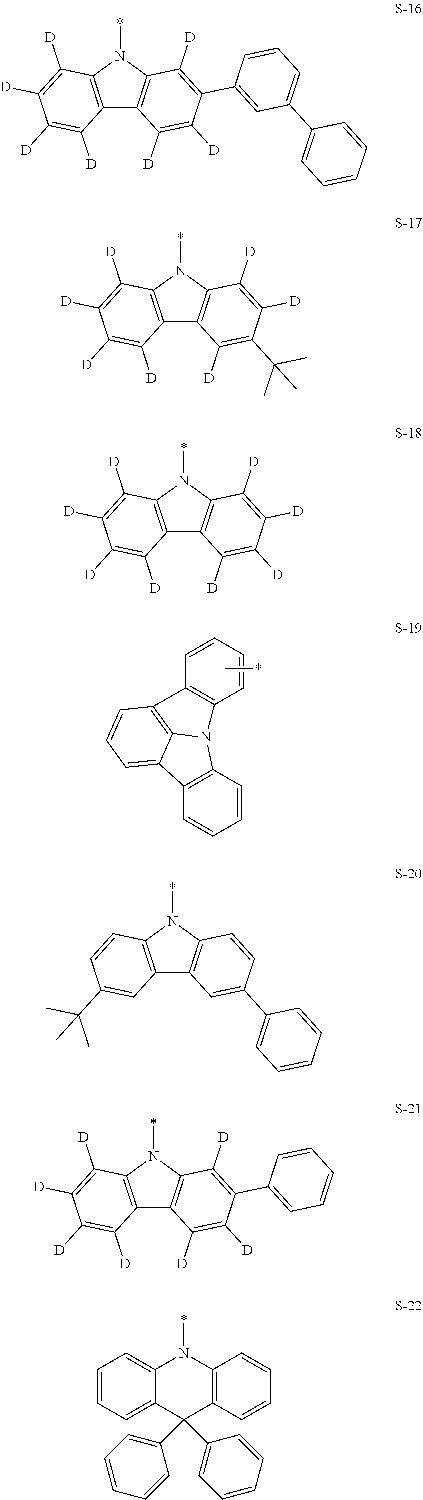

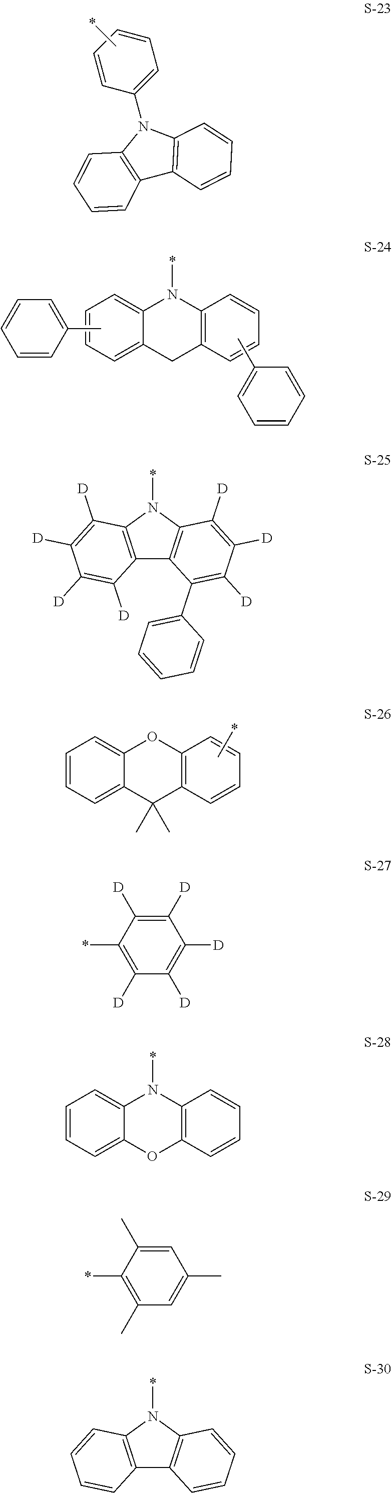

For example, R₄ and R₅ may each independently be a hydrogen atom, a deuterium atom, a substituted or unsubstituted alkyl group having 1 to 30 carbon atoms, or a substituted or unsubstituted aryl group having 6 to 30 ring-forming carbon atoms. In one or more embodiments, R₄ may be a hydrogen atom, a deuterium atom, a substituted or unsubstituted t-butyl group, a substituted or unsubstituted phenyl group, a substituted or unsubstituted biphenyl group, or a substituted or unsubstituted phenanthryl group. In one or more embodiments, R₅ may be a hydrogen atom or a deuterium atom, but the embodiment of the present disclosure is limited thereto.

In Formula 1, R₆ may be a substituted or unsubstituted aryl group having 6 to 30 ring-forming carbon atoms, or a substituted or unsubstituted heteroaryl group having 5 to 30 ring-forming carbon atoms. For example, R₆ may be a substituted biphenyl group. R₆ may be a substituted or unsubstituted t-butyl group, a substituted or unsubstituted phenyl group, a substituted or unsubstituted biphenyl group, or a biphenyl group substituted with a substituted or unsubstituted phenanthryl group.

In Formula 1, n1 may be an integer of 0 to 3. n2 to n4 may each independently be an integer of 0 to 4. n5 may be an integer of 0 to 9. When n1 to n5 are each 0, the polycyclic compound according to one or more embodiments may not be substituted by each of R₁, R₂, R₃, R₄, and R₅. The case where n1 is 0 may be the same as a case where n1 is 3 and all three R₁'s are hydrogen atoms. For example, the case where n2 to n4 are each 0 may be the same as a case where n2 to n4 are 4 and R₂ to R₄ each provided in sets of four are each (e.g., all) hydrogen atoms. The case where n5 is 0 may be the same as a case where n5 is 9 and each (e.g., all) nine R₅'s are hydrogen atoms. When n1 to n5 are each an integer of 2 or greater, R₁, R₂, R₃, R₄, and R₅ provided in plurality may each (e.g., all) be the same or at least one may be different from the others.

For example, when n1 is 3, R₁ bonded to a first aromatic ring and (e.g., to be) positioned para to the boron atom of the core may be a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms, and the other two R₁'s bonded to the first aromatic ring may each (e.g., all) be hydrogen atoms or deuterium atoms. However, the embodiment of the present disclosure is not limited thereto, and the number and type of substituted R₁'s may be selected depending on one or more embodiments of the polycyclic compound.

For example, when n2 and n3 are each 4, one R₂ and one R₃ bonded to a second aromatic ring and a third aromatic ring and (e.g., to be) positioned para or meta to the boron atom of the core may be a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. The other three R₂'s linked to the second aromatic ring and the other three R₃'s linked to the third aromatic ring may each and all be hydrogen atoms or deuterium atoms. However, the embodiment of the present disclosure is not limited thereto, and the number and type of R₂'s and R₃'s substituted in the second aromatic ring and the third aromatic ring may be selected depending on one or more embodiments of the polycyclic compound.

In one or more embodiments, n1+n2+n3≠0 (i.e., the sum of n1+n2+n3 may not be zero) may be applied, and at least one of R₁ to R₃ may not be a hydrogen atom. For example, in the polycyclic compound represented by Formula 1, at least one of (e.g., selected from among) R₁ to R₃ substituted in the first to third aromatic rings may not be a hydrogen atom. To be specific, R₁ to R₃ may each be provided in plurality, and at least one of (e.g., selected from among) R₁ to R₃ provided in plurality may not be a hydrogen atom.

In the polycyclic compound of one or more embodiments represented by Formula 1, at least one hydrogen atom may be substituted by (e.g., with) a deuterium atom. In one or more embodiments, at least one hydrogen atom of (e.g., selected from among) R₁ to R₆ in Formula 1 may be substituted with a deuterium atom. For example, at least one of (e.g., selected from among) R₁ to R₆ may be a deuterium atom or a substituent containing a deuterium atom.

In the polycyclic compound of one or more embodiments, at least one substituent that is not (e.g., instead of) a hydrogen atom may be included in (e.g., introduced into) the first to third aromatic rings. In the polycyclic compound of one or more embodiments, when at least one substituent is included in (e.g., introduced into) each of the first to third aromatic rings, the boron atoms of the core may be better protected, and accordingly, the polycyclic compound may have improved material stability.

The polycyclic compound of one or more embodiments represented by Formula 1 may be represented by Formula 2. Formula 2 shows a structure in which each of the first to third aromatic rings is substituted with a substituent as an example. In the polycyclic compound of one or more embodiments, a first substituent may be linked to the nitrogen atom of the core through a first linker, and substituents may be linked to the first to third aromatic rings, thereby producing a steric hindrance effect in which other materials are hardly available to access the core. Accordingly, in the polycyclic compound of one or more embodiments, the effect of protecting the core may be maximized.

For example, the boron atom included in the core may be electron-deficient (e.g., has electron-deficient properties) due to an empty p-orbital, and may thus be easily bonded to other nucleophiles or deteriorated products (e.g., radicals, and the like) in an element. When the boron atom forms a bond with other nucleophiles or deteriorated products, a boron atom having a trigonal planar bonding structure in the core portion of the polycyclic compound may be converted (e.g., turn) into a boron atom having a tetrahedral bonding structure, (e.g., which may cause element deterioration). In the polycyclic compound of one or more embodiments, the first substituent may be linked to the nitrogen atom of the core portion through the first linker, and substituents that may provide a steric hindrance effect are linked to each of the first to third aromatic rings, and accordingly, the empty p-orbital of boron atoms may effectively be protected to prevent deterioration resulting from structural deformation of materials.

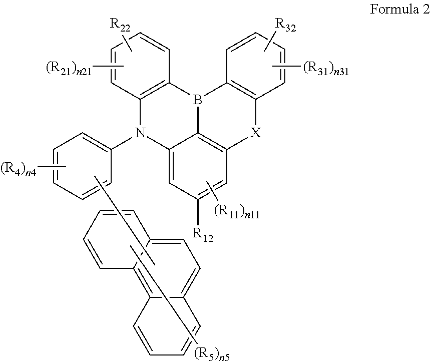

In Formula 2, the same descriptions as in Formula 1 herein may also apply to X, R₄ and R₅, n4, and n5.

In Formula 2, R₁₁, R₂₁, and R₃₁ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. For example, R₁₁, R₂₁, and R₃₁ may each independently be a hydrogen atom or a deuterium atom.

In Formula 2, n11 may be an integer of 0 to 2, and n21 and n31 may each independently be an integer of 0 to 3. In Formula 2, when n11, n21, and n31 are each 0, the polycyclic compound of one or more embodiments may not be substituted with each of R₁₁, R₂₁, and R₃₁. The case where n21 and n31 are each 0 may be the same as a case where n21 and n31 are each 3 and R₂₁ and to R₃₁ each provided in plurality are all hydrogen atoms. When n11, n21, and n31 are each 2 or greater, R₁₁, R₂₁, and R₃₁ provided in plurality may each and all be the same or at least one may be different from the others.

In Formula 2, R₁₂, R₂₂, and R₃₂ may each independently be a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. For example, R₁₂, R₂₂, and R₃₂ may each independently be a substituted or unsubstituted amine group, a substituted or unsubstituted t-butyl group, a substituted or unsubstituted phenyl group, a substituted or unsubstituted biphenyl group, a substituted or unsubstituted terphenyl group, a substituted or unsubstituted dibenzofuran group, a substituted or unsubstituted dibenzothiophene group, a substituted or unsubstituted carbazole group, a substituted or unsubstituted fluorenyl group, a substituted or unsubstituted dihydroacridine group, a substituted or unsubstituted xanthene group, a substituted or unsubstituted phenoxazine group, or a substituted or unsubstituted indolocarbazole group. When R₁₂, R₂₂, and R₃₂ are each substituted, R₁₂, R₂₂, and R₃₂ may each be substituted with a deuterium atom, a cyano group, an unsubstituted methyl group, an unsubstituted t-butyl group, an unsubstituted phenyl group, an unsubstituted biphenyl group, and/or the like, but the embodiment of the present disclosure is not limited thereto. In one or more embodiments, R₁₂, R₂₂, and R₃₂ may each independently be represented by any one selected from among the substituents of Substituent Group 1.

In one or more embodiments, at least one of R₁₂, R₂₂, or R₃₂ may be positioned para to the boron atom of the core. For example, R₁₂ may be linked to the first aromatic ring and (e.g., to be) positioned para to the boron atom of the core. For example, R₂₂ may be linked to the second aromatic ring to be positioned para to the boron atom of the core, and R₃₂ may be linked to the third aromatic ring to be positioned para to the boron atom of the core. However, the embodiment of the present disclosure is not limited thereto, and R₂₂ and R₃₂ may each be bonded to the second aromatic ring and the third aromatic ring to be positioned meta to the boron atom of the core.

In one or more embodiments, the polycyclic compound represented by Formula 1 includes a structure in which the first to third aromatic rings are fused through two nitrogen atoms and one boron atom, and may be represented by Formula 3. The polycyclic compound represented by Formula 3 may include a structure in which the first substituent is linked to the first nitrogen atom of the core through the first linker, and a substituted or unsubstituted phenyl group and/or a substituted or unsubstituted phenanthryl group may be linked to the second nitrogen atom of the core through the second linker. The second linker may include a benzene moiety, for example, a substituted or unsubstituted phenylene group. The polycyclic compound represented by Formula 3 may suitably (e.g., effectively) protect the boron atom of the core, and may thus have improved chemical stability.

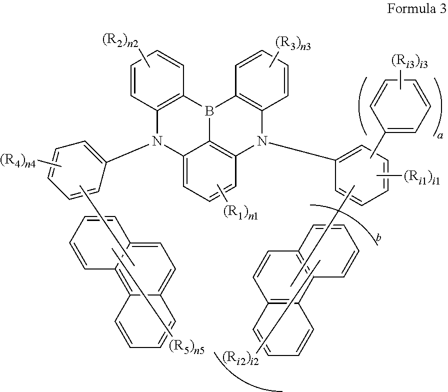

In Formula 3, a and b may each independently be an integer of 0 to 2, and a+b may equal 2 or 3. For example, when a is 2 and b is 0, the polycyclic compound represented by Formula 3 may include a structure in which at least two substituted or unsubstituted phenyl groups are linked to the second nitrogen atom through the second linker. Accordingly, in the polycyclic compound represented by Formula 3, a substituted or unsubstituted terphenyl group may be linked to the second nitrogen atom. When a is 1 and b is 1, the polycyclic compound represented by Formula 3 may include at least one substituted or unsubstituted phenyl group and at least one substituted or unsubstituted phenanthryl group linked to the second nitrogen atom through the second linker. When a is 0 and b is 2, the polycyclic compound represented by Formula 3 may include two substituted or unsubstituted phenanthryl groups linked to the second nitrogen atom through the second linker. However, the embodiment of the present disclosure is not limited thereto, and a may be 1 and b may be 2, or a may be 2 and b may be 3.

In Formula 3, Rᵢ₁, Rᵢ₂, and Rᵢ₃ may each independently be a hydrogen atom, a deuterium atom, a substituted or unsubstituted alkyl group having 1 to 20 carbon atoms, or a substituted or unsubstituted aryl group having 6 to 20 ring-forming carbon atoms. For example, Rᵢ₁ and Rᵢ₃ may each independently be a hydrogen atom, a deuterium atom, an unsubstituted t-butyl group, or an unsubstituted phenyl group. Rᵢ₂ may be a hydrogen atom or a deuterium atom.

In Formula 3, i1 may be an integer of 0 to 3, i2 may be an integer of 0 to 9, and i3 may be an integer of 0 to 5. In Formula 3, when i1, i2, and i3 are each 0, the polycyclic compound of one or more embodiments may not be substituted with (e.g., may exclude) each of Rᵢ₁, Rᵢ₂, and Rᵢ₃. The case where i1 is 0 may be the same as a case where i1 is 3 and three Rᵢ₁'s are all hydrogen atoms. The case where i2 is 0 may be the same as a case where i2 is 9 and nine Rᵢ₂'s are all hydrogen atoms. The case where i3 is 0 may be the same as a case where i3 is 5 and five Rᵢ₃'s are all hydrogen atoms. When i1, i2, and i3 are each 2 or greater, Rᵢ₁, Rᵢ₂, and Rᵢ₃ provided in plurality may each and all be the same or at least one Rᵢ₁, Rᵢ₂, and Rᵢ₃ may be different from the others.

In Formula 3, R₁ to R₅, and n1 to n5 may be as defined for Formula 1.

In one or more embodiments, the polycyclic compound represented by Formula 1 may be represented by Formula 4. In the polycyclic compound of one or more embodiments represented by Formula 4, the first substituent may be linked to an ortho-positioned carbon with respect to the carbon atom linked to the first nitrogen atom among the carbons including (e.g., constituting) a phenylene group of the first linker. Accordingly, the first substituent may be linked to the first linker and (e.g., to be) positioned ortho to the first nitrogen atom of the core. For example, the polycyclic compound of one or more embodiments may include at least one phenyl group or phenanthryl group linked to the first nitrogen atom through the first linker of a phenylene group, and may include at least two phenyl groups or phenanthryl groups linked to the second nitrogen atom through the second linker of a phenylene group.

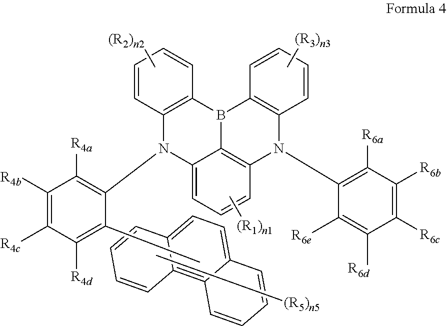

In Formula 4, at least one of R₄ₐ to R_{4d} may be a substituted or unsubstituted phenyl group, or a substituted or unsubstituted phenanthryl group. For example, any remaining selected from among (e.g., the others of) R₄ₐ to R_{4d} may each independently be a hydrogen atom, a deuterium atom, a substituted or unsubstituted alkyl group having 1 to 30 carbon atoms, or a substituted or unsubstituted aryl group having 6 to 30 ring-forming carbon atoms. For example, any one selected from among R₄ₐ to R_{4d} may be an unsubstituted phenyl group, an unsubstituted biphenyl group, or an unsubstituted phenanthryl group. In this case, the other three selected from among R₄ₐ to R_{4d} may each independently be a hydrogen atom, a deuterium atom, or an unsubstituted t-butyl group.

In Formula 4, at least two of (e.g., selected from among) R₆ₐ to R₆ₑ may be a substituted or unsubstituted phenyl group, or a substituted or unsubstituted phenanthryl group. Any remaining selected from among (e.g., the others of) R₆ₐ to R₆ₑ may each independently be a hydrogen atom, a deuterium atom, a substituted or unsubstituted alkyl group having 1 to 30 carbon atoms, or a substituted or unsubstituted aryl group having 6 to 30 ring-forming carbon atoms. For example, two of (e.g., selected from among) R₆ₐ to R₆ₑ may both be substituted or unsubstituted phenyl groups, or both may be substituted or unsubstituted phenanthryl groups. Alternatively, two of (e.g., selected from among) R₆ₐ to R₆ₑ may each be a substituted or unsubstituted phenyl group and a substituted or unsubstituted phenanthryl group. The other three selected from among R₆ₐ to R₆ₑ may each independently be a hydrogen atom, a deuterium atom, an unsubstituted t-butyl group, a substituted or unsubstituted phenyl group, or a substituted or unsubstituted phenanthryl group.

In one or more embodiments, R₄ₐ, R₆ₐ, and R₆ₑ in Formula 4 may each independently be a substituted or unsubstituted phenyl group, or a substituted or unsubstituted phenanthryl group. Accordingly, the polycyclic compound of one or more embodiments represented by Formula 4 may include a substituted or unsubstituted phenyl group or a substituted or unsubstituted phenanthryl group linked to the first linker to be positioned ortho to the first nitrogen atom and linked to the second linker to be positioned ortho to the second nitrogen atom.

In one or more embodiments, in Formula 4, R_{4b} to R_{4d}, and R_{6b} to R_{6d} may each independently be a hydrogen atom, a deuterium atom, a substituted or unsubstituted alkyl group having 1 to 30 carbon atoms, a substituted or unsubstituted aryl group having 6 to 30 ring-forming carbon atoms. For example, R_{4b} to R_{4d} may each independently be a hydrogen atom, a deuterium atom, or an unsubstituted t-butyl group. R_{6b} to R_{6d} may each independently be a hydrogen atom, a deuterium atom, an unsubstituted t-butyl group, an unsubstituted phenyl group, or an unsubstituted phenanthryl group. In Formula 4, R1 to R3, R5, n1 to n3 and n5 may be as defined in Formula 1.

The polycyclic compound of one or more embodiments may be represented by any one selected from among the compounds of Compound Group 1. The light emitting element ED according to one or more embodiments may include at least one of the compounds selected from among Compound Group 1. In Compound Group 1, D is a deuterium atom.

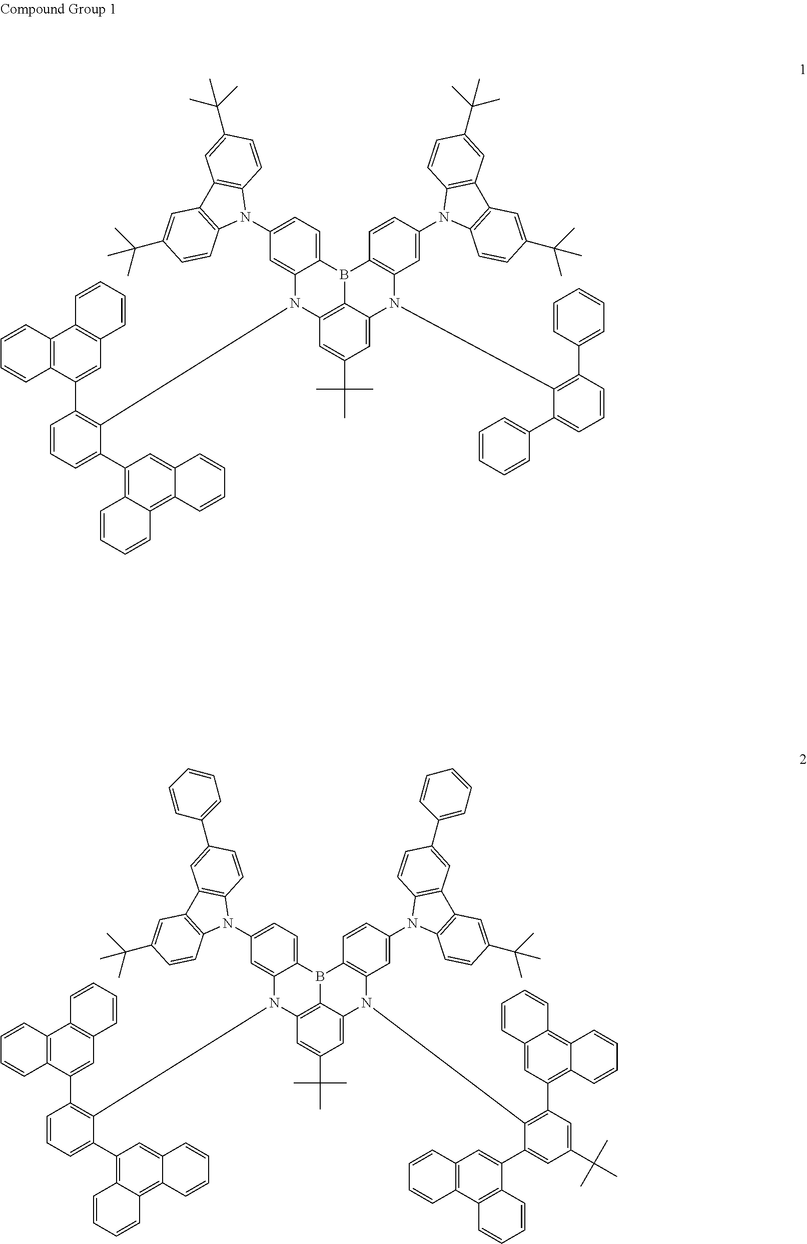 [SMILES: CC(C)(C)c1cc2c3c(c1)N(c1c(-c4cc5ccccc5c5ccccc45)cccc1-c1cc4ccccc4c4ccccc14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; CC(C)(C)c1cc(-c2cc3ccccc3c3ccccc23)c(N2c3cc(-n4c5ccc(-c6ccccc6)cc5c5cc(C(C)(C)C)ccc54)ccc3B3c4ccc(-n5c6ccc(-c7ccccc7)cc6c6cc(C(C)(C)C)ccc65)cc4N(c4c(-c5cc6ccccc6c6ccccc56)cccc4-c4cc5ccccc5c5ccccc45)c4cc(C(C)(C)C)cc2c43)c(-c2cc3ccccc3c3ccccc23)c1]

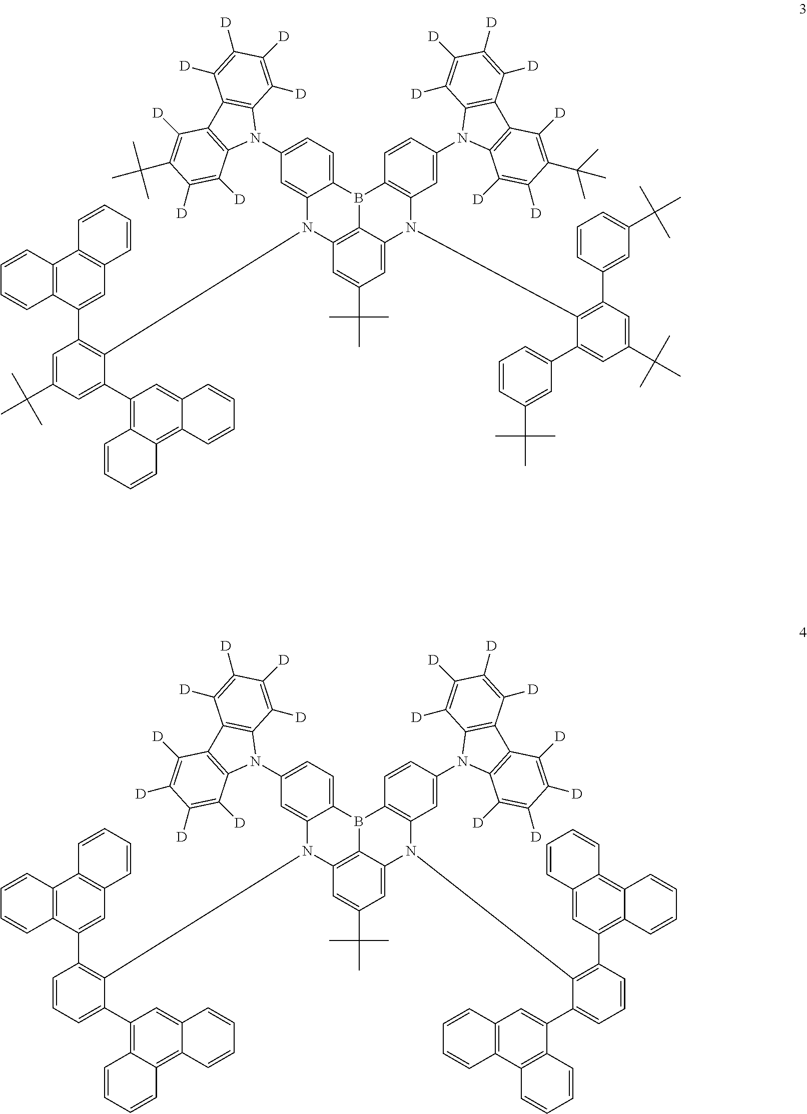

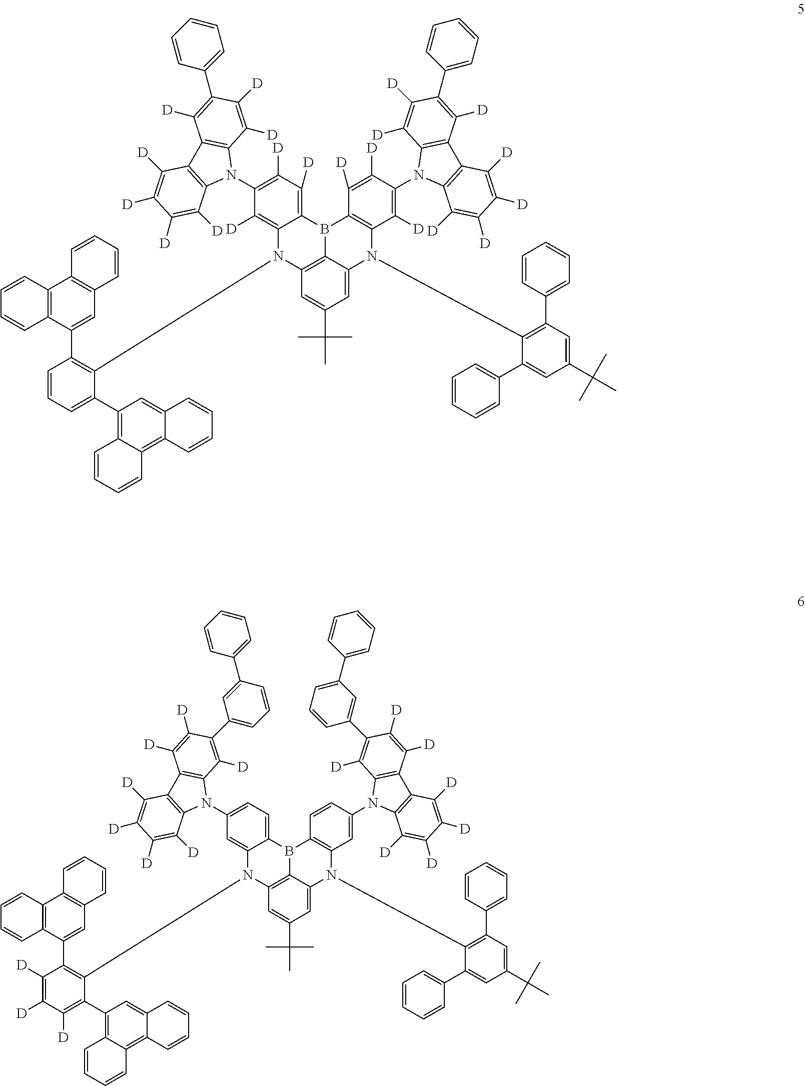

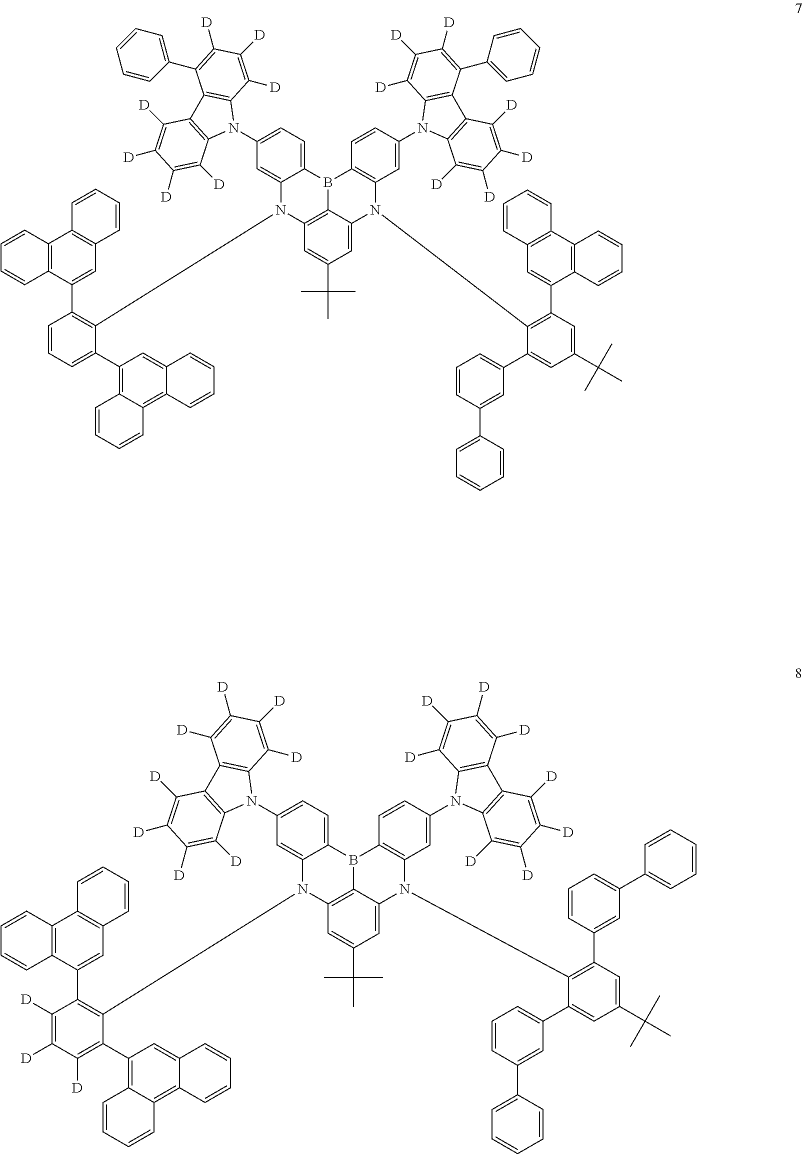

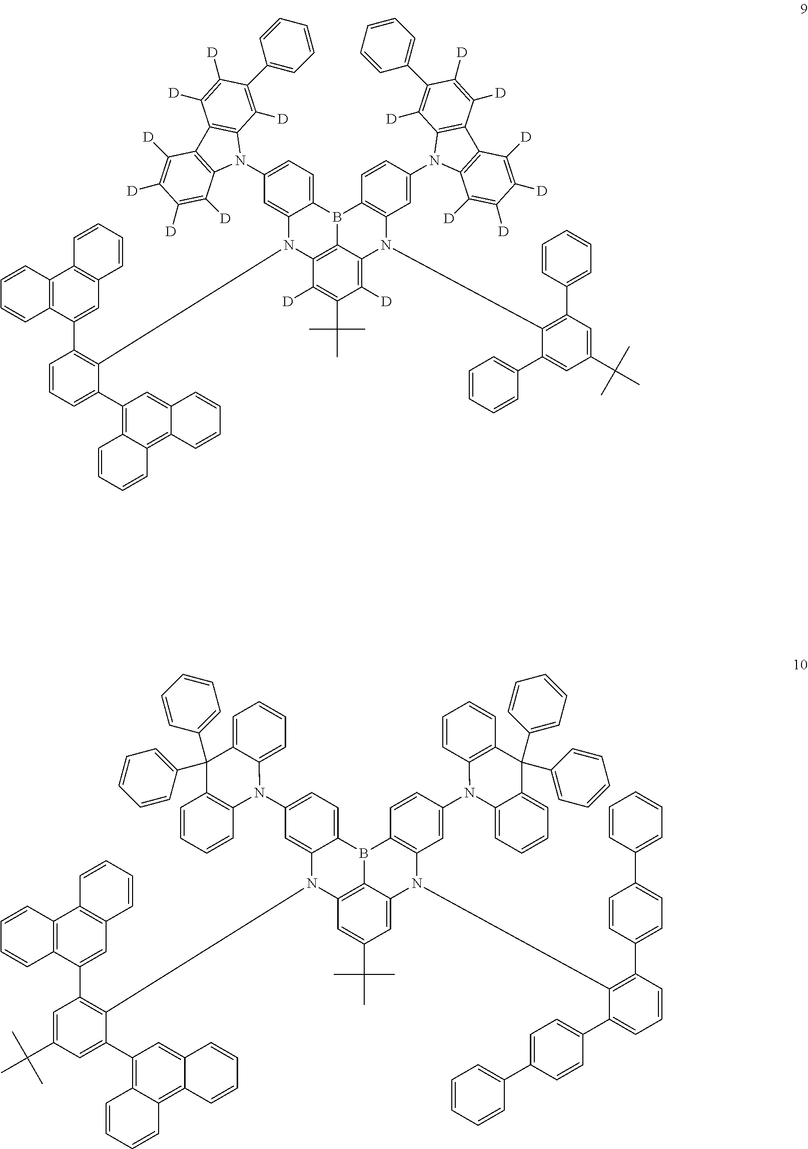

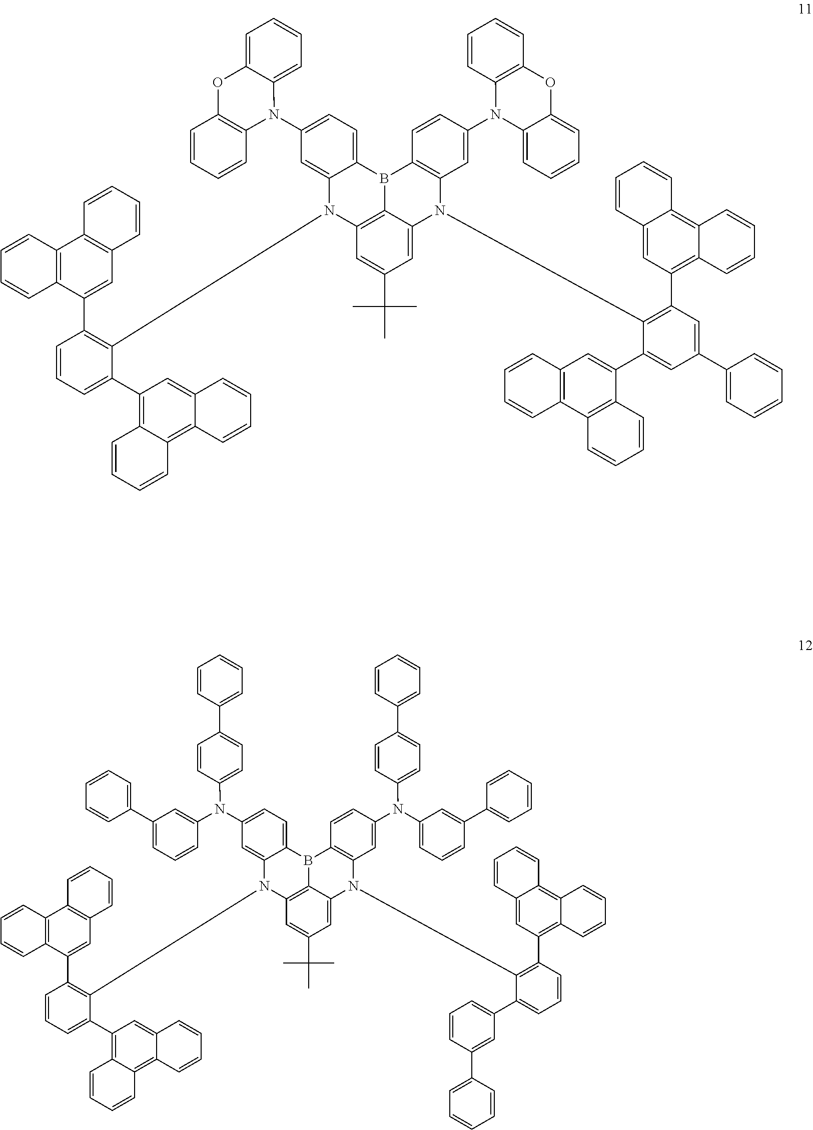 [SMILES: CC(C)(C)c1cc2c3c(c1)N(c1c(-c4cc5ccccc5c5ccccc45)cc(-c4ccccc4)cc1-c1cc4ccccc4c4ccccc14)c1cc(N4c5ccccc5Oc5ccccc54)ccc1B3c1ccc(N3c4ccccc4Oc4ccccc43)cc1N2c1c(-c2cc3ccccc3c3ccccc23)cccc1-c1cc2ccccc2c2ccccc12 ; CC(C)(C)c1cc2c3c(c1)N(c1c(-c4cc5ccccc5c5ccccc45)cccc1-c1cc4ccccc4c4ccccc14)c1cc(N(c4ccc(-c5ccccc5)cc4)c4cccc(-c5ccccc5)c4)ccc1B3c1ccc(N(c3ccc(-c4ccccc4)cc3)c3cccc(-c4ccccc4)c3)cc1N2c1c(-c2cccc(-c3ccccc3)c2)cccc1-c1cc2ccccc2c2ccccc12]

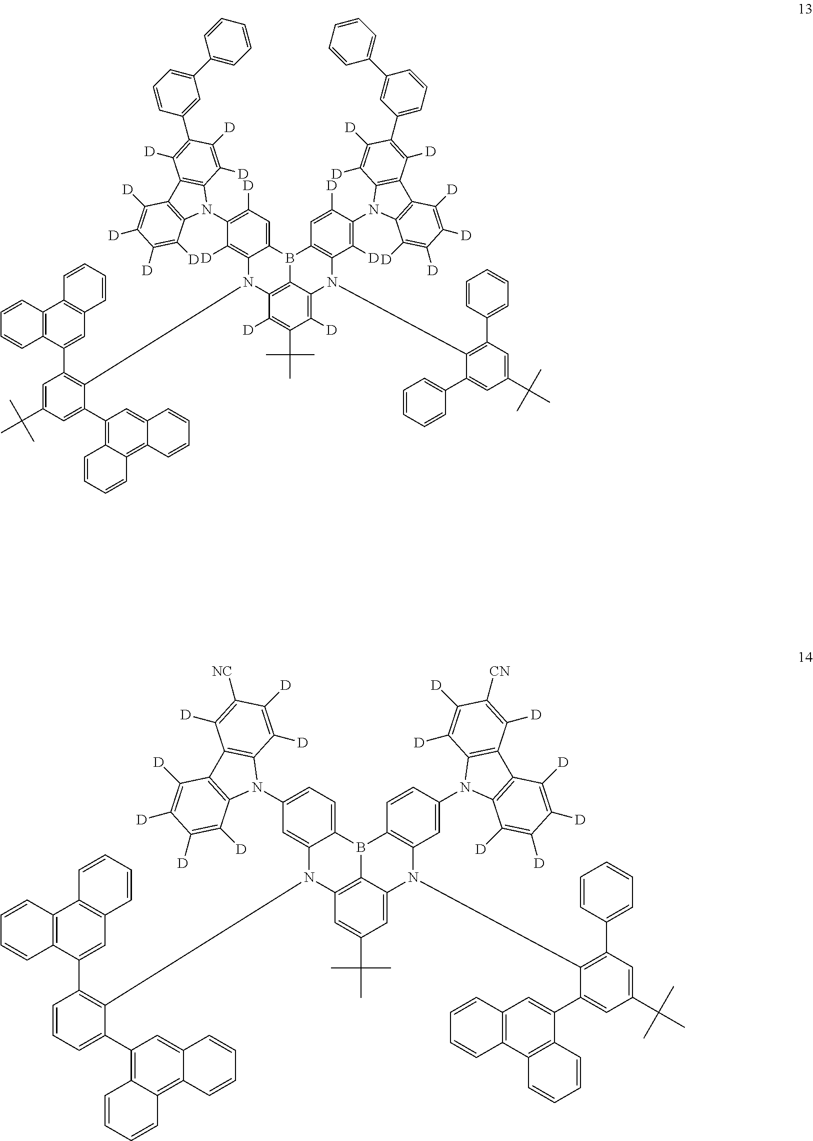

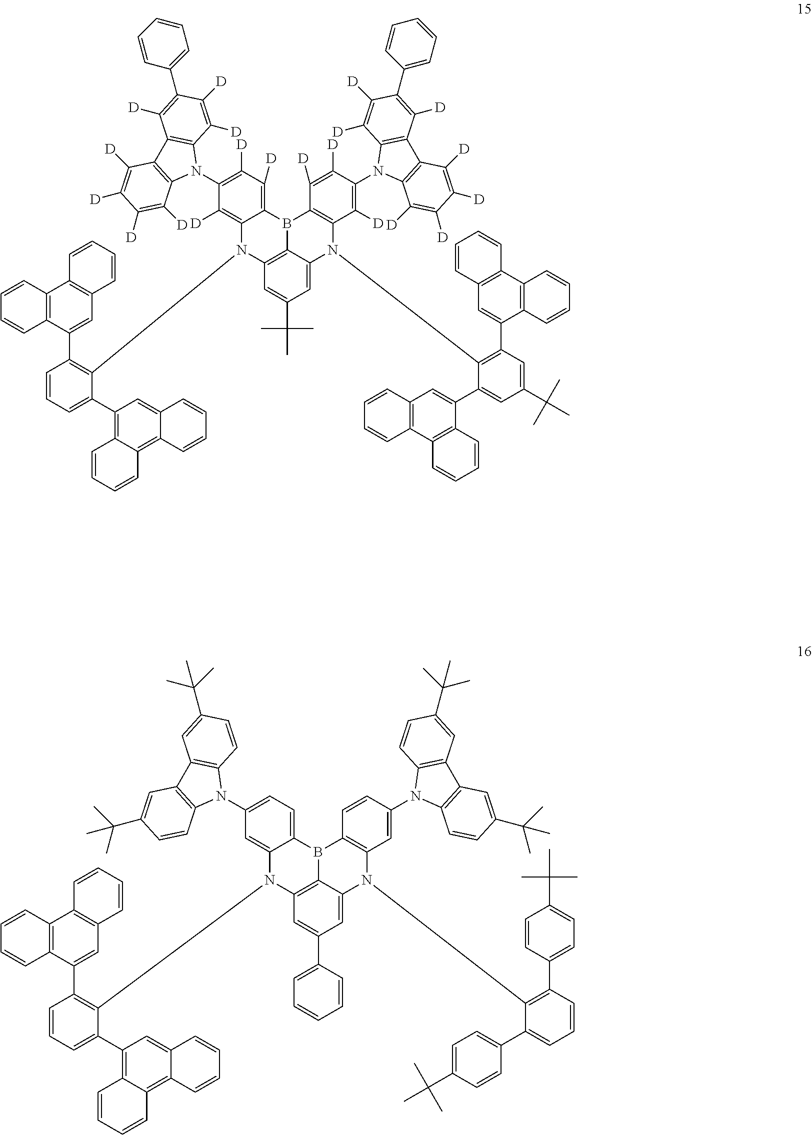

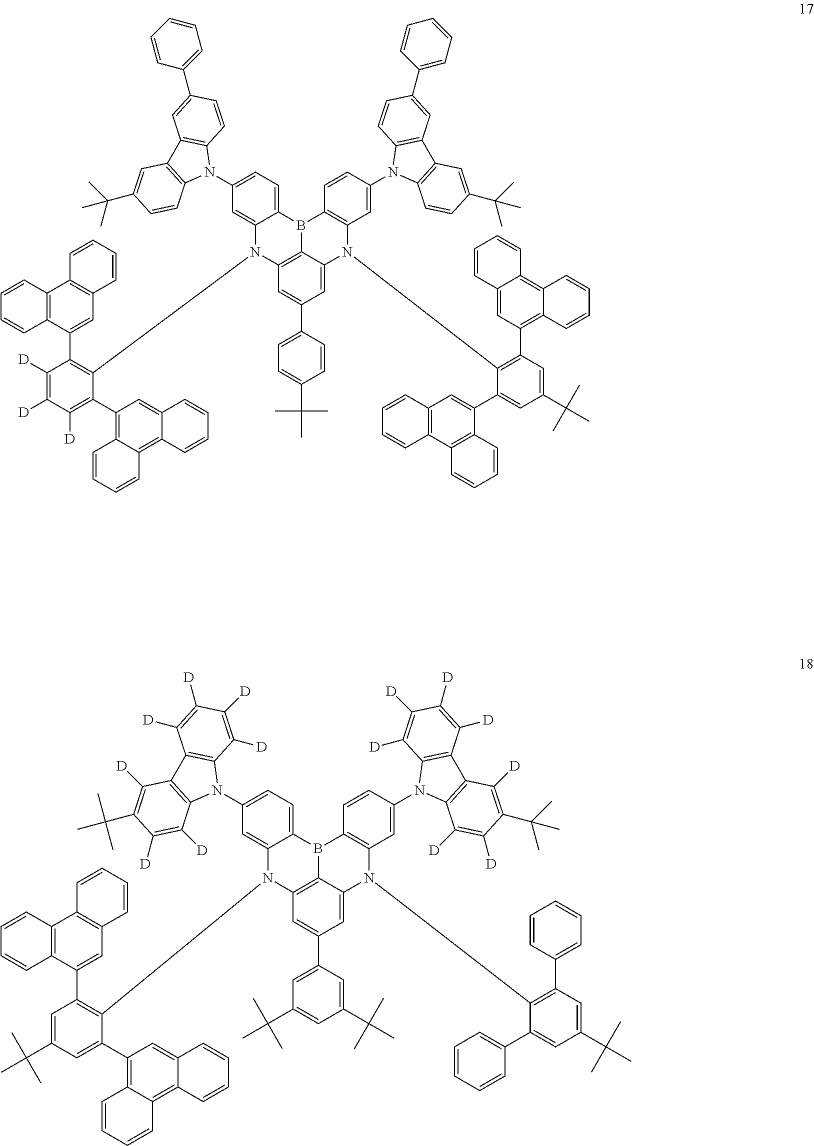

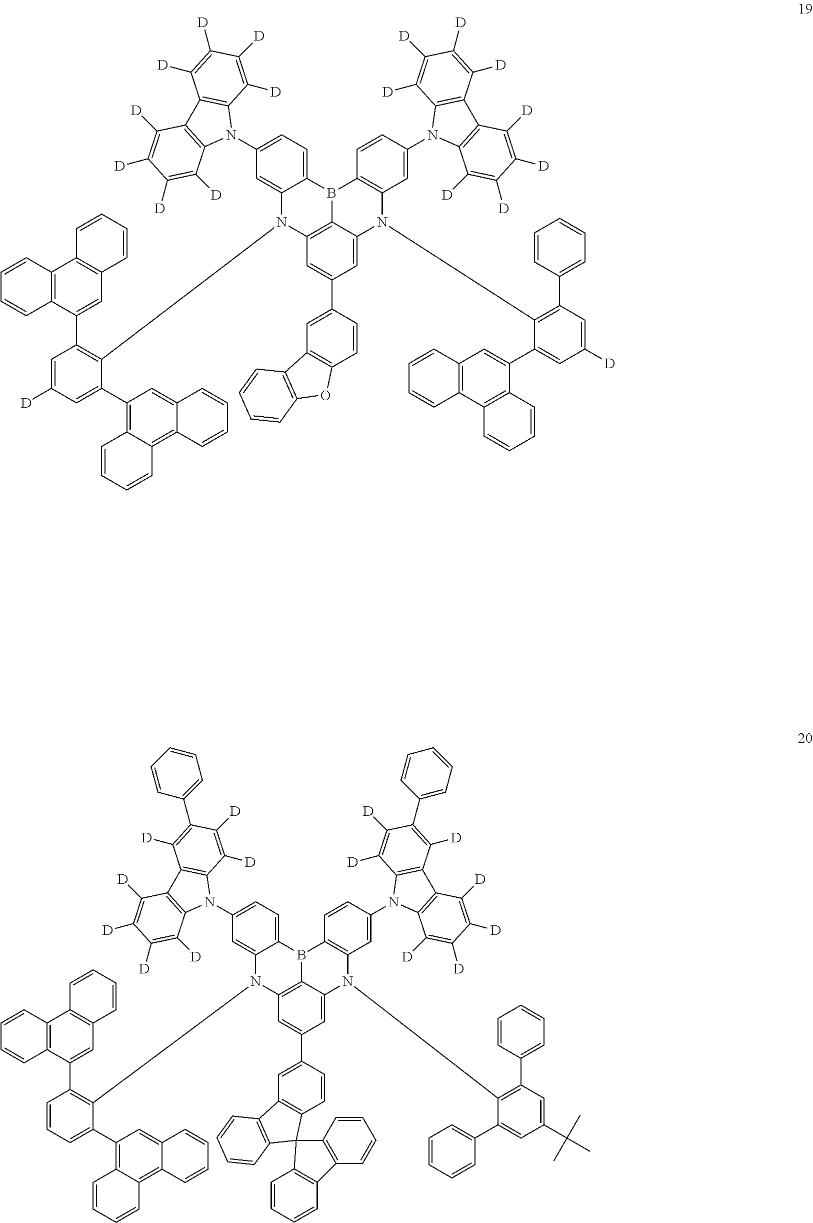

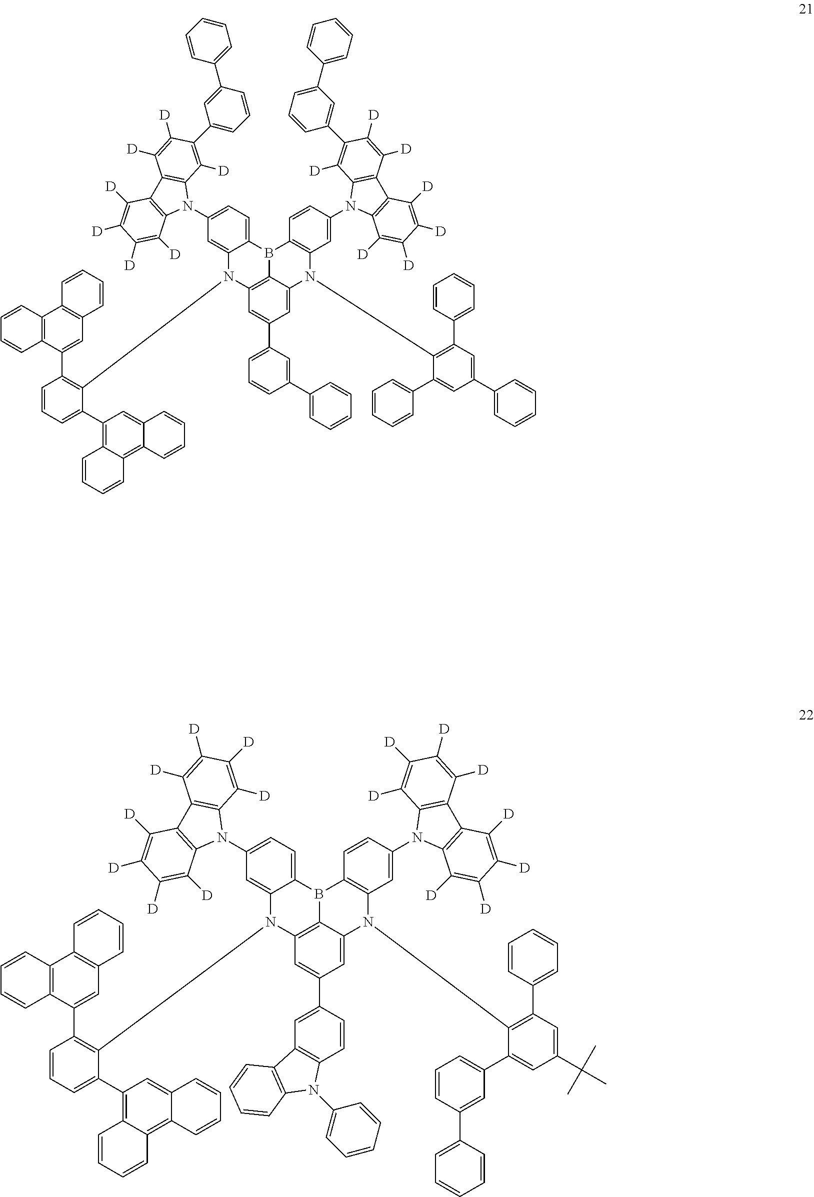

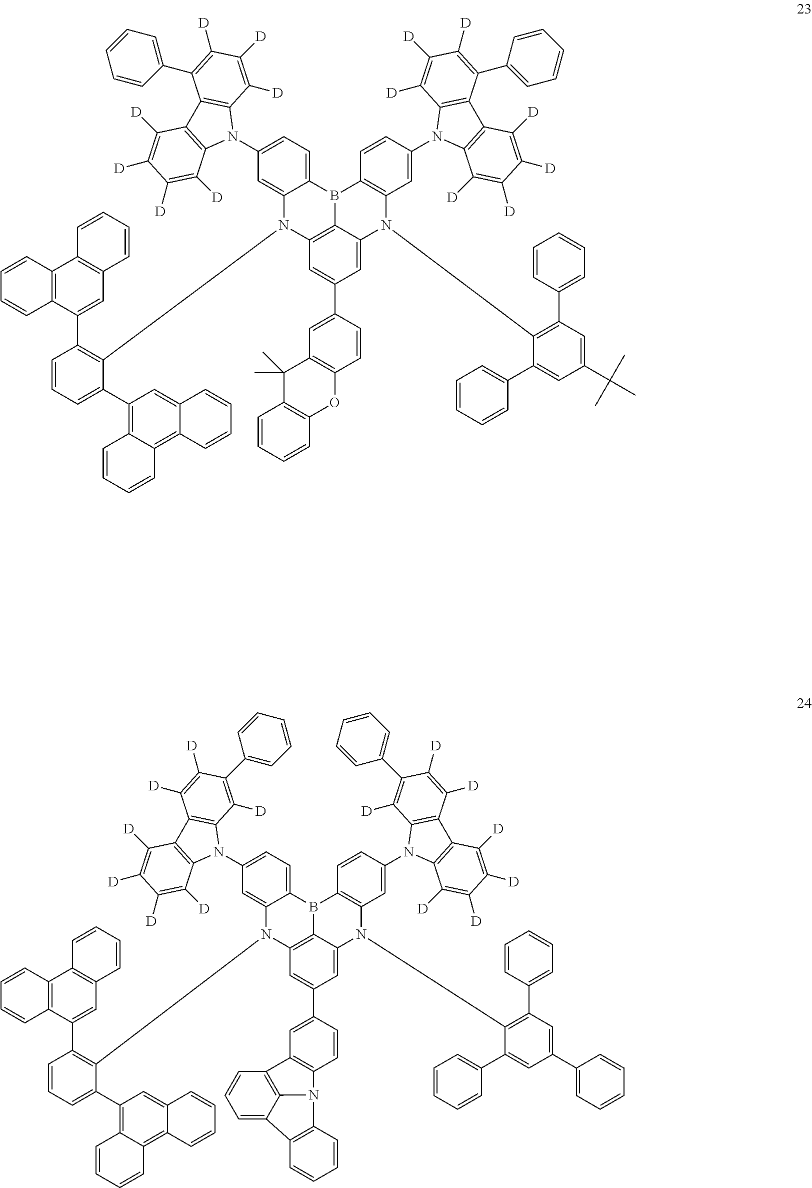

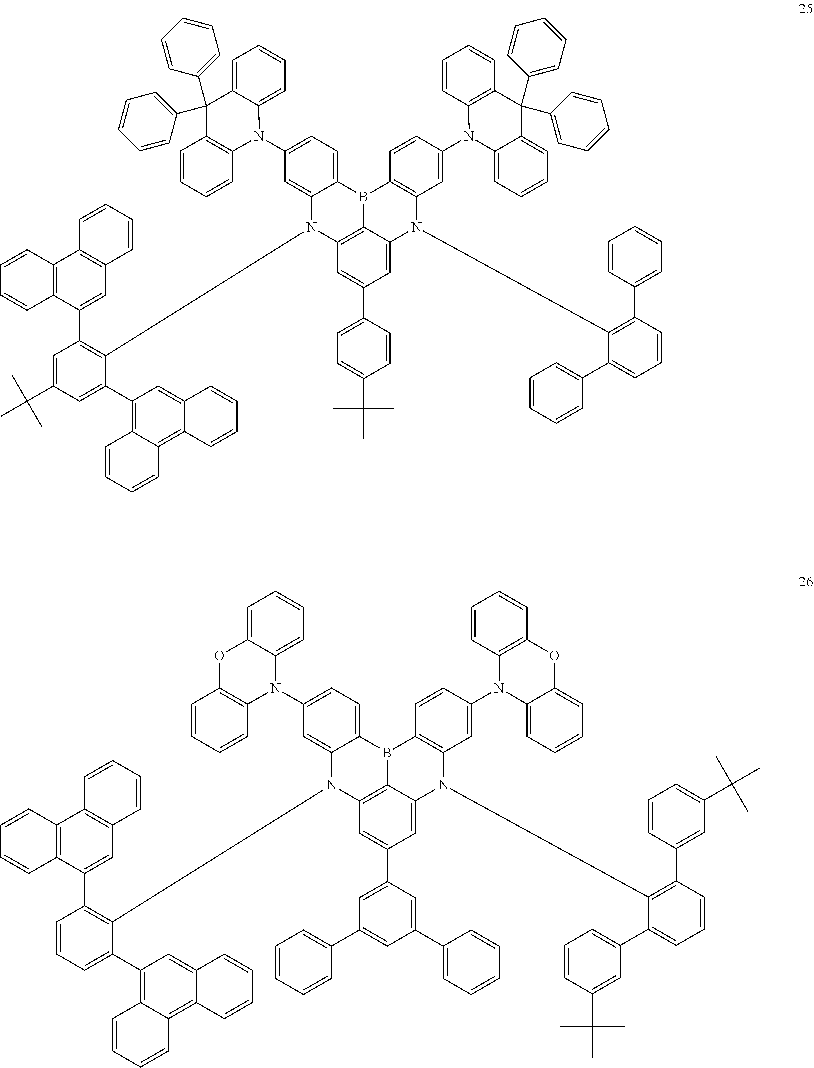 [SMILES: CC(C)(C)c1ccc(-c2cc3c4c(c2)N(c2c(-c5cc6ccccc6c6ccccc56)cc(C(C)(C)C)cc2-c2cc5ccccc5c5ccccc25)c2cc(N5c6ccccc6C(c6ccccc6)(c6ccccc6)c6ccccc65)ccc2B4c2ccc(N4c5ccccc5C(c5ccccc5)(c5ccccc5)c5ccccc54)cc2N3c2c(-c3ccccc3)cccc2-c2ccccc2)cc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5cc6ccccc6c6ccccc56)cccc4-c4cc5ccccc5c5ccccc45)c4cc(-c5cc(-c6ccccc6)cc(-c6ccccc6)c5)cc2c43)c1]

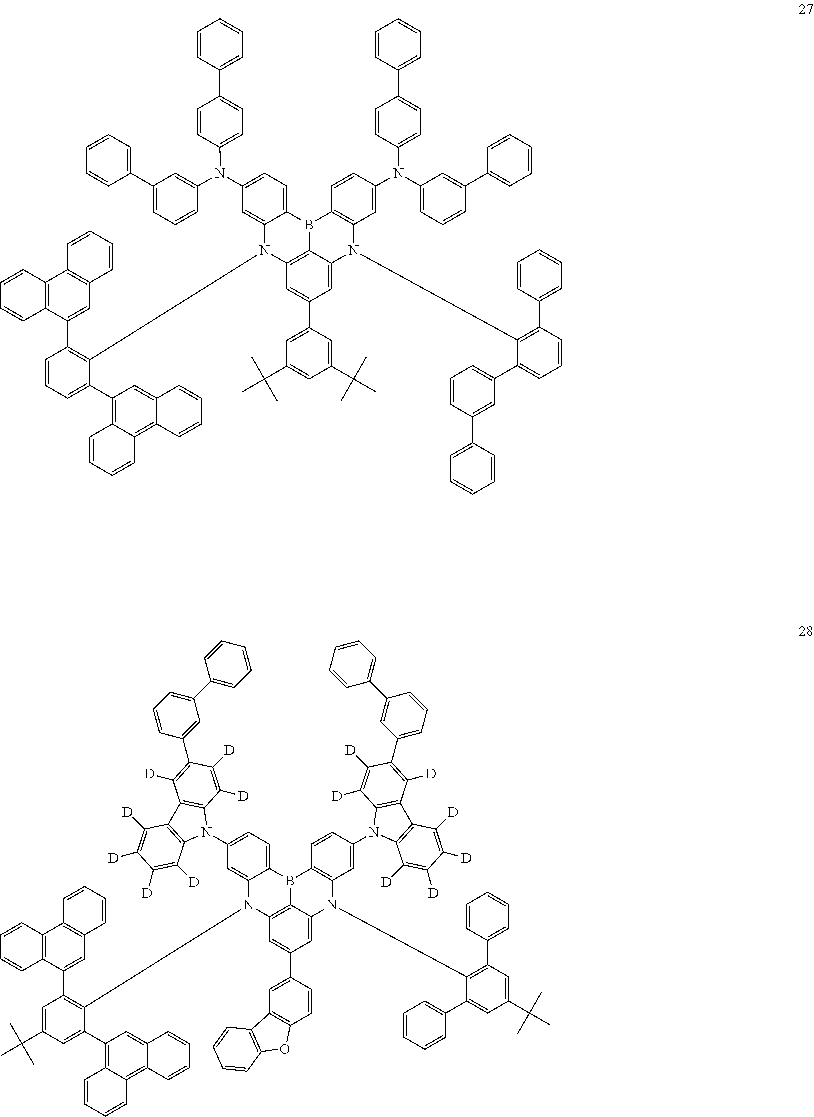

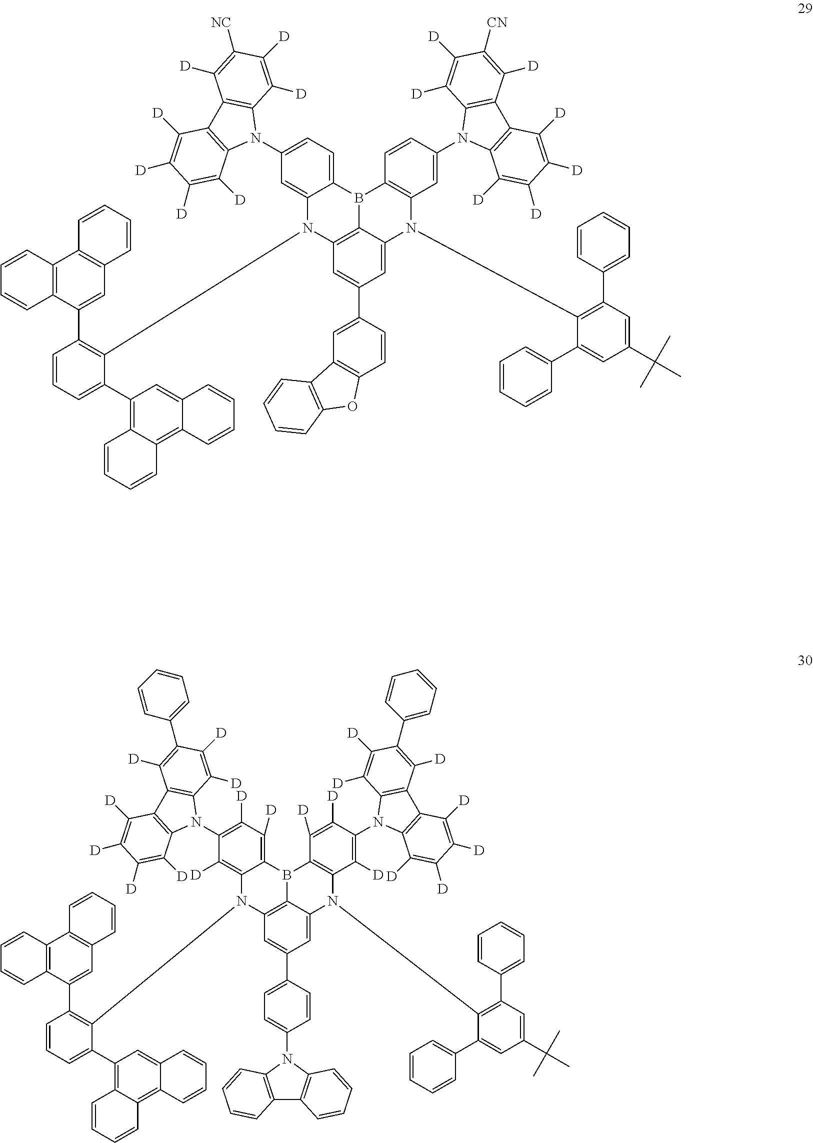

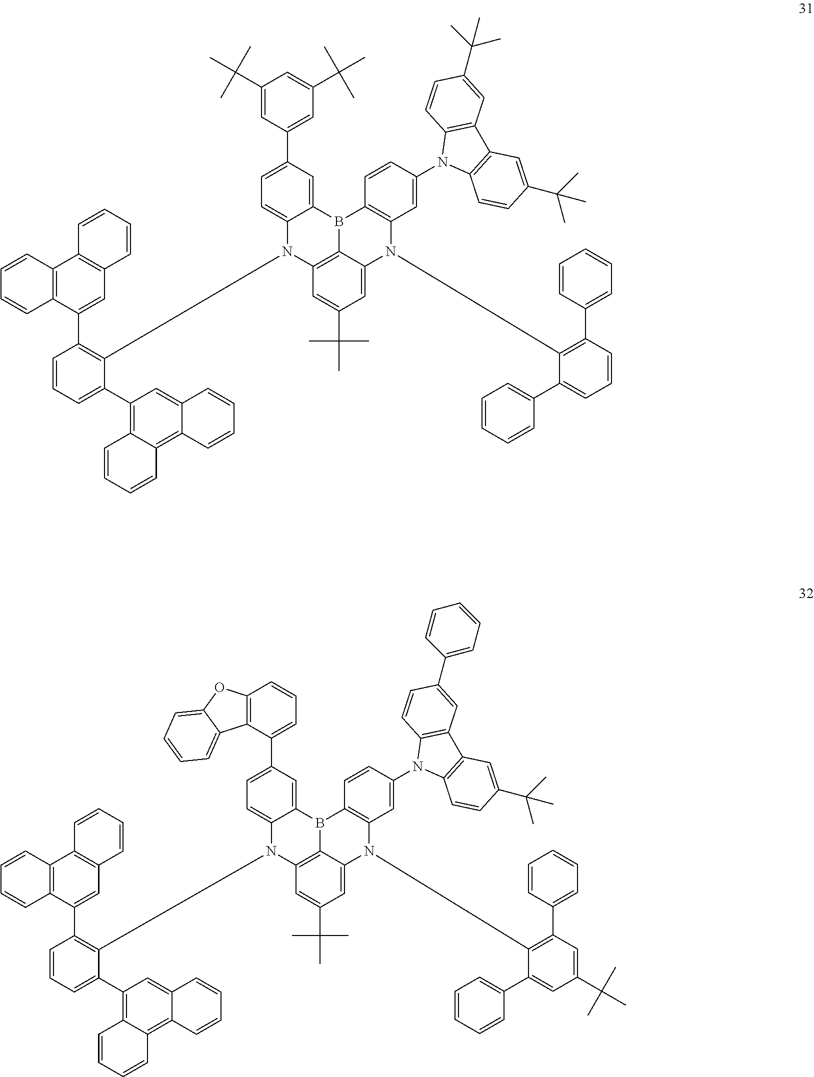 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3cc4ccccc4c4ccccc34)cccc2-c2cc3ccccc3c3ccccc23)cc(C(C)(C)C)c1 ; CC(C)(C)c1cc(-c2ccccc2)c(N2c3cc(-n4c5ccc(-c6ccccc6)cc5c5cc(C(C)(C)C)ccc54)ccc3B3c4cc(-c5cccc6oc7ccccc7c56)ccc4N(c4c(-c5cc6ccccc6c6ccccc56)cccc4-c4cc5ccccc5c5ccccc45)c4cc(C(C)(C)C)cc2c43)c(-c2ccccc2)c1]

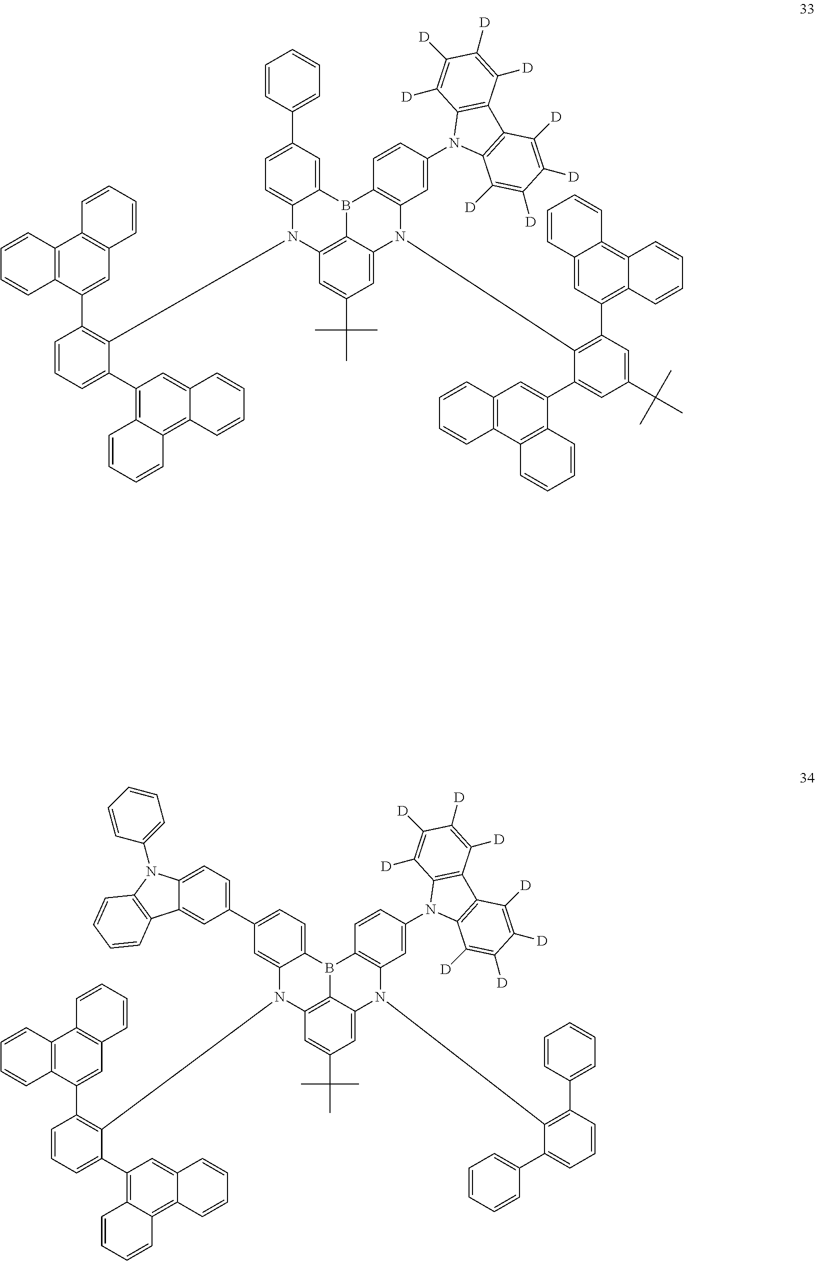 [SMILES: [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cc(C(C)(C)C)cc1-c1cc3ccccc3c3ccccc13)c1cc(C(C)(C)C)cc3c1B2c1cc(-c2ccccc2)ccc1N3c1c(-c2cc3ccccc3c3ccccc23)cccc1-c1cc2ccccc2c2ccccc12 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2cc3ccccc3c3ccccc23)cccc1-c1cc2ccccc2c2ccccc12]

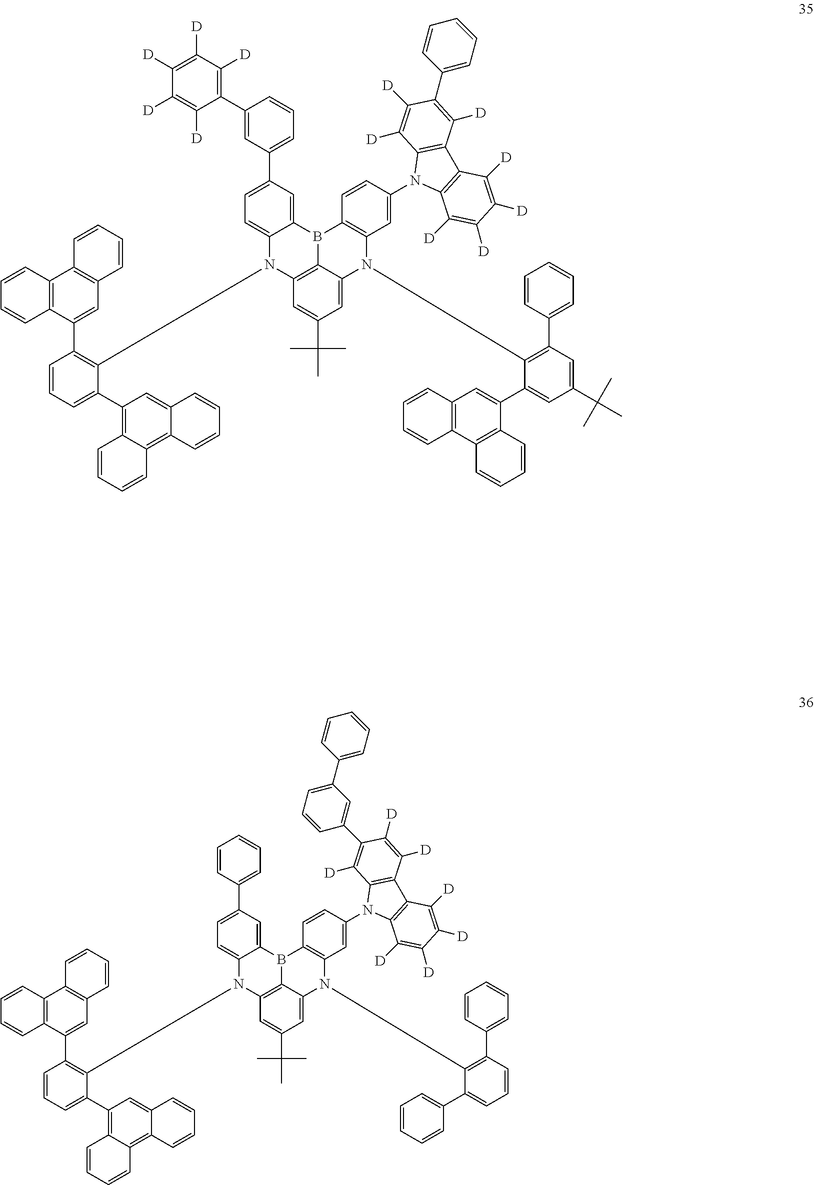 [SMILES: [2H]c1c([2H])c([2H])c(-c2cccc(-c3ccc4c(c3)B3c5ccc(-n6c7c([2H])c([2H])c([2H])c([2H])c7c7c([2H])c(-c8ccccc8)c([2H])c([2H])c76)cc5N(c5c(-c6ccccc6)cc(C(C)(C)C)cc5-c5cc6ccccc6c6ccccc56)c5cc(C(C)(C)C)cc(c53)N4c3c(-c4cc5ccccc5c5ccccc45)cccc3-c3cc4ccccc4c4ccccc34)c2)c([2H])c1[2H] ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2cc3ccccc3c3ccccc23)cccc1-c1cc2ccccc2c2ccccc12]

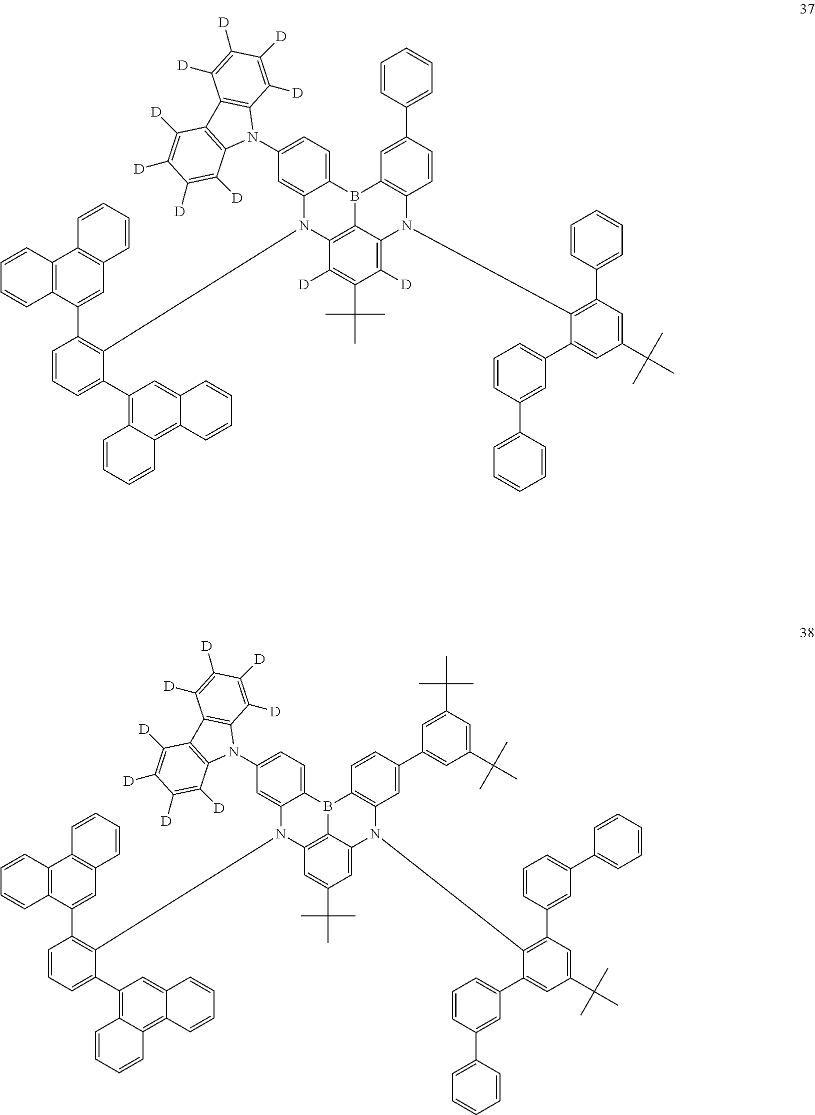 [SMILES: [2H]c1c2c3c(c([2H])c1C(C)(C)C)N(c1c(-c4cc5ccccc5c5ccccc45)cccc1-c1cc4ccccc4c4ccccc14)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1]

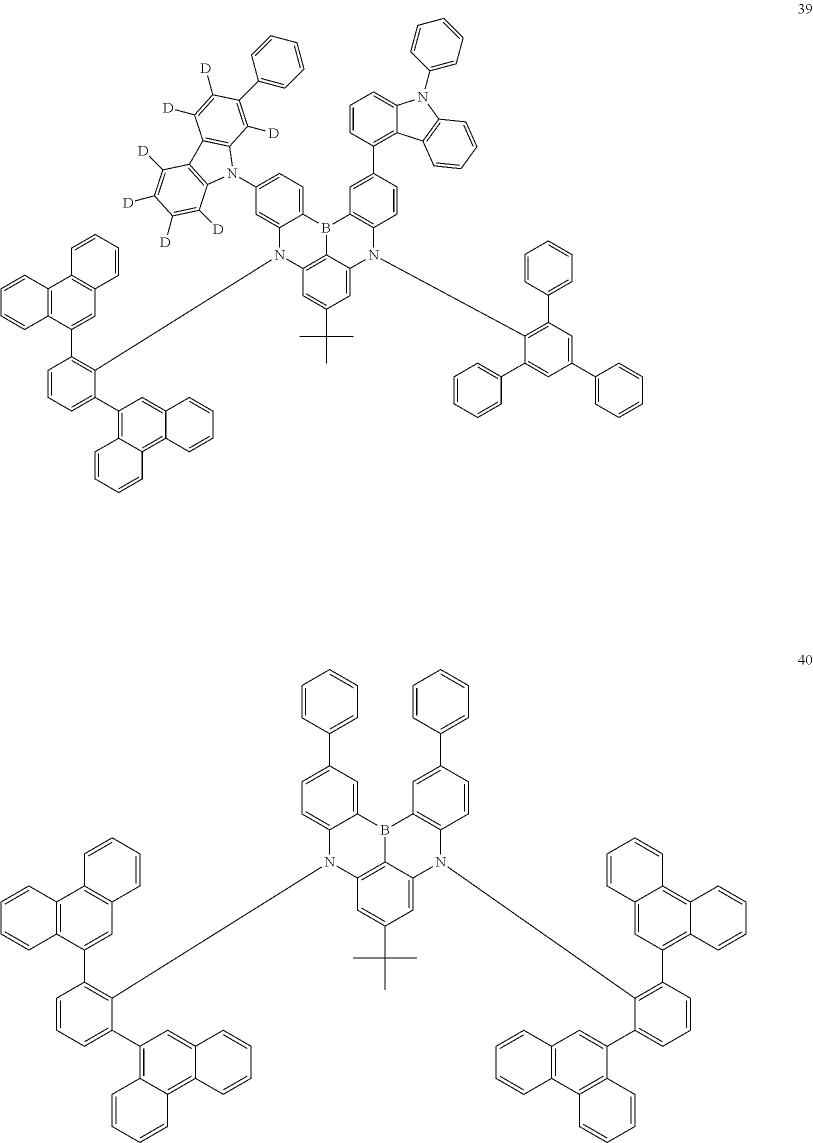 [SMILES: [2H]c1c([2H])c([2H])c2c(c1[2H])c1c([2H])c([2H])c(-c3ccccc3)c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1cc(-c2cccc4c2c2ccccc2n4-c2ccccc2)ccc1N3c1c(-c2ccccc2)cc(-c2ccccc2)cc1-c1ccccc1 ; CC(C)(C)c1cc2c3c(c1)N(c1c(-c4cc5ccccc5c5ccccc45)cccc1-c1cc4ccccc4c4ccccc14)c1ccc(-c4ccccc4)cc1B3c1cc(-c3ccccc3)ccc1N2c1c(-c2cc3ccccc3c3ccccc23)cccc1-c1cc2ccccc2c2ccccc12]

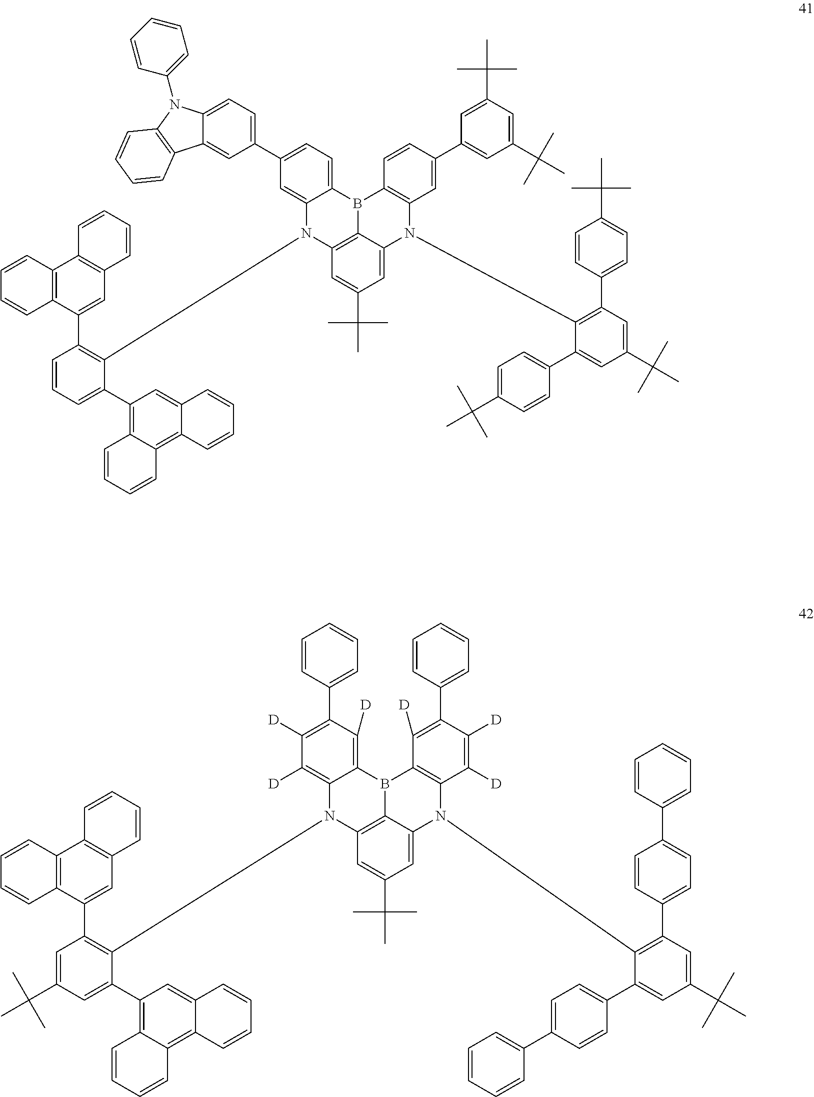 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-c5ccc6c(c5)c5ccccc5n6-c5ccccc5)cc4N(c4c(-c5cc6ccccc6c6ccccc56)cccc4-c4cc5ccccc5c5ccccc45)c4cc(C(C)(C)C)cc2c43)cc1 ; [2H]c1c([2H])c2c(c([2H])c1-c1ccccc1)B1c3c(cc(C(C)(C)C)cc3N(c3c(-c4cc5ccccc5c5ccccc45)cc(C(C)(C)C)cc3-c3cc4ccccc4c4ccccc34)c3c([2H])c([2H])c(-c4ccccc4)c([2H])c31)N2c1c(-c2ccc(-c3ccccc3)cc2)cc(C(C)(C)C)cc1-c1ccc(-c2ccccc2)cc1]

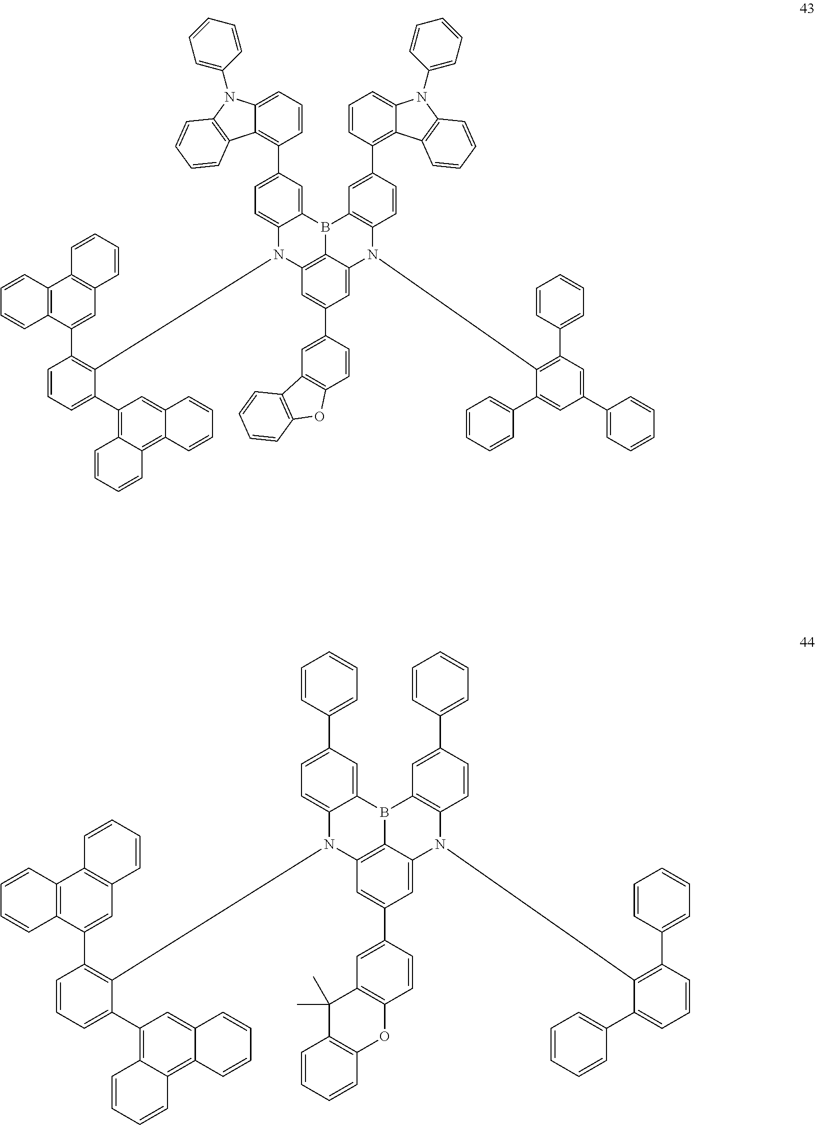 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6cc7ccccc7c7ccccc67)cccc5-c5cc6ccccc6c6ccccc56)c5cc(-c6ccc7oc8ccccc8c7c6)cc3c54)c(-c3ccccc3)c2)cc1 ; CC1(C)c2ccccc2Oc2ccc(-c3cc4c5c(c3)N(c3c(-c6cc7ccccc7c7ccccc67)cccc3-c3cc6ccccc6c6ccccc36)c3ccc(-c6ccccc6)cc3B5c3cc(-c5ccccc5)ccc3N4c3c(-c4ccccc4)cccc3-c3ccccc3)cc21]

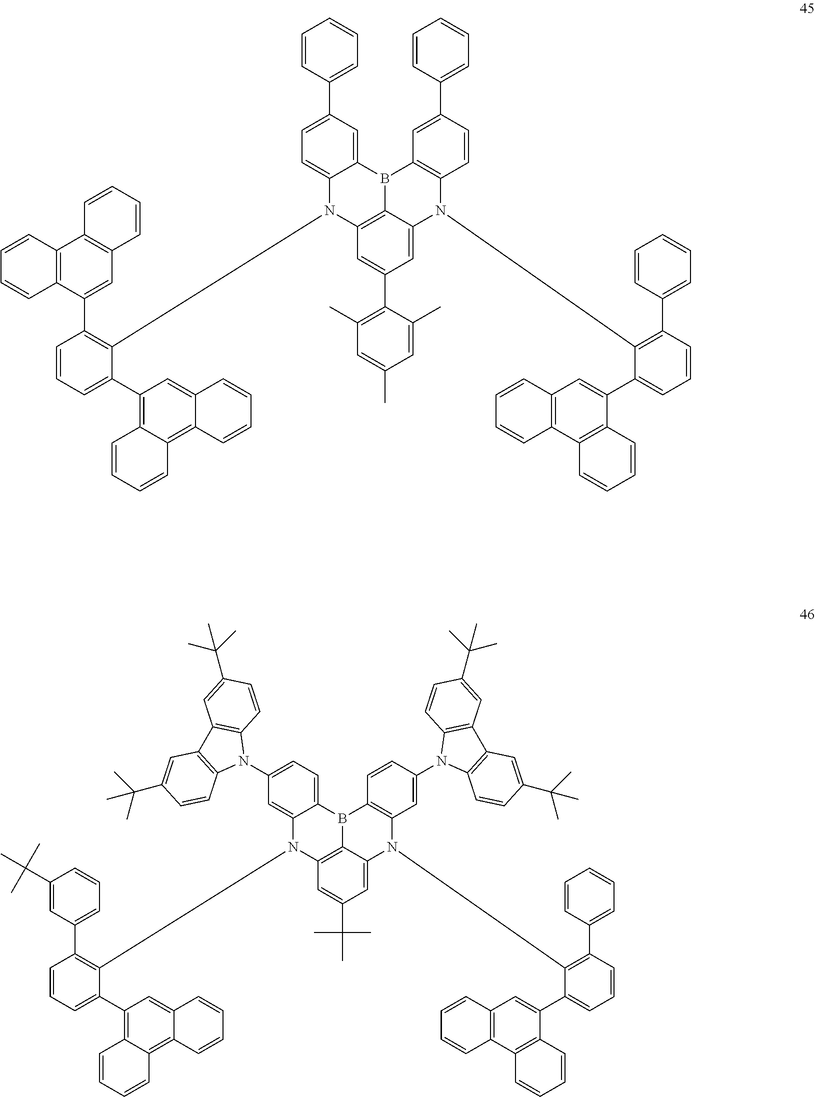 [SMILES: Cc1cc(C)c(-c2cc3c4c(c2)N(c2c(-c5cc6ccccc6c6ccccc56)cccc2-c2cc5ccccc5c5ccccc25)c2ccc(-c5ccccc5)cc2B4c2cc(-c4ccccc4)ccc2N3c2c(-c3ccccc3)cccc2-c2cc3ccccc3c3ccccc23)c(C)c1 ; CC(C)(C)c1cccc(-c2cccc(-c3cc4ccccc4c4ccccc34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cccc4-c4cc5ccccc5c5ccccc45)c4cc(C(C)(C)C)cc2c43)c1]

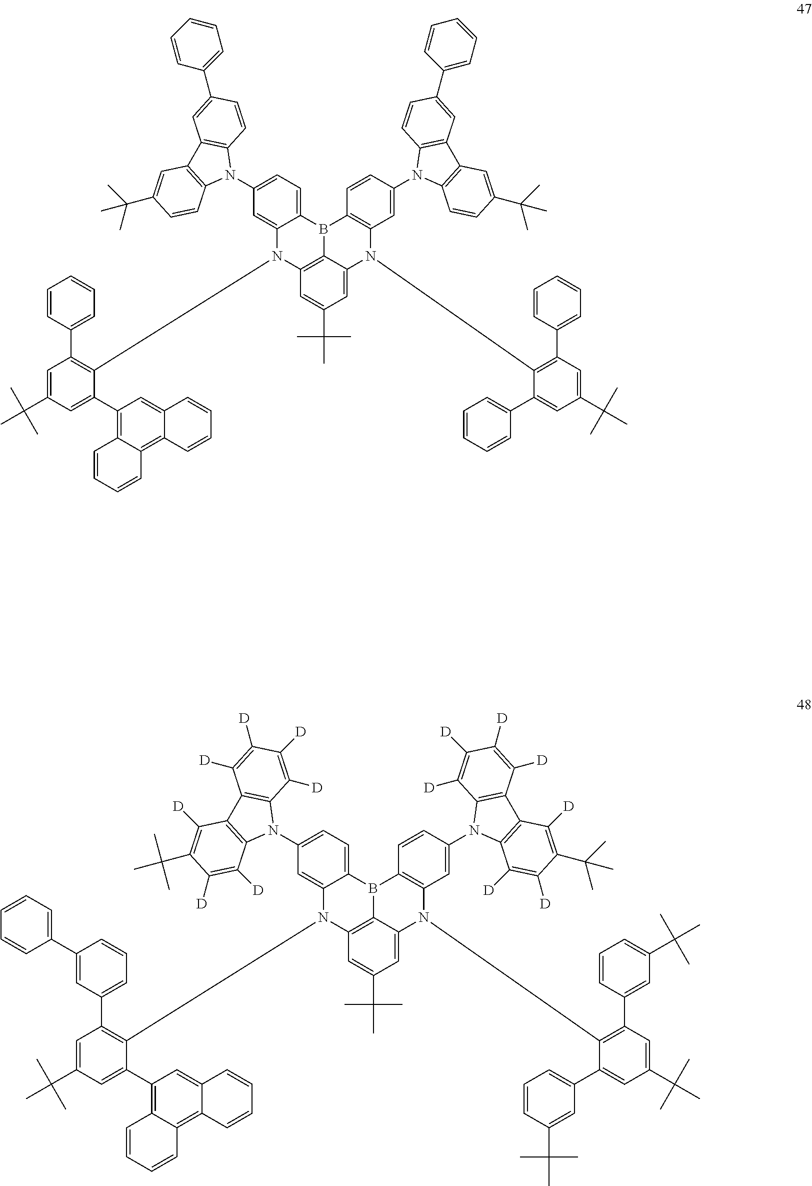

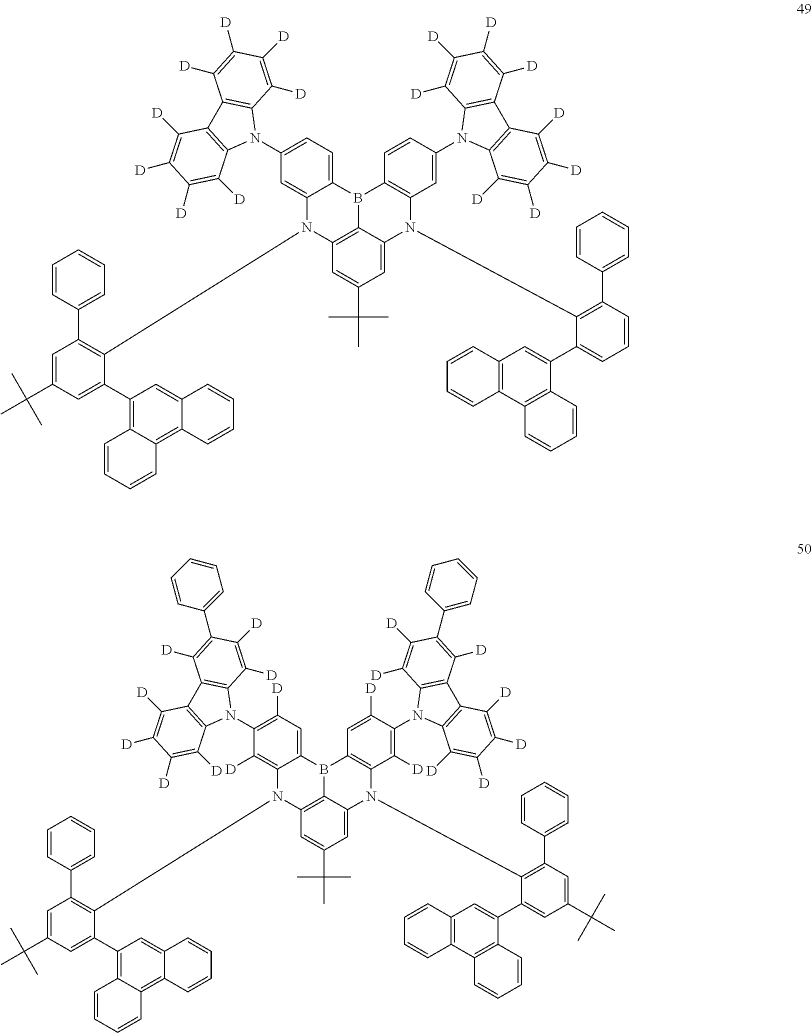

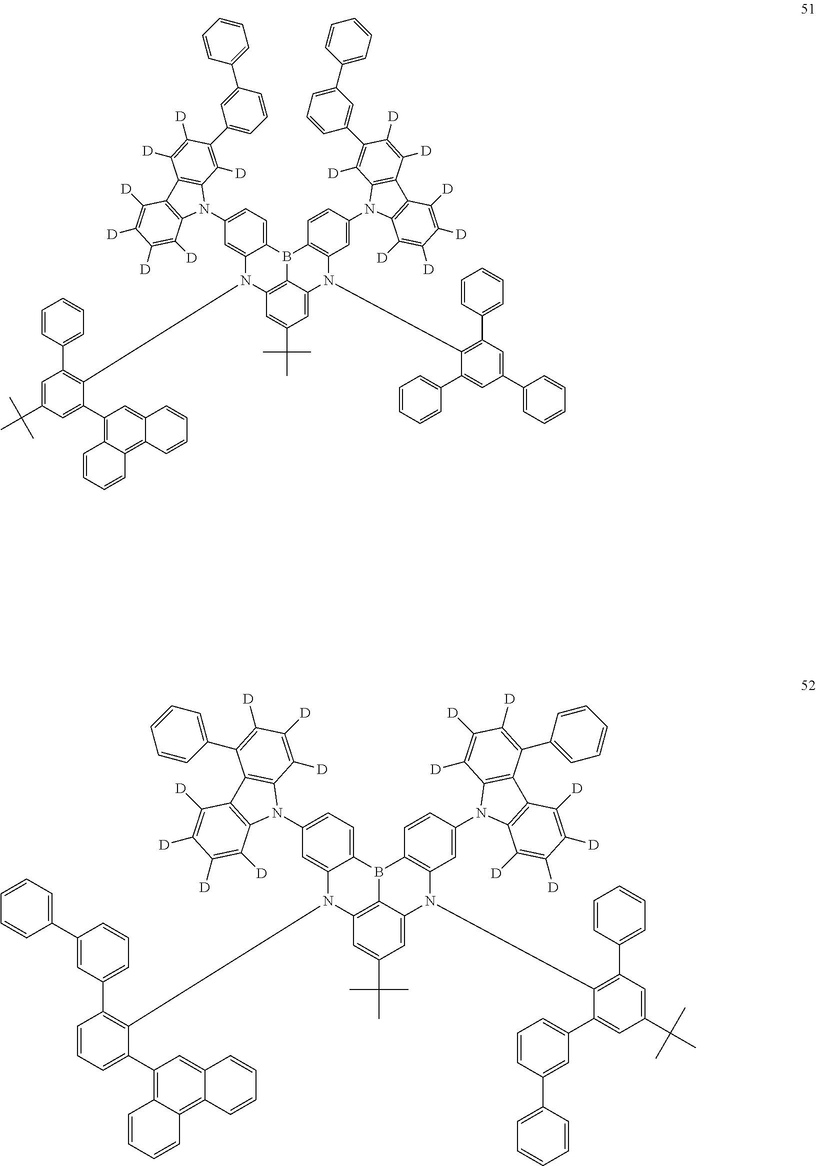

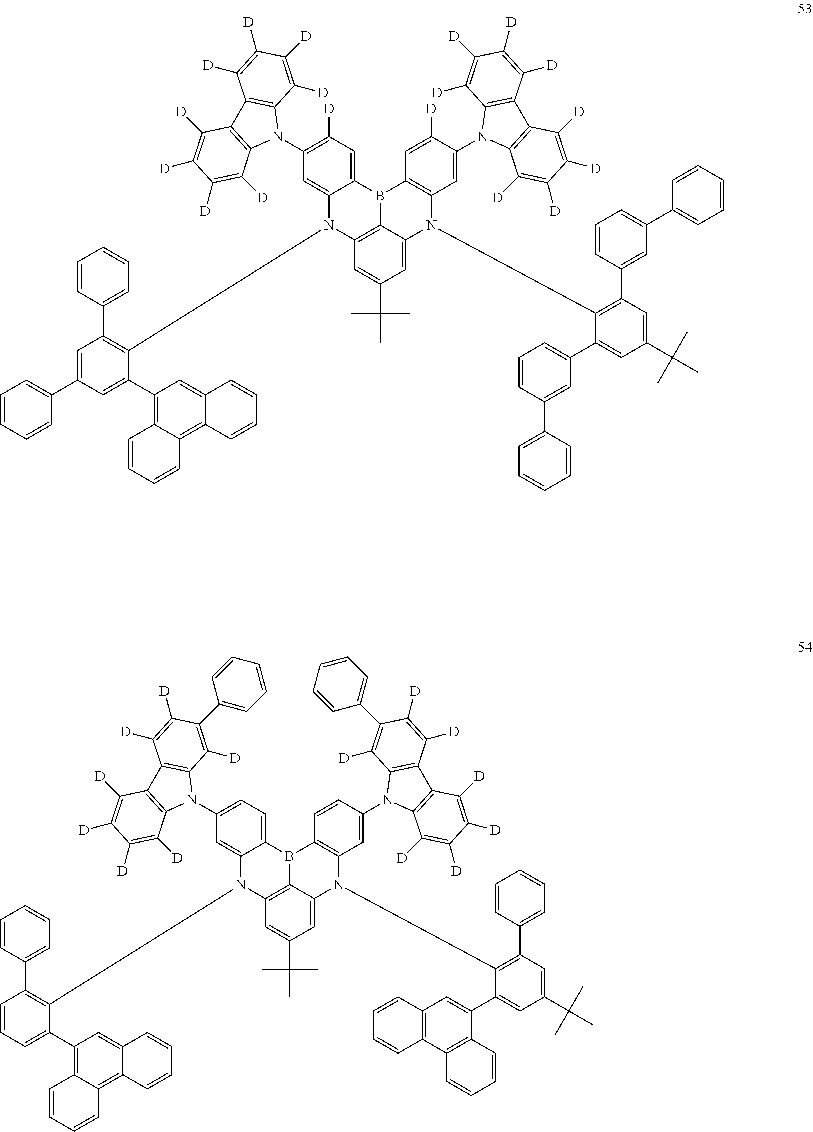

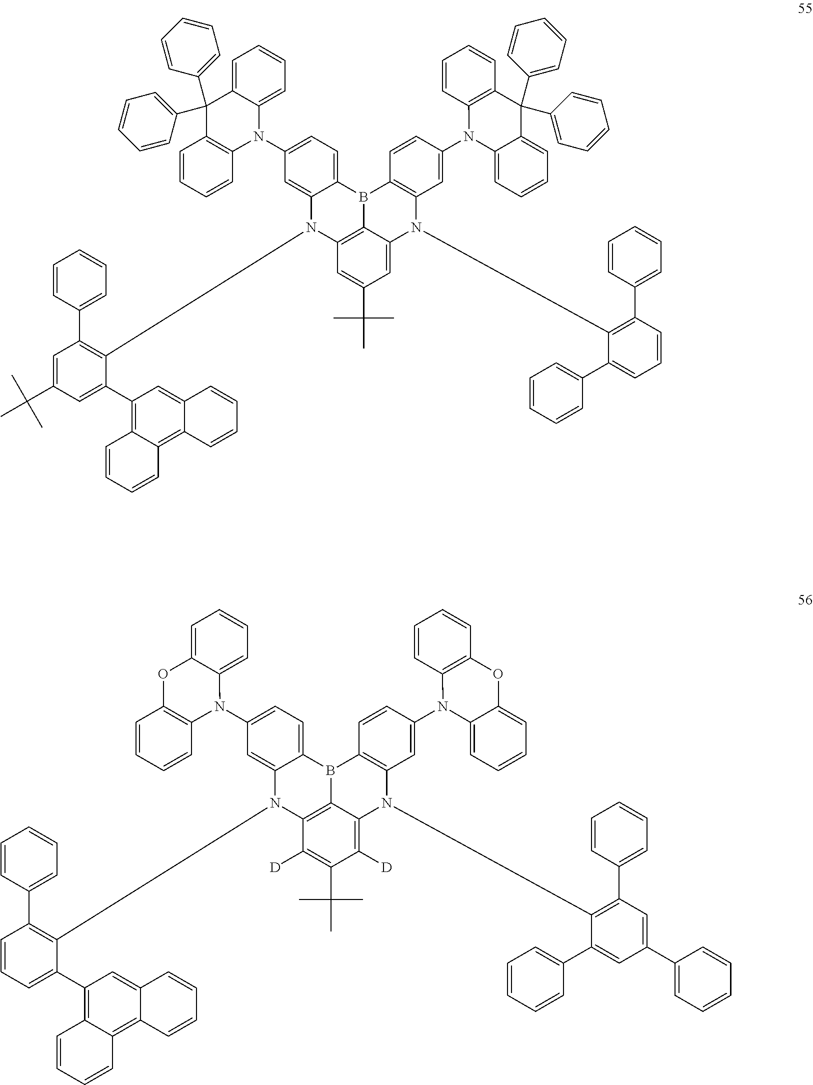 [SMILES: CC(C)(C)c1cc(-c2ccccc2)c(N2c3cc(N4c5ccccc5C(c5ccccc5)(c5ccccc5)c5ccccc54)ccc3B3c4ccc(N5c6ccccc6C(c6ccccc6)(c6ccccc6)c6ccccc65)cc4N(c4c(-c5ccccc5)cccc4-c4ccccc4)c4cc(C(C)(C)C)cc2c43)c(-c2cc3ccccc3c3ccccc23)c1 ; [2H]c1c2c3c(c([2H])c1C(C)(C)C)N(c1c(-c4ccccc4)cccc1-c1cc4ccccc4c4ccccc14)c1cc(N4c5ccccc5Oc5ccccc54)ccc1B3c1ccc(N3c4ccccc4Oc4ccccc43)cc1N2c1c(-c2ccccc2)cc(-c2ccccc2)cc1-c1ccccc1]

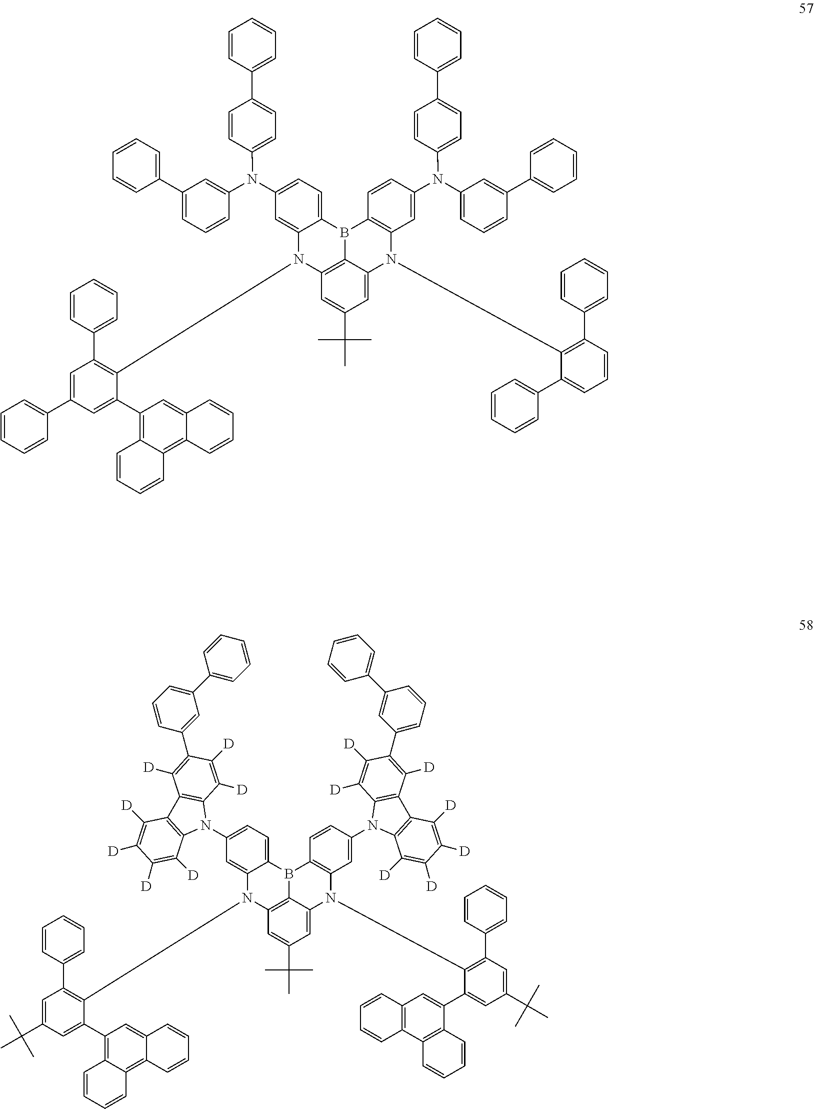

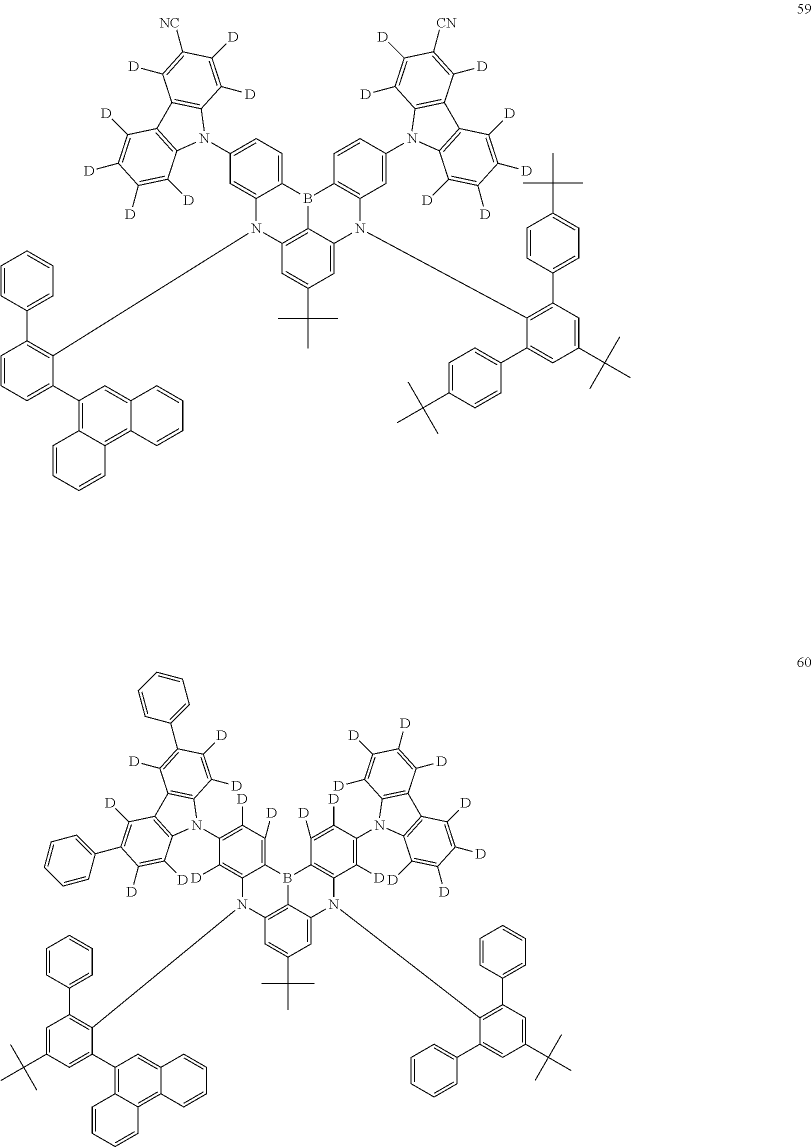

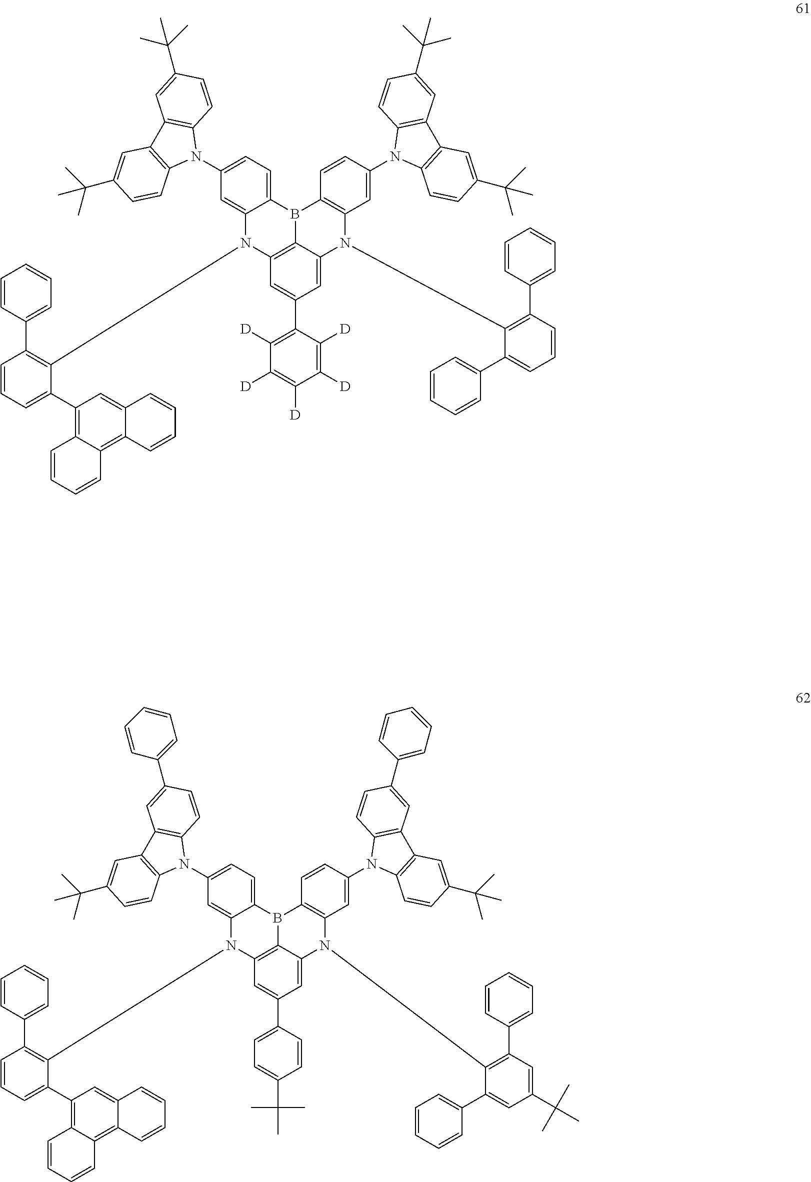 [SMILES: [2H]c1c([2H])c([2H])c(-c2cc3c4c(c2)N(c2c(-c5ccccc5)cccc2-c2cc5ccccc5c5ccccc25)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)c([2H])c1[2H] ; CC(C)(C)c1ccc(-c2cc3c4c(c2)N(c2c(-c5ccccc5)cccc2-c2cc5ccccc5c5ccccc25)c2cc(-n5c6ccc(-c7ccccc7)cc6c6cc(C(C)(C)C)ccc65)ccc2B4c2ccc(-n4c5ccc(-c6ccccc6)cc5c5cc(C(C)(C)C)ccc54)cc2N3c2c(-c3ccccc3)cc(C(C)(C)C)cc2-c2ccccc2)cc1]

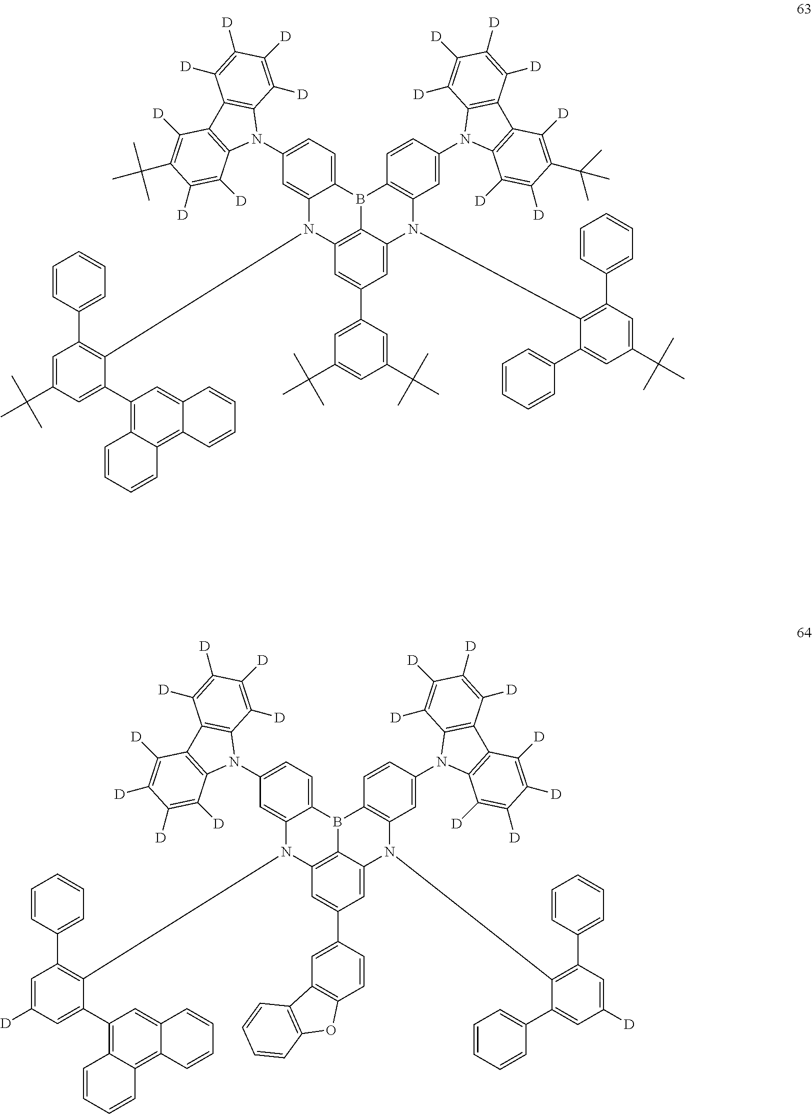

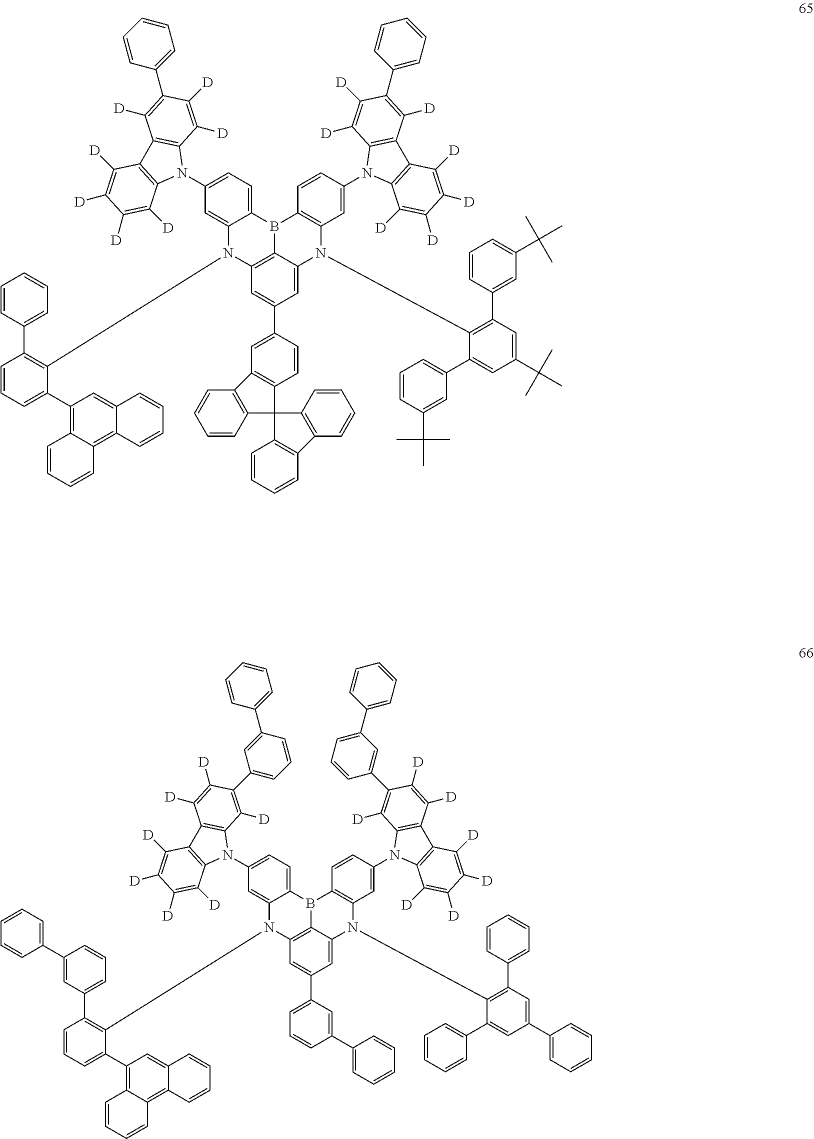

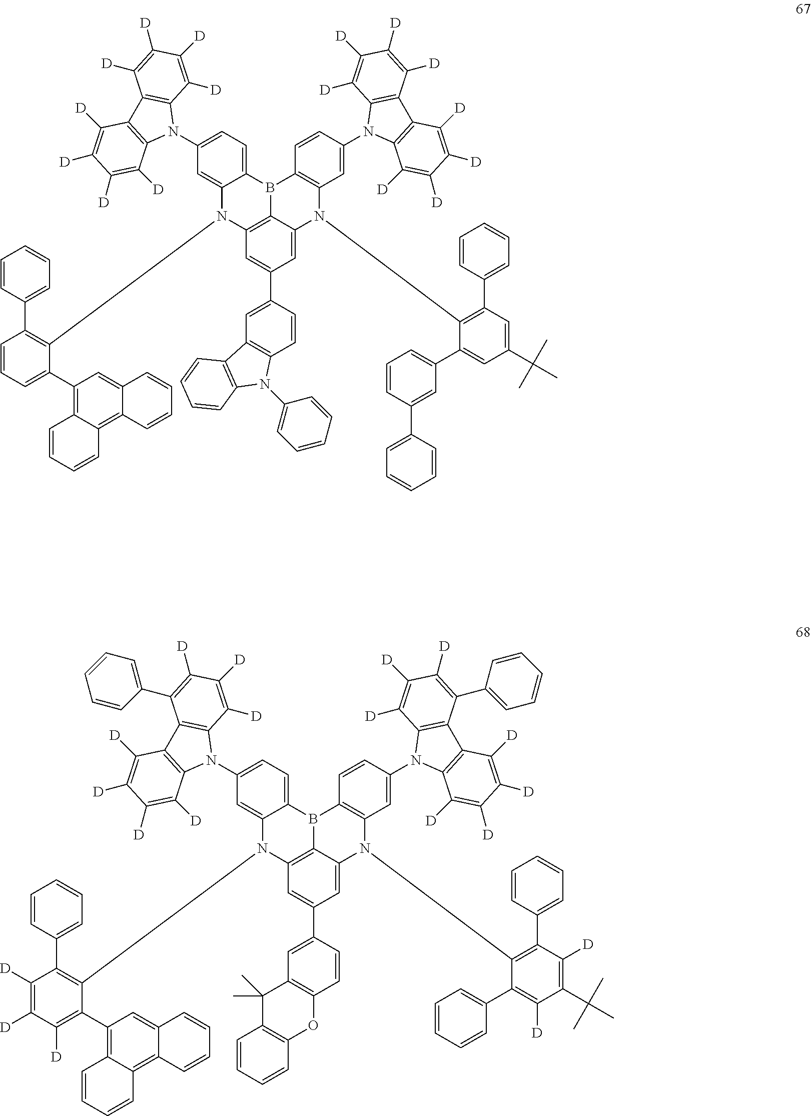

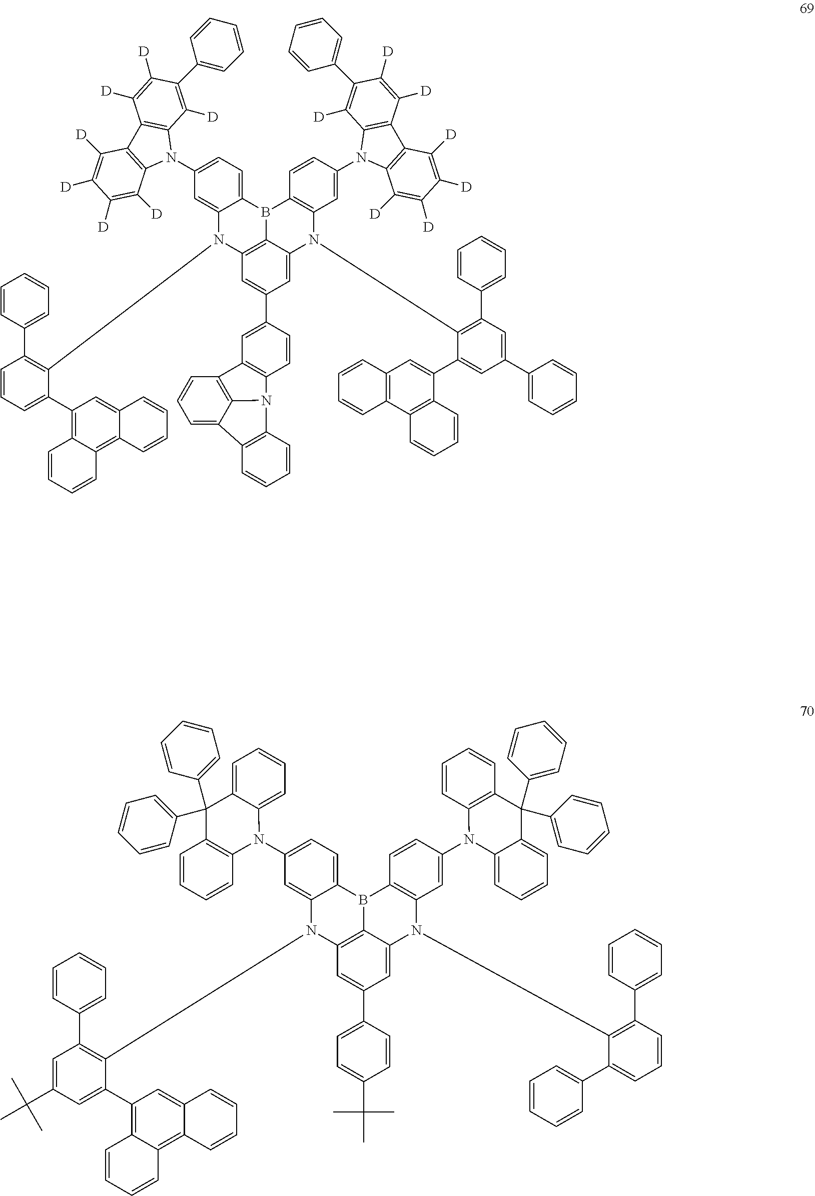

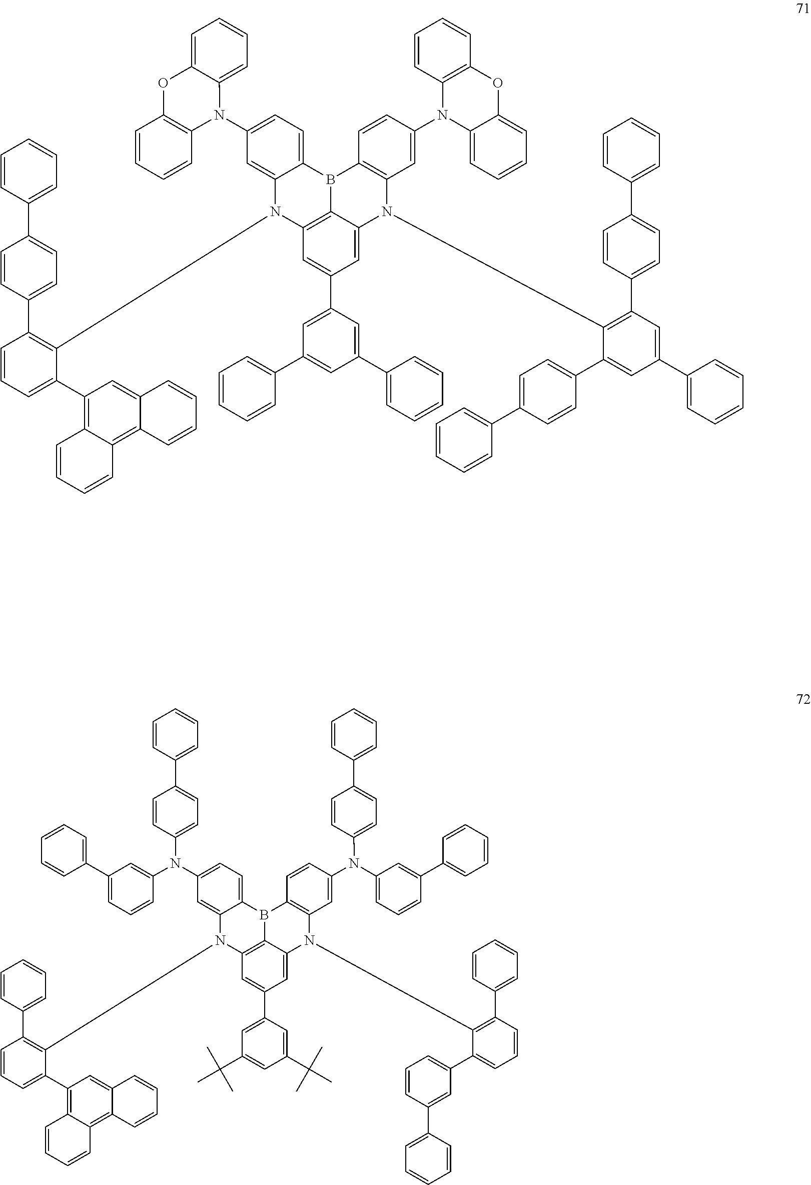 [SMILES: c1ccc(-c2ccc(-c3cc(-c4ccccc4)cc(-c4ccc(-c5ccccc5)cc4)c3N3c4cc(N5c6ccccc6Oc6ccccc65)ccc4B4c5ccc(N6c7ccccc7Oc7ccccc76)cc5N(c5c(-c6ccc(-c7ccccc7)cc6)cccc5-c5cc6ccccc6c6ccccc56)c5cc(-c6cc(-c7ccccc7)cc(-c7ccccc7)c6)cc3c54)cc2)cc1 ; CC(C)(C)c1cc(-c2cc3c4c(c2)N(c2c(-c5ccccc5)cccc2-c2cc5ccccc5c5ccccc25)c2cc(N(c5ccc(-c6ccccc6)cc5)c5cccc(-c6ccccc6)c5)ccc2B4c2ccc(N(c4ccc(-c5ccccc5)cc4)c4cccc(-c5ccccc5)c4)cc2N3c2c(-c3ccccc3)cccc2-c2cccc(-c3ccccc3)c2)cc(C(C)(C)C)c1]

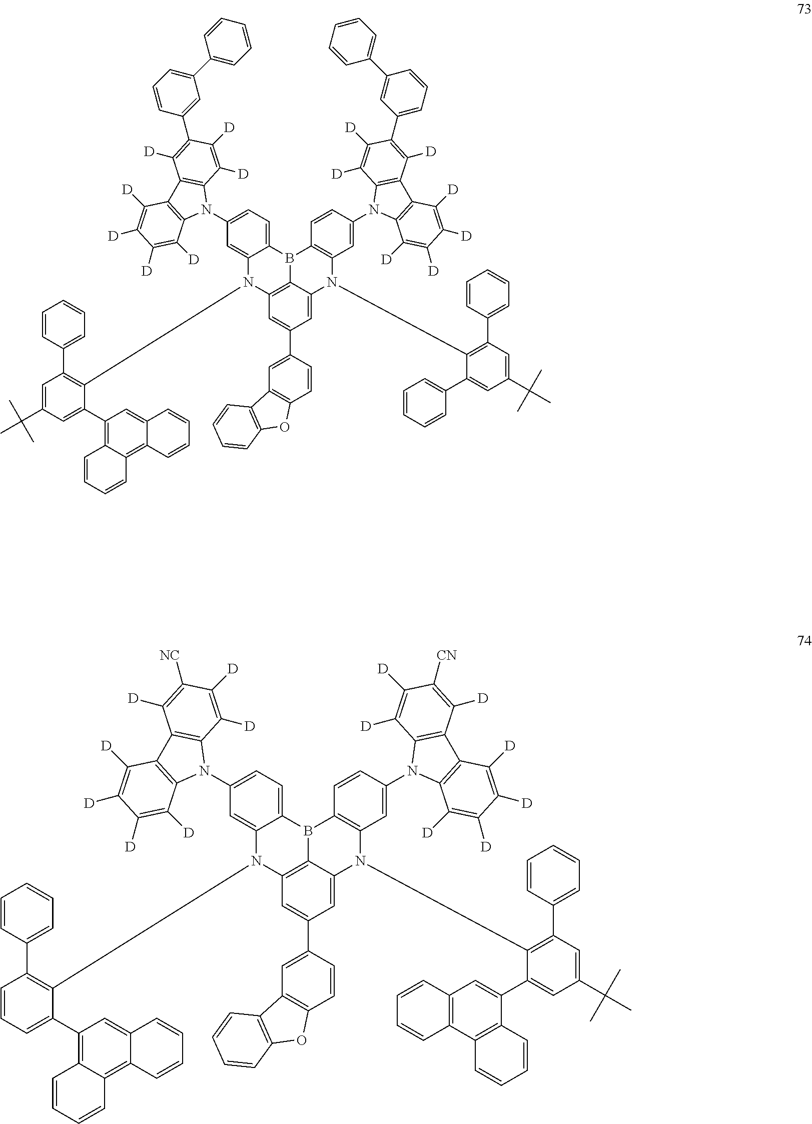

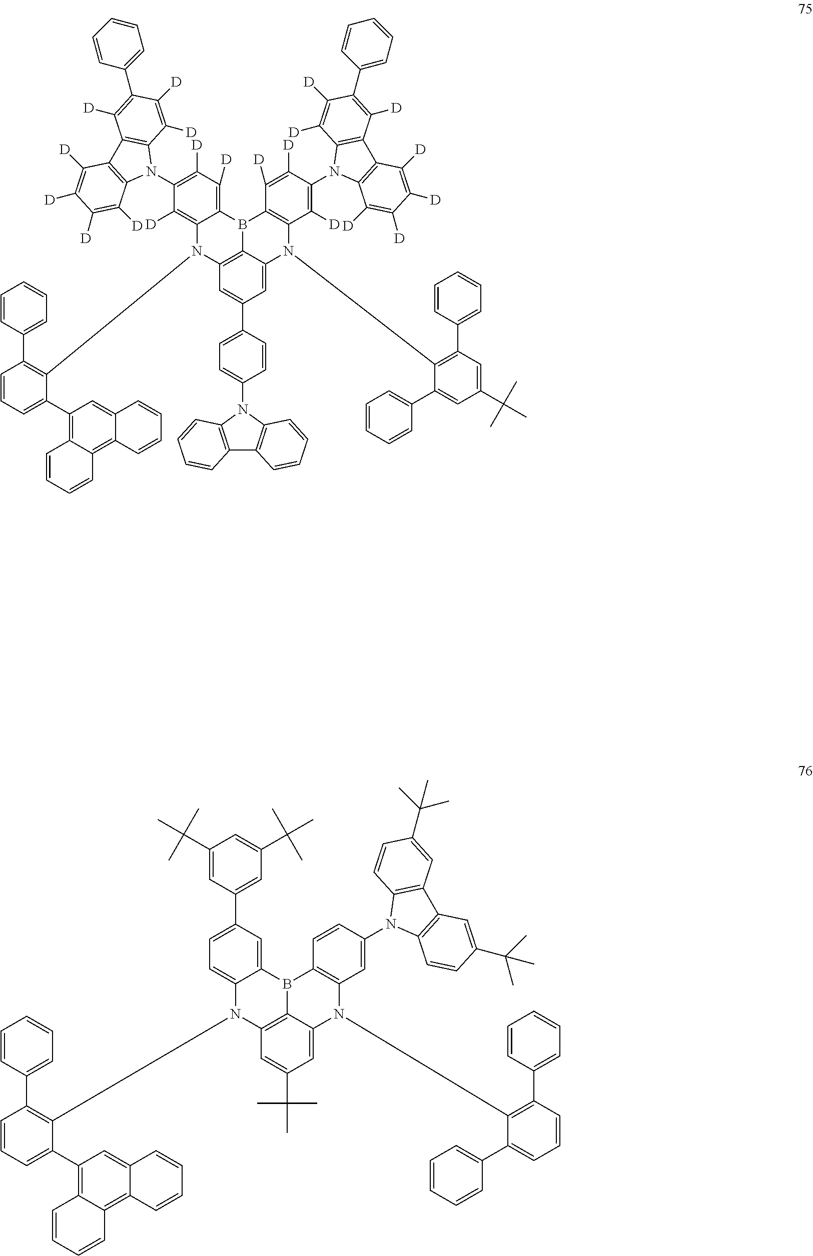

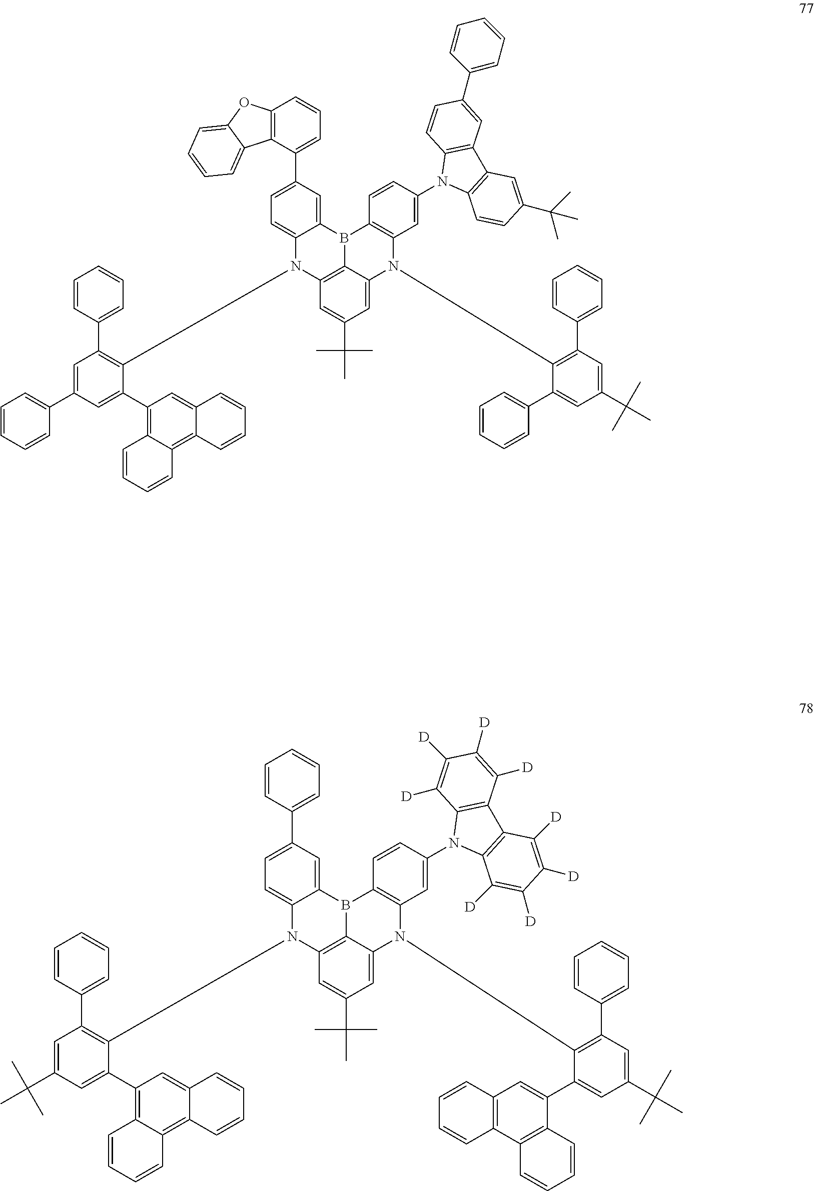

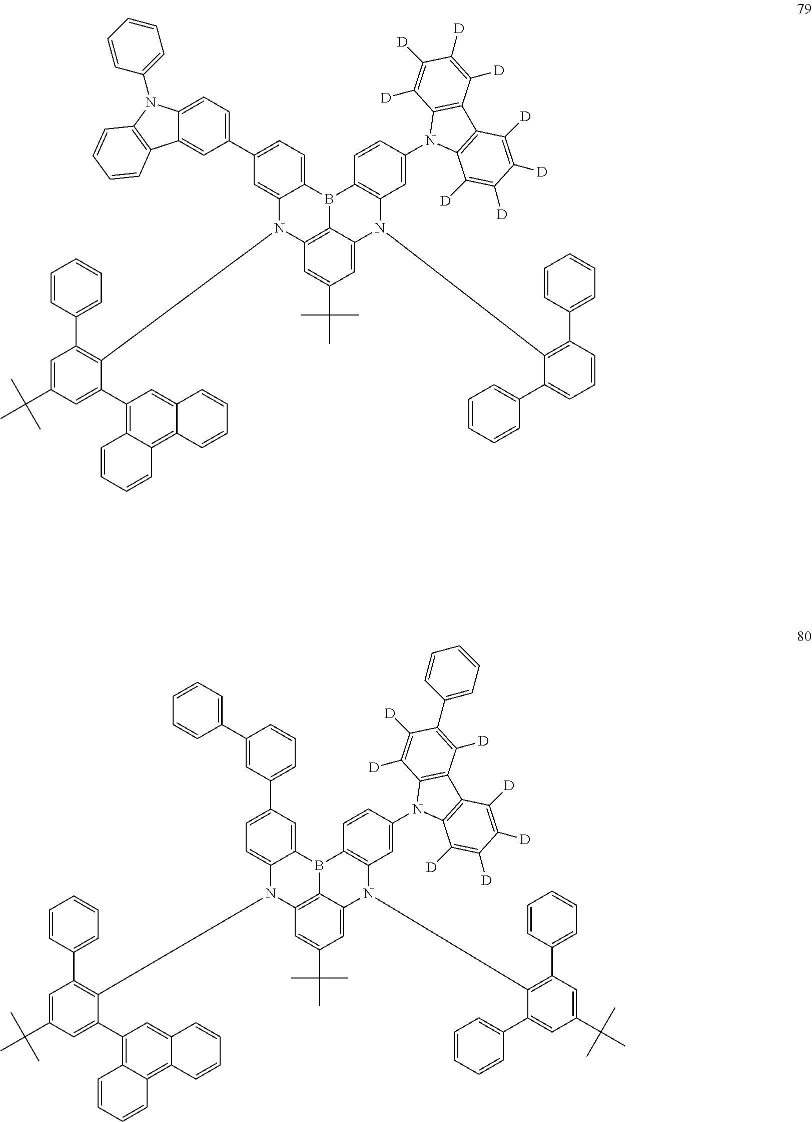 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccccc2)cc(C(C)(C)C)cc1-c1cc2ccccc2c2ccccc12 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccccc2)cc(C(C)(C)C)cc1-c1cc2ccccc2c2ccccc12]

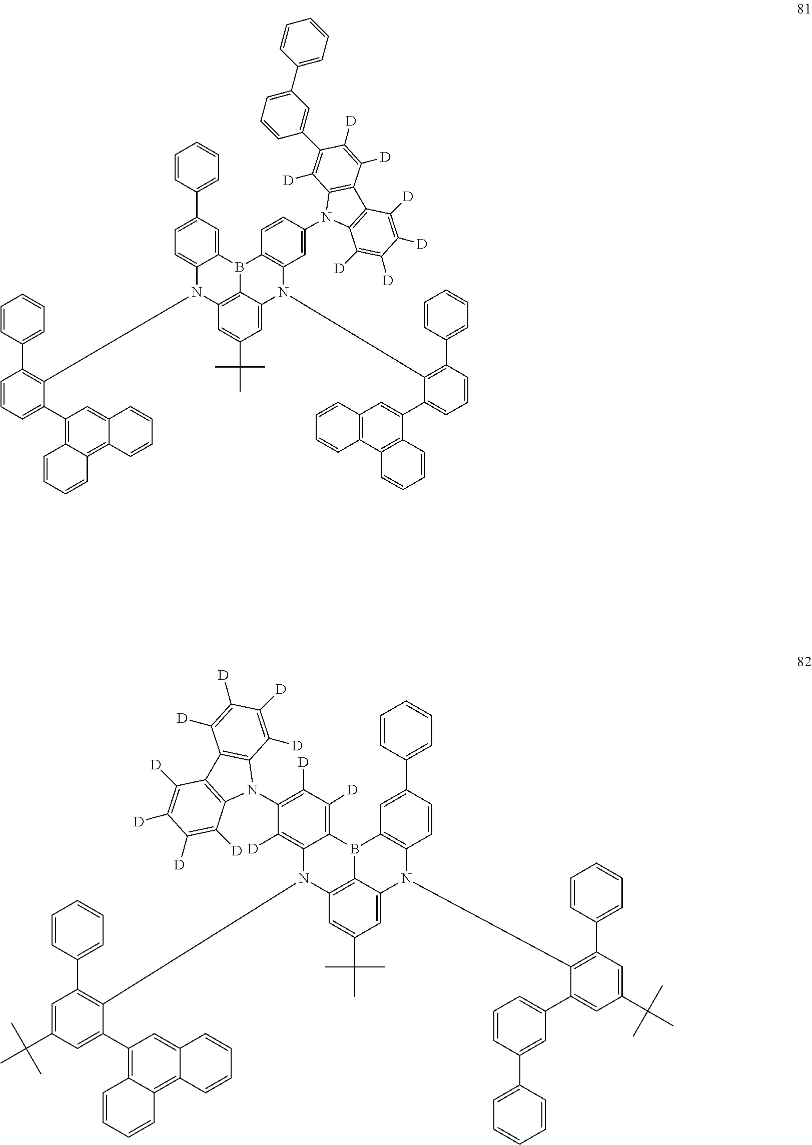 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1cc3ccccc3c3ccccc13)c1cc(C(C)(C)C)cc3c1B2c1cc(-c2ccccc2)ccc1N3c1c(-c2ccccc2)cccc1-c1cc2ccccc2c2ccccc12 ; [2H]c1c([2H])c(-n2c3c([2H])c([2H])c([2H])c([2H])c3c3c([2H])c([2H])c([2H])c([2H])c32)c([2H])c2c1B1c3cc(-c4ccccc4)ccc3N(c3c(-c4ccccc4)cc(C(C)(C)C)cc3-c3cccc(-c4ccccc4)c3)c3cc(C(C)(C)C)cc(c31)N2c1c(-c2ccccc2)cc(C(C)(C)C)cc1-c1cc2ccccc2c2ccccc12]

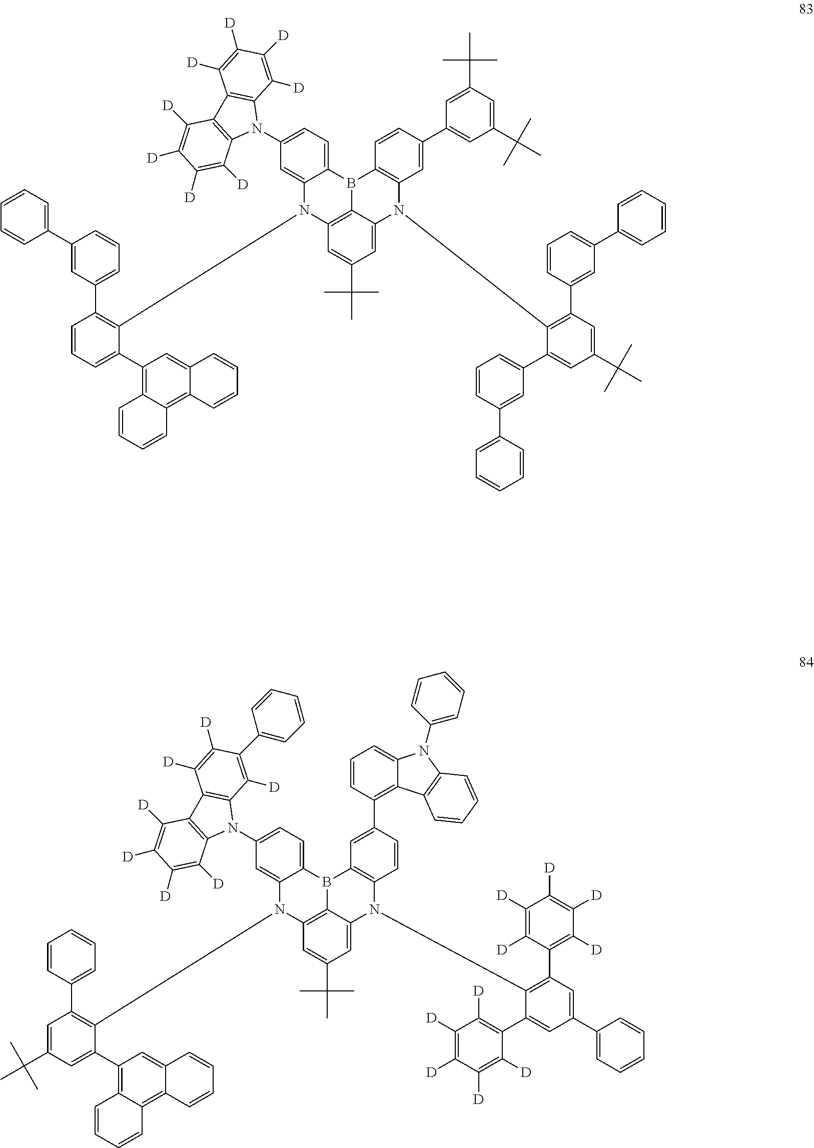

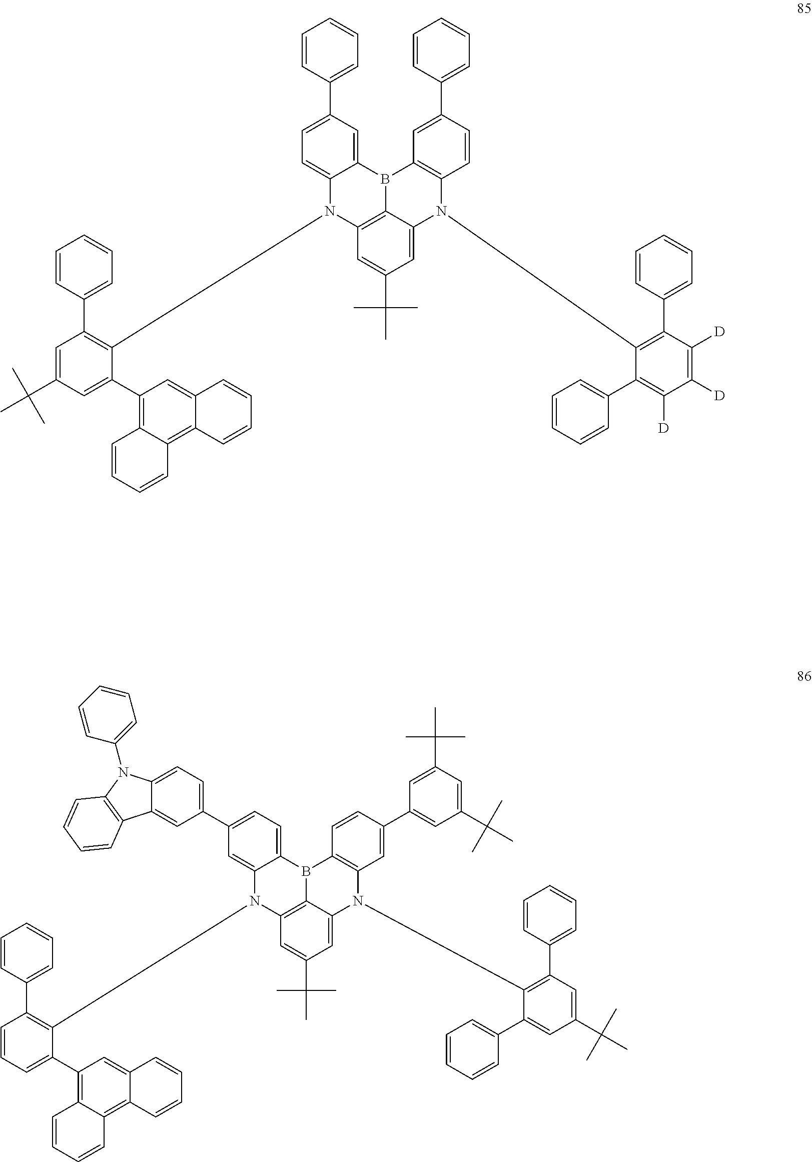 [SMILES: [2H]c1c([2H])c(-c2ccccc2)c(N2c3ccc(-c4ccccc4)cc3B3c4cc(-c5ccccc5)ccc4N(c4c(-c5ccccc5)cc(C(C)(C)C)cc4-c4cc5ccccc5c5ccccc45)c4cc(C(C)(C)C)cc2c43)c(-c2ccccc2)c1[2H] ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-c3ccc5c(c3)c3ccccc3n5-c3ccccc3)cc2N4c2c(-c3ccccc3)cccc2-c2cc3ccccc3c3ccccc23)cc(C(C)(C)C)c1]

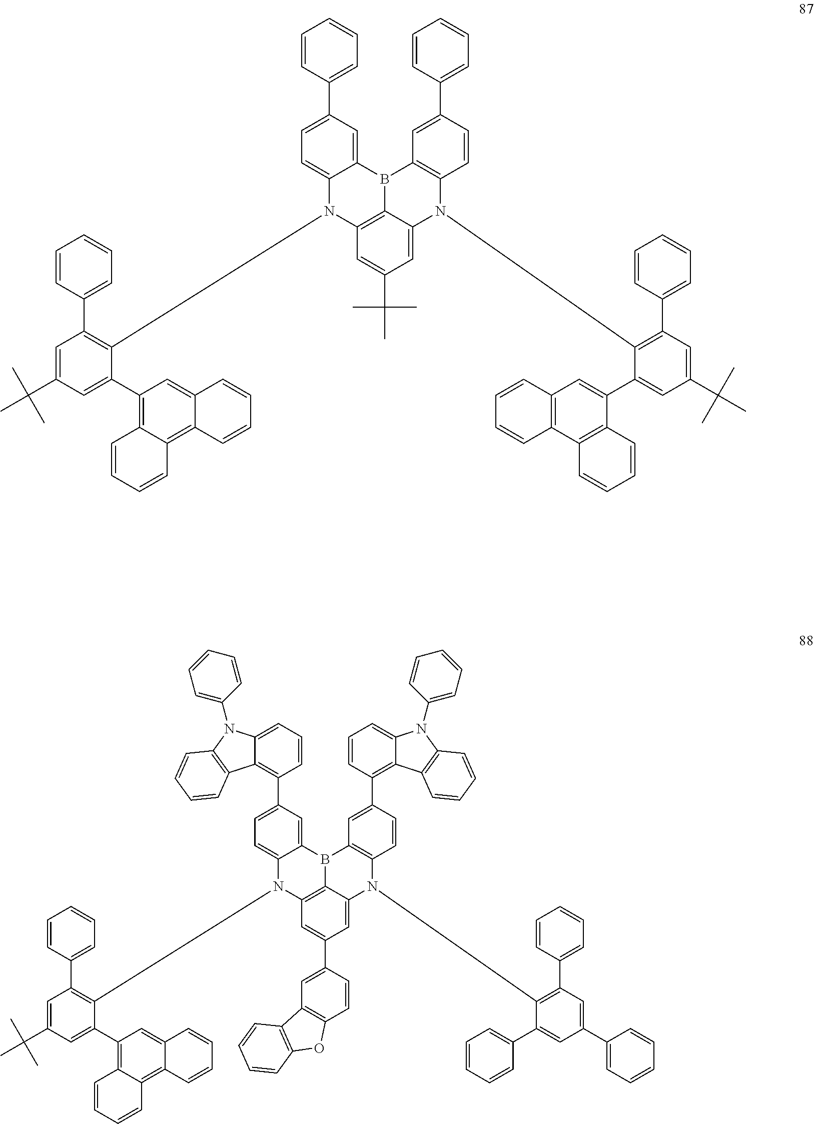

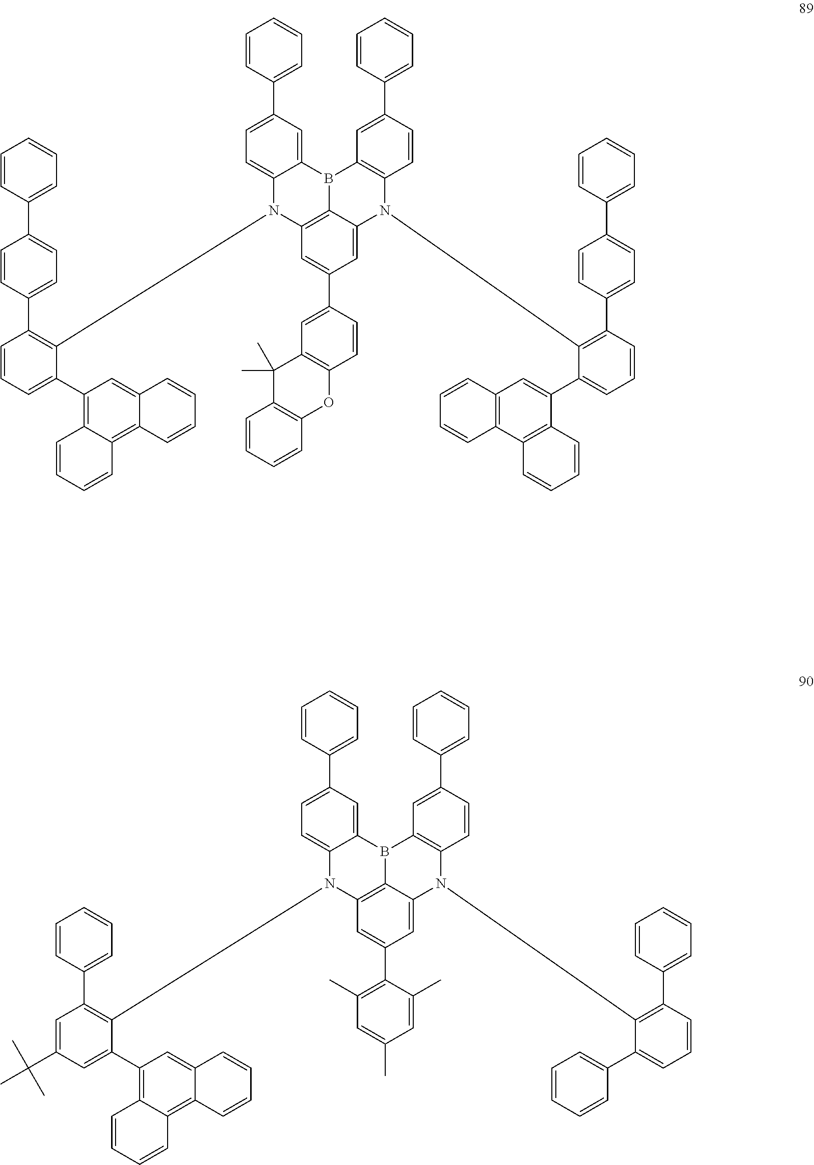 [SMILES: CC1(C)c2ccccc2Oc2ccc(-c3cc4c5c(c3)N(c3c(-c6ccc(-c7ccccc7)cc6)cccc3-c3cc6ccccc6c6ccccc36)c3ccc(-c6ccccc6)cc3B5c3cc(-c5ccccc5)ccc3N4c3c(-c4ccc(-c5ccccc5)cc4)cccc3-c3cc4ccccc4c4ccccc34)cc21 ; Cc1cc(C)c(-c2cc3c4c(c2)N(c2c(-c5ccccc5)cc(C(C)(C)C)cc2-c2cc5ccccc5c5ccccc25)c2ccc(-c5ccccc5)cc2B4c2cc(-c4ccccc4)ccc2N3c2c(-c3ccccc3)cccc2-c2ccccc2)c(C)c1]

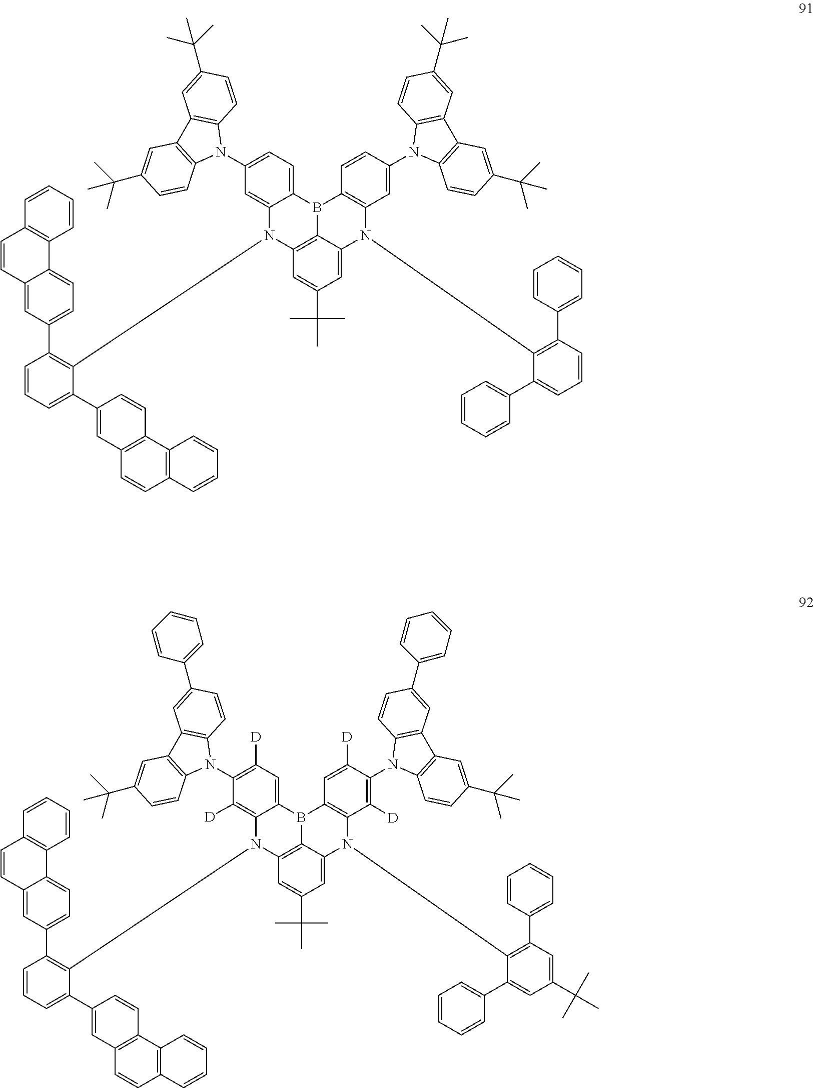 [SMILES: CC(C)(C)c1cc2c3c(c1)N(c1c(-c4ccc5c(ccc6ccccc65)c4)cccc1-c1ccc4c(ccc5ccccc54)c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; [2H]c1cc2c(c([2H])c1-n1c3ccc(-c4ccccc4)cc3c3cc(C(C)(C)C)ccc31)N(c1c(-c3ccc4c(ccc5ccccc54)c3)cccc1-c1ccc3c(ccc4ccccc43)c1)c1cc(C(C)(C)C)cc3c1B2c1cc([2H])c(-n2c4ccc(-c5ccccc5)cc4c4cc(C(C)(C)C)ccc42)c([2H])c1N3c1c(-c2ccccc2)cc(C(C)(C)C)cc1-c1ccccc1]

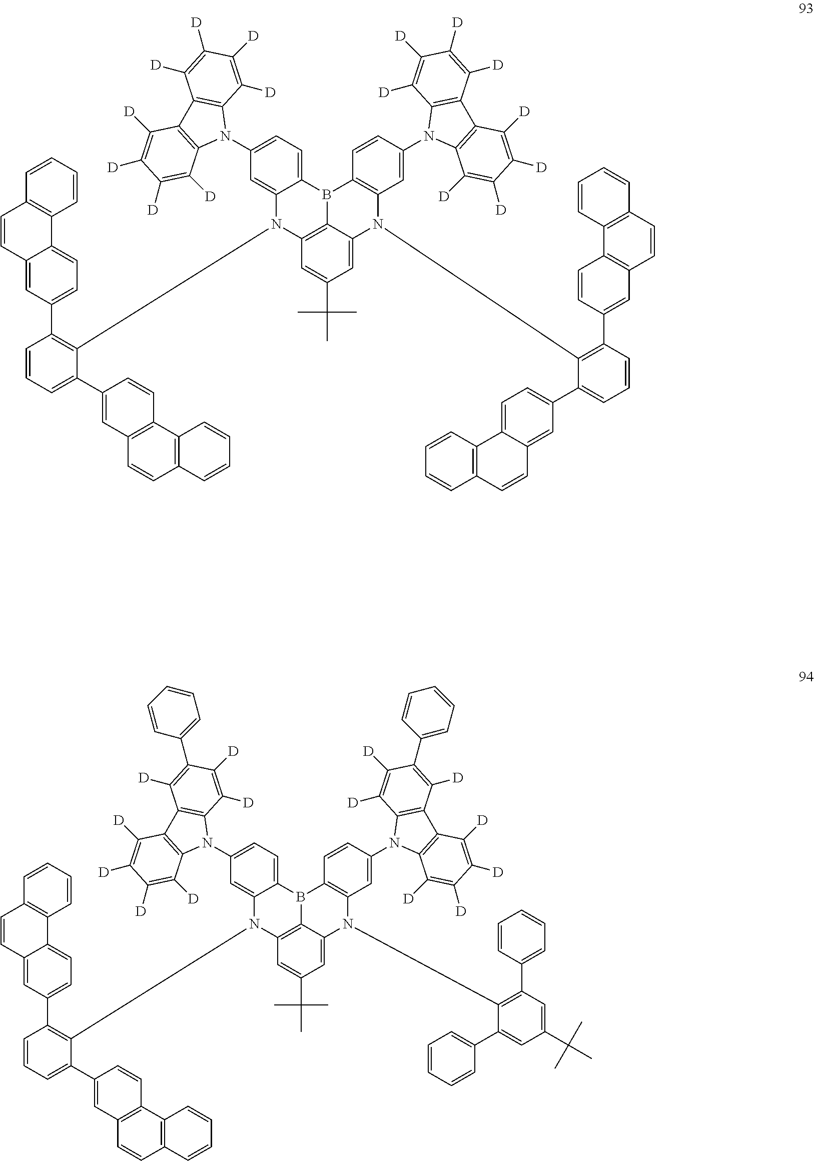

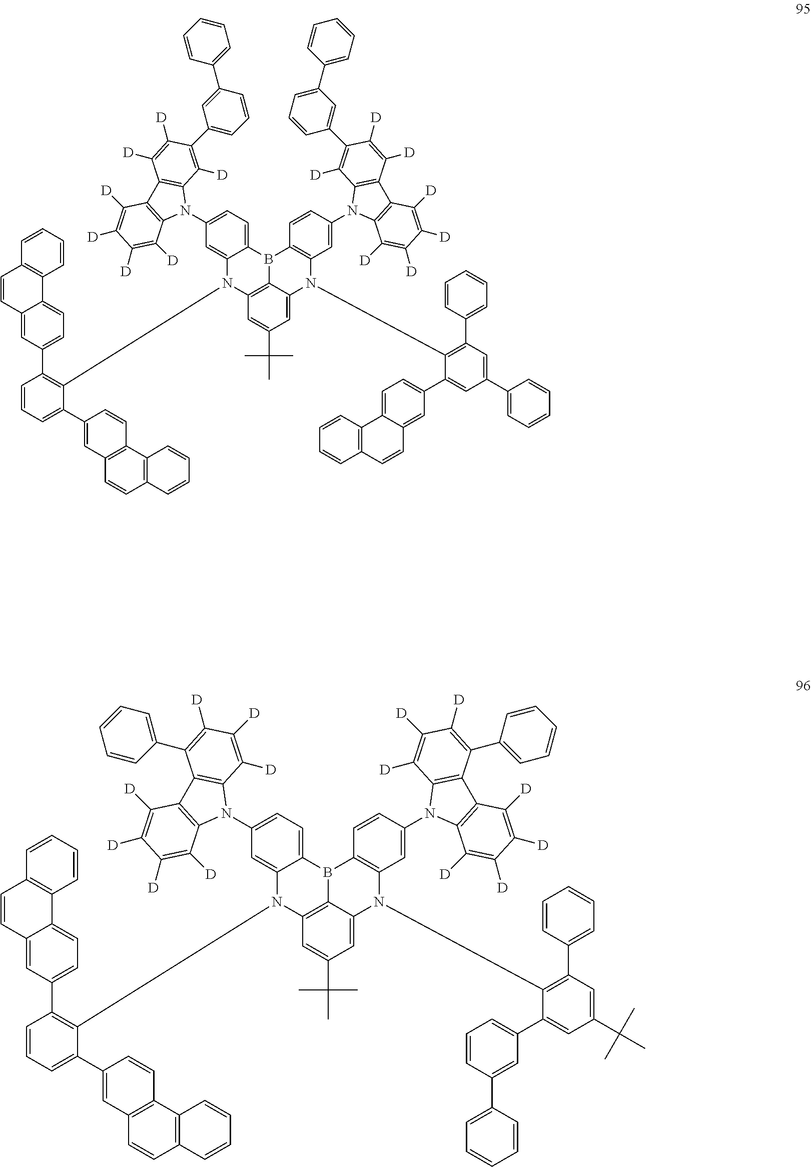

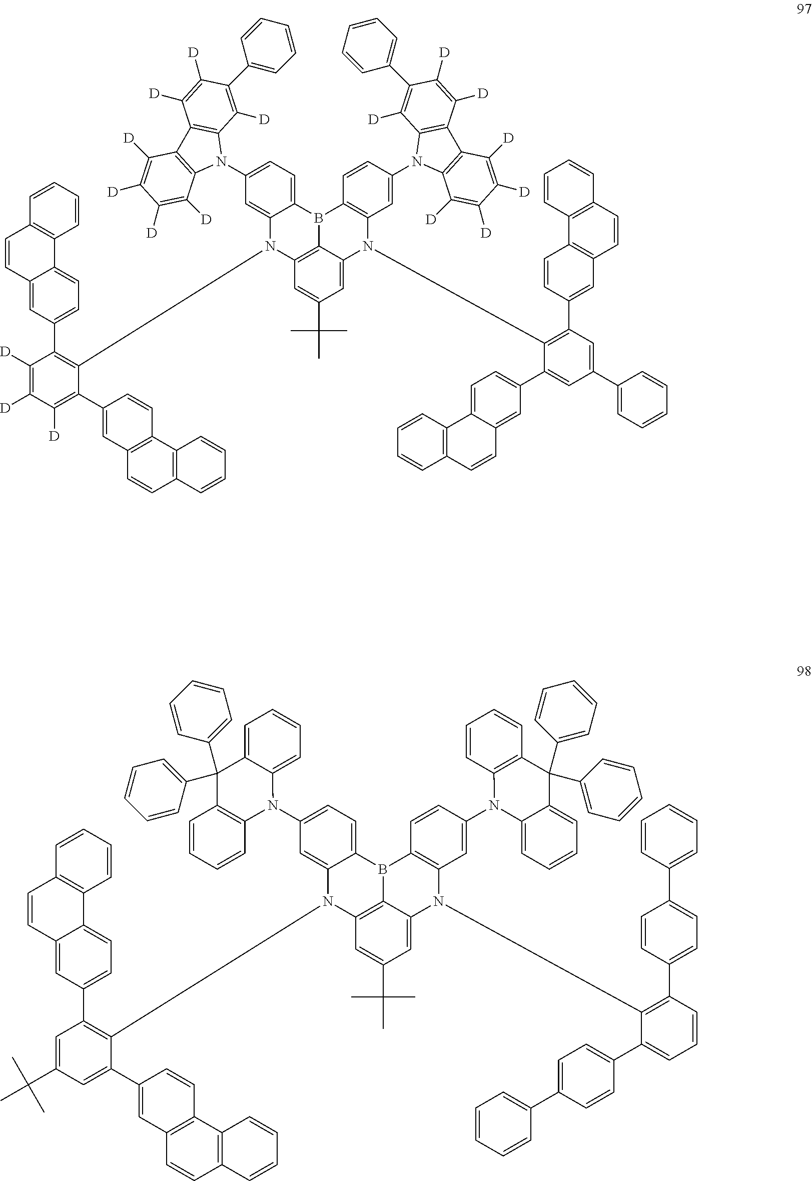

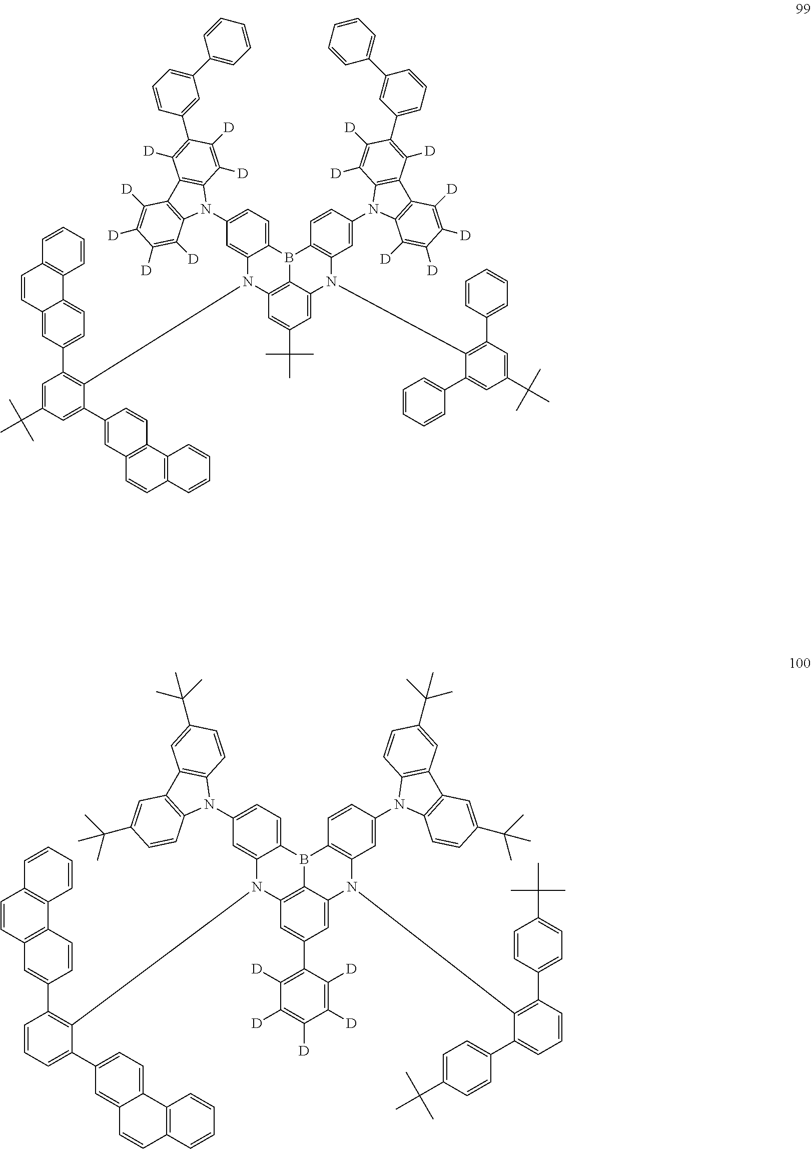

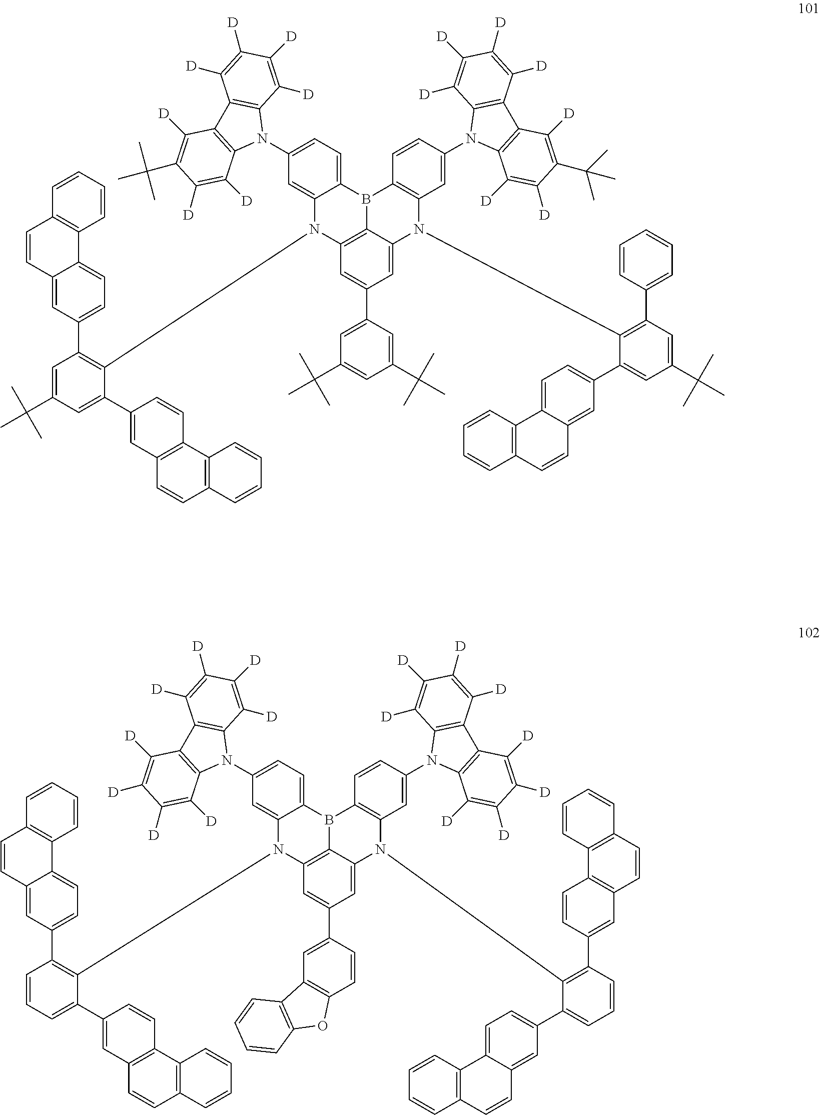

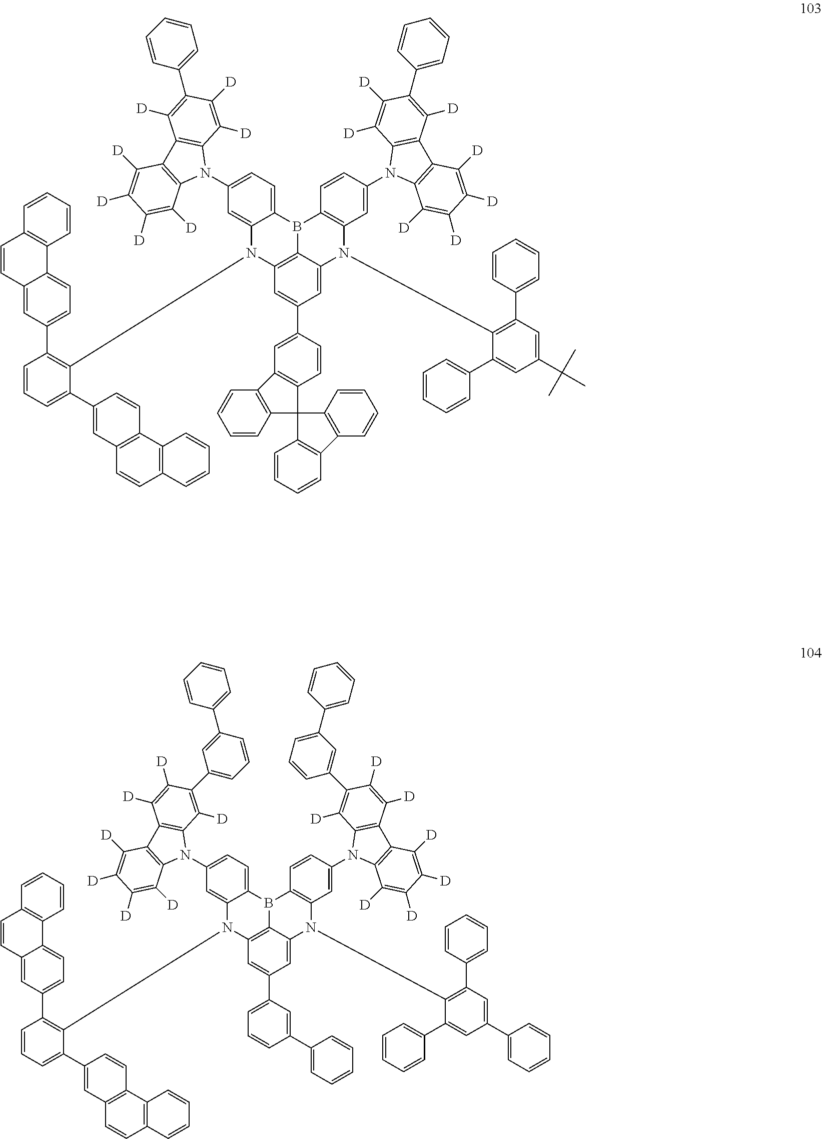

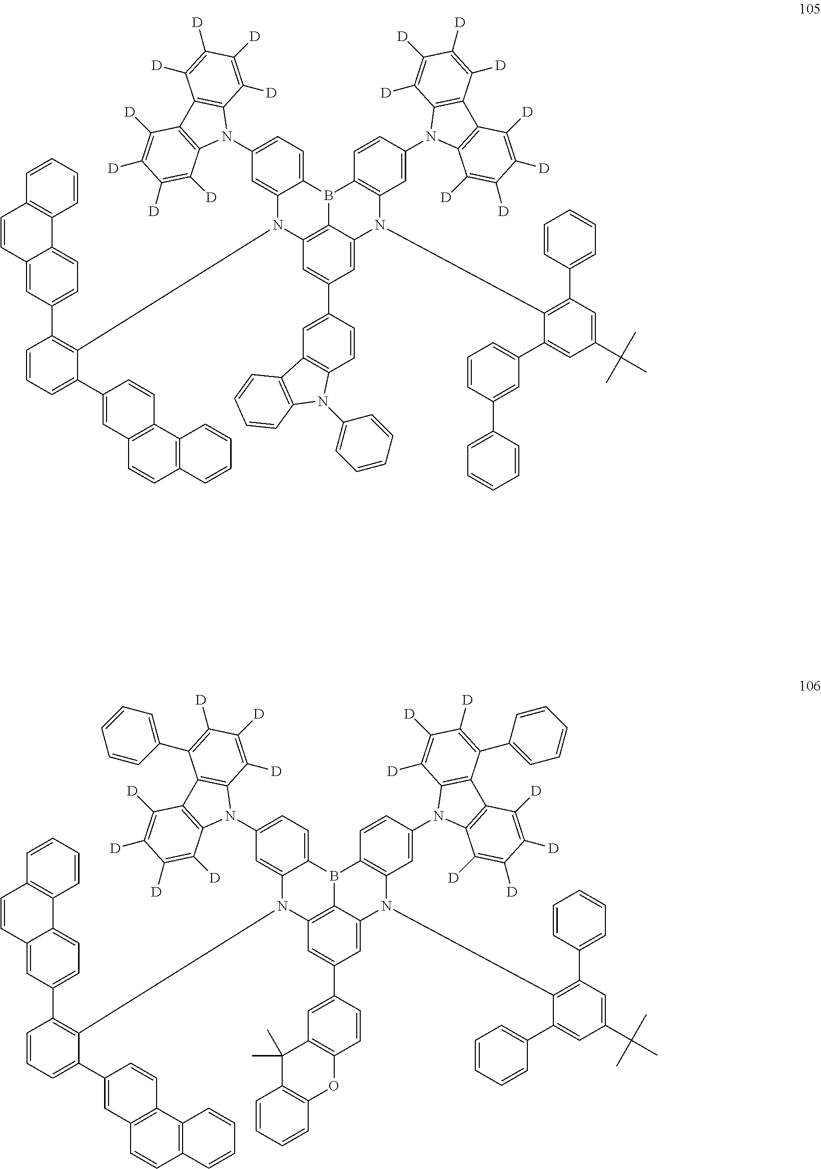

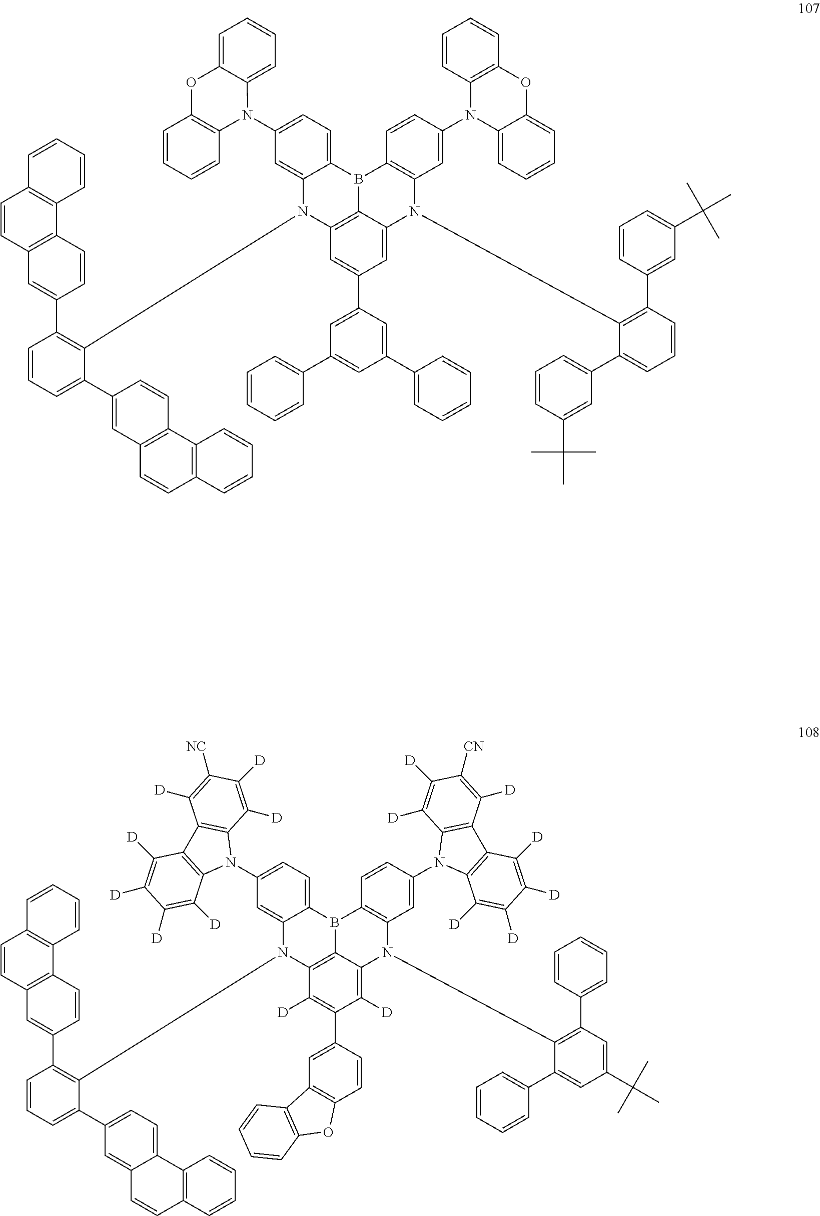

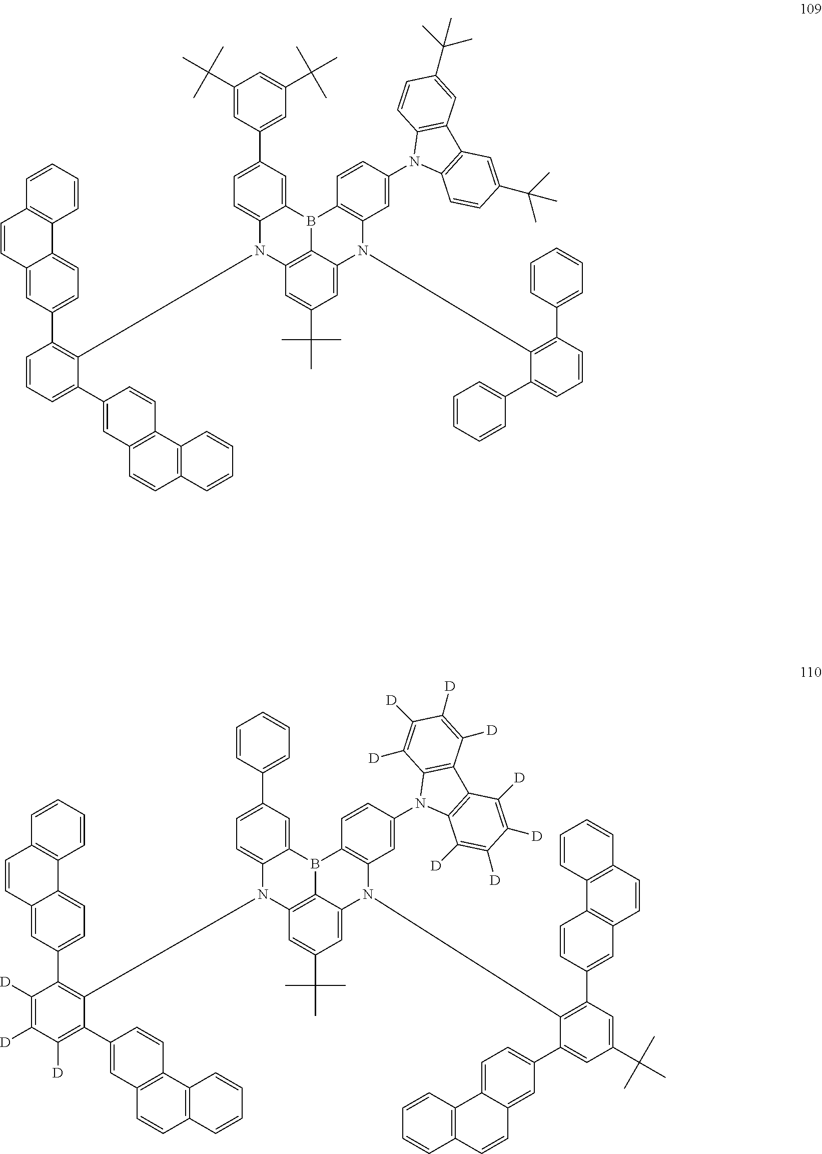 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3ccc4c(ccc5ccccc54)c3)cccc2-c2ccc3c(ccc4ccccc43)c2)cc(C(C)(C)C)c1 ; [2H]c1c([2H])c(-c2ccc3c(ccc4ccccc43)c2)c(N2c3ccc(-c4ccccc4)cc3B3c4ccc(-n5c6c([2H])c([2H])c([2H])c([2H])c6c6c([2H])c([2H])c([2H])c([2H])c65)cc4N(c4c(-c5ccc6c(ccc7ccccc76)c5)cc(C(C)(C)C)cc4-c4ccc5c(ccc6ccccc65)c4)c4cc(C(C)(C)C)cc2c43)c(-c2ccc3c(ccc4ccccc43)c2)c1[2H]]

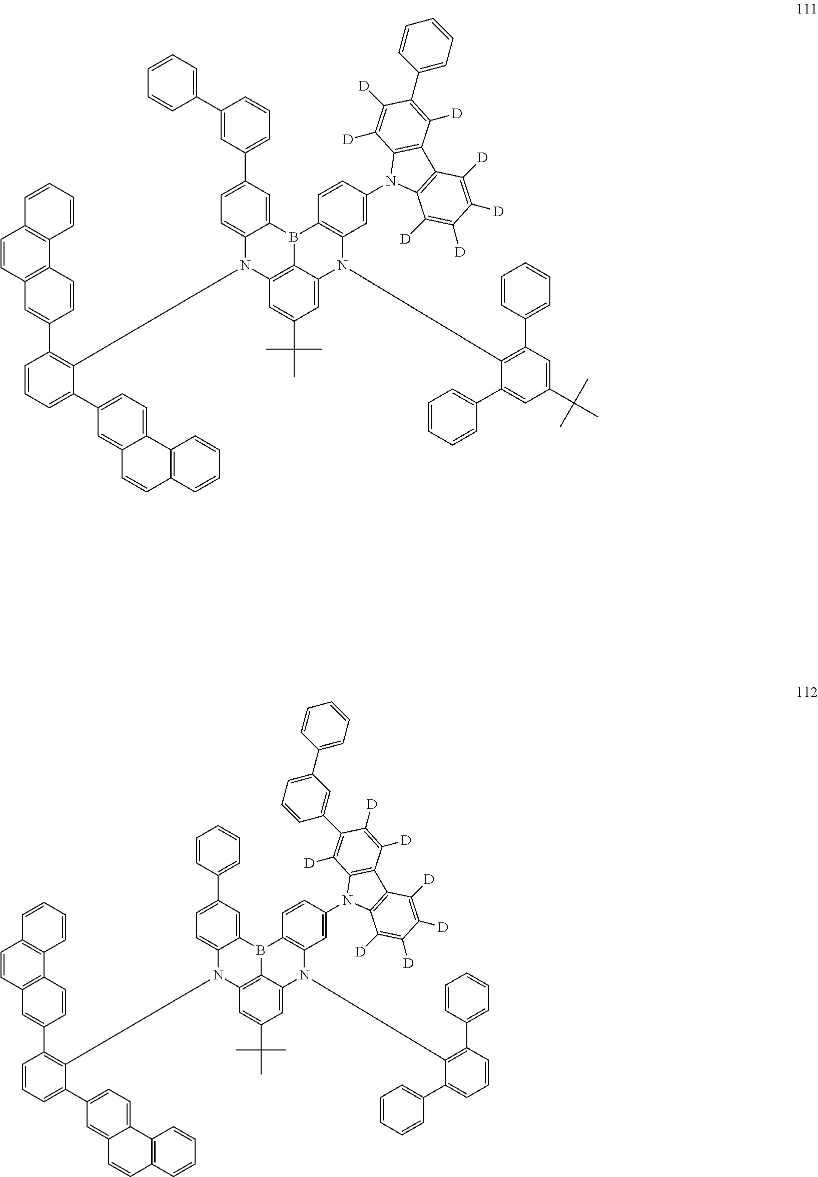 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccc3c(ccc4ccccc43)c2)cccc1-c1ccc2c(ccc3ccccc32)c1 ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccc3c(ccc4ccccc43)c2)cccc1-c1ccc2c(ccc3ccccc32)c1]

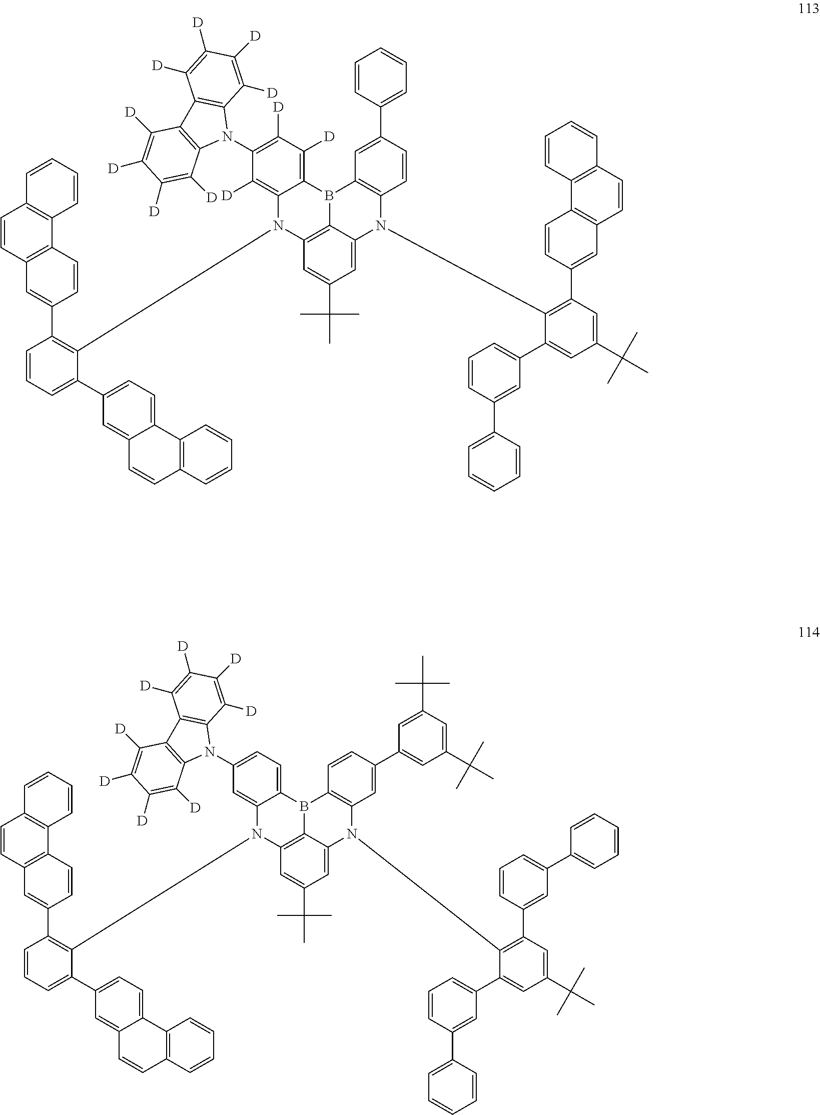

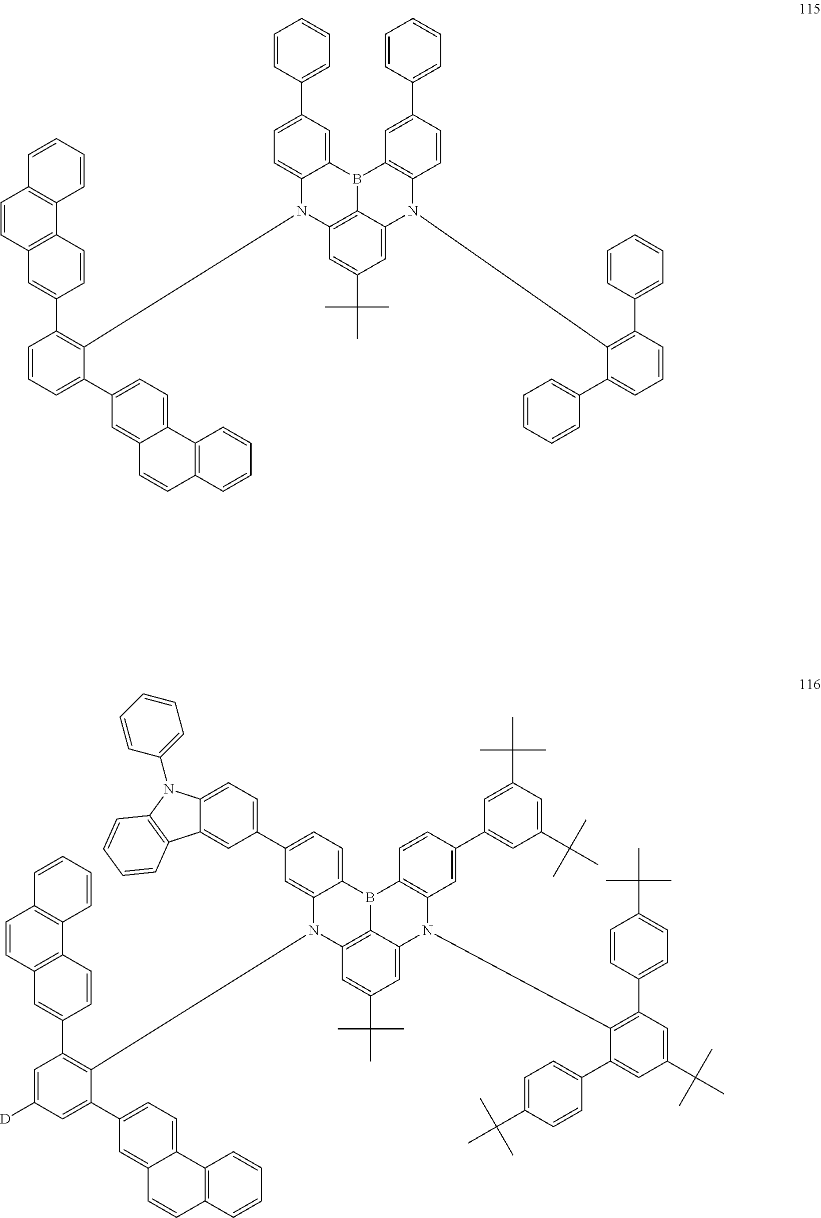 [SMILES: CC(C)(C)c1cc2c3c(c1)N(c1c(-c4ccc5c(ccc6ccccc65)c4)cccc1-c1ccc4c(ccc5ccccc54)c1)c1ccc(-c4ccccc4)cc1B3c1cc(-c3ccccc3)ccc1N2c1c(-c2ccccc2)cccc1-c1ccccc1 ; [2H]c1cc(-c2ccc3c(ccc4ccccc43)c2)c(N2c3cc(-c4ccc5c(c4)c4ccccc4n5-c4ccccc4)ccc3B3c4ccc(-c5cc(C(C)(C)C)cc(C(C)(C)C)c5)cc4N(c4c(-c5ccc(C(C)(C)C)cc5)cc(C(C)(C)C)cc4-c4ccc(C(C)(C)C)cc4)c4cc(C(C)(C)C)cc2c43)c(-c2ccc3c(ccc4ccccc43)c2)c1]

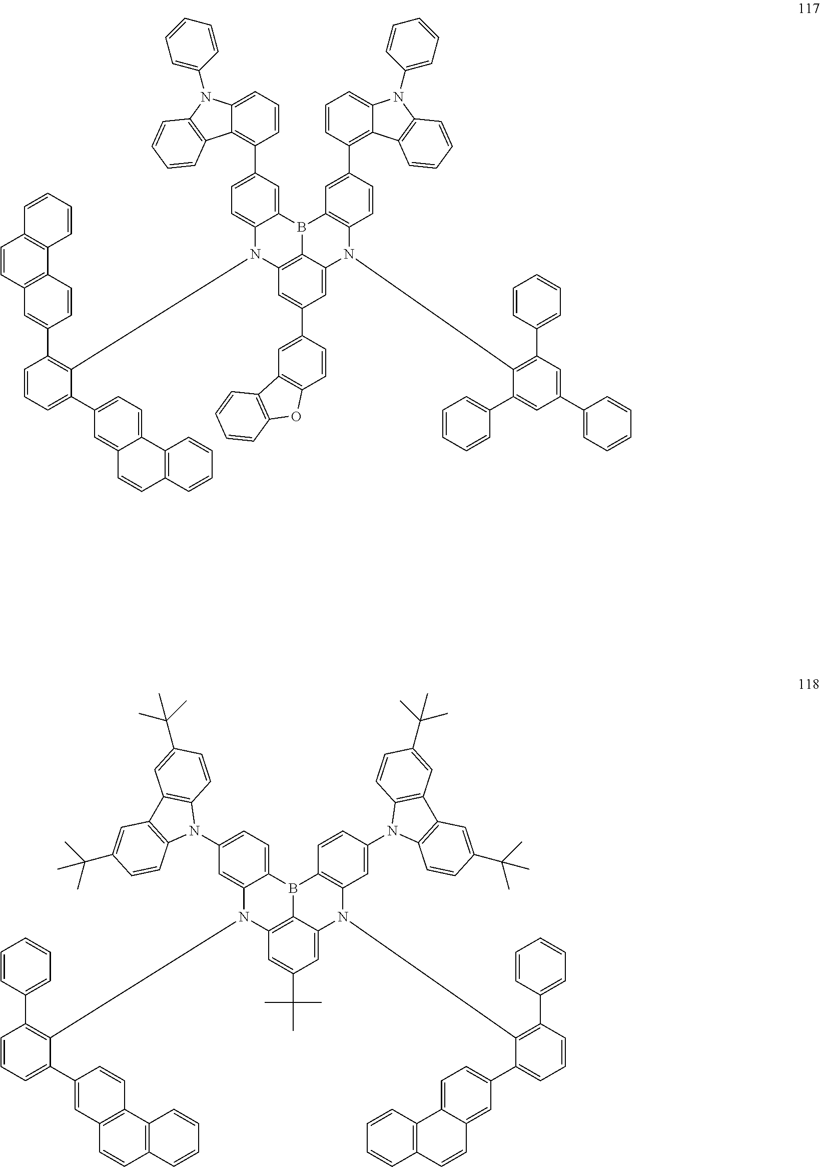 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccc7c(ccc8ccccc87)c6)cccc5-c5ccc6c(ccc7ccccc76)c5)c5cc(-c6ccc7oc8ccccc8c7c6)cc3c54)c(-c3ccccc3)c2)cc1 ; CC(C)(C)c1cc2c3c(c1)N(c1c(-c4ccccc4)cccc1-c1ccc4c(ccc5ccccc54)c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccc2c(ccc3ccccc32)c1]

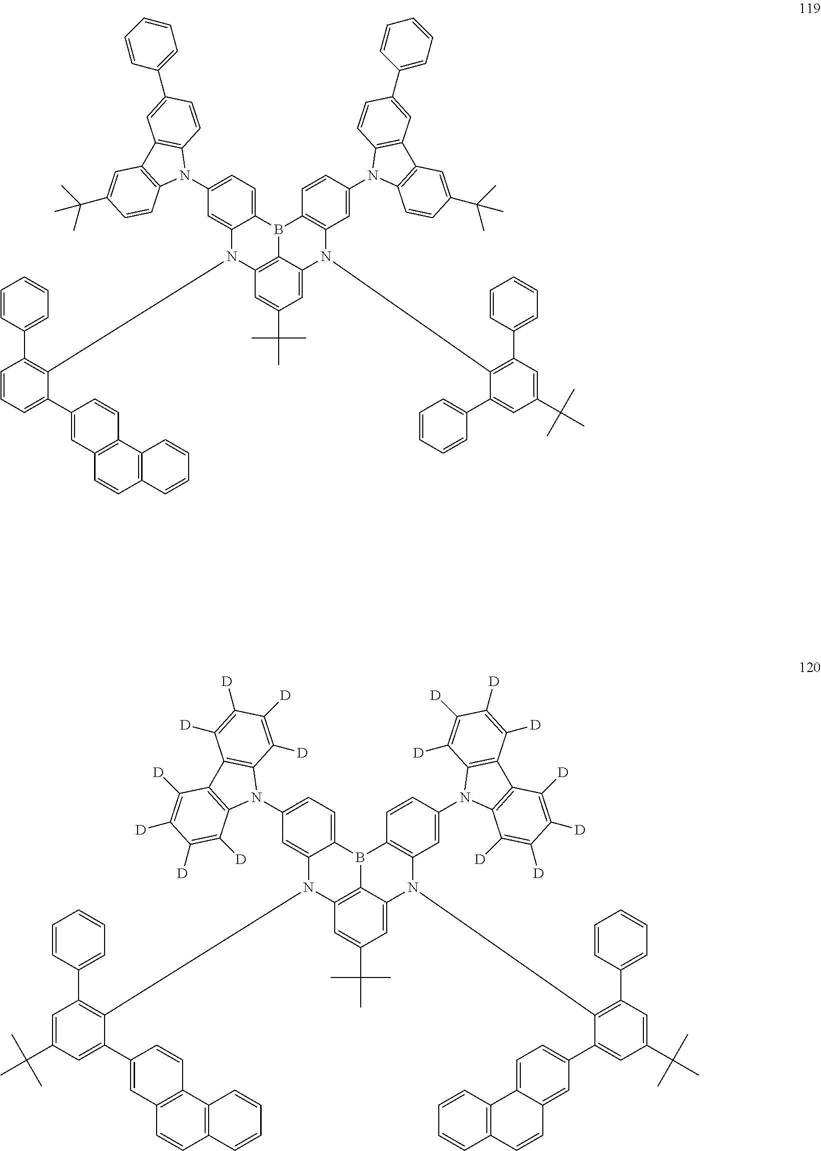

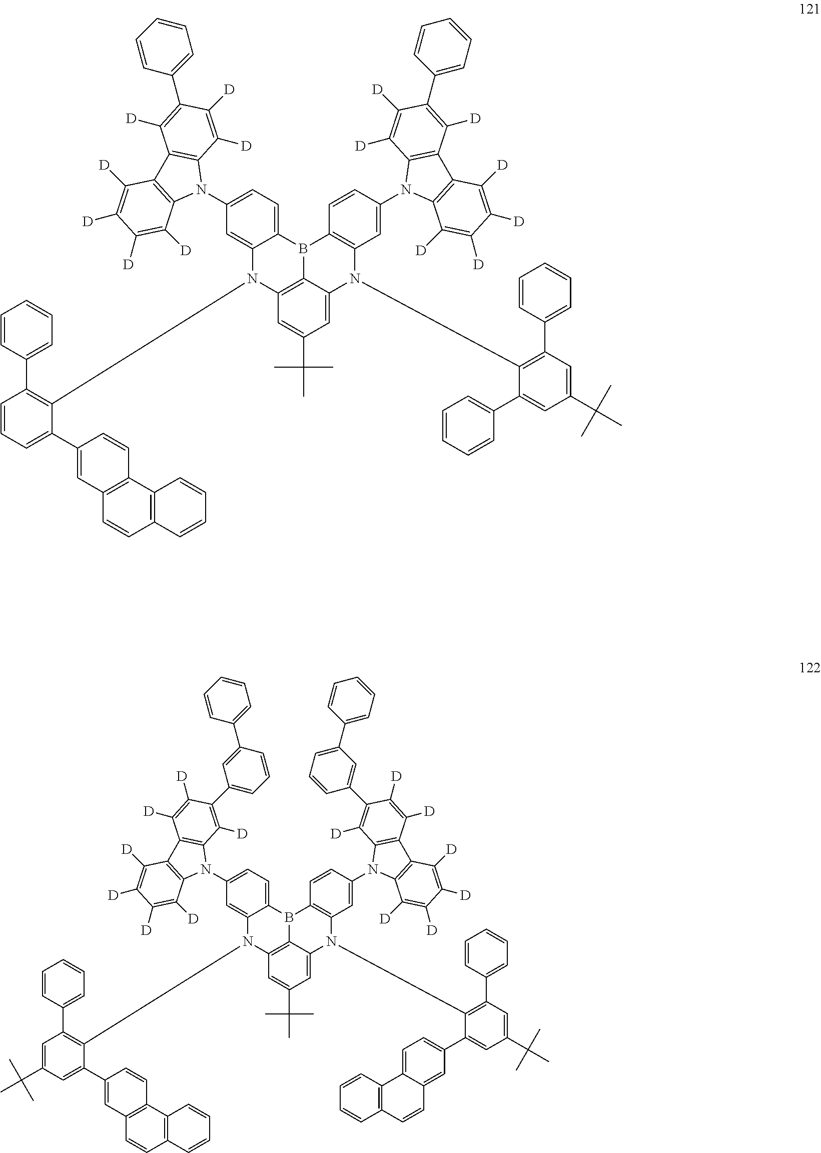

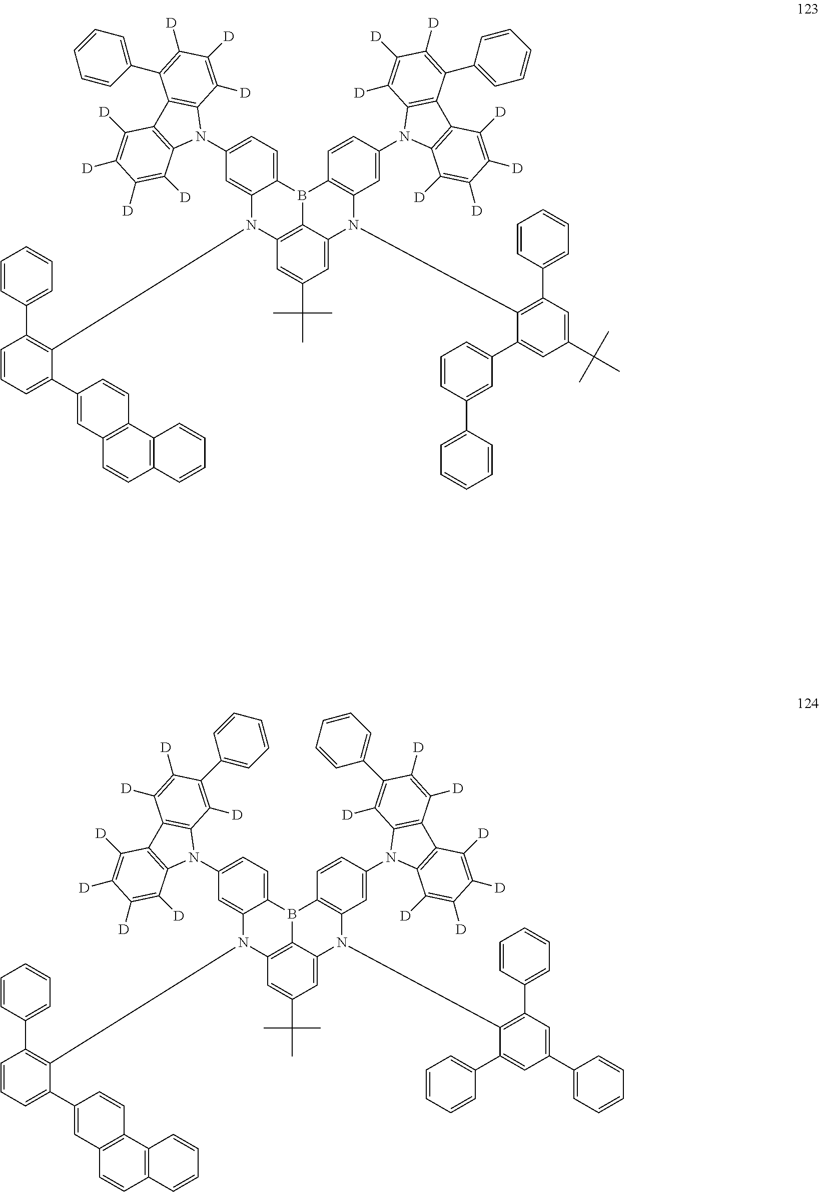

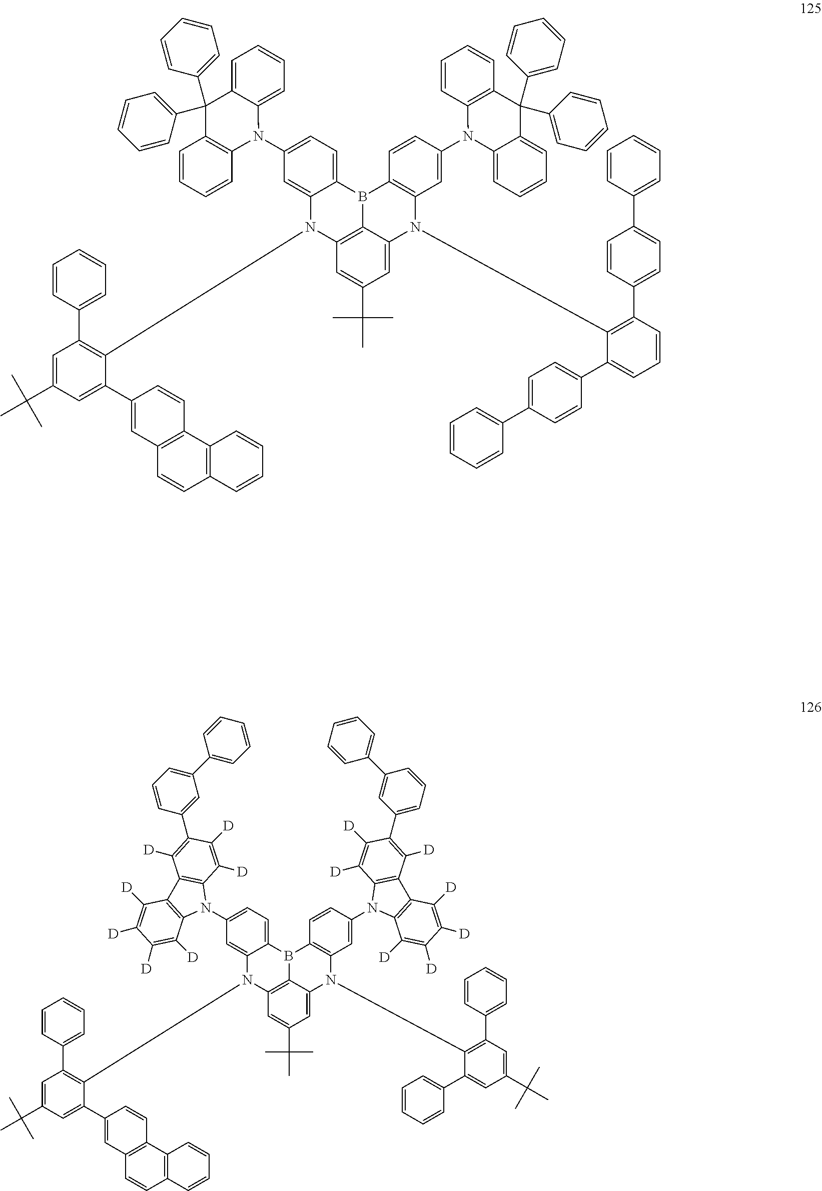

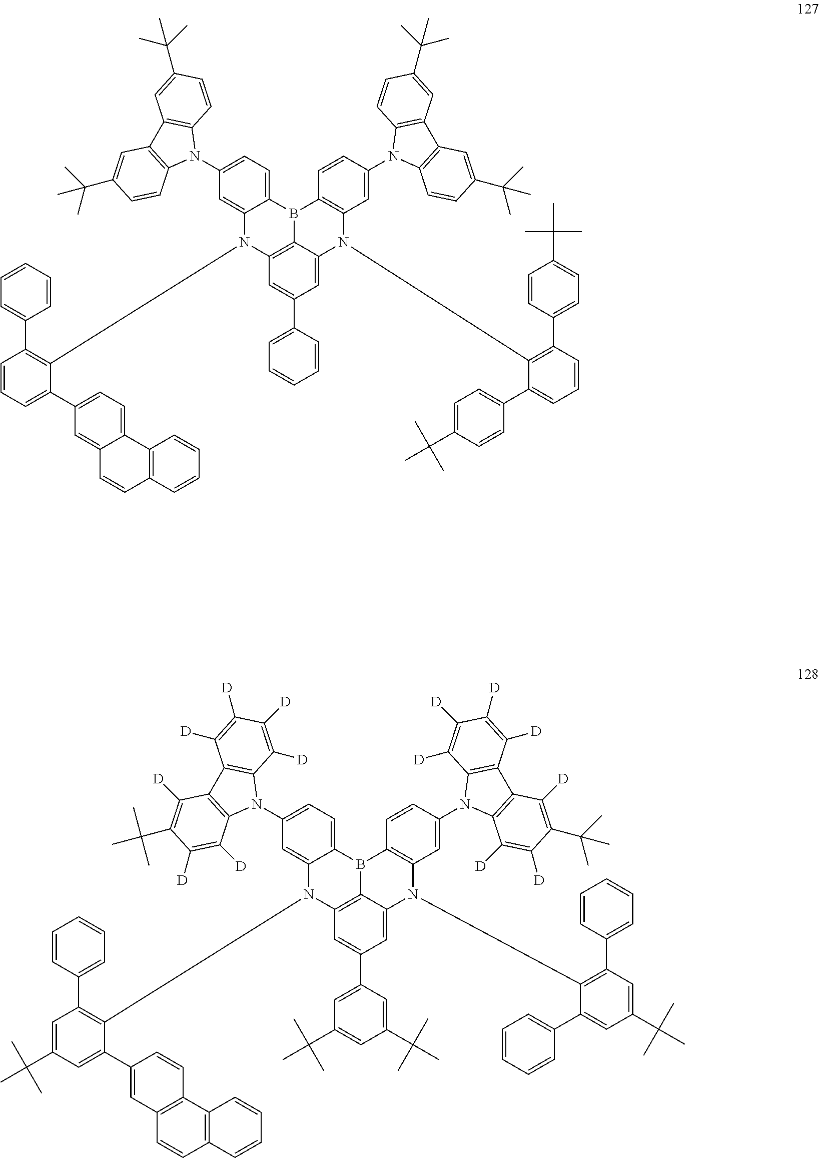

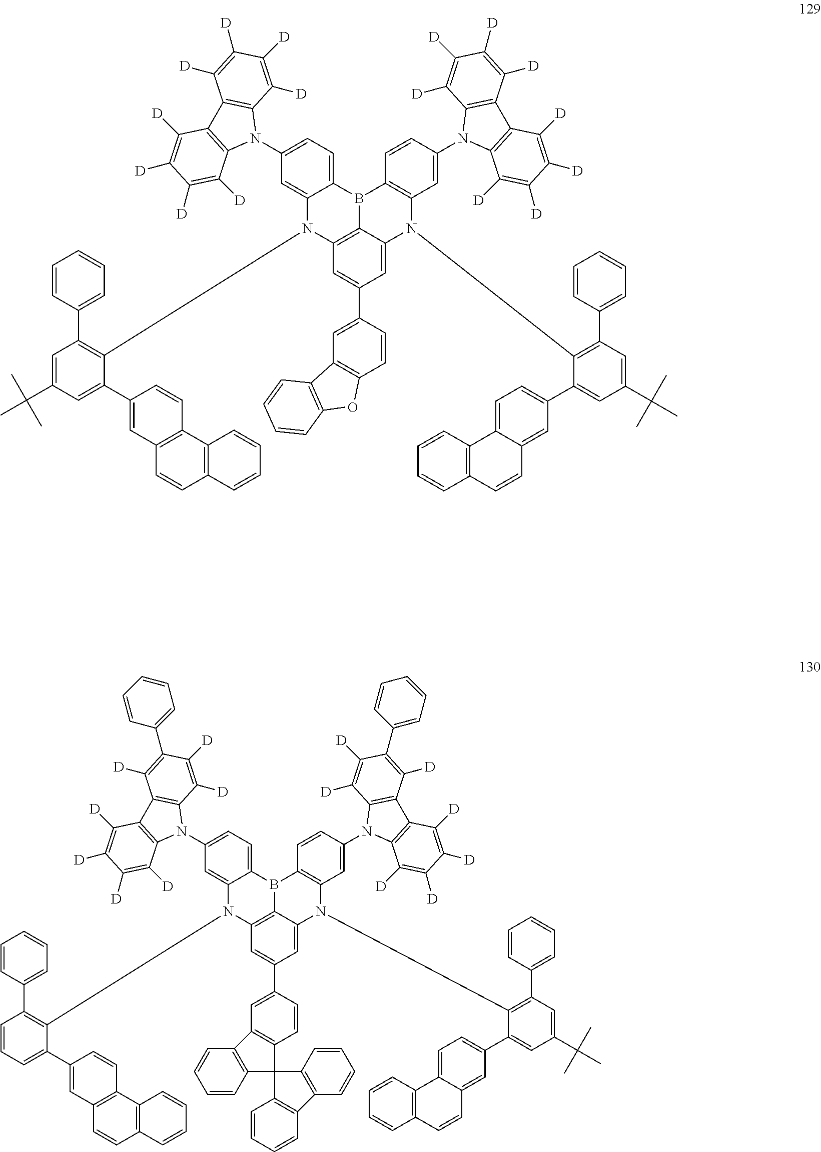

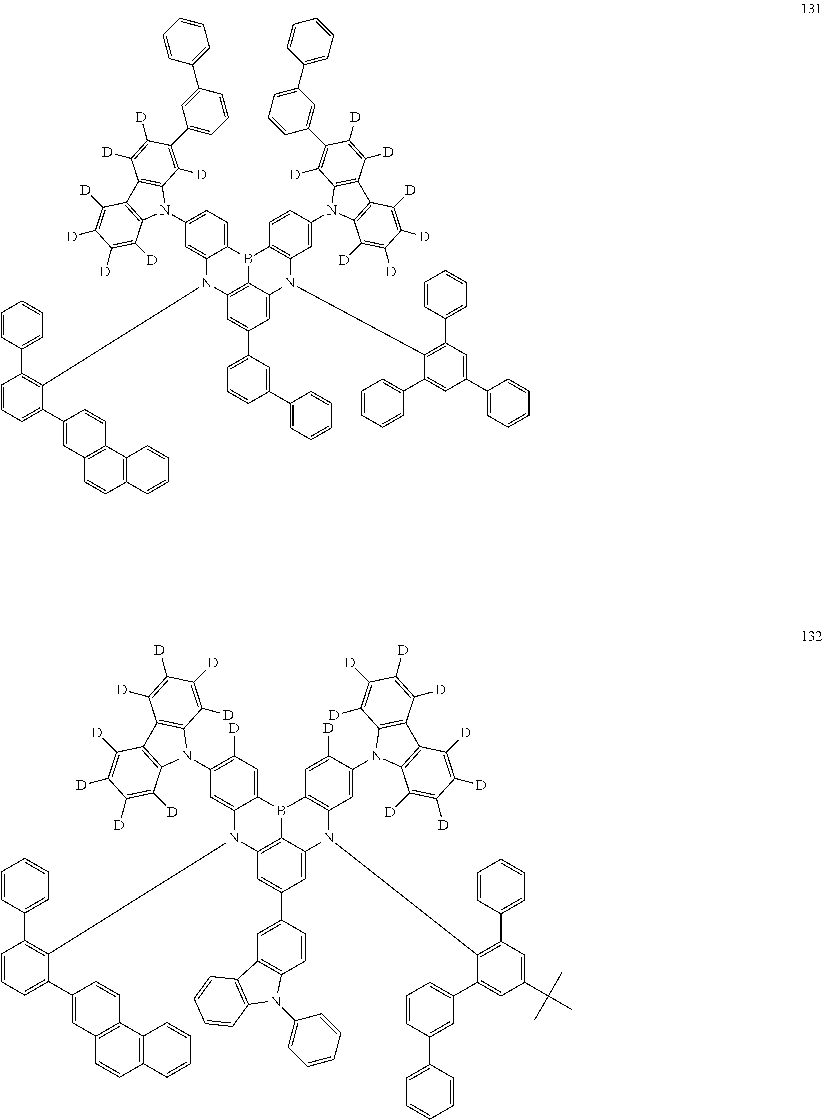

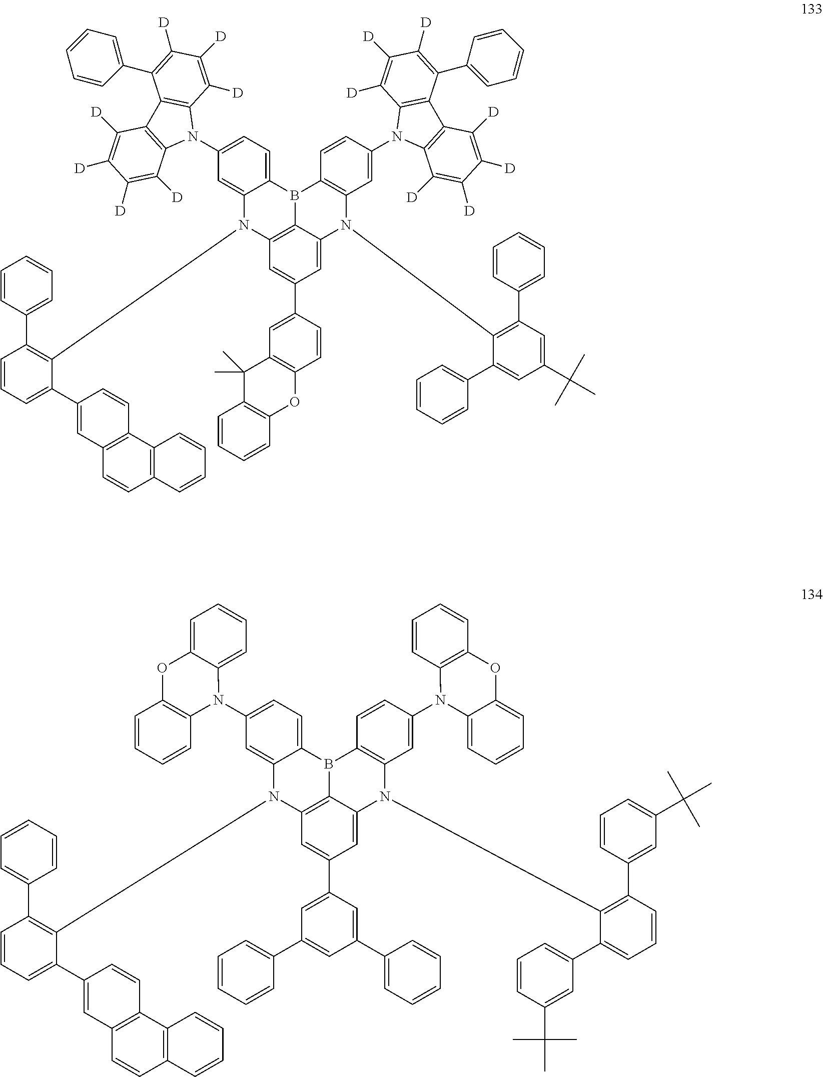 [SMILES: [2H]c1c([2H])c([2H])c2c(c1[2H])c1c(-c3ccccc3)c([2H])c([2H])c([2H])c1n2-c1ccc2c(c1)N(c1c(-c3ccccc3)cccc1-c1ccc3c(ccc4ccccc43)c1)c1cc(-c3ccc4c(c3)C(C)(C)c3ccccc3O4)cc3c1B2c1ccc(-n2c4c([2H])c([2H])c([2H])c([2H])c4c4c(-c5ccccc5)c([2H])c([2H])c([2H])c42)cc1N3c1c(-c2ccccc2)cc(C(C)(C)C)cc1-c1ccccc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5ccccc5)cccc4-c4ccc5c(ccc6ccccc65)c4)c4cc(-c5cc(-c6ccccc6)cc(-c6ccccc6)c5)cc2c43)c1]

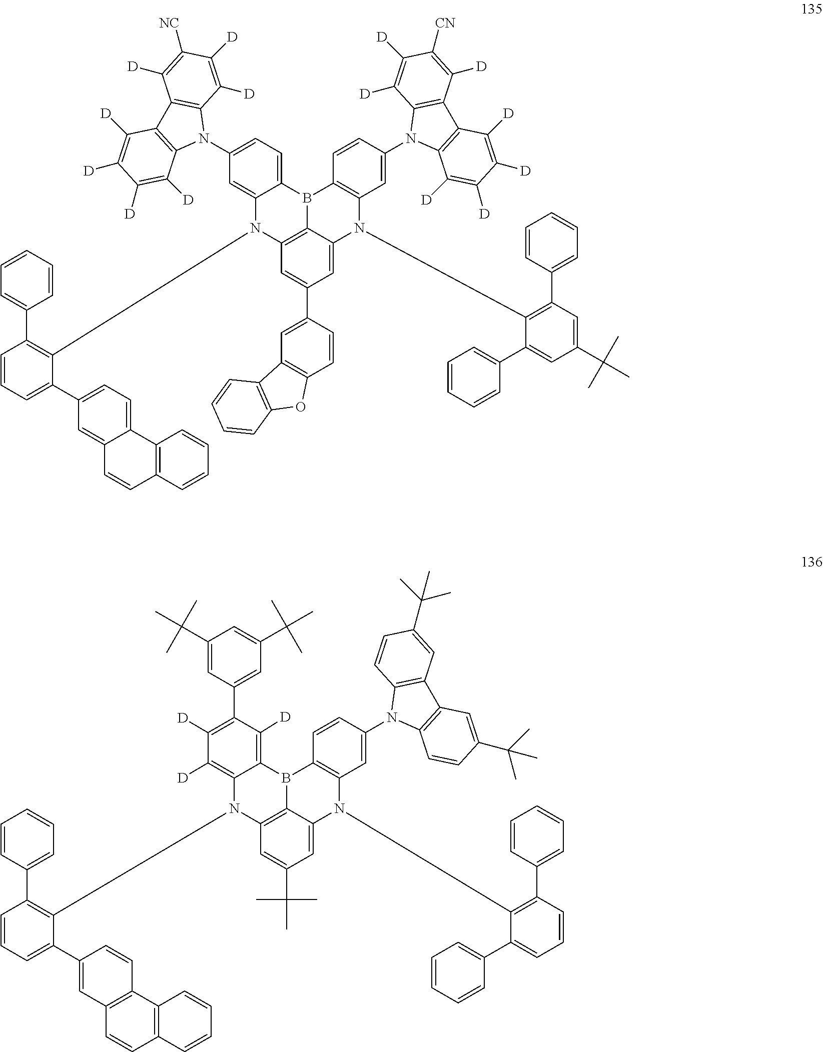 [SMILES: [2H]c1c([2H])c([2H])c2c(c1[2H])c1c([2H])c(C#N)c([2H])c([2H])c1n2-c1ccc2c(c1)N(c1c(-c3ccccc3)cccc1-c1ccc3c(ccc4ccccc43)c1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cc(C(C)(C)C)cc1-c1ccccc1 ; [2H]c1c([2H])c2c(c([2H])c1-c1cc(C(C)(C)C)cc(C(C)(C)C)c1)B1c3ccc(-n4c5ccc(C(C)(C)C)cc5c5cc(C(C)(C)C)ccc54)cc3N(c3c(-c4ccccc4)cccc3-c3ccccc3)c3cc(C(C)(C)C)cc(c31)N2c1c(-c2ccccc2)cccc1-c1ccc2c(ccc3ccccc32)c1]

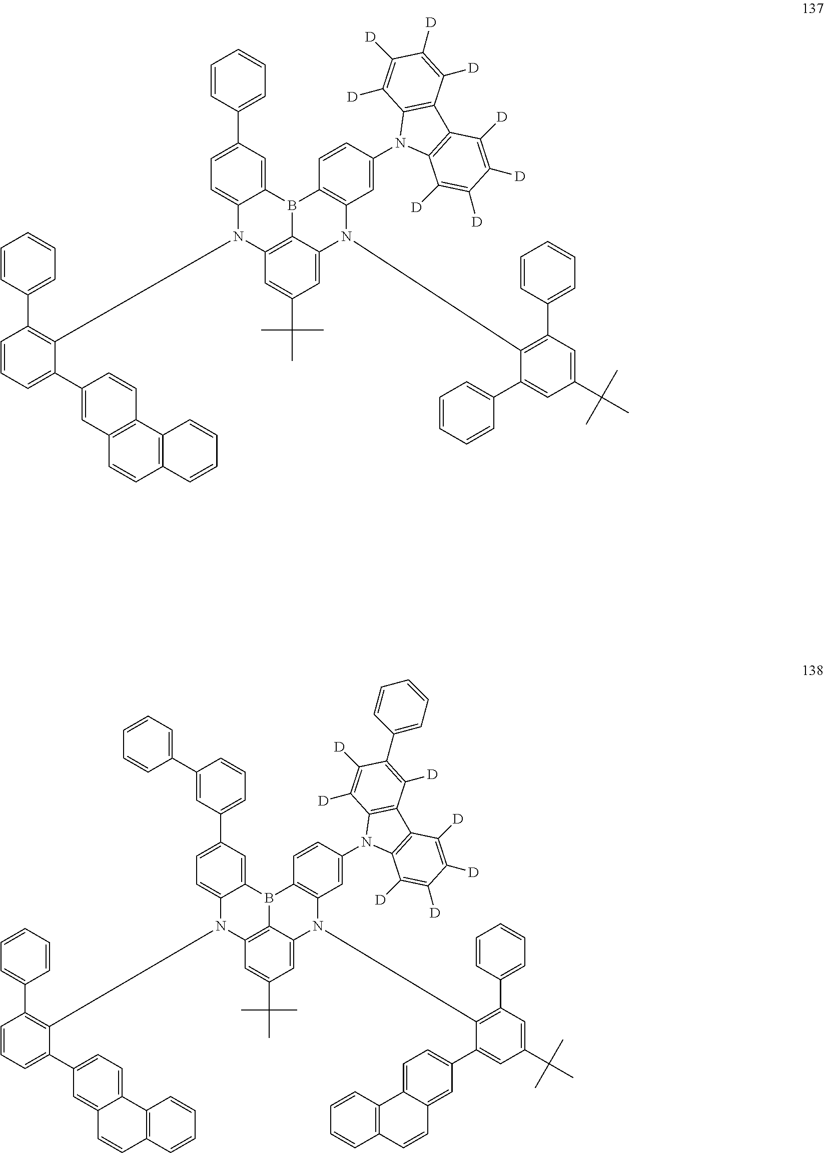 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2ccccc2)ccc1N3c1c(-c2ccccc2)cccc1-c1ccc2c(ccc3ccccc32)c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccc3c(ccc4ccccc43)c1)c1cc(C(C)(C)C)cc3c1B2c1cc(-c2cccc(-c4ccccc4)c2)ccc1N3c1c(-c2ccccc2)cccc1-c1ccc2c(ccc3ccccc32)c1]

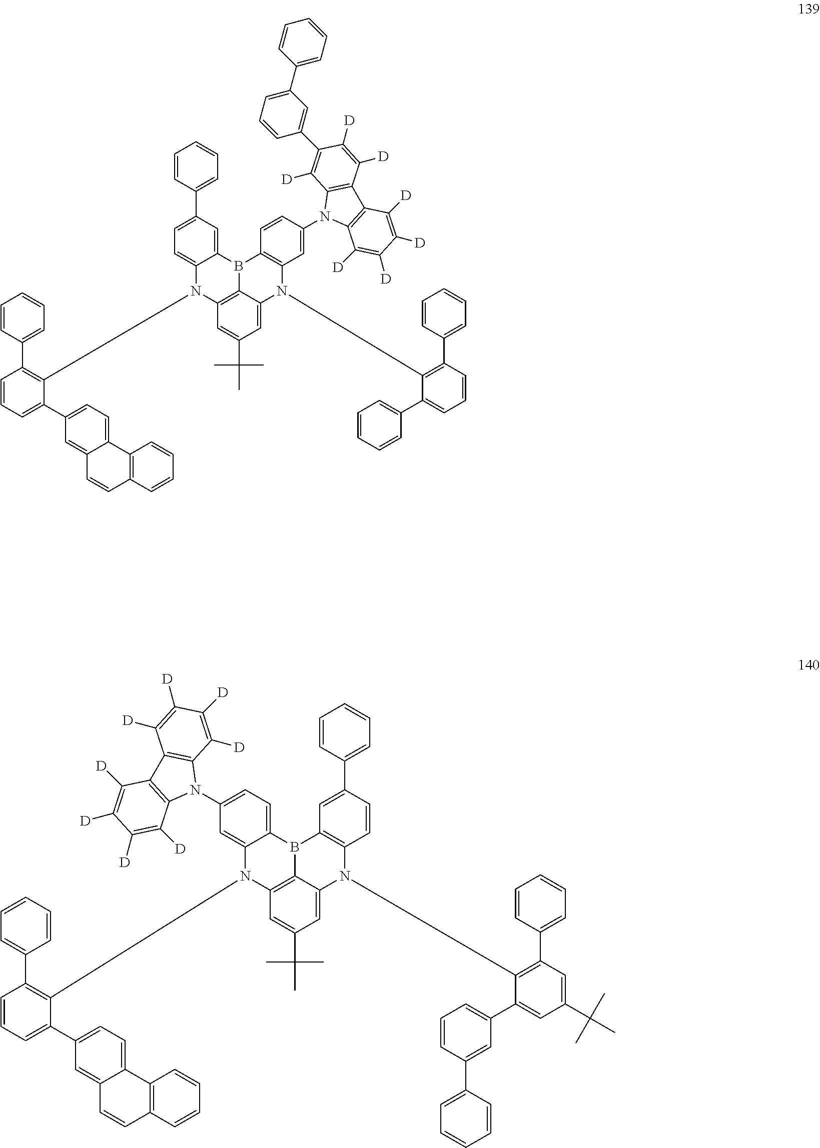 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1ccc2c(ccc3ccccc32)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccc3c(ccc4ccccc43)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1]

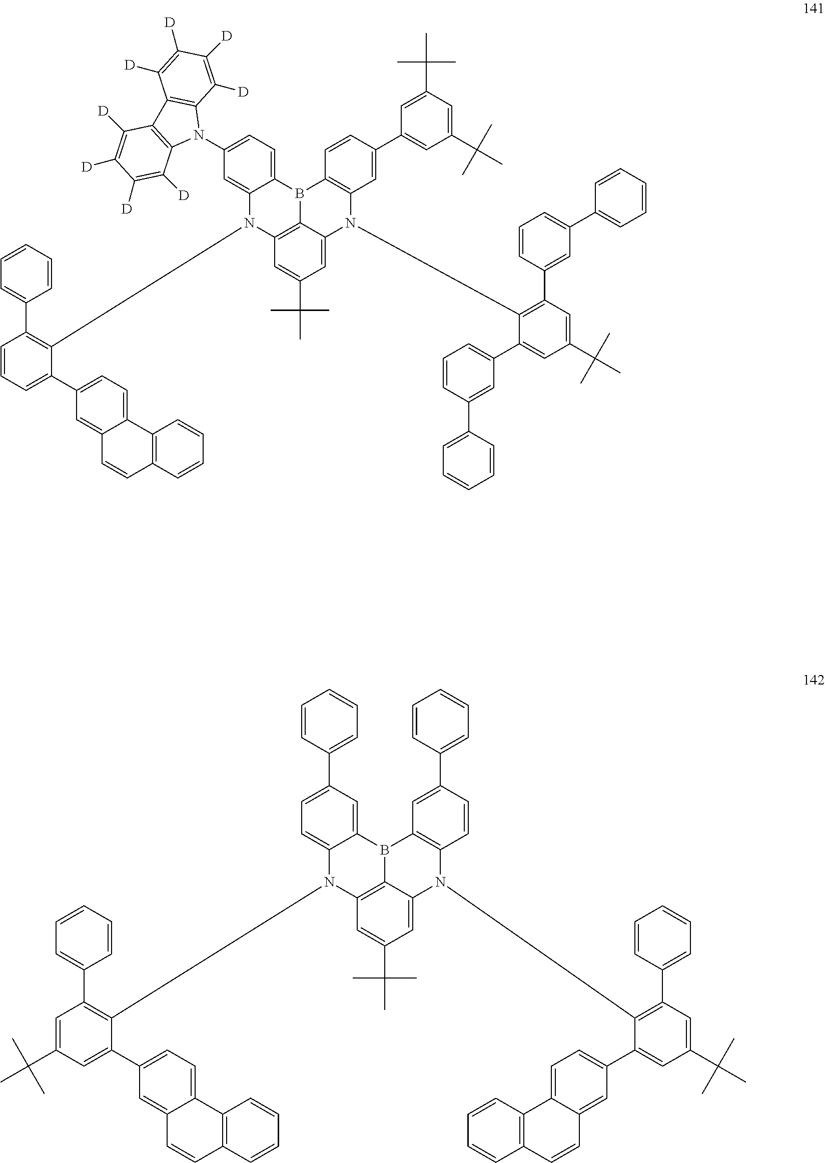 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc3c(ccc4ccccc43)c1)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1 ; CC(C)(C)c1cc(-c2ccccc2)c(N2c3ccc(-c4ccccc4)cc3B3c4cc(-c5ccccc5)ccc4N(c4c(-c5ccccc5)cc(C(C)(C)C)cc4-c4ccc5c(ccc6ccccc65)c4)c4cc(C(C)(C)C)cc2c43)c(-c2ccc3c(ccc4ccccc43)c2)c1]

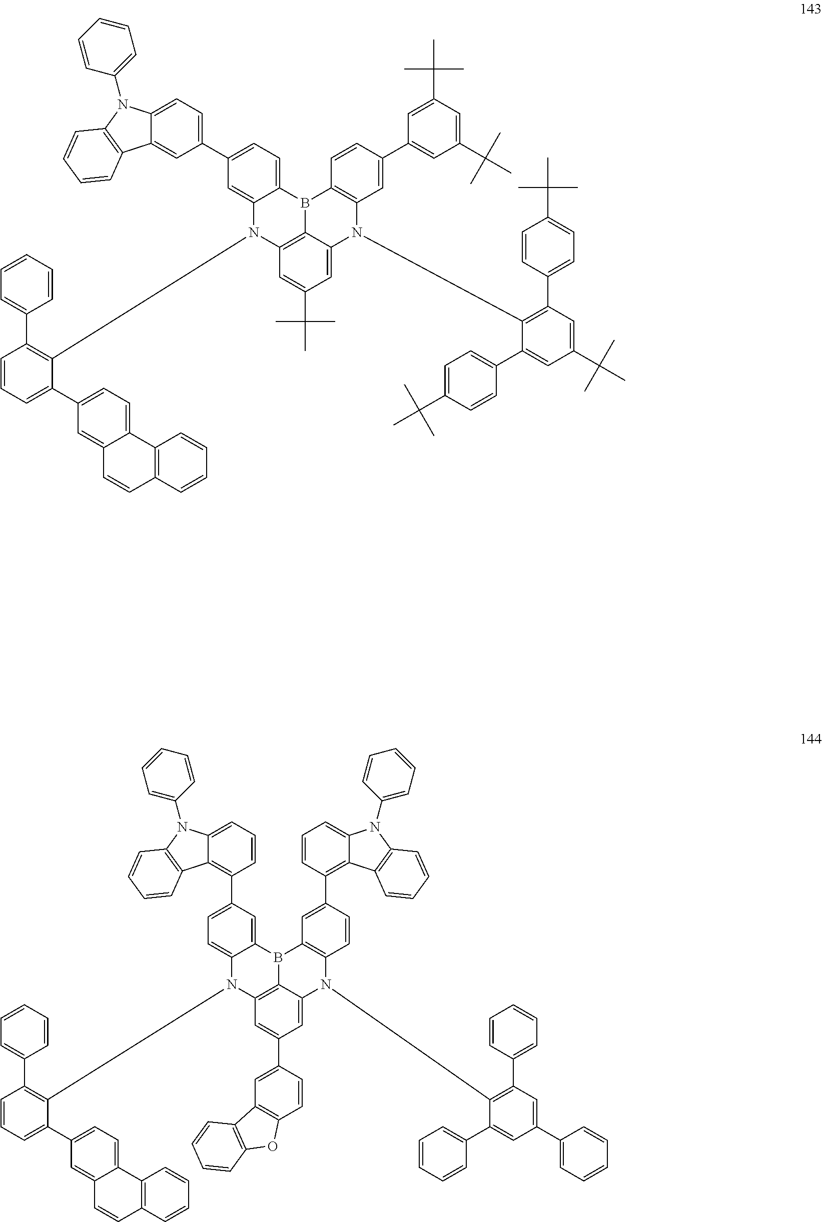 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-c5ccc6c(c5)c5ccccc5n6-c5ccccc5)cc4N(c4c(-c5ccccc5)cccc4-c4ccc5c(ccc6ccccc65)c4)c4cc(C(C)(C)C)cc2c43)cc1 ; c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cccc5-c5ccc6c(ccc7ccccc76)c5)c5cc(-c6ccc7oc8ccccc8c7c6)cc3c54)c(-c3ccccc3)c2)cc1]

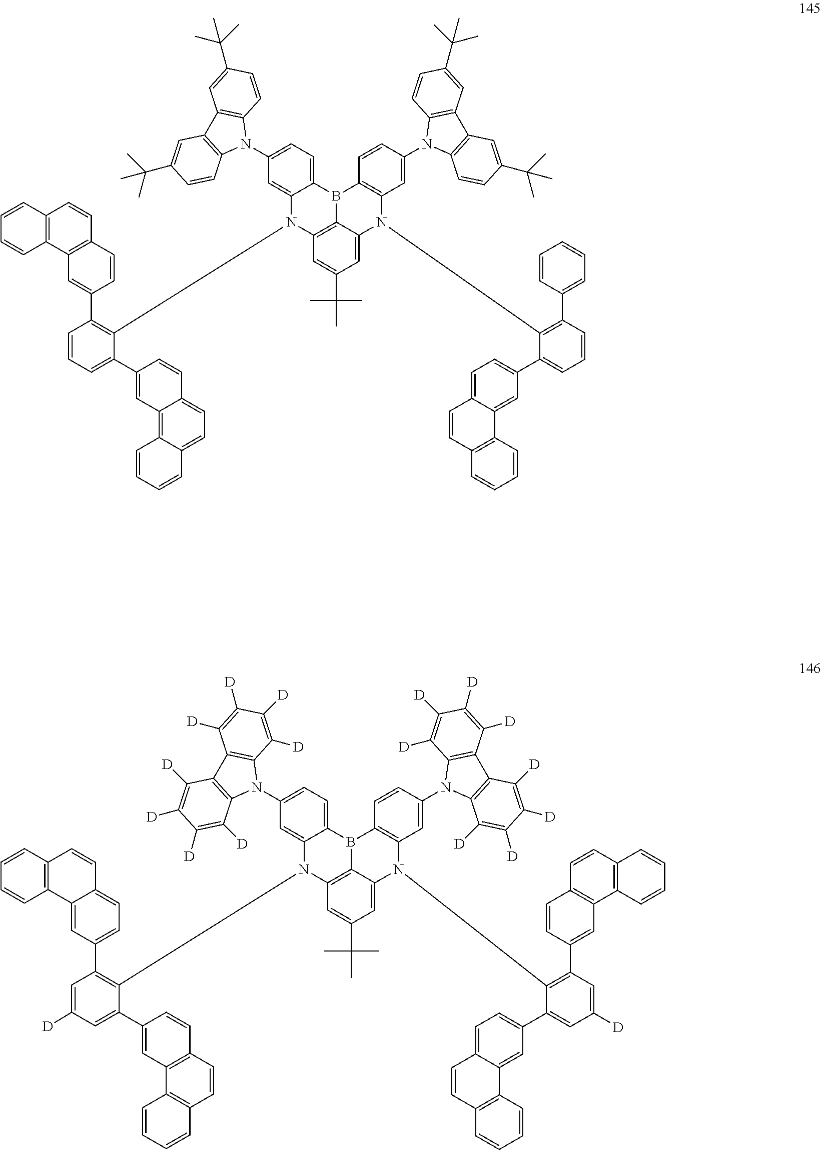

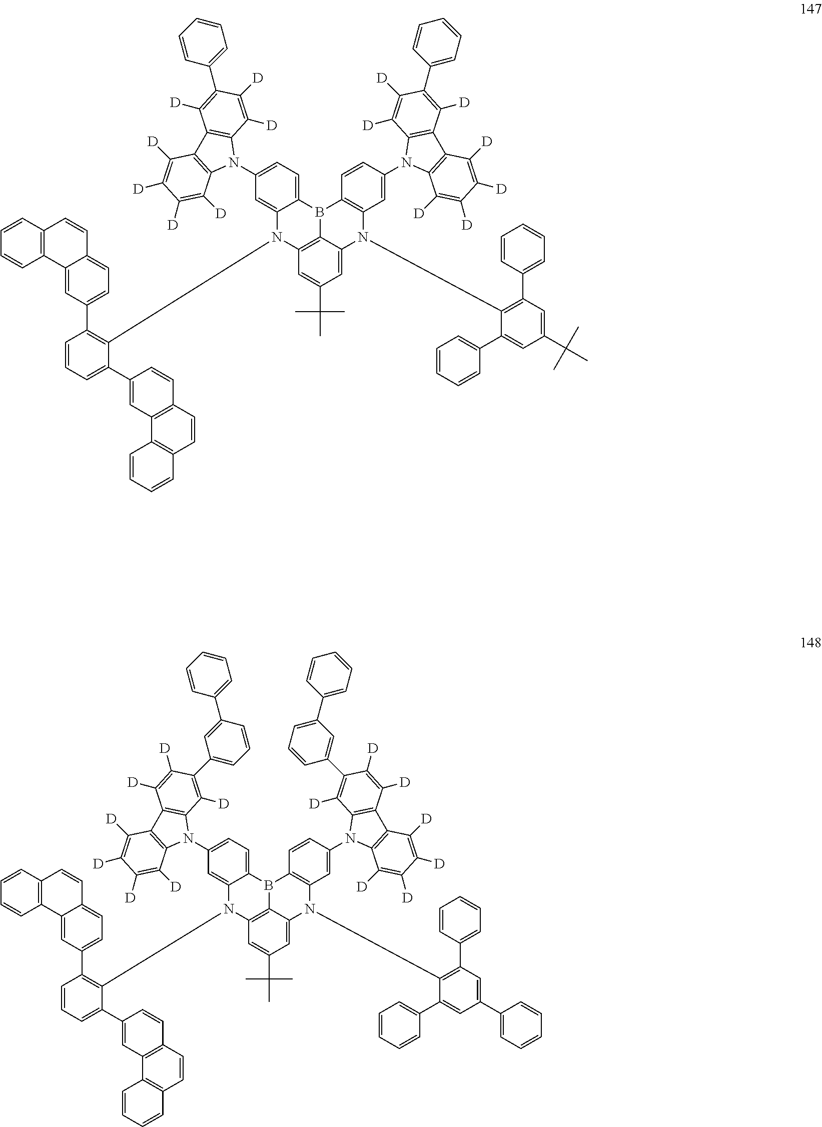

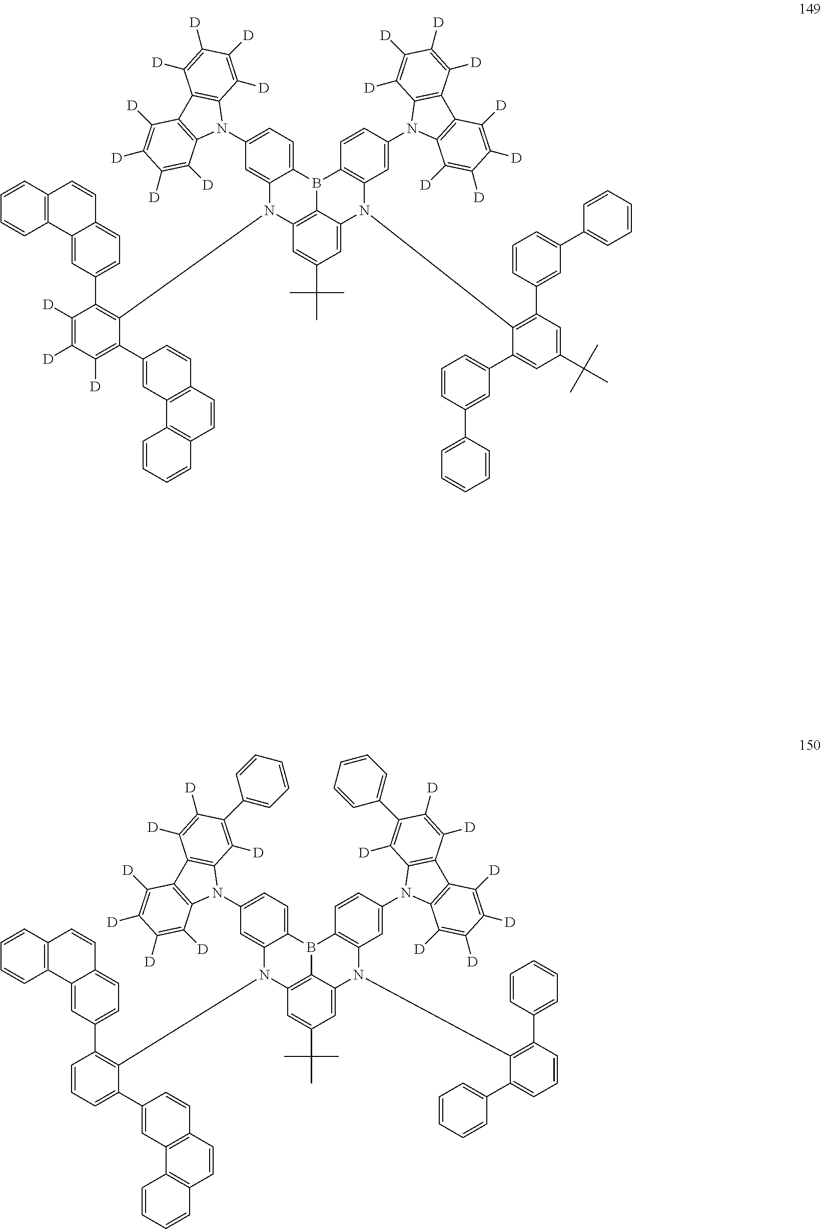

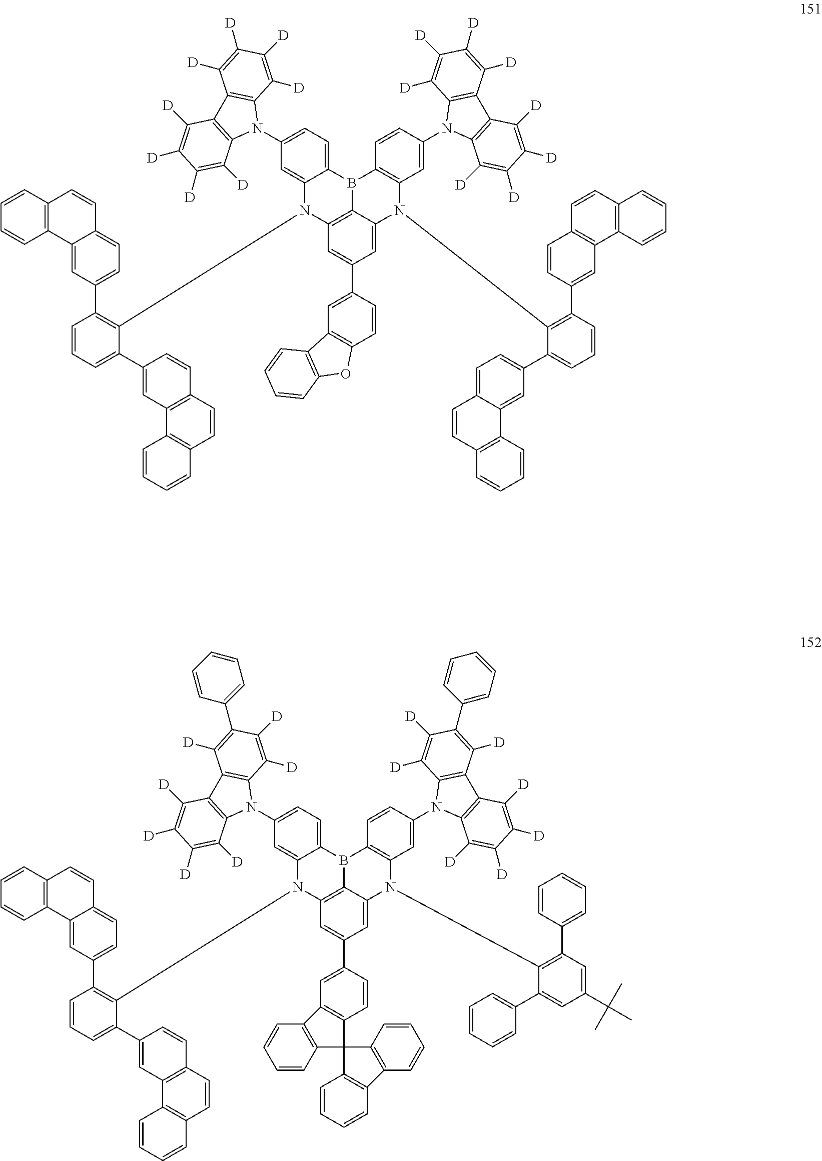

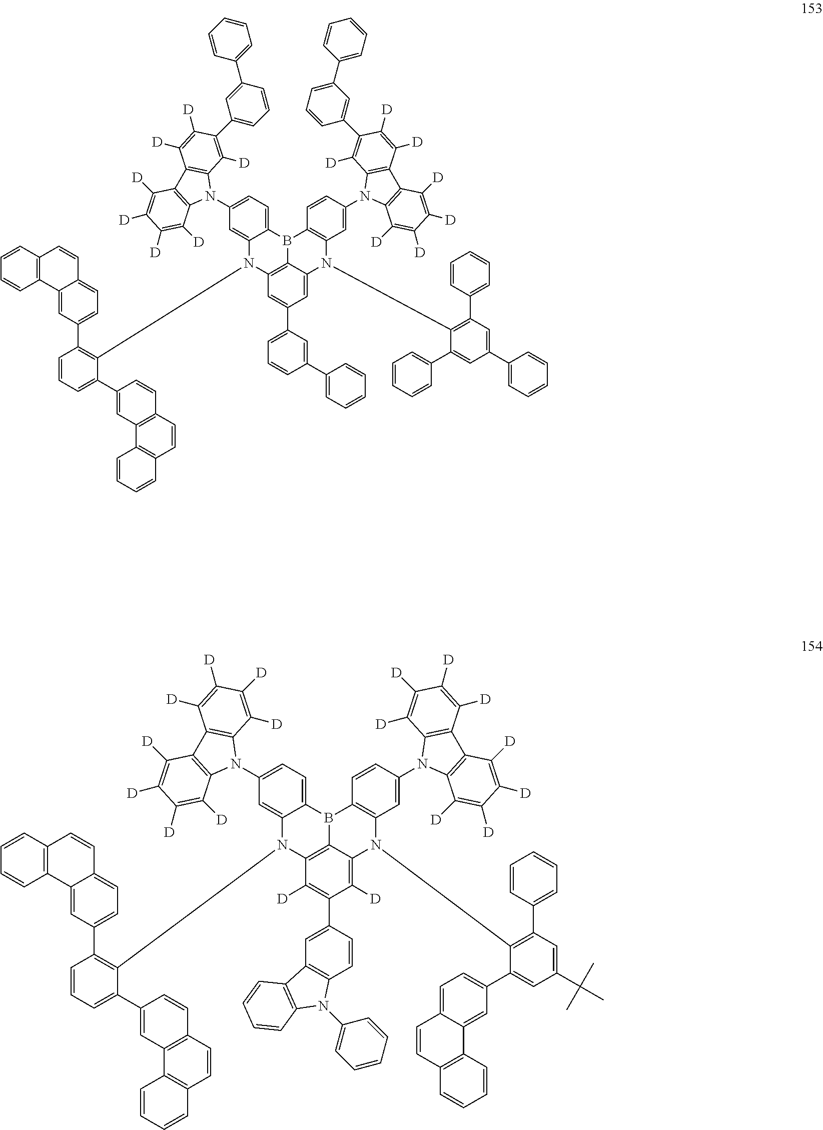

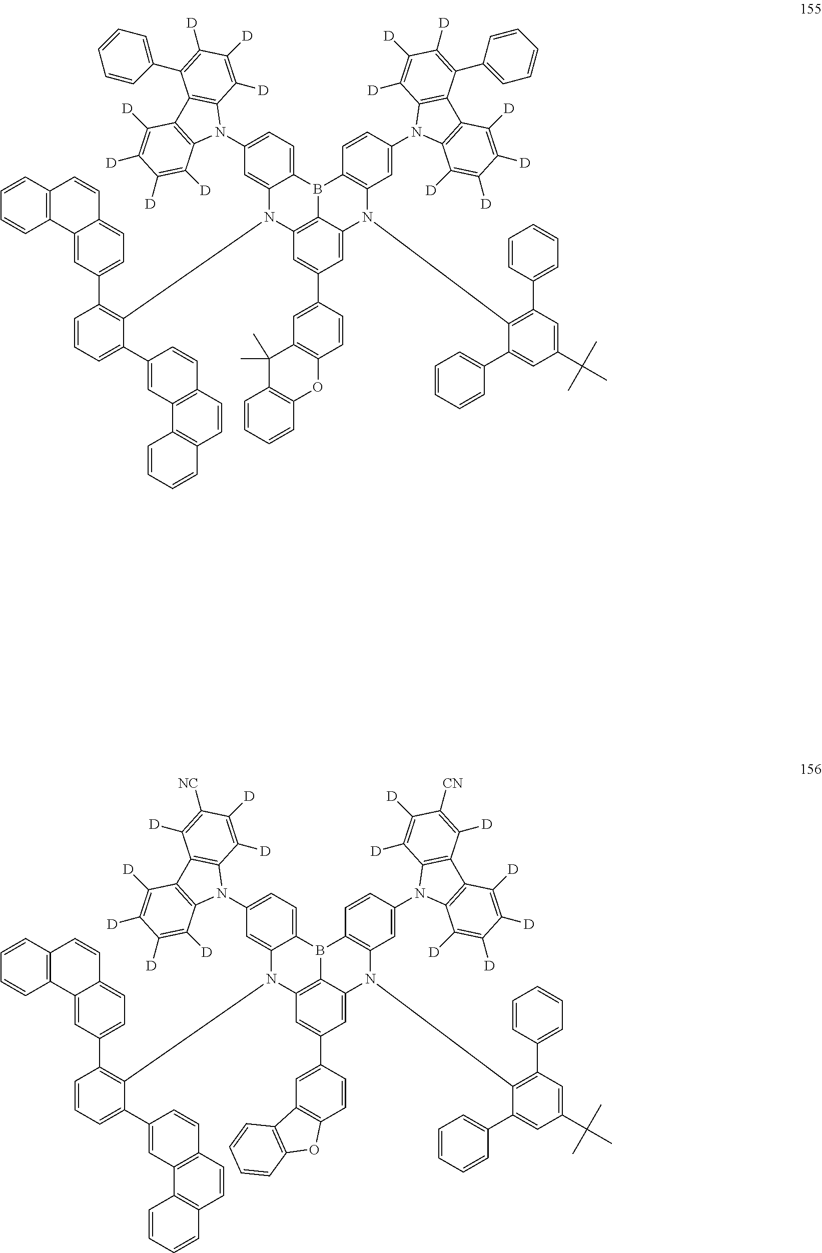

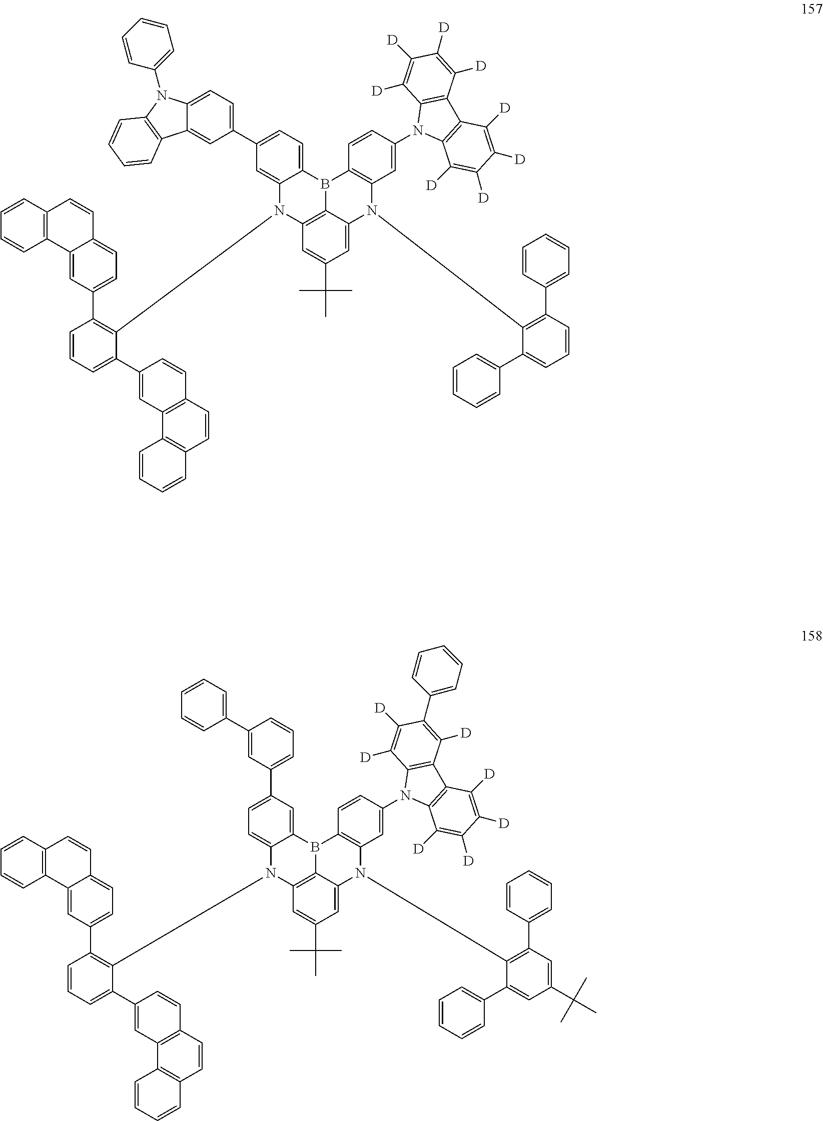 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccc3ccc4ccccc4c3c2)cccc1-c1ccc2ccc3ccccc3c2c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccc3ccc4ccccc4c3c2)cccc1-c1ccc2ccc3ccccc3c2c1]

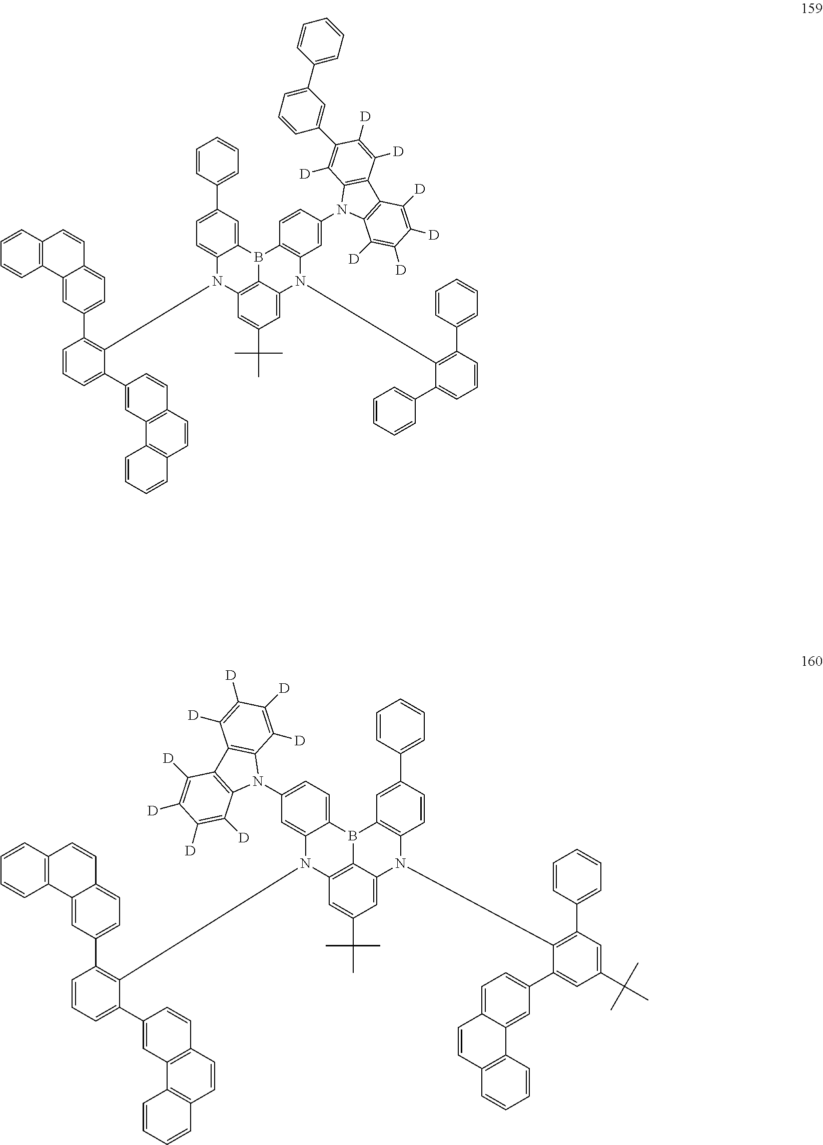 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccc3ccc4ccccc4c3c2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccc4ccc5ccccc5c4c3)cccc1-c1ccc3ccc4ccccc4c3c1)c1cc(C(C)(C)C)cc3c1B2c1cc(-c2ccccc2)ccc1N3c1c(-c2ccccc2)cc(C(C)(C)C)cc1-c1ccc2ccc3ccccc3c2c1]

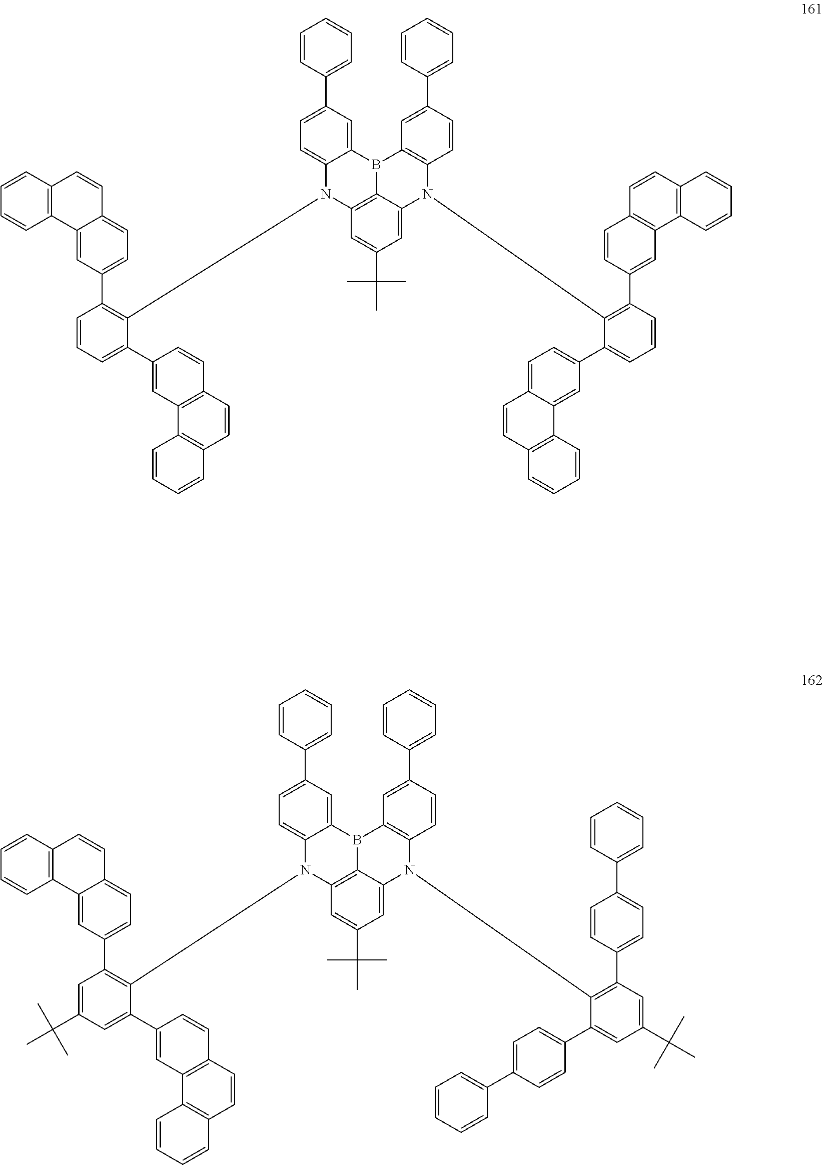 [SMILES: CC(C)(C)c1cc2c3c(c1)N(c1c(-c4ccc5ccc6ccccc6c5c4)cccc1-c1ccc4ccc5ccccc5c4c1)c1ccc(-c4ccccc4)cc1B3c1cc(-c3ccccc3)ccc1N2c1c(-c2ccc3ccc4ccccc4c3c2)cccc1-c1ccc2ccc3ccccc3c2c1 ; CC(C)(C)c1cc(-c2ccc(-c3ccccc3)cc2)c(N2c3ccc(-c4ccccc4)cc3B3c4cc(-c5ccccc5)ccc4N(c4c(-c5ccc6ccc7ccccc7c6c5)cc(C(C)(C)C)cc4-c4ccc5ccc6ccccc6c5c4)c4cc(C(C)(C)C)cc2c43)c(-c2ccc(-c3ccccc3)cc2)c1]

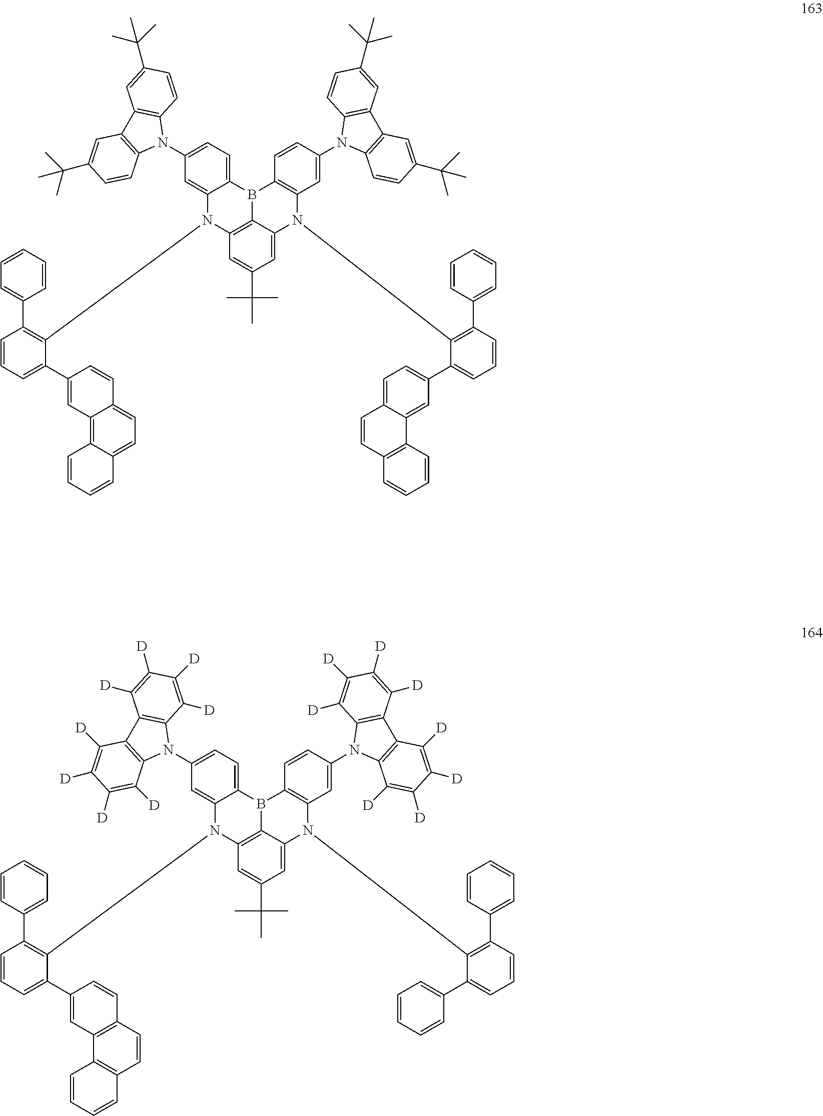 [SMILES: CC(C)(C)c1cc2c3c(c1)N(c1c(-c4ccccc4)cccc1-c1ccc4ccc5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc2ccc3ccccc3c2c1]

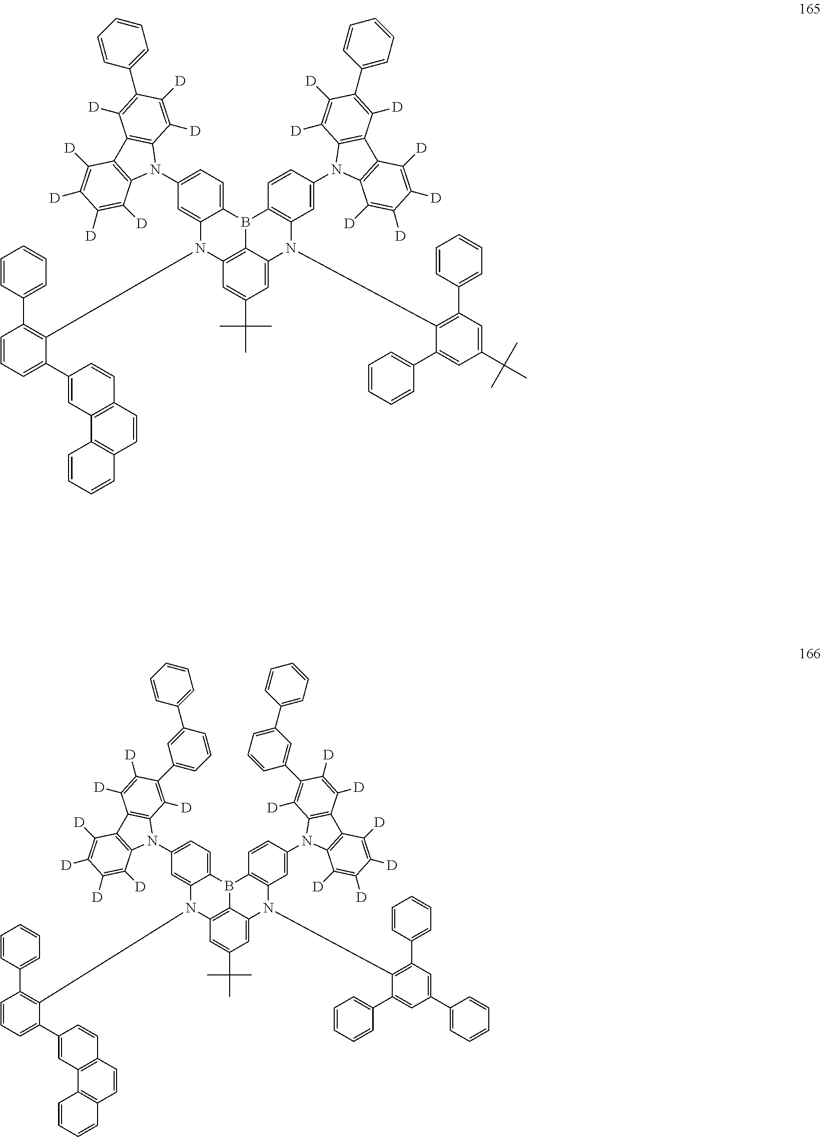

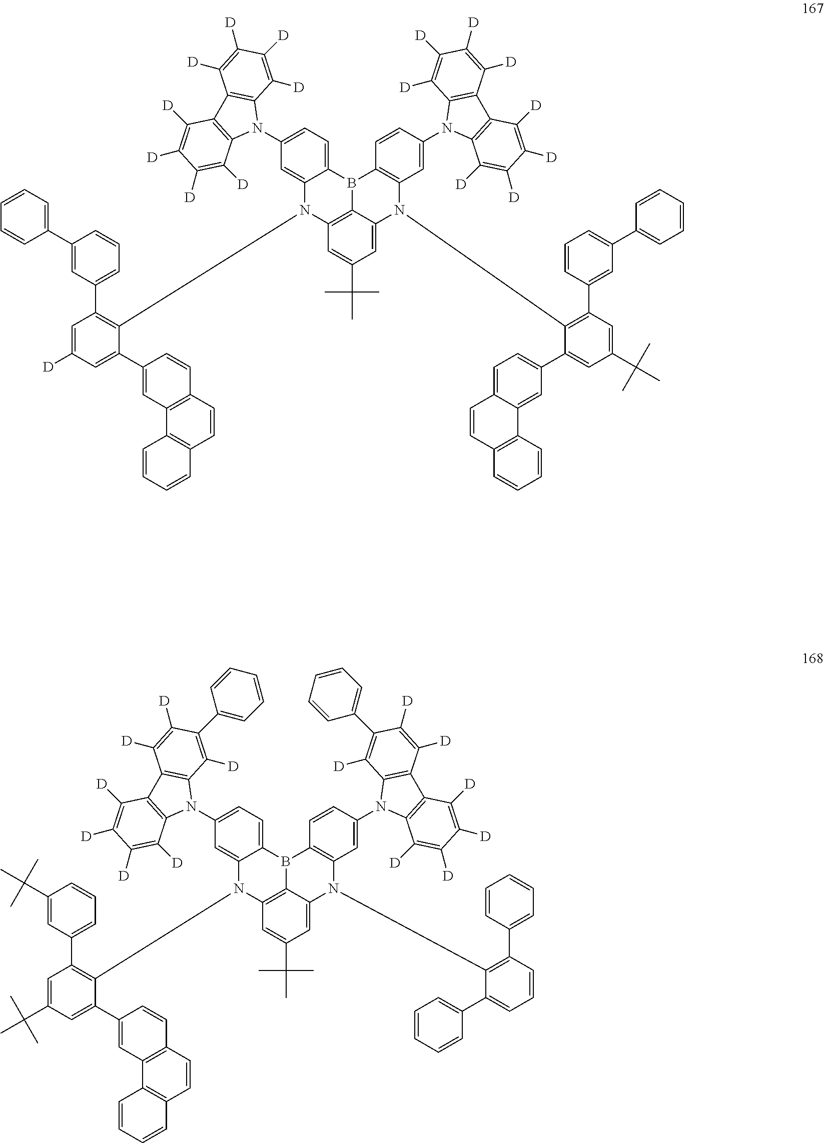

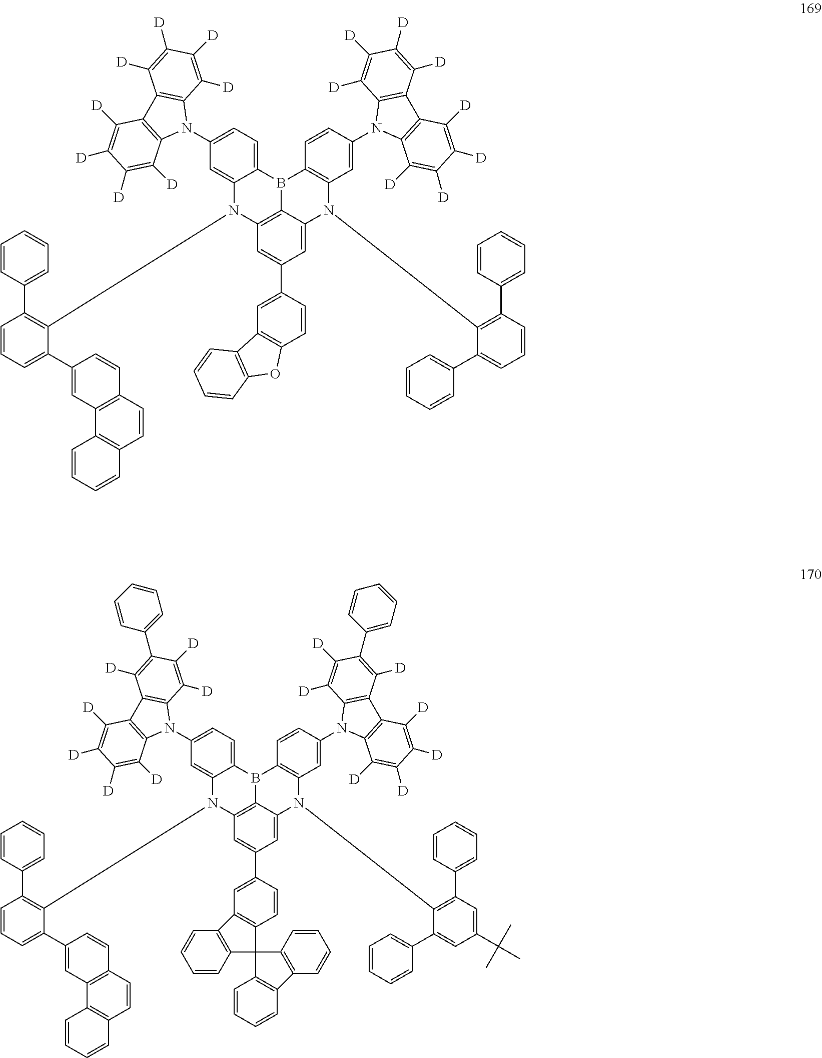

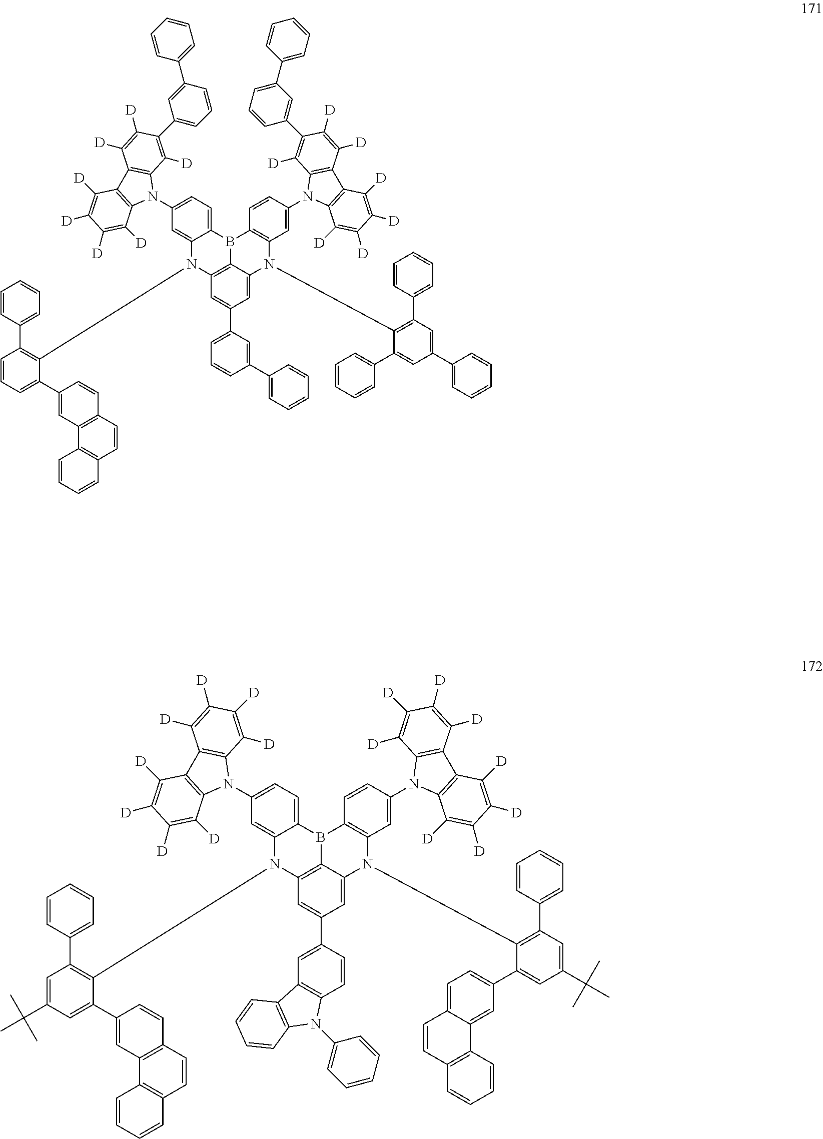

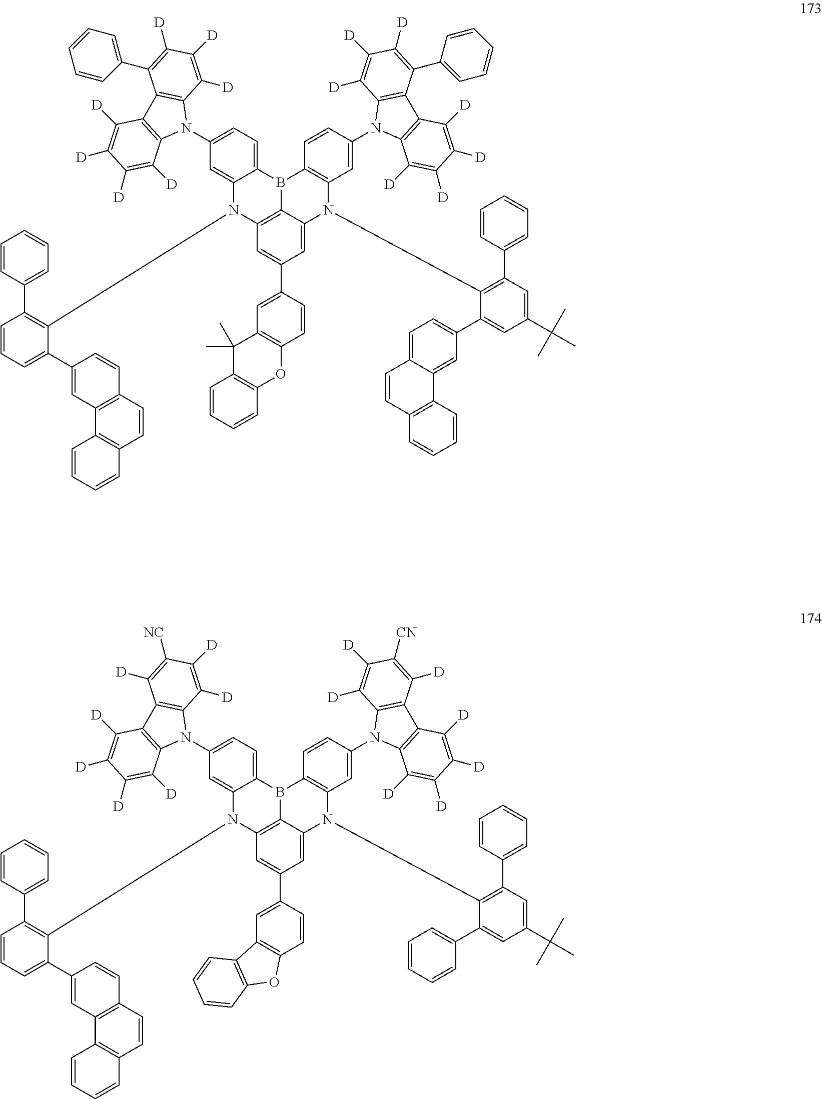

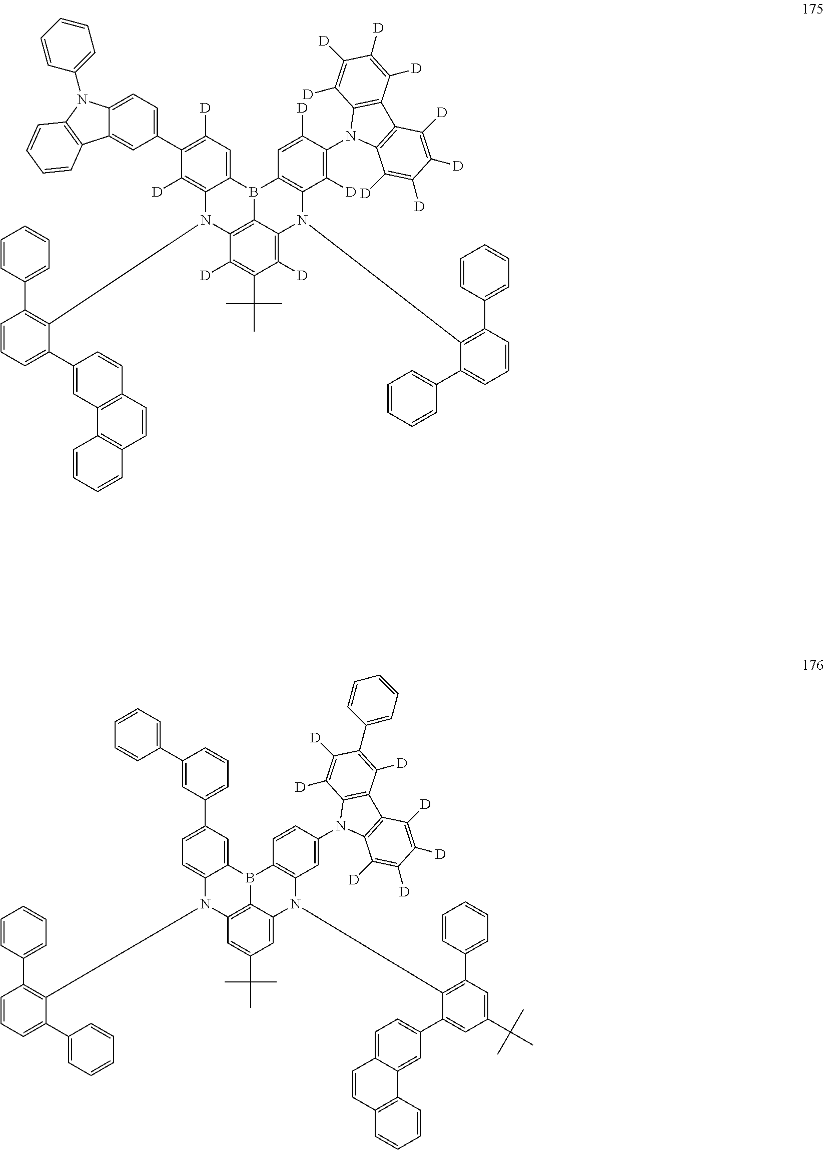 [SMILES: [2H]c1cc2c(c([2H])c1-c1ccc3c(c1)c1ccccc1n3-c1ccccc1)N(c1c(-c3ccccc3)cccc1-c1ccc3ccc4ccccc4c3c1)c1c([2H])c(C(C)(C)C)c([2H])c3c1B2c1cc([2H])c(-n2c4c([2H])c([2H])c([2H])c([2H])c4c4c([2H])c([2H])c([2H])c([2H])c42)c([2H])c1N3c1c(-c2ccccc2)cccc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccc3ccc4ccccc4c3c1)c1cc(C(C)(C)C)cc3c1B2c1cc(-c2cccc(-c4ccccc4)c2)ccc1N3c1c(-c2ccccc2)cccc1-c1ccccc1]

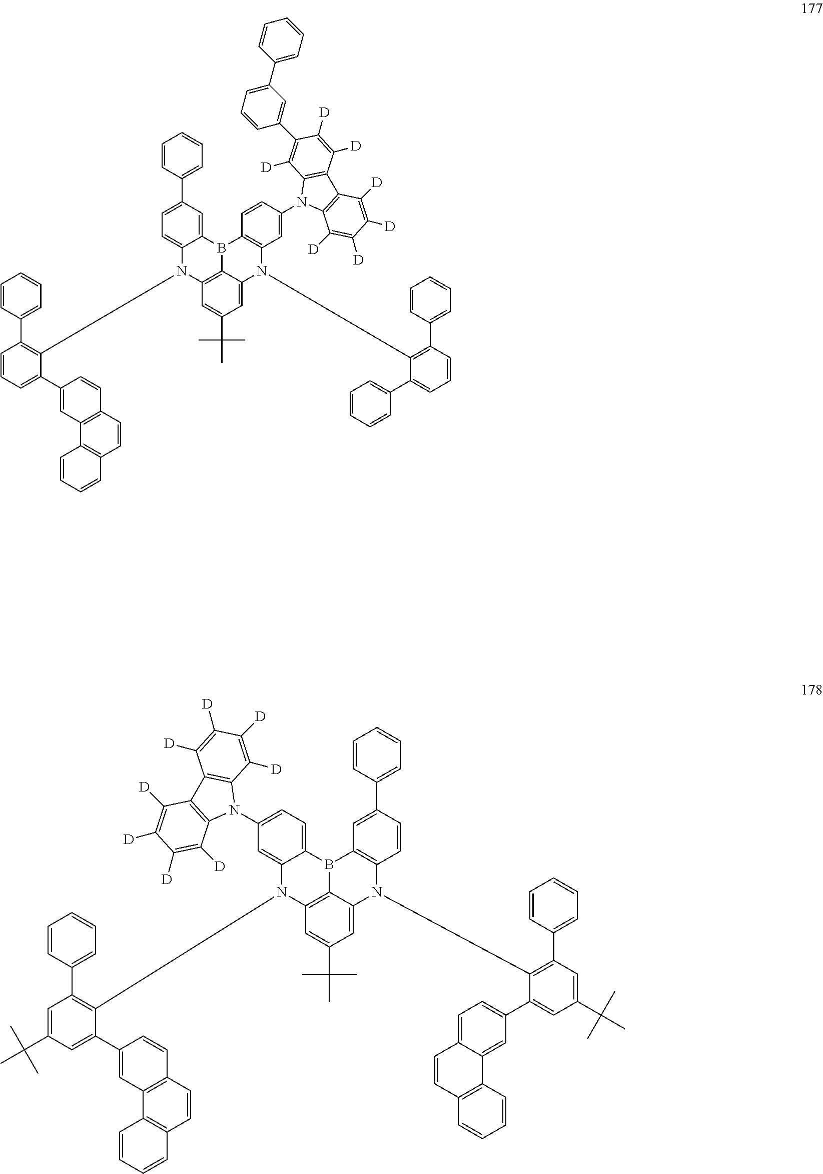 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccc3ccc4ccccc4c3c1)c1cc(C(C)(C)C)cc3c1B2c1cc(-c2ccccc2)ccc1N3c1c(-c2ccccc2)cc(C(C)(C)C)cc1-c1ccc2ccc3ccccc3c2c1]

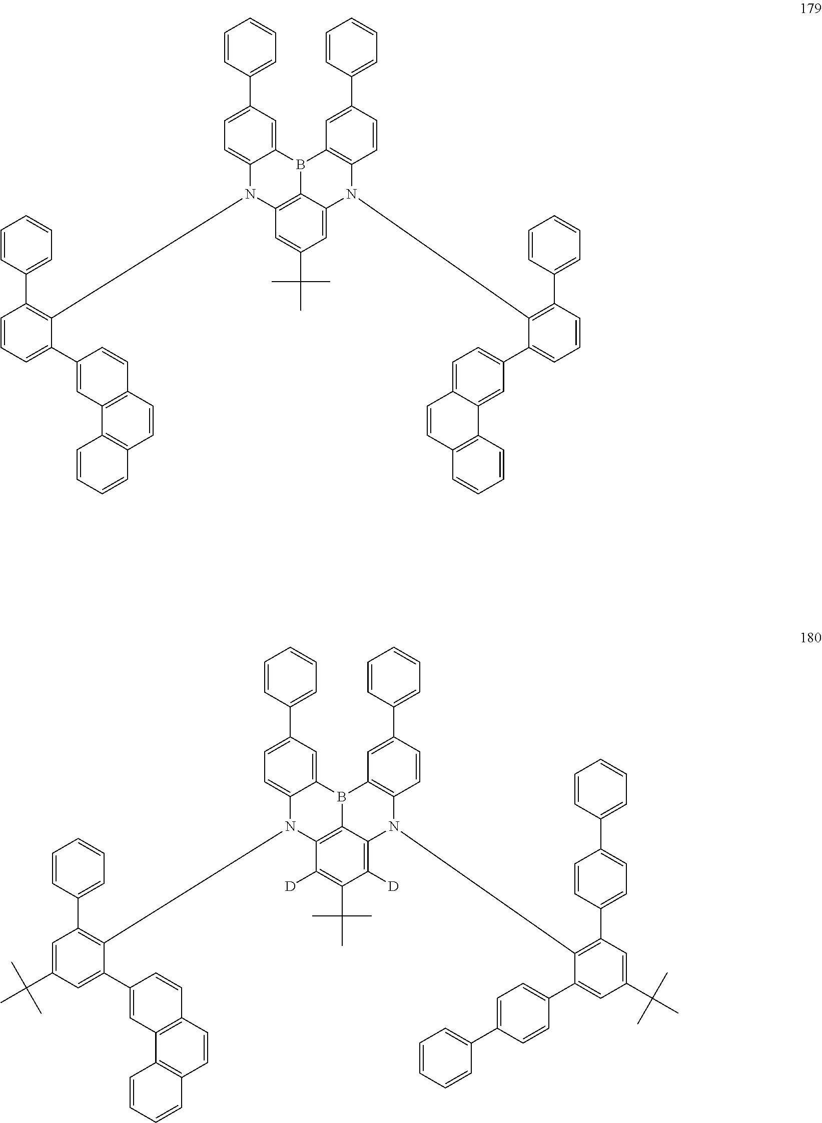 [SMILES: CC(C)(C)c1cc2c3c(c1)N(c1c(-c4ccccc4)cccc1-c1ccc4ccc5ccccc5c4c1)c1ccc(-c4ccccc4)cc1B3c1cc(-c3ccccc3)ccc1N2c1c(-c2ccccc2)cccc1-c1ccc2ccc3ccccc3c2c1 ; [2H]c1c2c3c(c([2H])c1C(C)(C)C)N(c1c(-c4ccccc4)cc(C(C)(C)C)cc1-c1ccc4ccc5ccccc5c4c1)c1ccc(-c4ccccc4)cc1B3c1cc(-c3ccccc3)ccc1N2c1c(-c2ccc(-c3ccccc3)cc2)cc(C(C)(C)C)cc1-c1ccc(-c2ccccc2)cc1]

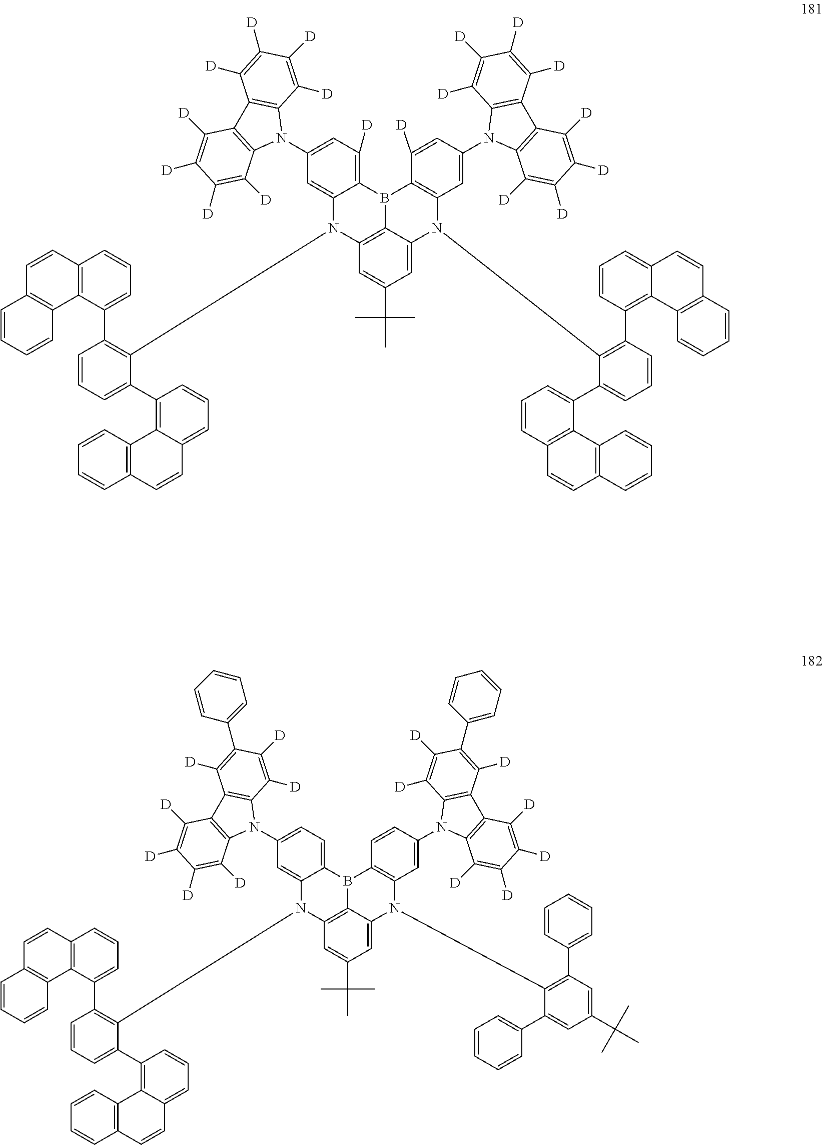

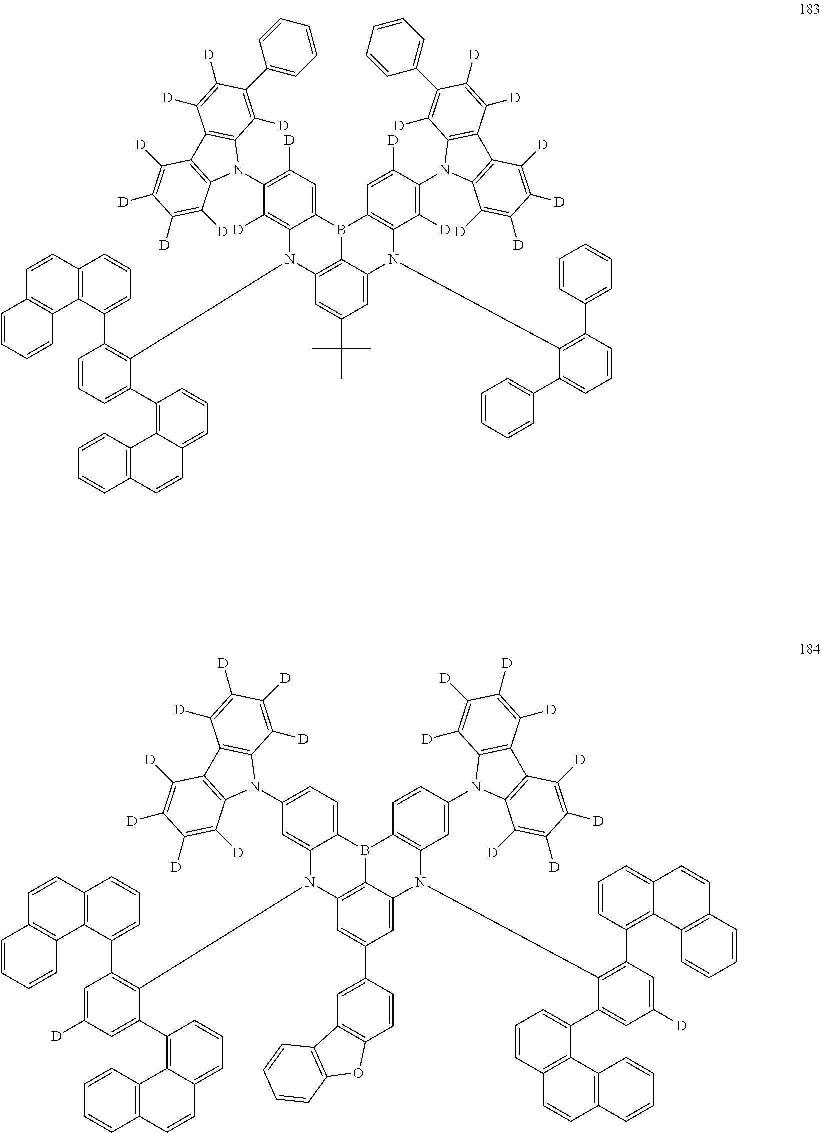

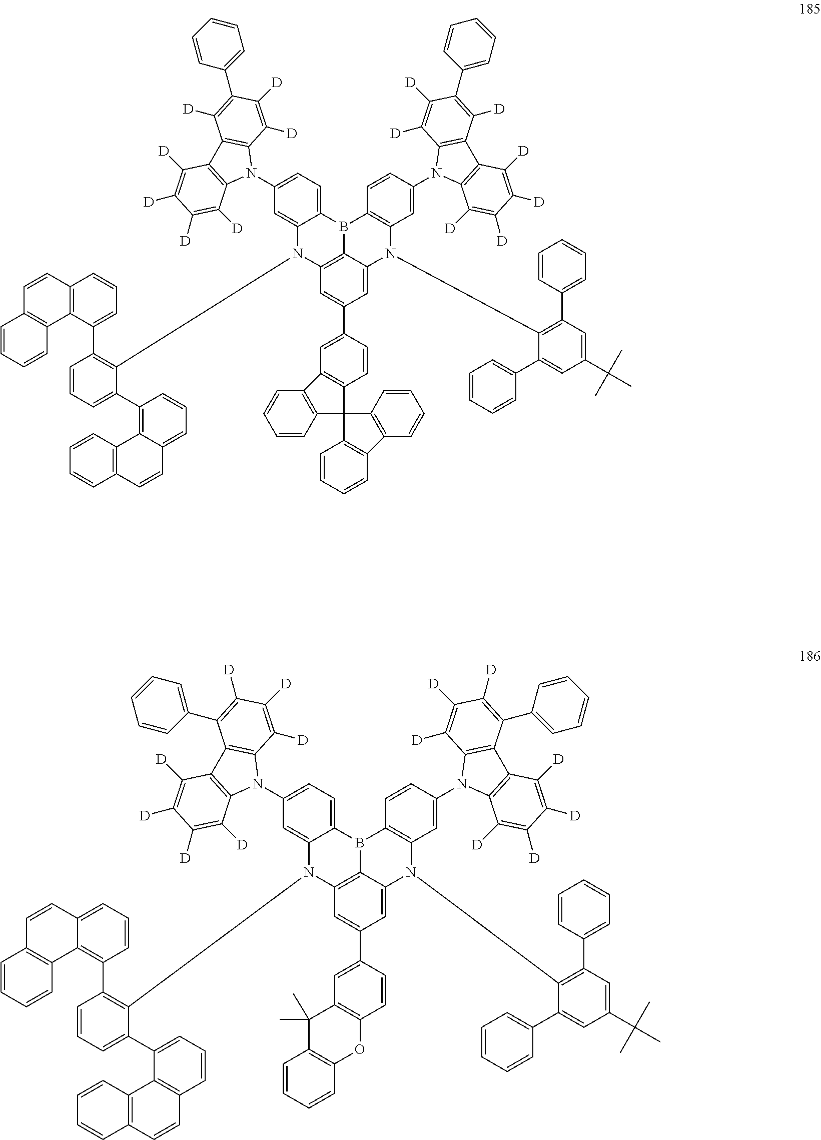

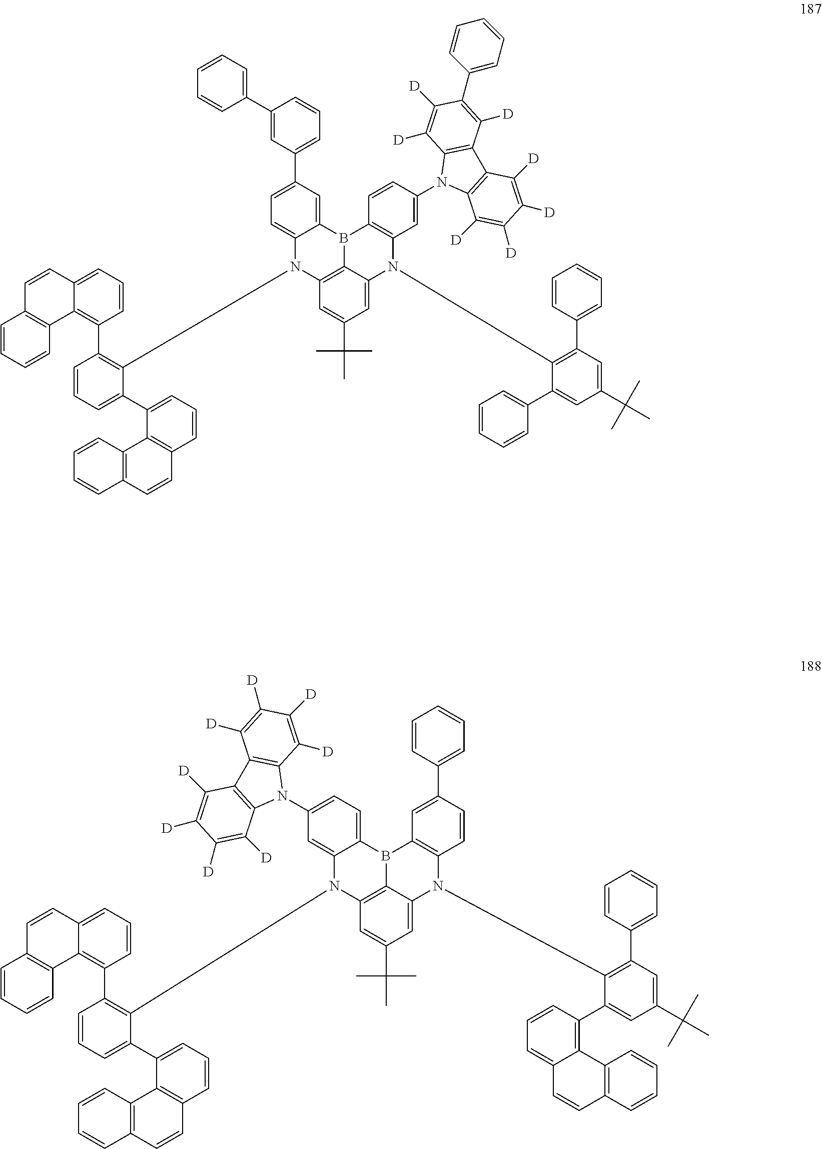 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2cccc3ccc4ccccc4c23)cccc1-c1cccc2ccc3ccccc3c12 ; [2H]c1c([2H])c([2H])c2c(c1[2H])c1c([2H])c([2H])c([2H])c([2H])c1n2-c1ccc2c(c1)N(c1c(-c3cccc4ccc5ccccc5c34)cccc1-c1cccc3ccc4ccccc4c13)c1cc(C(C)(C)C)cc3c1B2c1cc(-c2ccccc2)ccc1N3c1c(-c2ccccc2)cc(C(C)(C)C)cc1-c1cccc2ccc3ccccc3c12]

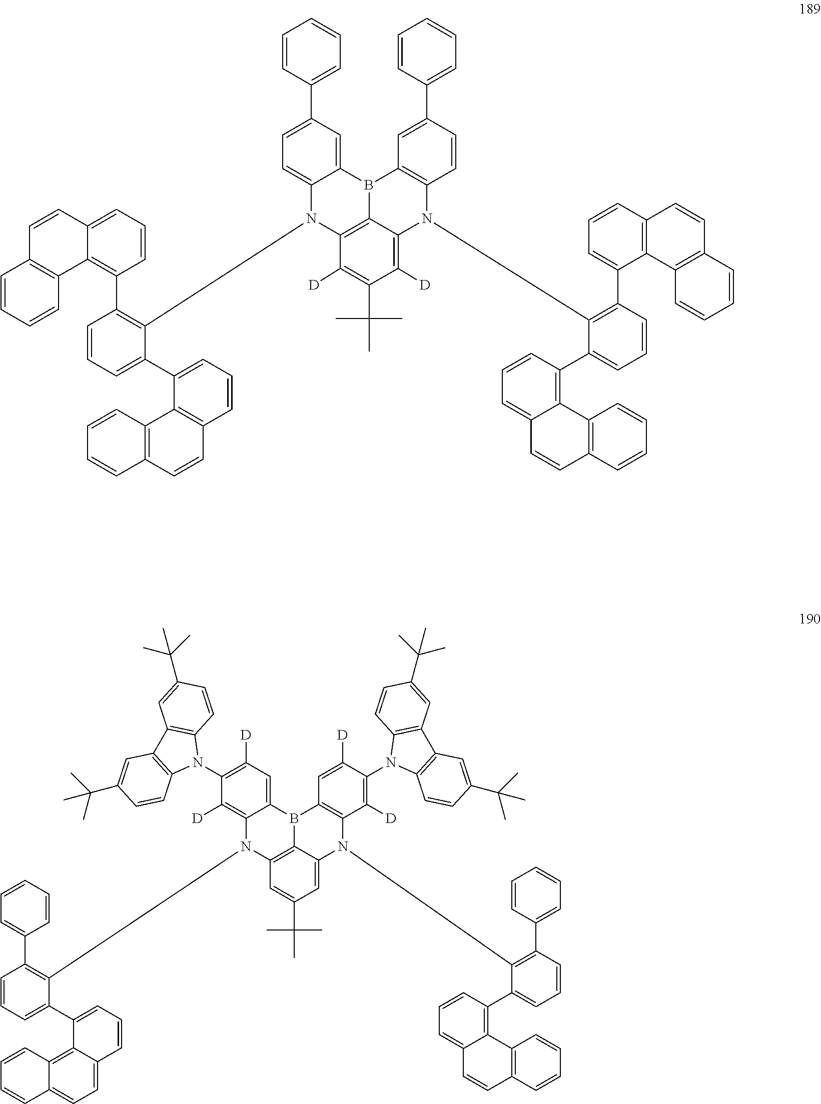 [SMILES: [2H]c1c2c3c(c([2H])c1C(C)(C)C)N(c1c(-c4cccc5ccc6ccccc6c45)cccc1-c1cccc4ccc5ccccc5c14)c1ccc(-c4ccccc4)cc1B3c1cc(-c3ccccc3)ccc1N2c1c(-c2cccc3ccc4ccccc4c23)cccc1-c1cccc2ccc3ccccc3c12 ; [2H]c1cc2c(c([2H])c1-n1c3ccc(C(C)(C)C)cc3c3cc(C(C)(C)C)ccc31)N(c1c(-c3ccccc3)cccc1-c1cccc3ccc4ccccc4c13)c1cc(C(C)(C)C)cc3c1B2c1cc([2H])c(-n2c4ccc(C(C)(C)C)cc4c4cc(C(C)(C)C)ccc42)c([2H])c1N3c1c(-c2ccccc2)cccc1-c1cccc2ccc3ccccc3c12]

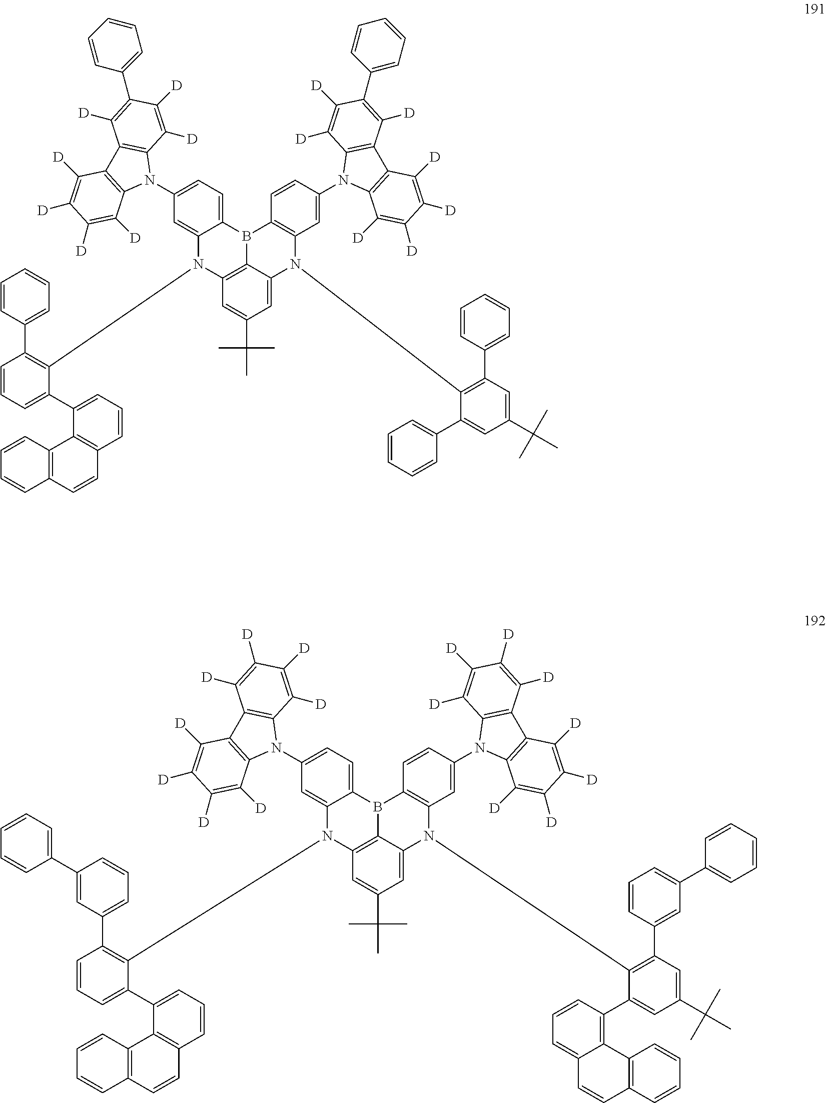

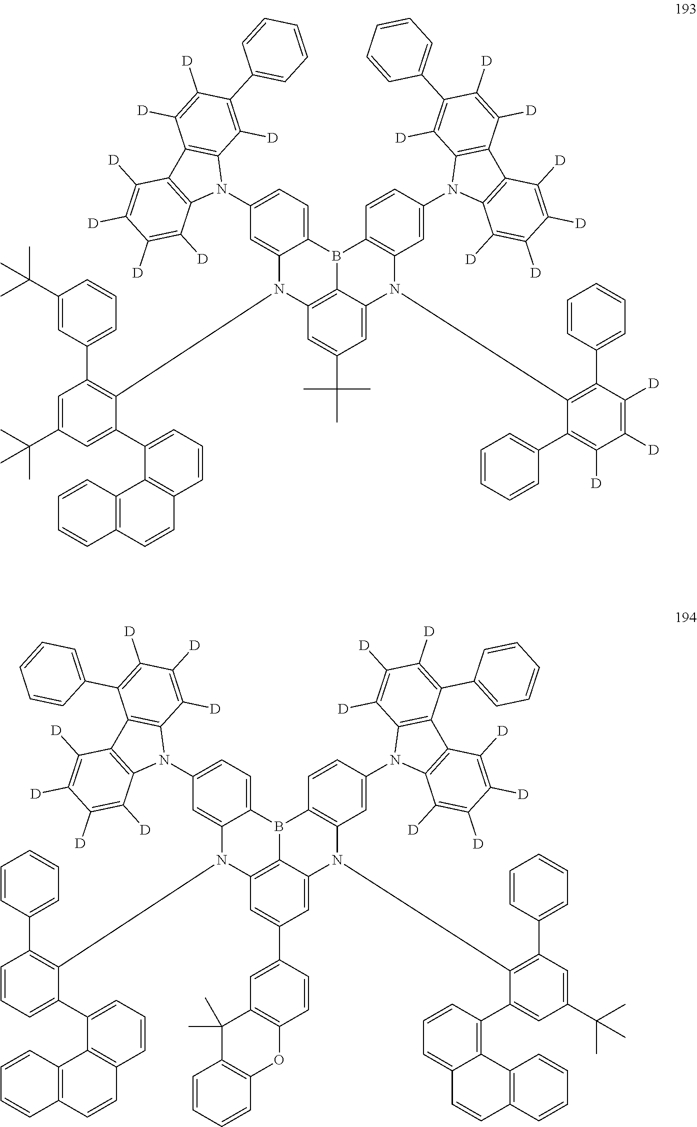

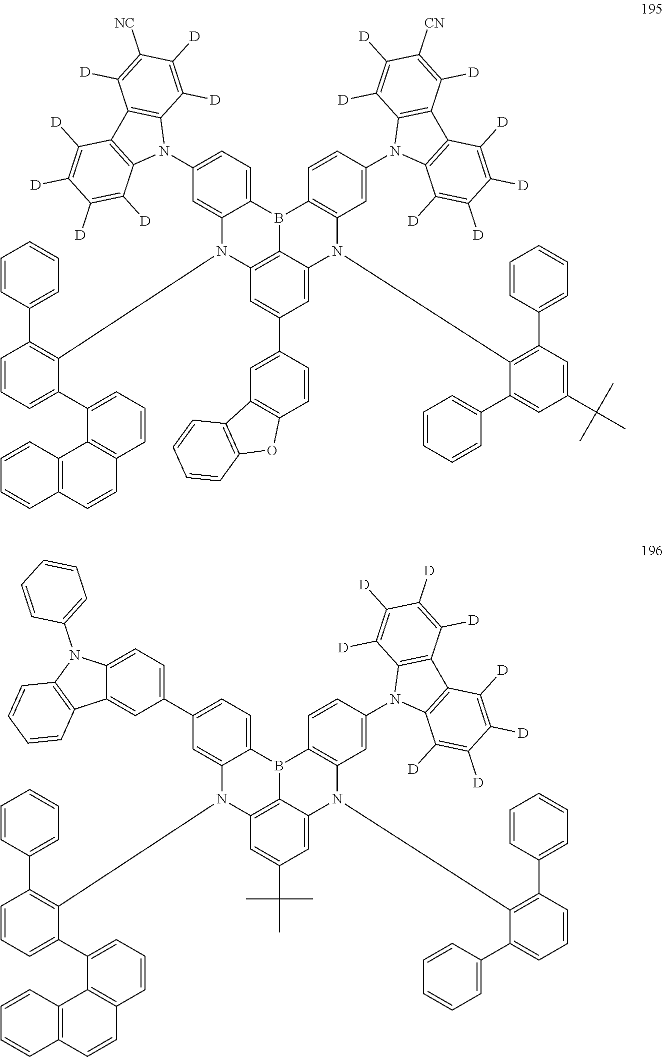 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(C(C)(C)C)cc1-c1ccccc1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cccc1-c1cccc2ccc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccccc2)cccc1-c1cccc2ccc3ccccc3c12]

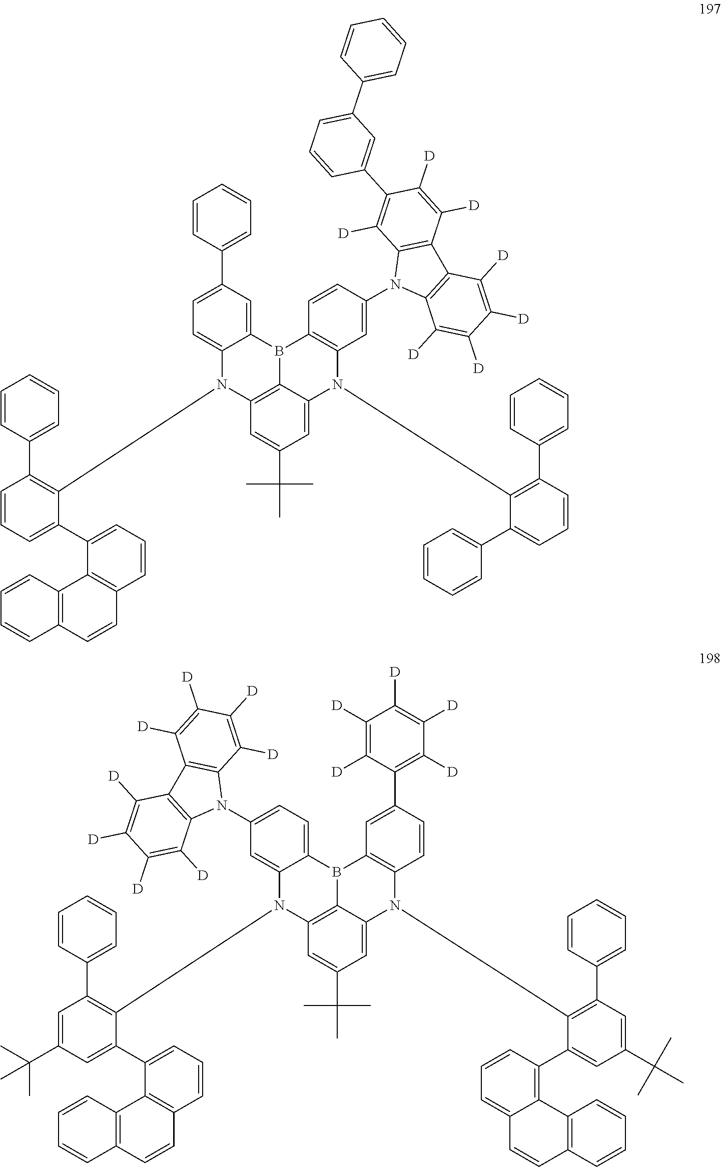 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1cccc2ccc3ccccc3c12 ; [2H]c1c([2H])c([2H])c(-c2ccc3c(c2)B2c4ccc(-n5c6c([2H])c([2H])c([2H])c([2H])c6c6c([2H])c([2H])c([2H])c([2H])c65)cc4N(c4c(-c5ccccc5)cc(C(C)(C)C)cc4-c4cccc5ccc6ccccc6c45)c4cc(C(C)(C)C)cc(c42)N3c2c(-c3ccccc3)cc(C(C)(C)C)cc2-c2cccc3ccc4ccccc4c23)c([2H])c1[2H]]

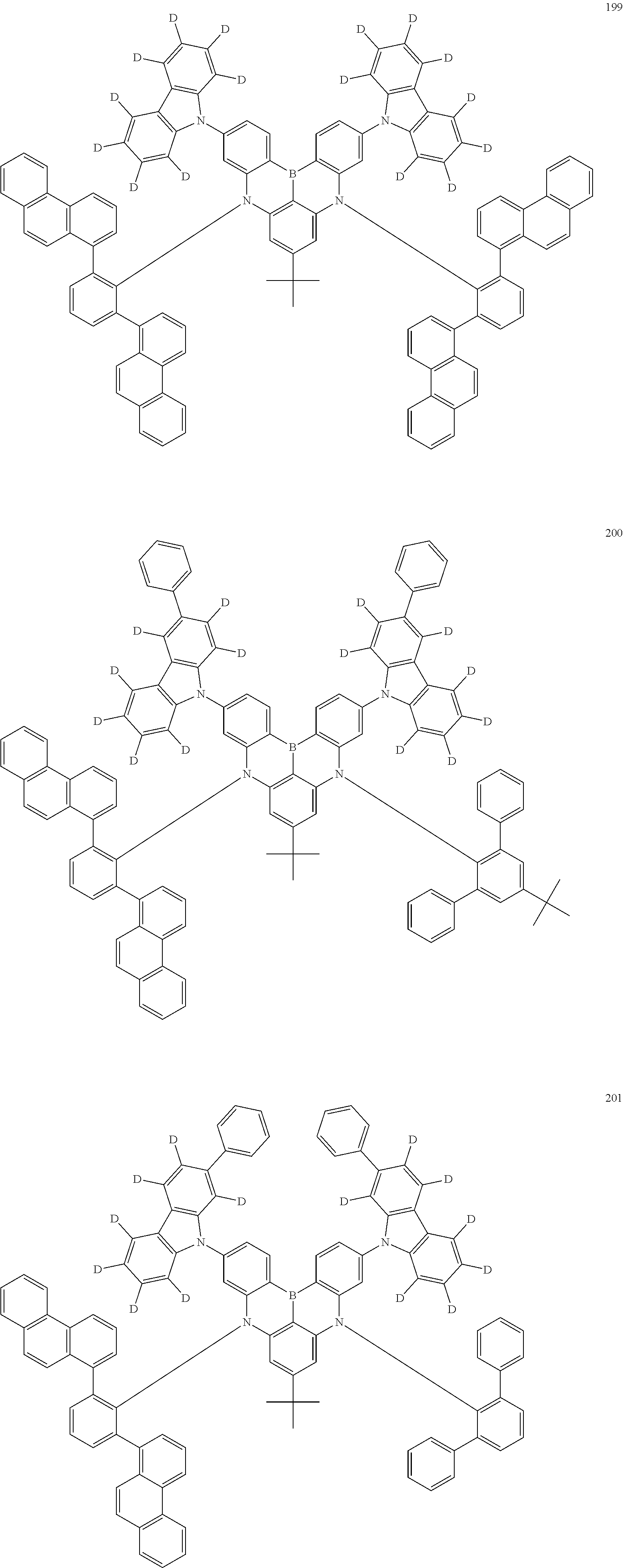

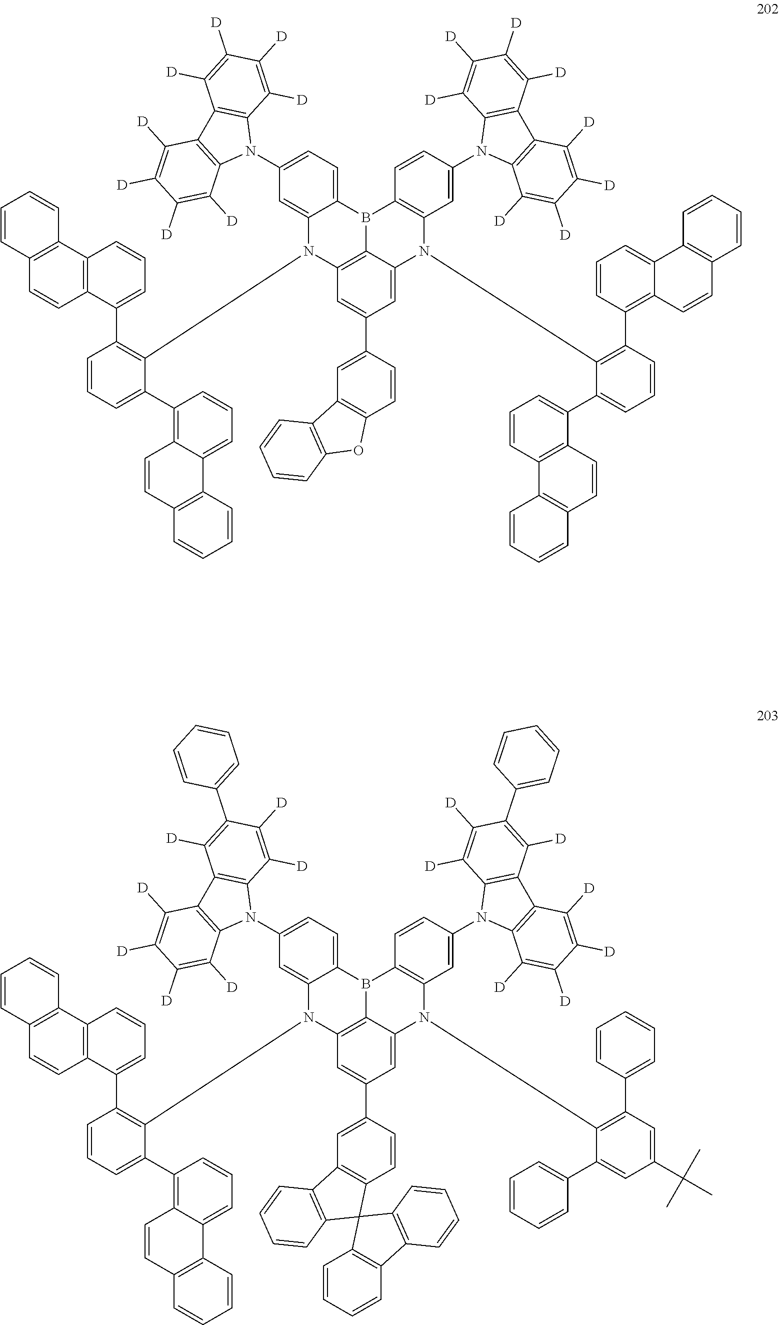

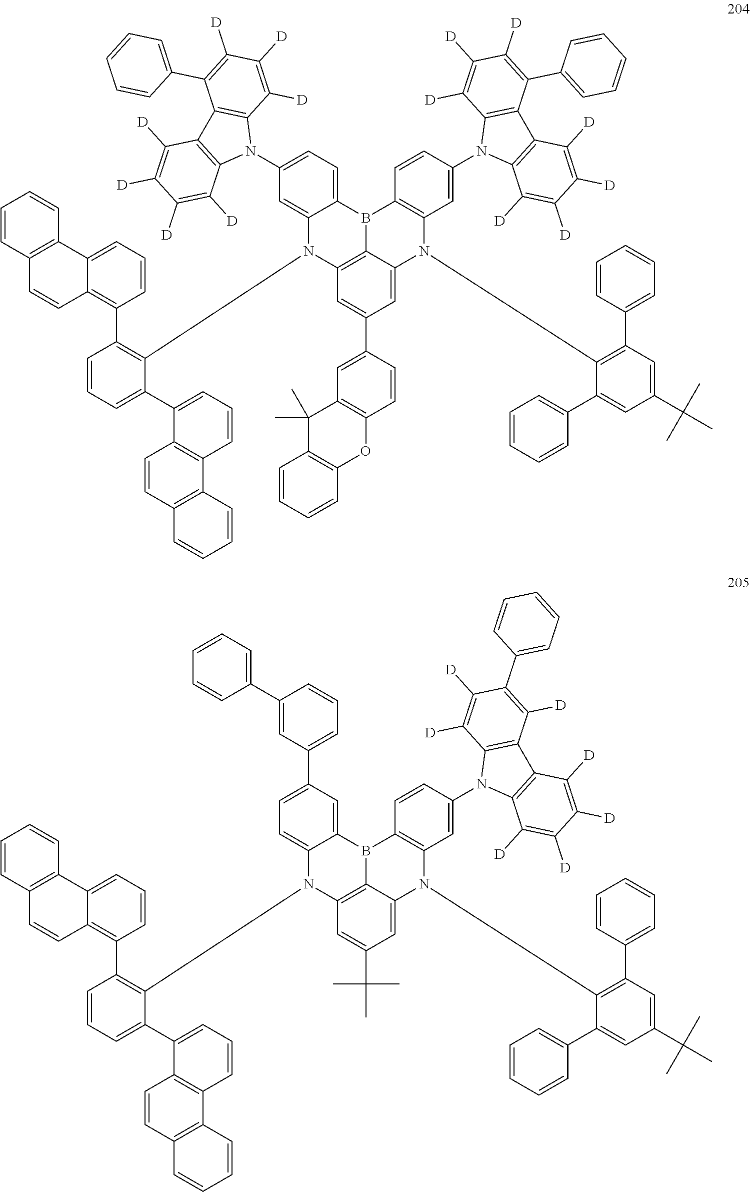

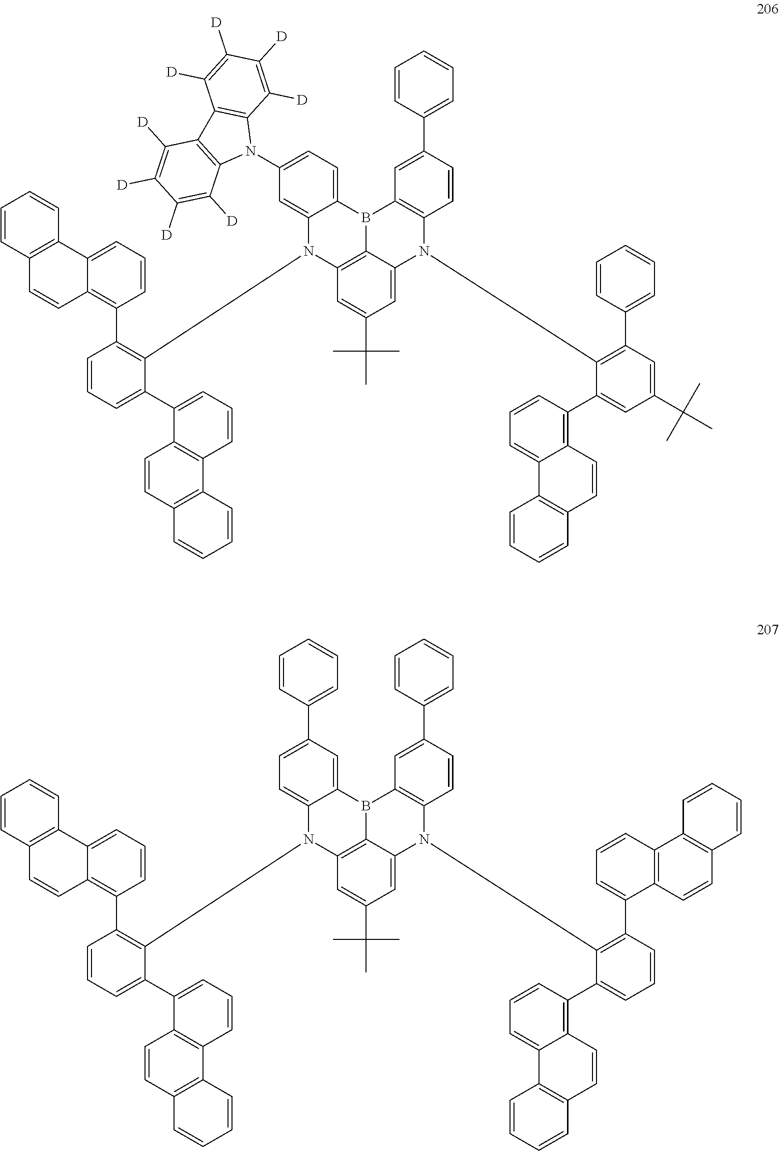 [SMILES: [2H]c1c([2H])c([2H])c2c(c1[2H])c1c([2H])c([2H])c([2H])c([2H])c1n2-c1ccc2c(c1)N(c1c(-c3cccc4c3ccc3ccccc34)cccc1-c1cccc3c1ccc1ccccc13)c1cc(C(C)(C)C)cc3c1B2c1cc(-c2ccccc2)ccc1N3c1c(-c2ccccc2)cc(C(C)(C)C)cc1-c1cccc2c1ccc1ccccc12 ; CC(C)(C)c1cc2c3c(c1)N(c1c(-c4cccc5c4ccc4ccccc45)cccc1-c1cccc4c1ccc1ccccc14)c1ccc(-c4ccccc4)cc1B3c1cc(-c3ccccc3)ccc1N2c1c(-c2cccc3c2ccc2ccccc23)cccc1-c1cccc2c1ccc1ccccc12]

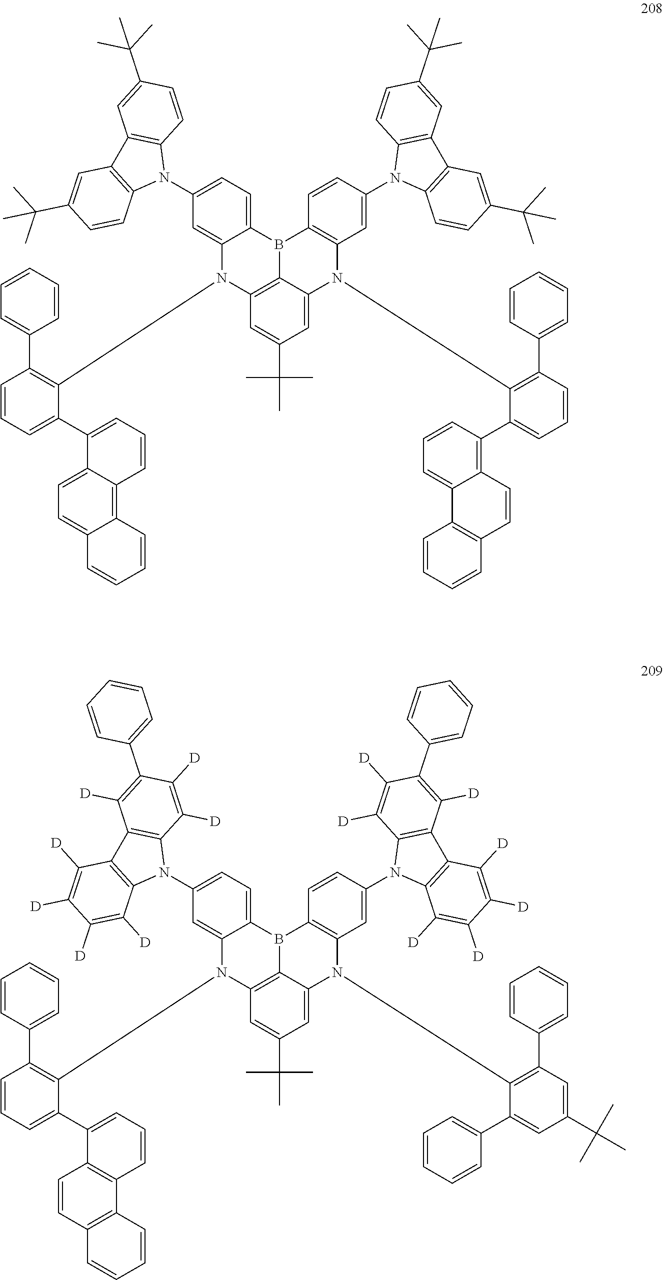 [SMILES: CC(C)(C)c1cc2c3c(c1)N(c1c(-c4ccccc4)cccc1-c1cccc4c1ccc1ccccc14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1cccc2c1ccc1ccccc12 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c(-c5ccccc5)c([2H])c([2H])c42)cc1N3c1c(-c2ccccc2)cccc1-c1cccc2c1ccc1ccccc12]

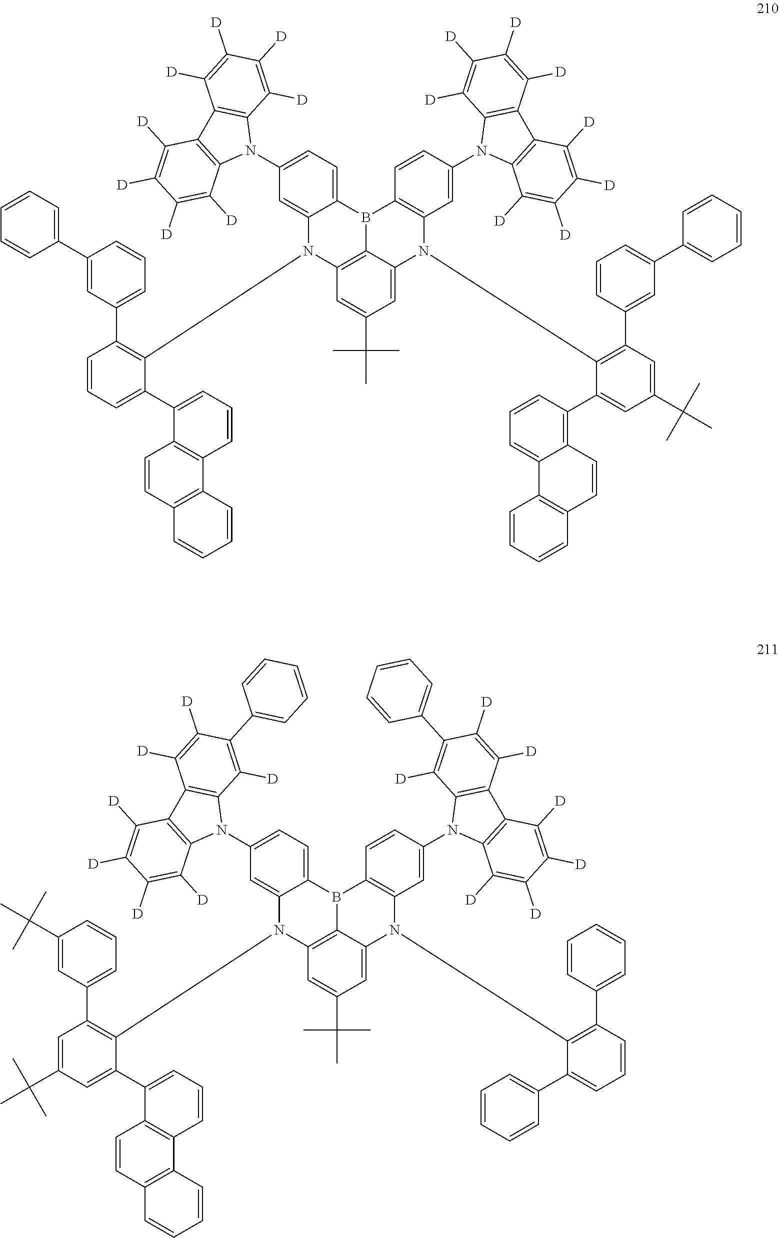

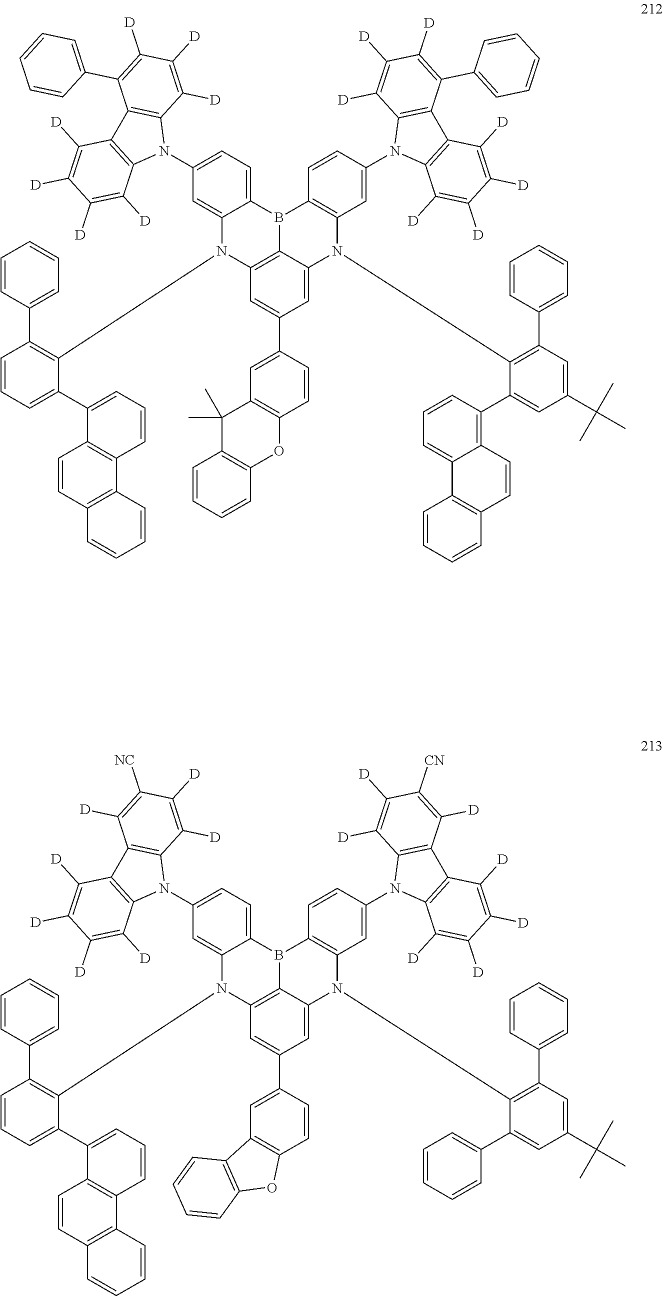

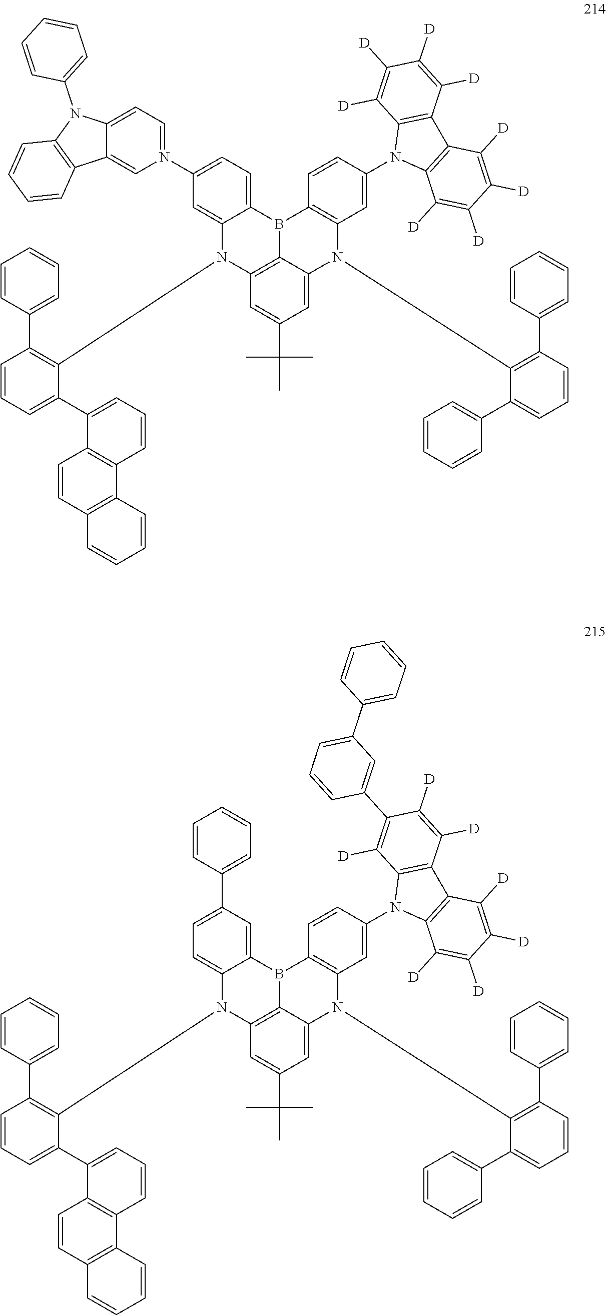

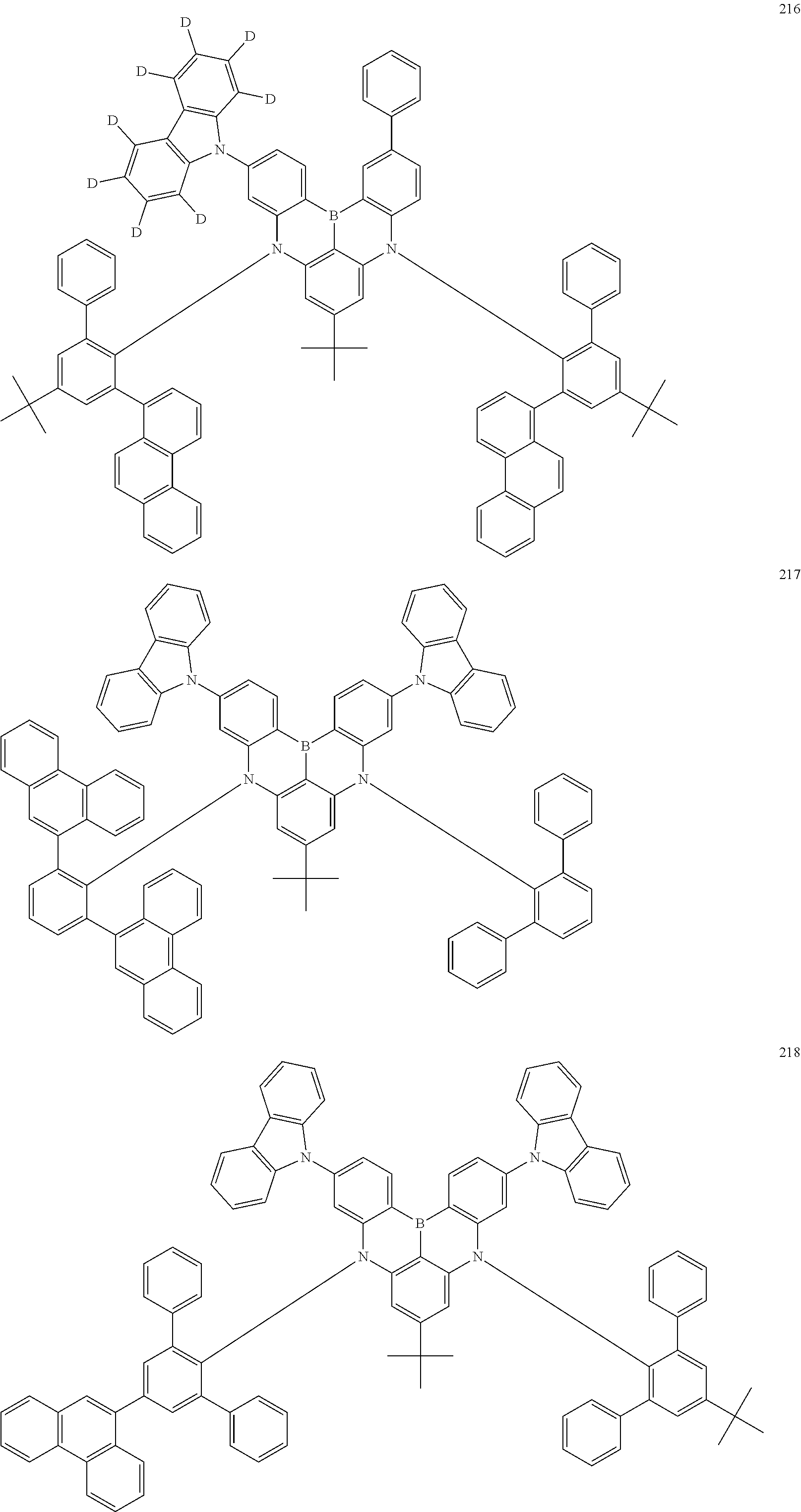

wherein in Compound Group 1, D is a deuterium atom.

The polycyclic compound according to one or more embodiments includes at least one phenanthryl group linked to the nitrogen atom of the core through a phenylene linker, and may thus contribute to achieving high luminous efficiency and long service life of the light emitting element ED.

In the polycyclic compound of one or more embodiments, the steric hindrance effect caused by a phenanthryl group may suppress intermolecular interactions to control aggregation, excimer formation, or exciplex formation, resulting in greater luminous efficiency. The polycyclic compound of one or more embodiments has a bulky structure, and may thus reduce dexter energy transfer by increasing (e.g., widening) the distance between molecules. Accordingly, an increase in the concentration of triplet exciton in the polycyclic compound may be reduced or prevented. The triplet exciton at a high concentration remains in an excited state for a long period of time and may thus cause compound decomposition, and may induce hot exciton having high energy generated through triplet-triplet annihilation (TTA) to cause surrounding compound structures to collapse. For example, the triplet-triplet annihilation is a bimolecular reaction that fast-quenches the triplet exciton utilized for light emission, and may thus cause a decrease in luminous efficiency as a non-radiative transition. In one or more embodiments of the polycyclic compound, the core is effectively protected by a phenanthryl group, and the intermolecular distance is increased to suppress the dexter energy transfer, and accordingly, service life deterioration caused by an increase in triplet concentration may be suppressed. Accordingly, when the polycyclic compound of one or more embodiments is applied to the emission layer EML of the light emitting element ED, the luminous efficiency may be increased and the element service life may also be improved.

For example, the polycyclic compound of one or more embodiments has a characteristic in which the energy level of the higher triplet state (Tn) is lower than the energy level of the lowest singlet (S1) state, or surrounds (e.g., is packed around) the energy level of the lowest singlet (S1) state, to cause fast reverse intersystem crossing (RISC), and may thus exhibit long service life and improved luminous efficiency. For example, the polycyclic compound of one or more embodiments converts (e.g., turns) into the lowest singlet (S1) state via the second triplet (T2) state or the third triplet (T3) state upon the reverse intersystem crossing (RISC). For example, in the polycyclic compound of one or more embodiments, RISC transitions along the path of lowest triplet-second triplet-lowest singlet (T1-T2-S1) and/or lowest triplet-second triplet-third triplet-lowest singlet (T1-T2-T3-S1) may be achieved. The polycyclic compound of one or more embodiments may exhibit a characteristic in which the energy level of the second triplet (T2) state is lower than the energy level of the lowest singlet (S1) state, and the energy level of the third triplet (T3) state is lower than the energy level of the lowest singlet (S1) state or close to the energy level of the lowest singlet (S1) state, thereby promoting RISC acceleration. For example, in the polycyclic compound of one or more embodiments, a difference in energy level (ΔT2-T1) between the second triplet (T2) state and the lowest triplet (T1) state may be less than 0.1 eV, which is very small, and the energy level of the fourth triplet (T4) state may also be close to the energy level of the lowest singlet (S1) state, (e.g., to allow the fourth triplet (T4) to interact with the lowest singlet (S1)). Accordingly, the polycyclic compound of one or more embodiments may exhibit fast RISC, and the light emitting element ED containing the polycyclic compound of one or more embodiments as a light emitting material may have the lowest triplet (T1) at a significantly reduced concentration in the light emitting element ED to provide an improved service life.

Herein, the energy level of the second triplet (T2) state indicates the second lowest triplet energy level, and the energy level of the third triplet (T3) state indicates the third lowest triplet energy level. For example, the energy level of the fourth triplet (T4) state indicates the fourth lowest triplet energy level.

In the polycyclic compound of one or more embodiments, the emission spectrum may have a full width of half maximum of about 10 nanometer (nm) to about 50 nm, or about 20 nm to about 40 nm. The polycyclic compound according to one or more embodiments of the present disclosure has a full width of half maximum in the described range(s) and may thus exhibit excellent optical properties. For example, when the polycyclic compound of one or more embodiments is utilized as a dopant material for a light emitting element ED, the light emitting element ED may have improved luminous efficiency and service life.

The polycyclic compound of one or more embodiments may be utilized as a delayed fluorescence material. For example, the polycyclic compound of one or more embodiments may be utilized as a thermally activated delayed fluorescence (TADF) material.

In the light emitting element ED according to one or more embodiments, the emission layer EML may be a delayed fluorescence emission layer including a host and a dopant. To be more specific, the emission layer EML may be to emit light of thermally activated delayed fluorescence (TADF). The polycyclic compound of one or more embodiments may be a thermally activated delayed fluorescent dopant.

For example, the emission layer EML of the light emitting element ED may be to emit blue light. For example, the emission layer EML of a light emitting element ED of one or more embodiments may be to emit blue light in a wavelength range of about 490 nm or less. However, the embodiment of the present disclosure is not limited thereto, and the emission layer EML may be to emit green light or red light.

In one or more embodiments, the emission layer EML may include the first compound represented by Formula 1, and may further include at least one of the second compound represented by Formula HT-1, the third compound represented by Formula ET-1, or the fourth compound represented by Formula D-1.

In one or more embodiments, the second compound may be utilized as a hole transporting host material of the emission layer EML.

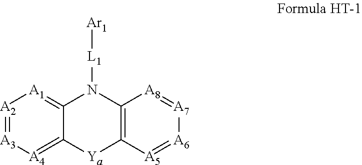

In Formula HT-1, A₁ to A₈ may each independently be N or CR₅₁. For example, each (e.g., all) of A₁ to A₈ may be CR₅₁. In some embodiments, any one (e.g., one) or at least one (e.g., one or more) selected from among A₁ to A₈ may be N, and the rest (e.g., the remaining or all remaining) selected from among A₁ to A₈ may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but the embodiment of the present disclosure is not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

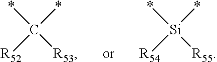

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

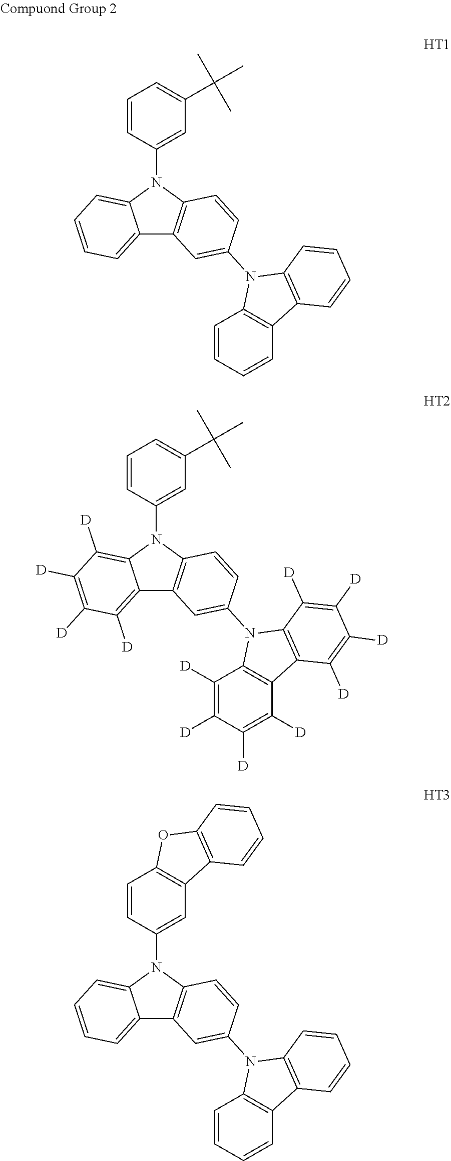

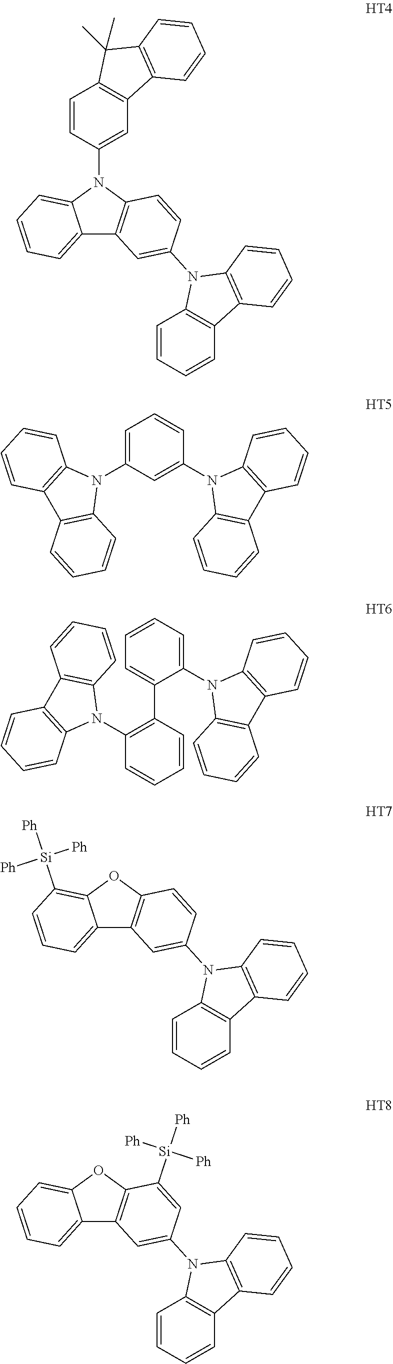

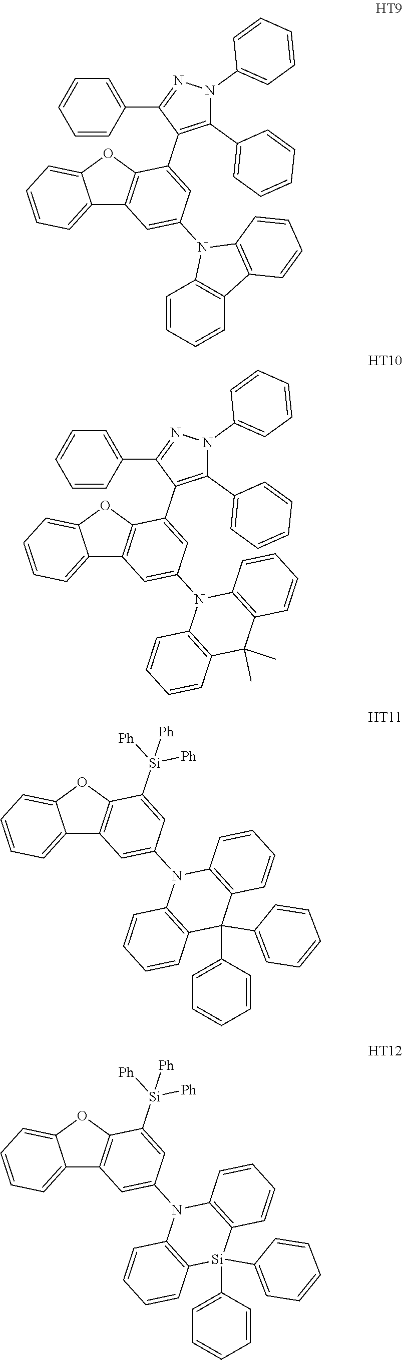

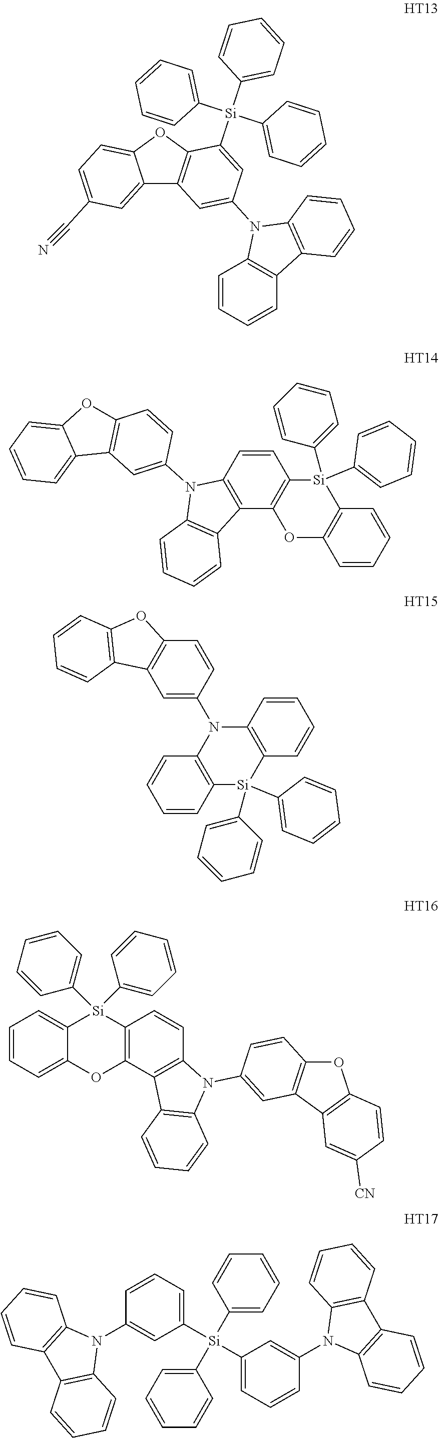 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

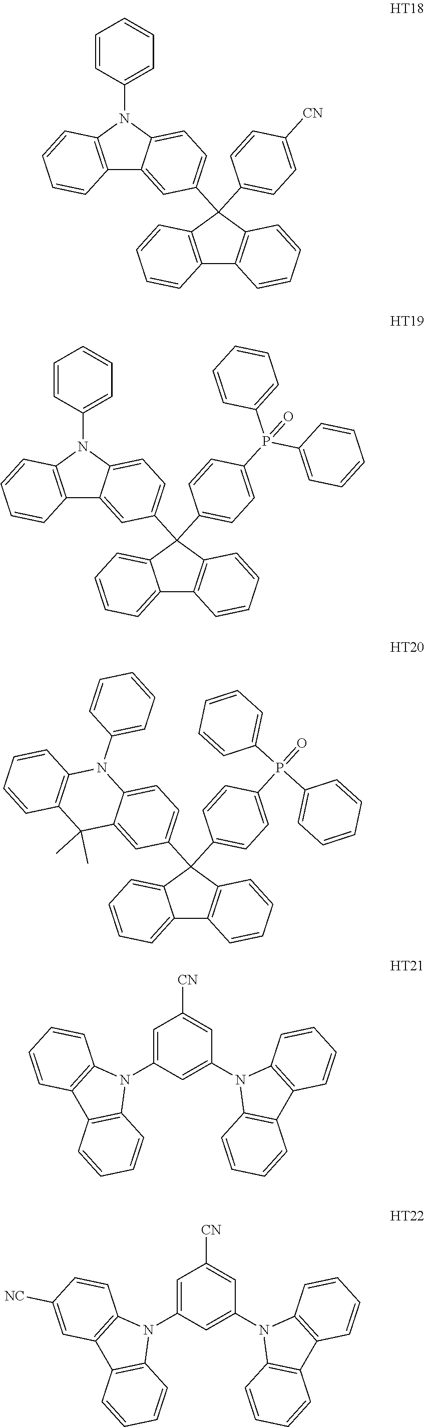 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

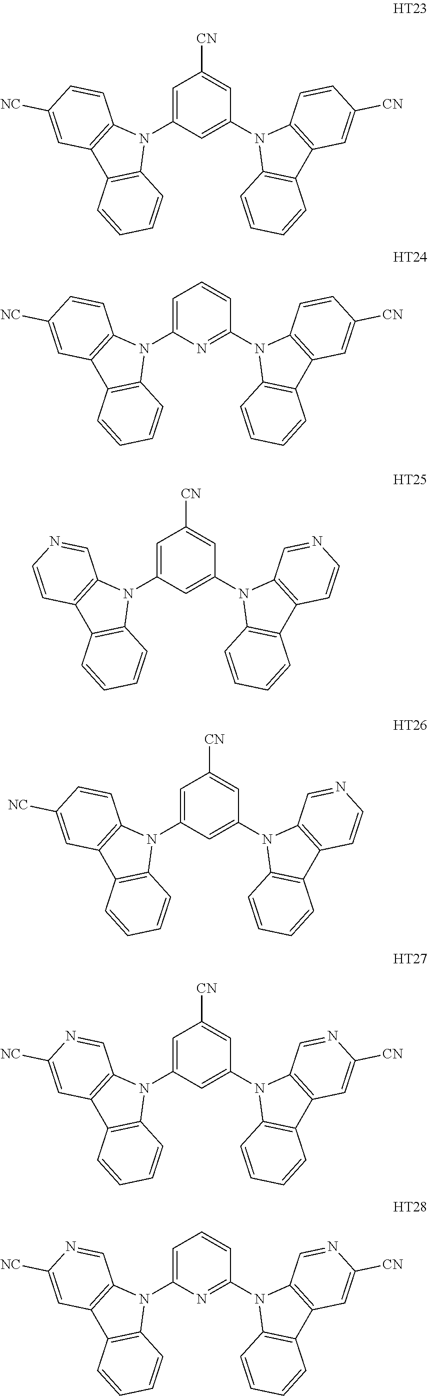 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

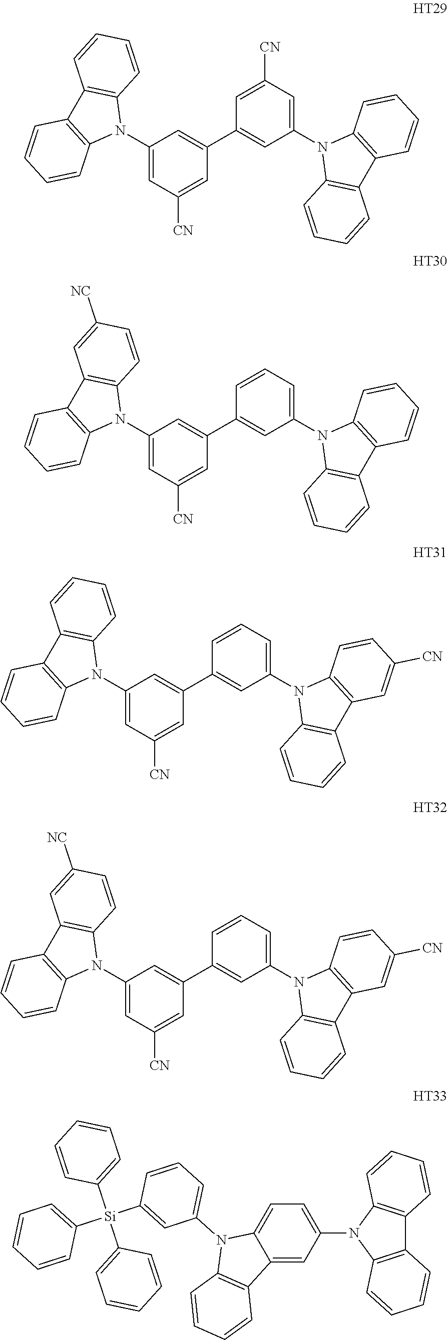 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

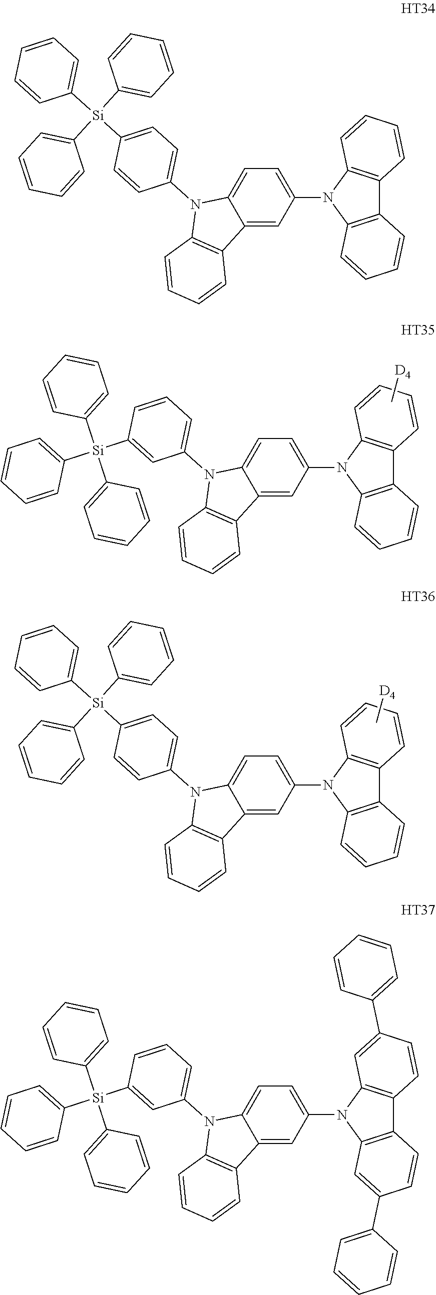

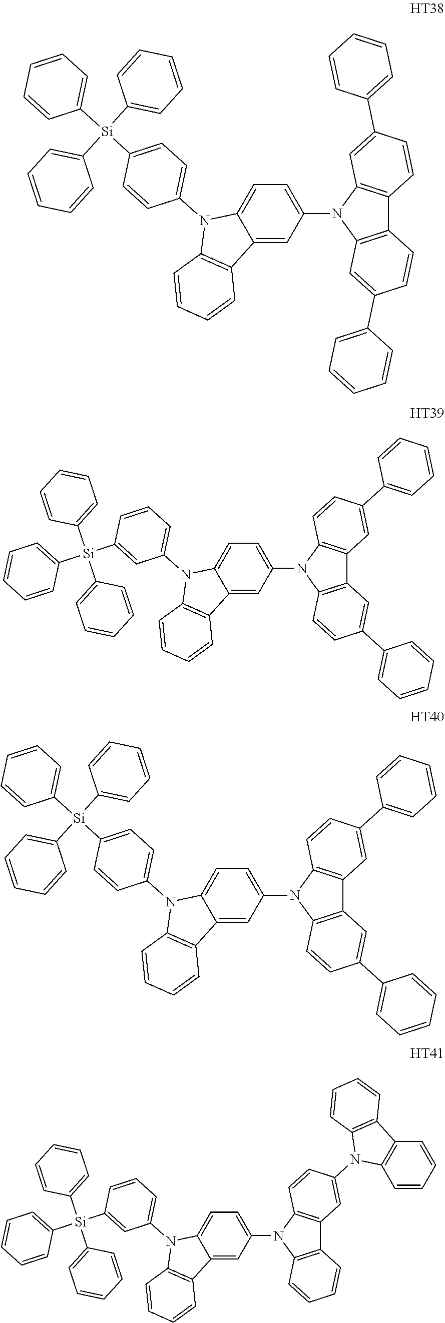 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

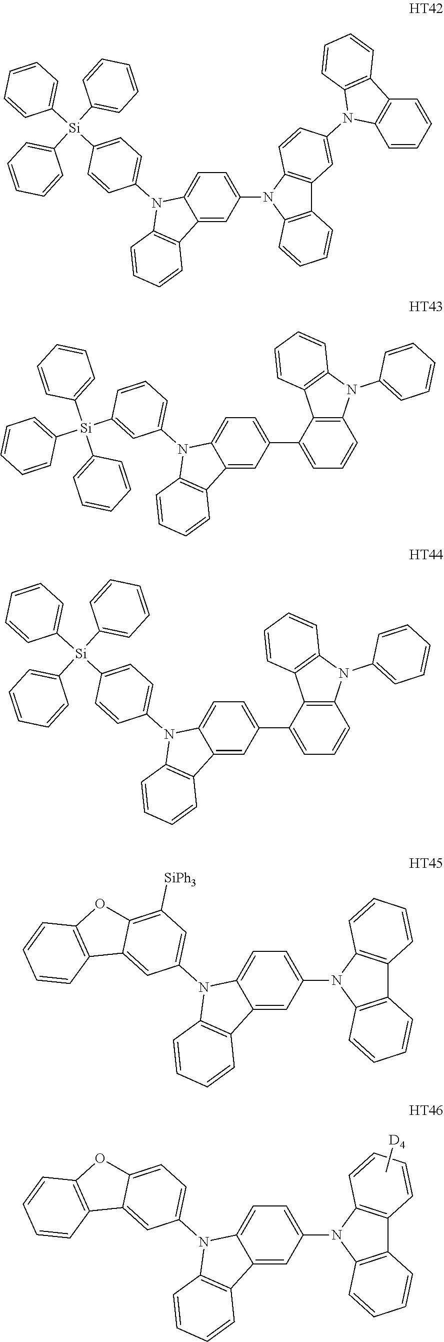

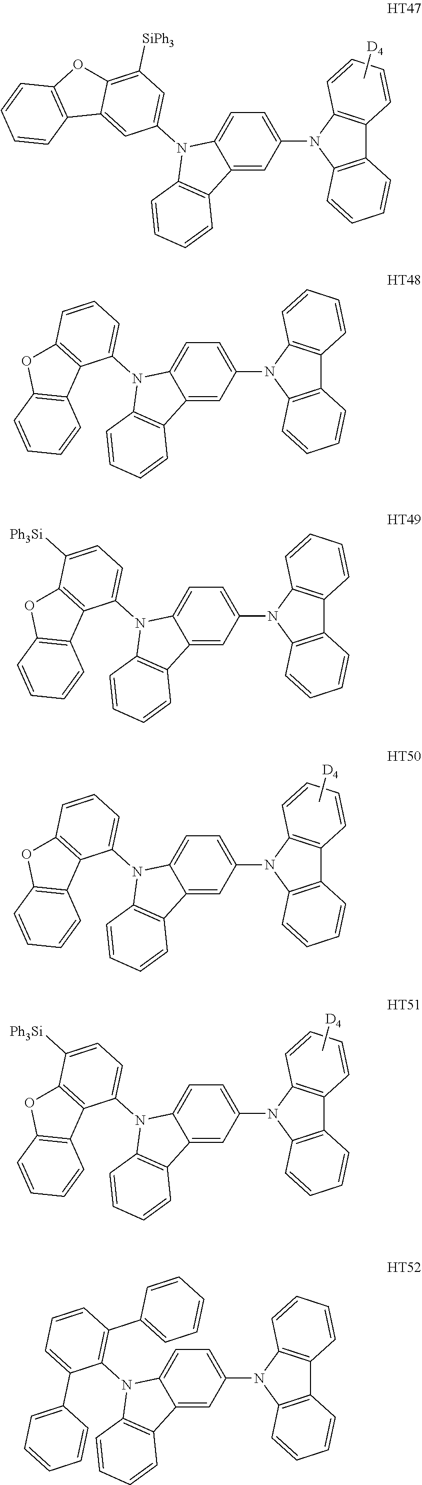

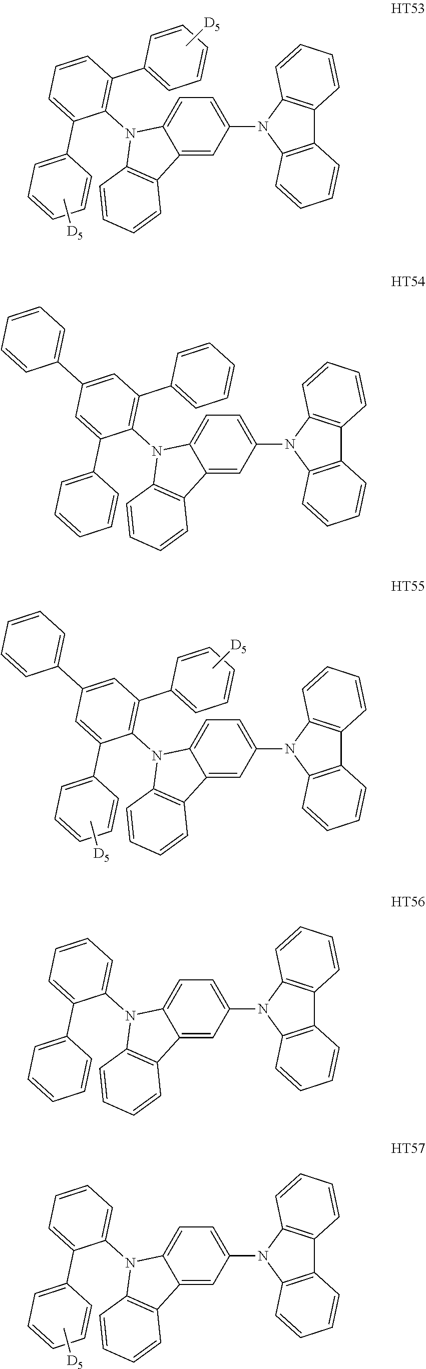

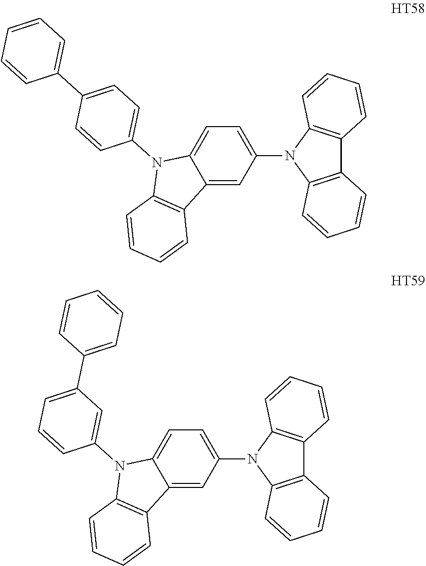 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be utilized as an electron transport host material for the emission layer EML.

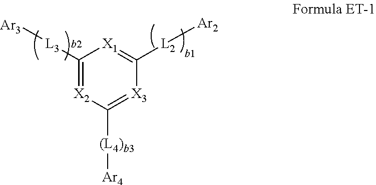

In Formula ET-1, at least one selected from among X₁ to X₃ may be N, and the rest (e.g., any remaining selected from among X₁ to X₃) may be CR₅₆. For example, any one among X₁ to X₃ may be N, and the rest may each independently be CR₅₆. In this case, the third compound represented by Formula ET-1 may include a pyridine moiety. In some embodiments, two selected from among X₁ to X₃ may be N, and the rest (e.g., any remaining selected from among X₁ to X₃) may be CR₅₆. In this case, the third compound represented by Formula ET-1 may include a pyrimidine moiety. In some embodiments, X₁ to X₃ may each (e.g., all) be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by any one (e.g., one) selected from among compounds in Compound Group 3. The light emitting element ED of one or more embodiments may include at least one (e.g., one or more) selected from among the compounds in Compound Group 3.

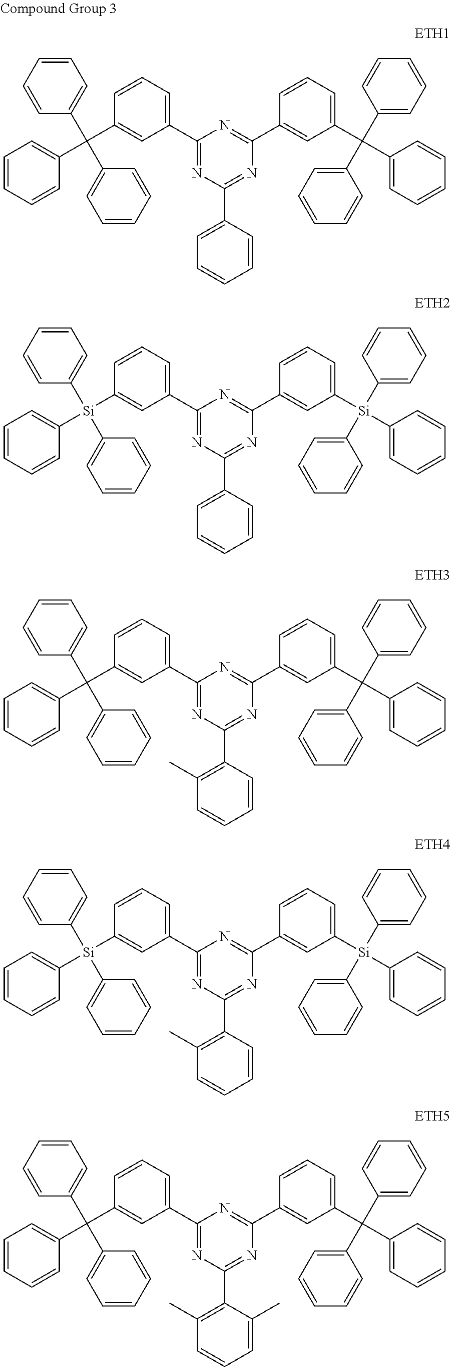

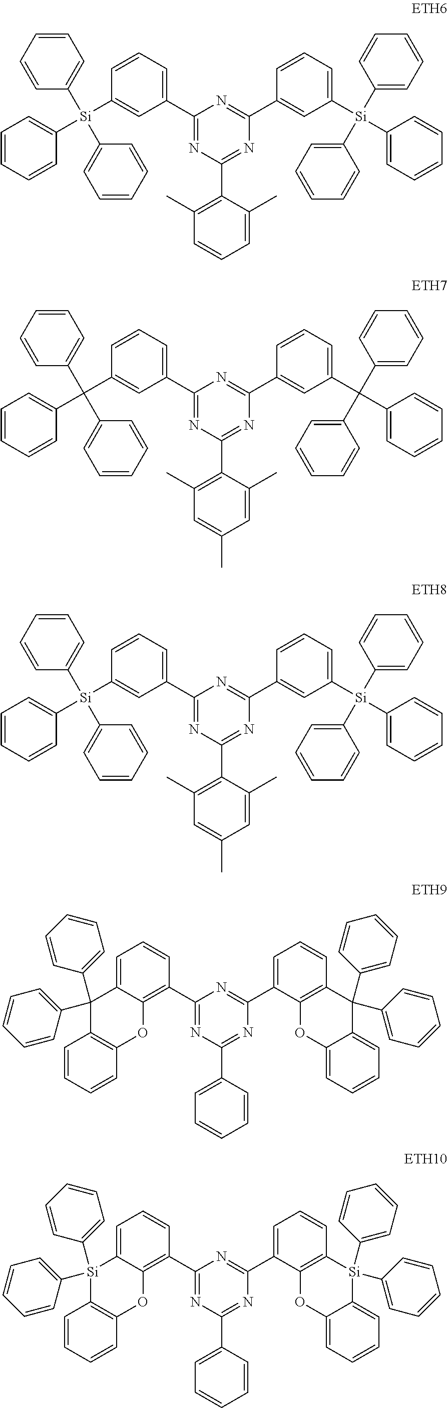

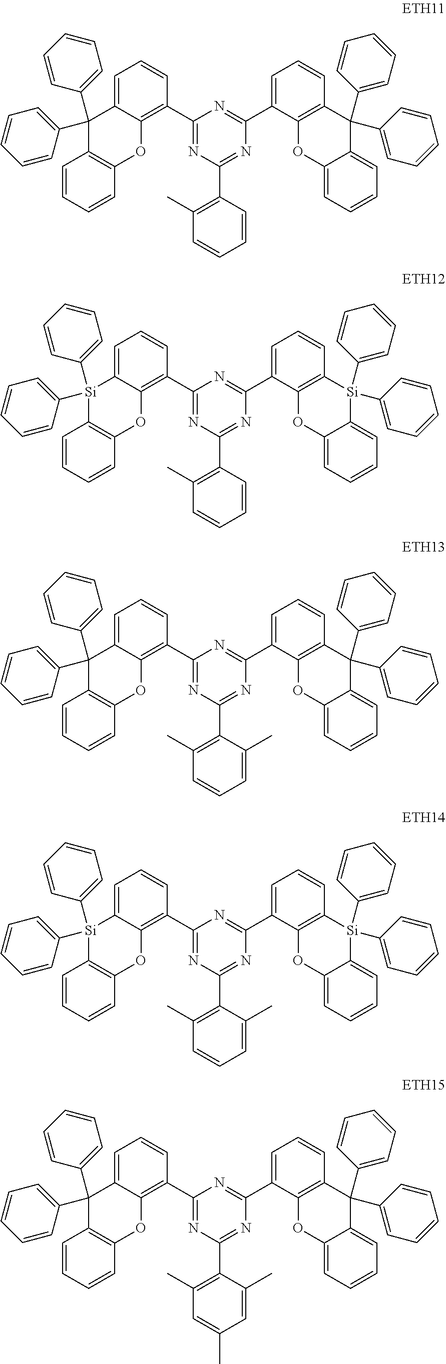

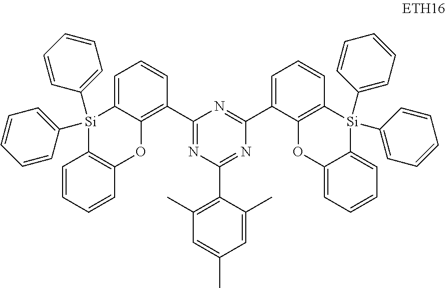 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

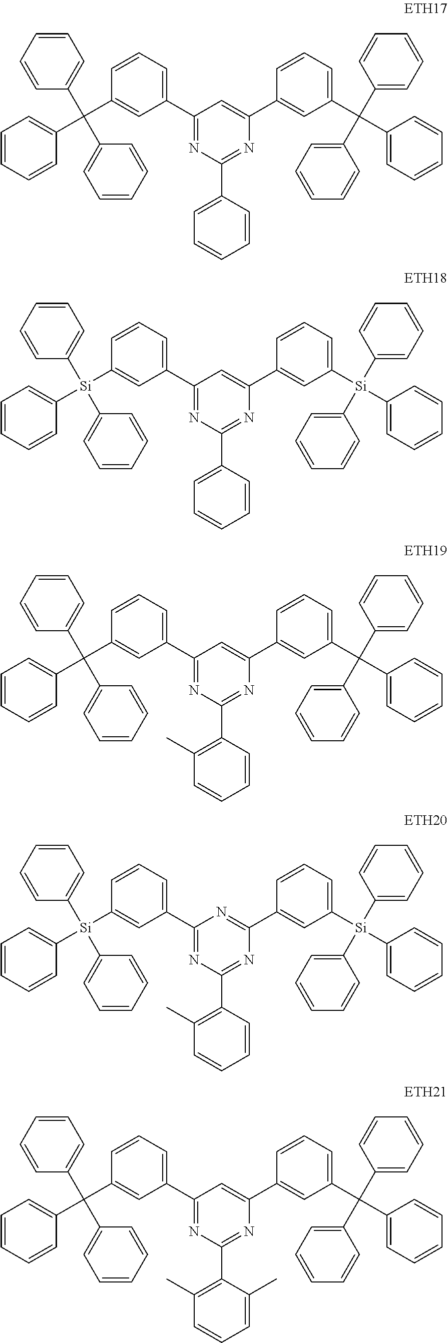

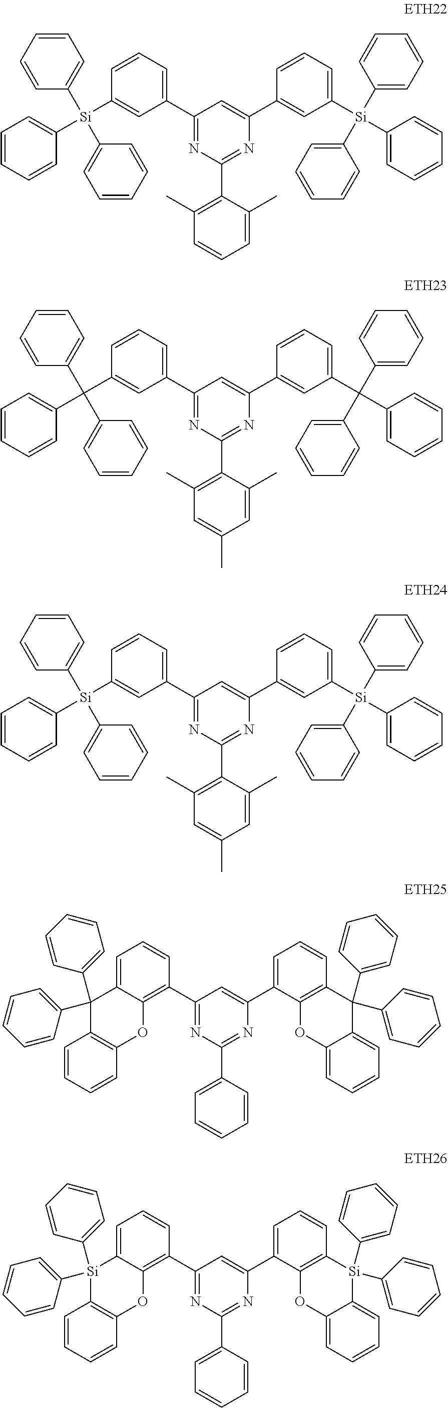

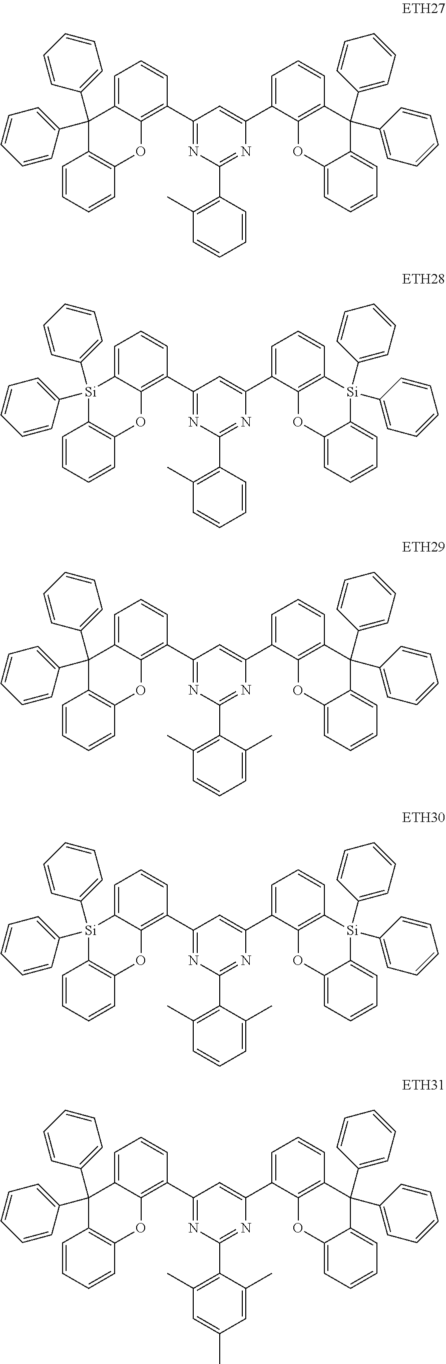

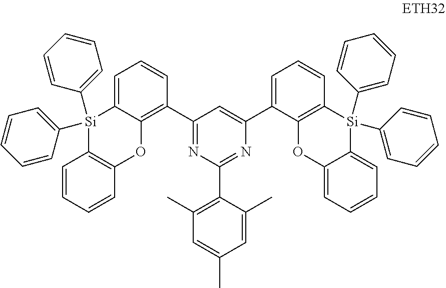 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

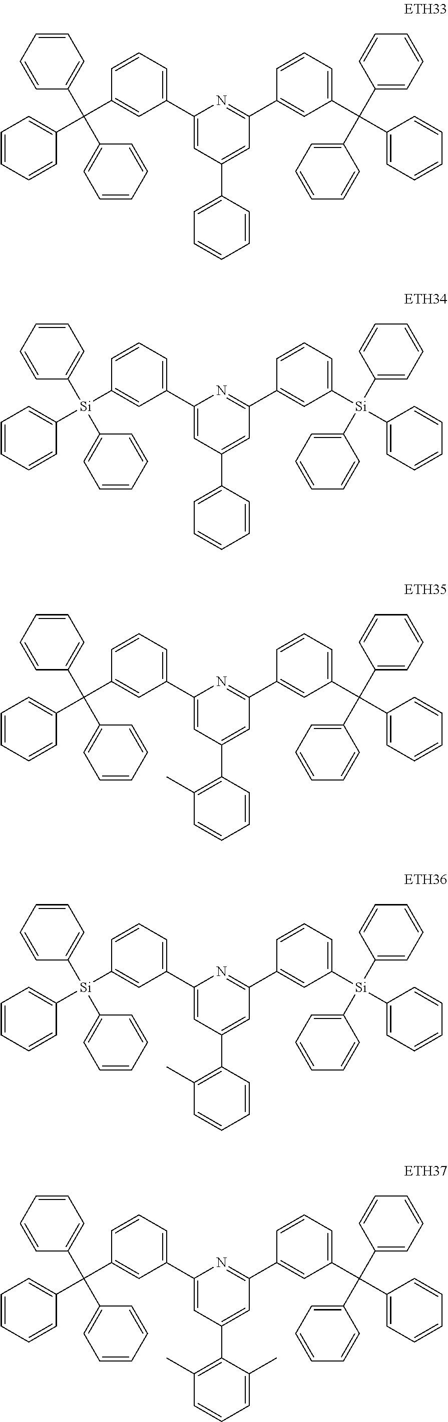

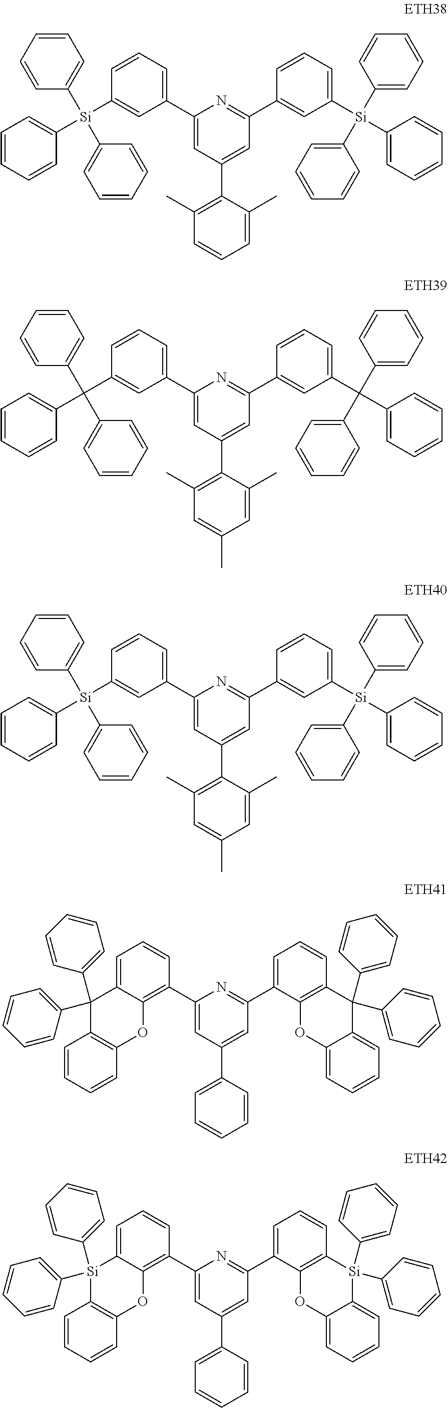

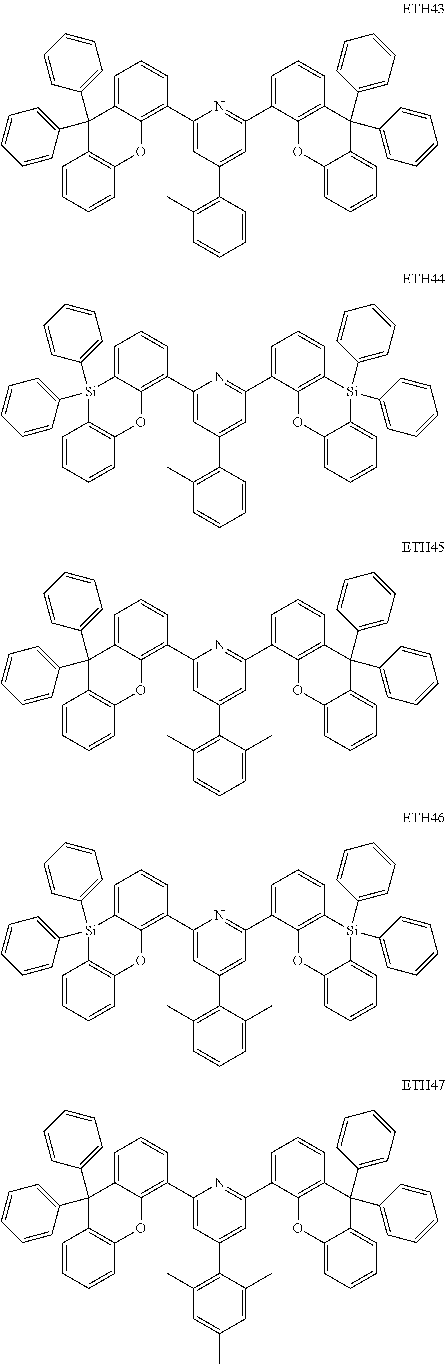

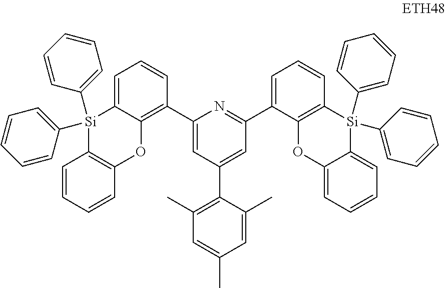 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

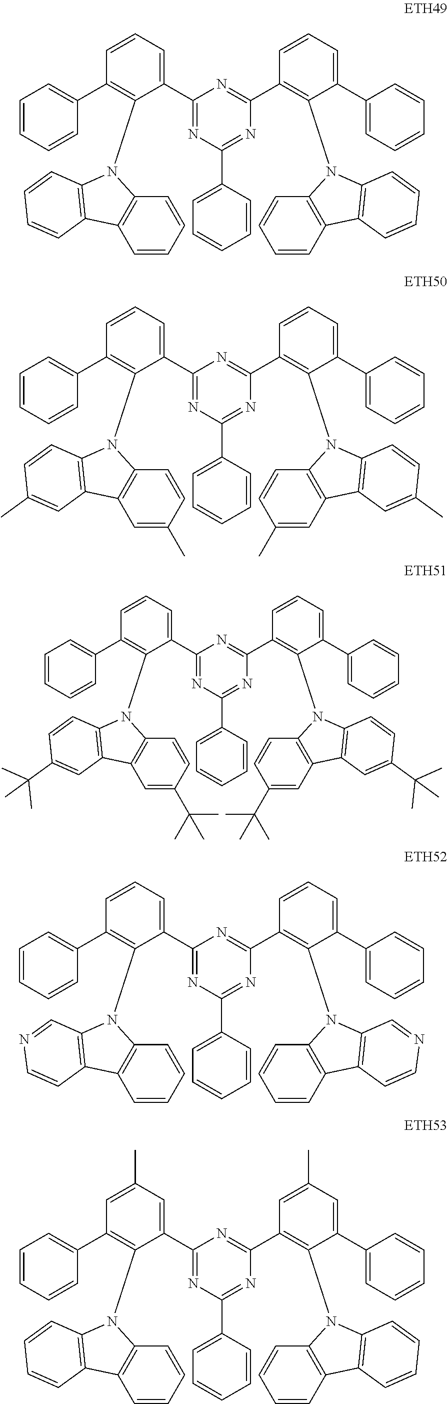

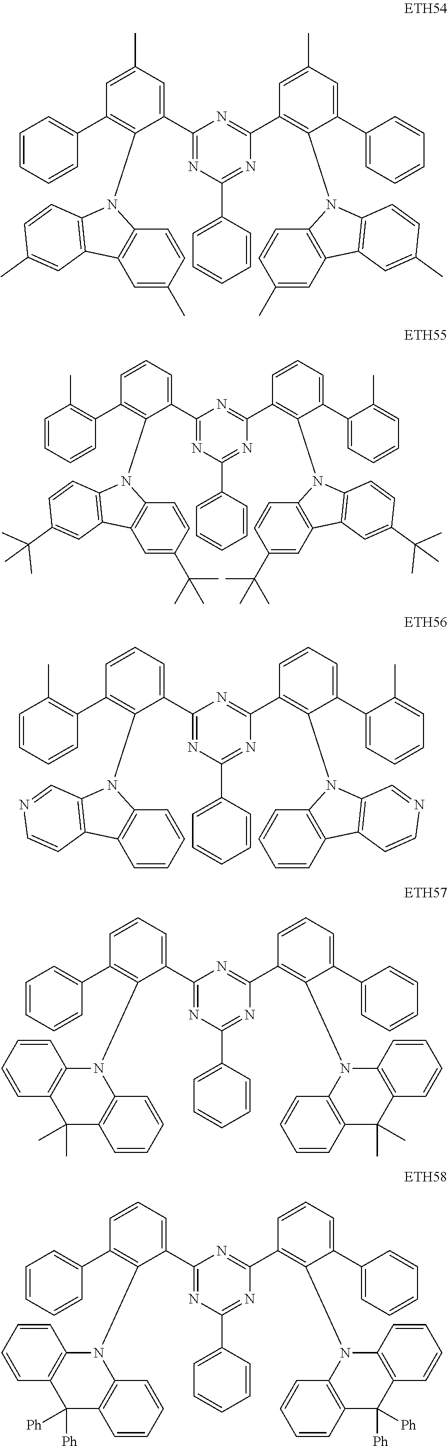

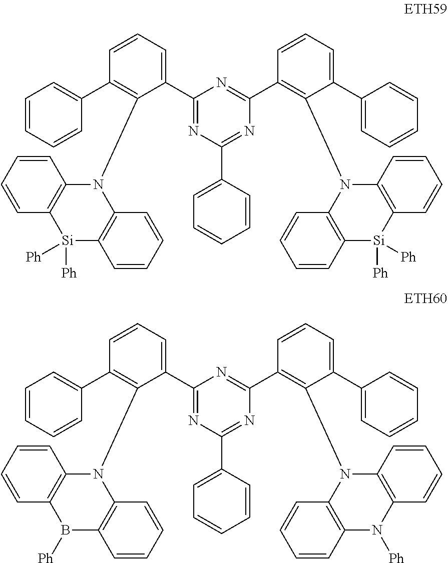 [SMILES: c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5N(c5ccccc5)c5ccccc54)n3)c3ccccc32)cc1]

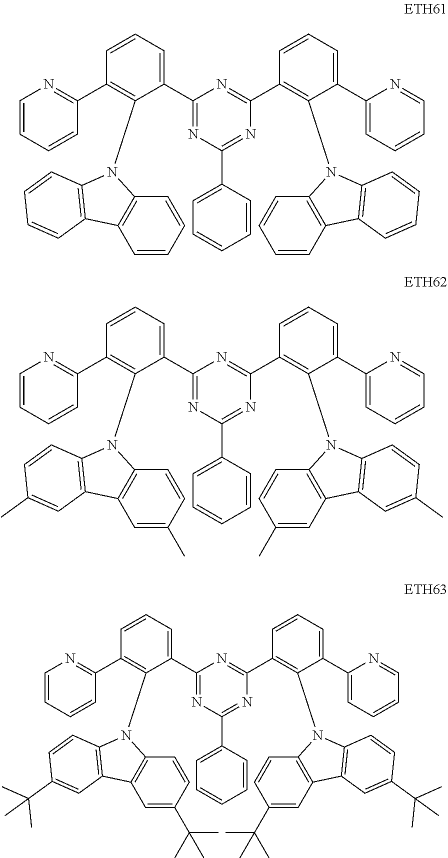

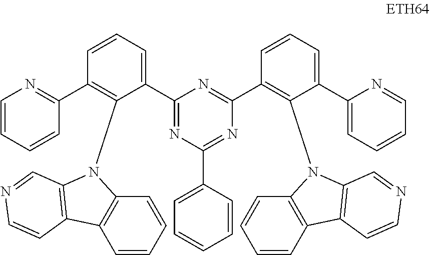 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1]

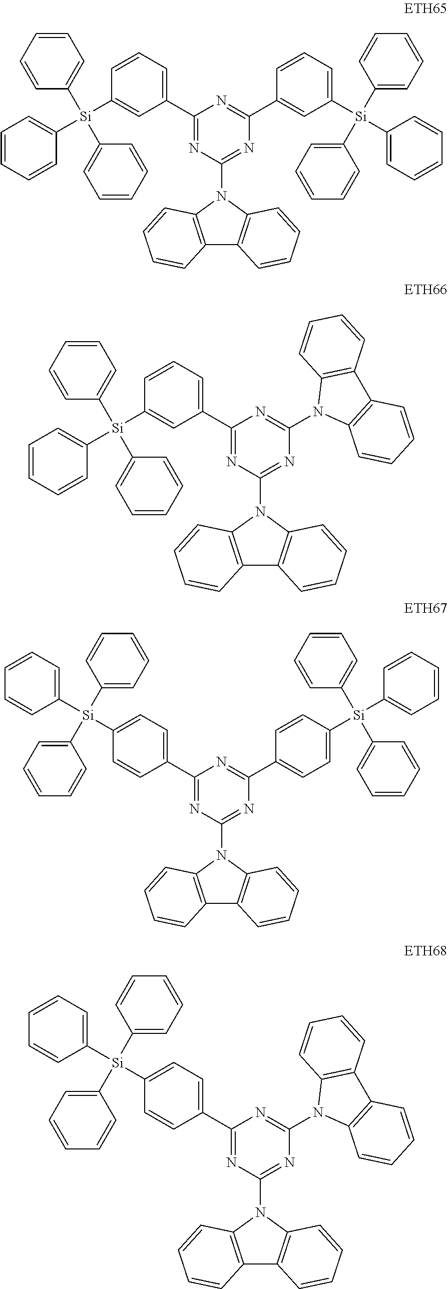

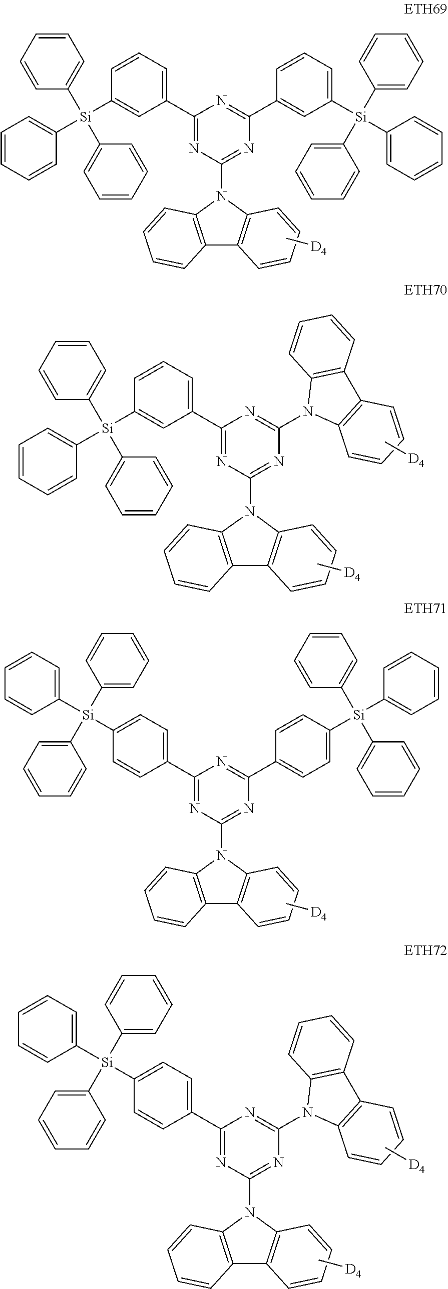

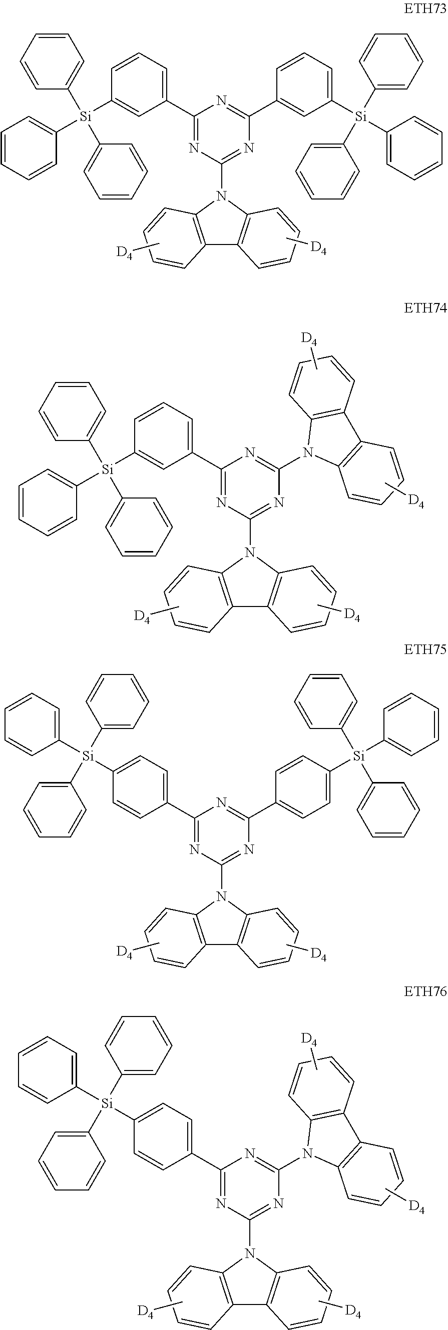

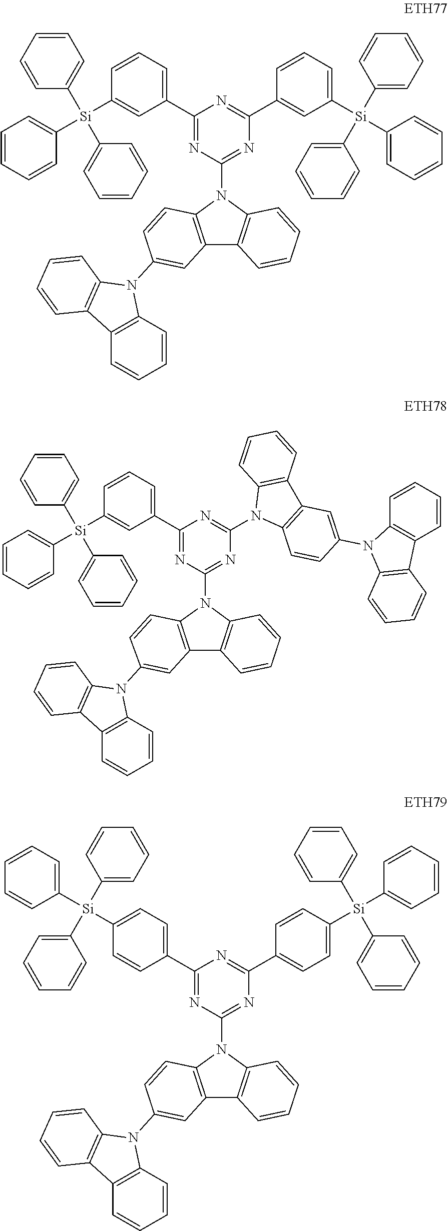 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

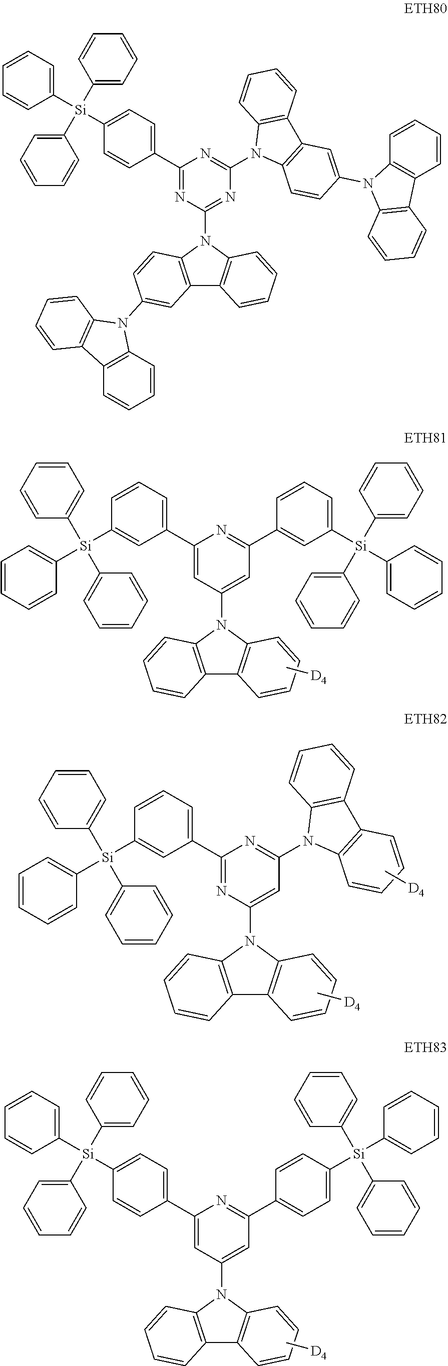

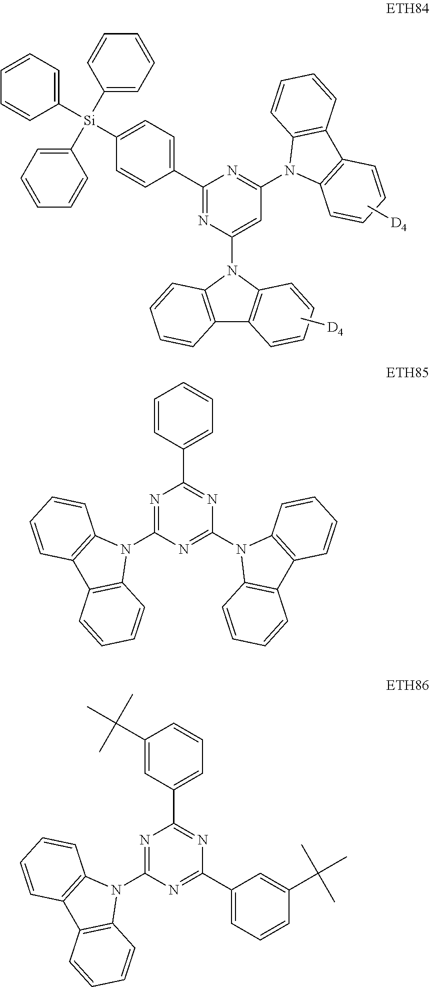

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 electron volt (eV) to about 3.0 eV. For example, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described herein. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

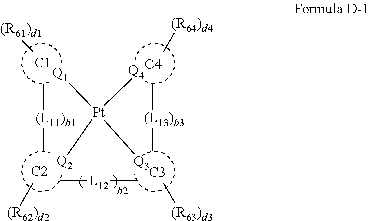

In Formula D-1, Q₁ to Q₄ may each independently be C or N. In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

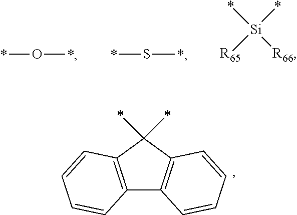

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “—*” refers to a part linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The case where each of d1 to d4 is 4 and R₆₁'s to R₆₄′ are each hydrogen atoms may be the same as the case where each of d1 to d4 is 0. When each of d1 to d4 is an integer of 2 or more, a plurality of R₆₁'s to R₆₄'s may each be the same or at least one among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

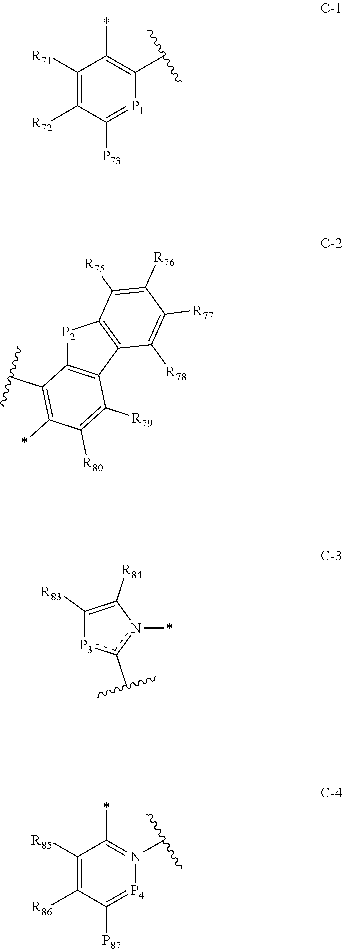

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

For example, in C-1 to C-4,

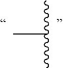

corresponds to a part linked to Pt that is a central metal atom, and “—*” corresponds to a part linked to a neighboring cyclic group (C1 to C4) or a linker (L₁₁ to L₁₃).

The emission layer EML of one or more embodiments may include the first compound, which is a fused polycyclic compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

For example, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. For example, when the energy delivery to the first compound is increased, an exciton formed in the emission layer EML is not accumulated inside the emission layer EML and emits light rapidly, and thus deterioration of the device may be reduced. Accordingly, the light emitting element ED of one or more embodiments may have increased service life.

The light emitting element ED of one or more embodiments may include all of a first compound, a second compound, a third compound, and a fourth compound, and the emission layer EML may thus include a combination of two host materials and two dopant materials. In the light emitting element ED of one or more embodiments, the emission layer EML include the second compound and the third compound that are two different hosts, the first compound emitting delayed fluorescence, and the fourth compound containing an organometallic complex, and may thus exhibit excellent or suitable luminous efficiency.

In one or more embodiments, the fourth compound represented by Formula D-1 may represented any one (e.g., one) selected from among the compounds represented by Compound Group 4. The emission layer EML may include at least one (e.g., one or more) selected from among the compounds represented by Compound Group 4 as a sensitizer material.

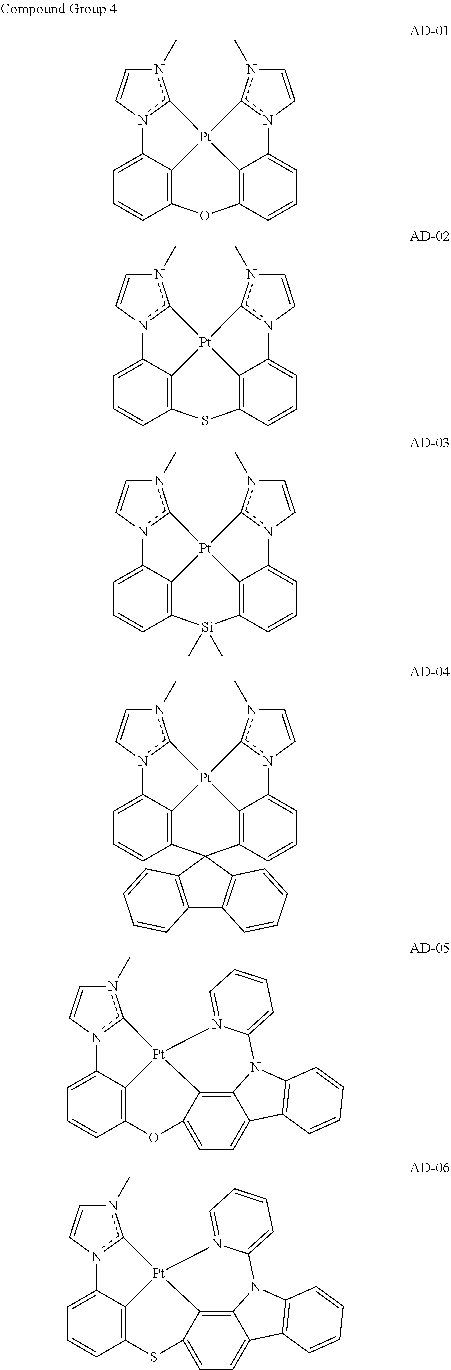

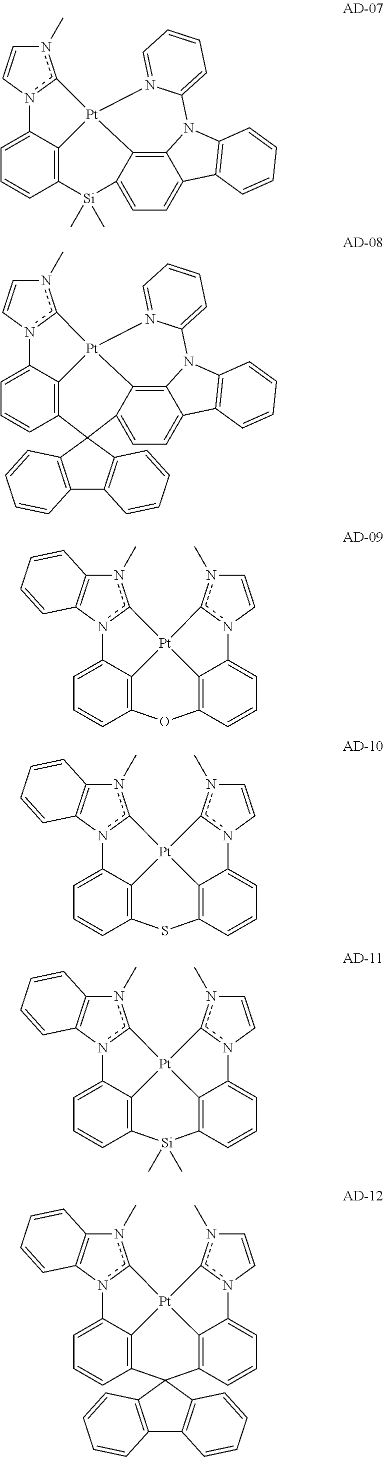

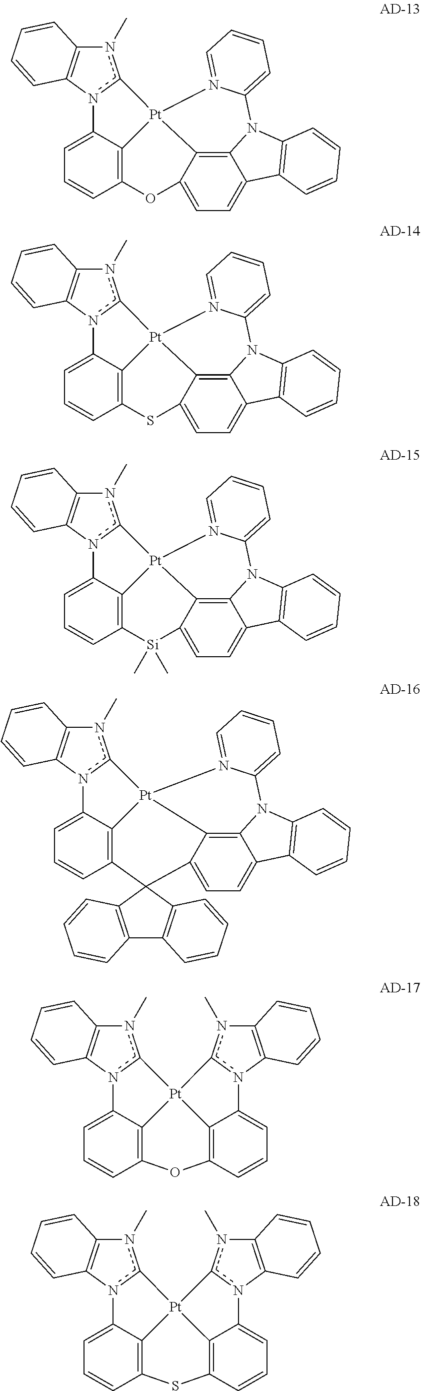

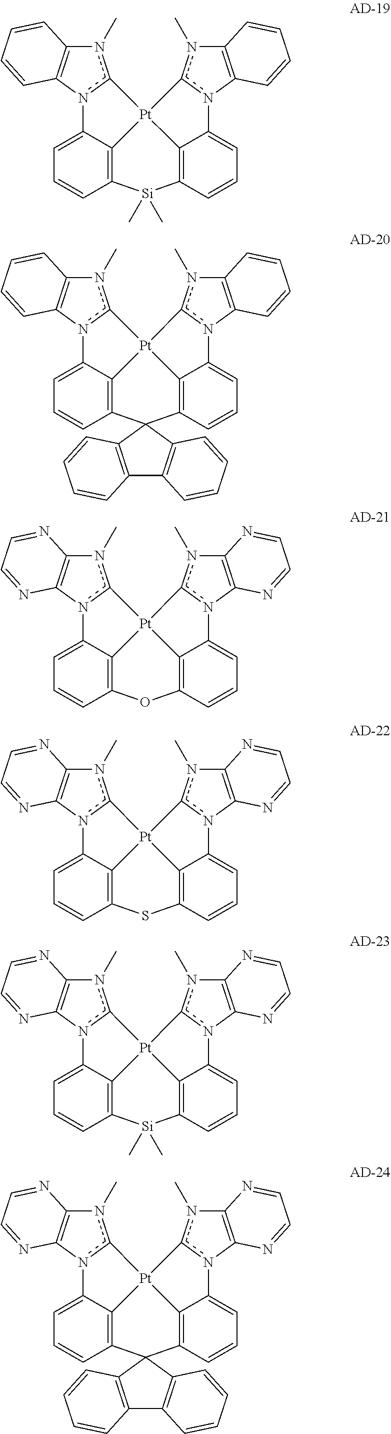

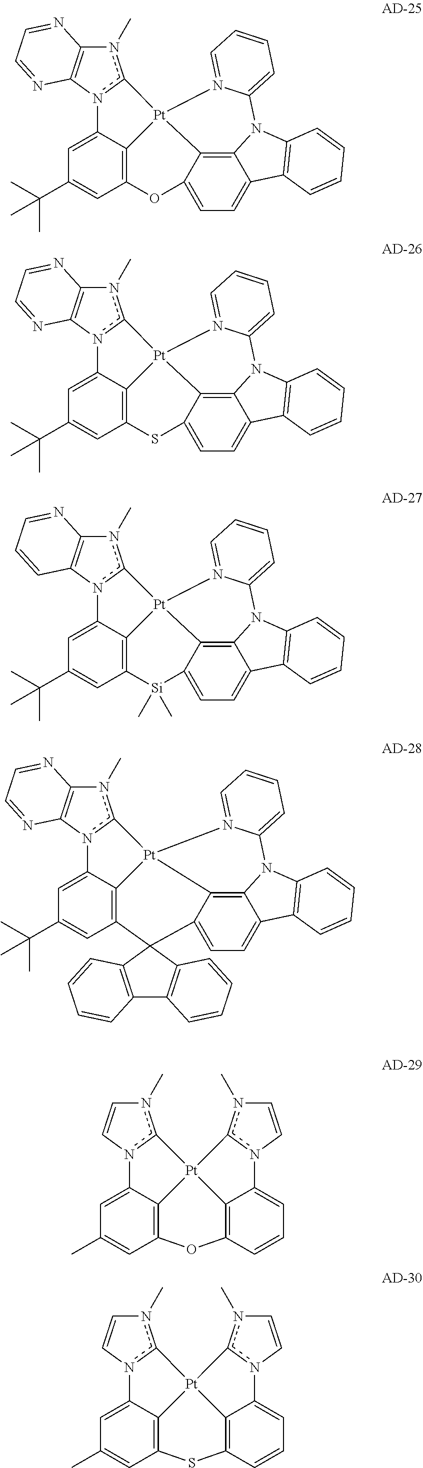

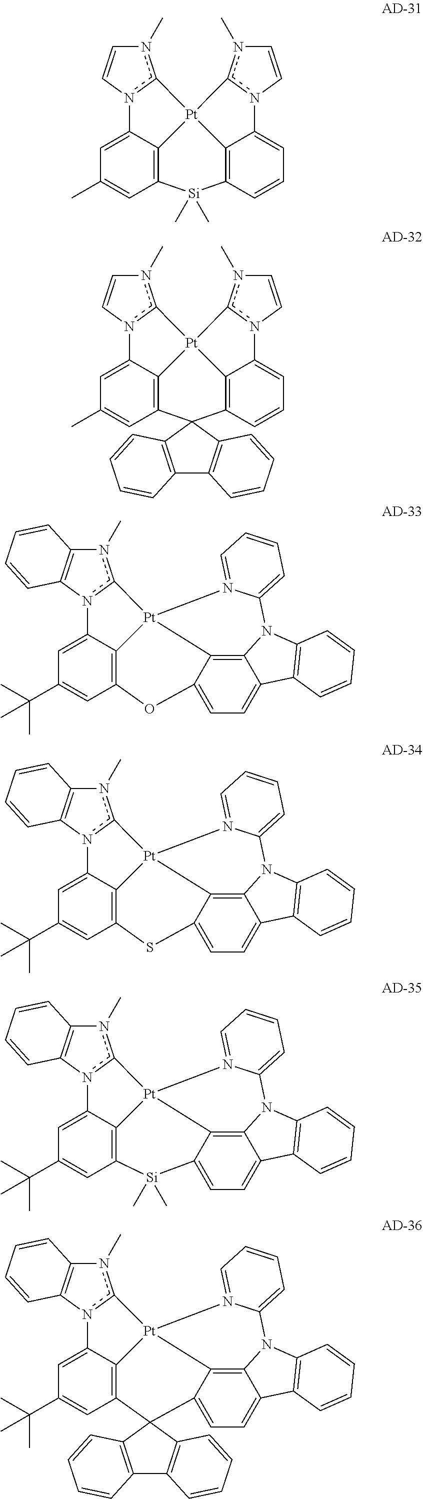

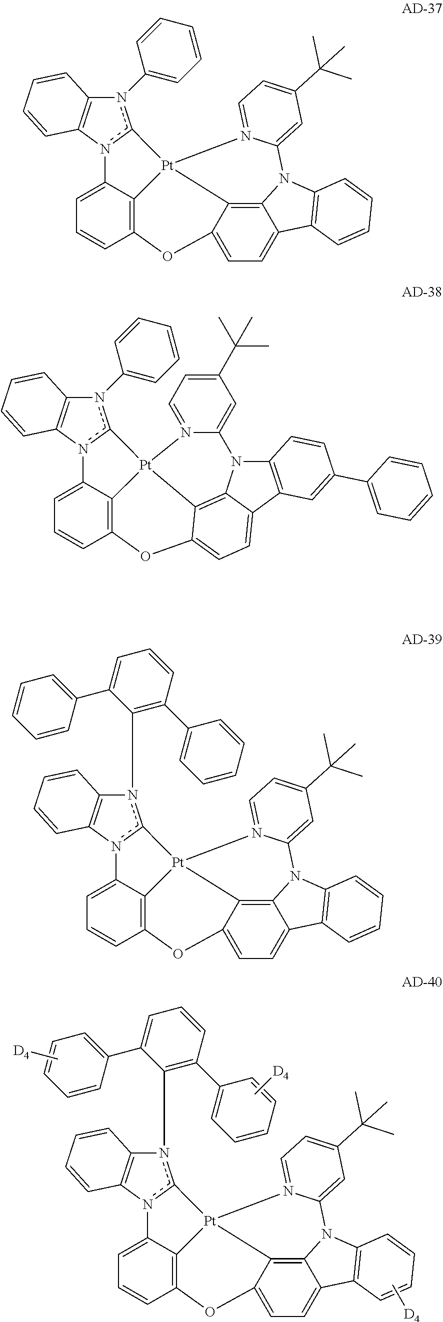

In the embodiment compounds presented in Compound Group 4, “D” refers to a deuterium atom.

When the emission layer EML in the light emitting element ED of one or more embodiments includes each (e.g., all) of the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfy the herein-described proportion, the energy transfer from the second compound and the third compound to the first compound may increase, and thus the luminous efficiency and device service life may increase.

The contents (e.g., amounts) of the second compound and the third compound in the emission layer EML may be the rest (e.g., total weight of the emission layer EML) excluding the weight of the first compound. For example, the contents (e.g., amounts) of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents (e.g., amounts) of the second compound and the third compound satisfy the herein-described ratio, a charge balance characteristic in the emission layer EML are improved, and thus the luminous efficiency and device service life may increase. When the contents (e.g., amounts) of the second compound and the third compound deviate from the herein-described ratio range, a charge balance in the emission layer EML is broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the herein-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the herein-described content (e.g., amount) ratio range(s), excellent or suitable luminous efficiency and long service life may be achieved.

The emission layer EML may have a thickness of, for example, about 100 Å to about 1,000 Å or about 100 Å to about 300 Å. The emission layer EML may have a single layer including (e.g., formed of) a single material, a single layer including (e.g., formed of) a plurality of different materials, or a multilayer structure having a plurality of layers including (e.g., formed of) a plurality of different materials.

In the light emitting element ED of one or more embodiments shown in FIGS. 3 to 7, the emission layer EML may include the polycyclic compound of one or more embodiments described herein as a dopant. For example, in the light emitting element ED of one or more embodiments shown in FIGS. 3 to 7, the emission layer EML may include the first compound, which is the polycyclic compound of one or more embodiments, and at least one of the second compound represented by Formula HT-1 or the third compound represented by Formula ET-1. For example, in the light emitting element ED of one or more embodiments shown in FIGS. 3 to 7, the emission layer EML may include the first compound, which is the polycyclic compound of one or more embodiments, the second compound represented by Formula HT-1, the third compound represented by Formula ET-1, and the fourth compound represented by Formula D-1.

In the light emitting element ED of one or more embodiments, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In each light emitting element ED of embodiments illustrated in FIGS. 3 to 7, the emission layer EML may further include a suitable host and dopant besides the herein-described host and dopant, and for example the emission layer EML may include a compound represented by Formula E-1. The compound represented by Formula E-1 may be utilized as a fluorescent host material.

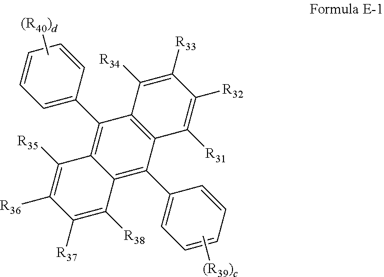

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compound E19:

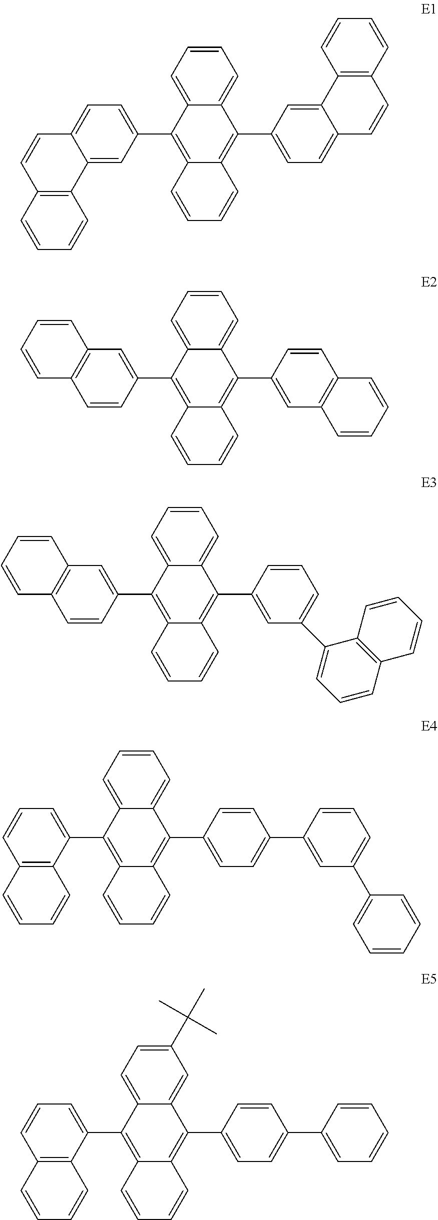

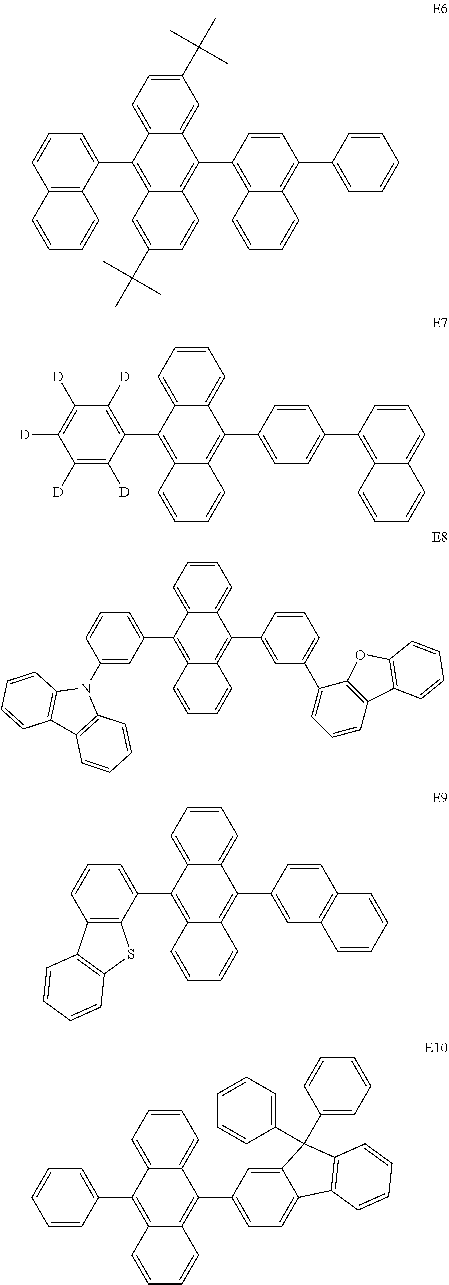

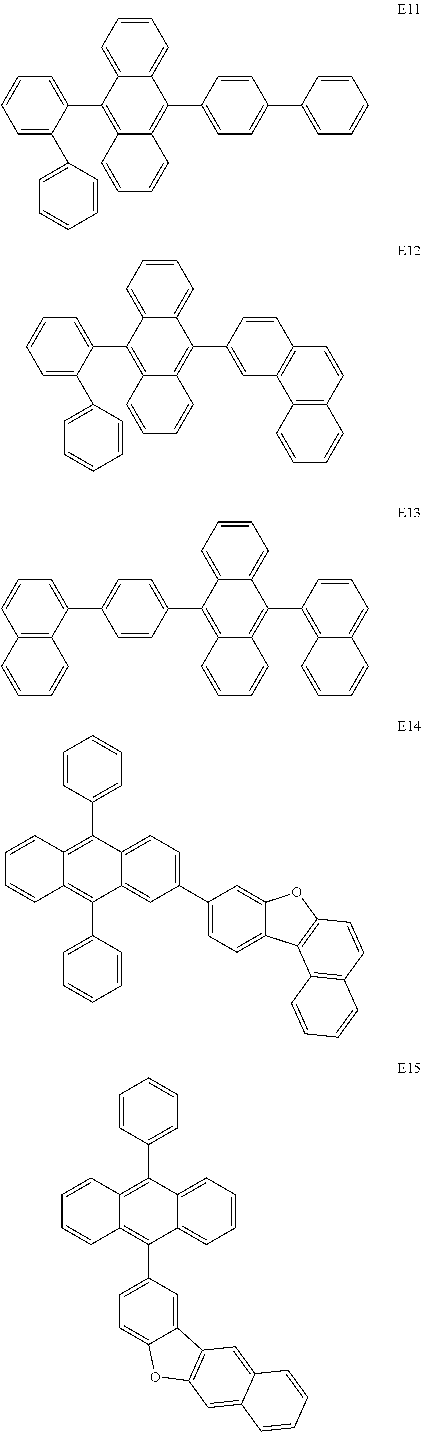

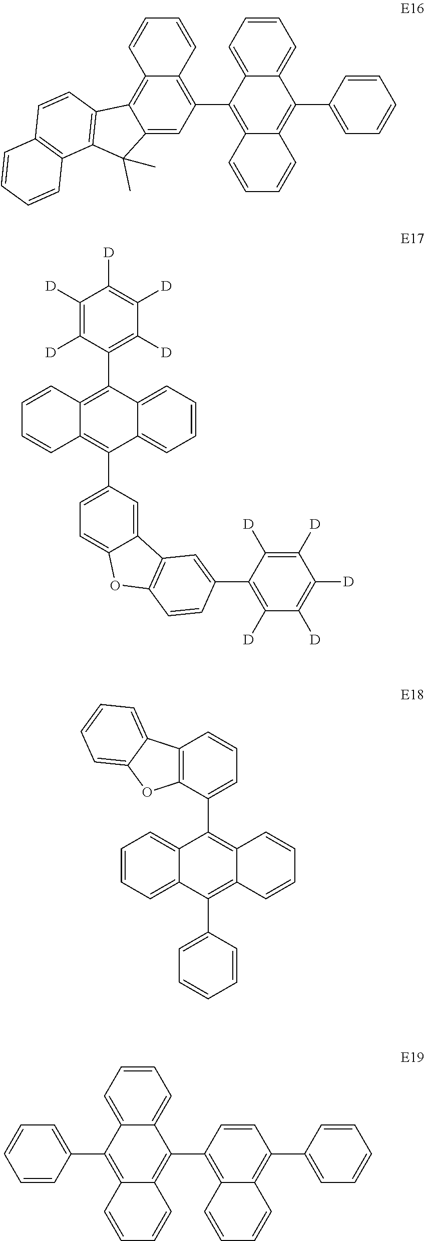

In one or more embodiments, the emission layer EML may include a compound represented by Formula E-2a or Formula E-2b. The compound represented by Formula E-2a or Formula E-2b may be utilized as a phosphorescent host material.

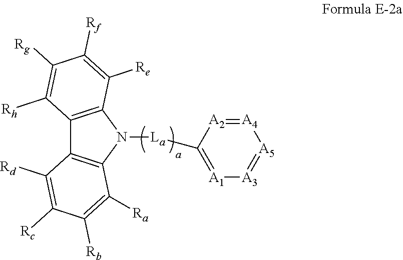

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

For example, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

In some embodiments, in Formula E-2a, two or three selected from among A₁ to A₅ may be N, and the rest (i.e., any remaining selected from among A₁ to A₅) may be CRᵢ.

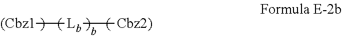

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are exemplary, and the compound represented by Formula E-2a or Formula E-2b is not limited to those represented in Compound Group E-2.

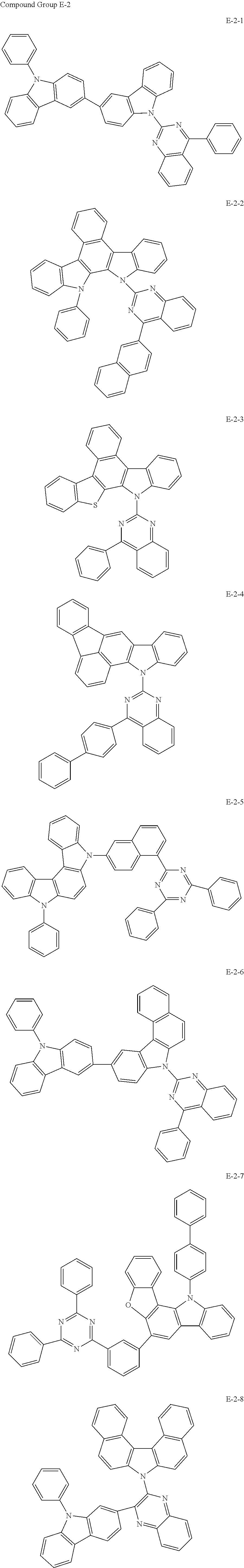

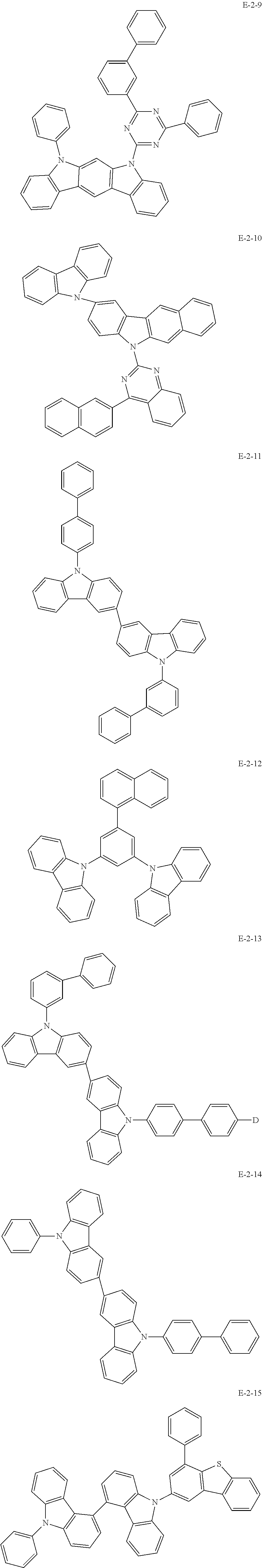

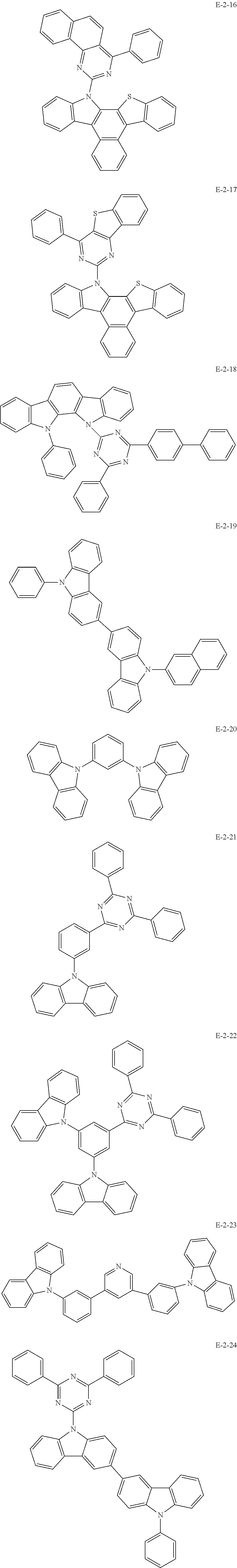

The emission layer EML may include the compound represented by Formula M-a. The compound represented by Formula M-a may be utilized as a phosphorescent dopant material.

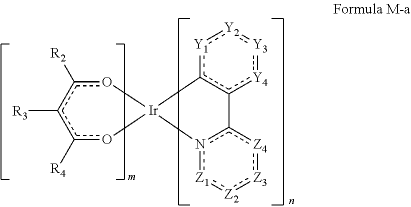

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one among Compound M-a1 to Compound M-a25. However, Compounds M-a1 to M-a25 are examples, and the compound represented by Formula M-a is not limited to those represented by Compounds M-a1 to M-a25.

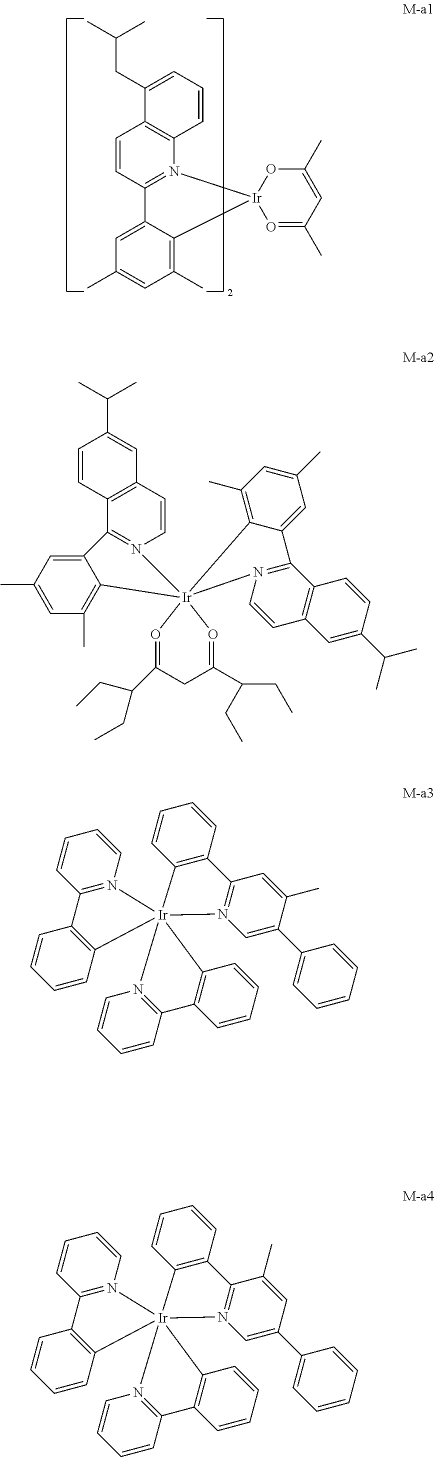

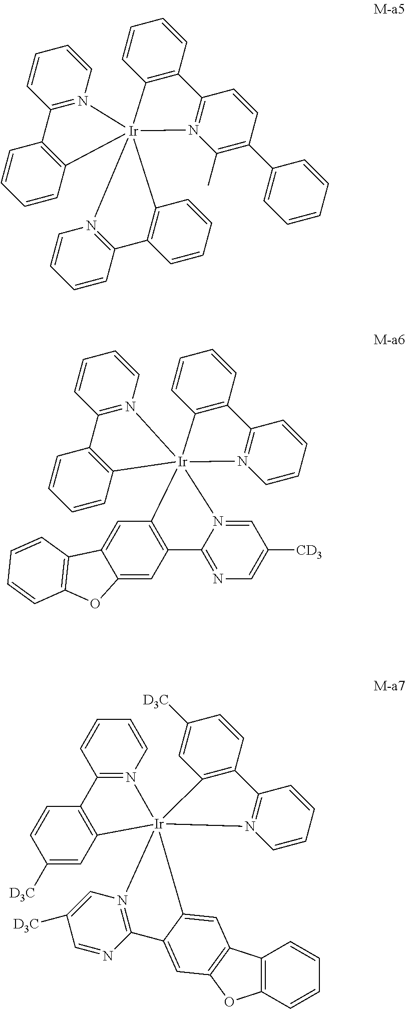

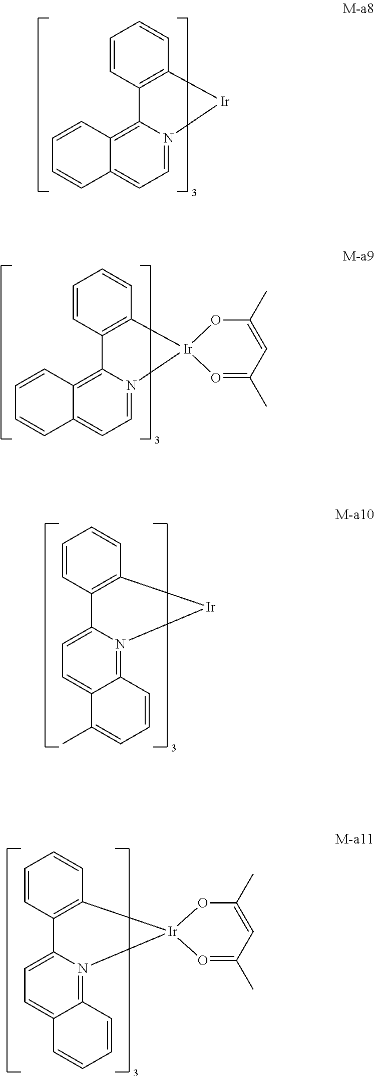

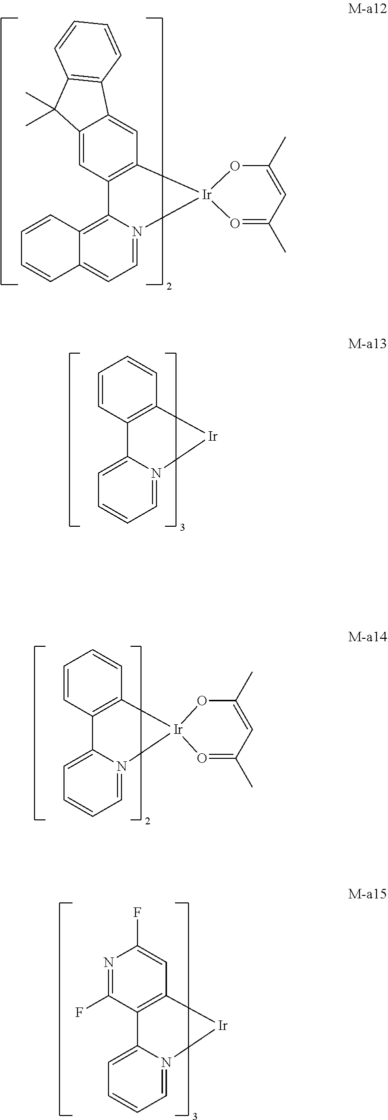

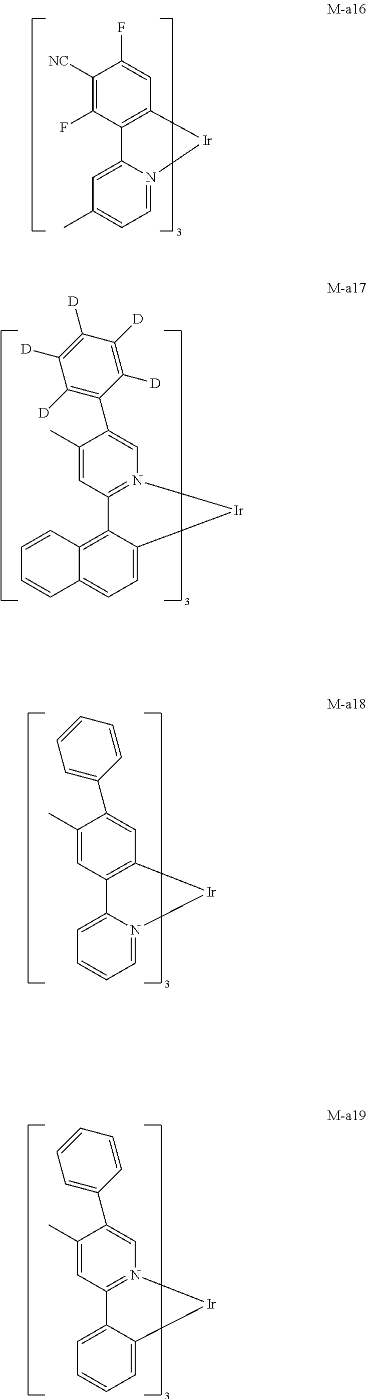

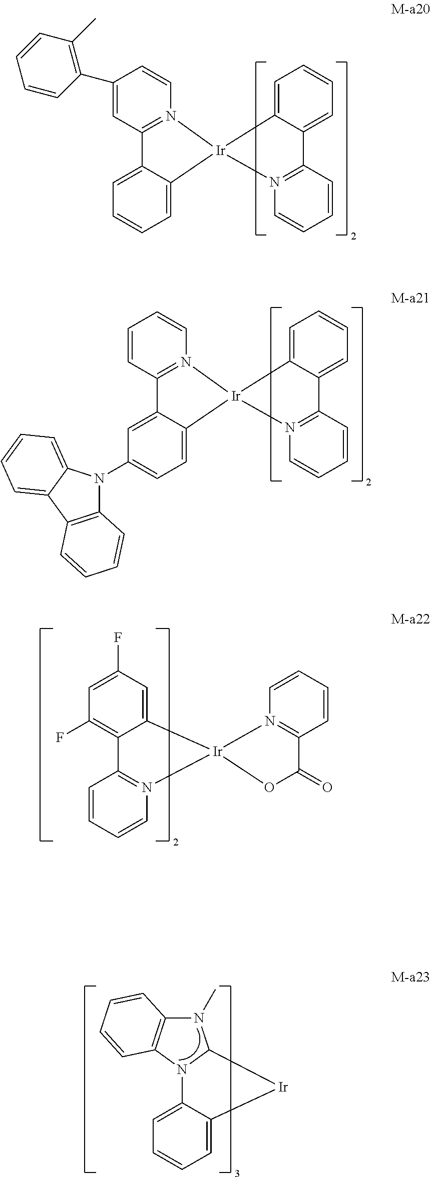

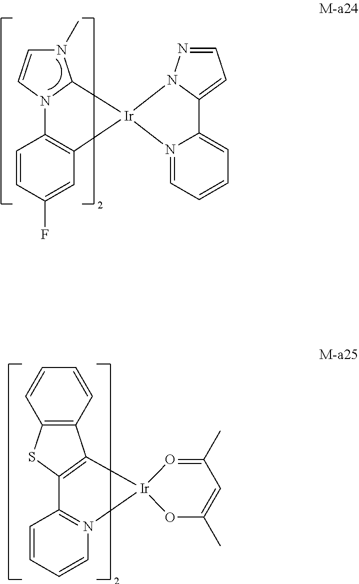

The emission layer EML may include a compound represented by any one selected from among Formula F-a to Formula F-c. The compound represented by Formula F-a to Formula F-c may be utilized as a fluorescence dopant material.

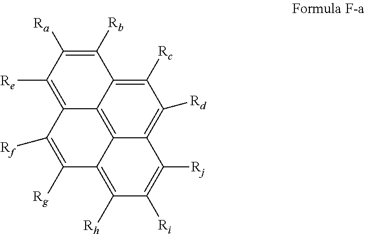

In Formula F-a, two selected from among Rₐ to Rⱼ may each independently be substituted with *—NAr₁Ar₂. The others, which are not substituted with *—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

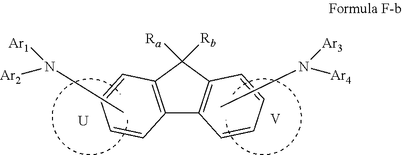

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. For example, when each number of U and V is 0, the fused ring in Formula F-b may be a cyclic compound having three rings. For example, when each number of U and V is 1, the fused ring having a fluorene core in Formula F-b may be a cyclic compound having five rings.

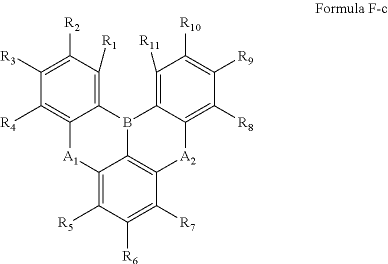

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-c, A₁ and A₂ may each independently be bonded to substituents of an adjacent ring to form a fused ring. For example, when A₁ and A₂ are each independently NRₘ, A₁ may be bonded to R₄ or R₅ to form a ring. For example, A₂ may be bonded to R₇ or R₈ to form a ring.

In one or more embodiments, the emission layer EML may further include, as a suitable dopant material, at least one selected from among a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2)picolinate (FIrpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂, or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary (i.e., multi-element) compound such as the binary compound, the ternary compound, or the quaternary compound may be present in a particle with a substantially uniform or non-substantially uniform concentration distribution. For example, the formulae may refer to the types (kinds) of elements included in the compounds, and the elemental ratio in the compound may be different. For example, AgInGaS₂ may refer to AgInₓGa₁₋ₓS₂ (where x is a real number of 0 to 1).

In some embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

The shell may be a single layer or multiple layers. An example of the shell of the quantum dots may include a metal or non-metal oxide, a semiconductor compound, or a combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each element included in a polynary compound such as the binary compound, or the ternary compound may be present in a particle with a substantially uniform or non-substantially uniform concentration distribution. For example, the formulae may refer to the types (kinds) of elements included in the compounds, and the elemental ratio in the compound may be different.

The quantum dot may have a full width of half maximum (FWHM) of a light emitting wavelength spectrum of about 45 nm or less, about 40 nm or less, or about 30 nm or less, and color purity or color reproducibility may be improved in the described ranges. For example, light emitted through such quantum dot may be emitted in all directions so that a wide viewing angle may be improved.

For example, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as described (utilizing different sizes of quantum dots or different elemental ratios in the quantum dot compound) may be utilized, and thus the light emitting element ED, which emits light in one or more suitable wavelengths, may be implemented. For example, the adjustment of the size of the quantum dot or the elemental ratio in the quantum dot compound may be selected to emit red, green, and/or blue light. For example, the quantum dots may be configured to emit white light by combining one or more suitable colors of light.

In each of the light emitting elements ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer including (e.g., formed of) a single material, a single layer including (e.g., formed of) a plurality of different materials, or a multilayer structure including a plurality of layers including (e.g., formed of) a plurality of different materials.

For example, the electron transport region ETR may have a single layer structure of the electron injection layer EIL or the electron transport layer ETL, and may have a single layer structure including (e.g., formed of) an electron injection material and an electron transport material. For example, the electron transport region ETR may have a single layer structure including (e.g., formed of) a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

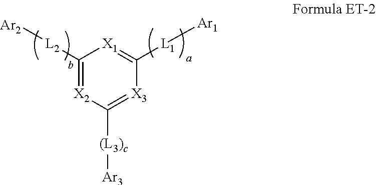

In Formula ET-2, at least one selected from among X₁ to X3 may be N, and the rest (e.g., any remaining one, or each of the remaining, X₁ to X₃) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

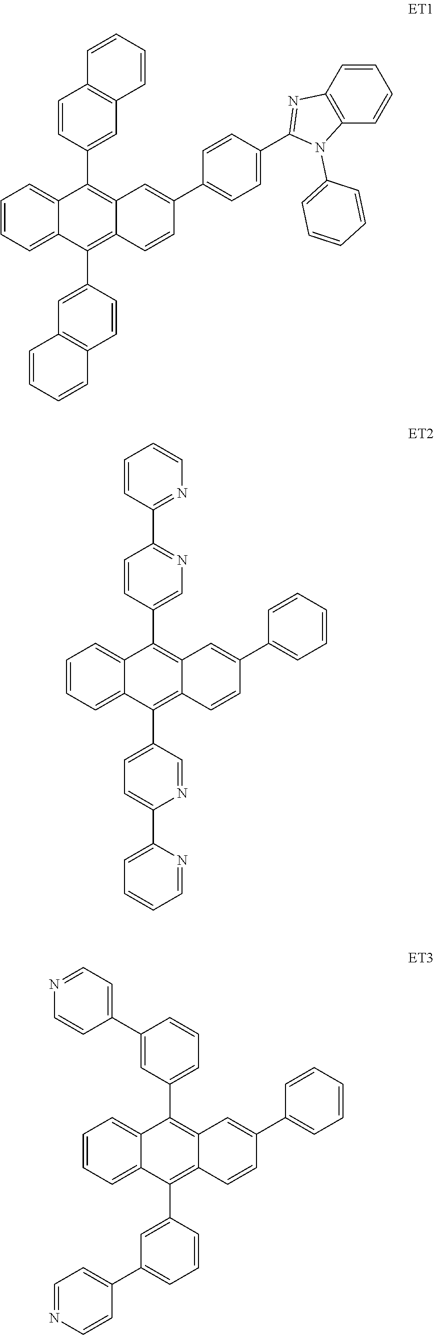 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

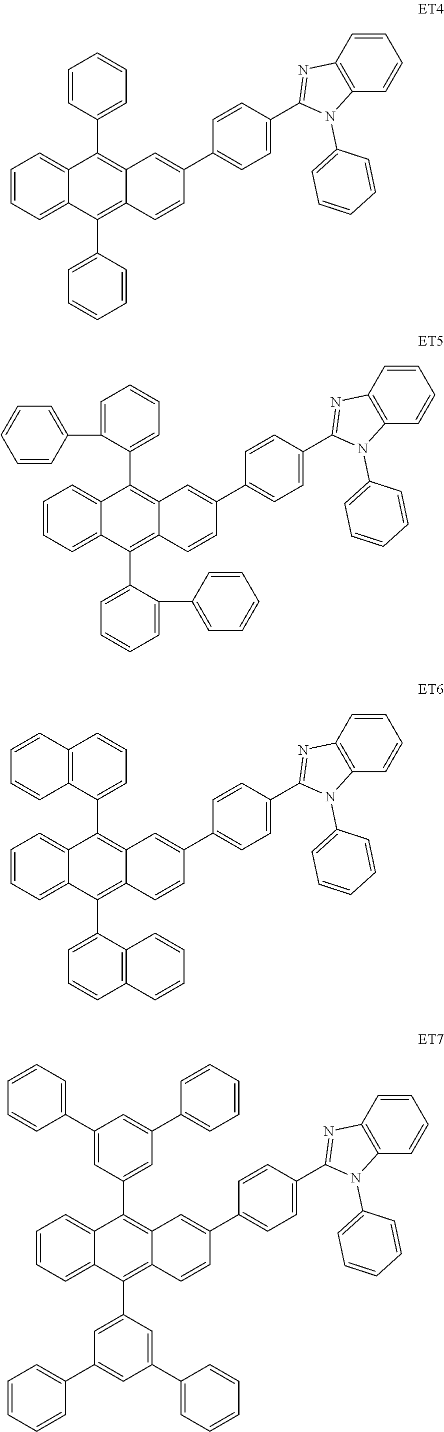 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

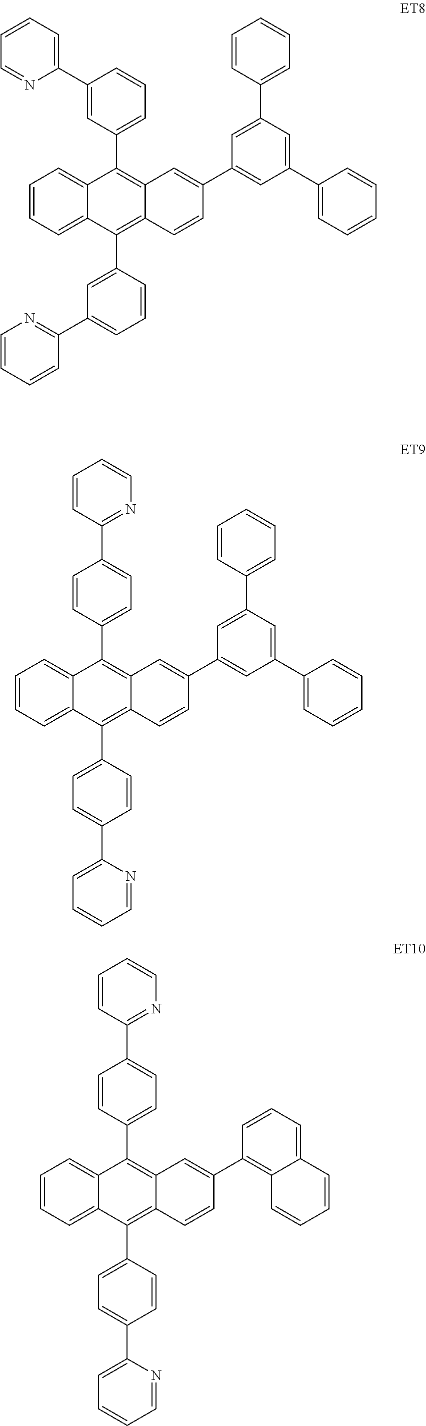

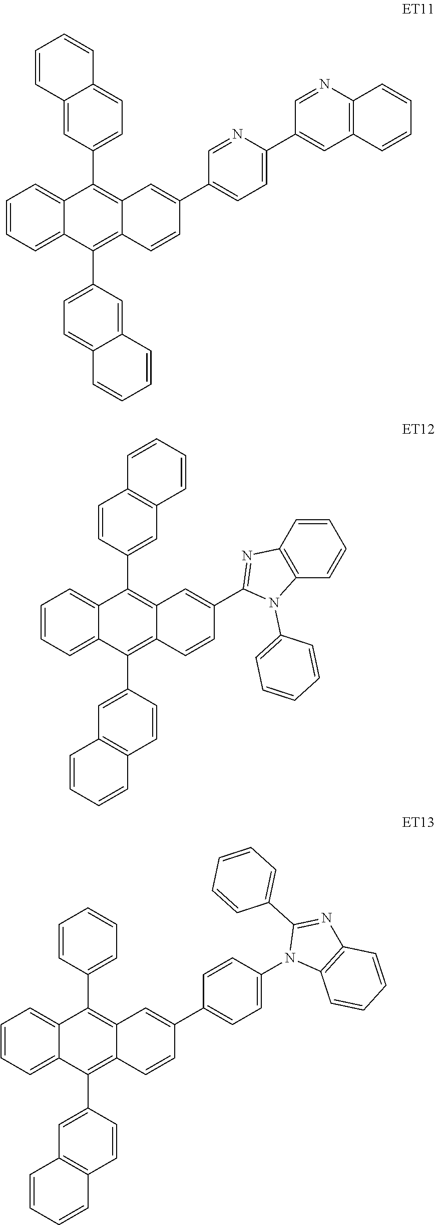 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

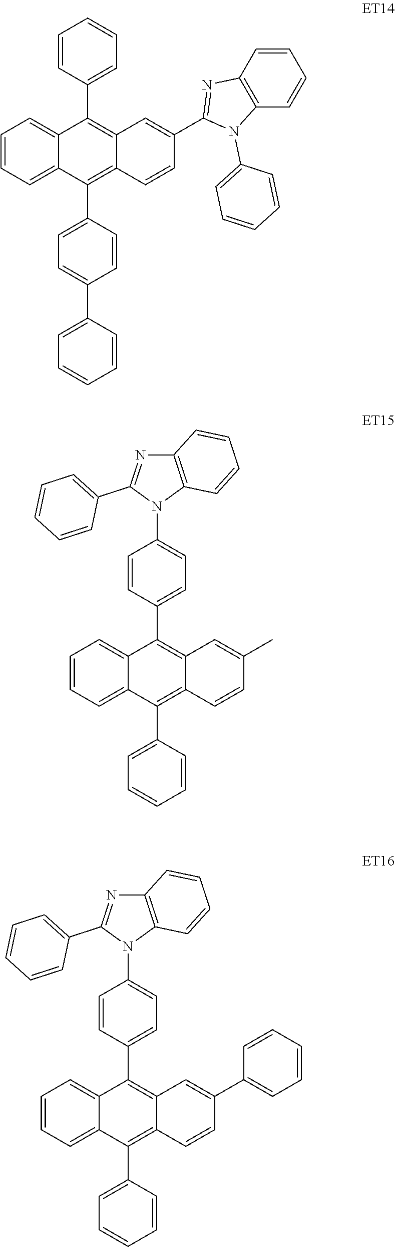 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

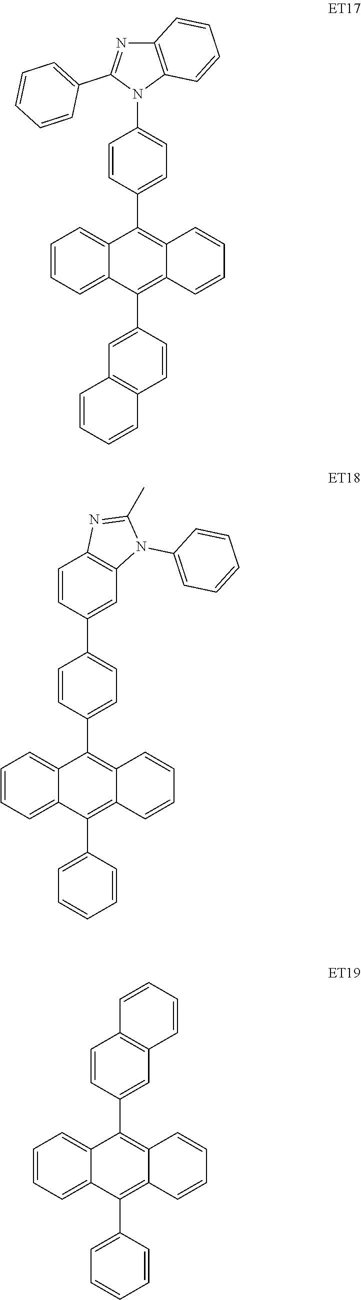

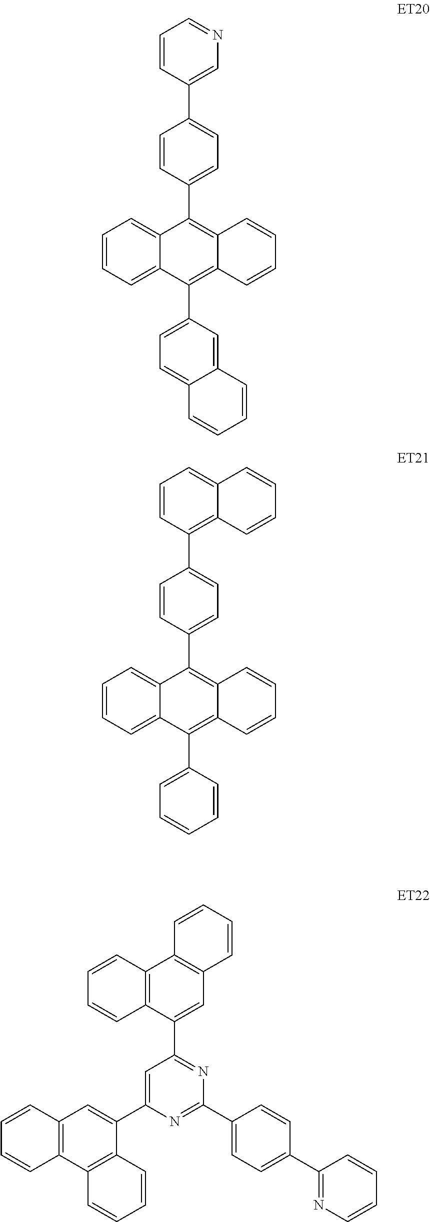

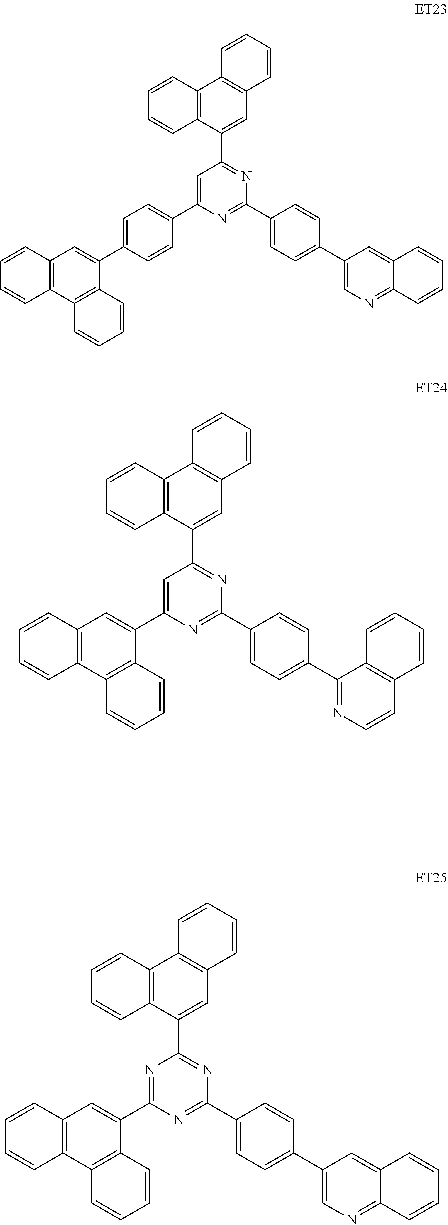 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

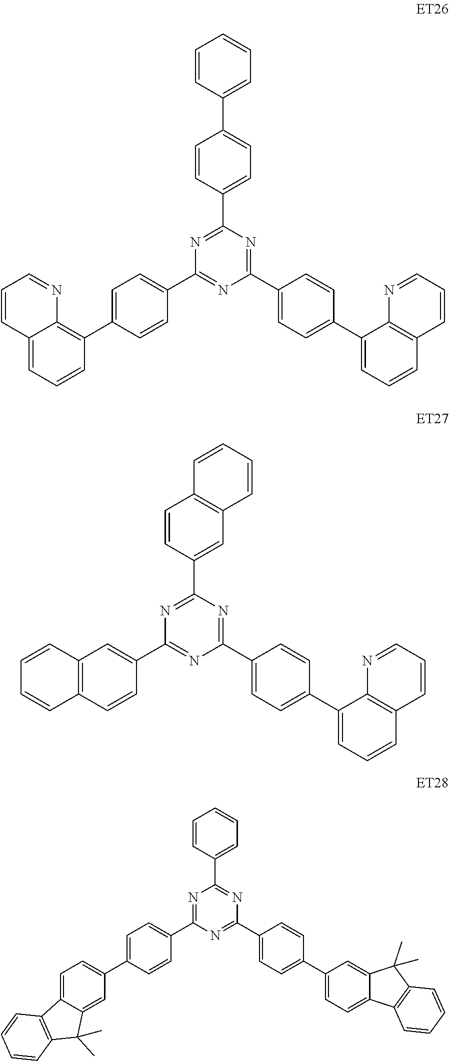 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

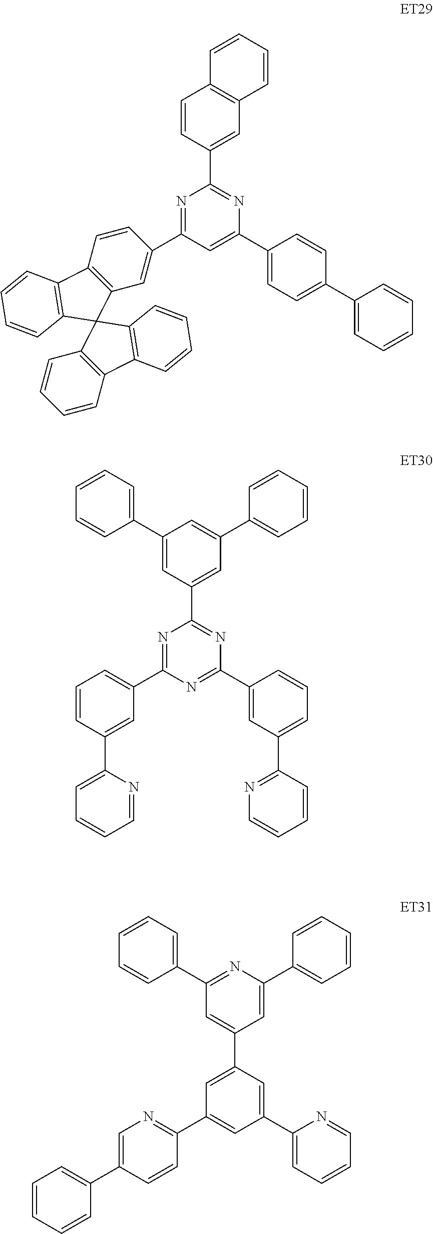 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

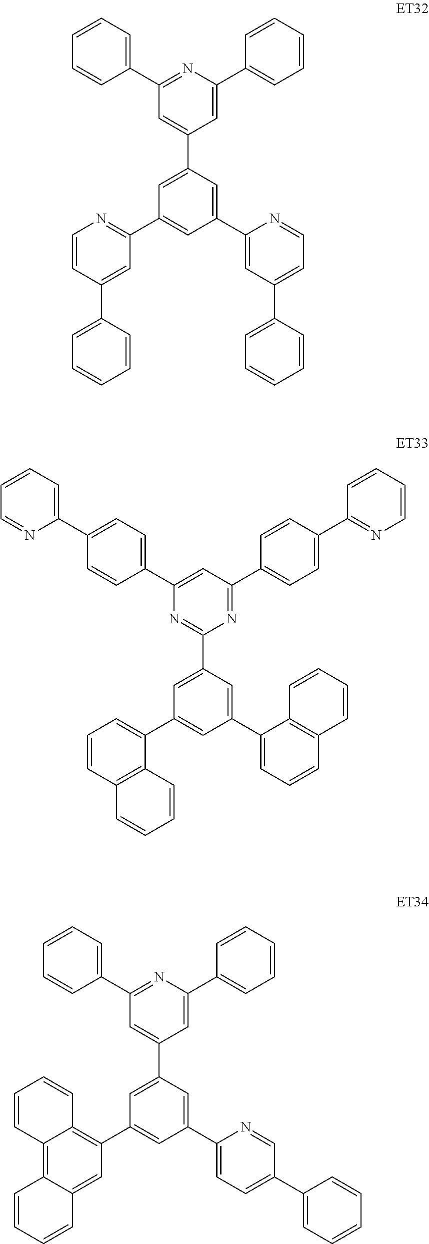 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

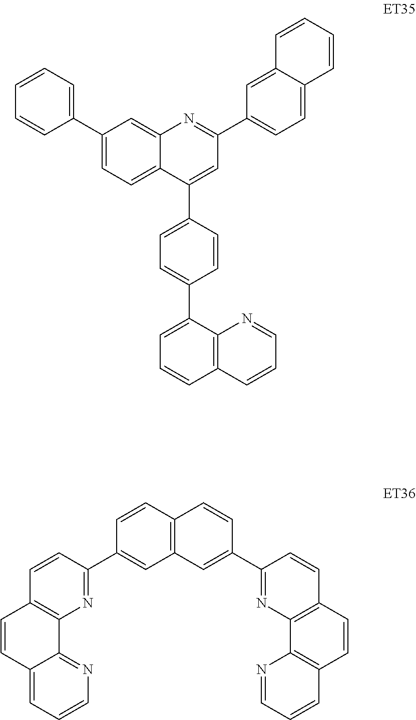 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

For example, the electron transport region ETR may include a metal halide such as LiF, NaCl, CsF, RbCl, RbI, CuI, and KI, a lanthanide metal such as Yb, and a co-deposited material of the metal halide and the lanthanide metal. For example, the electron transport region ETR may include KI:Yb, RbI:Yb, LiF:Yb, and/or the like, as a co-deposited material. In some embodiments, the electron transport region ETR may include (e.g., be formed utilizing) a metal oxide such as Li₂O or BaO, or 8-hydroxyl-lithium quinolate (Liq), and/or the like, but the embodiment of the present disclosure is not limited thereto. The electron transport region ETR may also include (e.g., be formed of) a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the herein-described materials, but the embodiment of the present disclosure is not limited thereto.

The electron transport region ETR may include the herein-described compounds of the electron transport region ETR in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the herein-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include (e.g., be formed of) a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In some embodiments, the second electrode EL2 may have a multilayer structure including a reflective film or a transflective film including (e.g., formed of) the herein-described materials, and a transparent conductive film including (e.g., formed of) ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting element ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, when the capping layer CPL includes an organic material, the organic material may include α-NPD (N,N′-Bis(naphthalen-1-yl)-N,N′-bis(phenyl)-2,2′-dimethylbenzidine), NPB, TPD, m-MTDATA, Alq3, CuPc (copper(II) phthalocyanine), N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, the embodiment of the present disclosure is not limited thereto, and the capping layer CPL may include at least one selected from among Compounds P1 to P5:

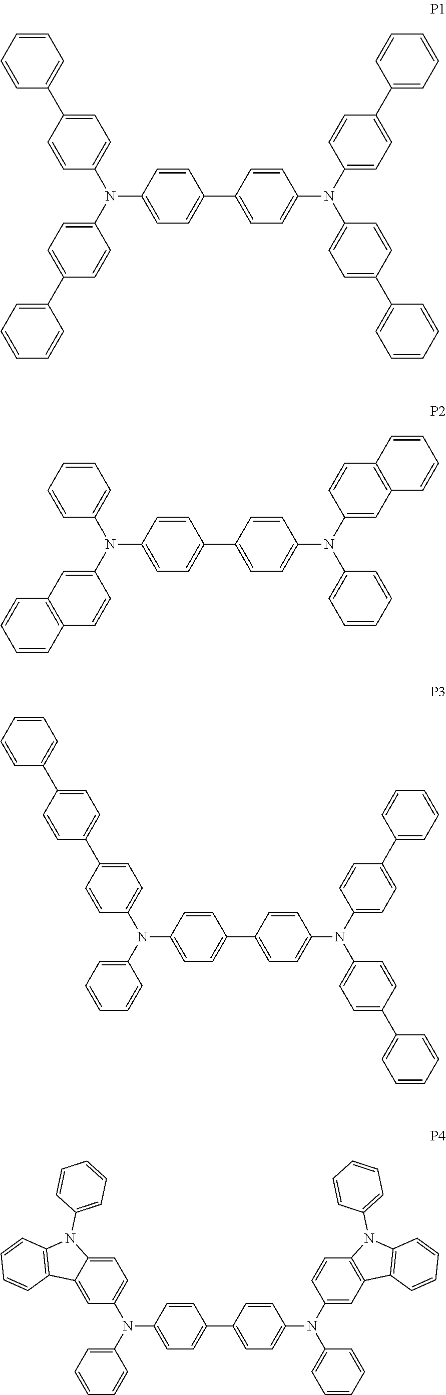 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

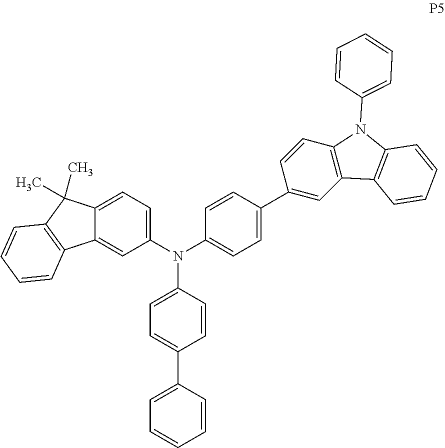 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

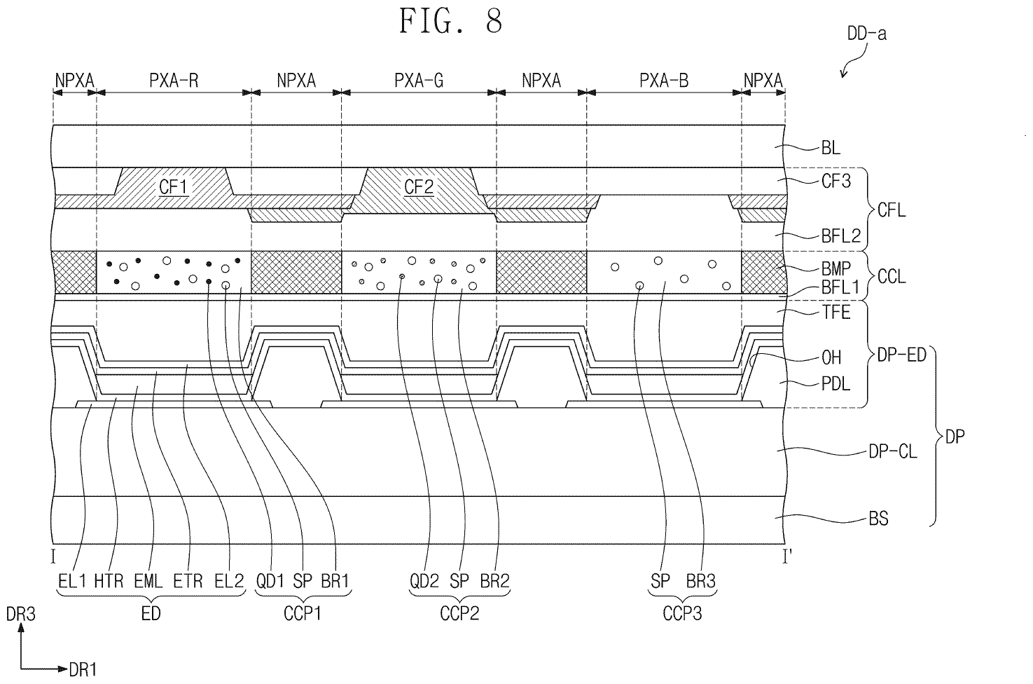

Each of FIGS. 8 to 11 is a cross-sectional view of a display device according to one or more embodiments of the present disclosure. Hereinafter, in describing the display devices of embodiments with reference to FIGS. 8 to 11, the duplicated features which have been described in FIGS. 1 to 7 are not described again, but their differences will be mainly described (e.g., in more detail).

Referring to FIG. 8, the display device DD-a according to one or more embodiments may include a display panel DP including a display element layer DP-ED, a light control layer CCL provided on the display panel DP, and a color filter layer CFL. In one or more embodiments illustrated in FIG. 8, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light emitting elements of FIGS. 3 to 7 as described herein may be equally applied to the structure of the light emitting element ED illustrated in FIG. 8. The light emitting element ED shown in FIG. 8 may include the polycyclic compound of one or more embodiments and at least one of the second to fourth compounds. Accordingly, the light emitting element ED may exhibit high efficiency and long service life.

Referring to FIG. 8, the emission layer EML may be provided in an opening OH defined in a pixel defining film PDL. For example, the emission layer EML which is divided by the pixel defining film PDL and provided corresponding to each of the light emitting regions PXA-R, PXA-G, and PXA-B may be to emit light in substantially the same wavelength range. In the display device DD-a of one or more embodiments, the emission layer EML may be to emit blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 8, divided patterns BMP may be provided between the light control parts CCP1, CCP2 and CCP3 which are spaced and/or apart from each other, but the embodiment of the present disclosure is not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described herein may be applied with respect to the quantum dots QD1 and QD2.

For example, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may be any one selected from (or include at least one selected from) among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3, respectively, in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include (e.g., be formed of) one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. For example, the barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may include (e.g., be formed of) a single layer or a plurality of layers.

In the display device DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a (e.g., any) pigment or dye. The third filter CF3 may include a polymeric photosensitive resin and may not include (e.g., may exclude) a pigment or dye. The third filter CF3 may be transparent. The third filter CF3 may include (e.g., be formed of) a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

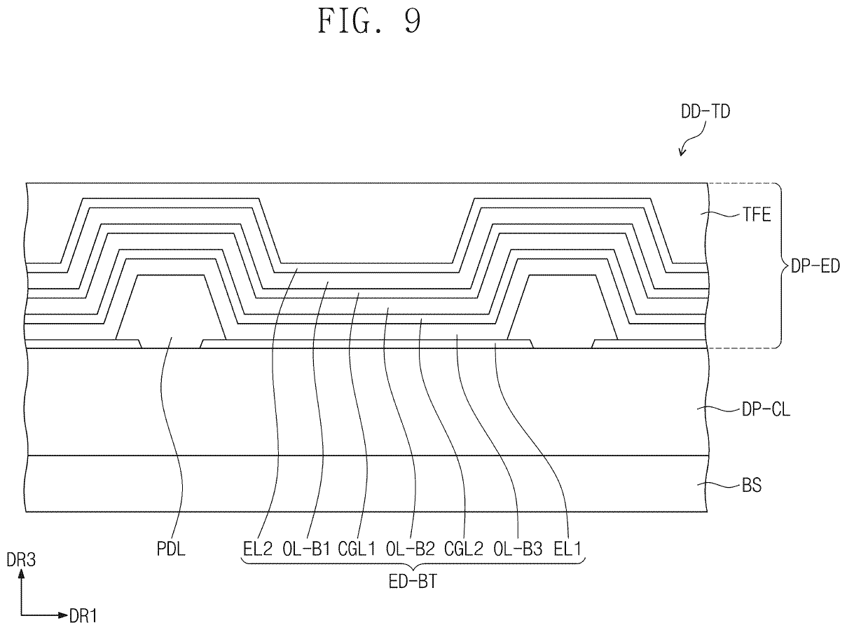

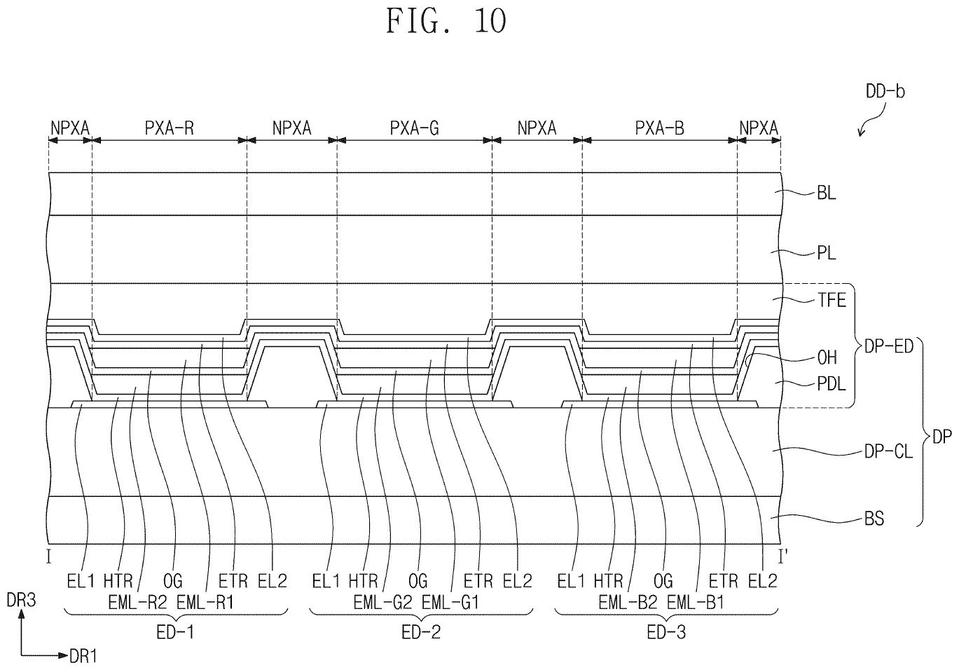

FIG. 9 is a cross-sectional view illustrating a portion of a display device according to one or more embodiments. In the display device DD-TD of one or more embodiments, the light emitting element ED-BT may include a plurality of light emitting structures OL-B1, OL-B2, and OL-B3. At least one of (e.g., selected from among) the plurality of light emitting structures OL-B1, OL-B2, and OL-B3 may include the polycyclic compound of one or more embodiments and at least one of the second to fourth compounds. Accordingly, the light emitting element ED-BT may exhibit high efficiency and long service life.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR provided with the emission layer EML (FIG. 8) located therebetween. For example, the light emitting element ED-BT included in the display device DD-TD of one or more embodiments may be a light emitting element having a tandem structure and including a plurality of emission layers.

In one or more embodiments illustrated in FIG. 9, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit white light.

Charge generation layers CGL1 and CGL2 may be respectively provided between two of the neighboring light emitting structures OL-B1, OL-B2, and OL-B3. The charge generation layers CGL1 and CGL2 may include a p-type or kind charge generation layer (e.g., p-charge generation) layer and/or an n-type charge generation (e.g., n-charge generation) layer.

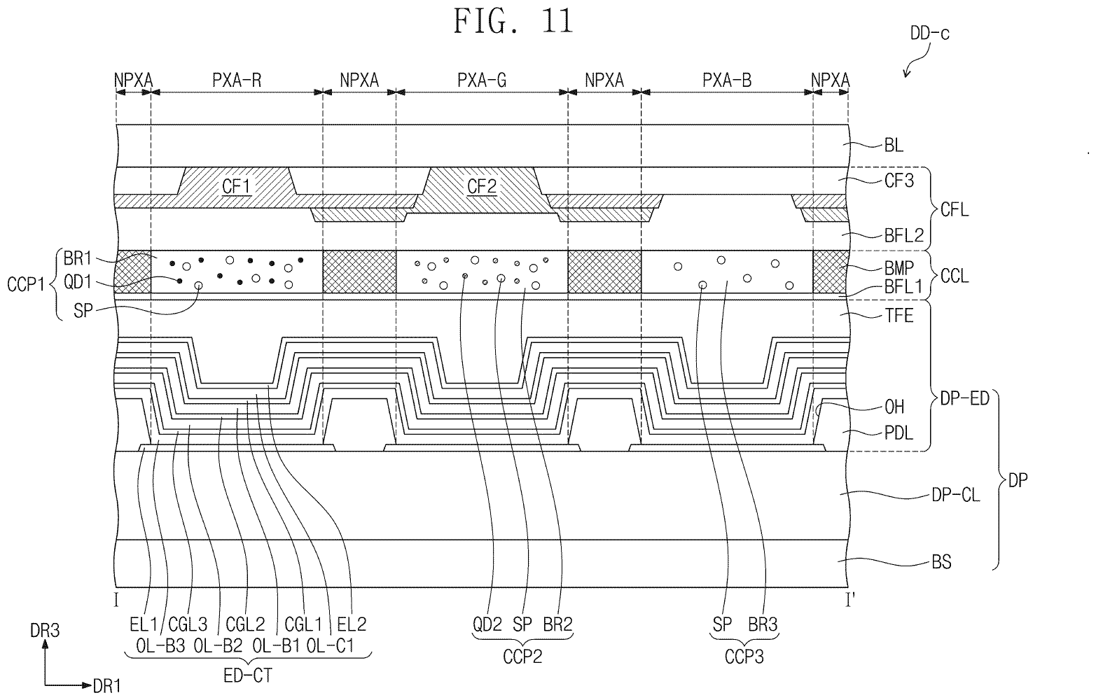

Referring to FIG. 10, the display device DD-b according to one or more embodiments may include light emitting elements ED-1, ED-2, and ED-3 in which two emission layers are stacked. At least one of the light emitting element ED-1, ED-2, and ED-3 may include the polycyclic compound of one or more embodiments and at least one of the second to fourth compounds. Accordingly, light emitting element ED-1, ED-2, and ED-3 may exhibit high efficiency and long service life.

Compared with the display device DD of one or more embodiments illustrated in FIG. 2, one or more embodiments illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the emission auxiliary part OG and the electron transport region ETR. The second red emission layer EML-R2, the second green emission layer EML-G2, and the second blue emission layer EML-B2 may be provided between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display element layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display device according to one or more embodiments may not be provided.

Unlike FIGS. 9 and 10, FIG. 11 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. At least one of the first to fourth light emitting structures OL-B1, OL-B2, OL-B3, or OL-C1 may include the polycyclic compound of one or more embodiments and at least one of the second to fourth compounds. Accordingly, the light emitting element ED-CT may exhibit high efficiency and long service life.

Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions. The charge generation layers CGL1, CGL2, and CGL3 provided between adjacent light emitting structures OL-B1, OL-B2, OL-B3, and OL-C1 may include a p-type or kind charge generation layer and/or an n-type or kind charge generation layer.

In one or more embodiments, the electronic apparatus may include a display device including a plurality of light emitting elements, and a control part which controls the display device. The electronic apparatus of one or more embodiments may be a device that is activated according to an electrical signal. The electronic apparatus may include display devices of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

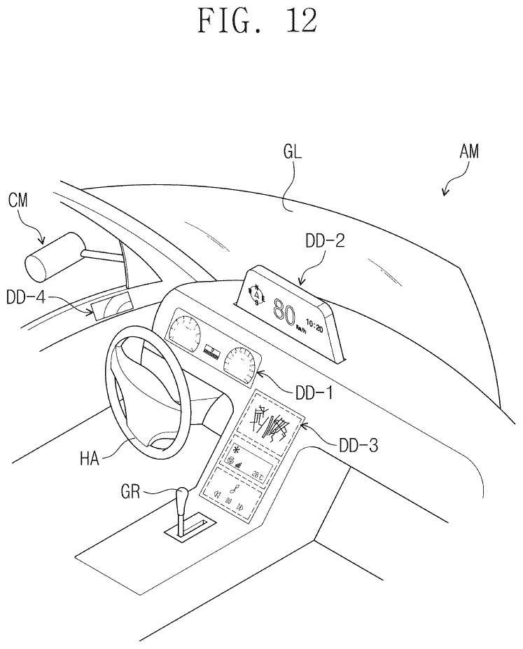

FIG. 12 is a view illustrating a vehicle AM in which first to fourth display devices DD-1, DD-2, DD-3, and DD-4 are provided. At least one among the first to fourth display devices DD-1, DD-2, DD-3, and DD-4 may include the same configuration as the display devices DD, DD-TD, DD-a, DD-b, and DD-c as described with reference to FIGS. 1, and 2, and 8 to 11.

FIG. 12 illustrates a vehicle AM, but this is an example, and the first to fourth display devices DD-1, DD-2, DD-3, and DD-4 may be provided in another transportation component such as bicycles, motorcycles, trains, ships, and airplanes. For example, at least one among the first to fourth display devices DD-1, DD-2, DD-3, and DD-4 including the same configuration as the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. For example, these are merely provided as embodiments, and thus may be employed in other electronic apparatuses unless departing from the present disclosure.

At least one of (e.g., selected from among) the first to fourth display devices DD-1, DD-2, DD-3, or DD-4 may include the light emitting element ED described with reference to FIGS. 3 to 7. At least one of (e.g., selected from among) the first to fourth display devices DD-1, DD-2, DD-3, or DD-4 may include the polycyclic compound of one or more embodiments and at least one of (e.g., selected from among) the second to fourth compounds. Accordingly, the first to fourth display devices DD-1, DD-2, DD-3, or DD-4 including the polycyclic compound of one or more embodiments and at least one of the second to fourth compounds may exhibit improved display efficiency and display service life (i.e., lifetime).

Referring to FIG. 12, the vehicle AM may include a steering wheel HA and a gear GR for driving the vehicle AM. In some embodiments, the vehicle AM may include a front window GL provided so as to face the driver.

The first display device DD-1 may be provided in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display device DD-2 may be provided in a second region facing the driver's seat and overlapping the front window GL. The driver's seat may be a seat in which the steering wheel HA is provided. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be provided in a third region adjacent to the gear GR. For example, the third display device DD-3 may be provided between the driver's seat and the passenger seat and may be a center information display (CID) for a vehicle for displaying third information. The passenger seat may be a seat spaced and/or apart from the driver's seat with the gear GR provided therebetween. The third information may include information about traffic (e.g., navigation information), playing music or radio or a video (or an image), temperatures inside the vehicle AM, and/or the like.

The fourth display device DD-4 may be spaced and/or apart from the steering wheel HA and the gear GR, and may be provided in a fourth region adjacent to the side of the vehicle AM. For example, the fourth display device DD-4 may be a digital side-view mirror which displays fourth information. The fourth display device DD-4 may display an image outside the vehicle AM taken by a camera module CM provided outside the vehicle AM. The fourth information may include an image outside the vehicle AM.

The herein-described first to fourth information may be examples, and the first to fourth display devices DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, with reference to Examples and Comparative Examples, a polycyclic compound and a light emitting element of one or more embodiments of the present disclosure will be specifically described. For example, Examples are shown only for the understanding of the present disclosure, and the scope of the present disclosure is not limited thereto.

### Examples

### 1. Synthesis of Polycyclic Compounds

A process of synthesizing polycyclic compounds according to one or more embodiments of the present disclosure will be described by providing a process of synthesizing Compound 4, Compound 5, Compound 115, Compound 120, Compound 169, Compound 217, and Compound 218 as an example. For example, a process of synthesizing polycyclic compounds, will be described in more detail hereinafter as an example, and thus a process of synthesizing compounds according to one or more embodiments of the present disclosure is not limited to the Examples.

### (1) Synthesis of Compound 4

Compound 4 according to one or more embodiments may be synthesized by, for example, a process of Reaction Formula 1.

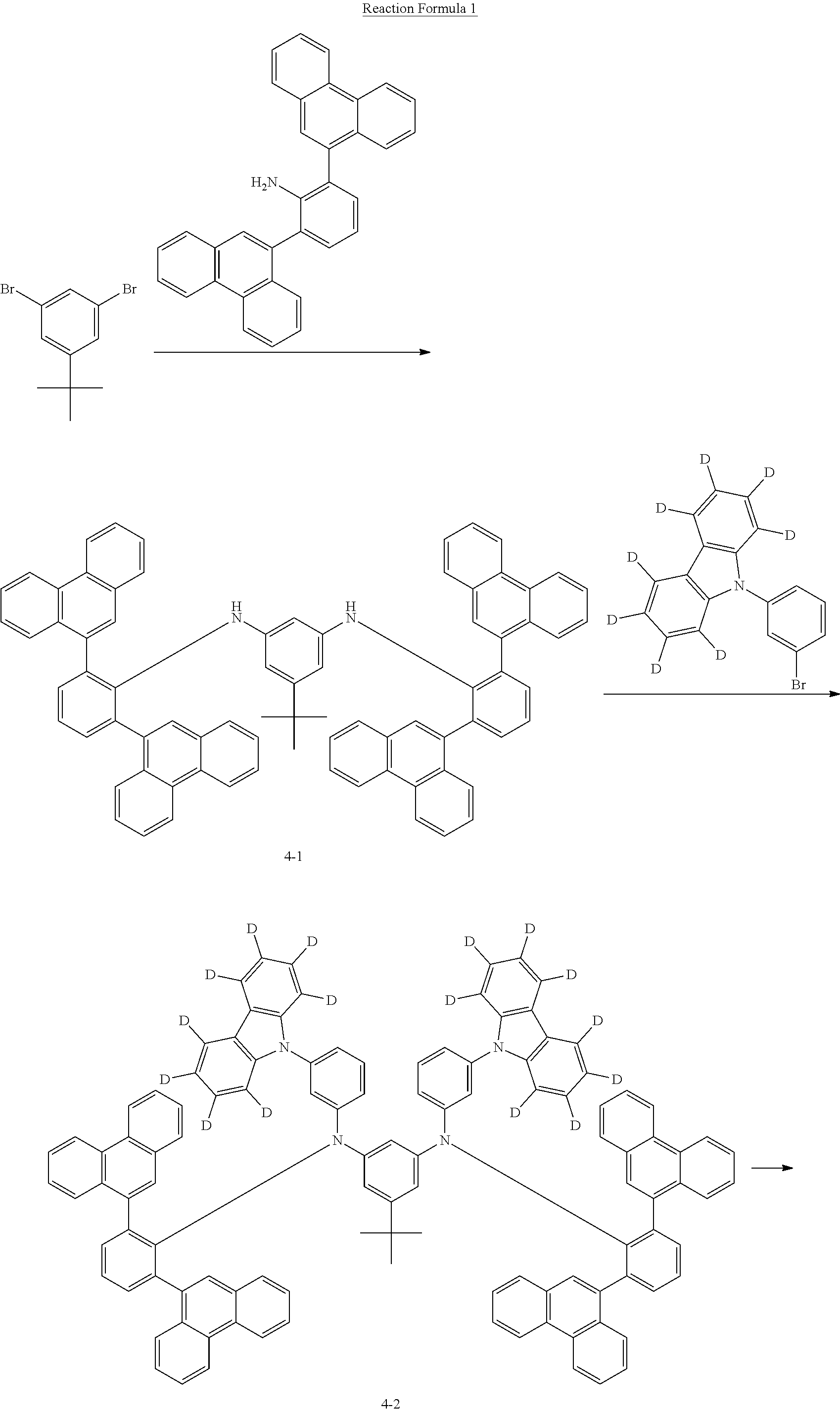

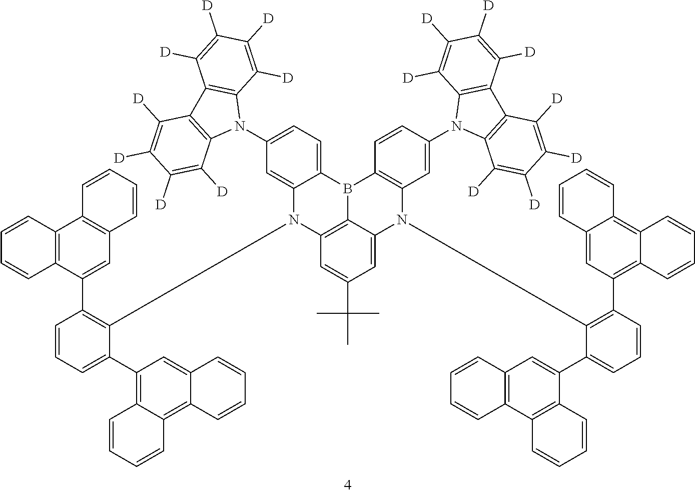 [SMILES: [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cc3ccccc3c3ccccc23)cccc1-c1cc2ccccc2c2ccccc12]

### Synthesis of Intermediate 4-1

1,3-dibromo-5-(tert-butyl)benzene (1 eq), 2,6-di(phenanthren-9-yl)aniline (2 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. The resulting product was purified through column chromatography with methylene chloride (MC) and n-hexane to obtain Intermediate 4-1. (Yield: 74%)

### Synthesis of Intermediate 4-2

Intermediate 4-1 (1 eq), 9-(3-bromophenyl)-9H-carbazole-1,2,3,4,5,6,7,8-d8 (4 eq), tris(dibenzylideneacetone)dipalladium(0) (0.2 eq), tri-tert-butylphosphine (0.4 eq), and sodium tert-butoxide (5 eq) were dissolved in o-xylene and then stirred at 150° C. for 60 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 4-2. (Yield: 28

### Synthesis of Compound 4

Intermediate 4-2 (1 eq) was dissolved in ortho dichlorobenzene, and cooled to 0° C., and then BBr₃ (4 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 4. (Yield: 2%)

### (2) Synthesis of Compound 5

Compound 5 according to one or more embodiments may be synthesized by, for example, a process of Reaction Formula 2.

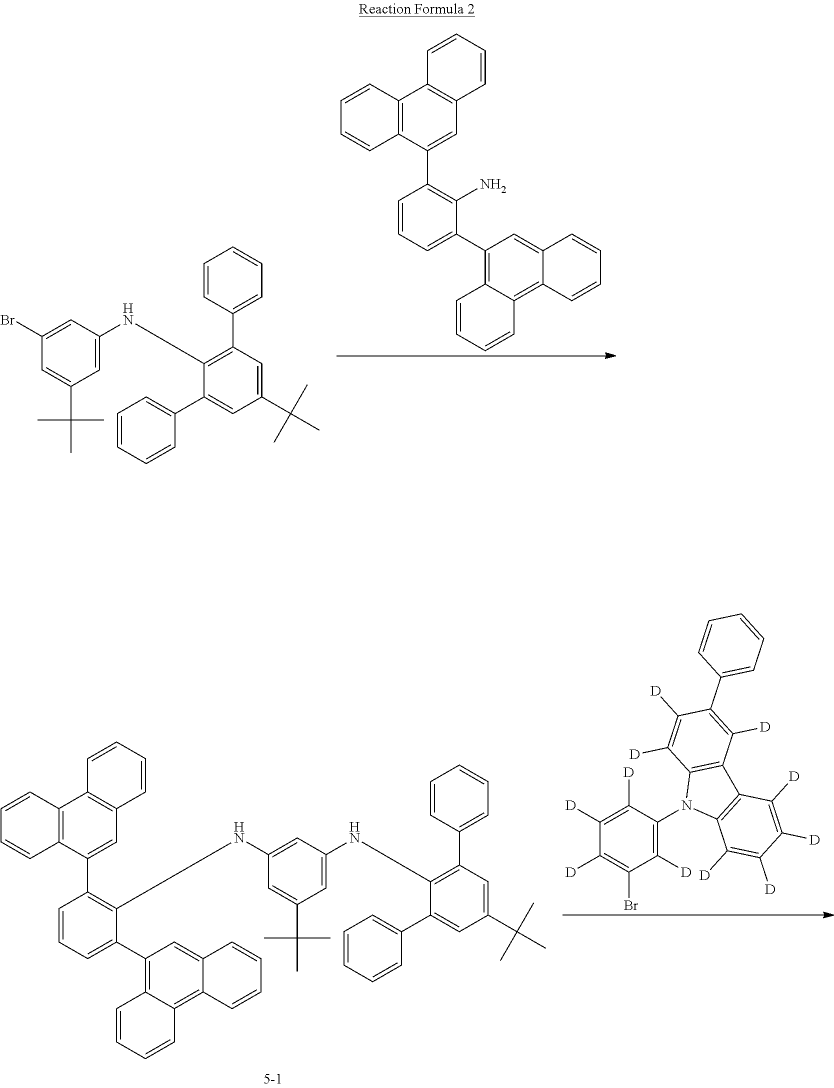 [SMILES: CC(C)(C)c1cc(Br)cc(Nc2c(-c3ccccc3)cc(C(C)(C)C)cc2-c2ccccc2)c1 ; Nc1c(-c2cc3ccccc3c3ccccc23)cccc1-c1cc2ccccc2c2ccccc12 ; CC(C)(C)c1cc(Nc2c(-c3ccccc3)cc(C(C)(C)C)cc2-c2ccccc2)cc(Nc2c(-c3cc4ccccc4c4ccccc34)cccc2-c2cc3ccccc3c3ccccc23)c1 ; [2H]c1c([2H])c(Br)c([2H])c(-n2c3c([2H])c([2H])c([2H])c([2H])c3c3c([2H])c(-c4ccccc4)c([2H])c([2H])c32)c1[2H]]

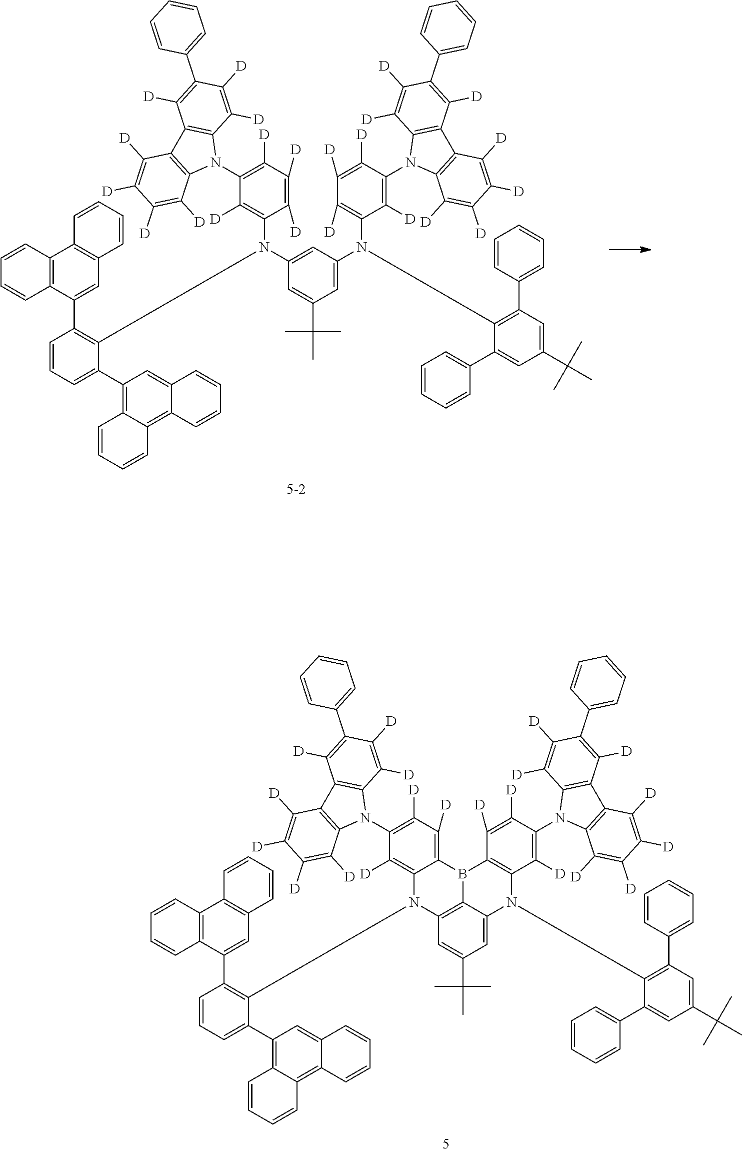

### Synthesis of Intermediate 5-1

N-(3-bromo-5-(tert-butyl)phenyl)-5′-(tert-butyl)-[1,1′:3′,1″-terphenyl]-2′-amine (1 eq), 2,6-di(phenanthren-9-yl)aniline (1.1 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 5-1. (Yield: 81%)

### Synthesis of Intermediate 5-2

Intermediate 5-1 (1 eq), 9-(3-bromophenyl-2,4,5,6-d4)-3-phenyl-9H-carbazole-1,2,4,5,6,7,8-d7 (4 eq), tris(dibenzylideneacetone)dipalladium(0) (0.2 eq), tri-tert-butylphosphine (0.4 eq), and sodium tert-butoxide (5 eq) were dissolved in o-xylene and then stirred at 150° C. for 60 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 5-2. (Yield: 26%)

### Synthesis of Compound 5

Intermediate 5-2 (1 eq) was dissolved in ortho dichlorobenzene, and cooled to 0° C., and then BBr₃ (4 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 5. (Yield: 3%)

### (3) Synthesis of Compound 115

Compound 115 according to one or more embodiments may be synthesized by, for example, a process of Reaction Formula 3.

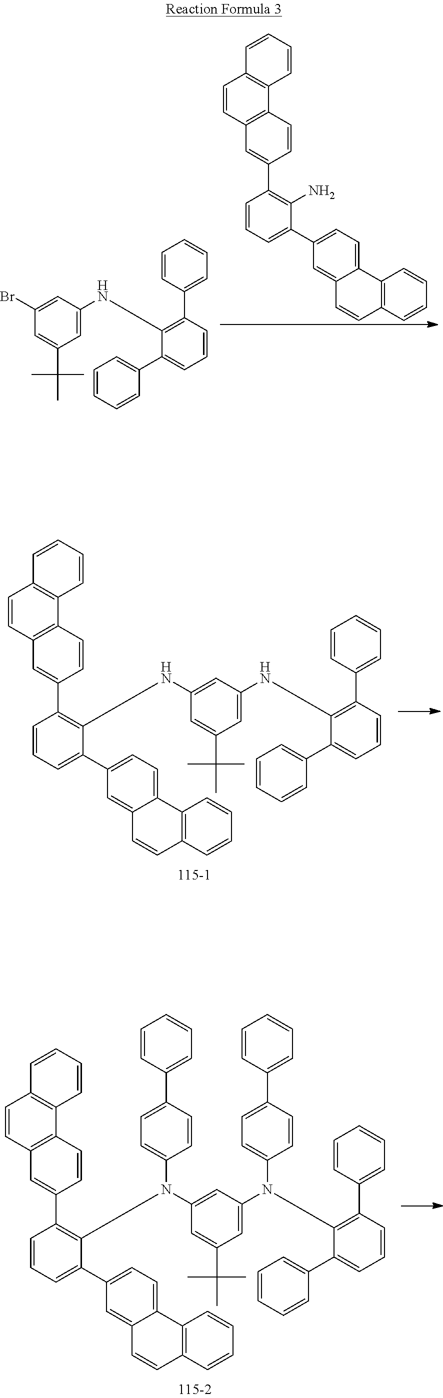 [SMILES: CC(C)(C)c1cc(Br)cc(Nc2c(-c3ccccc3)cccc2-c2ccccc2)c1 ; Nc1c(-c2ccc3c(ccc4ccccc43)c2)cccc1-c1ccc2c(ccc3ccccc32)c1 ; CC(C)(C)c1cc(Nc2c(-c3ccccc3)cccc2-c2ccccc2)cc(Nc2c(-c3ccc4c(ccc5ccccc54)c3)cccc2-c2ccc3c(ccc4ccccc43)c2)c1 ; CC(C)(C)c1cc(N(c2ccc(-c3ccccc3)cc2)c2c(-c3ccccc3)cccc2-c2ccccc2)cc(N(c2ccc(-c3ccccc3)cc2)c2c(-c3ccc4c(ccc5ccccc54)c3)cccc2-c2ccc3c(ccc4ccccc43)c2)c1]

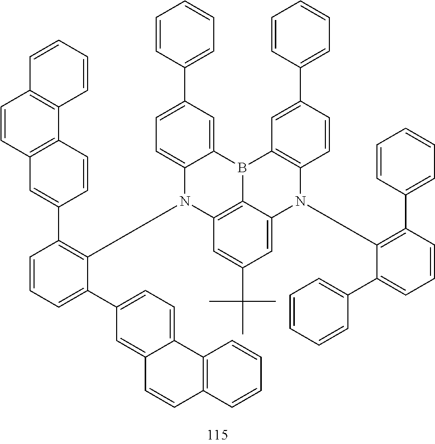 [SMILES: CC(C)(C)c1cc2c3c(c1)N(c1c(-c4ccc5c(ccc6ccccc65)c4)cccc1-c1ccc4c(ccc5ccccc54)c1)c1ccc(-c4ccccc4)cc1B3c1cc(-c3ccccc3)ccc1N2c1c(-c2ccccc2)cccc1-c1ccccc1]

### Synthesis of Intermediate 115-1

N-(3-bromo-5-(tert-butyl)phenyl)-[1,1′:3′,1″-terphenyl]-2′-amine (1 eq), 2,6-di(phenanthren-2-yl)aniline (1.1 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 115-1. (Yield: 73%)

### Synthesis of Intermediate 115-2

Intermediate 115-1 (1 eq), 4-iodo-1,1′-biphenyl (4eq), Tris(dibenzylideneacetone)dipalladium(0) (0.2 eq), tri-tert-butylphosphine (0.4 eq), and sodium tert-butoxide (5 eq) were dissolved in o-xylene and then stirred at 150° C. for 60 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 115-2. (Yield: 45%)

### Synthesis of Compound 115

Intermediate 115-2 (1 eq) was dissolved in ortho dichlorobenzene, and cooled to 0° C., and then BBr₃ (4 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 115. (Yield: 7%)

### (4) Synthesis of Compound 120

Compound 120 according to one or more embodiments may be synthesized by, for example, processes of Reaction Formula 4.

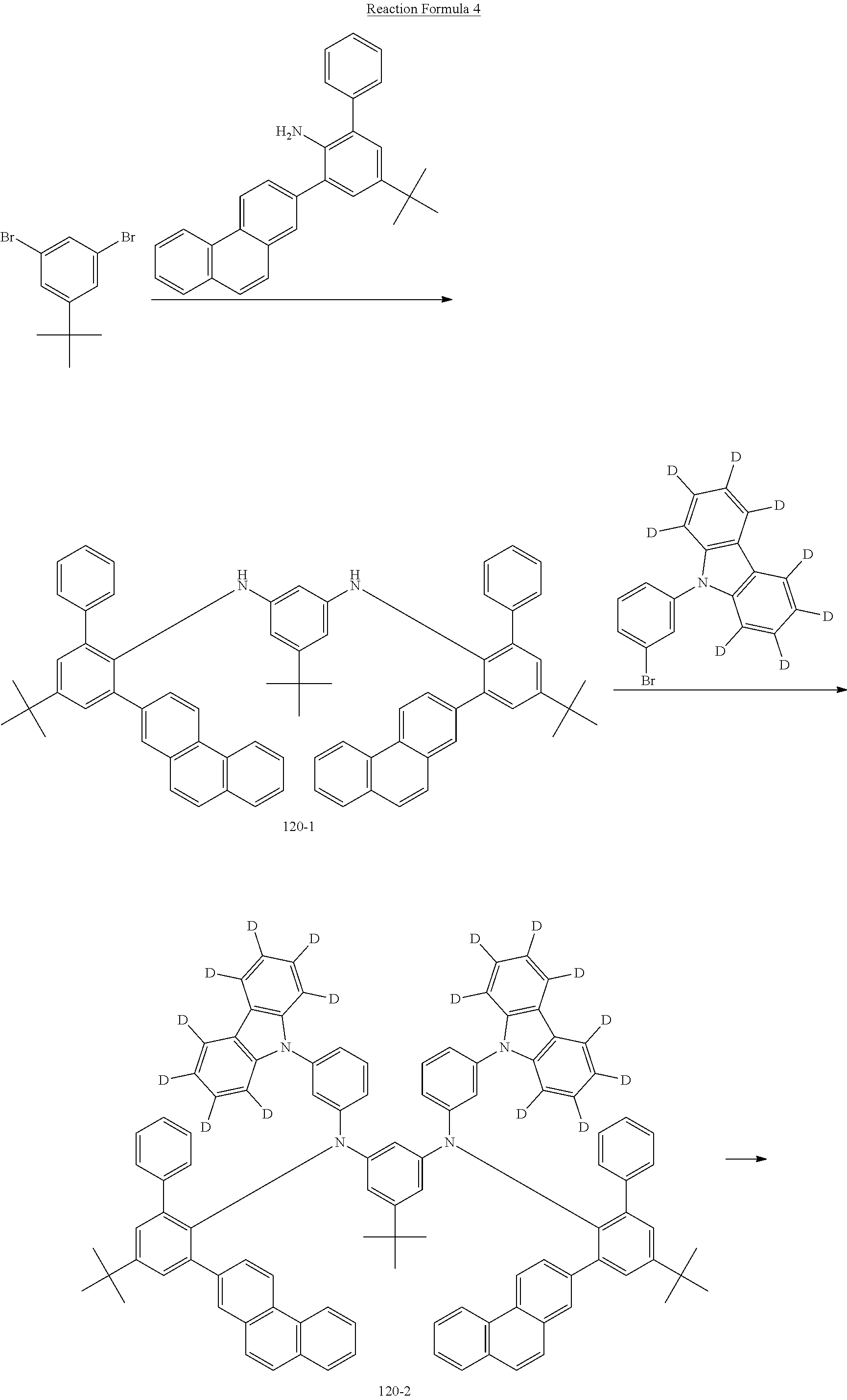

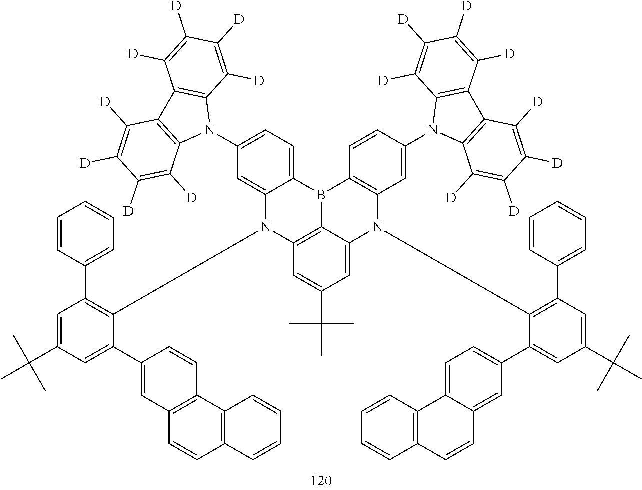 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccc3c(ccc4ccccc43)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1ccc2c(ccc3ccccc32)c1]

### Synthesis of Intermediate 120-1

1,3-dibromo-5-(tert-butyl)benzene (1 eq), 5-(tert-butyl)-3-(phenanthren-2-yl)-[1,1′-biphenyl]-2-amine (2 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 120-1. (Yield: 77%)

### Synthesis of Intermediate 120-2

Intermediate 120-1 (1 eq), 9-(3-bromophenyl)-9H-carbazole-1,2,3,4,5,6,7,8-d8 (4 eq), tris(dibenzylideneacetone)dipalladium(0) (0.2 eq), tri-tert-butylphosphine (0.4 eq), and sodium tert-butoxide (5 eq) were dissolved in o-xylene and then stirred at 150° C. for 60 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 120-2. (Yield: 31%)

### Synthesis of Compound 120

Intermediate 120-2 (1 eq) was dissolved in ortho dichlorobenzene, and cooled to 0° C., and then BBr₃ (4 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 120. (Yield: 5%)

### (5) Synthesis of Compound 169

Compound 169 according to one or more embodiments may be synthesized by, for example, a process of Reaction Formula 5.

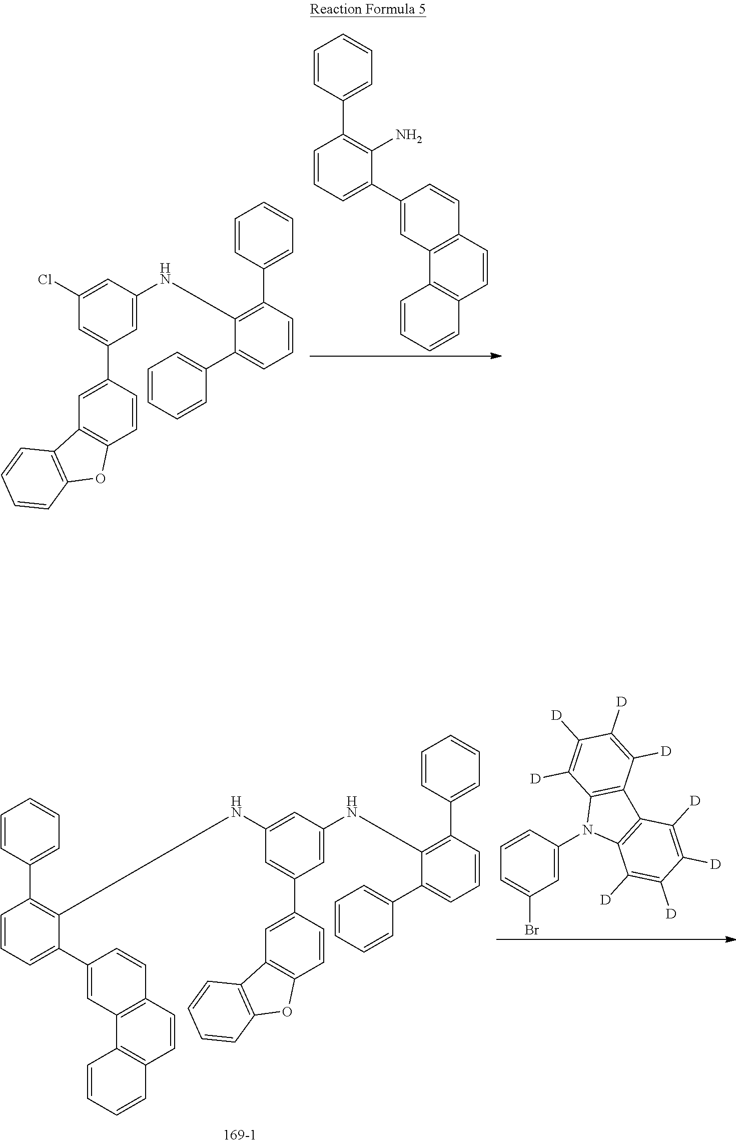

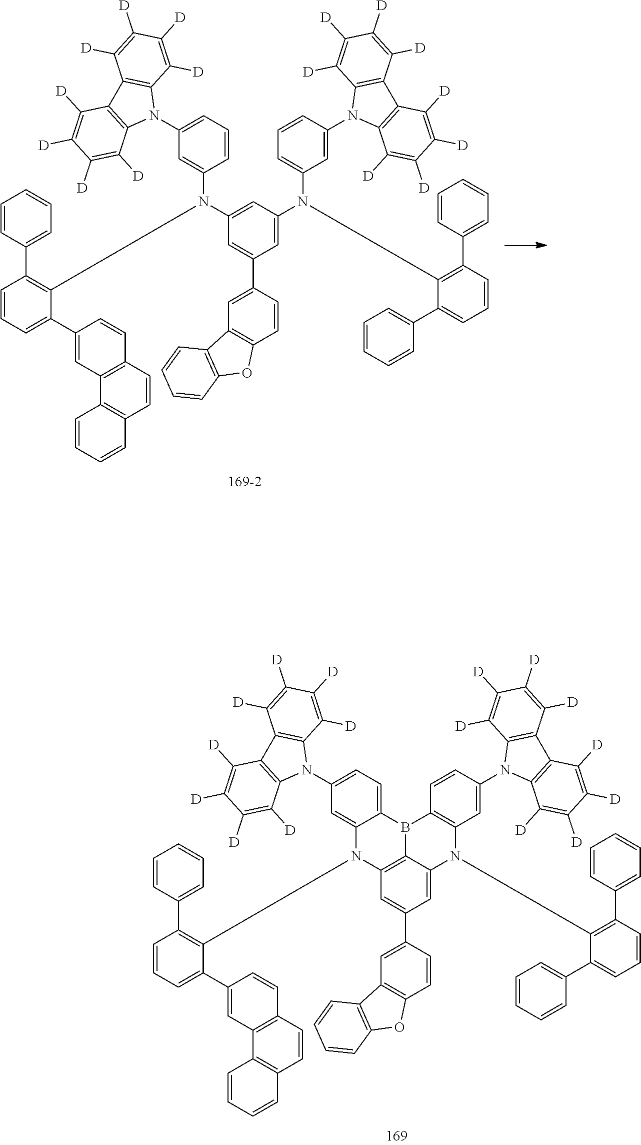

### Synthesis of Intermediate 169-1

N-(3-chloro-5-(dibenzo[b,d]furan-2-yl)phenyl)-[1,1′:3′,1″-terphenyl]-2′-amine (1 eq), 3-(phenanthren-3-yl)-[1,1′-biphenyl]-2-amine (1.1 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 169-1. (Yield: 80%)

### Synthesis of Intermediate 169-2

Intermediate 169-1 (1 eq), 9-(3-bromophenyl)-9H-carbazole-1,2,3,4,5,6,7,8-d8 (4 eq), tris(dibenzylideneacetone)dipalladium(0) (0.2 eq), tri-tert-butylphosphine (0.4 eq), and sodium tert-butoxide (5 eq) were dissolved in o-xylene and then stirred at 150° C. for 60 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 169-2. (Yield: 32%)

### Synthesis of Compound 169

Intermediate 169-2 (1 eq) was dissolved in ortho dichlorobenzene, and cooled to 0° C., and then BBr₃ (4 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 169. (Yield: 4%)

### (6) Synthesis of Compound 217

Compound 217 according to one or more embodiments may be synthesized by, for example, processes of Reaction Formula 6.

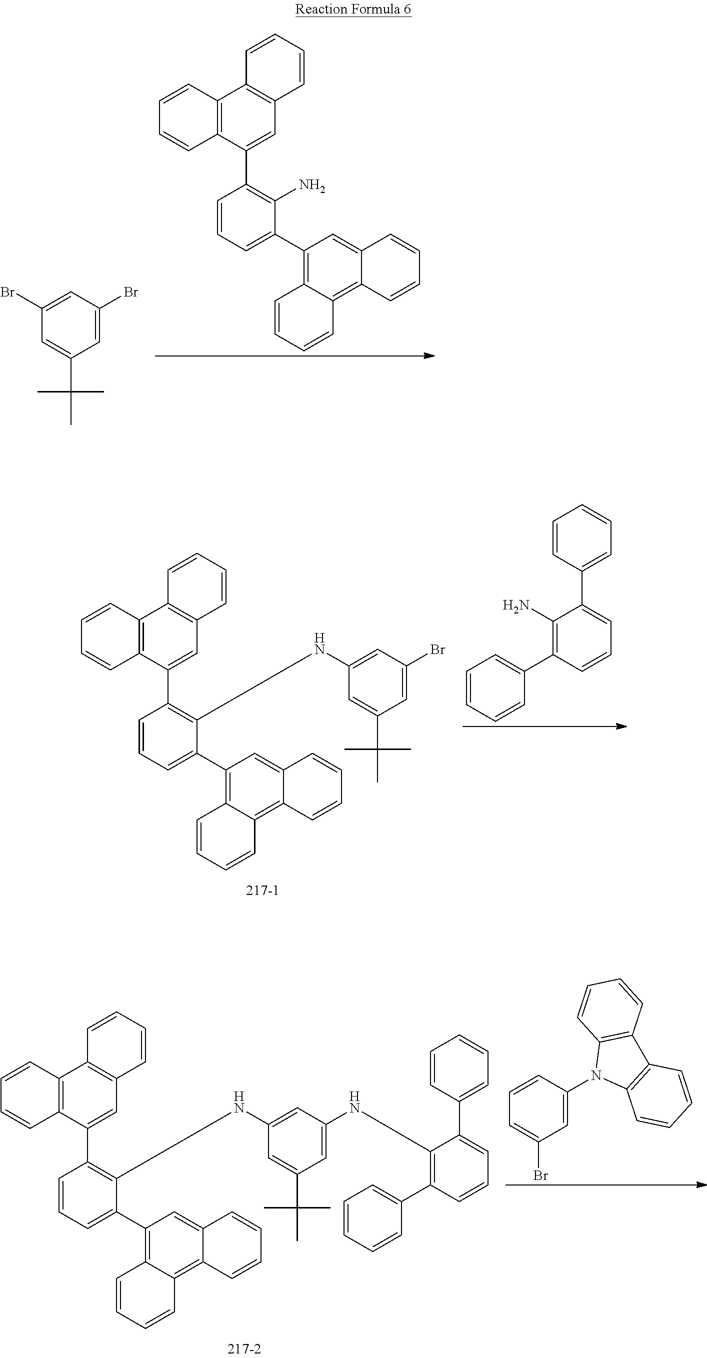

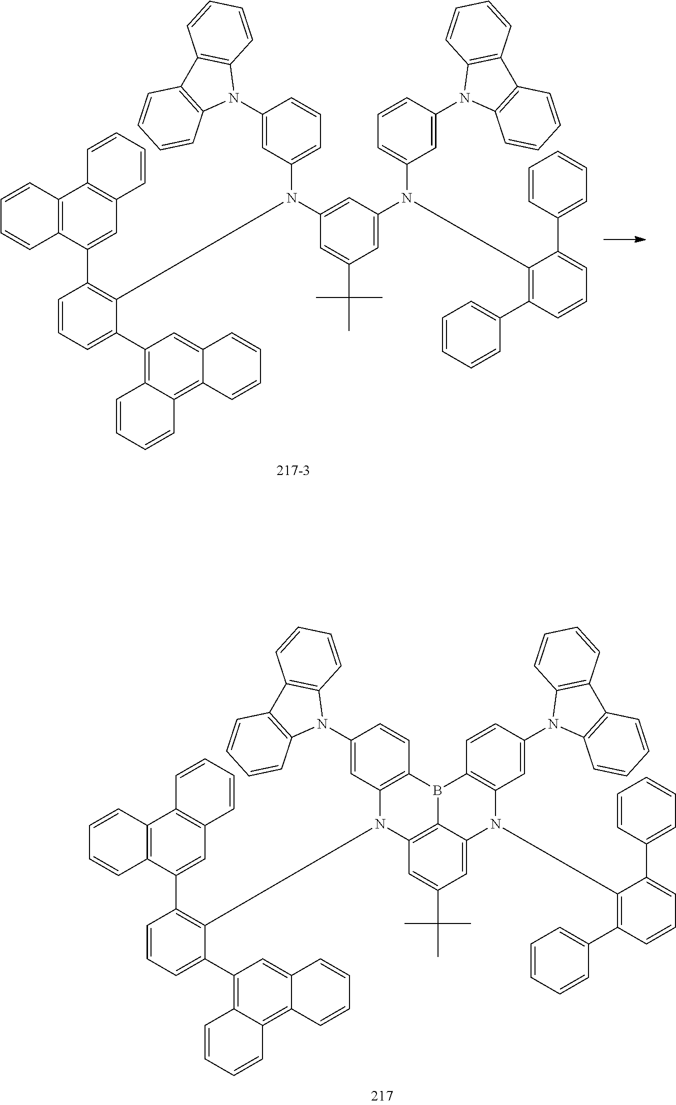 [SMILES: CC(C)(C)c1cc(N(c2cccc(-n3c4ccccc4c4ccccc43)c2)c2c(-c3ccccc3)cccc2-c2ccccc2)cc(N(c2cccc(-n3c4ccccc4c4ccccc43)c2)c2c(-c3cc4ccccc4c4ccccc34)cccc2-c2cc3ccccc3c3ccccc23)c1 ; CC(C)(C)c1cc2c3c(c1)N(c1c(-c4cc5ccccc5c5ccccc45)cccc1-c1cc4ccccc4c4ccccc14)c1cc(-n4c5ccccc5c5ccccc54)ccc1B3c1ccc(-n3c4ccccc4c4ccccc43)cc1N2c1c(-c2ccccc2)cccc1-c1ccccc1]

### Synthesis of Intermediate 217-1

1,3-dibromo-5-(tert-butyl)benzene (1 eq), 2,6-di(phenanthren-9-yl)aniline (0.9 eq), tris(dibenzylideneacetone)dipalladium(0) (0.05 eq), BINAP (0.1 eq), and sodium tert-butoxide (3 eq) were dissolved in toluene and then stirred at 90° C. for 12 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 217-1. (Yield: 67%)

### Synthesis of Intermediate 217-2

Intermediate 217-1 (1 eq), [1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 12 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 217-2. (Yield: 81%)

### Synthesis of Intermediate 217-3

Intermediate 217-2 (1 eq), 9-(3-bromophenyl)-9H-carbazole (3 eq), tris(dibenzylideneacetone)dipalladium(0) (0.15 eq), tri-tert-butylphosphine (0.3 eq), and sodium tert-butoxide (5 eq) were dissolved in o-xylene and then stirred at 150° C. for 48 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 217-3. (Yield: 33%)

### Synthesis of Compound 217

Intermediate 217-3 (1 eq) was dissolved in ortho dichlorobenzene, and cooled to 0° C., and then BBr₃ (3 eq) was slowly injected thereto in a nitrogen atmosphere. After completion of adding dropwise, the temperature was raised to 180° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 217. (Yield: 6%)

### (7) Synthesis of Compound 218

Compound 218 according to one or more embodiments may be synthesized by, for example, processes of Reaction Formula 7.

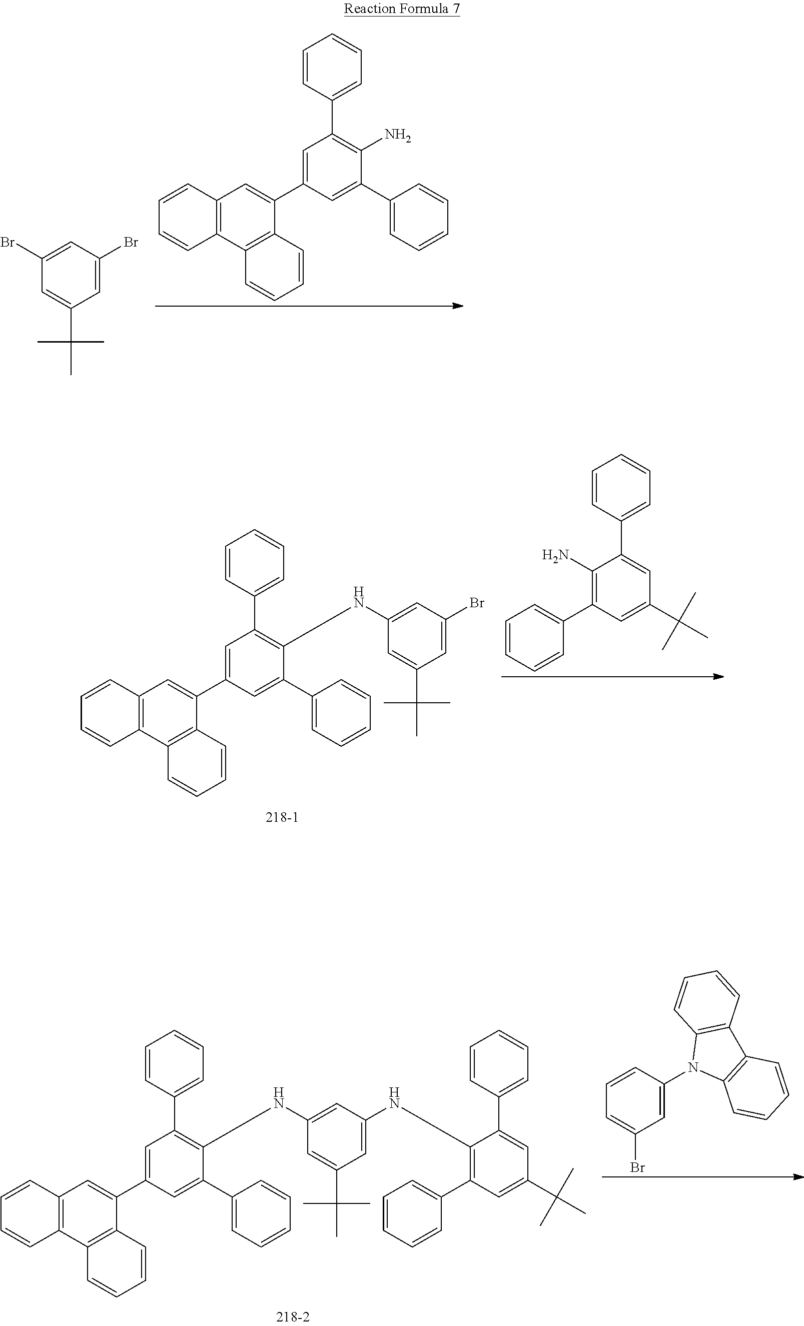

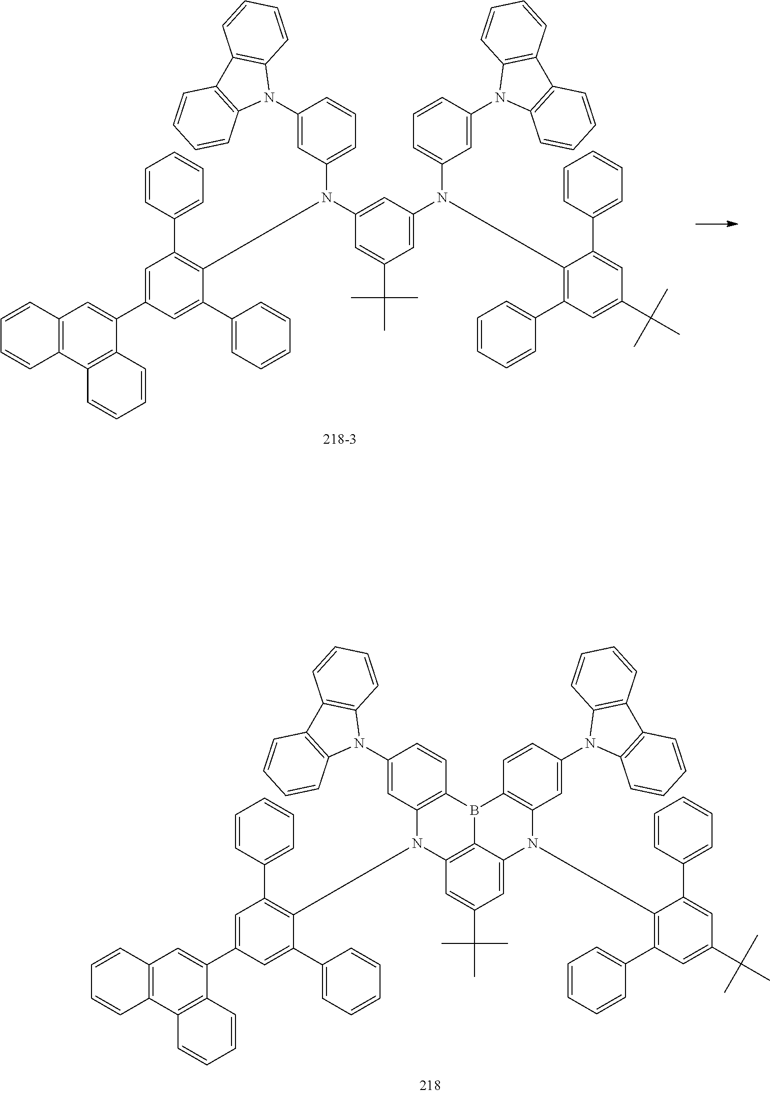 [SMILES: CC(C)(C)c1cc(N(c2cccc(-n3c4ccccc4c4ccccc43)c2)c2c(-c3ccccc3)cc(-c3cc4ccccc4c4ccccc34)cc2-c2ccccc2)cc(N(c2cccc(-n3c4ccccc4c4ccccc43)c2)c2c(-c3ccccc3)cc(C(C)(C)C)cc2-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(-c5cc6ccccc6c6ccccc56)cc4-c4ccccc4)c4cc(C(C)(C)C)cc2c43)c(-c2ccccc2)c1]

### Synthesis of Intermediate 218-1

1,3-dibromo-5-(tert-butyl)benzene (1 eq), 5′-(phenanthren-9-yl)-[1,1′:3′,1″-terphenyl]-2′-amine (0.9 eq), tris(dibenzylideneacetone)dipalladium(0) (0.05 eq), BINAP (0.1 eq), and sodium tert-butoxide (3 eq) were dissolved in toluene and then stirred at 90° C. for 12 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 218-1. (Yield: 58%)

### Synthesis of Intermediate 218-2

Intermediate 218-1 (1 eq), 5′-(tert-butyl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 12 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 218-2. (Yield: 77%)

### Synthesis of Intermediate 218-3

Intermediate 218-2 (1 eq), 9-(3-bromophenyl)-9H-carbazole (3 eq), tris(dibenzylideneacetone)dipalladium(0) (0.15 eq), tri-tert-butylphosphine (0.3 eq), and sodium tert-butoxide (5 eq) were dissolved in o-xylene and then stirred at 150° C. for 48 hours. After cooling, the resultant product was washed three times with ethyl acetate and water, and an organic layer obtained by separation was dried utilizing MgSO₄ and dried under reduced pressure. The resulting product was purified through column chromatography with MC and n-hexane to obtain Intermediate 218-3. (Yield: 37%)

### Synthesis of Compound 218

Intermediate 218-3 (1 eq) was dissolved in ortho dichlorobenzene, and cooled to 0° C., and then BBr₃ (3 eq) was slowly injected thereto in a nitrogen atmosphere. After the dropping was completed, the temperature was raised to 180° C. to stir the resulting product for 24 hours. After cooling, triethylamine was slowly added dropwise to a flask containing the reactants to terminate the reaction, and ethyl alcohol was added to the reactants to cause precipitation and a solid was obtained therefrom by filtration The obtained solid was purified through column chromatography with MC and n-hexane and then recrystallized utilizing toluene and acetone to obtain Compound 218. (Yield: 5%)

### 2. Evaluation of Polycyclic Compounds

Table 1 shows the Example polycyclic compounds (i.e., Compounds 4, 5, 115, 120, 169, 217, and 218) that were synthesized as described herein and evaluated in Examples 1 to 7 (EX 1 to EX 7). Table 1 shows Comparative compounds (i.e., Compounds C1, C2, C3 and C4) that were evaluated in Comparative Examples 1 to 4 (CE 1 to CE 4). Table 2 shows the evaluation of properties of the Example polycyclic compounds and the Comparative compounds.

TABLE 1

| Item | Compound |
|---|---|
| EX 1 | 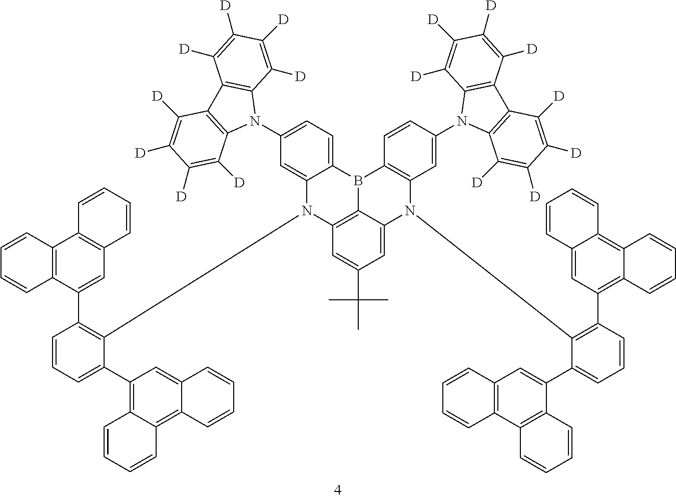 [SMILES: [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cc3ccccc3c3ccccc23)cccc1-c1cc2ccccc2c2ccccc12] |
| EX 2 | 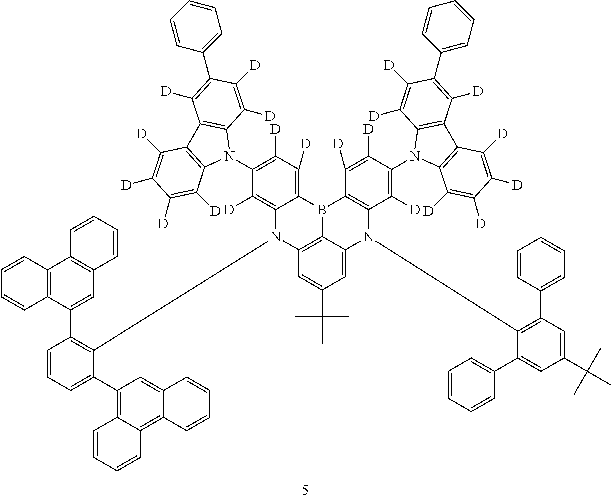 [SMILES: [2H]c1c([2H])c(-n2c3c([2H])c([2H])c([2H])c([2H])c3c3c([2H])c(-c4ccccc4)c([2H])c([2H])c32)c([2H])c2c1B1c3c(cc(C(C)(C)C)cc3N(c3c(-c4cc5ccccc5c5ccccc45)cccc3-c3cc4ccccc4c4ccccc34)c3c([2H])c(-n4c5c([2H])c([2H])c([2H])c([2H])c5c5c([2H])c(-c6ccccc6)c([2H])c([2H])c54)c([2H])c([2H])c31)N2c1c(-c2ccccc2)cc(C(C)(C)C)cc1-c1ccccc1] |
| EX 3 | 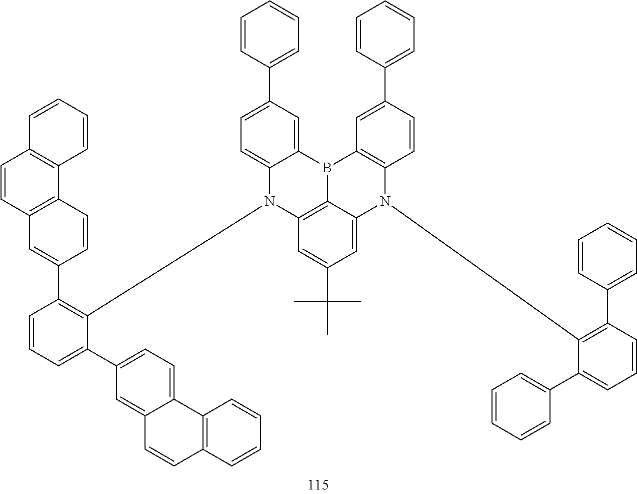 [SMILES: CC(C)(C)c1cc2c3c(c1)N(c1c(-c4ccc5c(ccc6ccccc65)c4)cccc1-c1ccc4c(ccc5ccccc54)c1)c1ccc(-c4ccccc4)cc1B3c1cc(-c3ccccc3)ccc1N2c1c(-c2ccccc2)cccc1-c1ccccc1] |
| EX 4 | 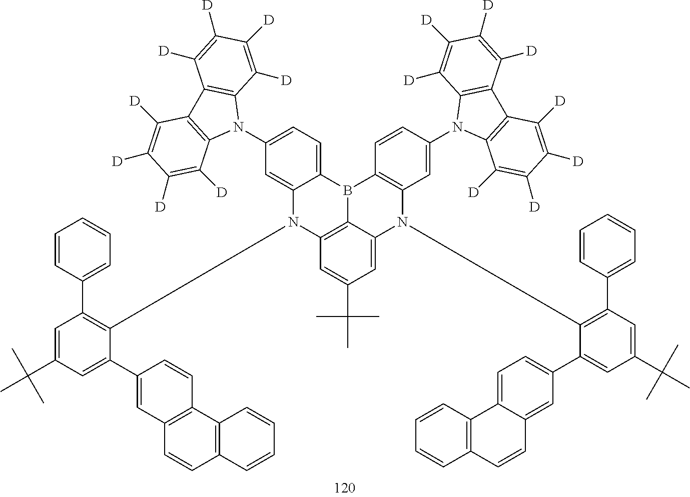 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccc3c(ccc4ccccc43)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1ccc2c(ccc3ccccc32)c1] |
| EX 5 | 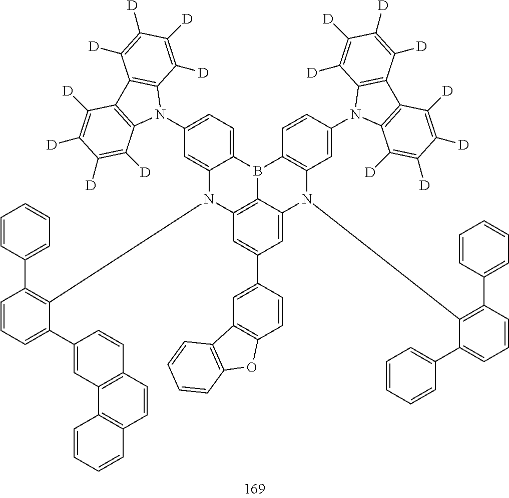 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc2ccc3ccccc3c2c1] |
| EX 6 | 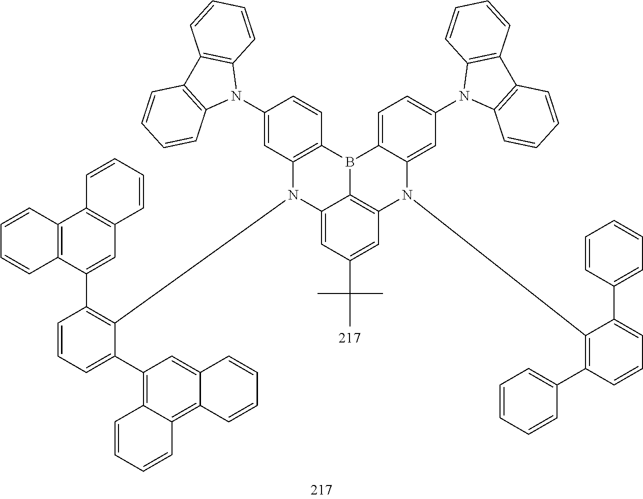 [SMILES: CC(C)(C)c1cc2c3c(c1)N(c1c(-c4cc5ccccc5c5ccccc45)cccc1-c1cc4ccccc4c4ccccc14)c1cc(-n4c5ccccc5c5ccccc54)ccc1B3c1ccc(-n3c4ccccc4c4ccccc43)cc1N2c1c(-c2ccccc2)cccc1-c1ccccc1] |
| EX 7 | 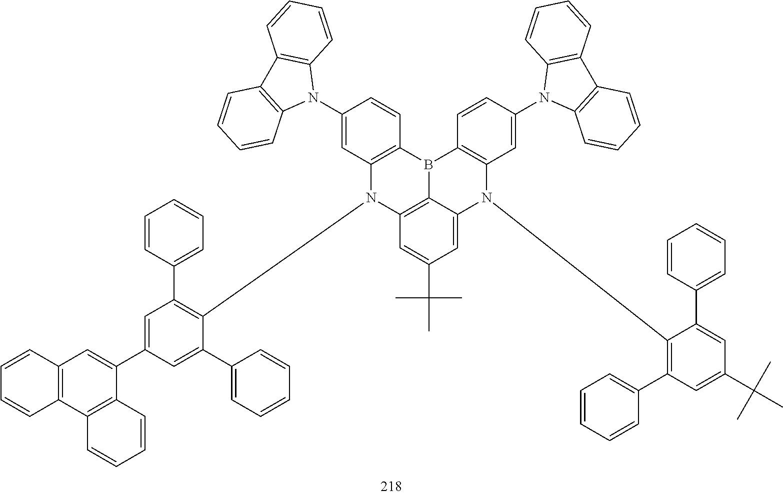 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(-c5cc6ccccc6c6ccccc56)cc4-c4ccccc4)c4cc(C(C)(C)C)cc2c43)c(-c2ccccc2)c1] |
| CE 1 | 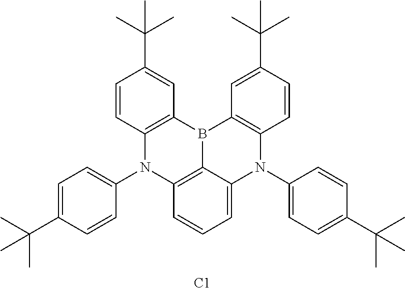 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; "C1"] |
| CE 2 | 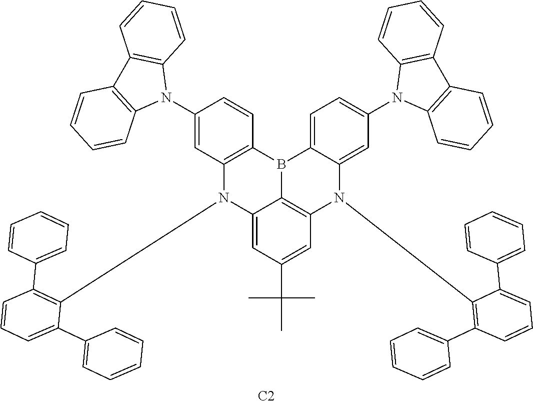 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1c(-c2ccccc2)cccc1-c1ccccc1 ; "C2"] |
| CE 3 | 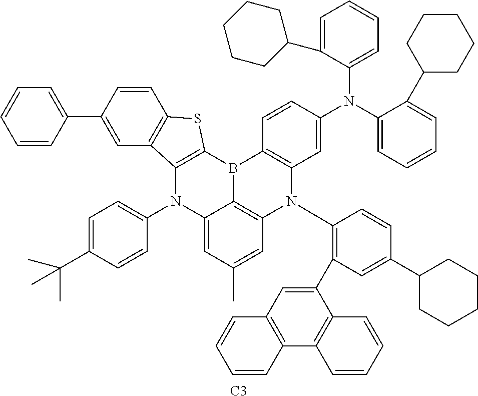 |
| CE 4 | 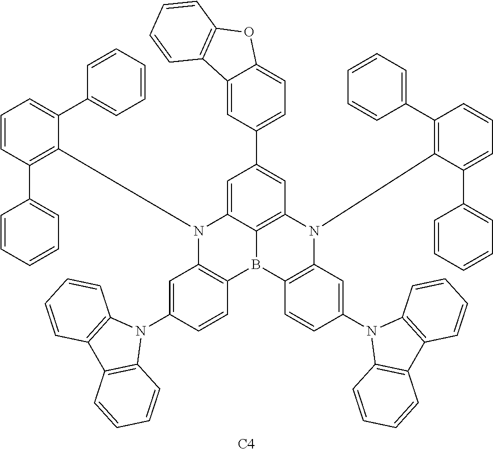 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5ccc6oc7ccccc7c6c5)cc2c43)cc1 ; "C4"] |

Examples 1 to 7 (EX 1 to EX 7) in Table 2 show the evaluation on H, L, S1, f, T1, ΔT2-T1, and ΔE_{ST} of the Example polycyclic compounds (i.e., Compounds 4, 5, 115, 120, 169, 217, and 218). Comparative Examples 1 to 4 (CE 1 to CE 4) in Table 2 show evaluation of Comparative compounds (i.e., Compounds C1, C2, C3 and C4).

H indicates the value of a HOMO energy level, and L indicates the value of a LUMO energy level (electron volt (eV)). S1 (nanometer (nm)) indicates an emission wavelength of singlet state, T1 (nm) indicates an emission wavelength of lowest triplet state, and T1 (eV) indicates an energy level of lowest triplet state. ΔT2-T1 indicates an absolute value of the energy level difference between the second lowest triplet state and the lowest triplet state. ΔE_{ST} indicates an absolute value of the energy level difference between the singlet state and the lowest triplet state. f indicates oscillator intensity.

TABLE 2

| | H | L | S1 | | T1 | T1 | ΔT2 − T1 | ΔE_{ST} |
|---|---|---|---|---|---|---|---|---|
| | (eV) | (eV) | (nm) | f | (nm) | (eV) | (eV) | (eV) |
| EX 1 | −5.18 | −1.62 | 414.9 | 0.232 | 474.9 | 2.6111 | 0.019 | 0.378 |
| EX 2 | −5.20 | −1.64 | 417.4 | 0.262 | 480.1 | 2.585 | 0.081 | 0.385 |
| EX 3 | −4.92 | −1.39 | 417.1 | 0.194 | 482.6 | 2.5694 | 0.077 | 0.403 |
| EX 4 | −5.15 | −1.61 | 417.3 | 0.26 | 478.6 | 2.5909 | 0.113 | 0.381 |
| EX 5 | −5.33 | −1.83 | 419.8 | 0.31 | 487.6 | 2.5431 | 0.149 | 0.411 |
| EX 6 | −5.22 | −1.69 | 417.8 | 0.266 | 480.7 | 2.5796 | 0.088 | 0.388 |
| EX 7 | −5.25 | −1.72 | 417.5 | 0.317 | 481.3 | 2.5764 | 0.136 | 0.394 |
| CE 1 | −4.84 | −1.29 | 410.3 | 0.225 | 486 | 2.5514 | 0.520 | 0.471 |
| CE 2 | −5.18 | −1.64 | 417 | 0.313 | 480.1 | 2.5828 | 0.469 | 0.391 |
| CE 3 | −4.91 | −1.44 | 414.2 | 0.221 | 517.1 | 2.3980 | 0.292 | 0.596 |
| CE 4 | −5.3 | −1.8 | 418.9 | 0.334 | 485.9 | 2.5520 | 0.428 | 0.408 |

Referring to Table 2, it is seen that the Example polycyclic compounds have deeper HOMO levels than the Comparative compounds, and thus may have less likelihood for an increase in Ti exciton concentration generated by trap assistant recombination resulting from hole trap (e.g., to effect being beneficial in increasing service life).

For example, it is seen that the Example polycyclic compounds have very small ΔT2-T1 values compared to the Comparative compounds. Accordingly, it is seen that the Example polycyclic compounds of one or more embodiments may exhibit relatively fast reverse intersystem crossing (RISC).

### 3. Preparation and Evaluation of Light Emitting Elements

### (1) Preparation of Light Emitting Elements

Light emitting elements including Example polycyclic compounds according to one or more embodiments or Comparative compounds were prepared through a method as described herein. The Example polycyclic compounds of one or more embodiments were each utilized as a dopant material for an emission layer to manufacture light emitting elements of Examples 1 to 7 (EX 1 to EX 7), as discussed regarding Tables 1 and 2. Light emitting elements of Comparative Examples 1 to 4 (CE 1 to CE 4), as discussed regarding Tables 1 and 2, were manufactured utilizing each of Comparative compounds C1 to C4, respectively, as a dopant material of an emission layer.

As a first electrode, a glass substrate having an indium tin oxide (ITO) electrode (Corning, 15 ohm per square centimeter (Ω/cm²) 1200 angstrom (Å)) formed thereon was cut to a size of about 50 millimeter (mm)×50 mm×0.7 mm, subjected to ultrasonic cleaning utilizing isopropyl alcohol and pure water each for 5 minutes, and ultraviolet irradiation for 30 minutes, and then exposed to ozone for cleaning to be mounted on a vacuum deposition apparatus.

On the first electrode, a hole injection layer having a thickness of 300 Å was formed through the deposition of NPD, and on the hole injection layer, a hole transport layer having a thickness of 200 Å was formed through the deposition of compound H-1-1. Then, on the hole transport layer, an auxiliary emission layer having a thickness of 100 Å was formed through the deposition of CzSi.

On the auxiliary emission layer, an emission layer having a thickness of 350 Å was formed through the co-deposition of a host mixture, a phosphorescent sensitizer, and a dopant in a weight ratio of 85:14:1. As for the host mixture, compound HT35 which is a hole transporting host and compound ETH66 which is an electron transporting host were provided in a weight ratio of 5:5. Compound AD-38 was utilized as a phosphorescent sensitizer material. As a dopant material, the Example polycyclic compounds or Comparative compounds were utilized.

On the emission layer, a hole blocking layer having a thickness of 50 Å was formed through the deposition of HBL-1. Thereafter, on the hole blocking layer, an electron transport layer having a thickness of 310 Å was formed through the co-deposition of CNNPTRZ and Liq to be in a weight ratio of 4.0:6.0, and then on the electron transport layer, an electron injection layer was formed to have a thickness of 15 Å through the deposition of Yb. Then, on the electron injection layer, a second electrode having a thickness of 800 Å was formed through the deposition of Mg to manufacture a light emitting element.

The compounds utilized to manufacture the light emitting elements are as follows.

### Materials Utilized in the Manufacture of Light Emitting Elements

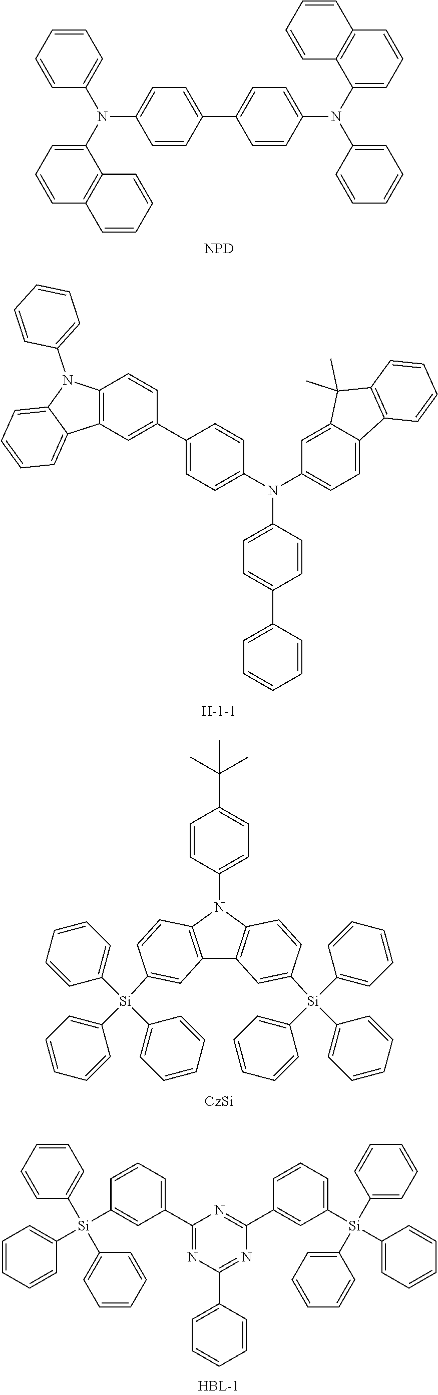

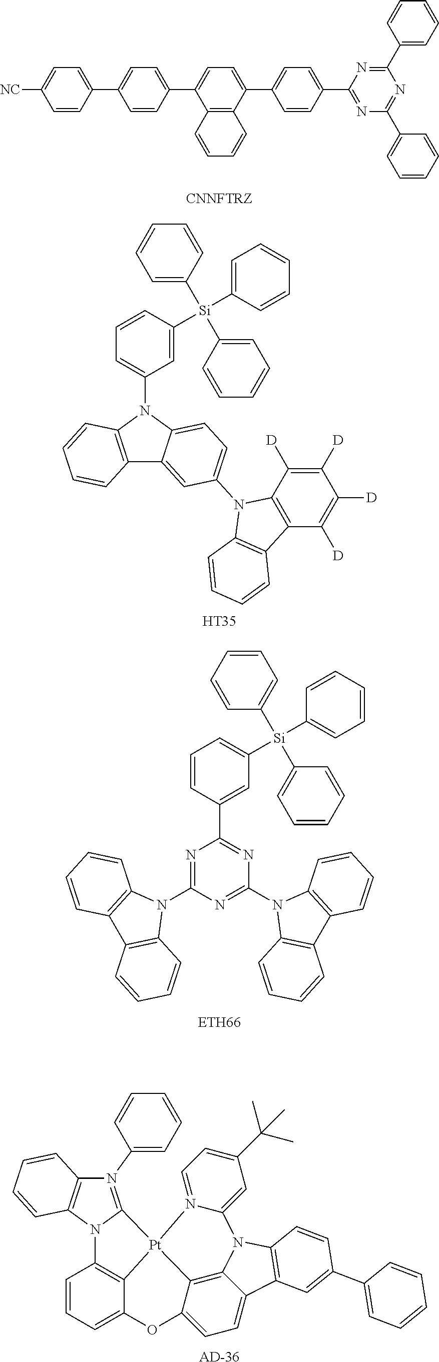

### (2) Evaluation of Light Emitting Elements

Table 3 shows evaluation results of the light emitting elements of Examples 1 to 7 (EX 1 to EX 7) and Comparative Examples 1 to 4 (CE 1 to CE 4). For example, at a current density of 10 milliampere per square centimeter (mA/cm²), driving voltage (V), efficiency (candela per ampere (cd/A)), and light emission wavelength were determined utilizing Keithley MU 236 and a luminance meter PR650. As for service life, the time taken for luminance to decrease to 95% with respect to an initial luminance was determined, and the values compared with Comparative Example 1 were indicated as relative element service life (i.e., lifetime).

TABLE 3

| | | | | | | Light | |
|---|---|---|---|---|---|---|---|
| | | | Boron | Driving | | emission | Lifetime |
| | Host | 4th | dopant | voltage | Efficiency | wavelength | ratio |
| Item | mixture | compound | (Formula 1) | (V) | (cd/A) | (nm) | (T95) |
| EX 1 | HT35/ | AD-38 | Compound | 4.5 | 26.4 | 461 | 6.8 |
| | ETH66 | | 4 | | | | |
| EX 2 | HT35/ | AD-38 | Compound | 4.4 | 26.8 | 462 | 6.9 |
| | ETH66 | | 5 | | | | |
| EX 3 | HT35/ | AD-38 | Compound | 4.5 | 25.5 | 463 | 6.7 |
| | ETH66 | | 115 | | | | |
| EX 4 | HT35/ | AD-38 | Compound | 4.4 | 26.4 | 462 | 7.2 |
| | ETH66 | | 120 | | | | |
| EX 5 | HT35/ | AD-38 | Compound | 4.5 | 25.9 | 462 | 7.3 |
| | ETH66 | | 169 | | | | |
| EX 6 | HT35/ | AD-38 | Compound | 4.5 | 26.7 | 460 | 7.3 |
| | ETH66 | | 217 | | | | |
| EX 7 | HT35/ | AD-38 | Compound | 4.4 | 26.3 | 461 | 7.6 |
| | ETH66 | | 218 | | | | |
| CE 1 | HT35/ | AD-38 | Compound | 5.2 | 19.8 | 465 | 1 |
| | ETH66 | | C1 | | | | |
| CE 2 | HT35/ | AD-38 | Compound | 4.5 | 26.6 | 461 | 6.4 |
| | ETH66 | | C2 | | | | |
| CE 3 | HT35/ | AD-38 | Compound | 5.4 | 21.4 | 462 | 1.2 |
| | ETH66 | | C3 | | | | |
| CE 4 | HT35/ | AD-38 | Compound | 4.5 | 25.9 | 462 | 6.1 |
| | ETH66 | | C4 | | | | |

Referring to the results of Table 3, it is seen that the light emitting elements of Examples 1 to 7 (EX 1 to EX 7) utilizing an Example polycyclic compound according to one or more embodiments as a light emitting material had lower driving voltage and greater luminous efficiency and service life (i.e., lifetime) than the light emitting elements of Comparative Examples 1 to 4 (CE 1 to CE 4).

For example, the Example polycyclic compounds (i.e., Compounds 4, 5, 115, 120, 169, 217, and 218), of Examples 1 to 7 (EX 1 to EX 7) each included a 5-ring fused ring core containing two nitrogen atoms and one boron atom as ring-forming atoms, and included a phenanthrene group linked to the core through a first linker, and thus showed low driving voltage and provided excellent luminous efficiency and service life. In comparison, the results showed the low driving voltage despite the shallower HOMO level than that of other compounds (e.g., compound 115 utilized in Example 3). The results indicate that (e.g., the introduction of) substituents such as a terphenyl group into the core of Compound 115 may be helpful for improving hole transport properties.

In the light emitting elements of Comparative Example 1 (CE 1) and Comparative Example 3 (CE 3), the HOMO energy level values of −4.84 eV and −4.91 eV, respectively, for Compound C1 and Compound C3 utilized as light emitting materials are too shallow, resulting in a driving voltage increase (e.g., 5.2 V and 5.4 V, respectively), caused by hole trap, an increased dopant exciton caused by trap assistant recombination, and an increased concentration of triplet exciton to cause a sharp increase in triplet-polaron quenching (TPQ), thereby leading to a significant reduction in service life.

For example, the light emitting elements of Comparative Examples 2 and 4 (CE 2 and CE4) utilizing Comparative compounds C2 and Compound C4, in which a phenanthrene moiety is not linked to the core of the light emitting materials, showed decreased service life when comparted to the light emitting elements of Examples 1 to 7 (EX 1 to EX 7).

A light emitting element according to one or more embodiments includes a polycyclic compound of one or more embodiments in an emission layer, and may thus exhibit high efficiency and long service life.

A polycyclic compound of one or more embodiments may have fast reverse intersystem crossing (RISC) and reduce dexter energy transfer, thereby contributing to improving light efficiency and extending service life of a light emitting element.

For example, a display device of one or more embodiments includes a light emitting element initiating the herein-described effects, and may thus exhibit improved image quality and display efficiency.

Although the present disclosure has been described with reference to a one or more embodiments of the present disclosure, it will be understood that the present disclosure should not be limited to these preferred embodiments but one or more suitable changes and modifications may be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode,
wherein the emission layer comprises a first compound represented by Formula 1: 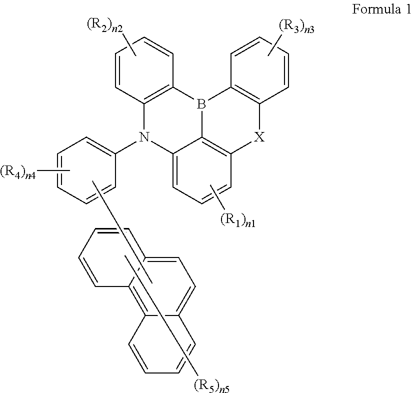
in Formula 1,
X is NR₆, S, O, or Se,
R₁ to R₅ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
R₆ is a substituted or unsubstituted aryl group having 6 to 30 ring-forming carbon atoms, or a substituted or unsubstituted heteroaryl group having 5 to 30 ring-forming carbon atoms,
n1 is an integer of 0 to 3,
n2 to n4 are each independently an integer of 0 to 4, and
n5 is an integer of 0 to 9.

2. The light emitting element of claim 1, wherein the first compound is represented by Formula 2: 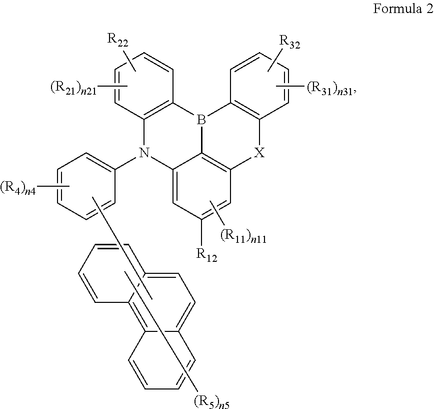
in Formula 2,
R₁₁, R₂₁, and R₃₁ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
R₁₂, R₂₂, and R₃₂ are each independently a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
n11 is an integer of 0 to 2,
n21 and n31 are each independently an integer of 0 to 3, and
X, R₄, R₅, n4, and n5 are as defined in Formula 1.

3. The light emitting element of claim 2, wherein at least one of R₁₂, R₂₂, or R₃₂ is positioned para to boron atoms of Formula 2.

4. The light emitting element of claim 1, wherein the first compound is represented by Formula 3: 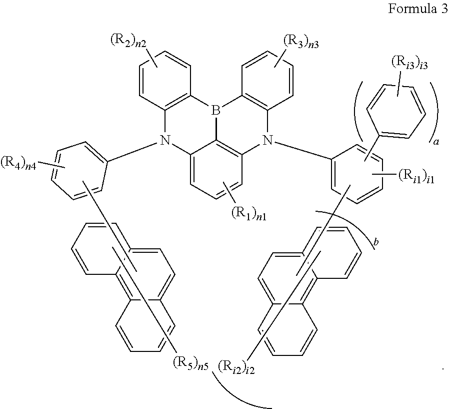
in Formula 3,
Rᵢ₁, Rᵢ₂, and Rᵢ₃ are each independently a hydrogen atom, a deuterium atom, a substituted or unsubstituted alkyl group having 1 to 20 carbon atoms, or a substituted or unsubstituted aryl group having 6 to 20 ring-forming carbon atoms,
i1 is an integer of 0 to 3,
2 is an integer of 0 to 9,
i3 is an integer of 0 to 5,
a and b are each independently an integer of 0 to 2, and a+b equals 2 or 3, and
R₁ to R₅, and n1 to n5 are as defined in Formula 1.

5. The light emitting element of claim 1, wherein the first compound is represented by Formula 4: 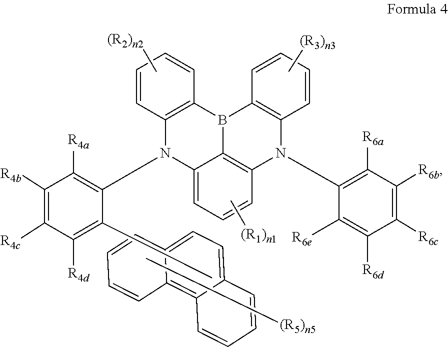
in Formula 4,
at least one selected from among R₄ₐ to R_{4d} and at least two selected from among R₆ₐ to R₆ₑ are each independently a substituted or unsubstituted phenyl group, or a substituted or unsubstituted phenanthryl group,
any remaining selected from among R₄ₐ to R_{4d}, and any remaining selected from among R₆ₐ to R₆ₑ are each independently a hydrogen atom, a deuterium atom, a substituted or unsubstituted alkyl group having 1 to 30 carbon atoms, or a substituted or unsubstituted aryl group having 6 to 30 ring-forming carbon atoms, and
R₁ to R₃, R₅, n1 to n3, and n5 are as defined in Formula 1.

6. The light emitting element of claim 5, wherein R₄ₐ, R₆ₐ, and R₆ₑ are each independently a substituted or unsubstituted phenyl group, or a substituted or unsubstituted phenanthryl group, and
R_{4b} to R_{4d}, and R_{6b} to R_{6d} are each independently a hydrogen atom, a deuterium atom, a substituted or unsubstituted alkyl group having 1 to 30 carbon atoms, or a substituted or unsubstituted aryl group having 6 to 30 ring-forming carbon atoms.

7. The light emitting element of claim 1, wherein in the first compound represented by Formula 1, R₁ to R₃ are each independently a hydrogen atom, a deuterium atom, or represented by any one selected from among the substituents of Substituent Group 1:

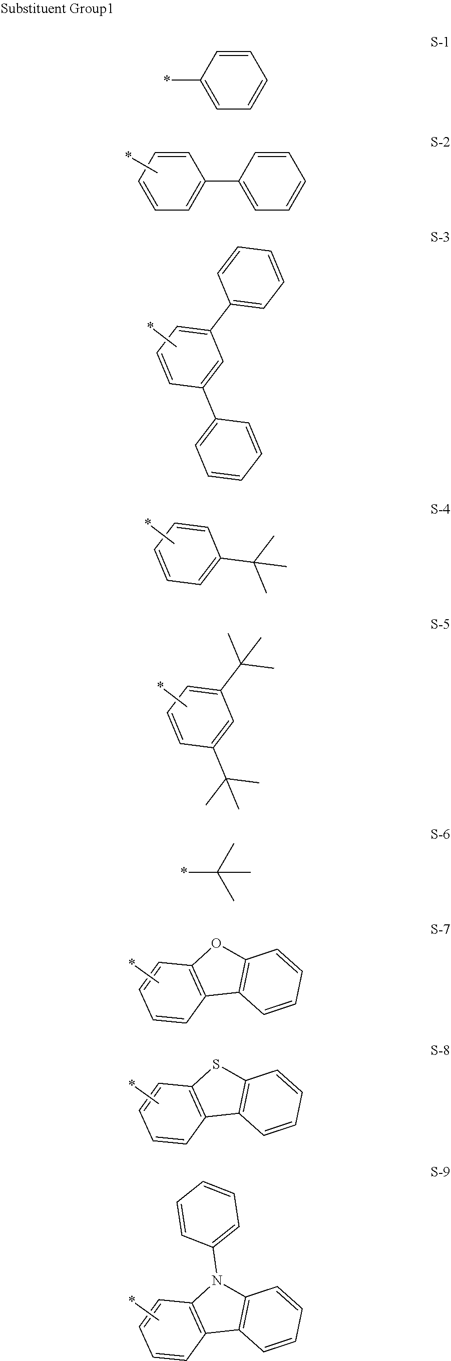

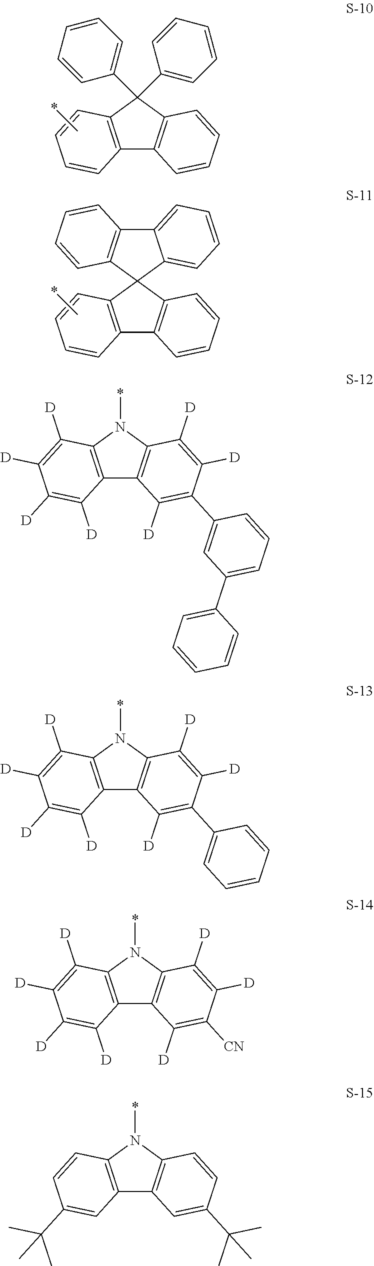

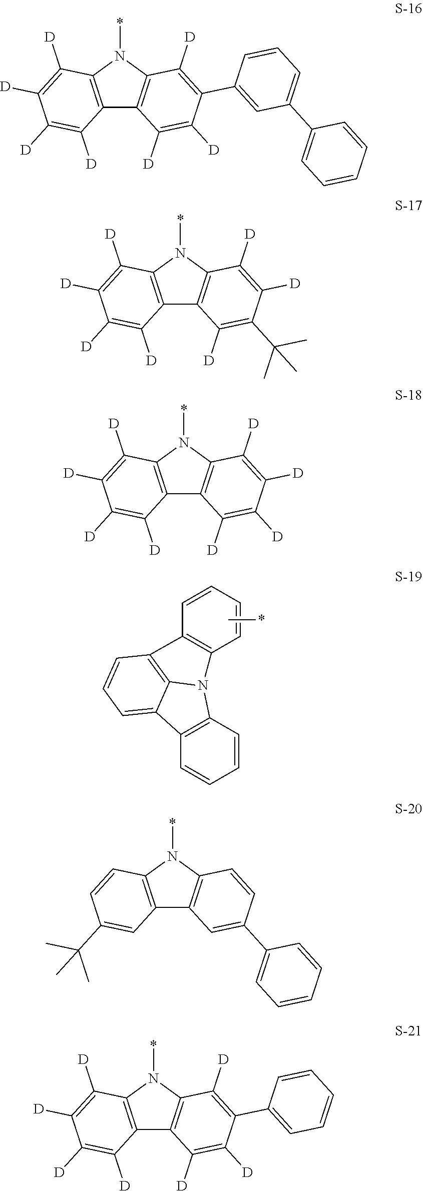

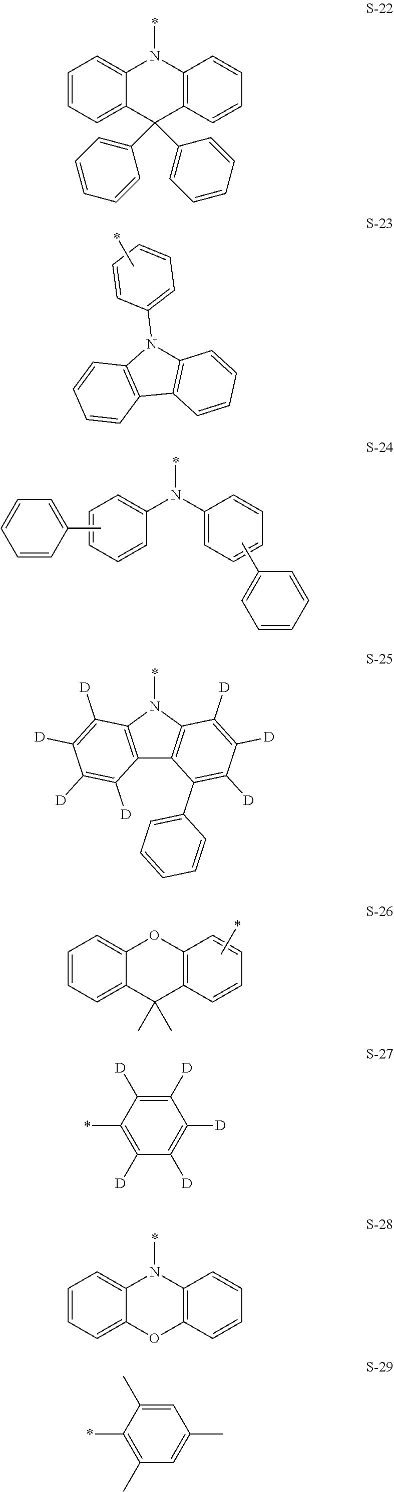

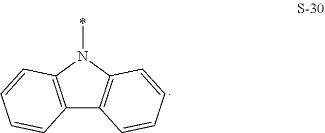 [SMILES: *n1c2ccccc2c2ccccc21]

8. The light emitting element of claim 1, wherein in Formula 1, at least one selected from among R₁ to R₆ is a deuterium atom or comprises a substituent containing a deuterium atom.

9. The light emitting element of claim 1, wherein the emission layer further comprises at least one of a second compound represented by Formula HT-1, a third compound represented by Formula ET-1, or a fourth compound represented by Formula D-1: 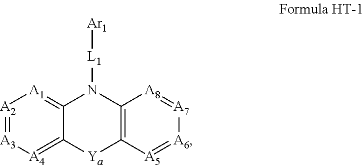
in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring, 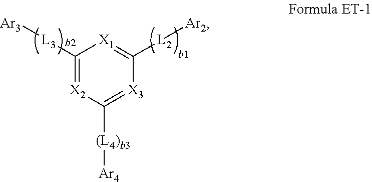
in Formula ET-1,
at least one selected from among X₁ to X₃ is N and any remaining selected from among X₁ to X₃ are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and 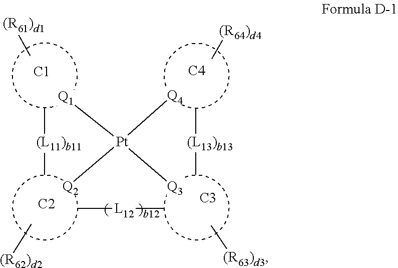
in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 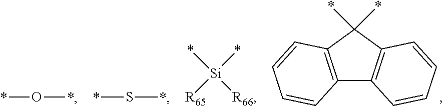
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

10. The light emitting element of claim 9, wherein the emission layer comprises the first compound, the second compound, the third compound, and the fourth compound.

11. The light emitting element of claim 1, wherein the emission layer comprises at least one selected from among the compounds of Compound Group 1: 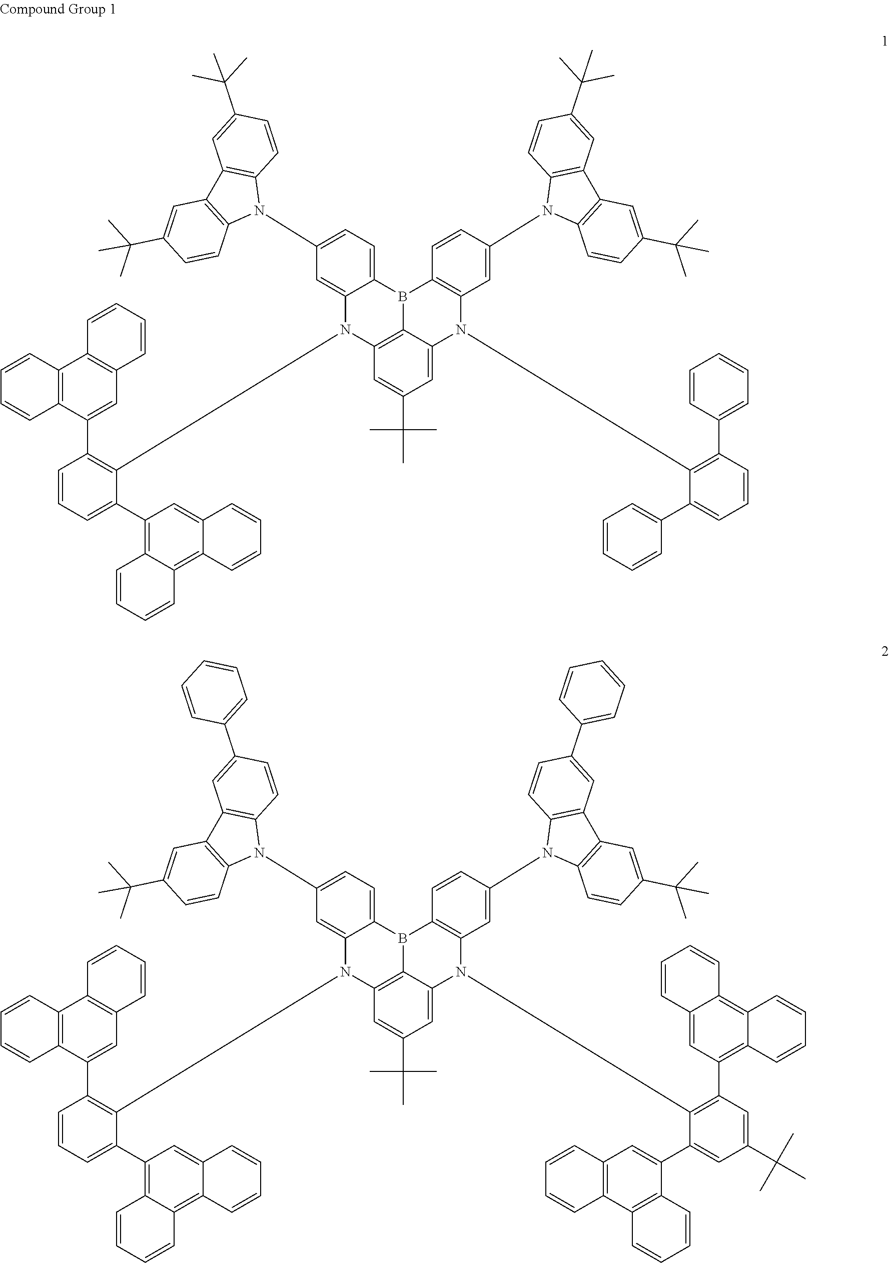 [SMILES: CC(C)(C)c1cc2c3c(c1)N(c1c(-c4cc5ccccc5c5ccccc45)cccc1-c1cc4ccccc4c4ccccc14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; CC(C)(C)c1cc(-c2cc3ccccc3c3ccccc23)c(N2c3cc(-n4c5ccc(-c6ccccc6)cc5c5cc(C(C)(C)C)ccc54)ccc3B3c4ccc(-n5c6ccc(-c7ccccc7)cc6c6cc(C(C)(C)C)ccc65)cc4N(c4c(-c5cc6ccccc6c6ccccc56)cccc4-c4cc5ccccc5c5ccccc45)c4cc(C(C)(C)C)cc2c43)c(-c2cc3ccccc3c3ccccc23)c1] 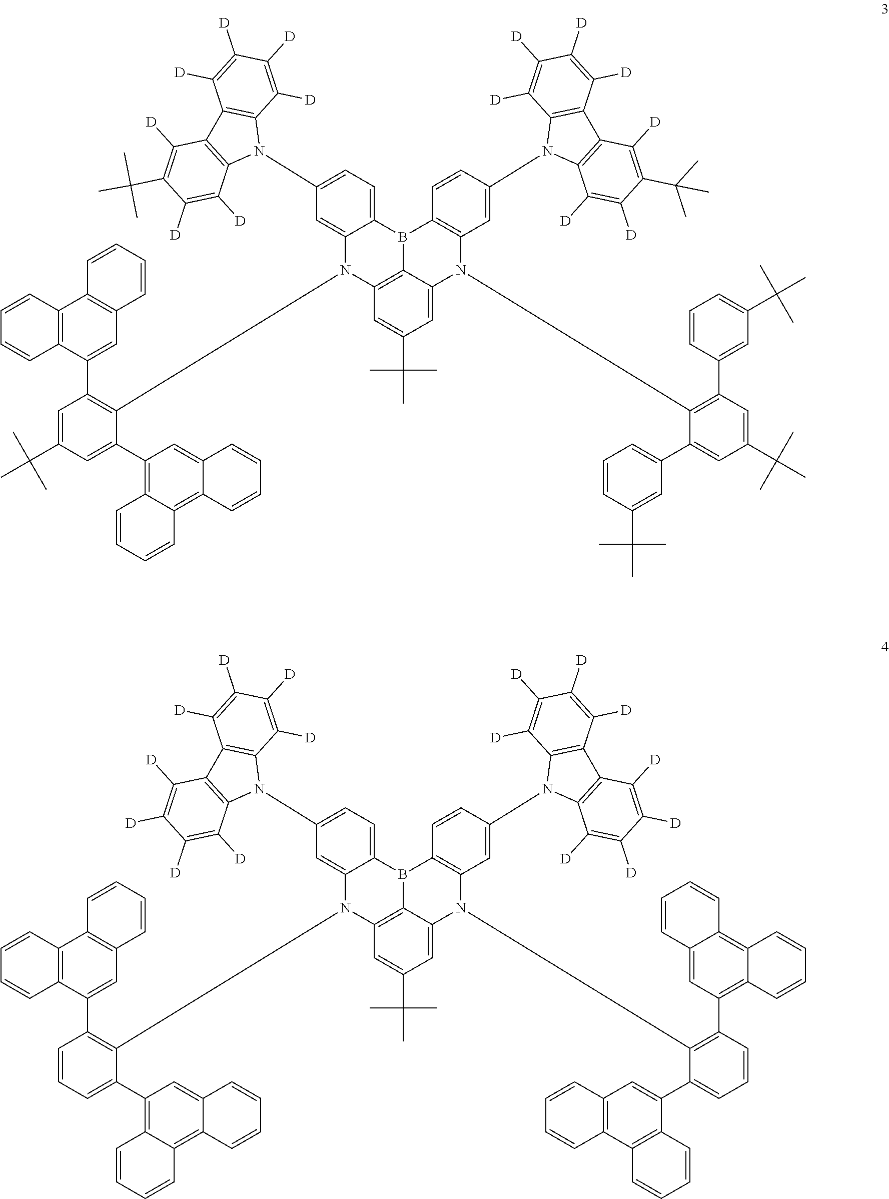 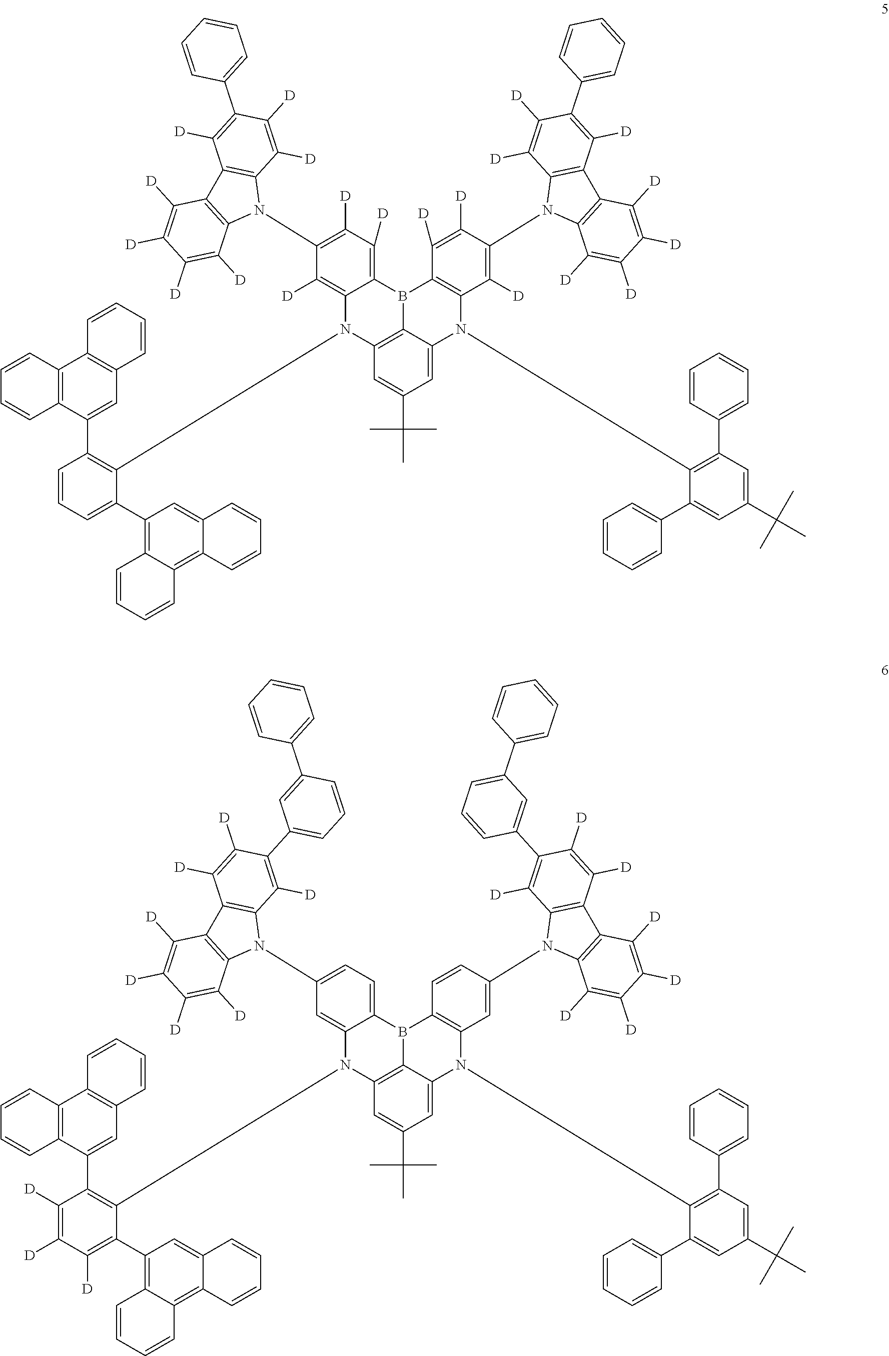 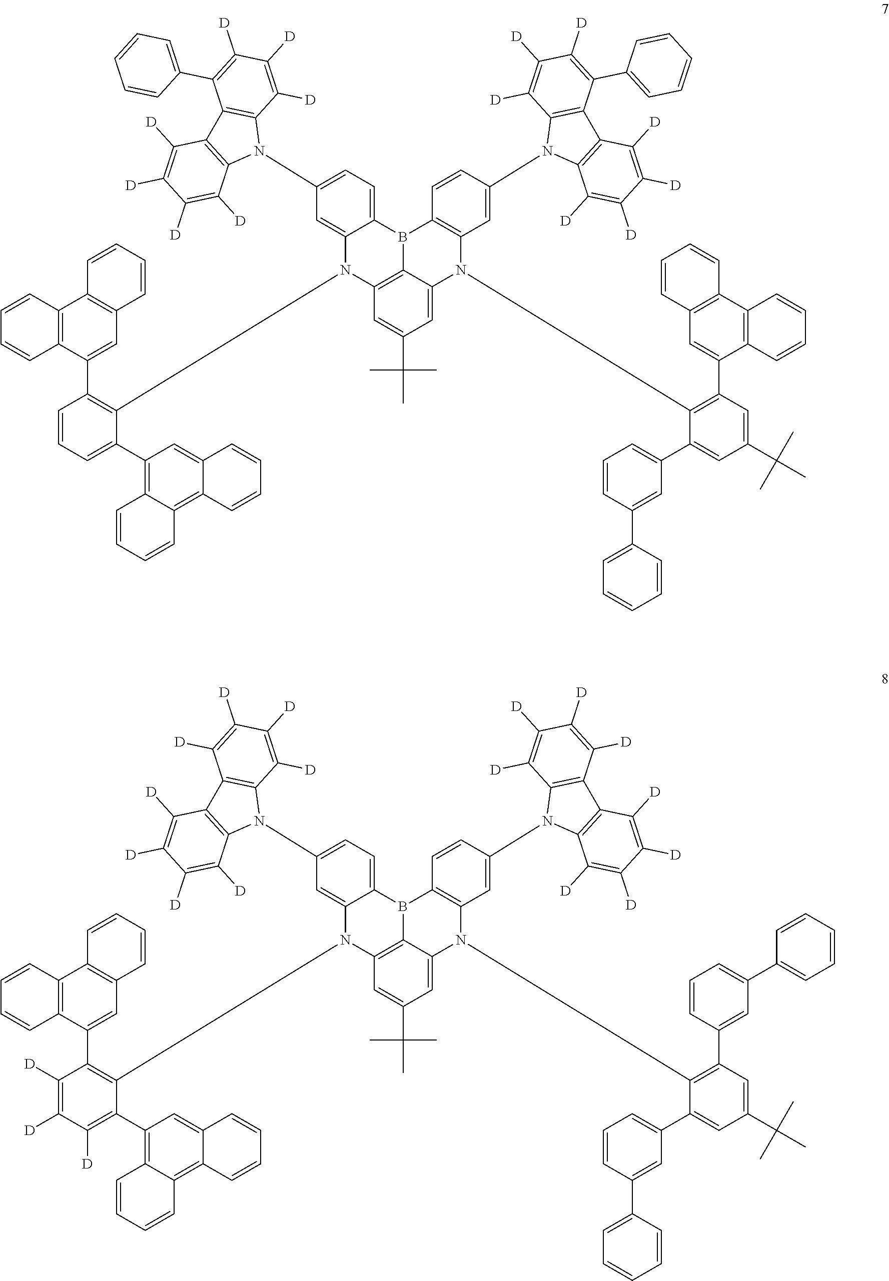 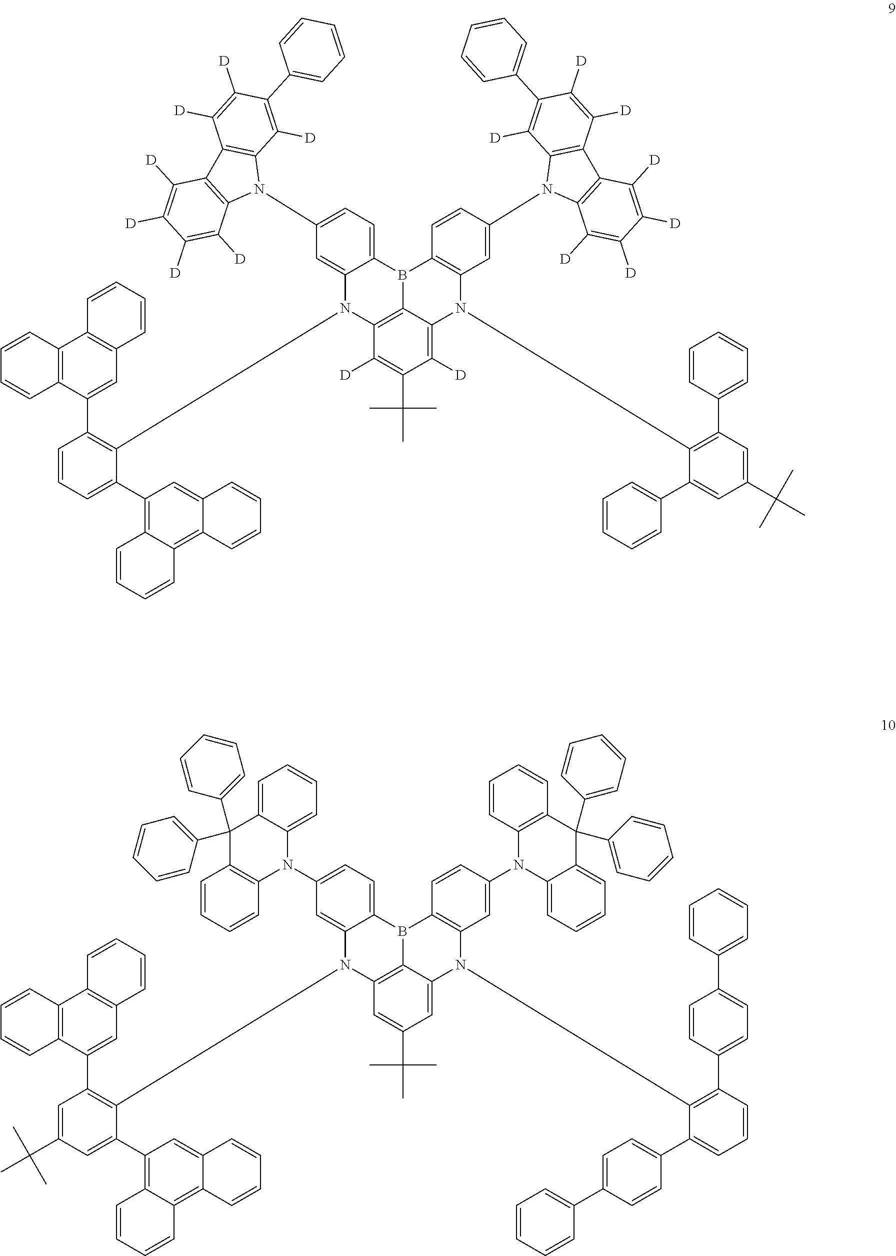 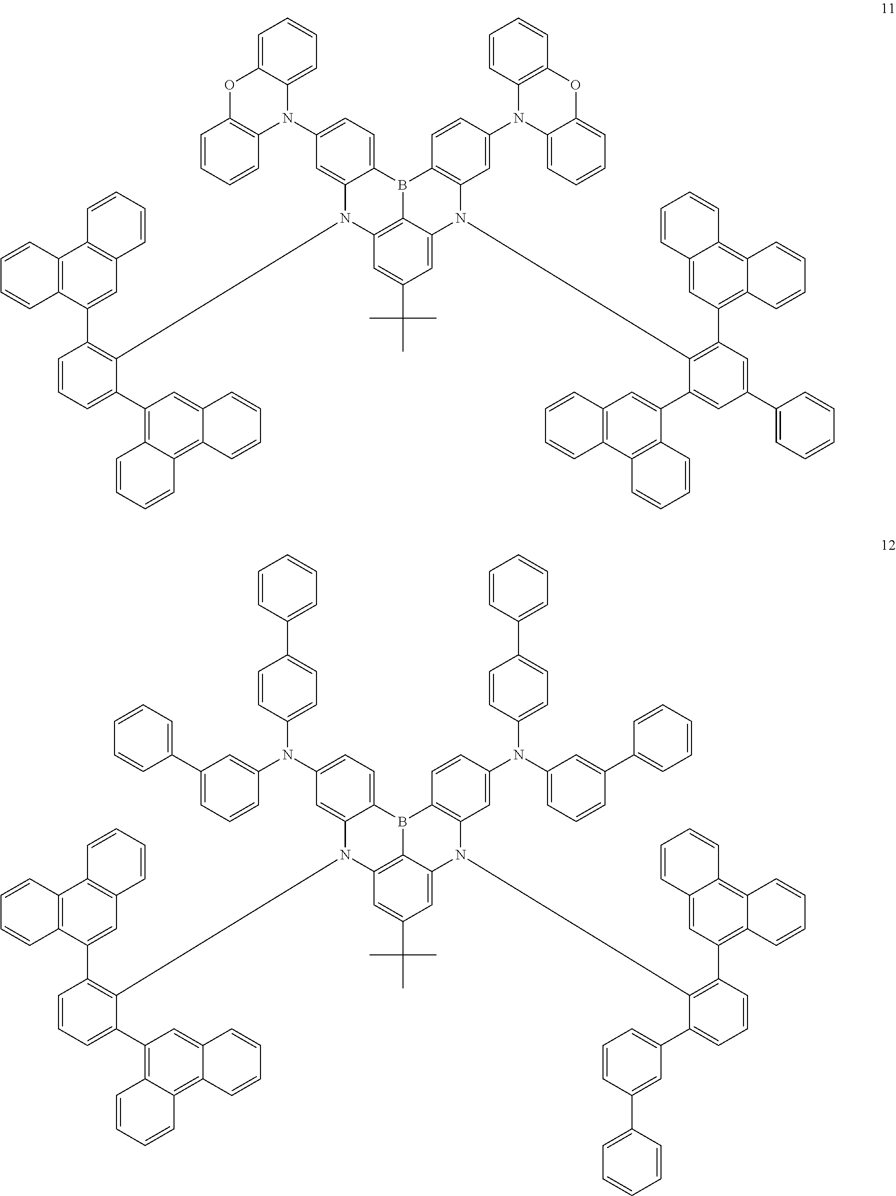 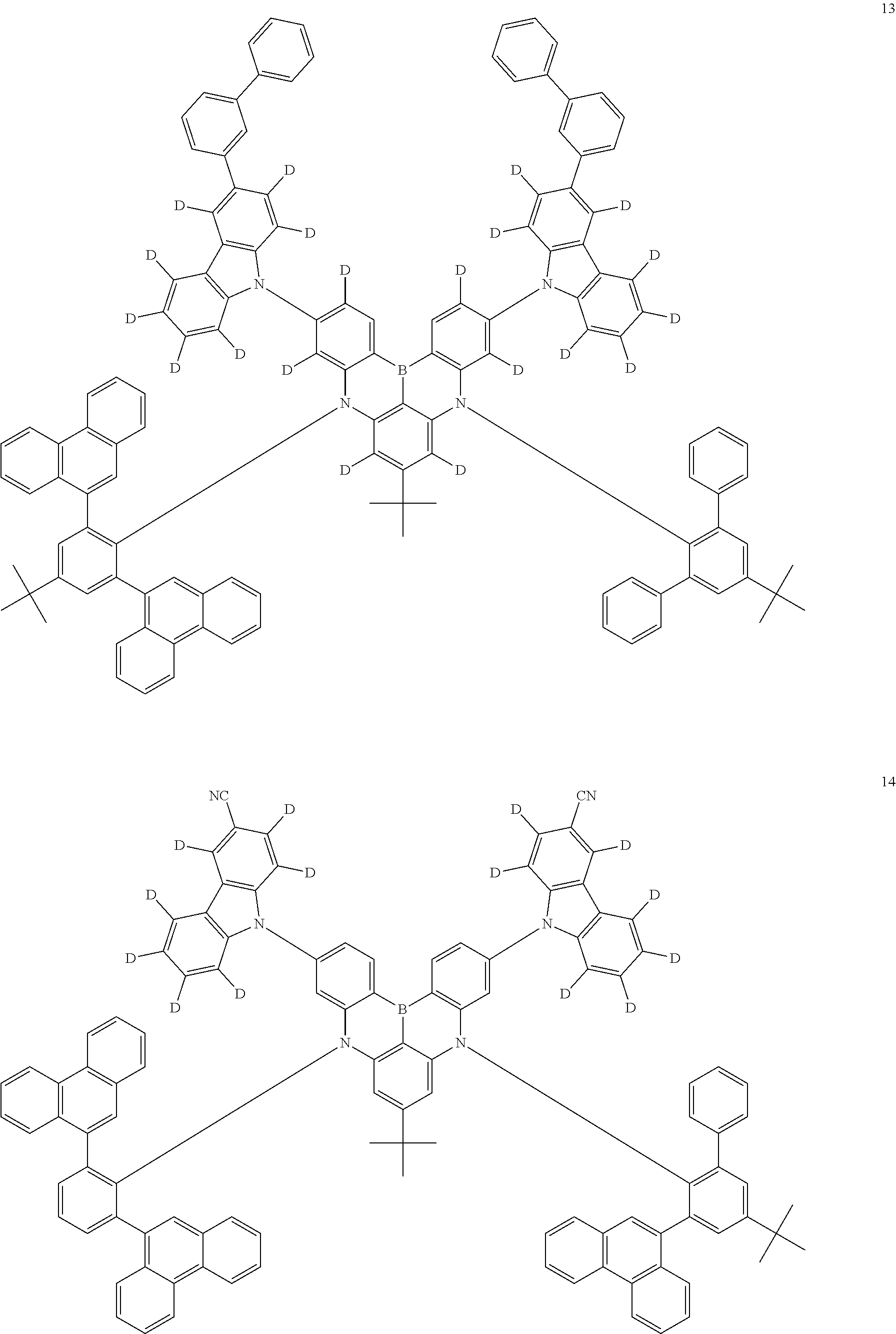 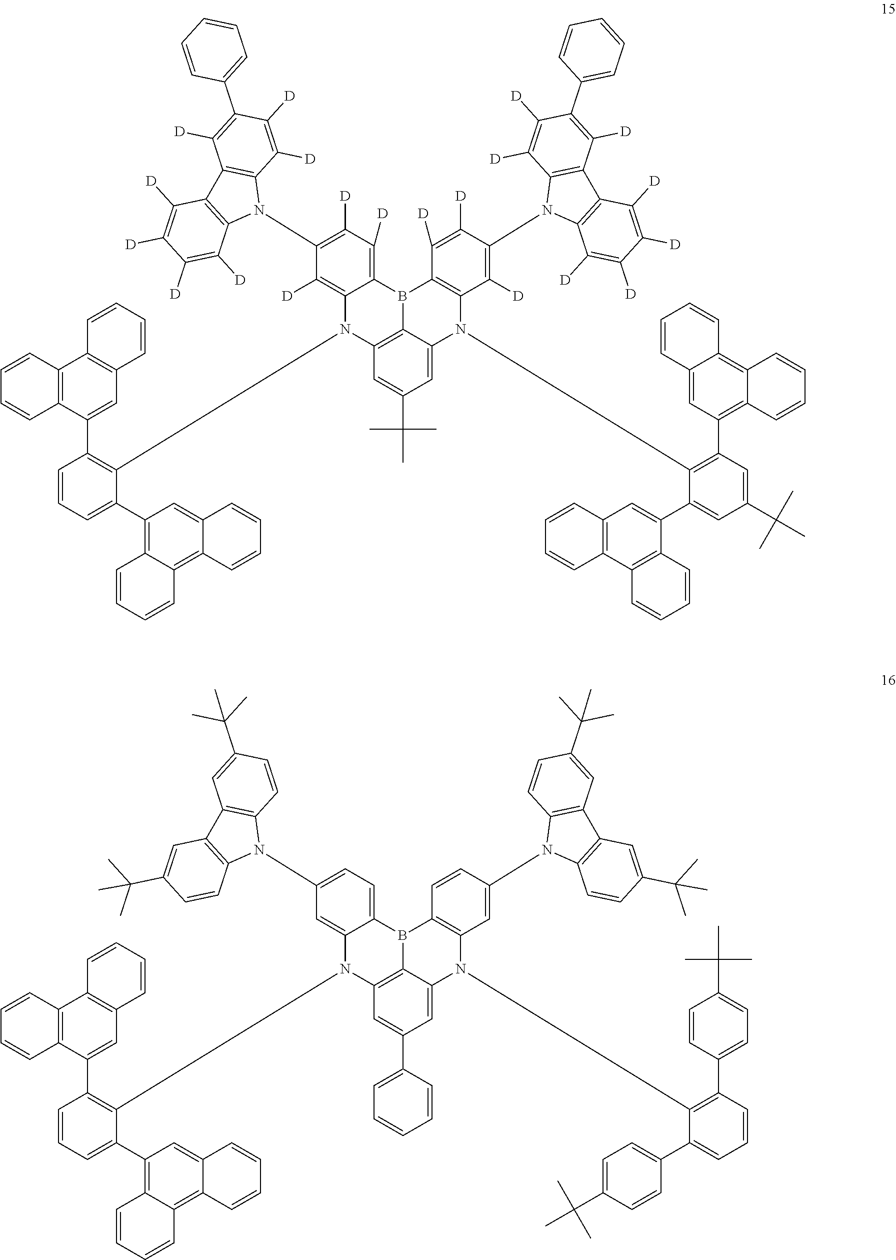 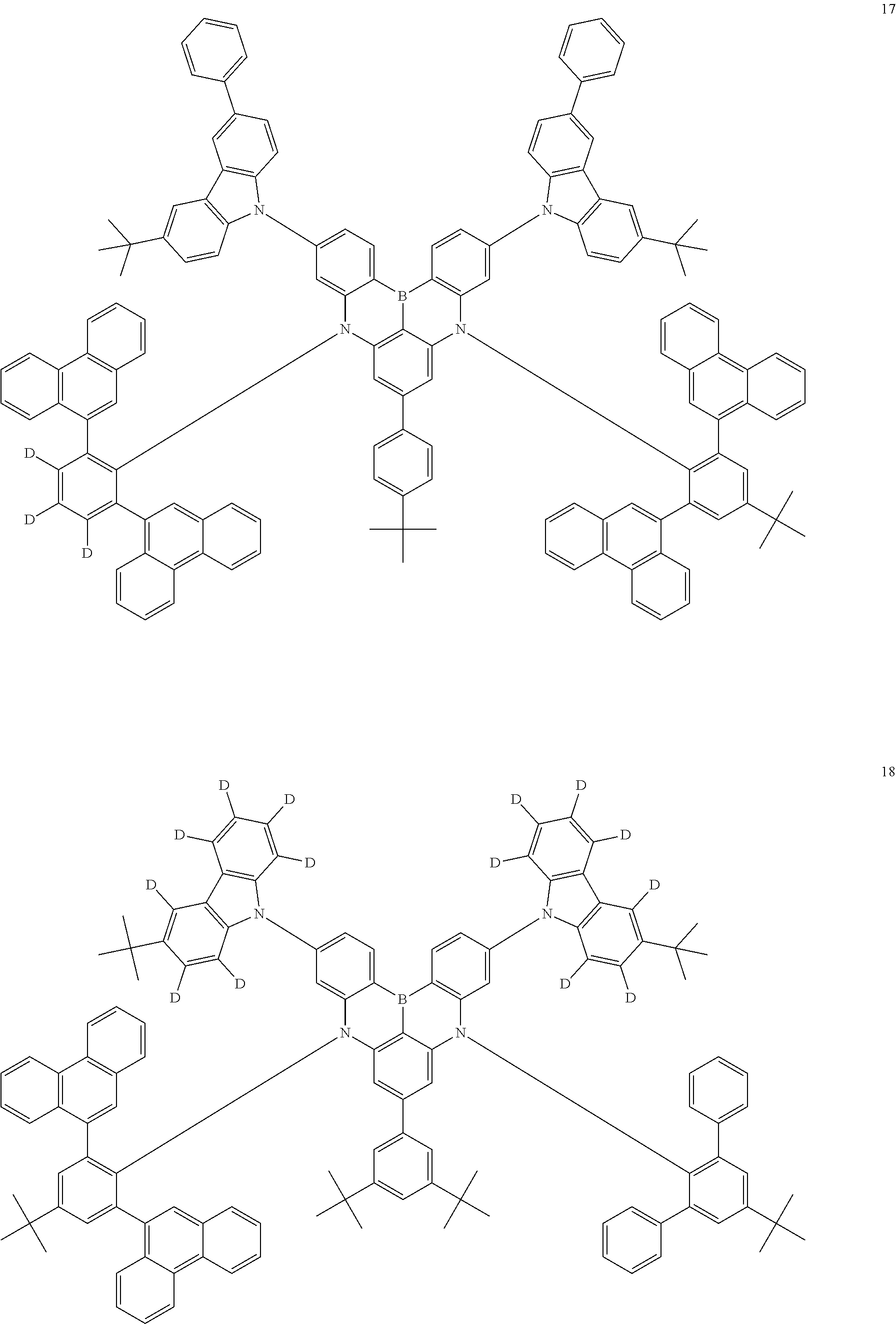 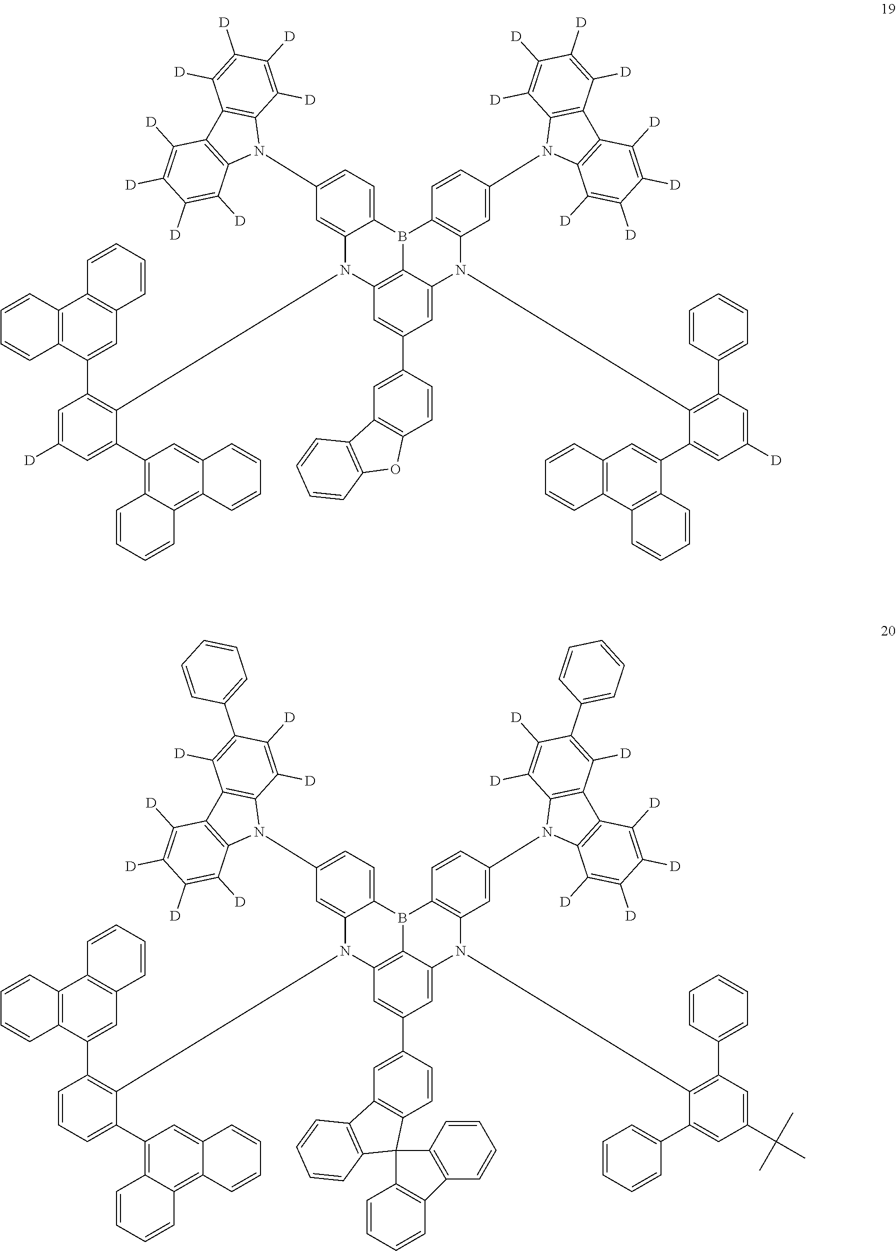 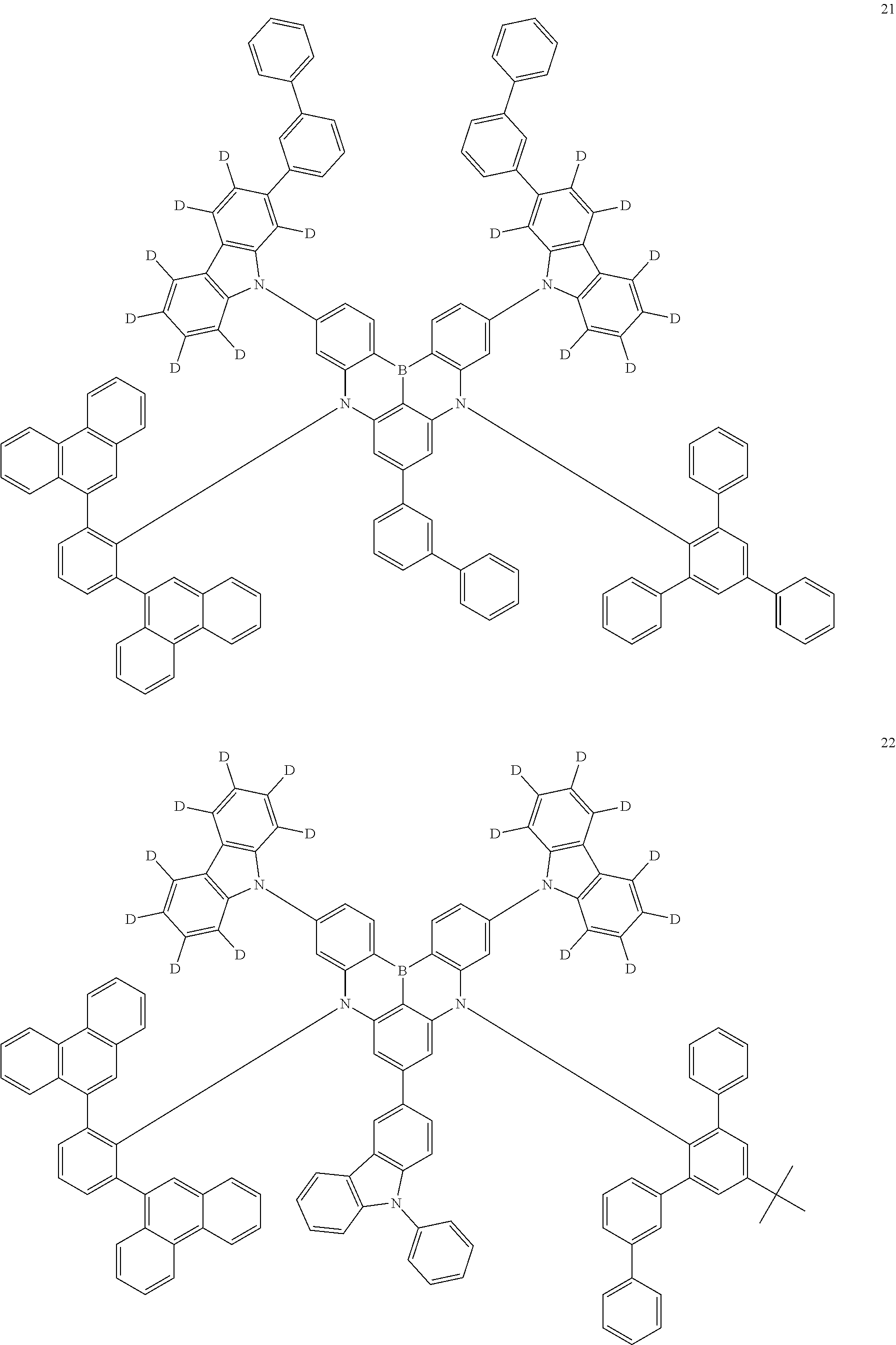 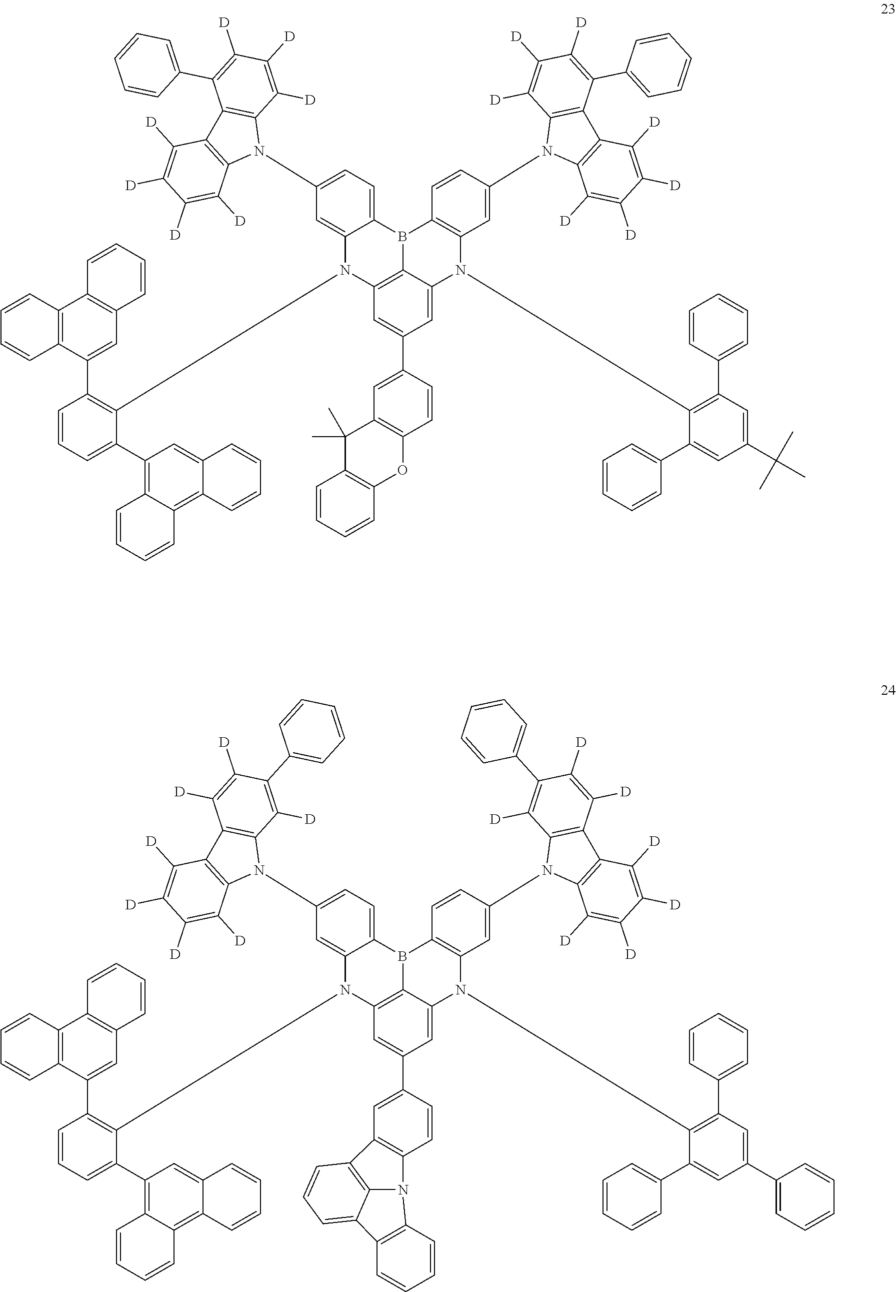 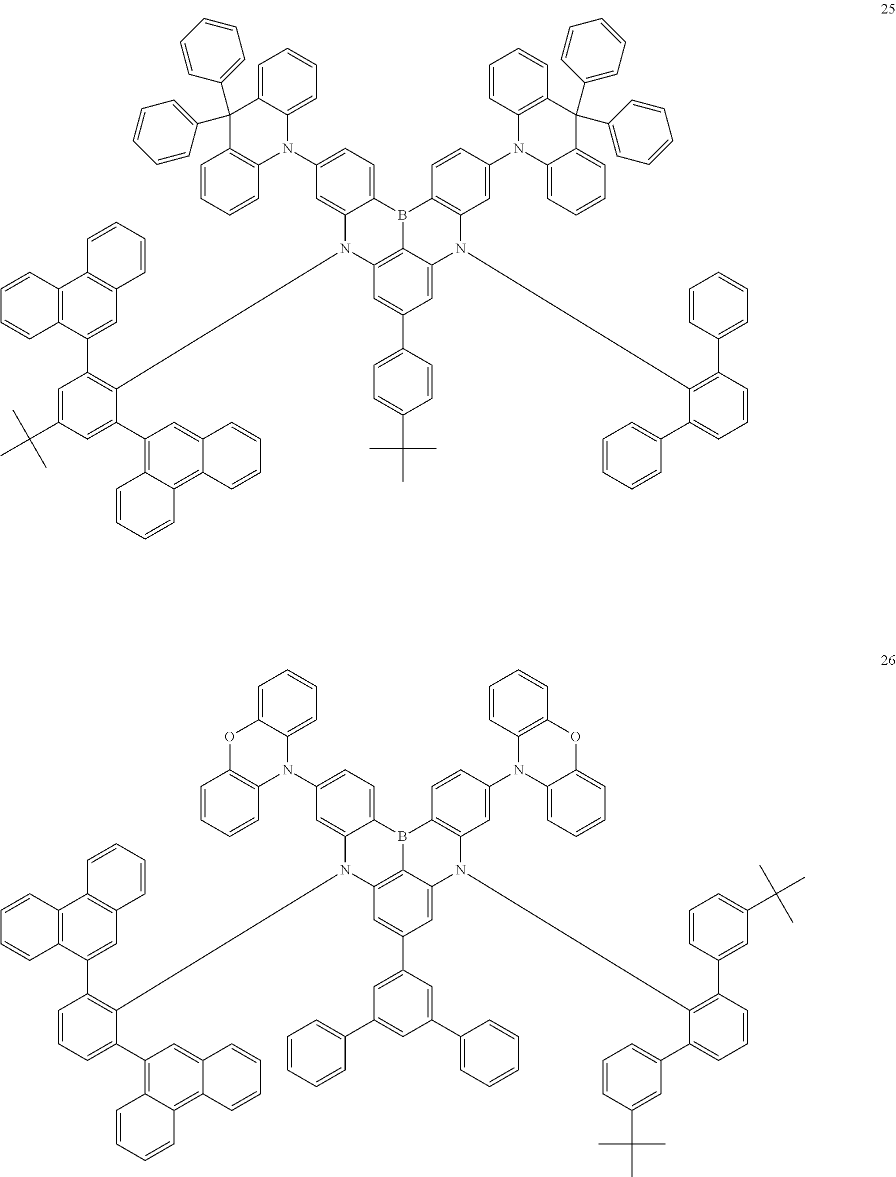 [SMILES: CC(C)(C)c1ccc(-c2cc3c4c(c2)N(c2c(-c5cc6ccccc6c6ccccc56)cc(C(C)(C)C)cc2-c2cc5ccccc5c5ccccc25)c2cc(N5c6ccccc6C(c6ccccc6)(c6ccccc6)c6ccccc65)ccc2B4c2ccc(N4c5ccccc5C(c5ccccc5)(c5ccccc5)c5ccccc54)cc2N3c2c(-c3ccccc3)cccc2-c2ccccc2)cc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5cc6ccccc6c6ccccc56)cccc4-c4cc5ccccc5c5ccccc45)c4cc(-c5cc(-c6ccccc6)cc(-c6ccccc6)c5)cc2c43)c1] 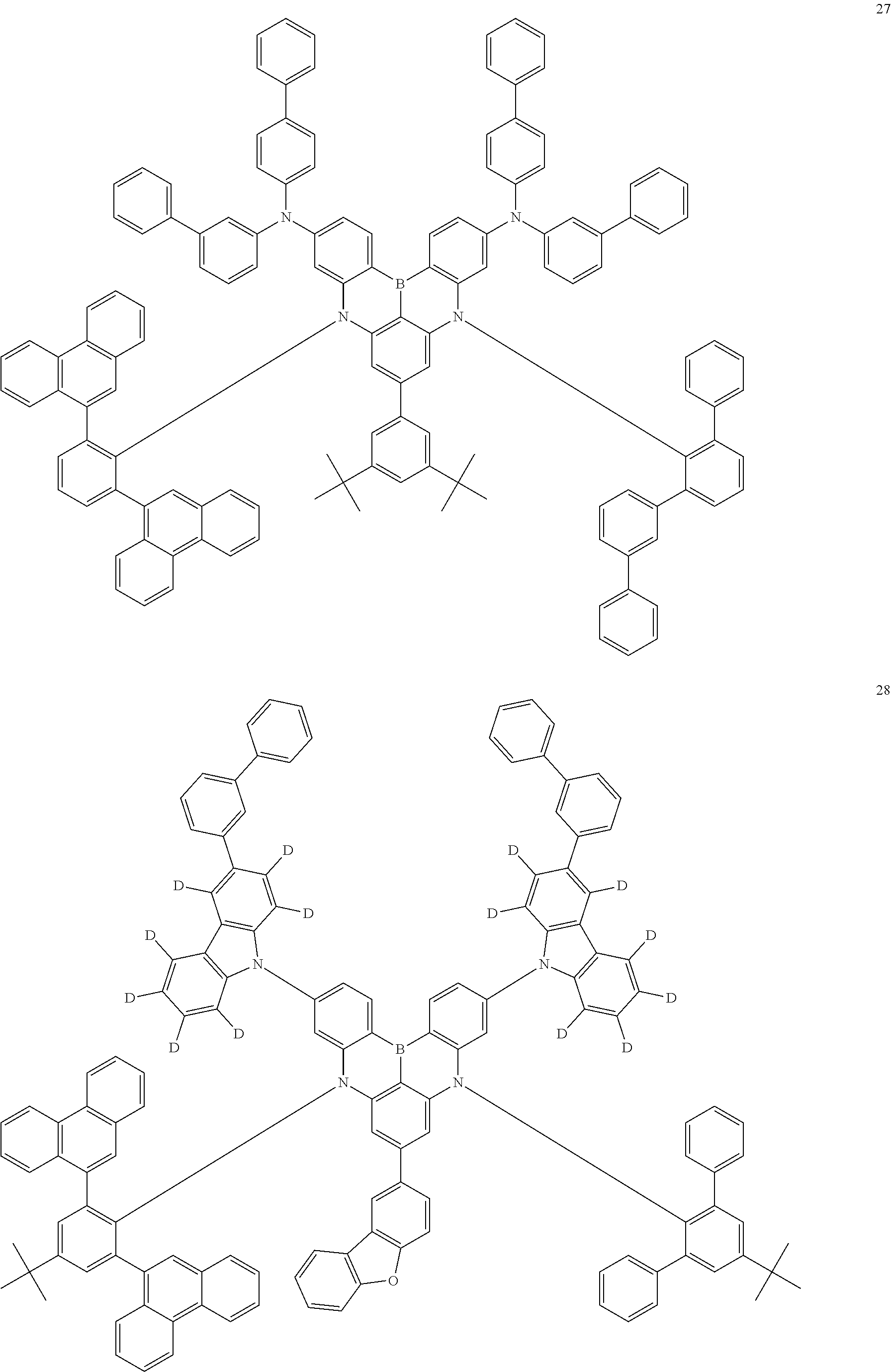 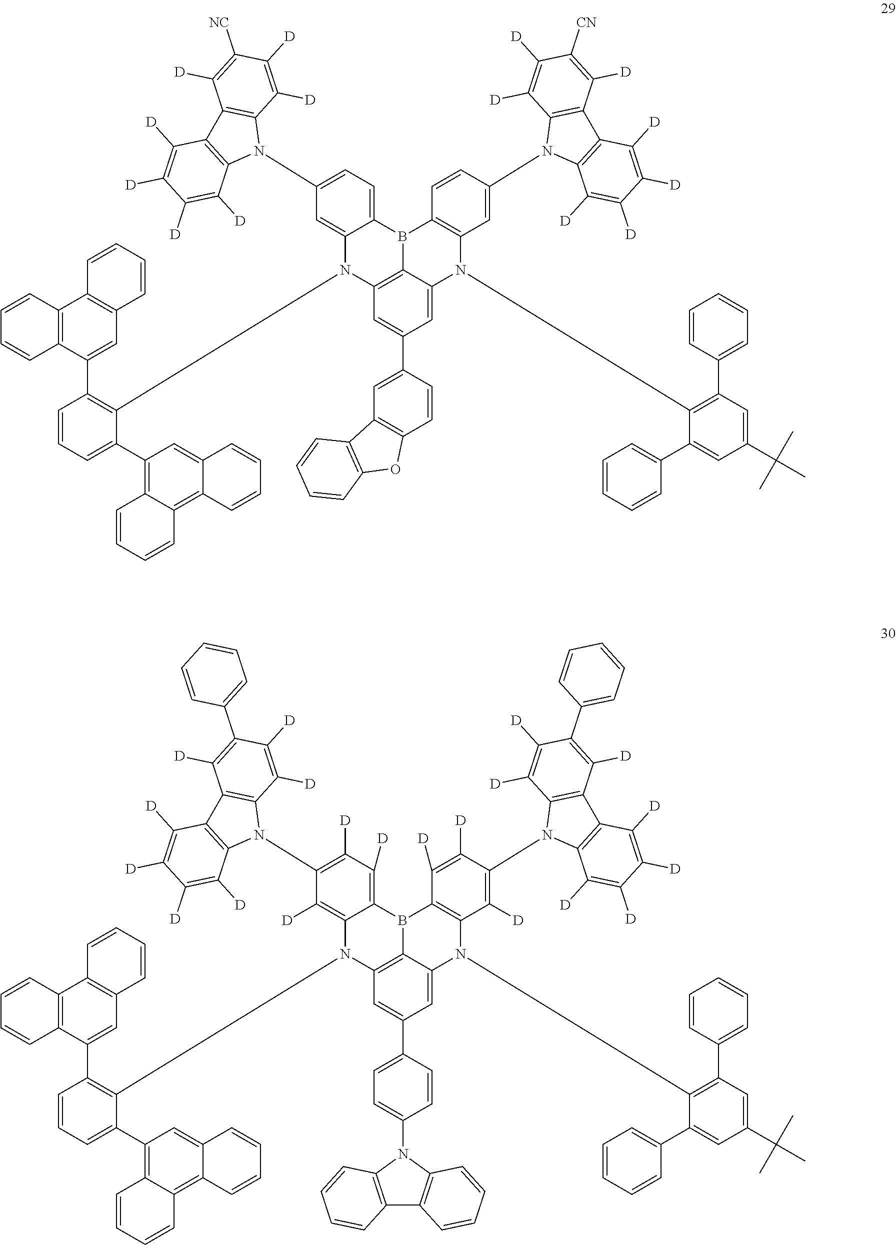 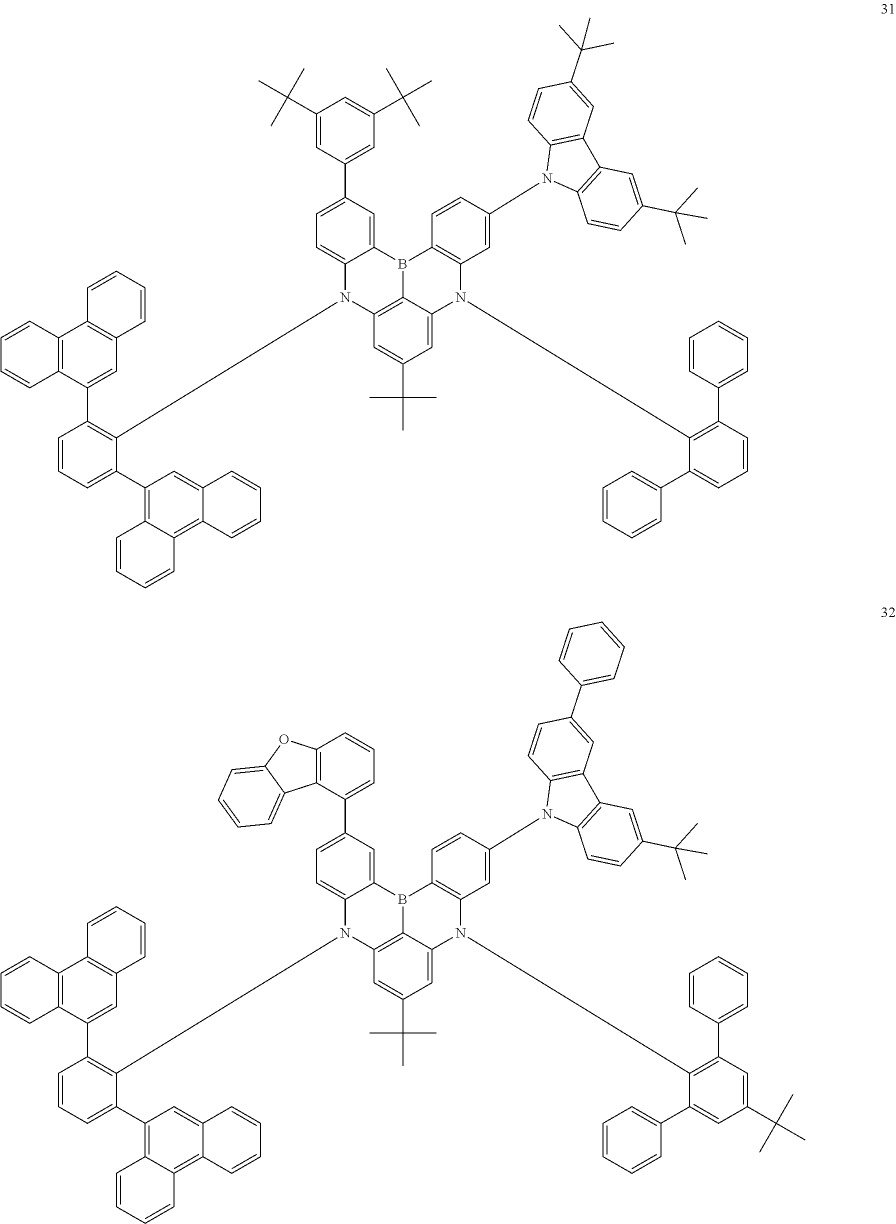 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3cc4ccccc4c4ccccc34)cccc2-c2cc3ccccc3c3ccccc23)cc(C(C)(C)C)c1 ; CC(C)(C)c1cc(-c2ccccc2)c(N2c3cc(-n4c5ccc(-c6ccccc6)cc5c5cc(C(C)(C)C)ccc54)ccc3B3c4cc(-c5cccc6oc7ccccc7c56)ccc4N(c4c(-c5cc6ccccc6c6ccccc56)cccc4-c4cc5ccccc5c5ccccc45)c4cc(C(C)(C)C)cc2c43)c(-c2ccccc2)c1] 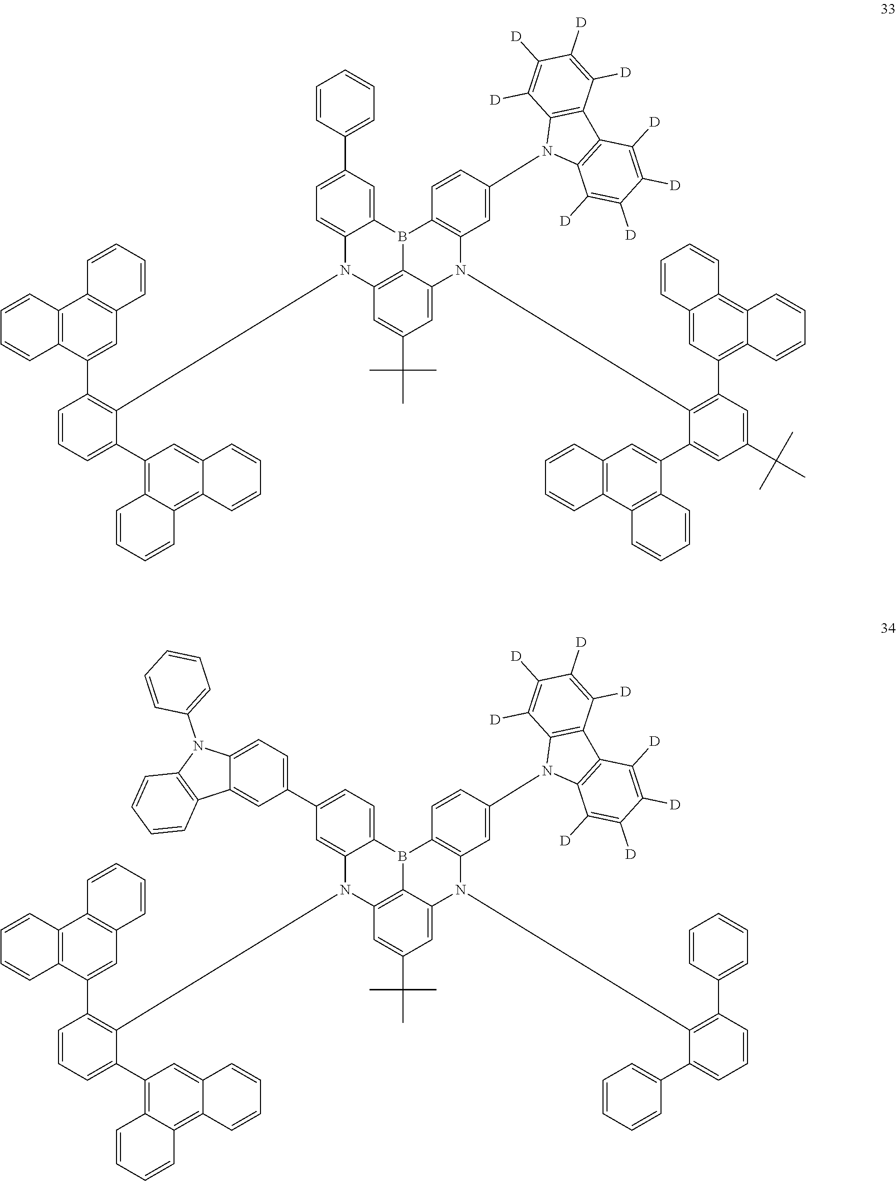 [SMILES: [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cc(C(C)(C)C)cc1-c1cc3ccccc3c3ccccc13)c1cc(C(C)(C)C)cc3c1B2c1cc(-c2ccccc2)ccc1N3c1c(-c2cc3ccccc3c3ccccc23)cccc1-c1cc2ccccc2c2ccccc12 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2cc3ccccc3c3ccccc23)cccc1-c1cc2ccccc2c2ccccc12] 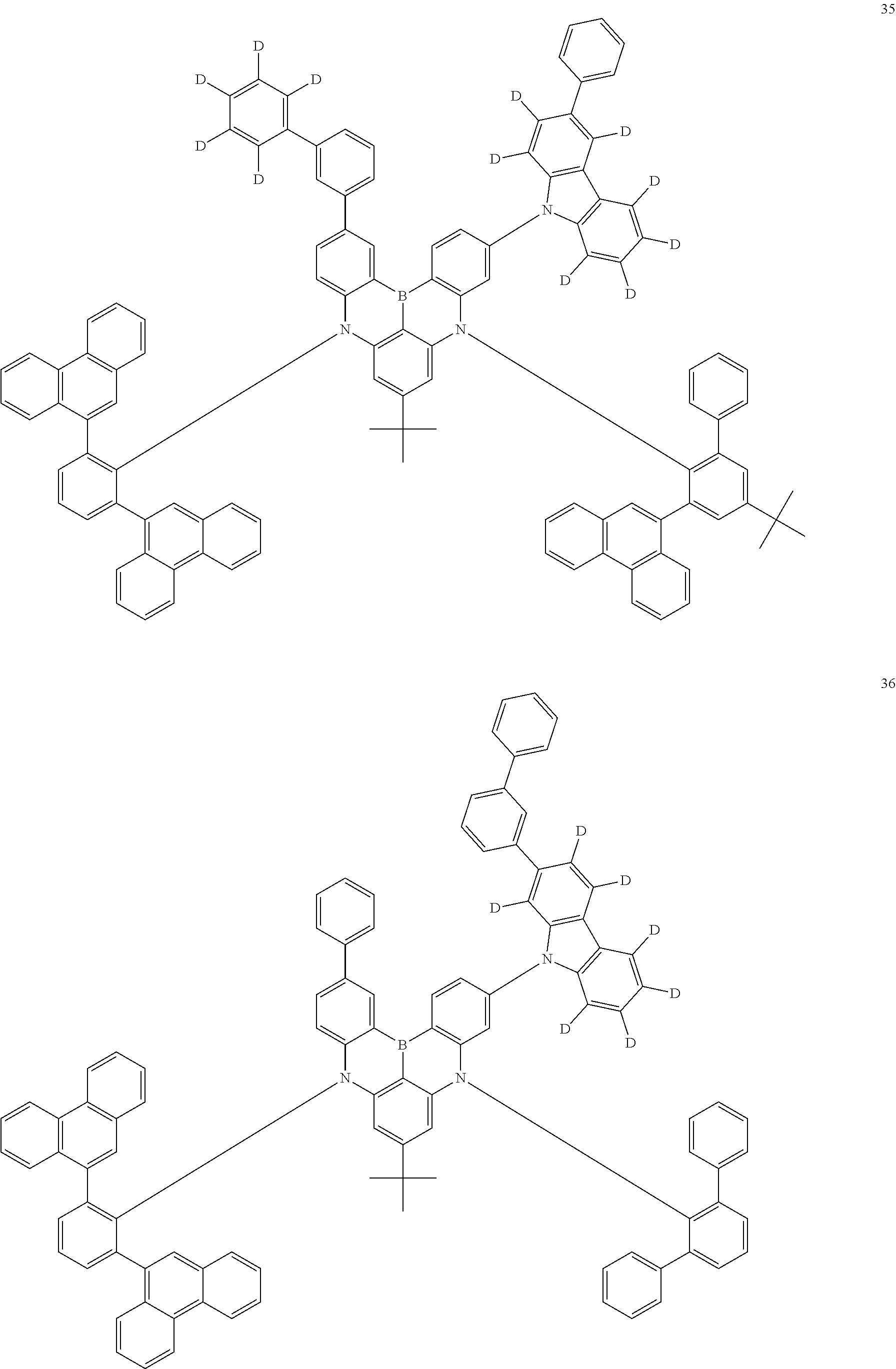 [SMILES: [2H]c1c([2H])c([2H])c(-c2cccc(-c3ccc4c(c3)B3c5ccc(-n6c7c([2H])c([2H])c([2H])c([2H])c7c7c([2H])c(-c8ccccc8)c([2H])c([2H])c76)cc5N(c5c(-c6ccccc6)cc(C(C)(C)C)cc5-c5cc6ccccc6c6ccccc56)c5cc(C(C)(C)C)cc(c53)N4c3c(-c4cc5ccccc5c5ccccc45)cccc3-c3cc4ccccc4c4ccccc34)c2)c([2H])c1[2H] ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2cc3ccccc3c3ccccc23)cccc1-c1cc2ccccc2c2ccccc12] 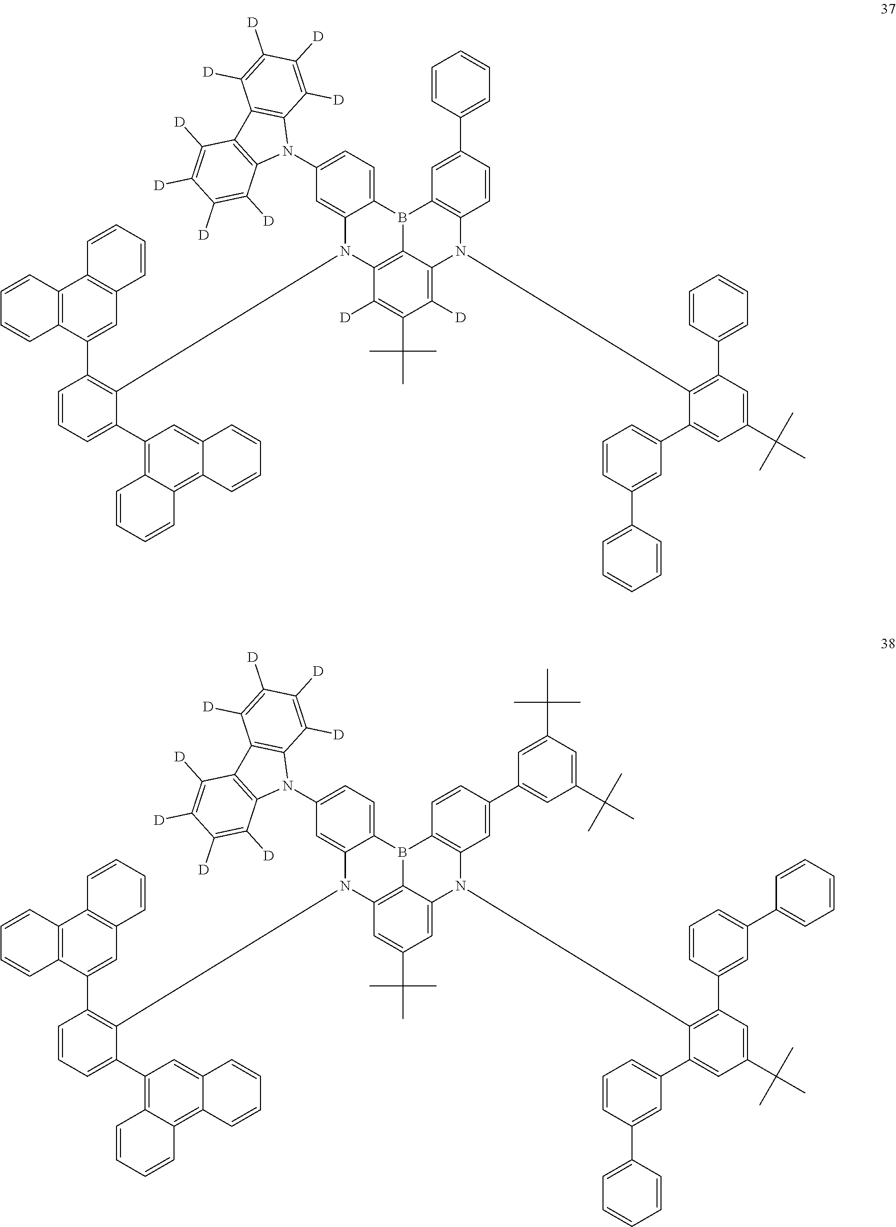 [SMILES: [2H]c1c2c3c(c([2H])c1C(C)(C)C)N(c1c(-c4cc5ccccc5c5ccccc45)cccc1-c1cc4ccccc4c4ccccc14)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1] 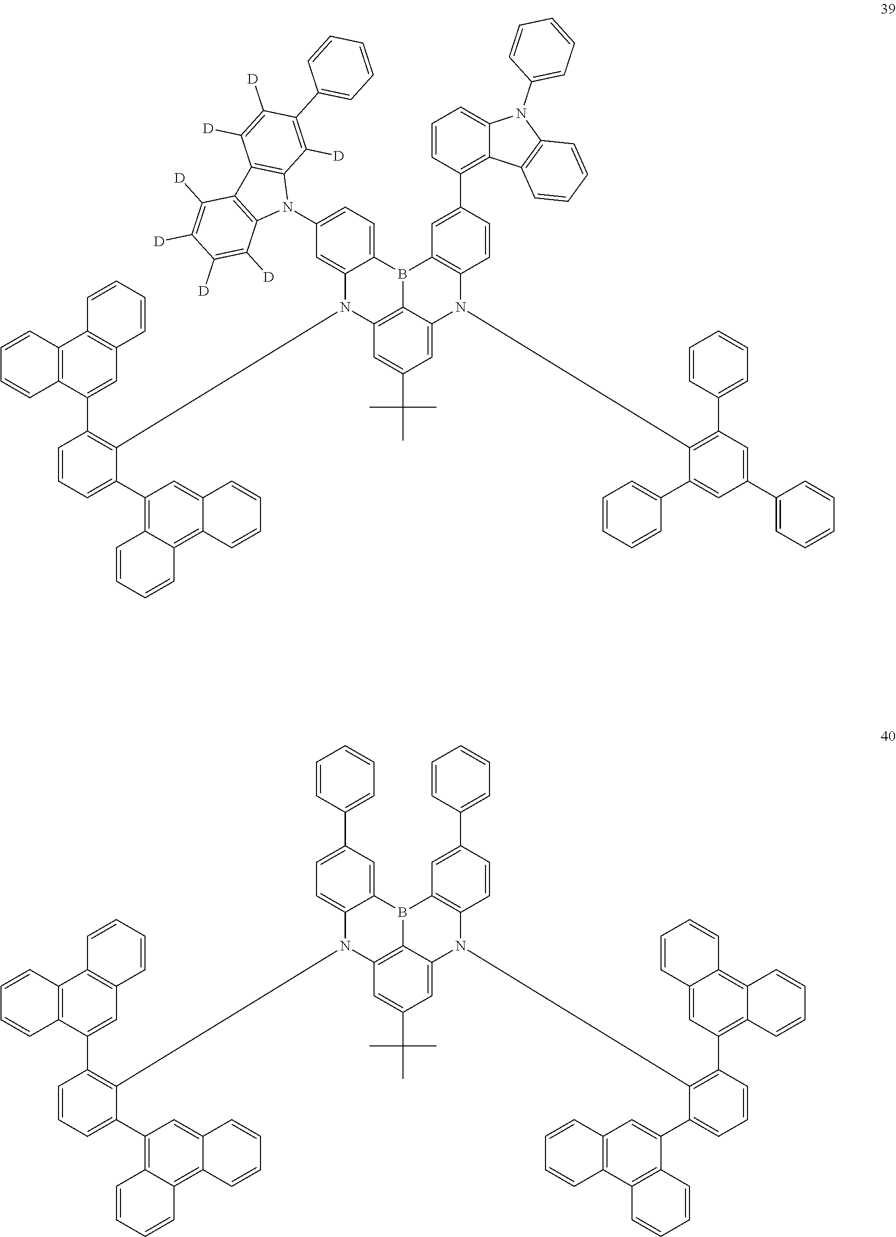 [SMILES: [2H]c1c([2H])c([2H])c2c(c1[2H])c1c([2H])c([2H])c(-c3ccccc3)c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1cc(-c2cccc4c2c2ccccc2n4-c2ccccc2)ccc1N3c1c(-c2ccccc2)cc(-c2ccccc2)cc1-c1ccccc1 ; CC(C)(C)c1cc2c3c(c1)N(c1c(-c4cc5ccccc5c5ccccc45)cccc1-c1cc4ccccc4c4ccccc14)c1ccc(-c4ccccc4)cc1B3c1cc(-c3ccccc3)ccc1N2c1c(-c2cc3ccccc3c3ccccc23)cccc1-c1cc2ccccc2c2ccccc12] 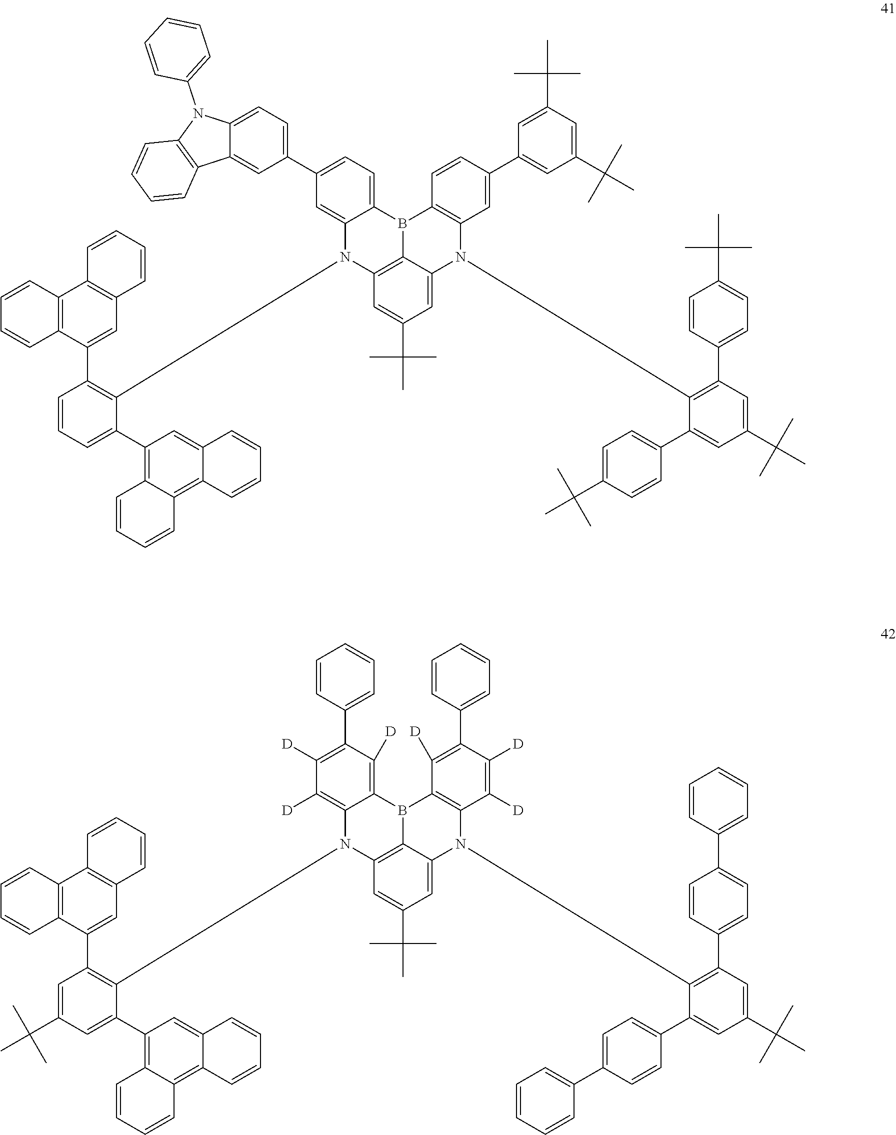 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-c5ccc6c(c5)c5ccccc5n6-c5ccccc5)cc4N(c4c(-c5cc6ccccc6c6ccccc56)cccc4-c4cc5ccccc5c5ccccc45)c4cc(C(C)(C)C)cc2c43)cc1 ; [2H]c1c([2H])c2c(c([2H])c1-c1ccccc1)B1c3c(cc(C(C)(C)C)cc3N(c3c(-c4cc5ccccc5c5ccccc45)cc(C(C)(C)C)cc3-c3cc4ccccc4c4ccccc34)c3c([2H])c([2H])c(-c4ccccc4)c([2H])c31)N2c1c(-c2ccc(-c3ccccc3)cc2)cc(C(C)(C)C)cc1-c1ccc(-c2ccccc2)cc1] 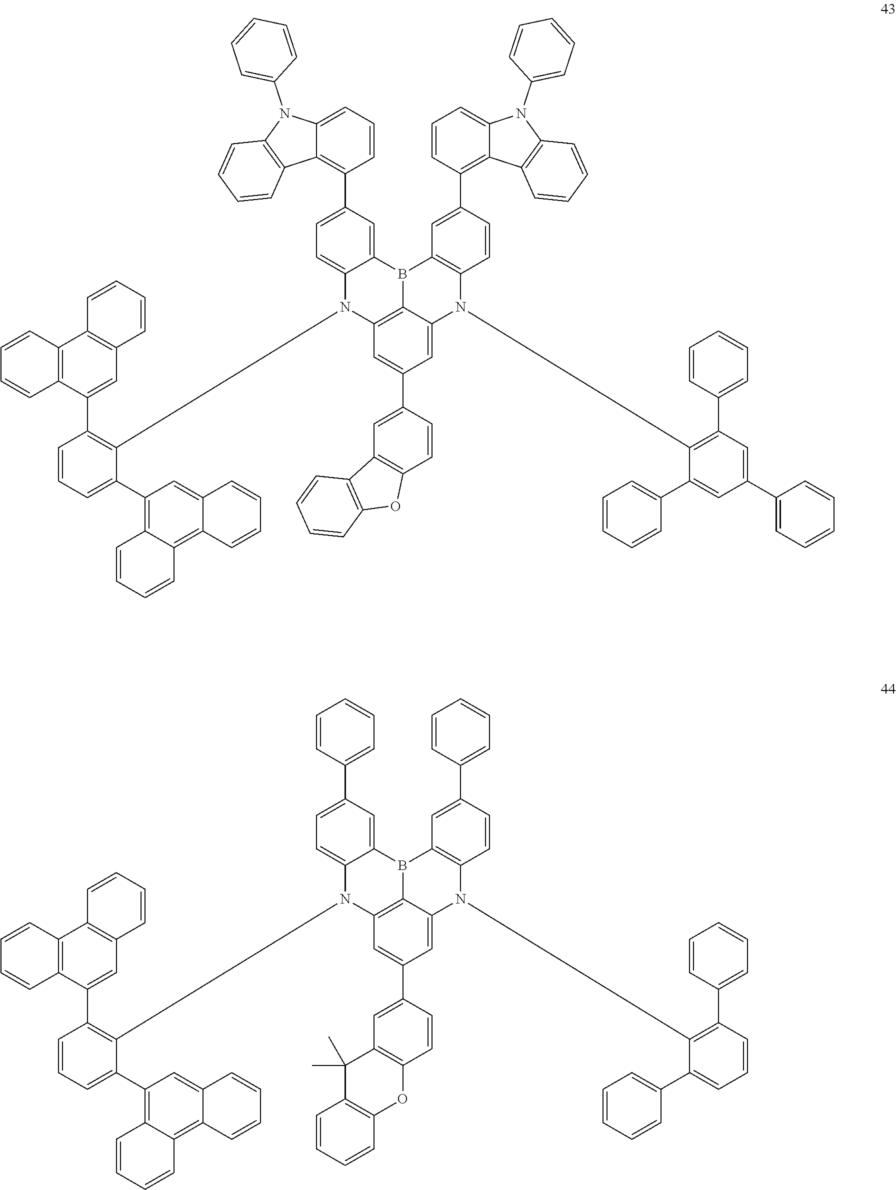 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6cc7ccccc7c7ccccc67)cccc5-c5cc6ccccc6c6ccccc56)c5cc(-c6ccc7oc8ccccc8c7c6)cc3c54)c(-c3ccccc3)c2)cc1 ; CC1(C)c2ccccc2Oc2ccc(-c3cc4c5c(c3)N(c3c(-c6cc7ccccc7c7ccccc67)cccc3-c3cc6ccccc6c6ccccc36)c3ccc(-c6ccccc6)cc3B5c3cc(-c5ccccc5)ccc3N4c3c(-c4ccccc4)cccc3-c3ccccc3)cc21] 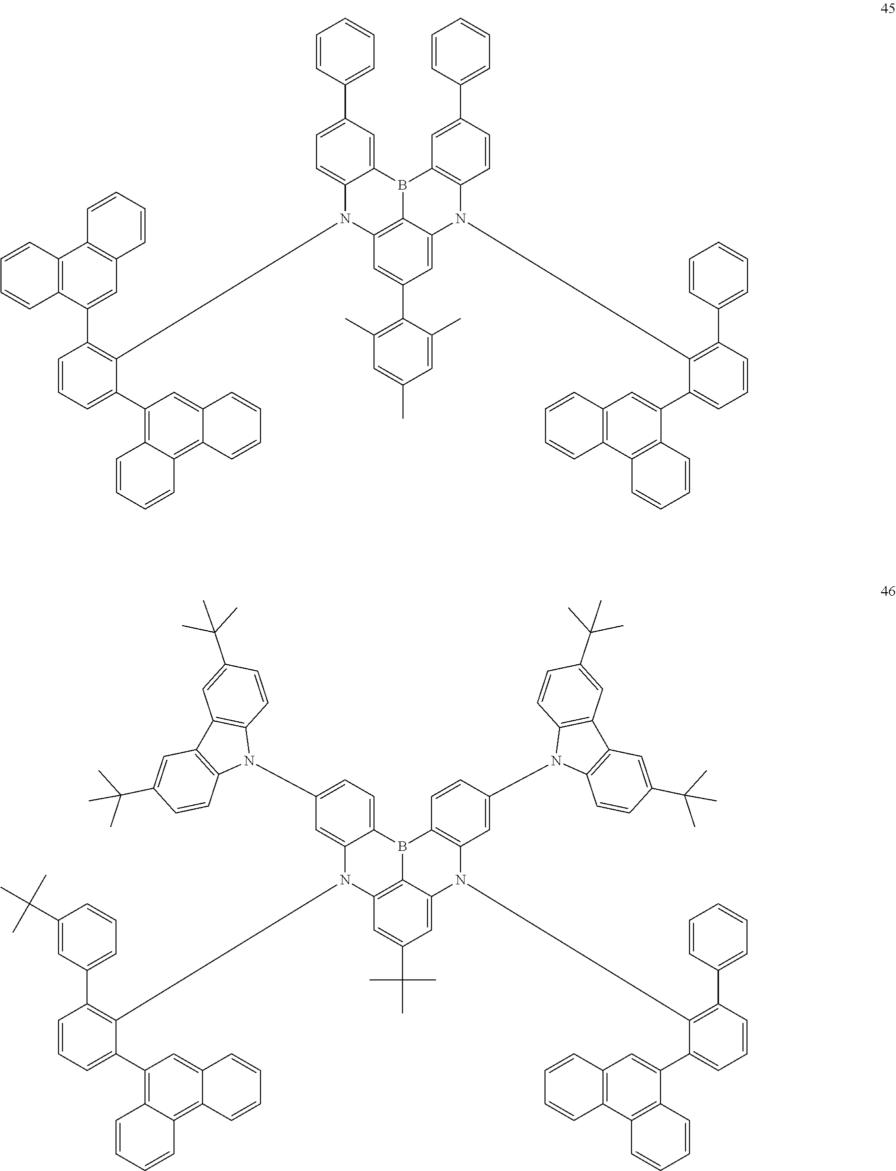 [SMILES: Cc1cc(C)c(-c2cc3c4c(c2)N(c2c(-c5cc6ccccc6c6ccccc56)cccc2-c2cc5ccccc5c5ccccc25)c2ccc(-c5ccccc5)cc2B4c2cc(-c4ccccc4)ccc2N3c2c(-c3ccccc3)cccc2-c2cc3ccccc3c3ccccc23)c(C)c1 ; CC(C)(C)c1cccc(-c2cccc(-c3cc4ccccc4c4ccccc34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cccc4-c4cc5ccccc5c5ccccc45)c4cc(C(C)(C)C)cc2c43)c1] 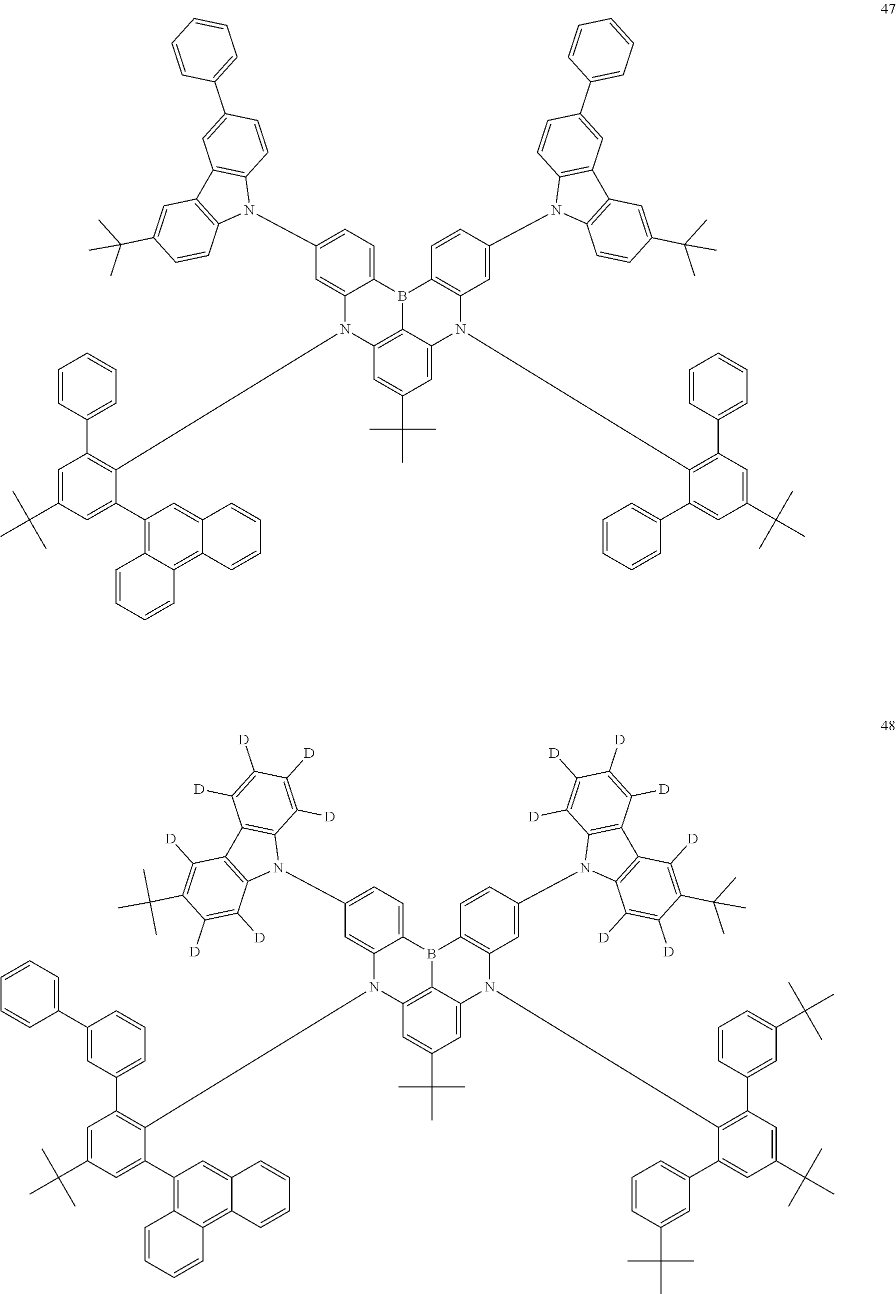 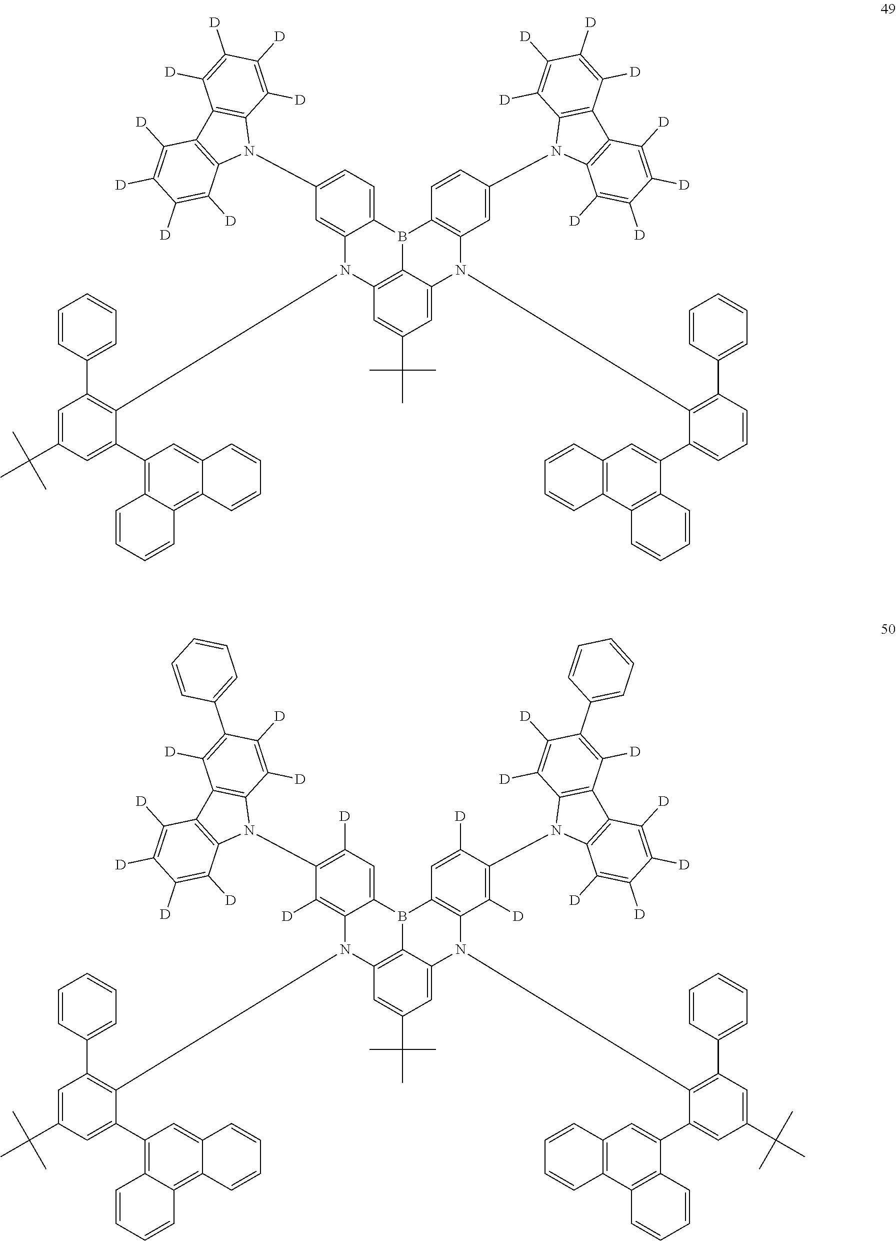 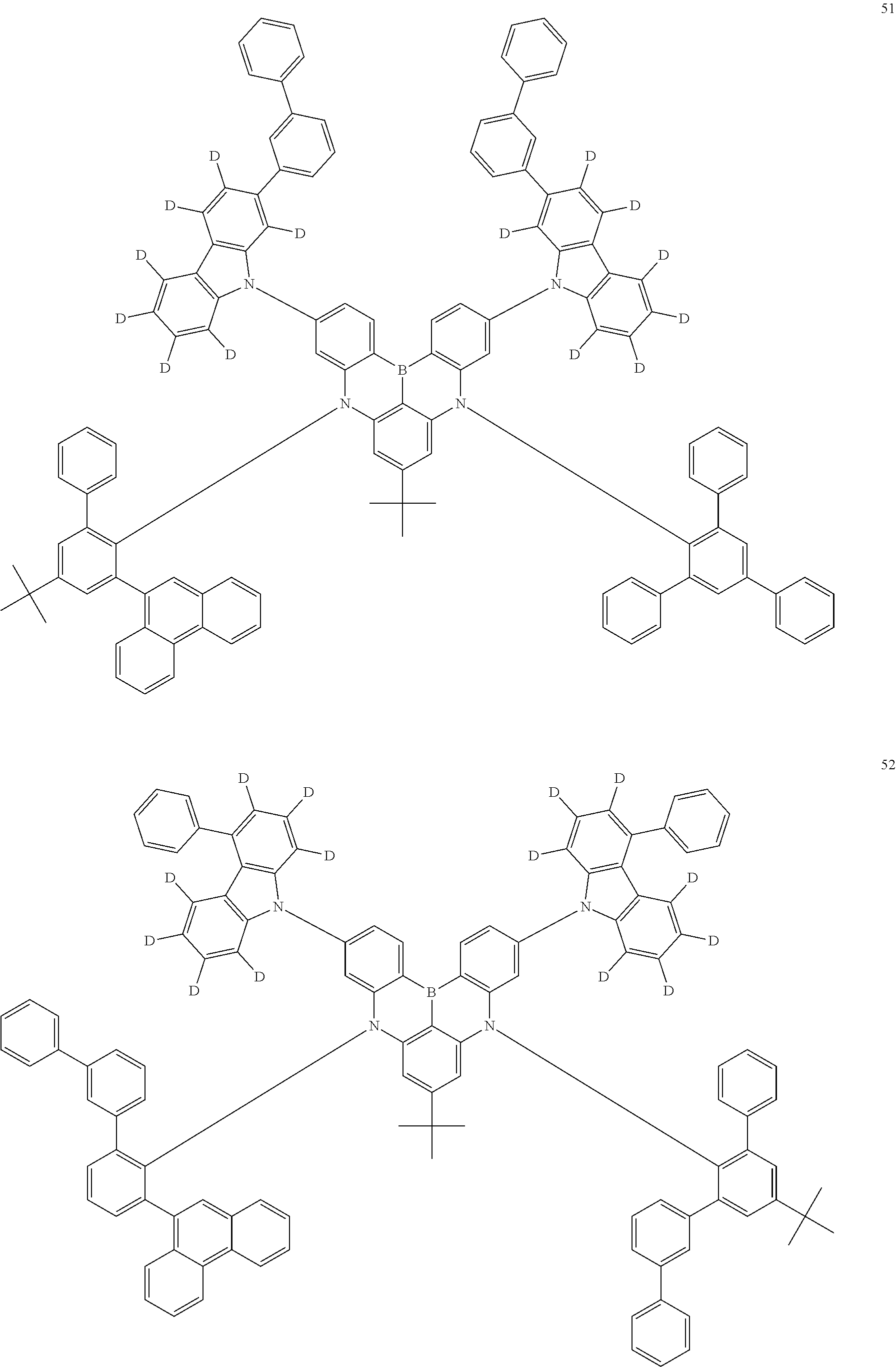 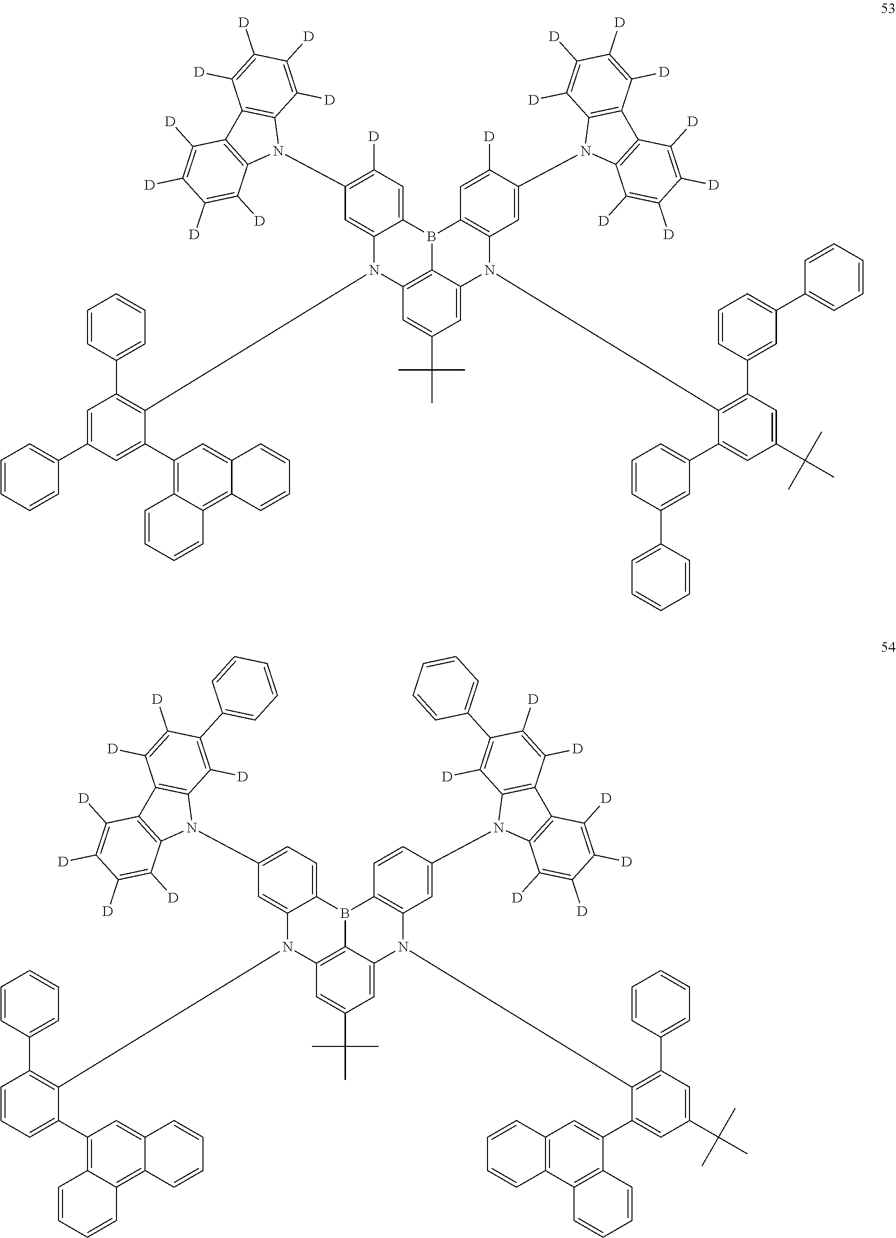 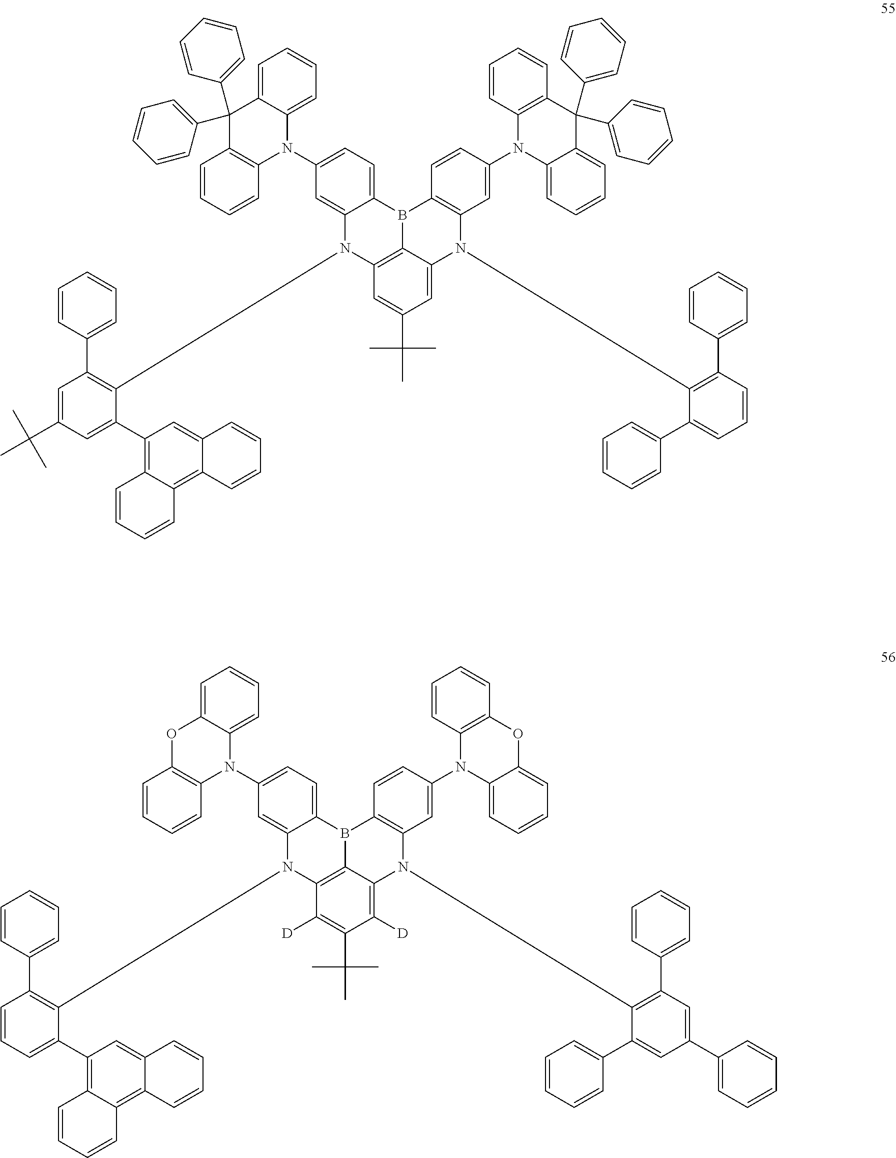 [SMILES: CC(C)(C)c1cc(-c2ccccc2)c(N2c3cc(N4c5ccccc5C(c5ccccc5)(c5ccccc5)c5ccccc54)ccc3B3c4ccc(N5c6ccccc6C(c6ccccc6)(c6ccccc6)c6ccccc65)cc4N(c4c(-c5ccccc5)cccc4-c4ccccc4)c4cc(C(C)(C)C)cc2c43)c(-c2cc3ccccc3c3ccccc23)c1 ; [2H]c1c2c3c(c([2H])c1C(C)(C)C)N(c1c(-c4ccccc4)cccc1-c1cc4ccccc4c4ccccc14)c1cc(N4c5ccccc5Oc5ccccc54)ccc1B3c1ccc(N3c4ccccc4Oc4ccccc43)cc1N2c1c(-c2ccccc2)cc(-c2ccccc2)cc1-c1ccccc1] 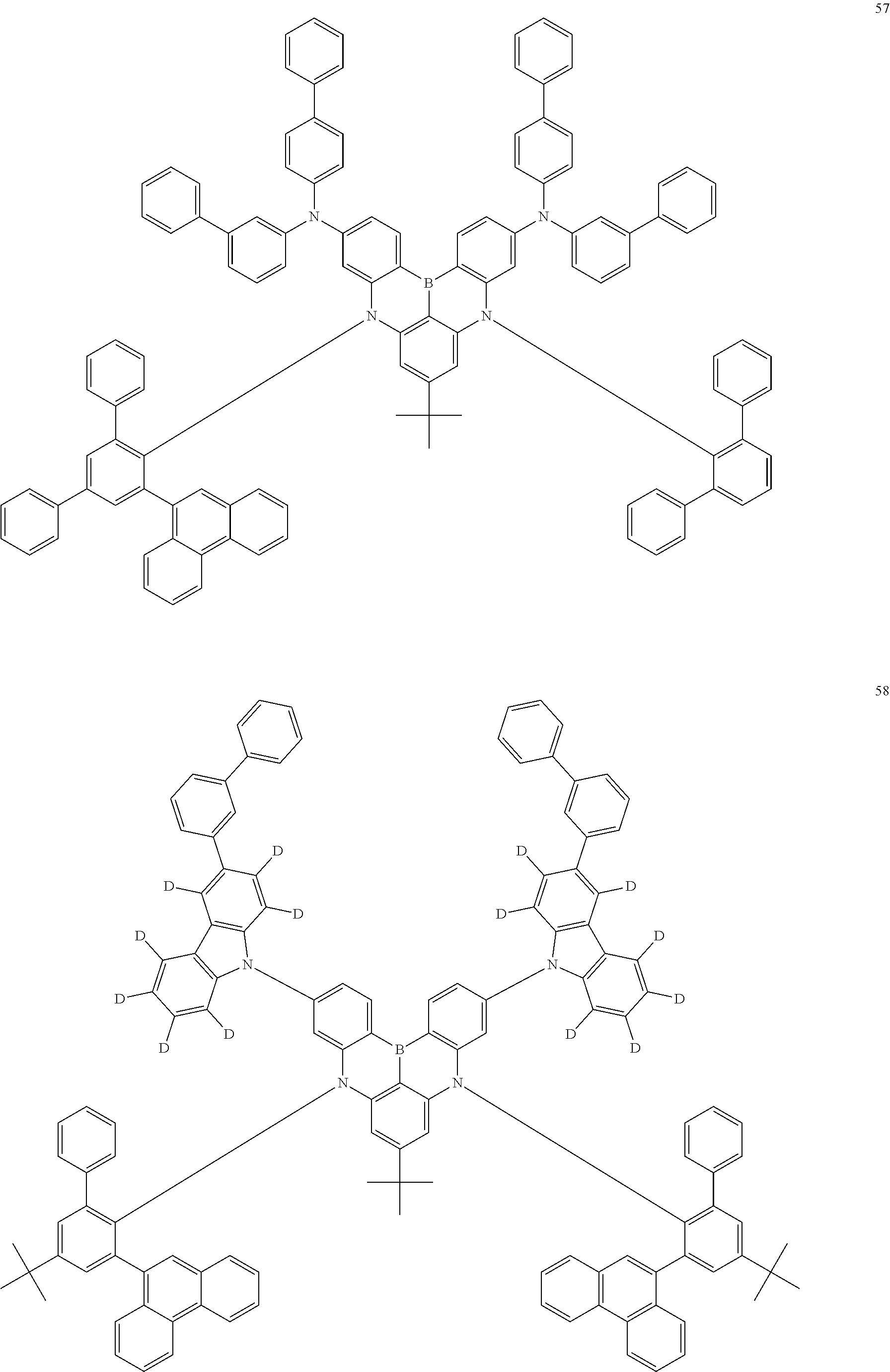 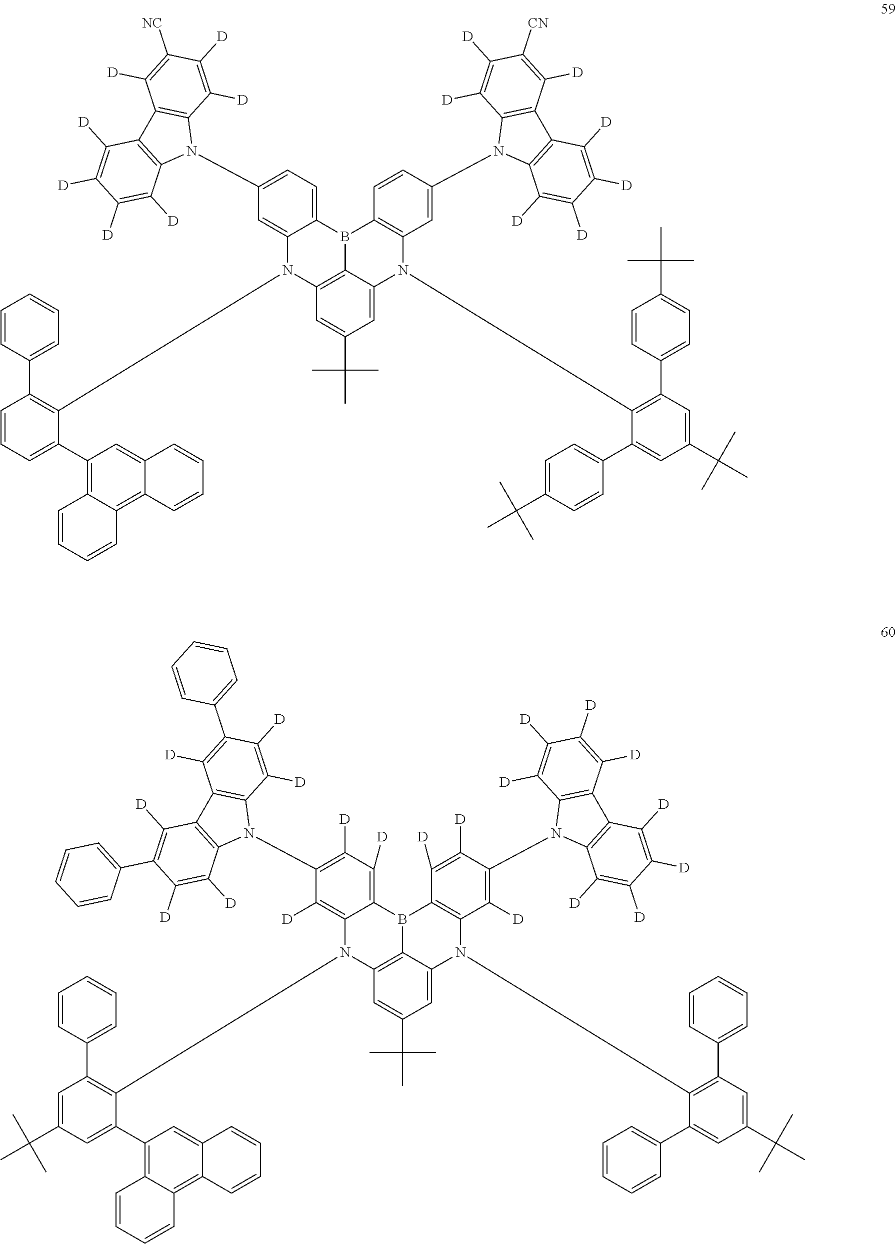 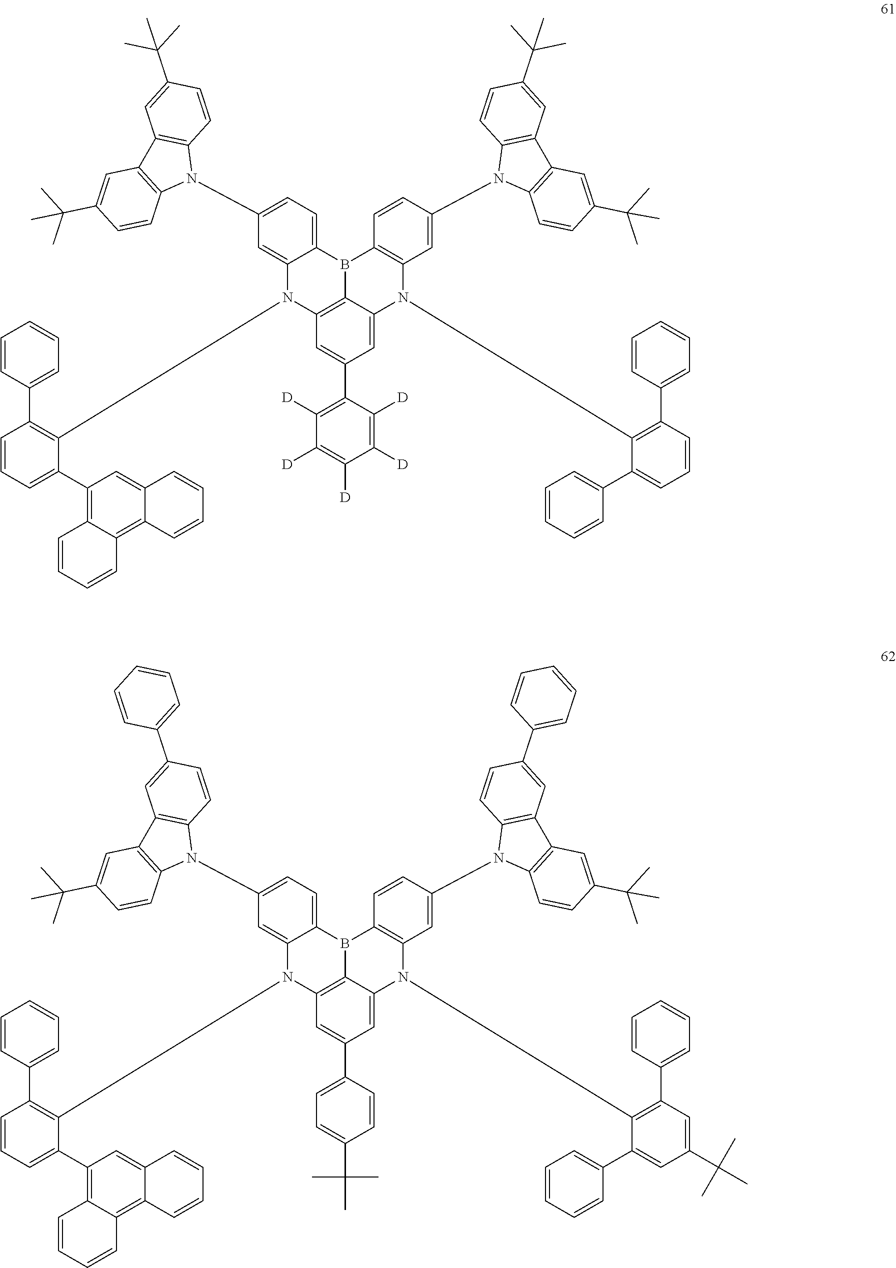 [SMILES: [2H]c1c([2H])c([2H])c(-c2cc3c4c(c2)N(c2c(-c5ccccc5)cccc2-c2cc5ccccc5c5ccccc25)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cccc2-c2ccccc2)c([2H])c1[2H] ; CC(C)(C)c1ccc(-c2cc3c4c(c2)N(c2c(-c5ccccc5)cccc2-c2cc5ccccc5c5ccccc25)c2cc(-n5c6ccc(-c7ccccc7)cc6c6cc(C(C)(C)C)ccc65)ccc2B4c2ccc(-n4c5ccc(-c6ccccc6)cc5c5cc(C(C)(C)C)ccc54)cc2N3c2c(-c3ccccc3)cc(C(C)(C)C)cc2-c2ccccc2)cc1] 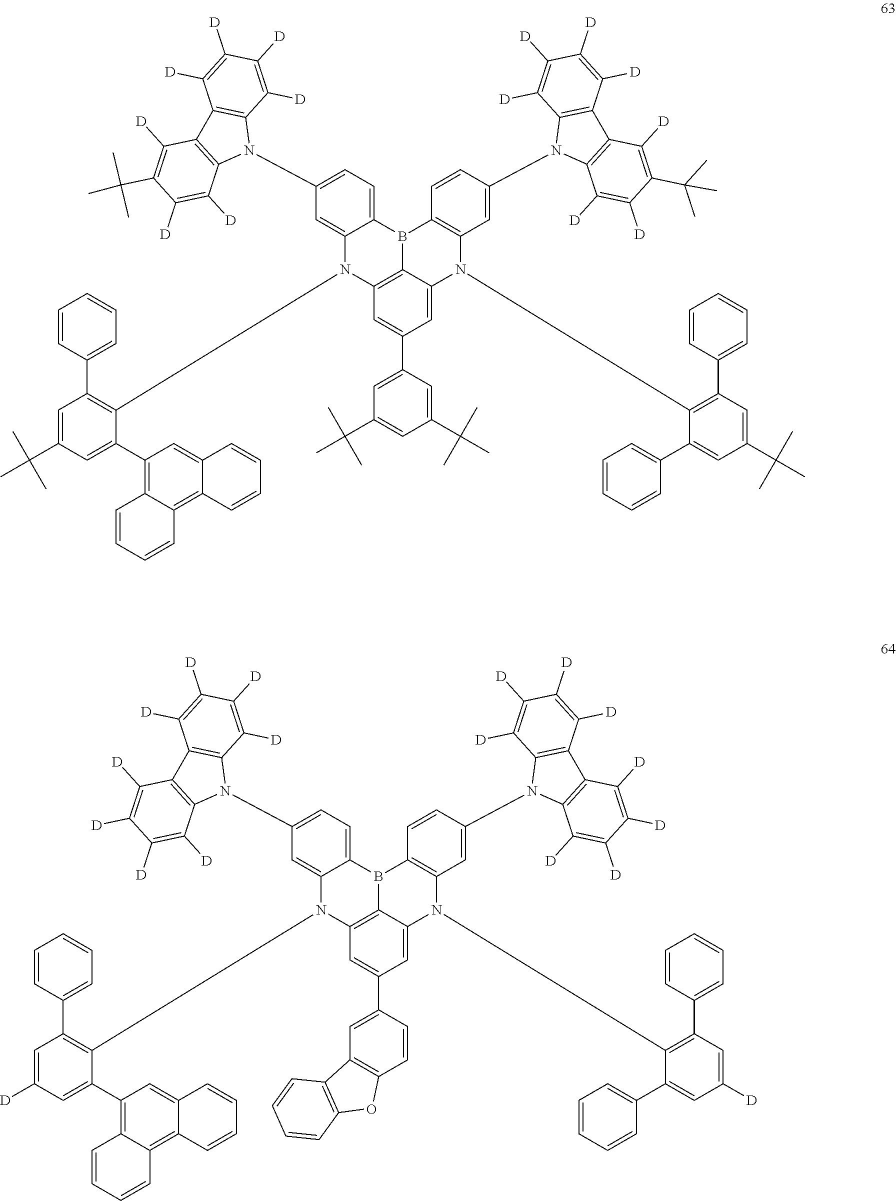 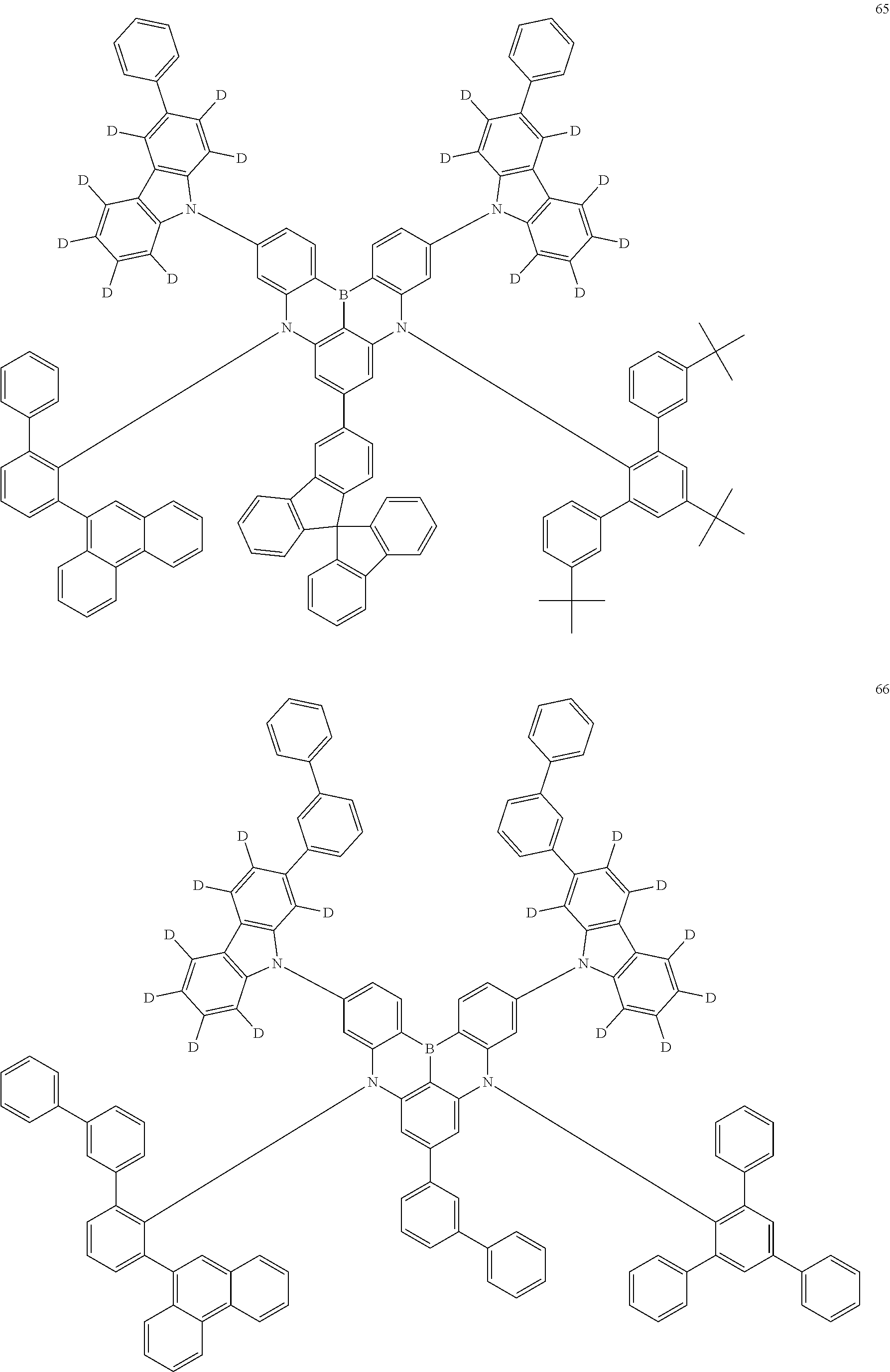 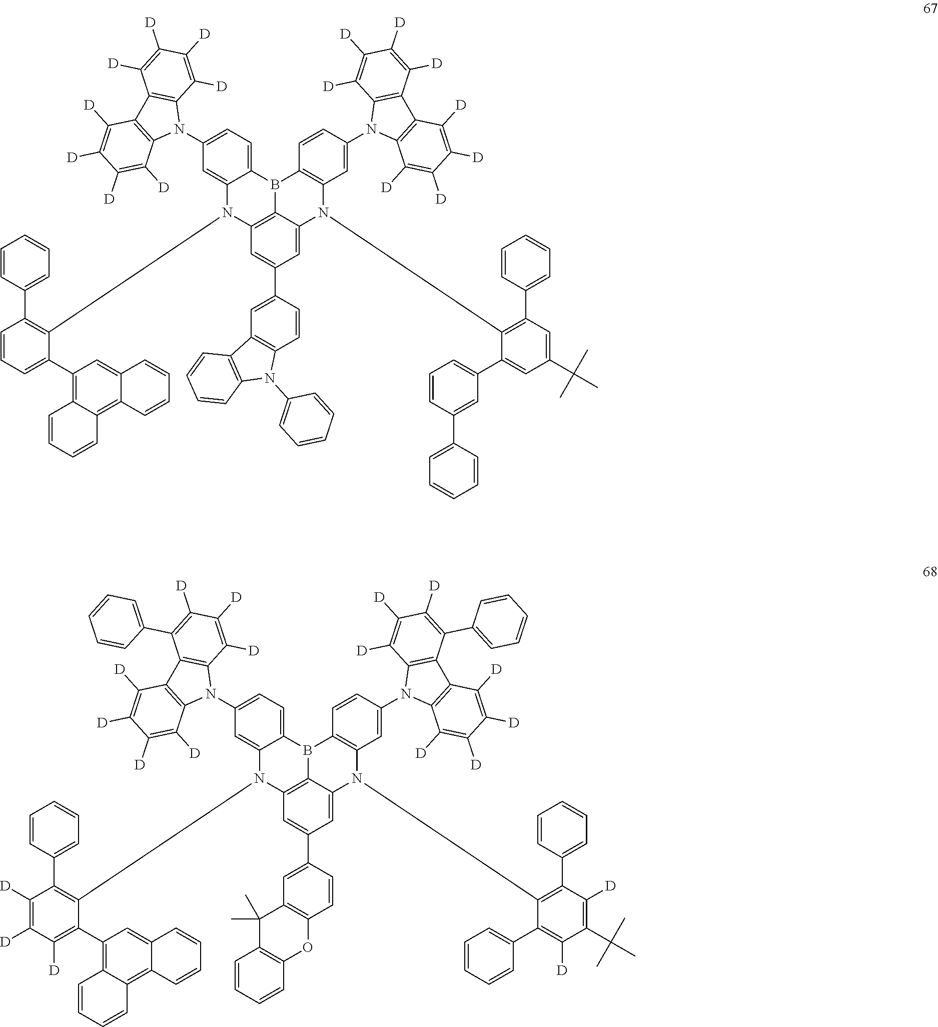 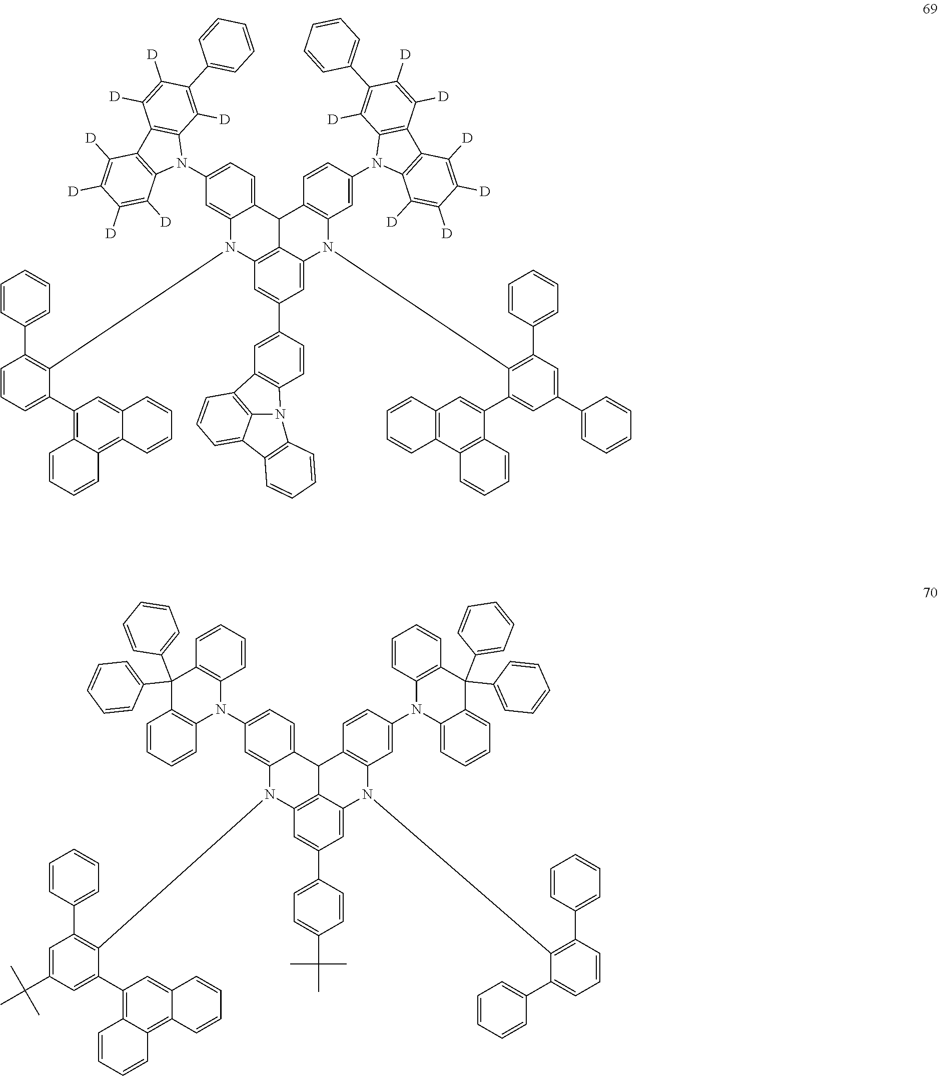 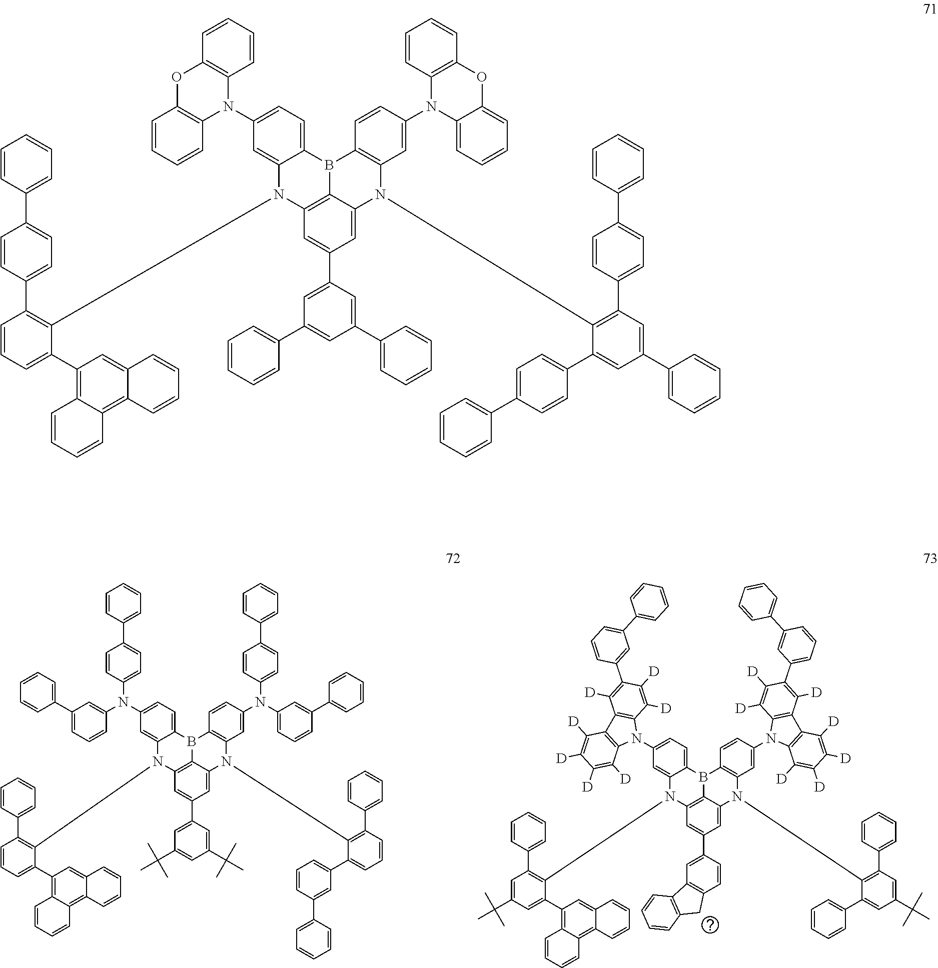 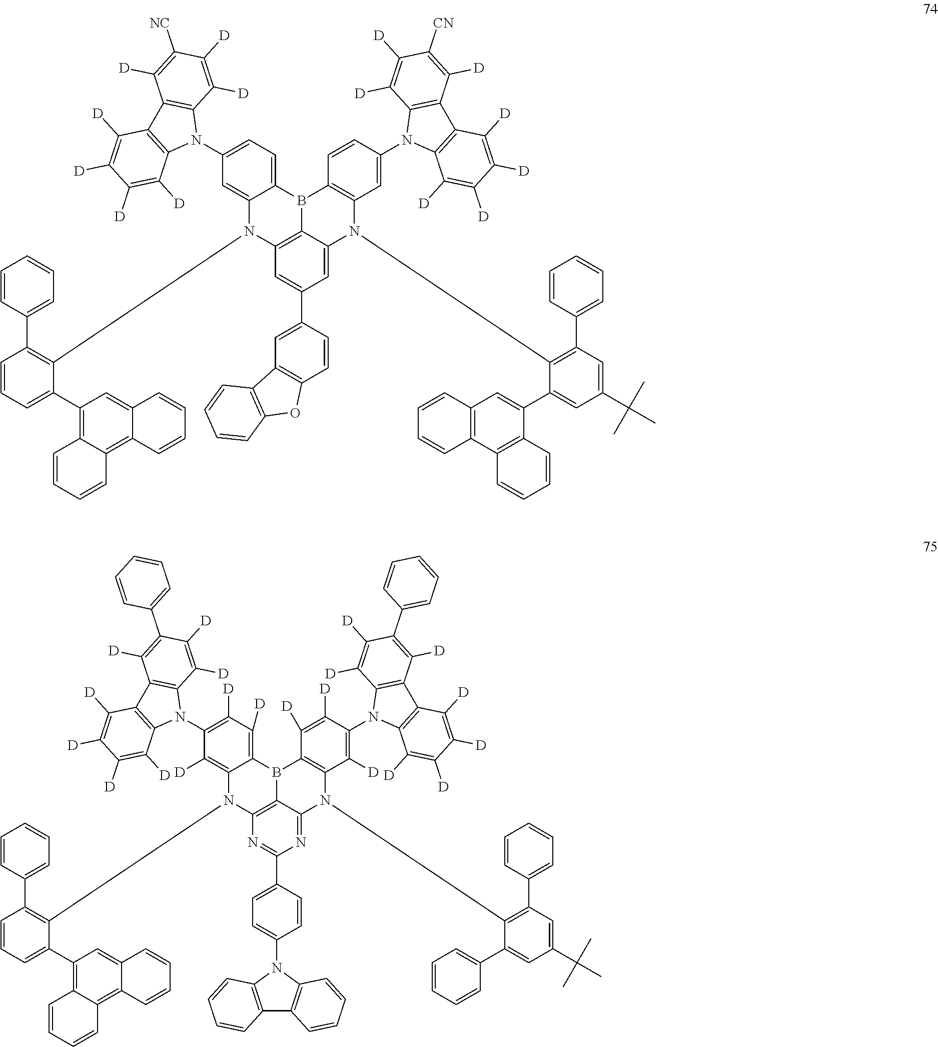 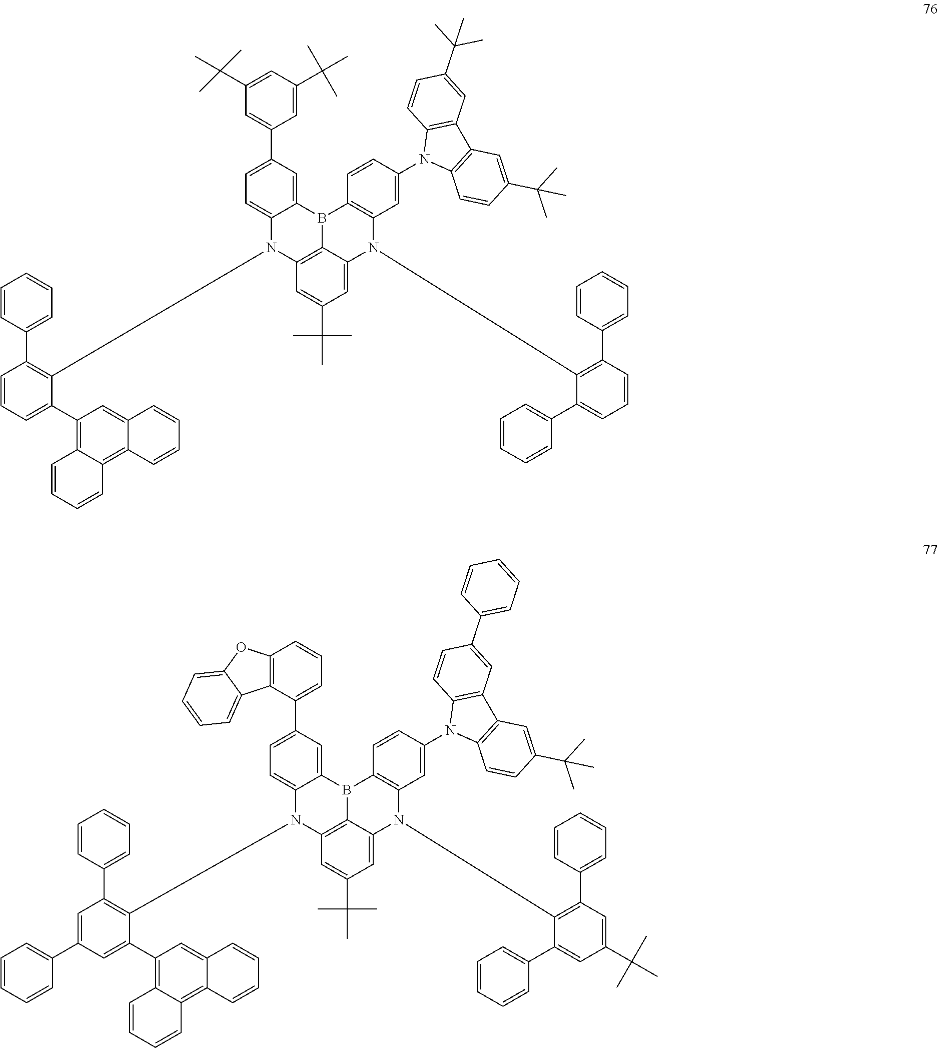 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3ccccc3)cccc2-c2cc3ccccc3c3ccccc23)cc(C(C)(C)C)c1 ; CC(C)(C)c1cc(-c2ccccc2)c(N2c3cc(-n4c5ccc(-c6ccccc6)cc5c5cc(C(C)(C)C)ccc54)ccc3B3c4cc(-c5cccc6oc7ccccc7c56)ccc4N(c4c(-c5ccccc5)cc(-c5ccccc5)cc4-c4cc5ccccc5c5ccccc45)c4cc(C(C)(C)C)cc2c43)c(-c2ccccc2)c1] 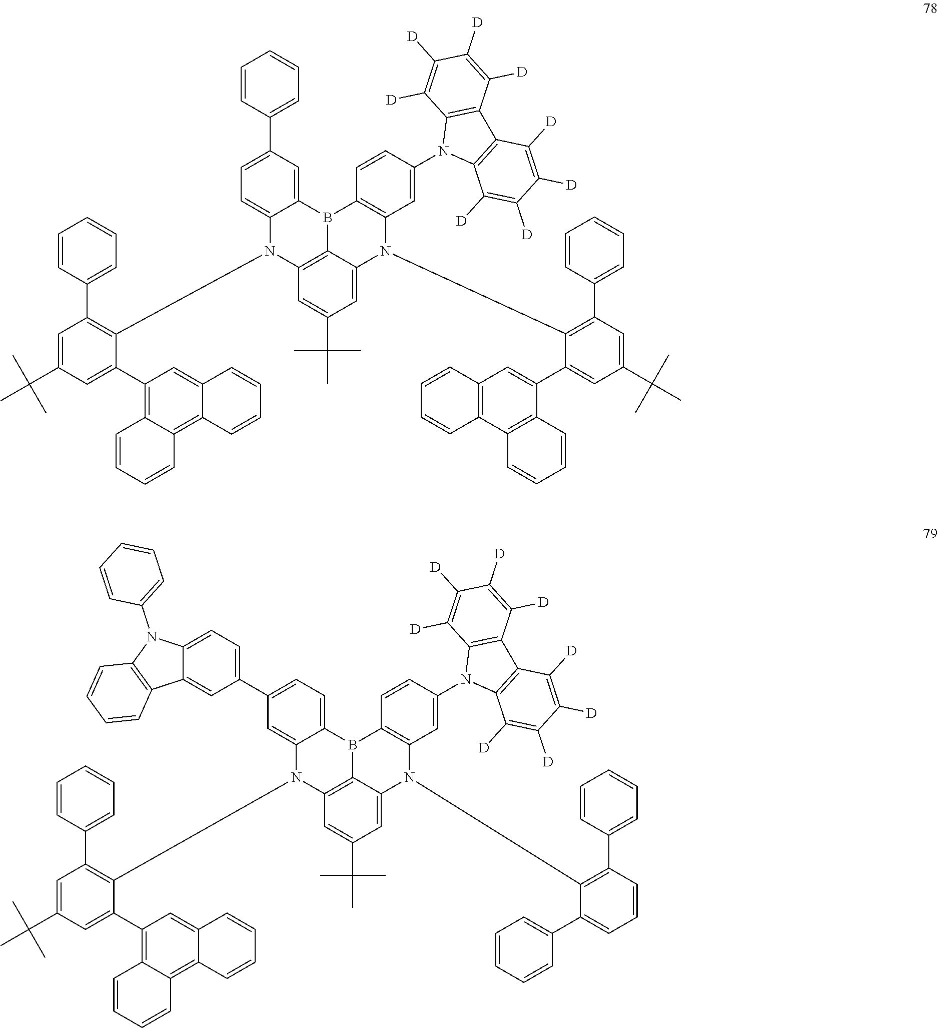 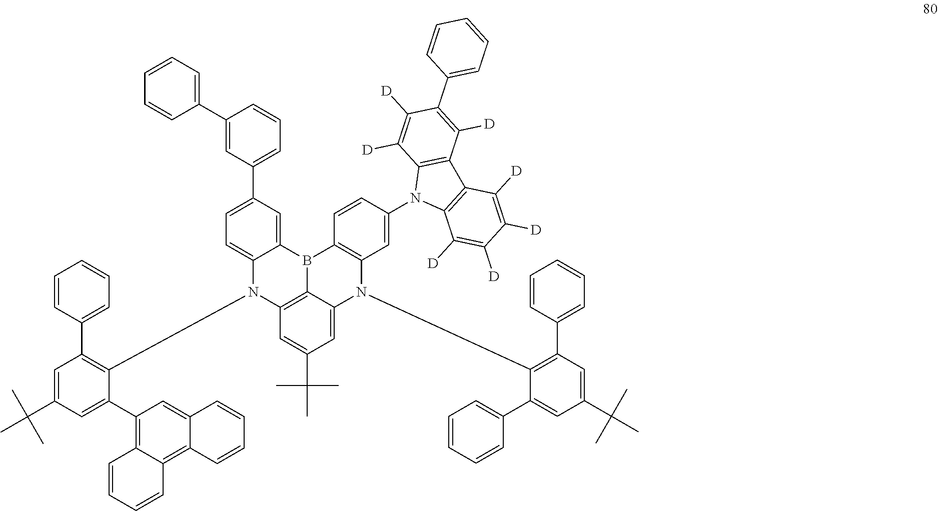 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccccc2)cc(C(C)(C)C)cc1-c1cc2ccccc2c2ccccc12] 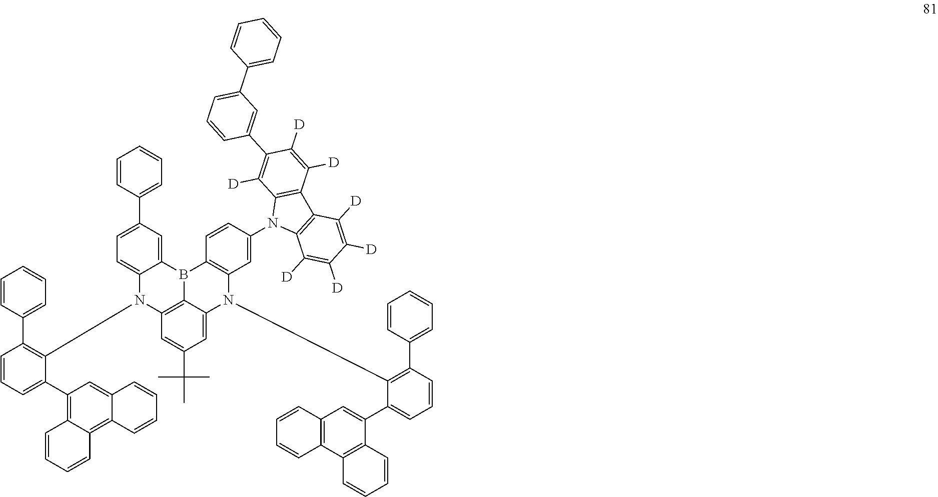 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1cc3ccccc3c3ccccc13)c1cc(C(C)(C)C)cc3c1B2c1cc(-c2ccccc2)ccc1N3c1c(-c2ccccc2)cccc1-c1cc2ccccc2c2ccccc12] 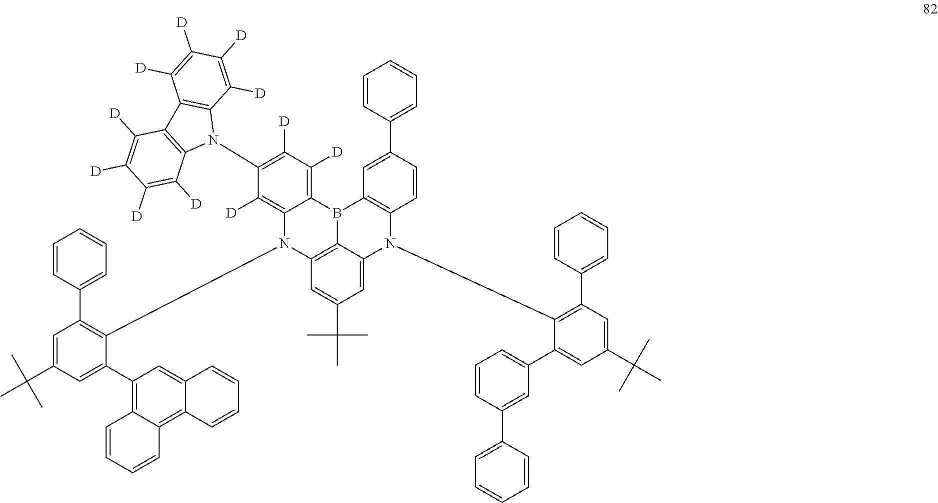 [SMILES: [2H]c1c([2H])c(-n2c3c([2H])c([2H])c([2H])c([2H])c3c3c([2H])c([2H])c([2H])c([2H])c32)c([2H])c2c1B1c3cc(-c4ccccc4)ccc3N(c3c(-c4ccccc4)cc(C(C)(C)C)cc3-c3cccc(-c4ccccc4)c3)c3cc(C(C)(C)C)cc(c31)N2c1c(-c2ccccc2)cc(C(C)(C)C)cc1-c1cc2ccccc2c2ccccc12] 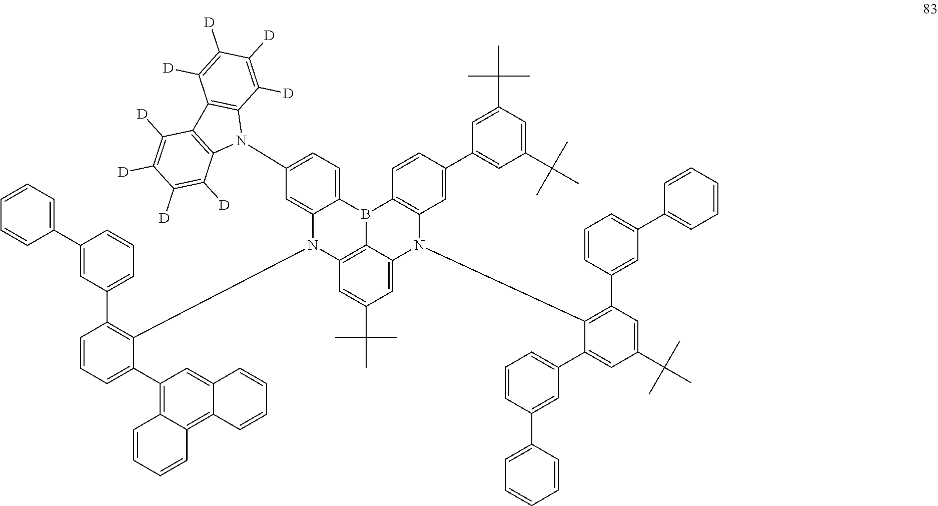 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cc3ccccc3c3ccccc13)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1] 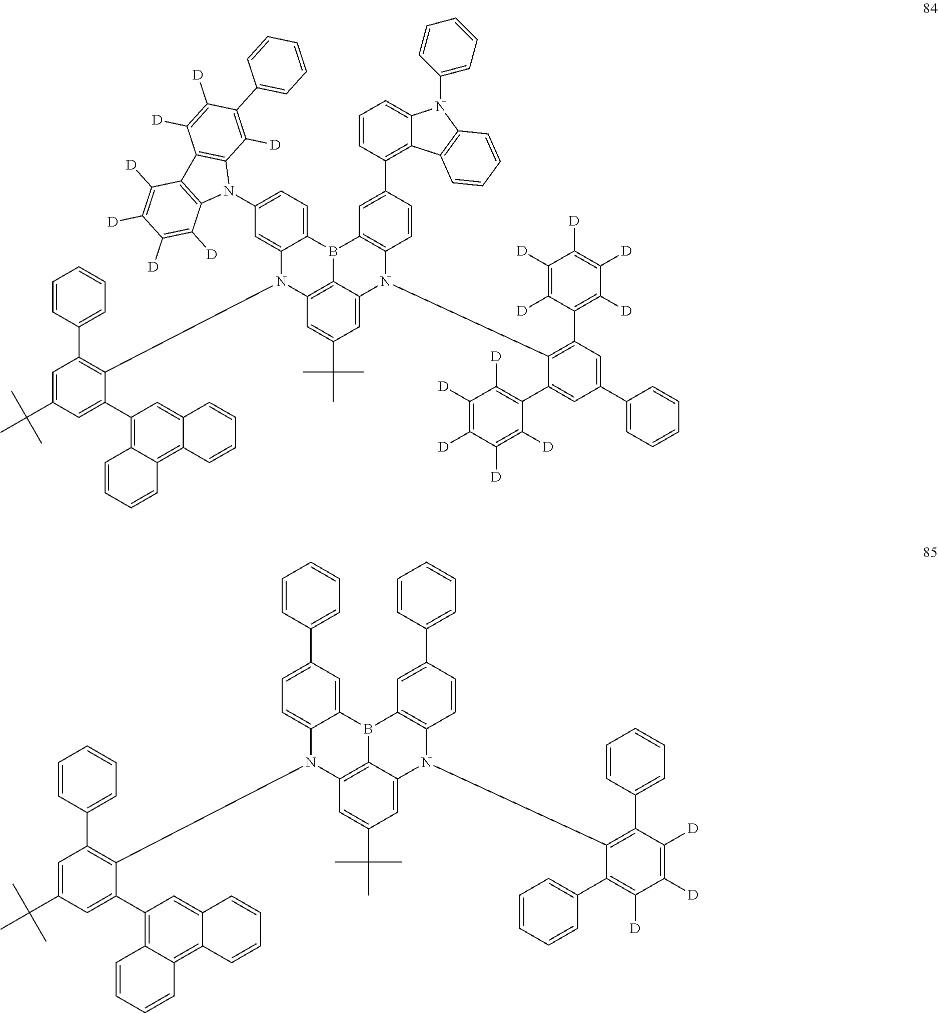 [SMILES: [2H]c1c([2H])c([2H])c(-c2cc(-c3ccccc3)cc(-c3c([2H])c([2H])c([2H])c([2H])c3[2H])c2N2c3ccc(-c4cccc5c4c4ccccc4n5-c4ccccc4)cc3B3c4ccc(-n5c6c([2H])c([2H])c([2H])c([2H])c6c6c([2H])c([2H])c(-c7ccccc7)c([2H])c65)cc4N(c4c(-c5ccccc5)cc(C(C)(C)C)cc4-c4cc5ccccc5c5ccccc45)c4cc(C(C)(C)C)cc2c43)c([2H])c1[2H] ; [2H]c1c([2H])c(-c2ccccc2)c(N2c3ccc(-c4ccccc4)cc3B3c4cc(-c5ccccc5)ccc4N(c4c(-c5ccccc5)cc(C(C)(C)C)cc4-c4cc5ccccc5c5ccccc45)c4cc(C(C)(C)C)cc2c43)c(-c2ccccc2)c1[2H]] 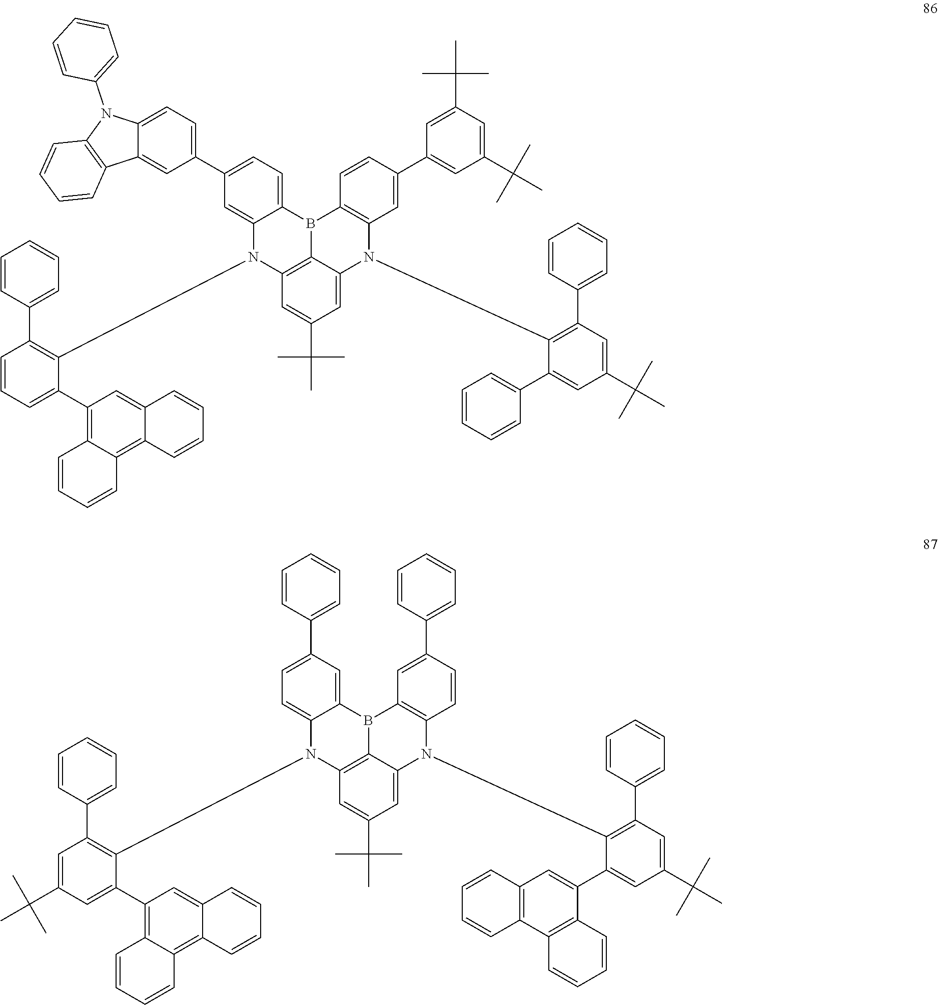 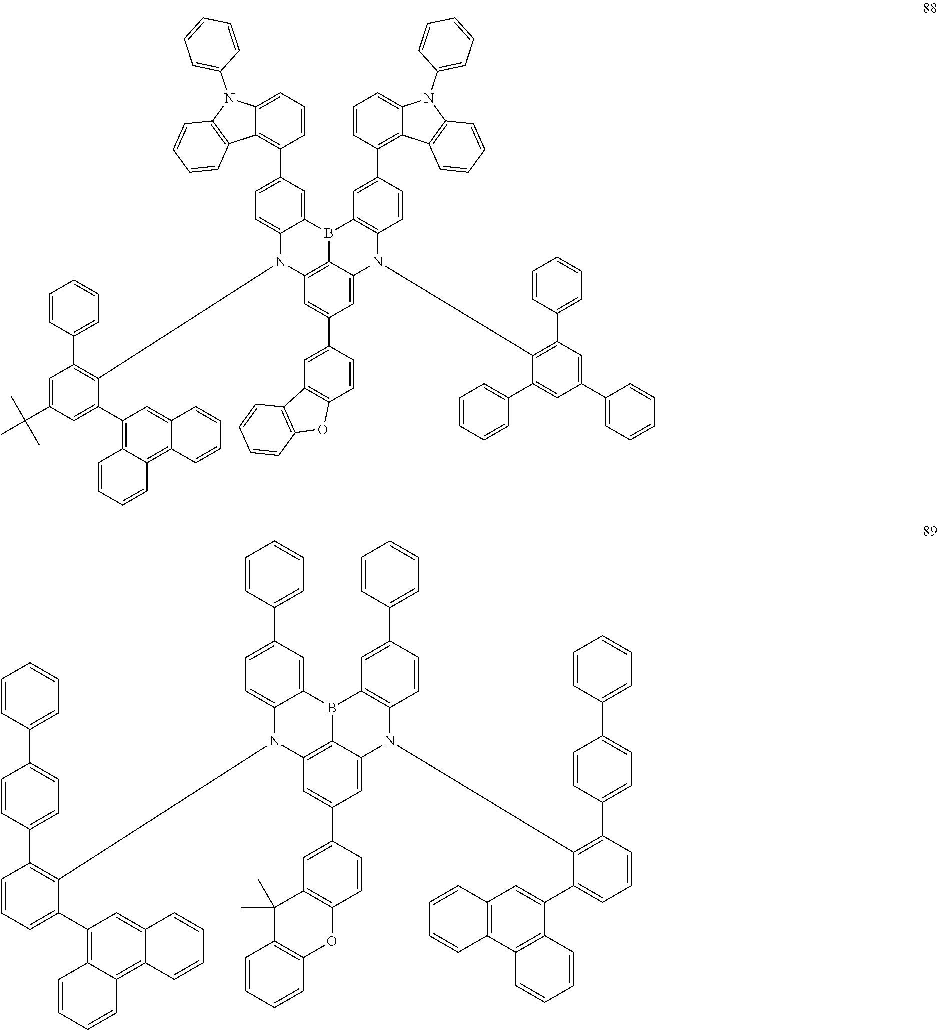 [SMILES: CC(C)(C)c1cc(-c2ccccc2)c(N2c3ccc(-c4cccc5c4c4ccccc4n5-c4ccccc4)cc3B3c4cc(-c5cccc6c5c5ccccc5n6-c5ccccc5)ccc4N(c4c(-c5ccccc5)cc(-c5ccccc5)cc4-c4ccccc4)c4cc(-c5ccc6oc7ccccc7c6c5)cc2c43)c(-c2cc3ccccc3c3ccccc23)c1 ; CC1(C)c2ccccc2Oc2ccc(-c3cc4c5c(c3)N(c3c(-c6ccc(-c7ccccc7)cc6)cccc3-c3cc6ccccc6c6ccccc36)c3ccc(-c6ccccc6)cc3B5c3cc(-c5ccccc5)ccc3N4c3c(-c4ccc(-c5ccccc5)cc4)cccc3-c3cc4ccccc4c4ccccc34)cc21] 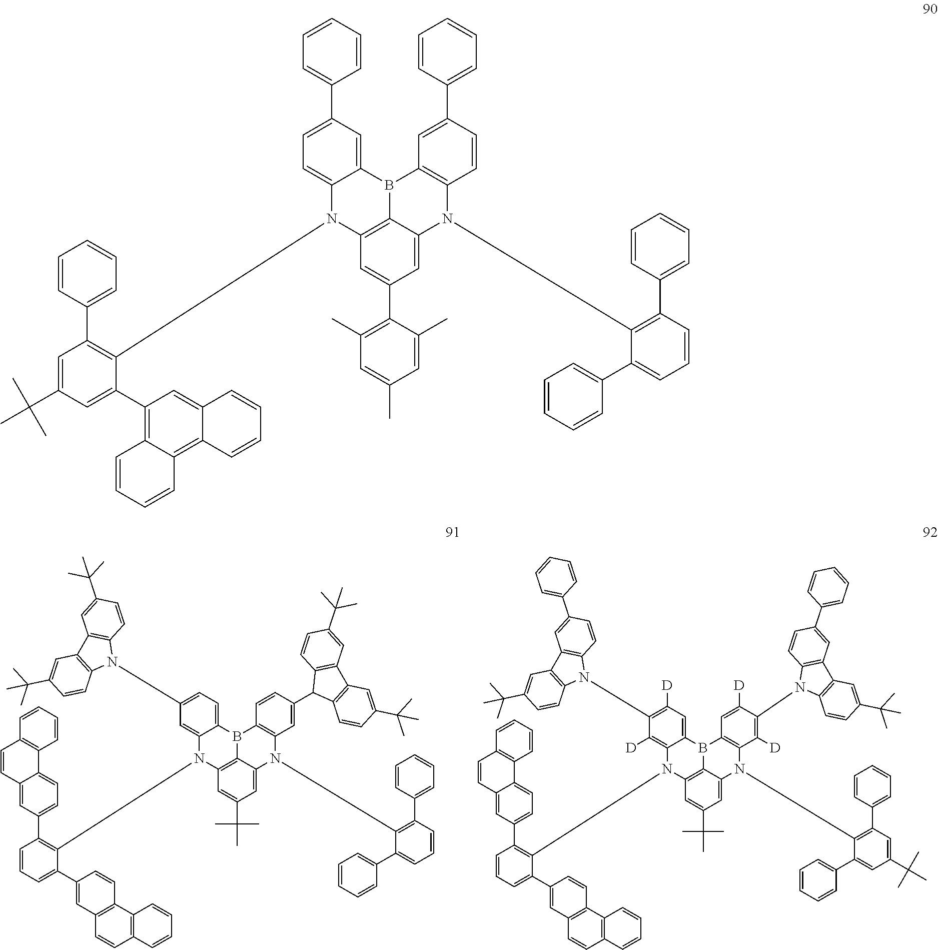 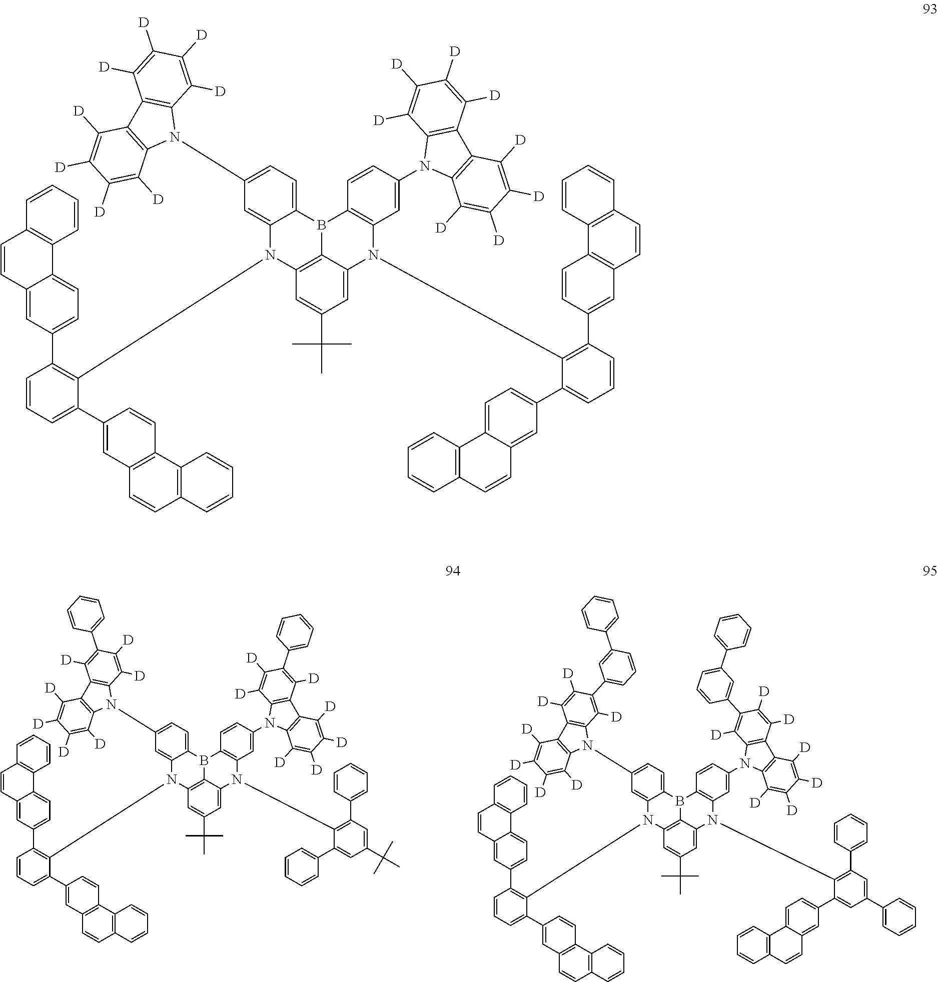 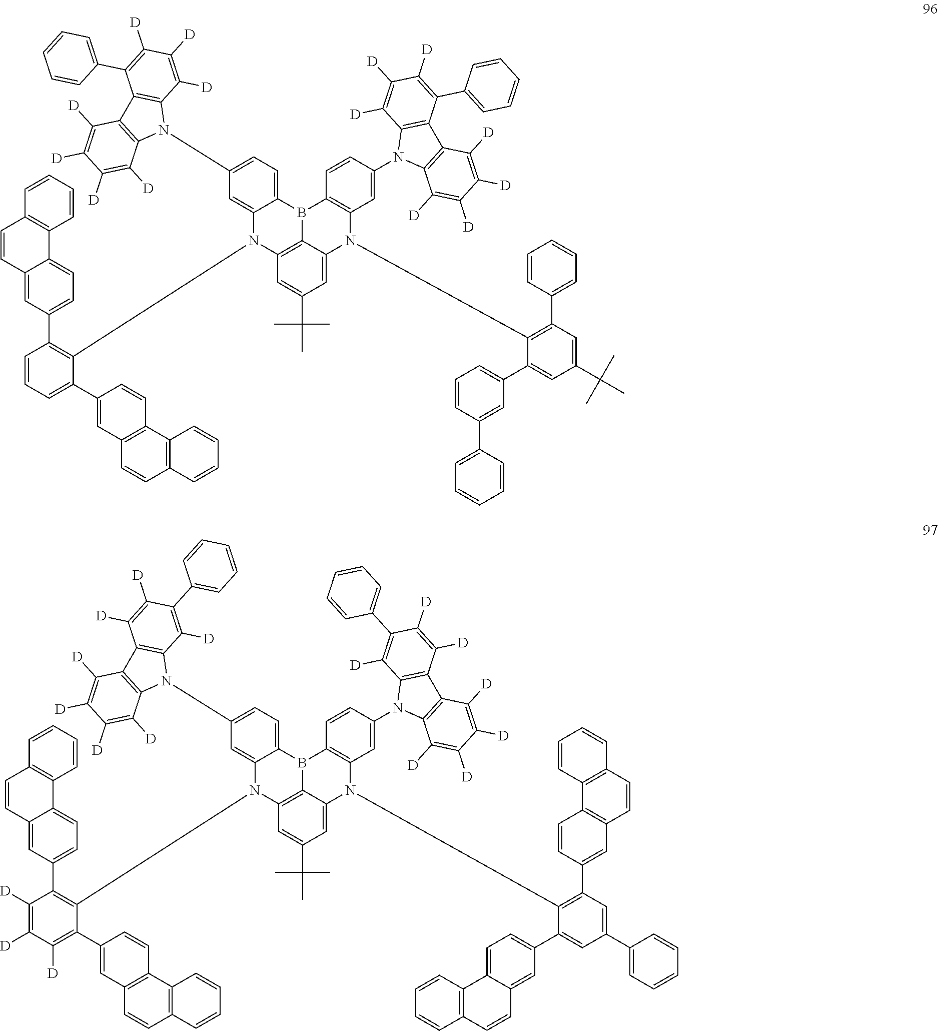 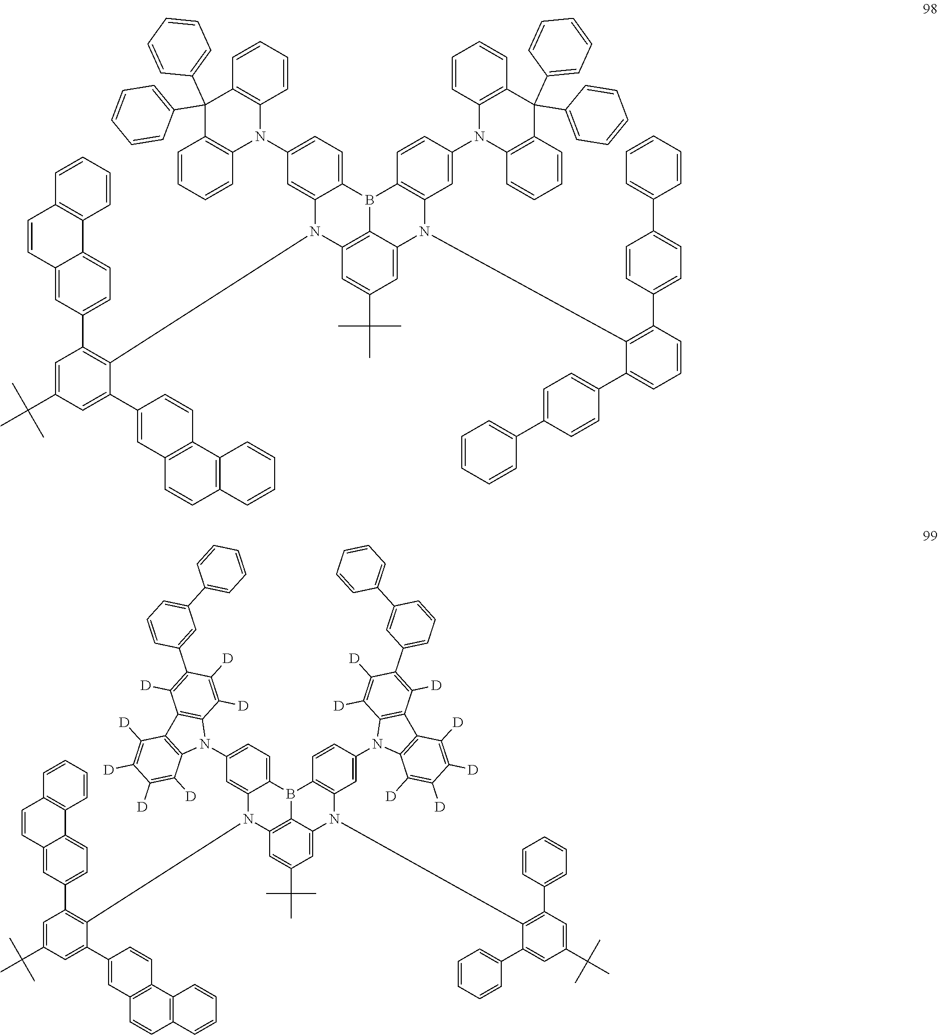 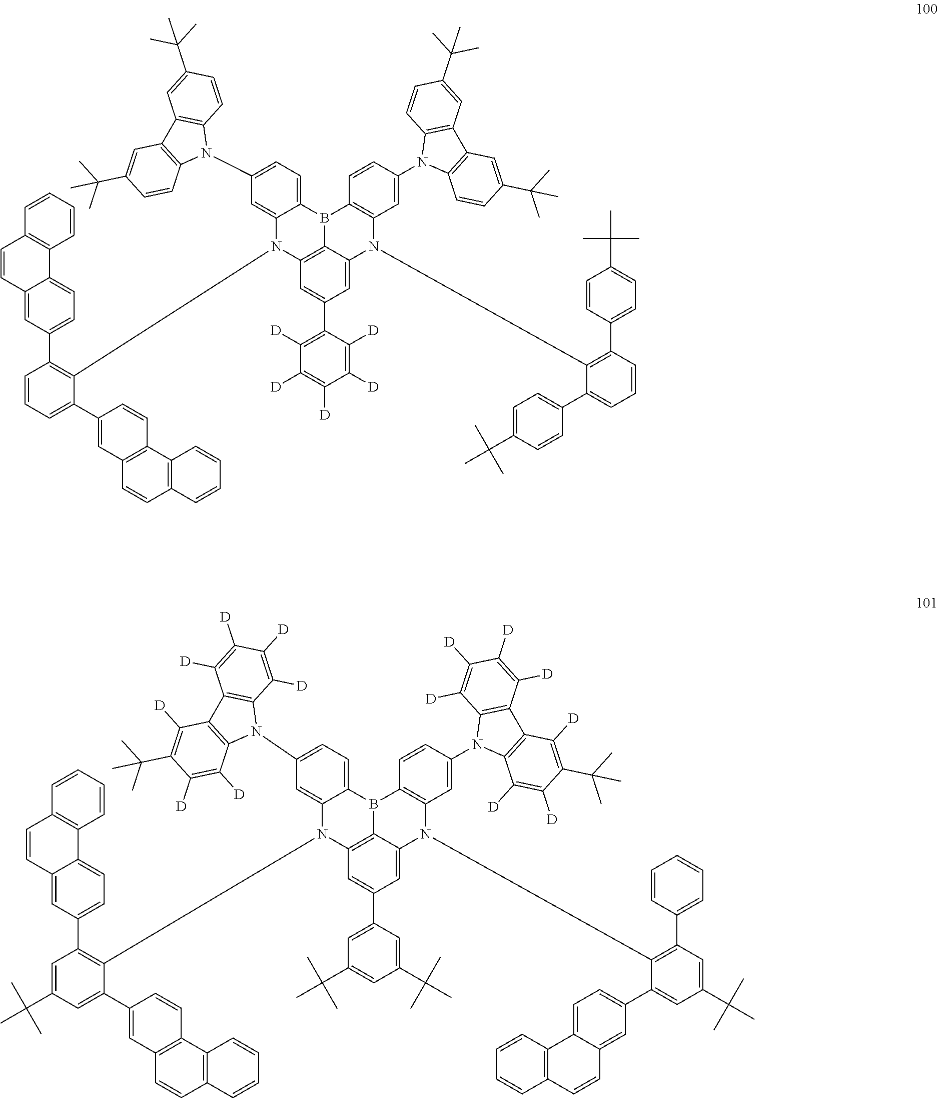 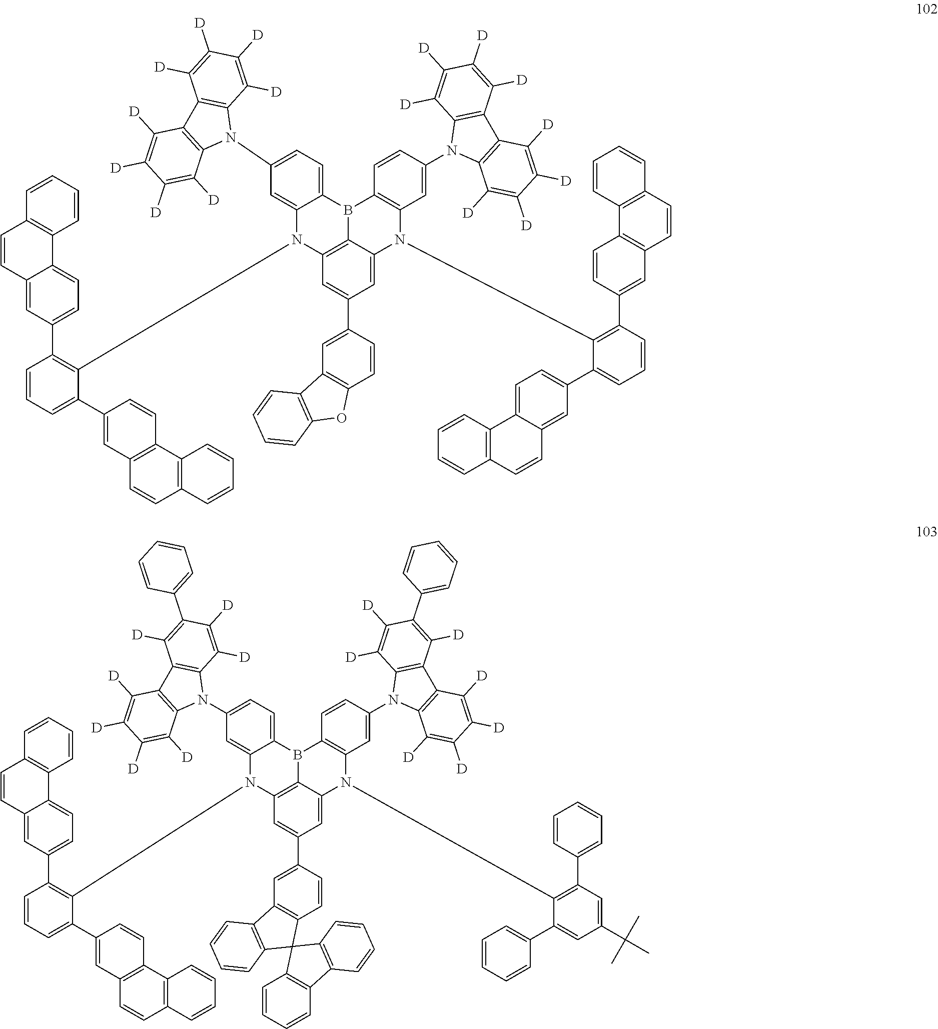 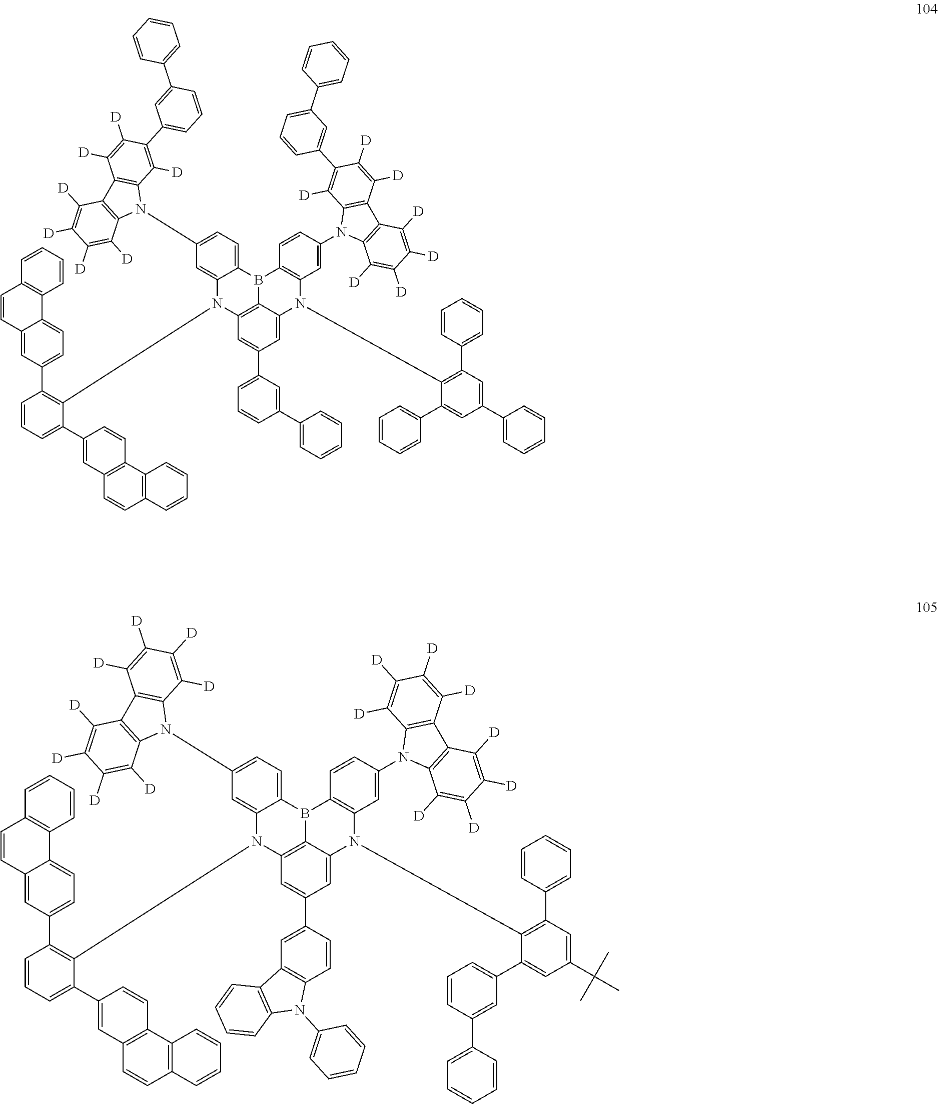 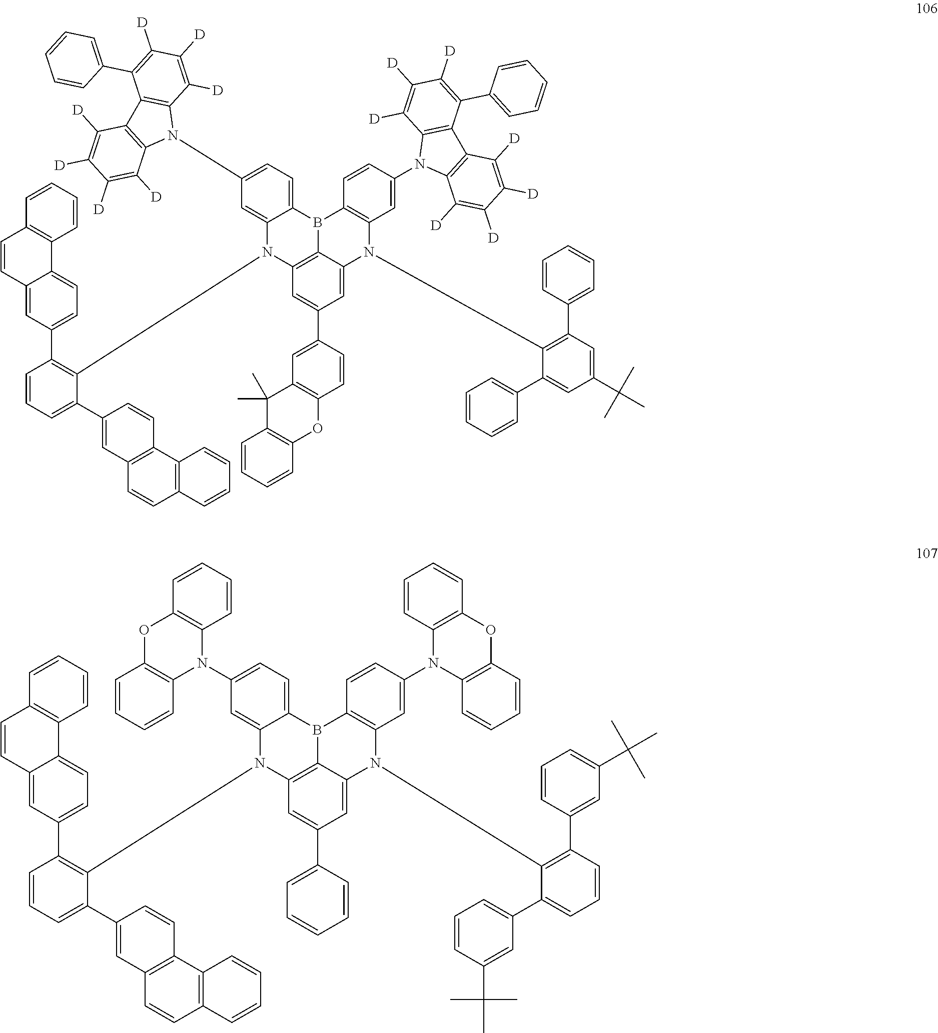 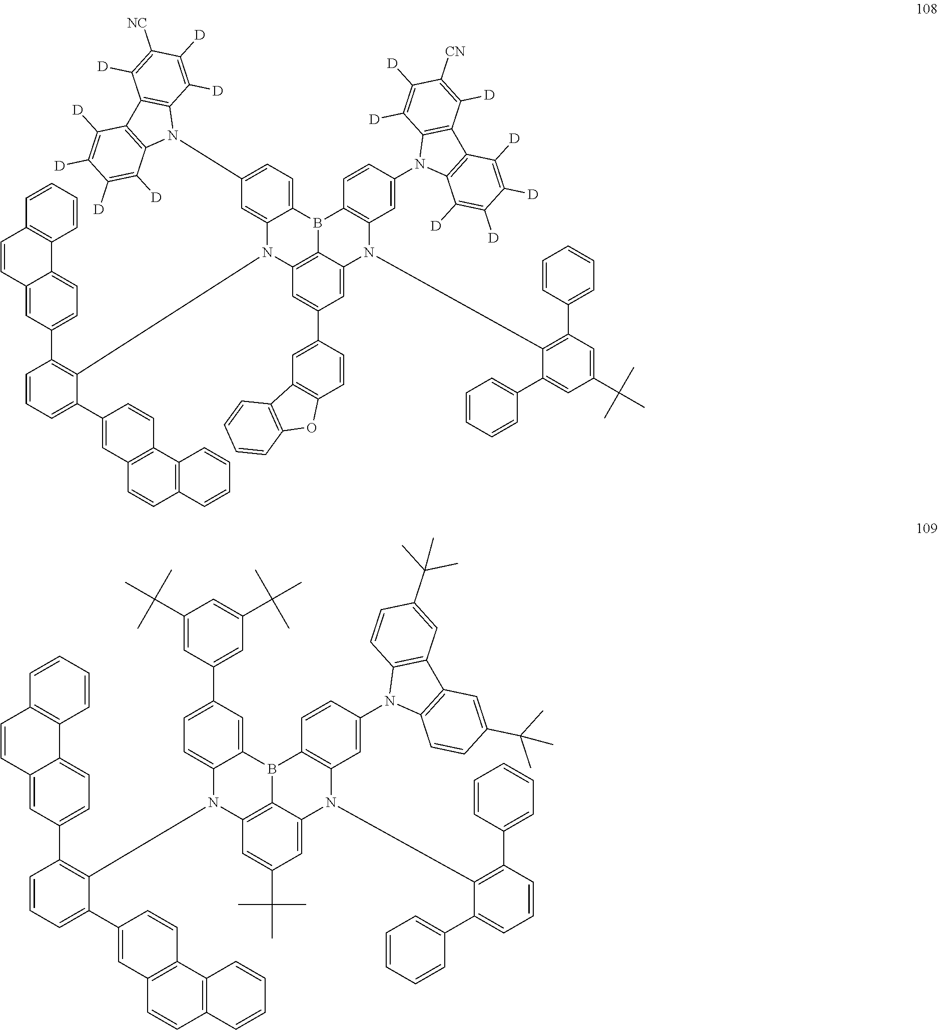 [SMILES: [2H]c1c([2H])c([2H])c2c(c1[2H])c1c([2H])c(C#N)c([2H])c([2H])c1n2-c1ccc2c(c1)N(c1c(-c3ccc4c(ccc5ccccc54)c3)cccc1-c1ccc3c(ccc4ccccc43)c1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cc(C(C)(C)C)cc1-c1ccccc1 ; CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3ccc4c(ccc5ccccc54)c3)cccc2-c2ccc3c(ccc4ccccc43)c2)cc(C(C)(C)C)c1] 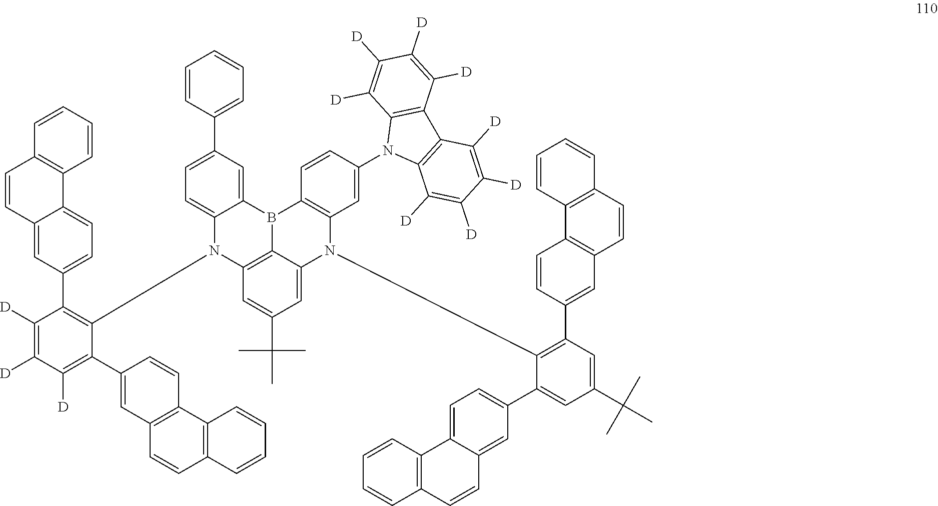 [SMILES: [2H]c1c([2H])c(-c2ccc3c(ccc4ccccc43)c2)c(N2c3ccc(-c4ccccc4)cc3B3c4ccc(-n5c6c([2H])c([2H])c([2H])c([2H])c6c6c([2H])c([2H])c([2H])c([2H])c65)cc4N(c4c(-c5ccc6c(ccc7ccccc76)c5)cc(C(C)(C)C)cc4-c4ccc5c(ccc6ccccc65)c4)c4cc(C(C)(C)C)cc2c43)c(-c2ccc3c(ccc4ccccc43)c2)c1[2H]] 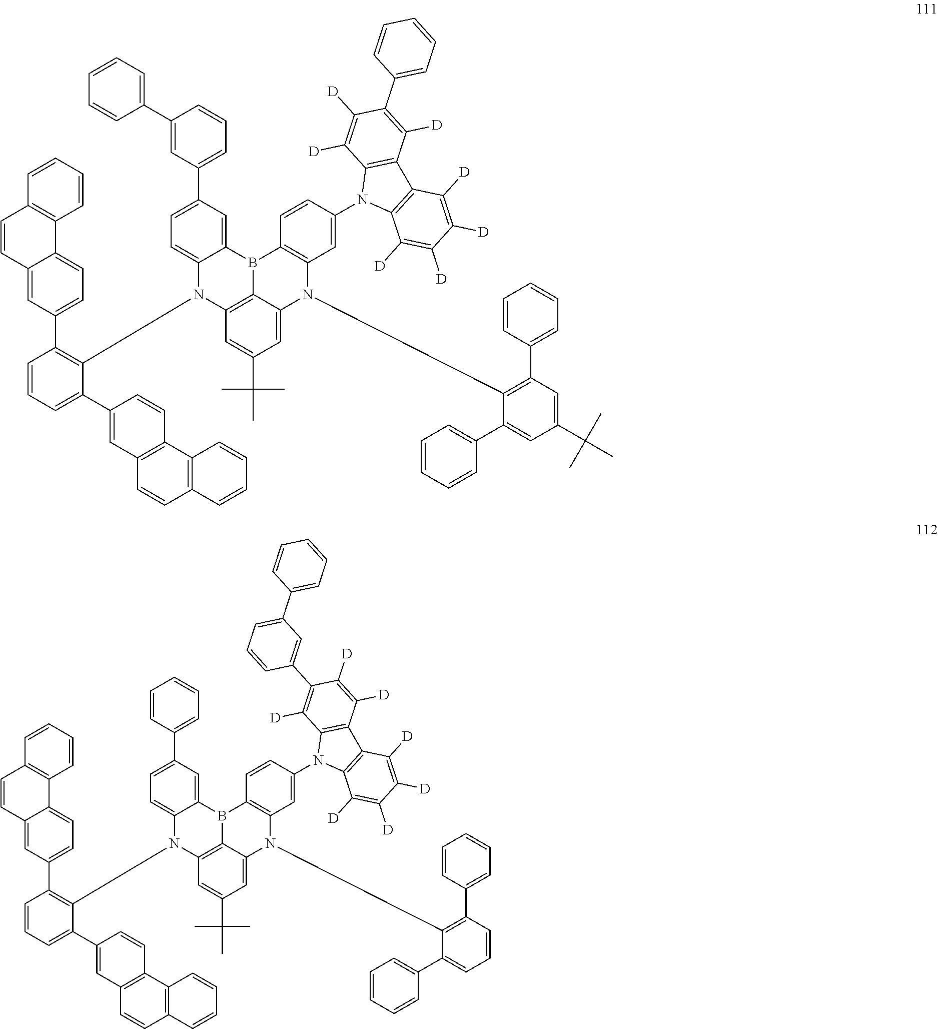 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccc3c(ccc4ccccc43)c2)cccc1-c1ccc2c(ccc3ccccc32)c1 ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccc3c(ccc4ccccc43)c2)cccc1-c1ccc2c(ccc3ccccc32)c1] 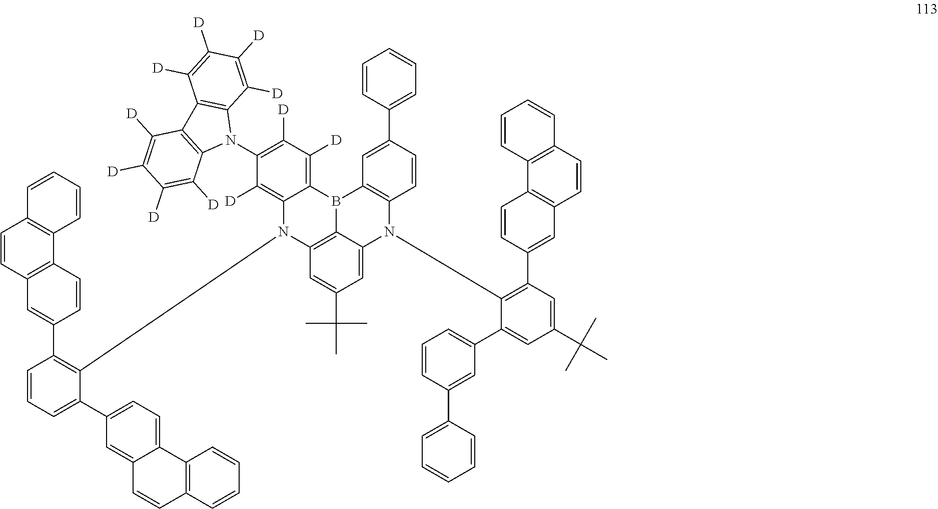 [SMILES: [2H]c1c([2H])c(-n2c3c([2H])c([2H])c([2H])c([2H])c3c3c([2H])c([2H])c([2H])c([2H])c32)c([2H])c2c1B1c3cc(-c4ccccc4)ccc3N(c3c(-c4cccc(-c5ccccc5)c4)cc(C(C)(C)C)cc3-c3ccc4c(ccc5ccccc54)c3)c3cc(C(C)(C)C)cc(c31)N2c1c(-c2ccc3c(ccc4ccccc43)c2)cccc1-c1ccc2c(ccc3ccccc32)c1] 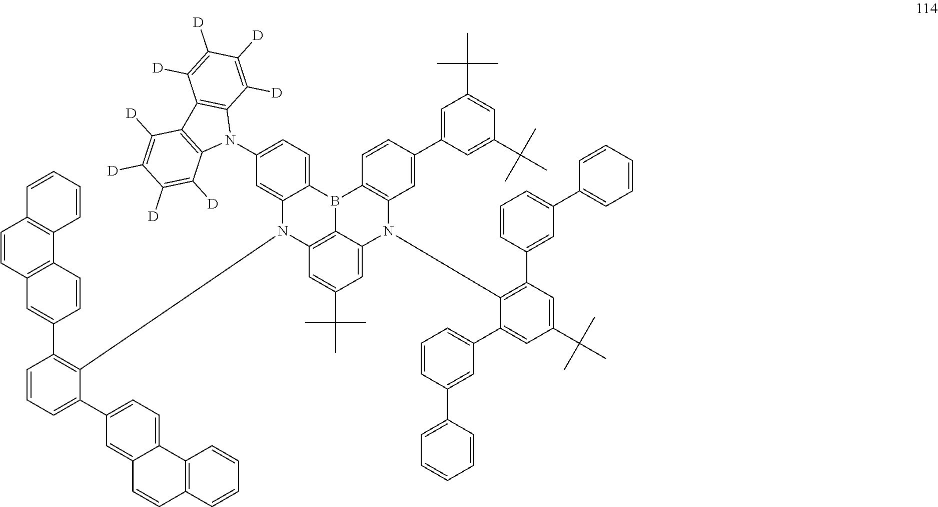 [SMILES: [2H]c1c([2H])c([2H])c2c(c1[2H])c1c([2H])c([2H])c([2H])c([2H])c1n2-c1ccc2c(c1)N(c1c(-c3ccc4c(ccc5ccccc54)c3)cccc1-c1ccc3c(ccc4ccccc43)c1)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1] 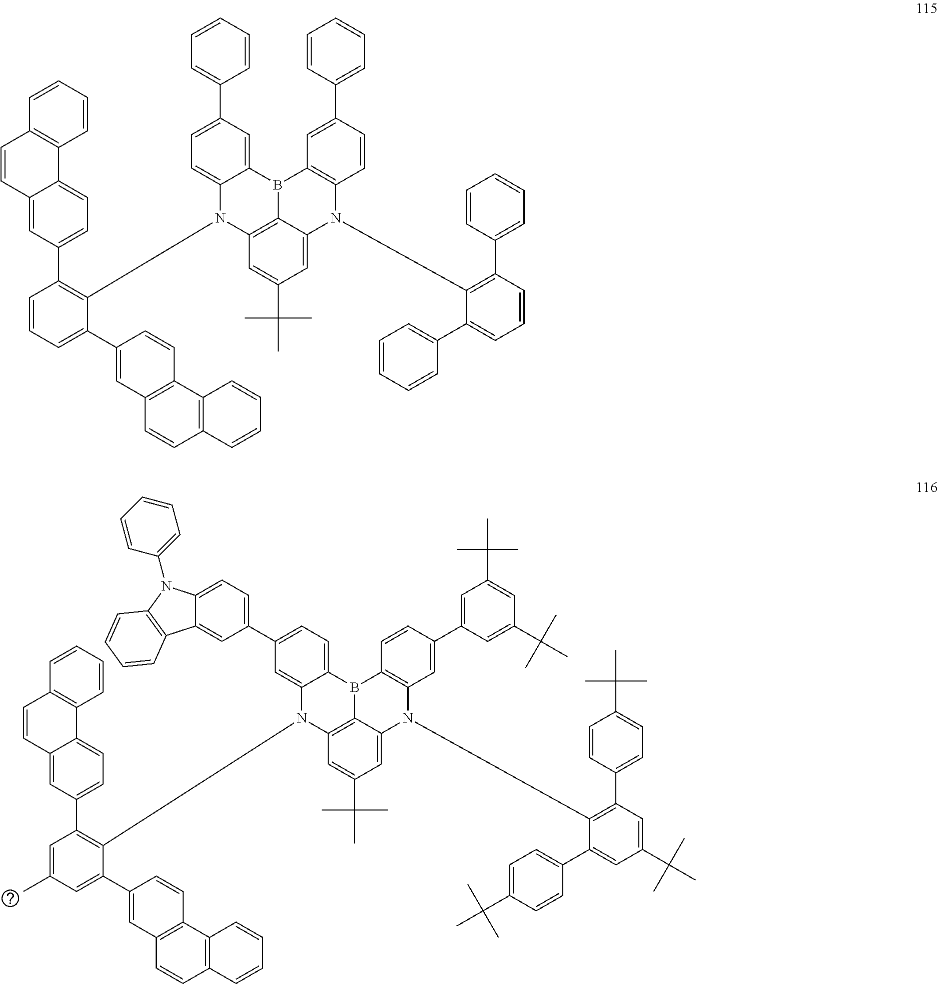 [SMILES: CC(C)(C)c1cc2c3c(c1)N(c1c(-c4ccc5c(ccc6ccccc65)c4)cccc1-c1ccc4c(ccc5ccccc54)c1)c1ccc(-c4ccccc4)cc1B3c1cc(-c3ccccc3)ccc1N2c1c(-c2ccccc2)cccc1-c1ccccc1 ; Cc1cc(-c2ccc3c(ccc4ccccc43)c2)c(N2c3cc(-c4ccc5c(c4)c4ccccc4n5-c4ccccc4)ccc3B3c4ccc(-c5cc(C(C)(C)C)cc(C(C)(C)C)c5)cc4N(c4c(-c5ccc(C(C)(C)C)cc5)cc(C(C)(C)C)cc4-c4ccc(C(C)(C)C)cc4)c4cc(C(C)(C)C)cc2c43)c(-c2ccc3c(ccc4ccccc43)c2)c1] 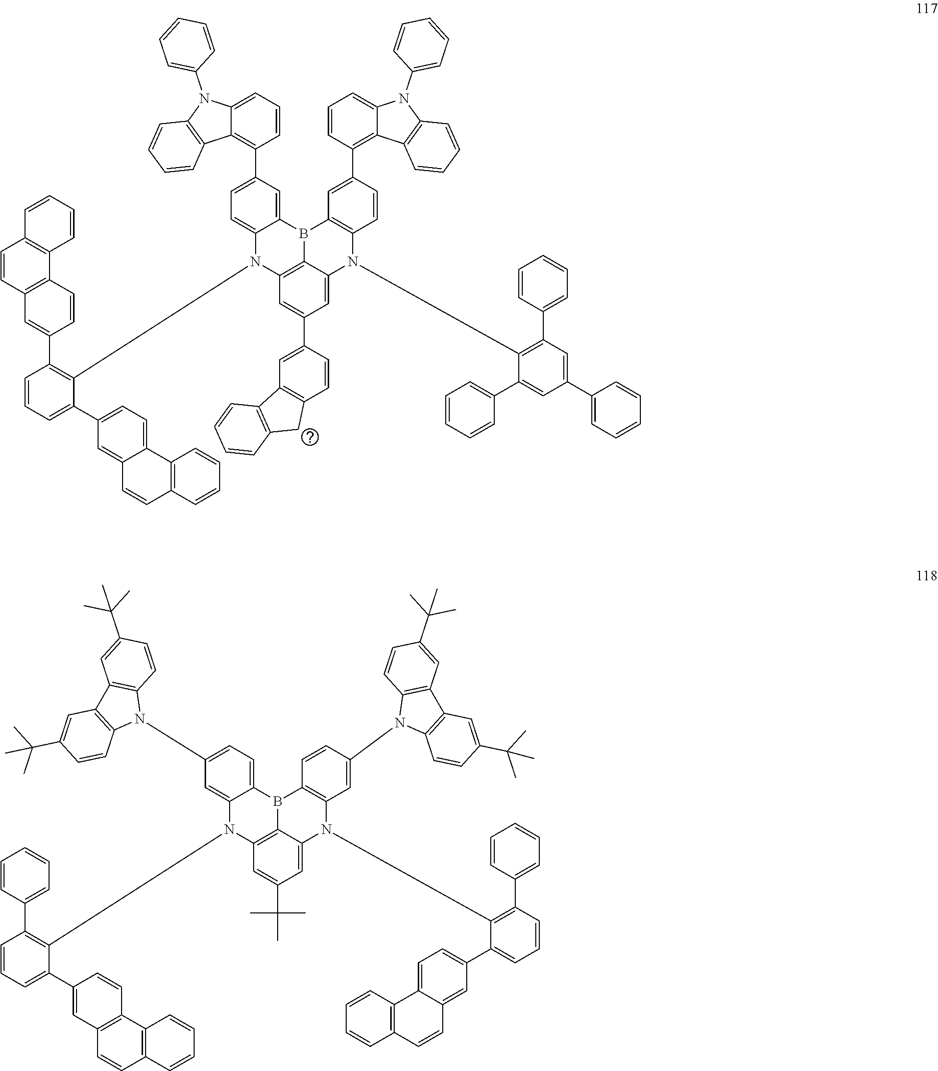 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccc7c(ccc8ccccc87)c6)cccc5-c5ccc6c(ccc7ccccc76)c5)c5cc(-c6ccc7c(c6)-c6ccccc6C7)cc3c54)c(-c3ccccc3)c2)cc1 ; CC(C)(C)c1cc2c3c(c1)N(c1c(-c4ccccc4)cccc1-c1ccc4c(ccc5ccccc54)c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccc2c(ccc3ccccc32)c1] 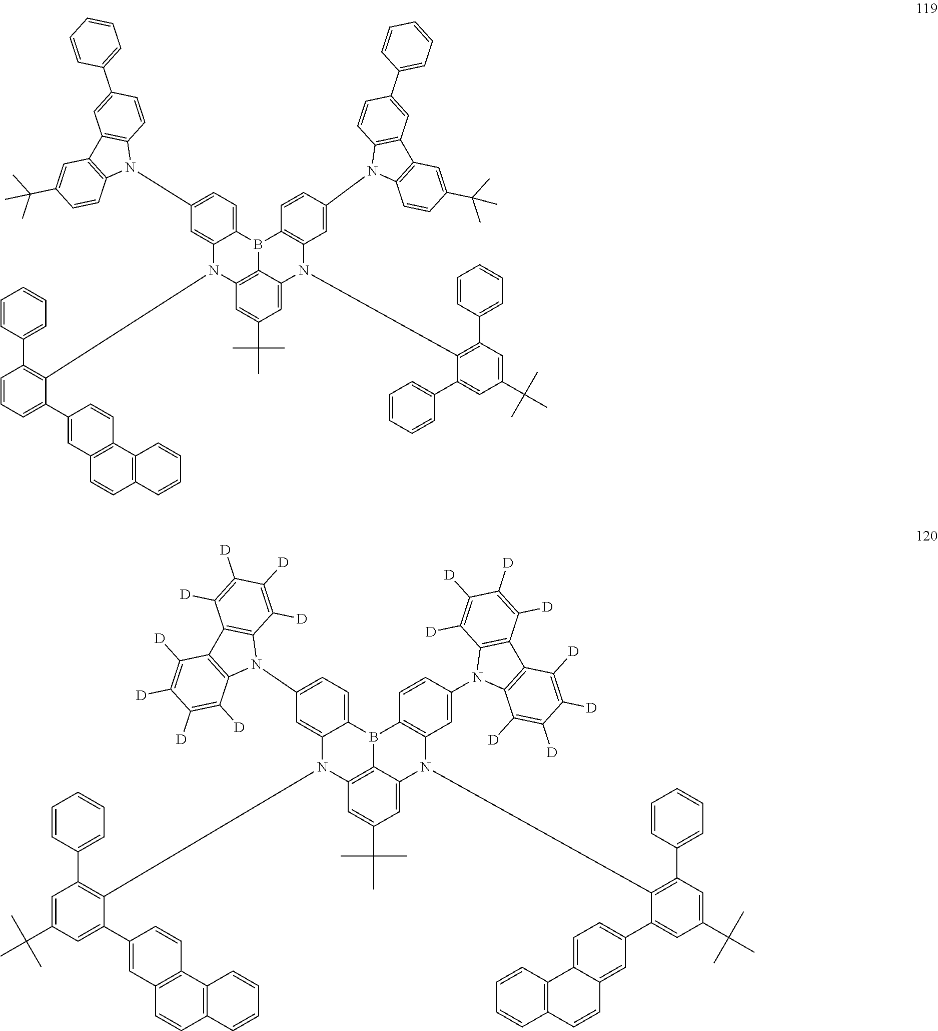 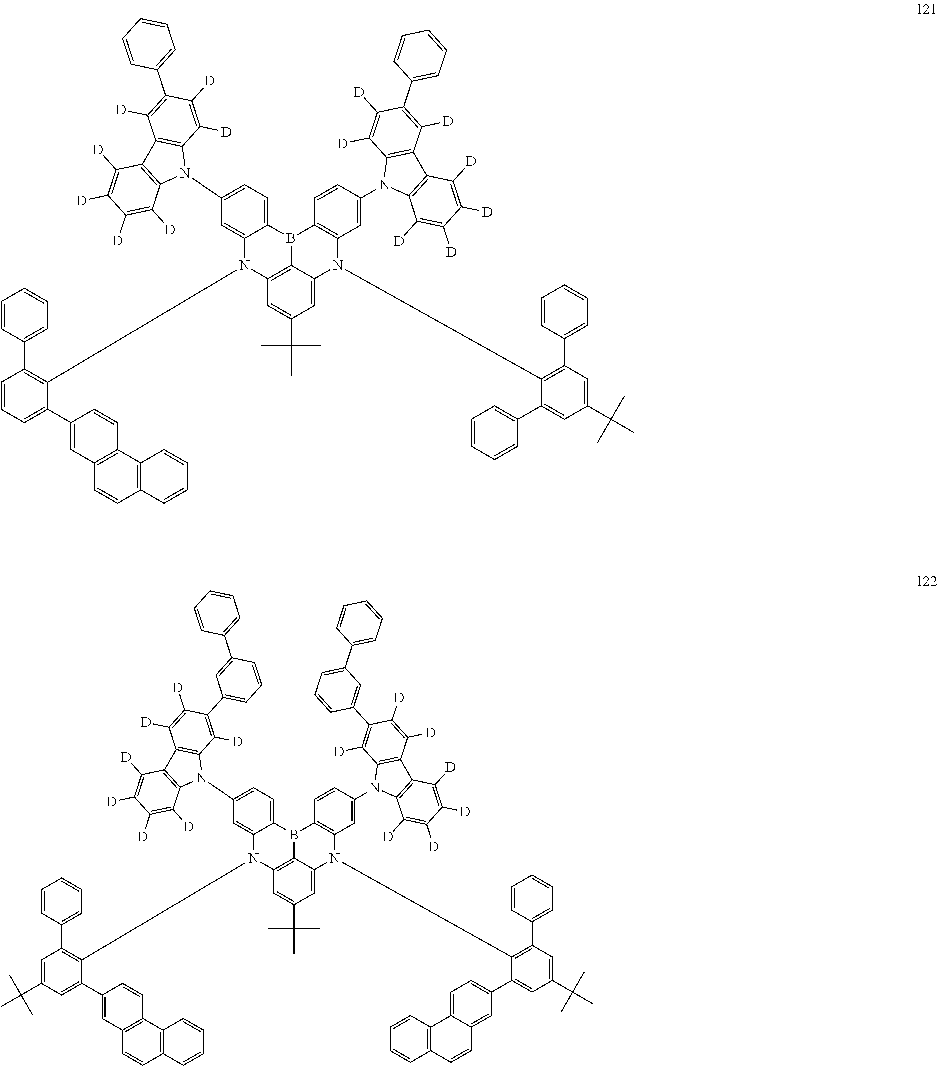 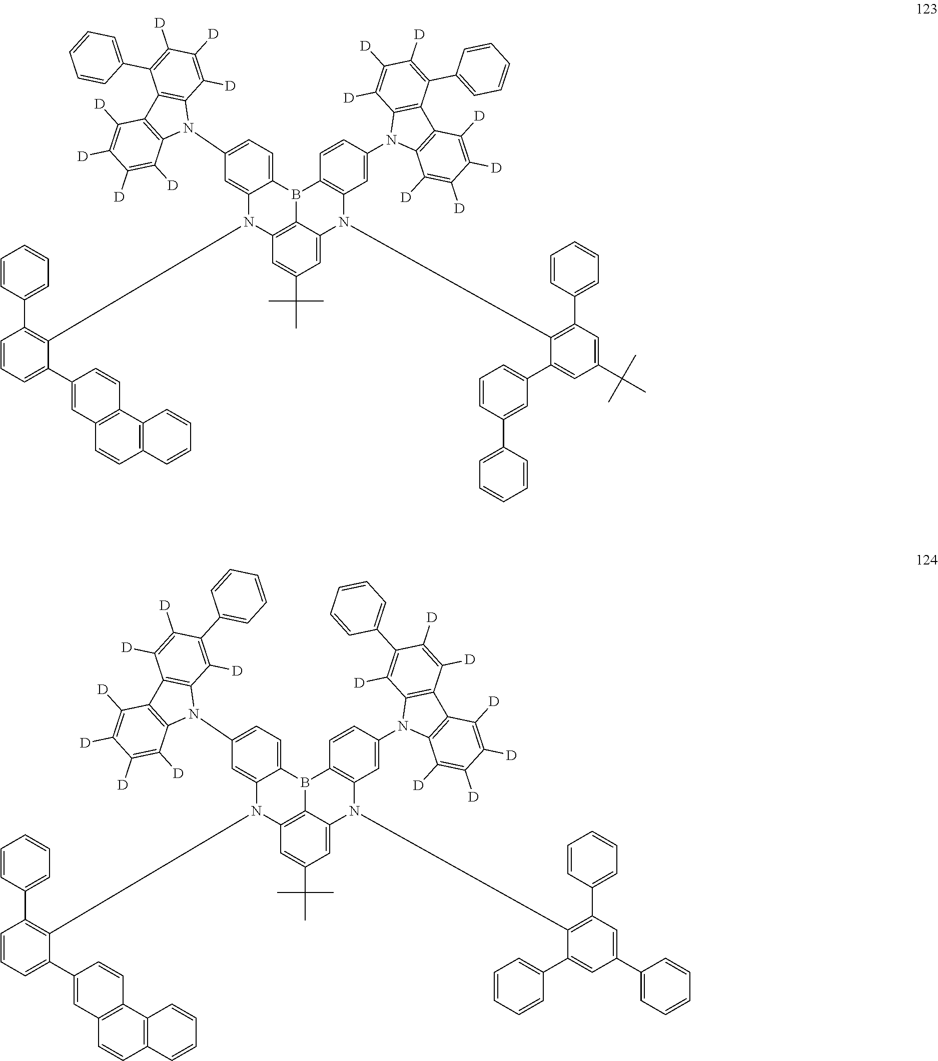 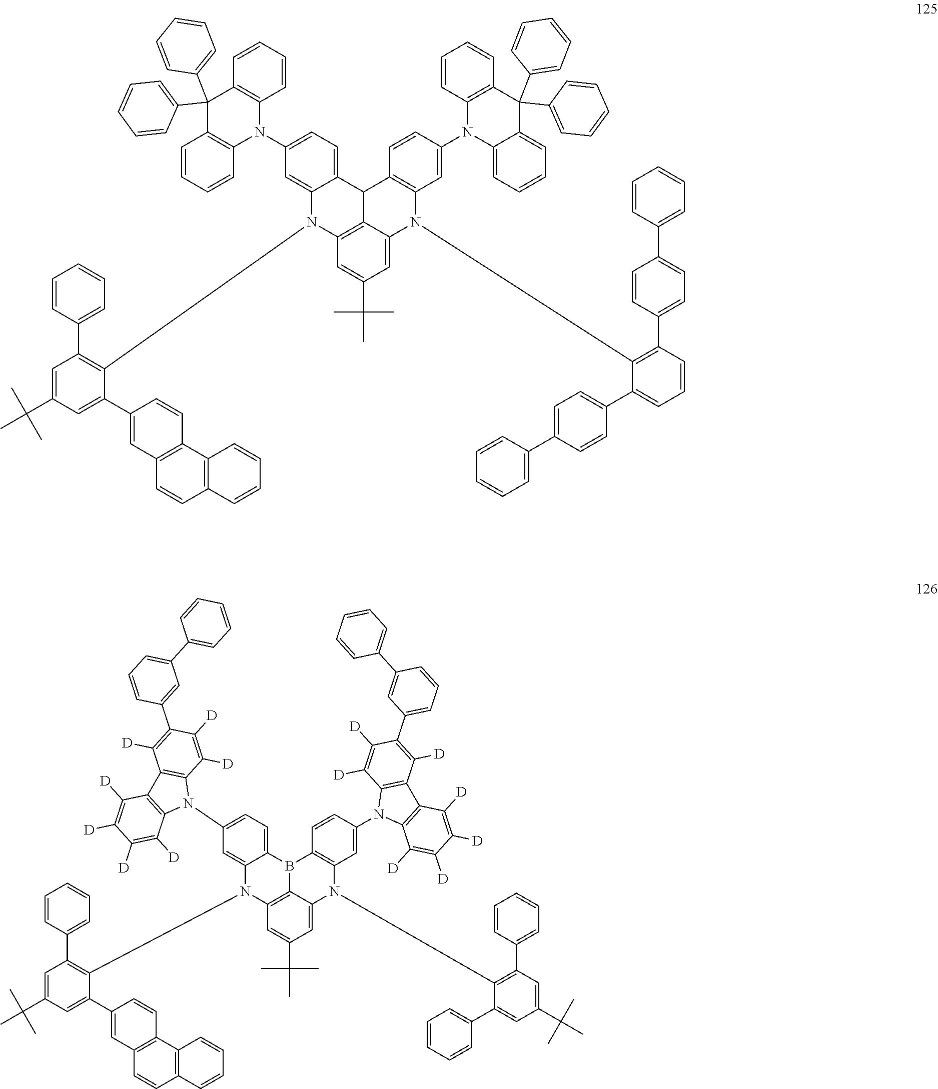 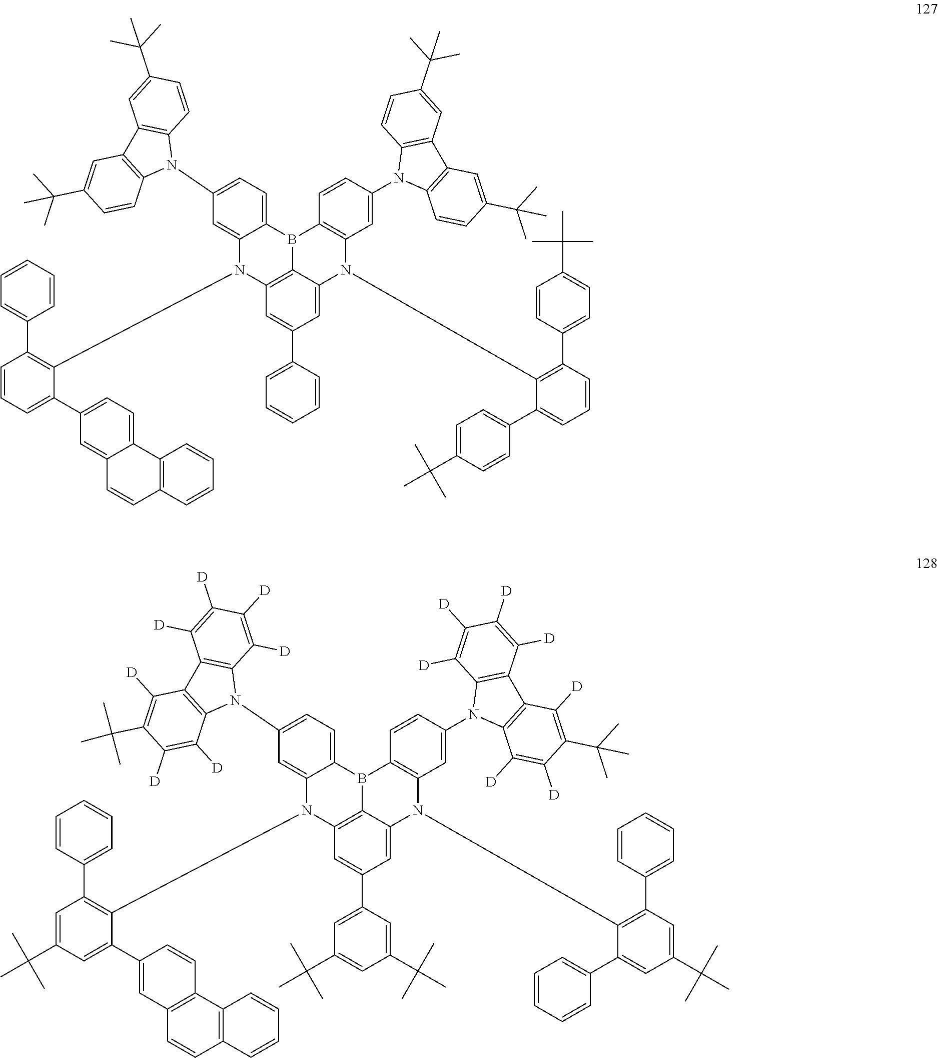 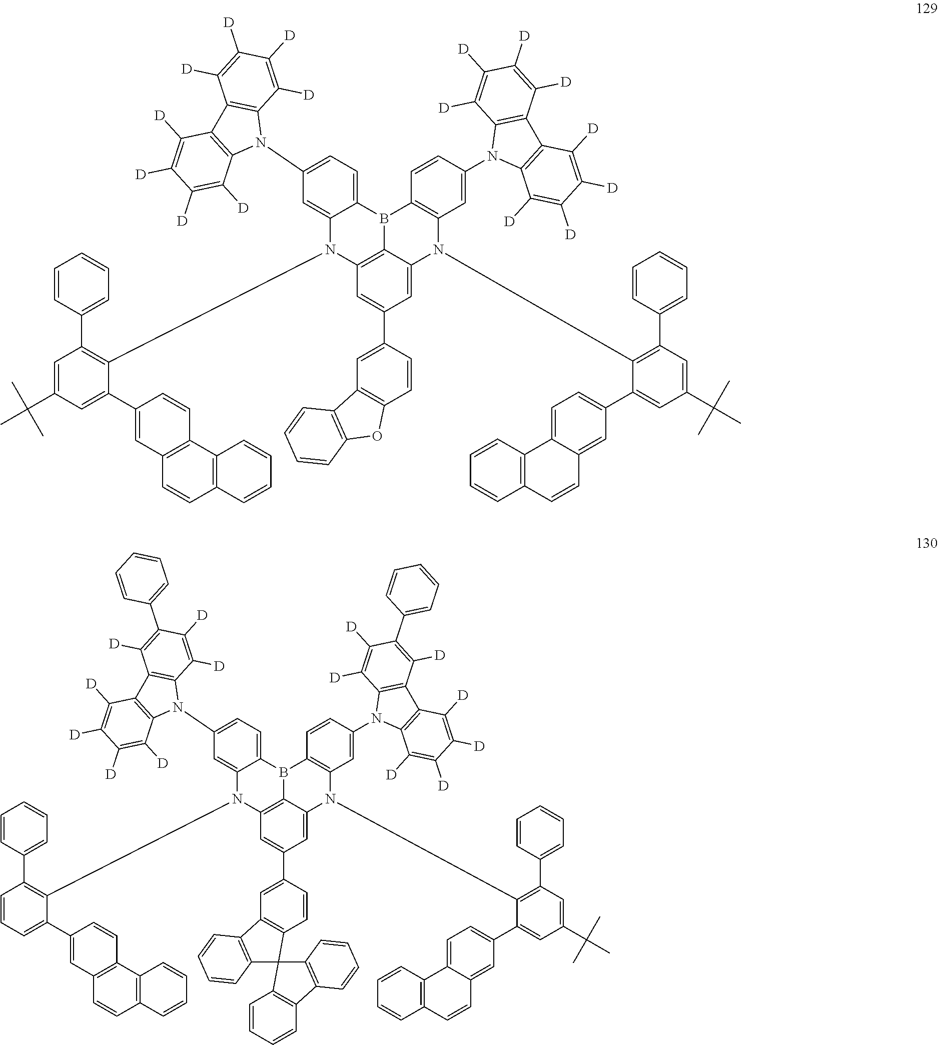 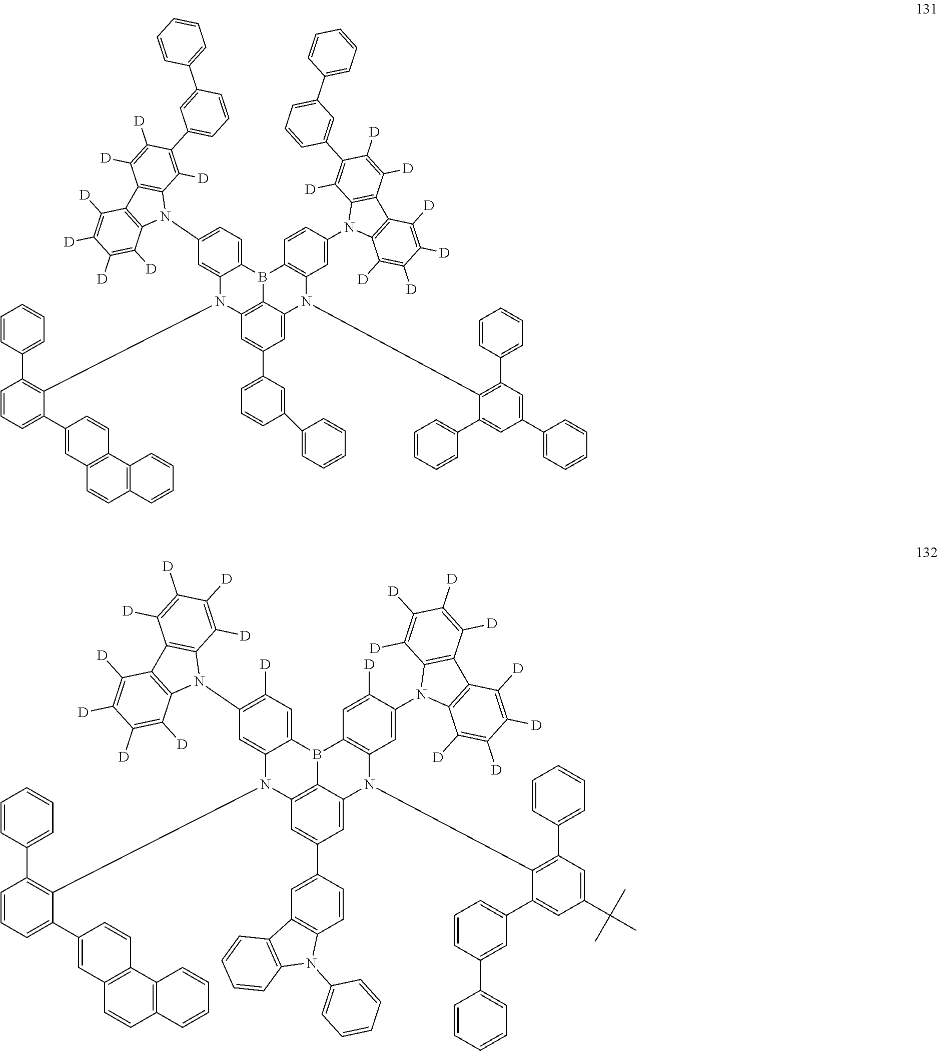 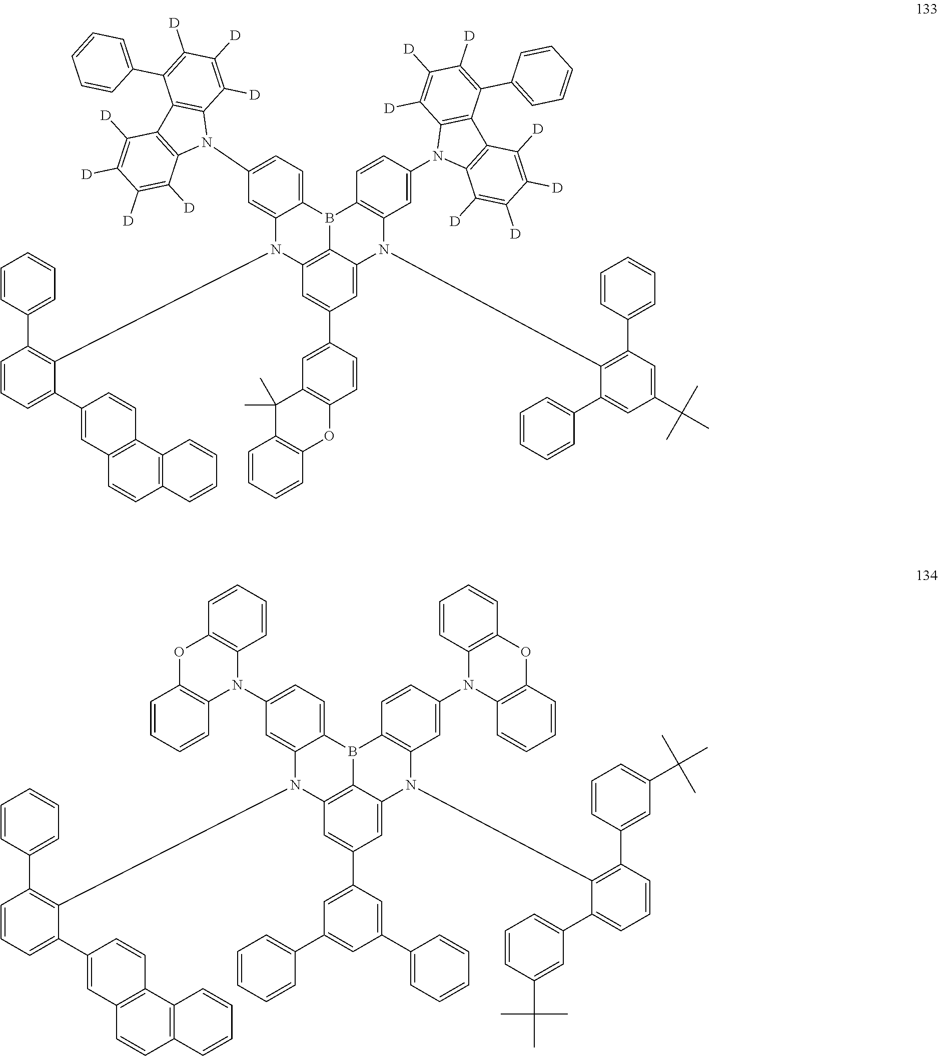 [SMILES: [2H]c1c([2H])c([2H])c2c(c1[2H])c1c(-c3ccccc3)c([2H])c([2H])c([2H])c1n2-c1ccc2c(c1)N(c1c(-c3ccccc3)cccc1-c1ccc3c(ccc4ccccc43)c1)c1cc(-c3ccc4c(c3)C(C)(C)c3ccccc3O4)cc3c1B2c1ccc(-n2c4c([2H])c([2H])c([2H])c([2H])c4c4c(-c5ccccc5)c([2H])c([2H])c([2H])c42)cc1N3c1c(-c2ccccc2)cc(C(C)(C)C)cc1-c1ccccc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5ccccc5)cccc4-c4ccc5c(ccc6ccccc65)c4)c4cc(-c5cc(-c6ccccc6)cc(-c6ccccc6)c5)cc2c43)c1] 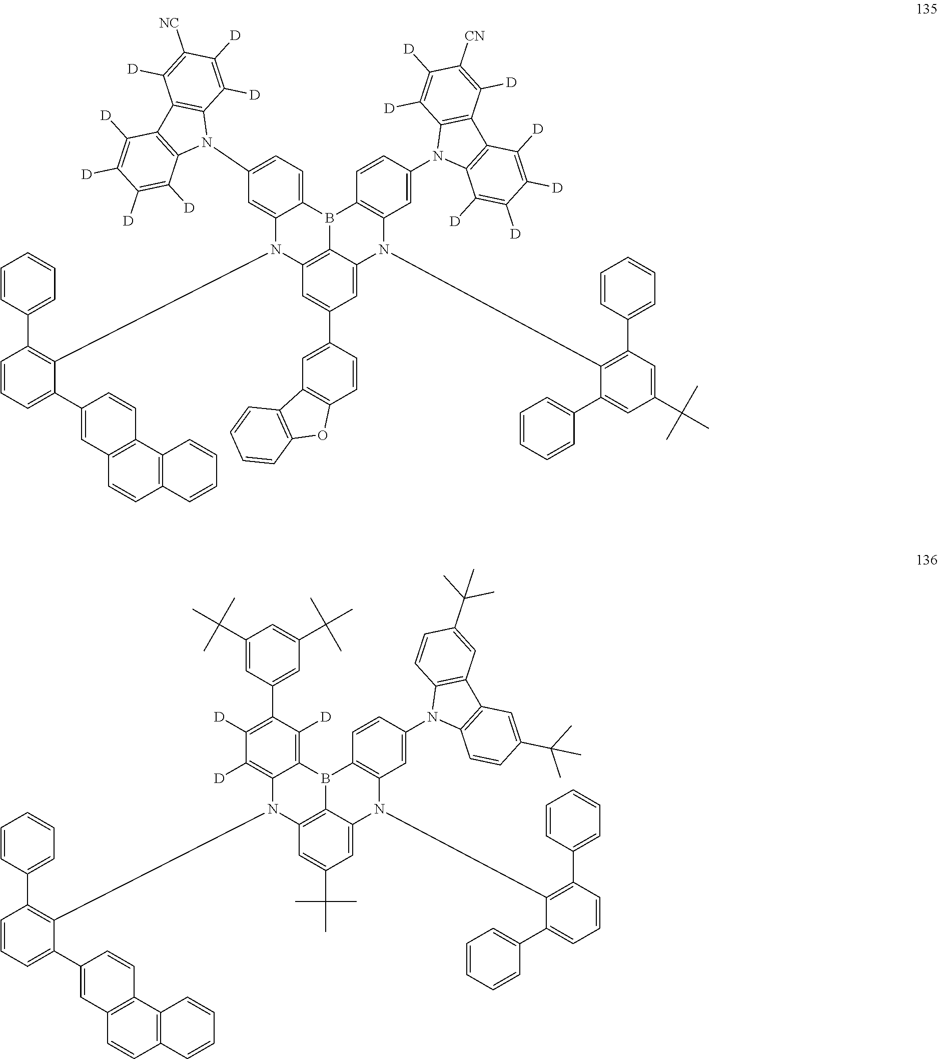 [SMILES: [2H]c1c([2H])c([2H])c2c(c1[2H])c1c([2H])c(C#N)c([2H])c([2H])c1n2-c1ccc2c(c1)N(c1c(-c3ccccc3)cccc1-c1ccc3c(ccc4ccccc43)c1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cc(C(C)(C)C)cc1-c1ccccc1 ; [2H]c1c([2H])c2c(c([2H])c1-c1cc(C(C)(C)C)cc(C(C)(C)C)c1)B1c3ccc(-n4c5ccc(C(C)(C)C)cc5c5cc(C(C)(C)C)ccc54)cc3N(c3c(-c4ccccc4)cccc3-c3ccccc3)c3cc(C(C)(C)C)cc(c31)N2c1c(-c2ccccc2)cccc1-c1ccc2c(ccc3ccccc32)c1] 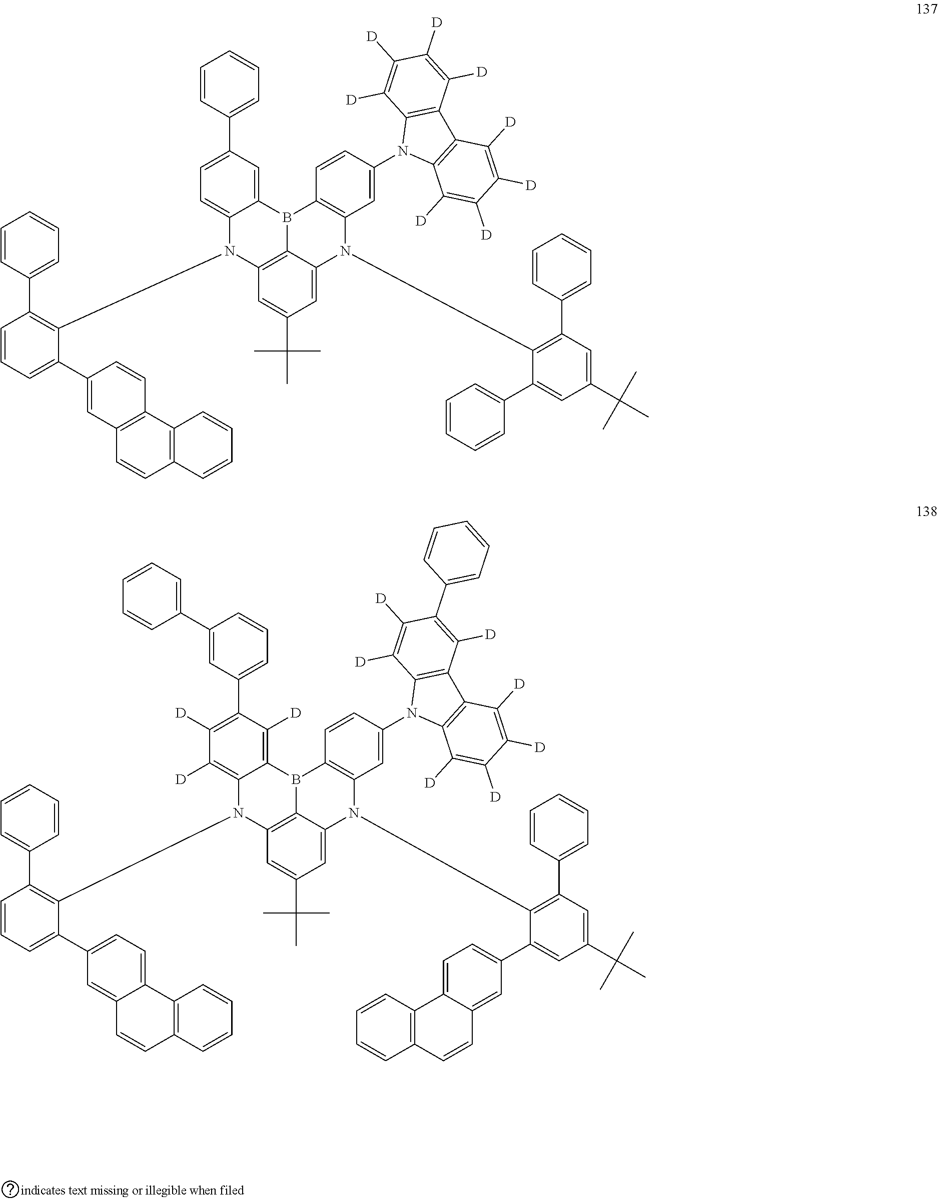 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2ccccc2)ccc1N3c1c(-c2ccccc2)cccc1-c1ccc2c(ccc3ccccc32)c1 ; [2H]c1c([2H])c2c(c([2H])c1-c1cccc(-c3ccccc3)c1)B1c3ccc(-n4c5c([2H])c([2H])c([2H])c([2H])c5c5c([2H])c(-c6ccccc6)c([2H])c([2H])c54)cc3N(c3c(-c4ccccc4)cc(C(C)(C)C)cc3-c3ccc4c(ccc5ccccc54)c3)c3cc(C(C)(C)C)cc(c31)N2c1c(-c2ccccc2)cccc1-c1ccc2c(ccc3ccccc32)c1] 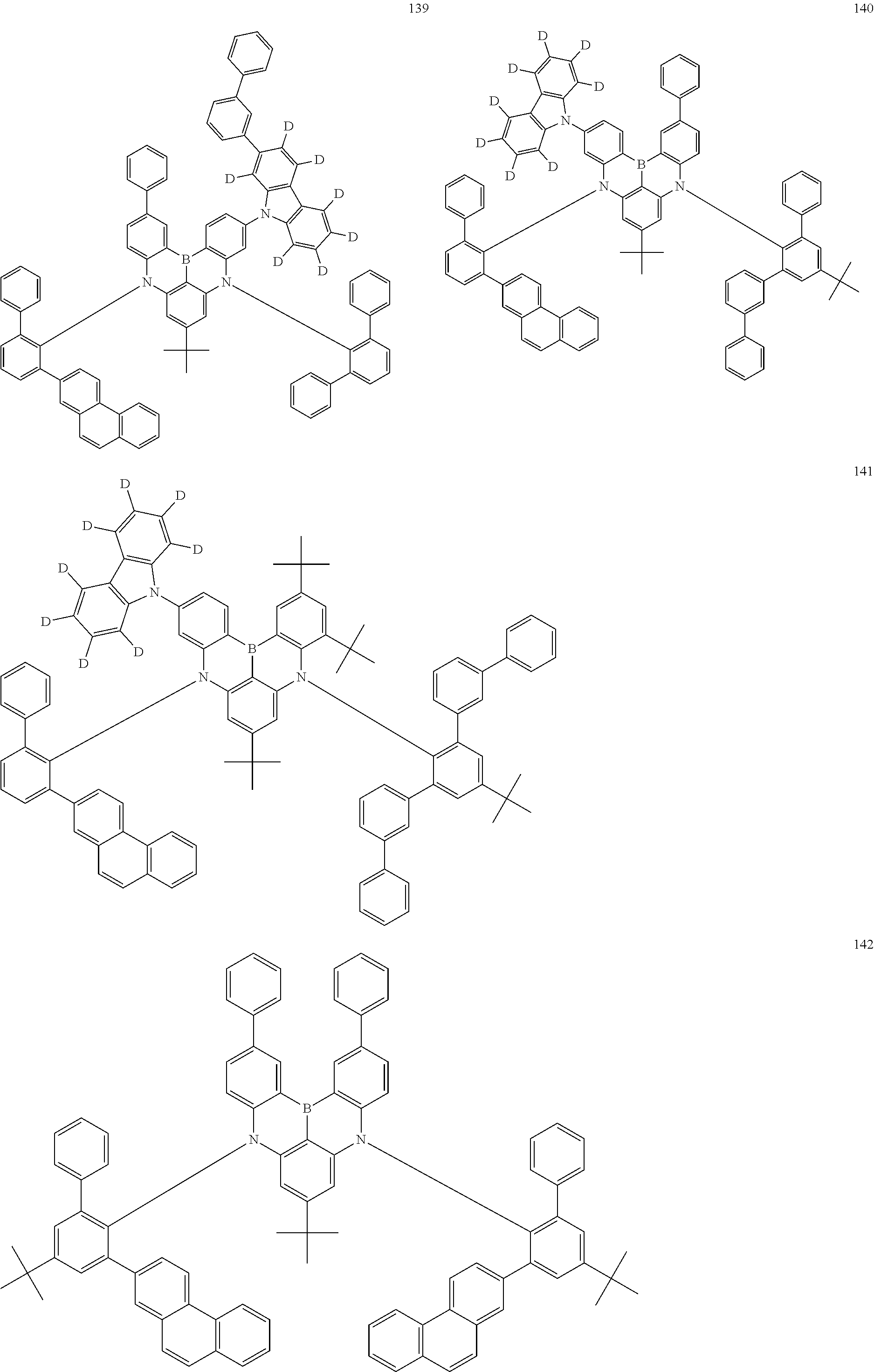 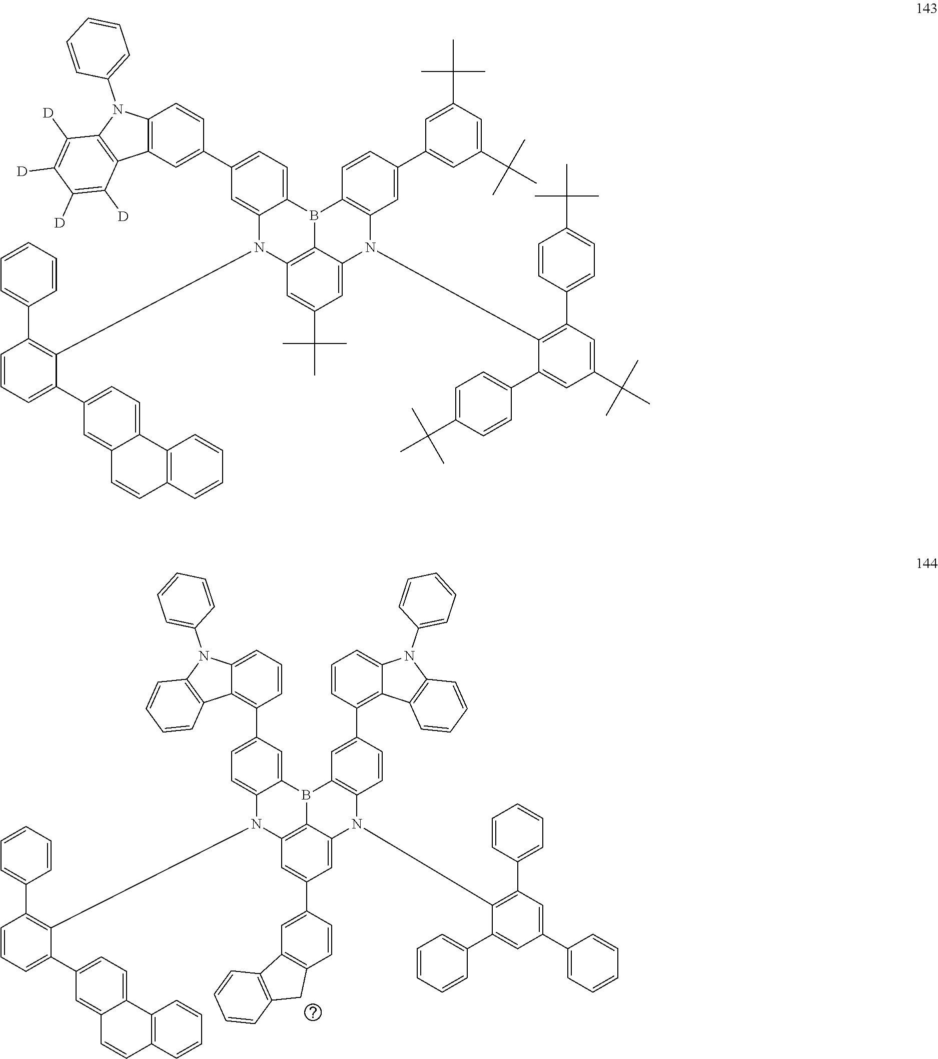 [SMILES: [2H]c1c([2H])c([2H])c2c(c1[2H])c1cc(-c3ccc4c(c3)N(c3c(-c5ccccc5)cccc3-c3ccc5c(ccc6ccccc65)c3)c3cc(C(C)(C)C)cc5c3B4c3ccc(-c4cc(C(C)(C)C)cc(C(C)(C)C)c4)cc3N5c3c(-c4ccc(C(C)(C)C)cc4)cc(C(C)(C)C)cc3-c3ccc(C(C)(C)C)cc3)ccc1n2-c1ccccc1 ; c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cccc5-c5ccc6c(ccc7ccccc76)c5)c5cc(-c6ccc7c(c6)-c6ccccc6C7)cc3c54)c(-c3ccccc3)c2)cc1] 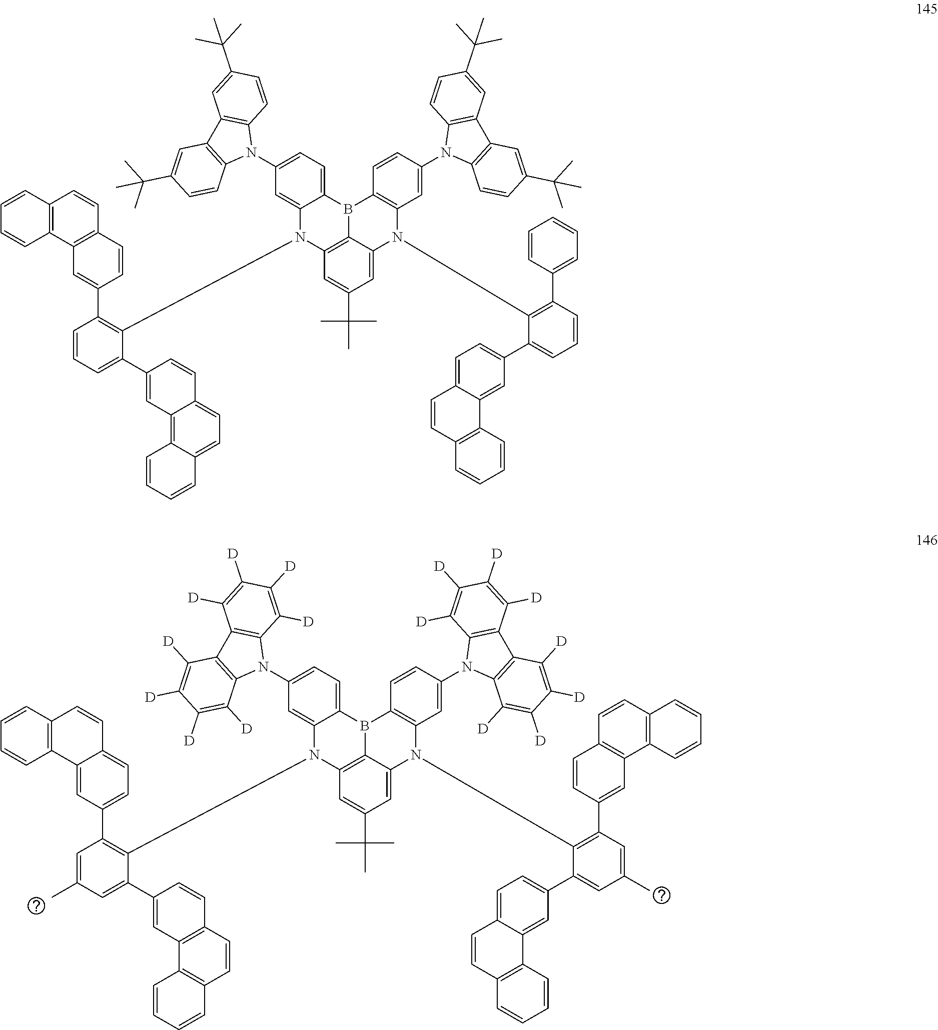 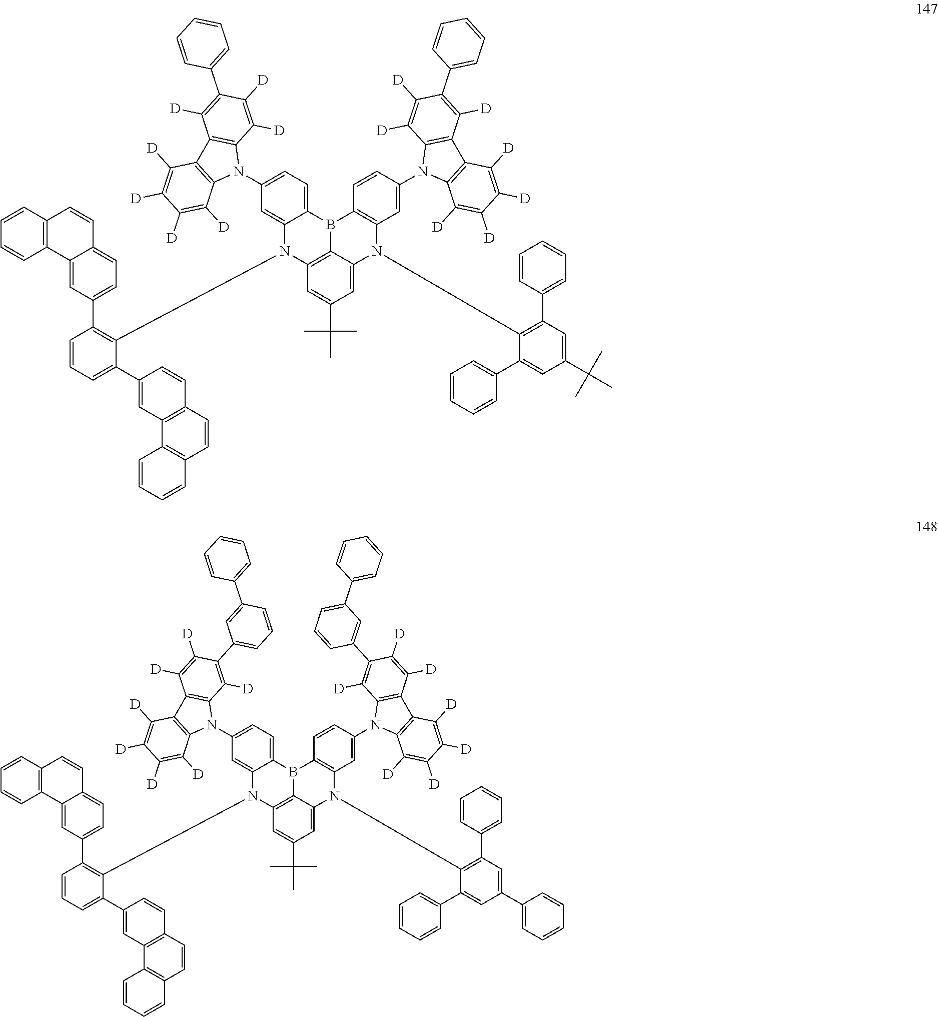 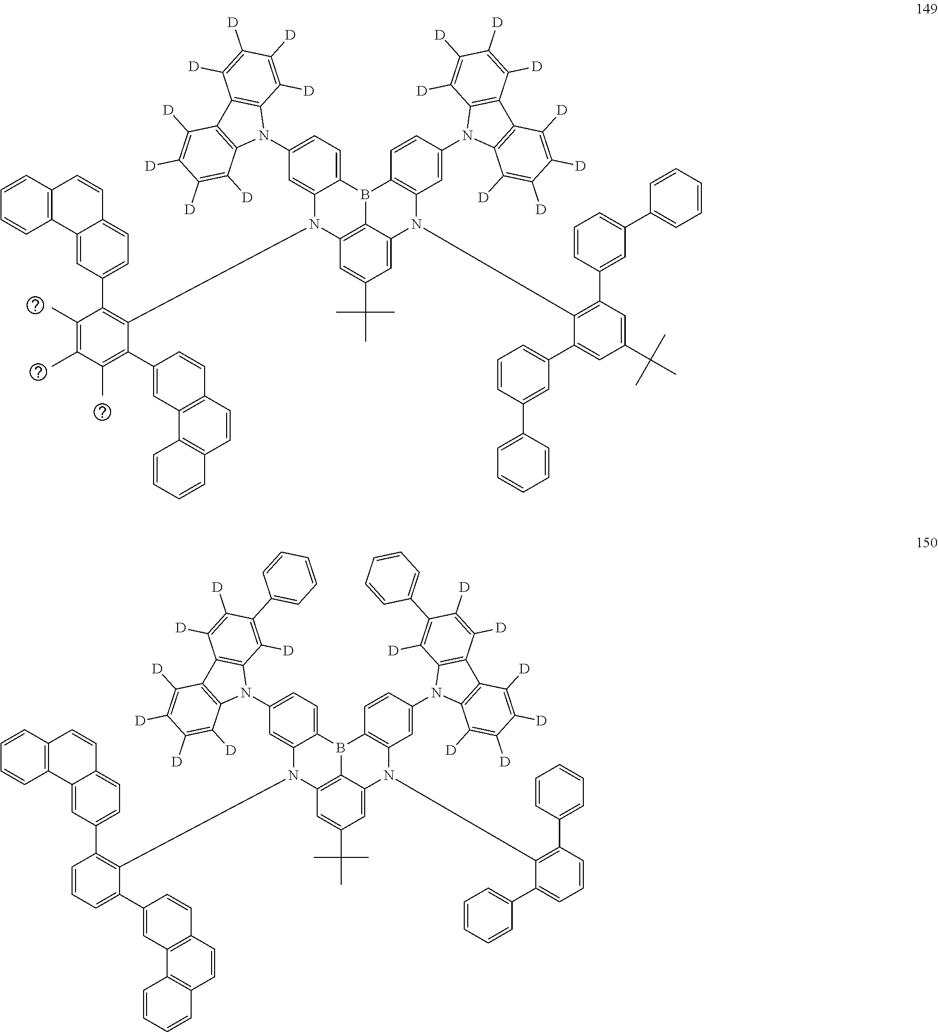 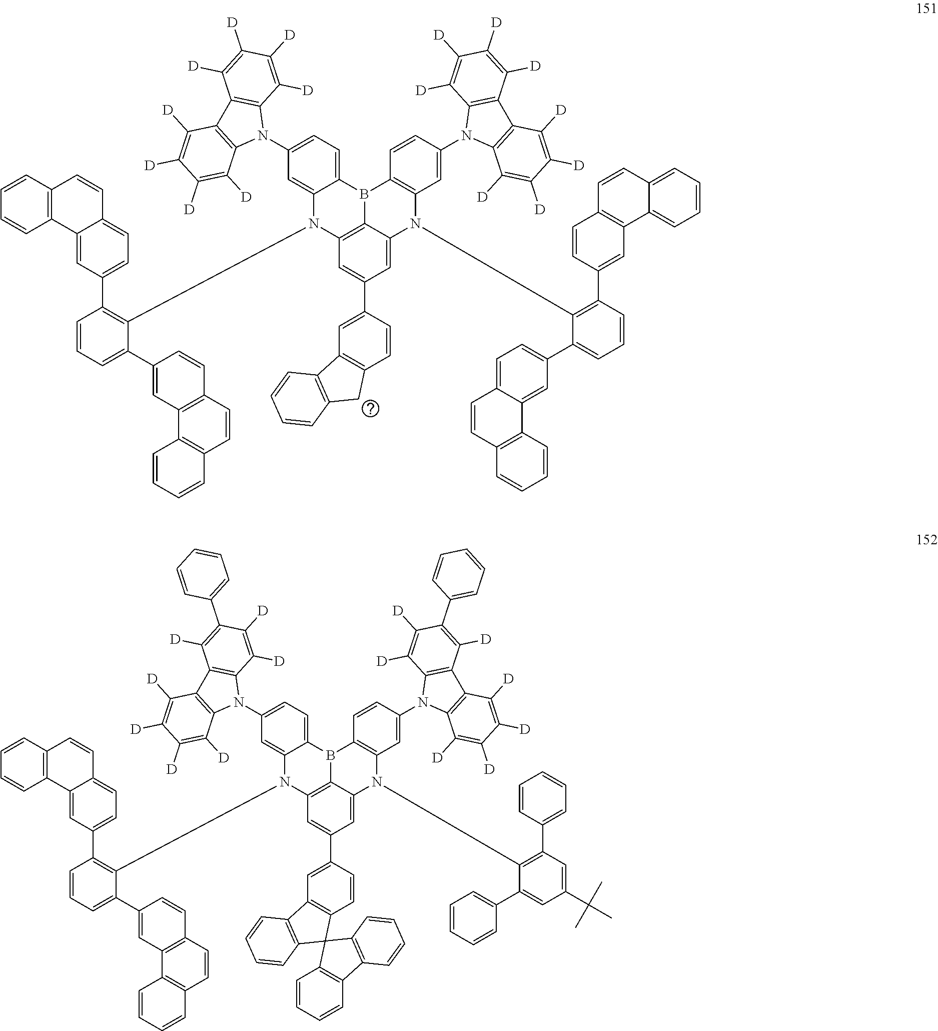 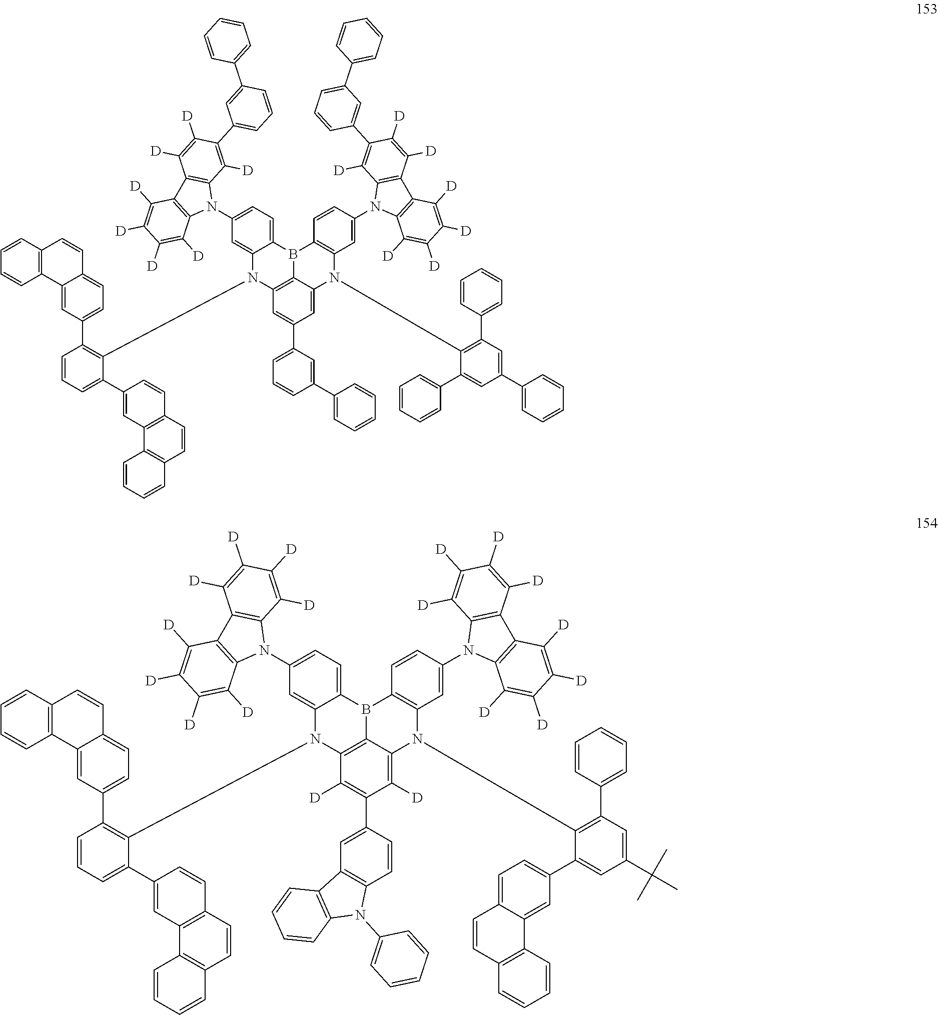 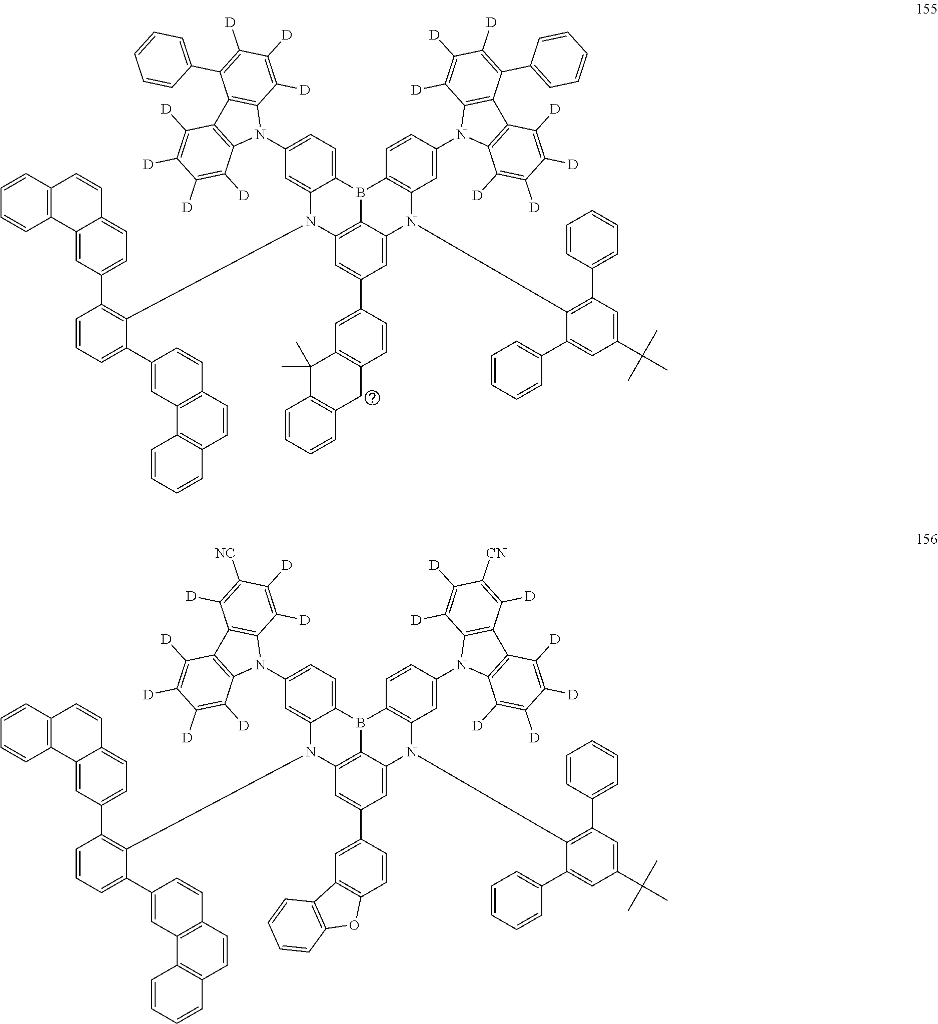 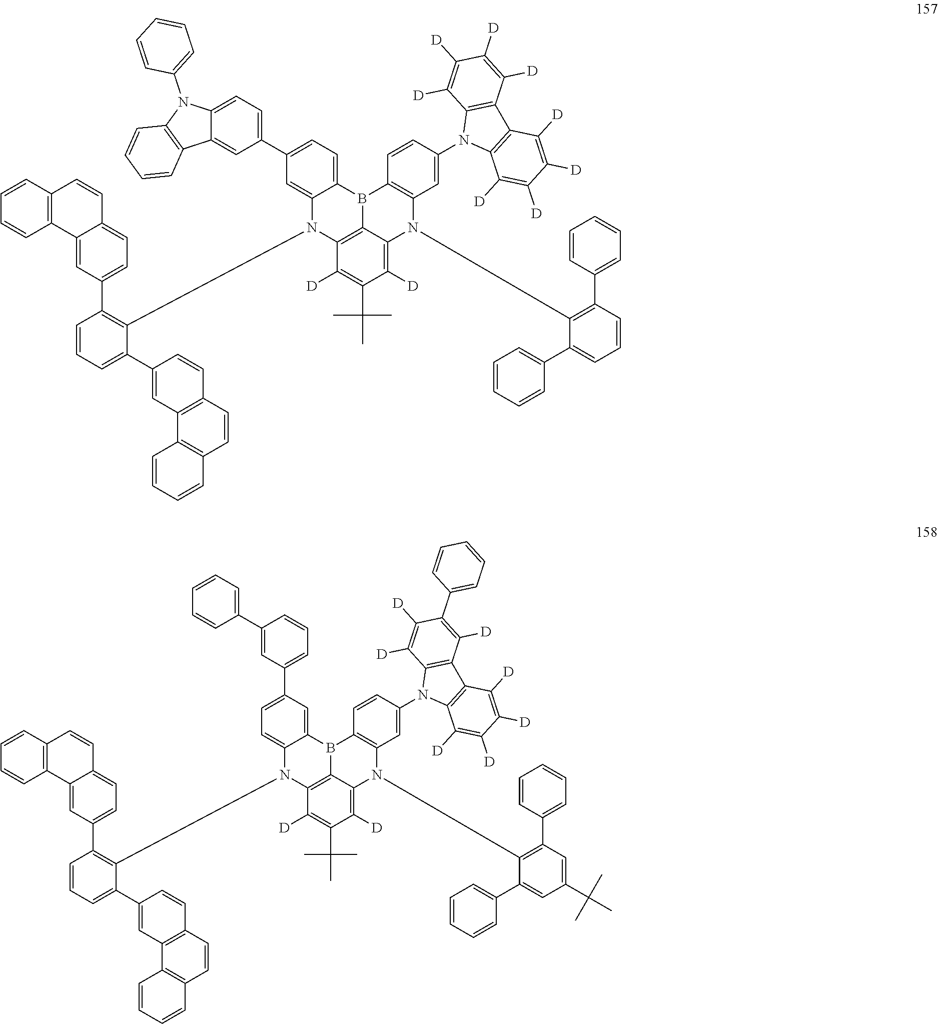 [SMILES: [2H]c1c2c3c(c([2H])c1C(C)(C)C)N(c1c(-c4ccccc4)cccc1-c1ccccc1)c1cc(-n4c5c([2H])c([2H])c([2H])c([2H])c5c5c([2H])c([2H])c([2H])c([2H])c54)ccc1B3c1ccc(-c3ccc4c(c3)c3ccccc3n4-c3ccccc3)cc1N2c1c(-c2ccc3ccc4ccccc4c3c2)cccc1-c1ccc2ccc3ccccc3c2c1 ; [2H]c1c2c3c(c([2H])c1C(C)(C)C)N(c1c(-c4ccccc4)cc(C(C)(C)C)cc1-c1ccccc1)c1cc(-n4c5c([2H])c([2H])c([2H])c([2H])c5c5c([2H])c(-c6ccccc6)c([2H])c([2H])c54)ccc1B3c1cc(-c3cccc(-c4ccccc4)c3)ccc1N2c1c(-c2ccc3ccc4ccccc4c3c2)cccc1-c1ccc2ccc3ccccc3c2c1] 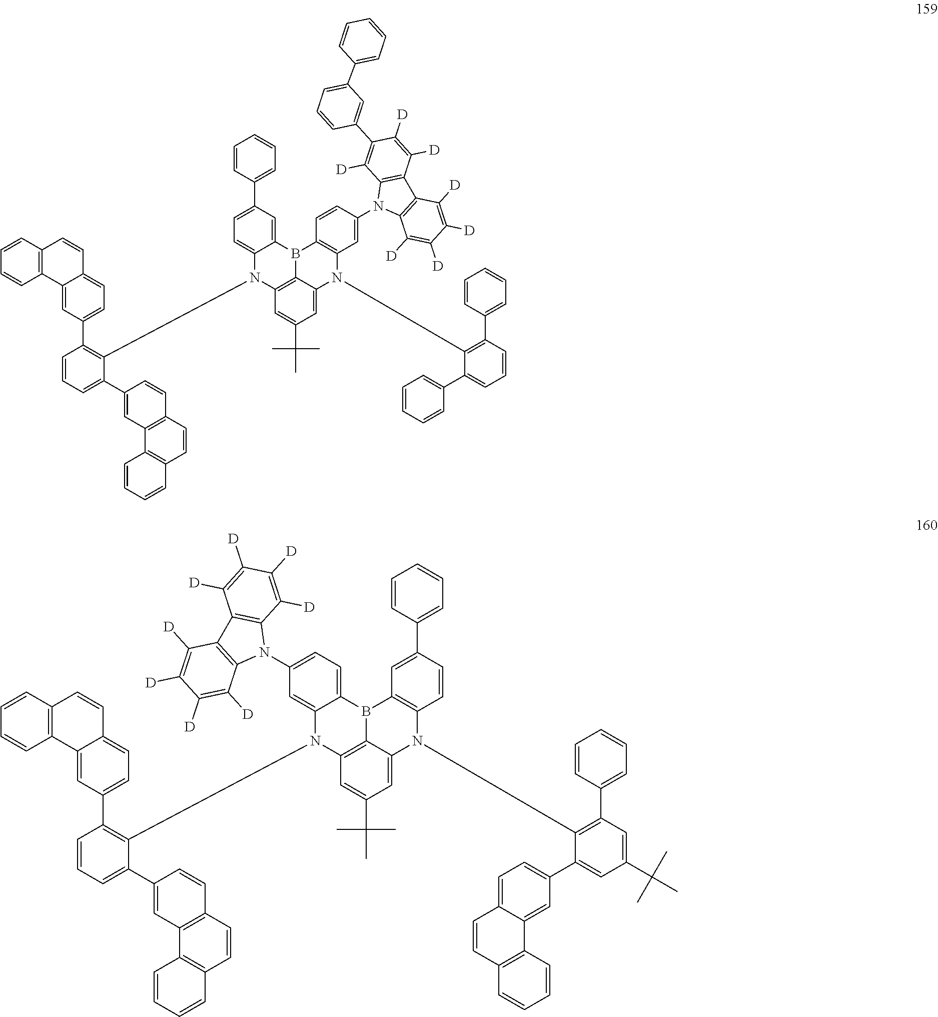 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccc3ccc4ccccc4c3c2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccc4ccc5ccccc5c4c3)cccc1-c1ccc3ccc4ccccc4c3c1)c1cc(C(C)(C)C)cc3c1B2c1cc(-c2ccccc2)ccc1N3c1c(-c2ccccc2)cc(C(C)(C)C)cc1-c1ccc2ccc3ccccc3c2c1] 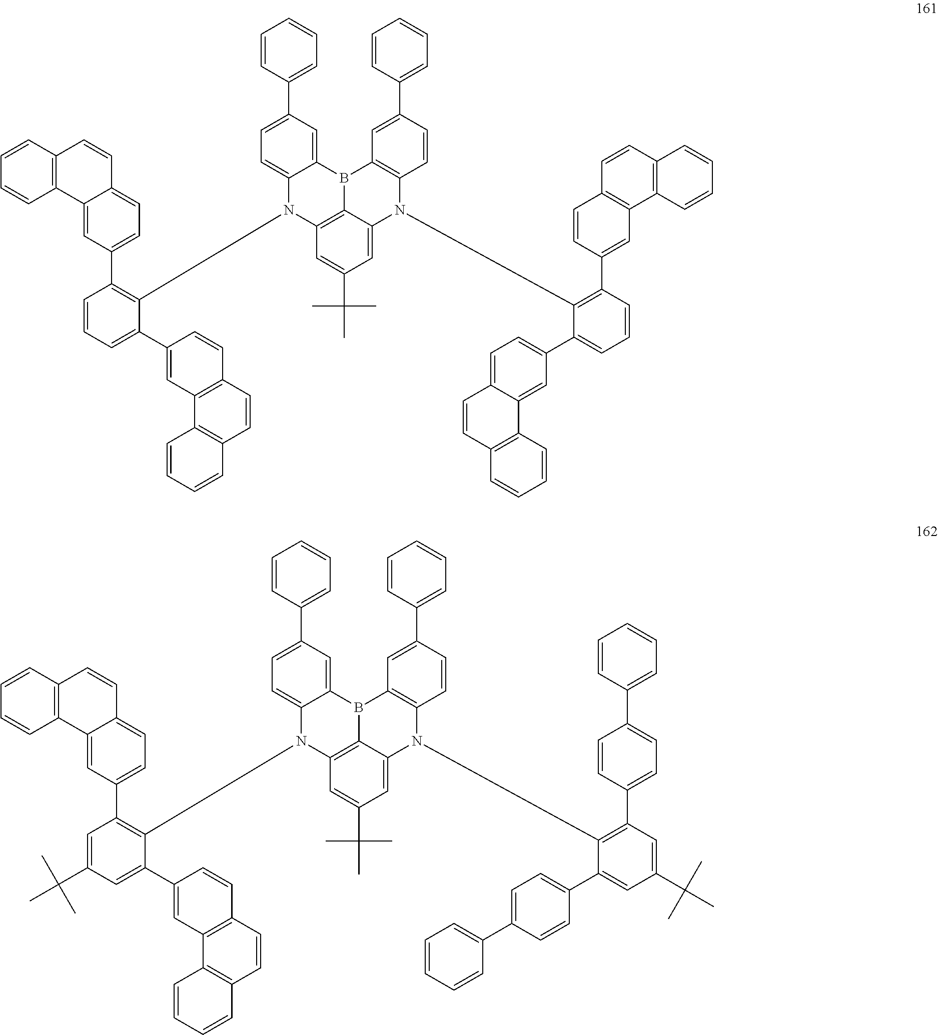 [SMILES: CC(C)(C)c1cc2c3c(c1)N(c1c(-c4ccc5ccc6ccccc6c5c4)cccc1-c1ccc4ccc5ccccc5c4c1)c1ccc(-c4ccccc4)cc1B3c1cc(-c3ccccc3)ccc1N2c1c(-c2ccc3ccc4ccccc4c3c2)cccc1-c1ccc2ccc3ccccc3c2c1 ; CC(C)(C)c1cc(-c2ccc(-c3ccccc3)cc2)c(N2c3ccc(-c4ccccc4)cc3B3c4cc(-c5ccccc5)ccc4N(c4c(-c5ccc6ccc7ccccc7c6c5)cc(C(C)(C)C)cc4-c4ccc5ccc6ccccc6c5c4)c4cc(C(C)(C)C)cc2c43)c(-c2ccc(-c3ccccc3)cc2)c1] 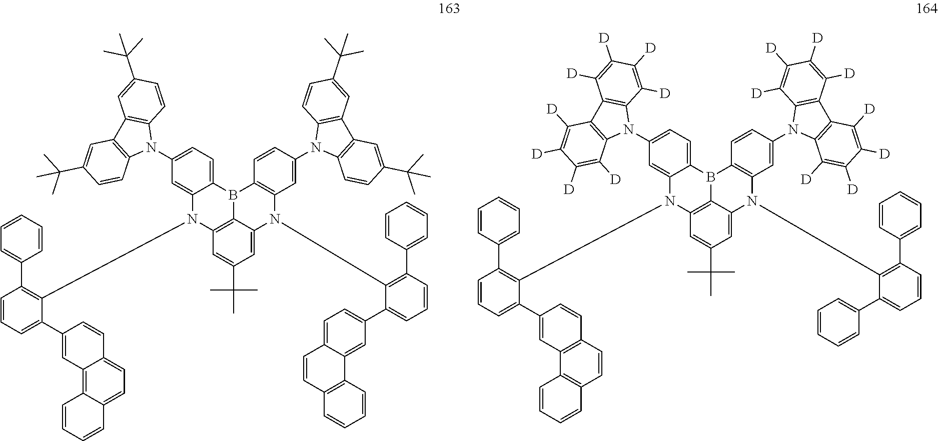 [SMILES: CC(C)(C)c1cc2c3c(c1)N(c1c(-c4ccccc4)cccc1-c1ccc4ccc5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc2ccc3ccccc3c2c1] 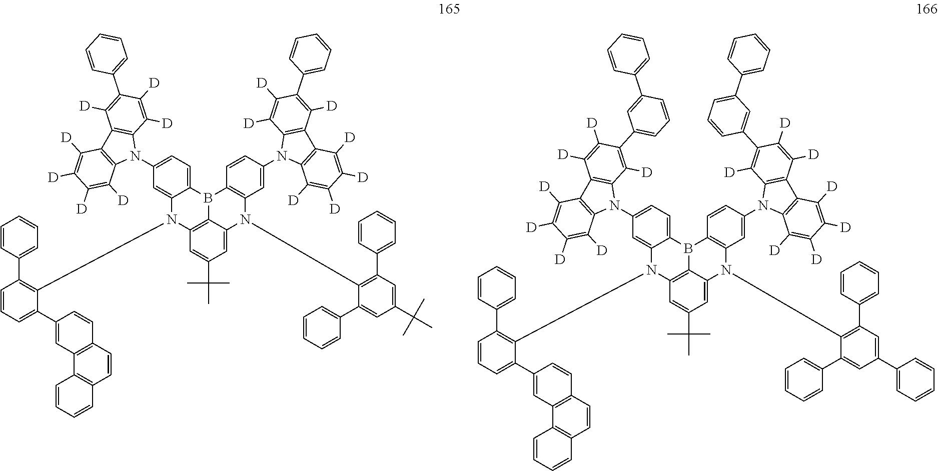 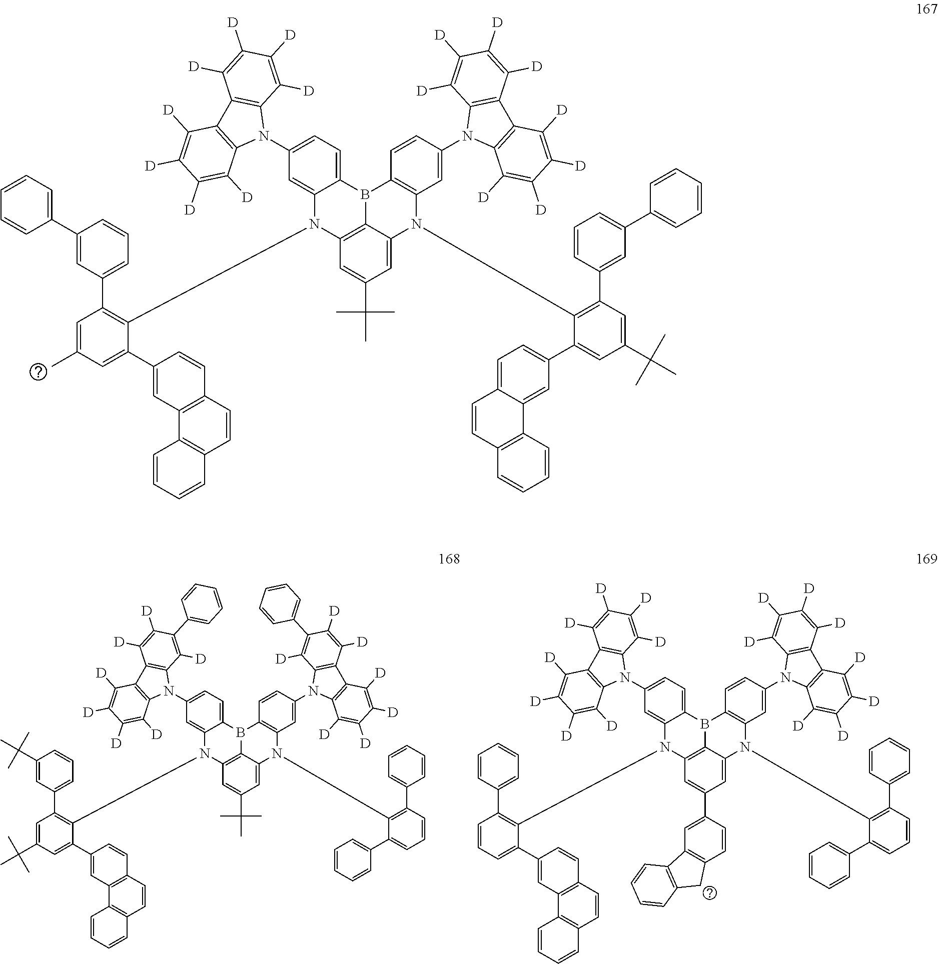 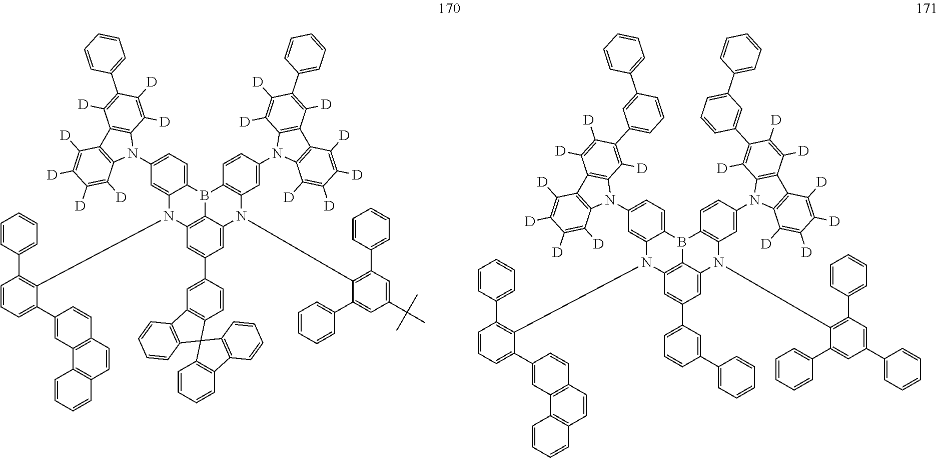 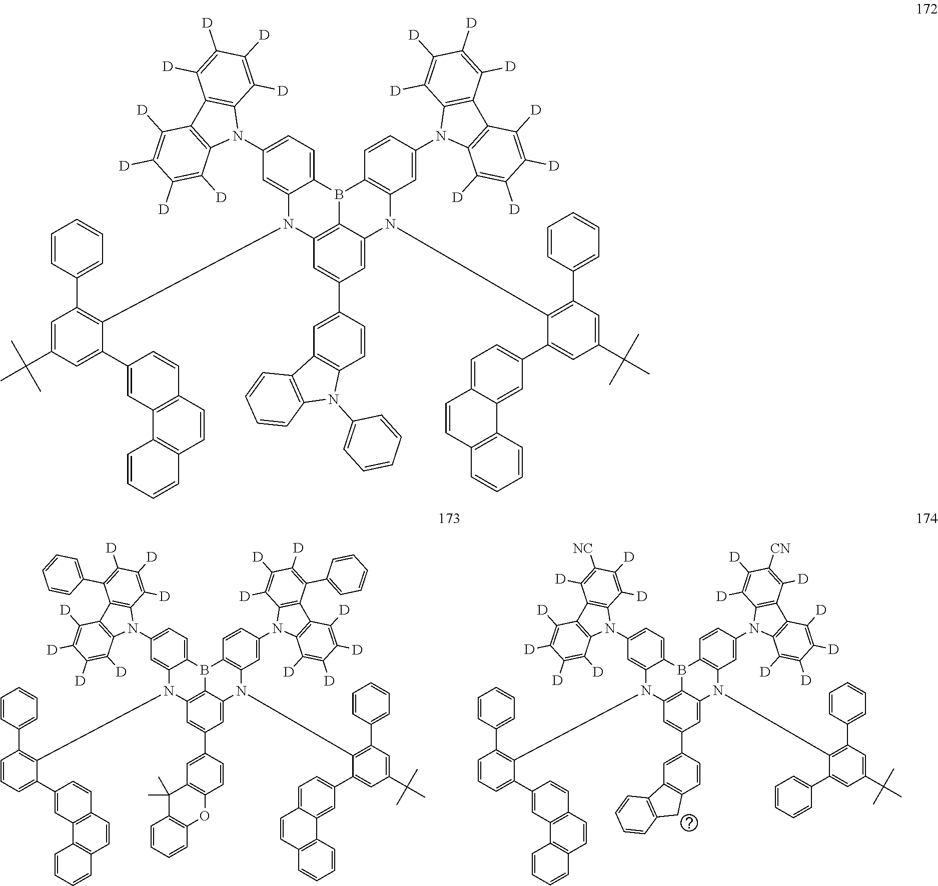 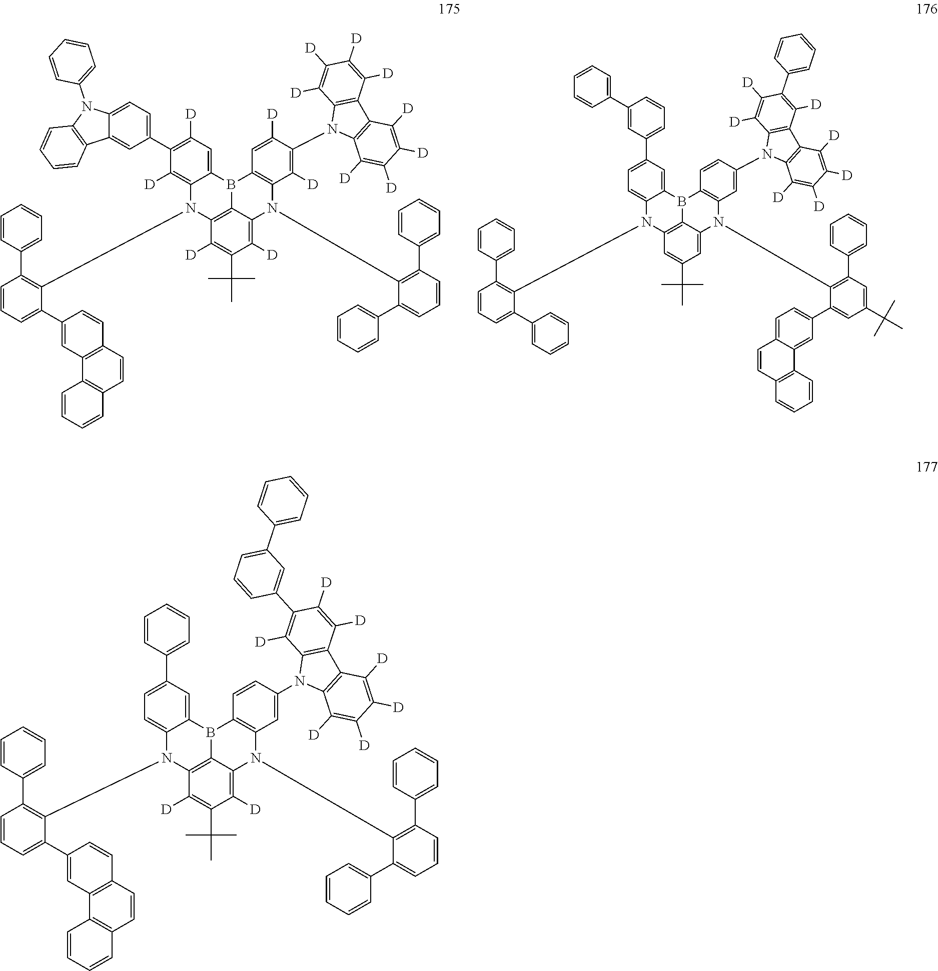 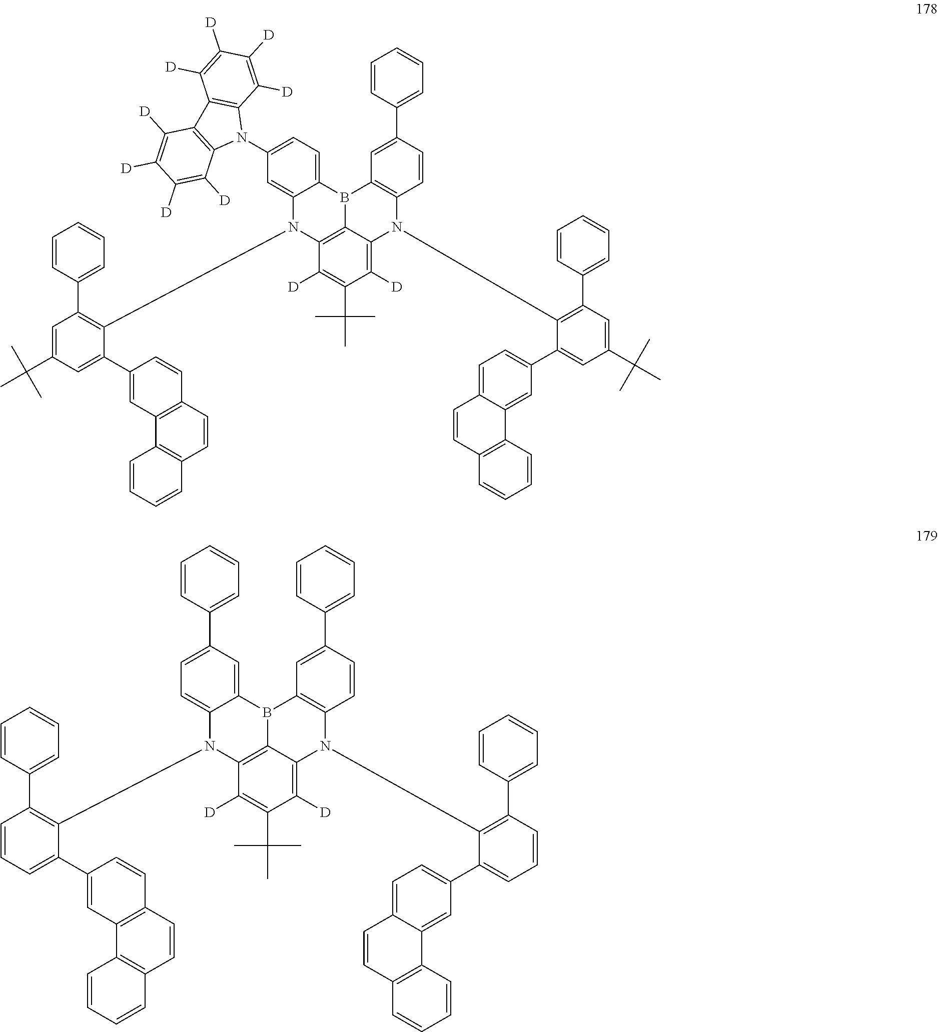 [SMILES: [2H]c1c2c3c(c([2H])c1C(C)(C)C)N(c1c(-c4ccccc4)cc(C(C)(C)C)cc1-c1ccc4ccc5ccccc5c4c1)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1ccc2ccc3ccccc3c2c1 ; [2H]c1c2c3c(c([2H])c1C(C)(C)C)N(c1c(-c4ccccc4)cccc1-c1ccc4ccc5ccccc5c4c1)c1ccc(-c4ccccc4)cc1B3c1cc(-c3ccccc3)ccc1N2c1c(-c2ccccc2)cccc1-c1ccc2ccc3ccccc3c2c1] 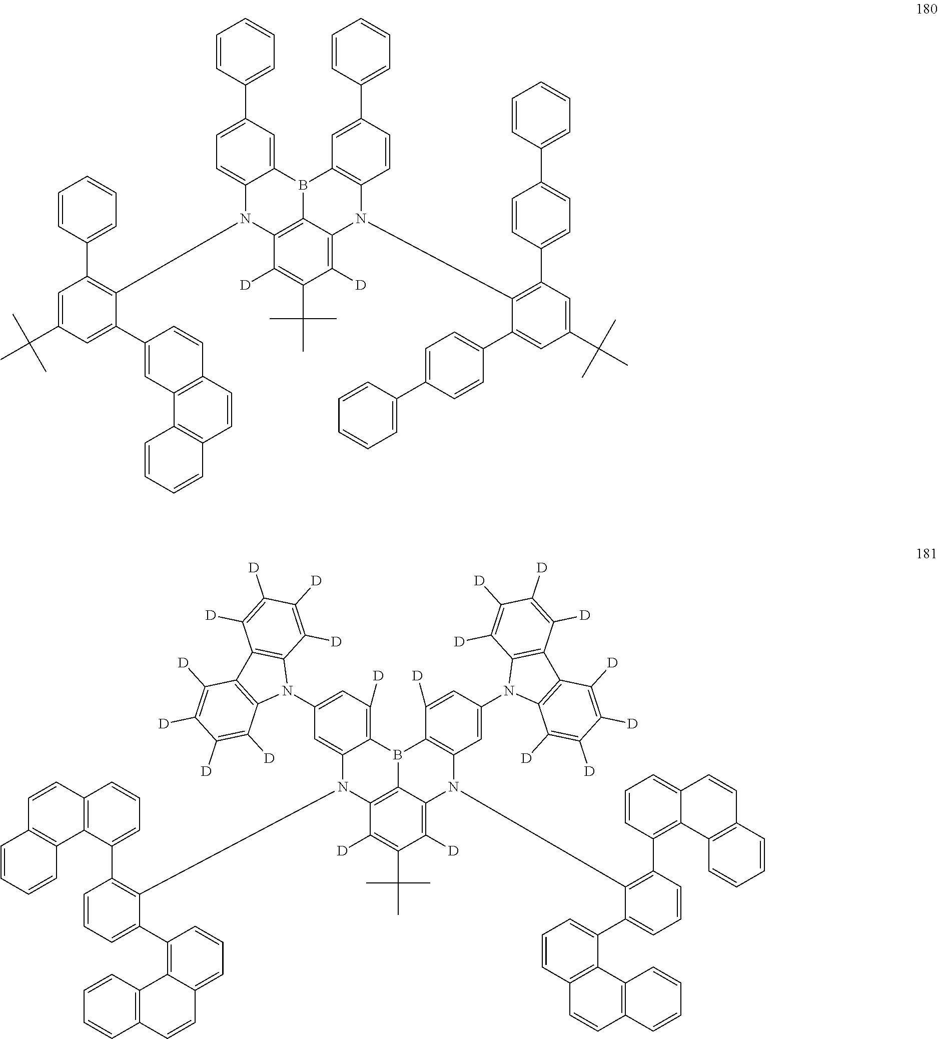 [SMILES: [2H]c1c2c3c(c([2H])c1C(C)(C)C)N(c1c(-c4ccccc4)cc(C(C)(C)C)cc1-c1ccc4ccc5ccccc5c4c1)c1ccc(-c4ccccc4)cc1B3c1cc(-c3ccccc3)ccc1N2c1c(-c2ccc(-c3ccccc3)cc2)cc(C(C)(C)C)cc1-c1ccc(-c2ccccc2)cc1 ; [2H]c1cc(-n2c3c([2H])c([2H])c([2H])c([2H])c3c3c([2H])c([2H])c([2H])c([2H])c32)cc2c1B1c3c([2H])cc(-n4c5c([2H])c([2H])c([2H])c([2H])c5c5c([2H])c([2H])c([2H])c([2H])c54)cc3N(c3c(-c4cccc5ccc6ccccc6c45)cccc3-c3cccc4ccc5ccccc5c34)c3c([2H])c(C(C)(C)C)c([2H])c(c31)N2c1c(-c2cccc3ccc4ccccc4c23)cccc1-c1cccc2ccc3ccccc3c12] 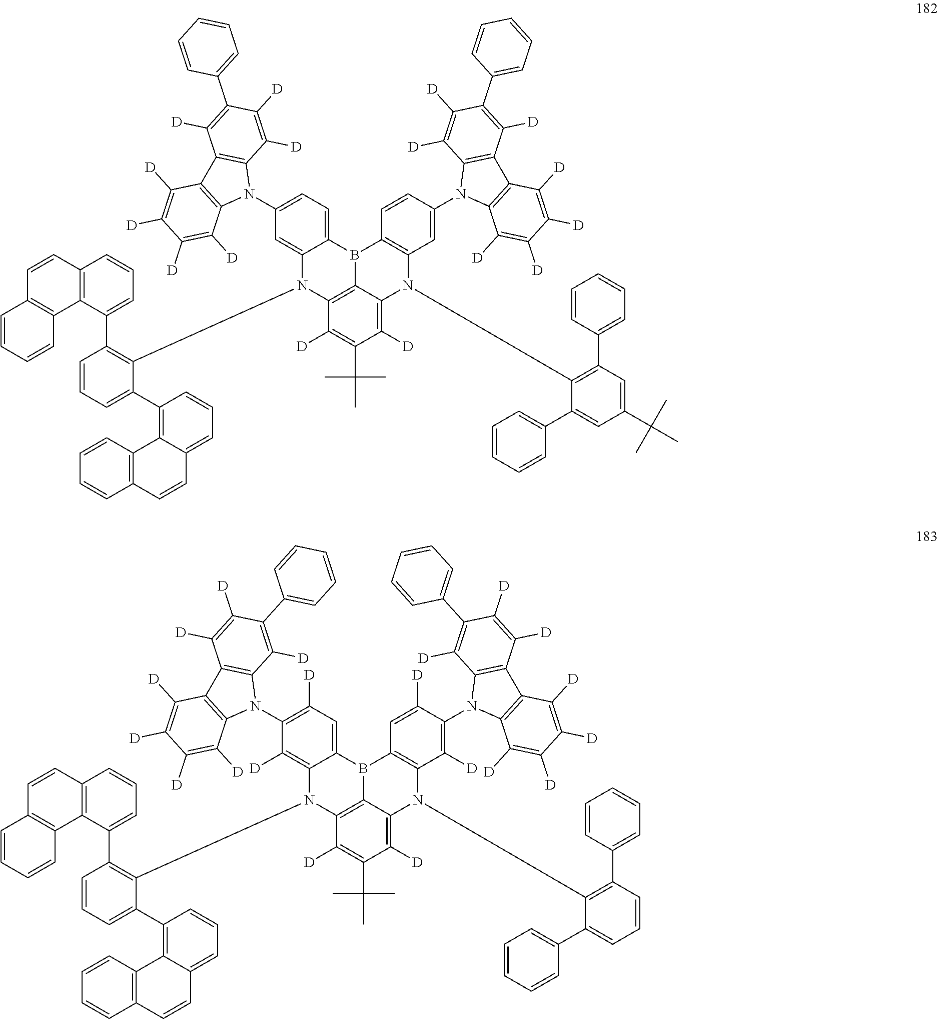 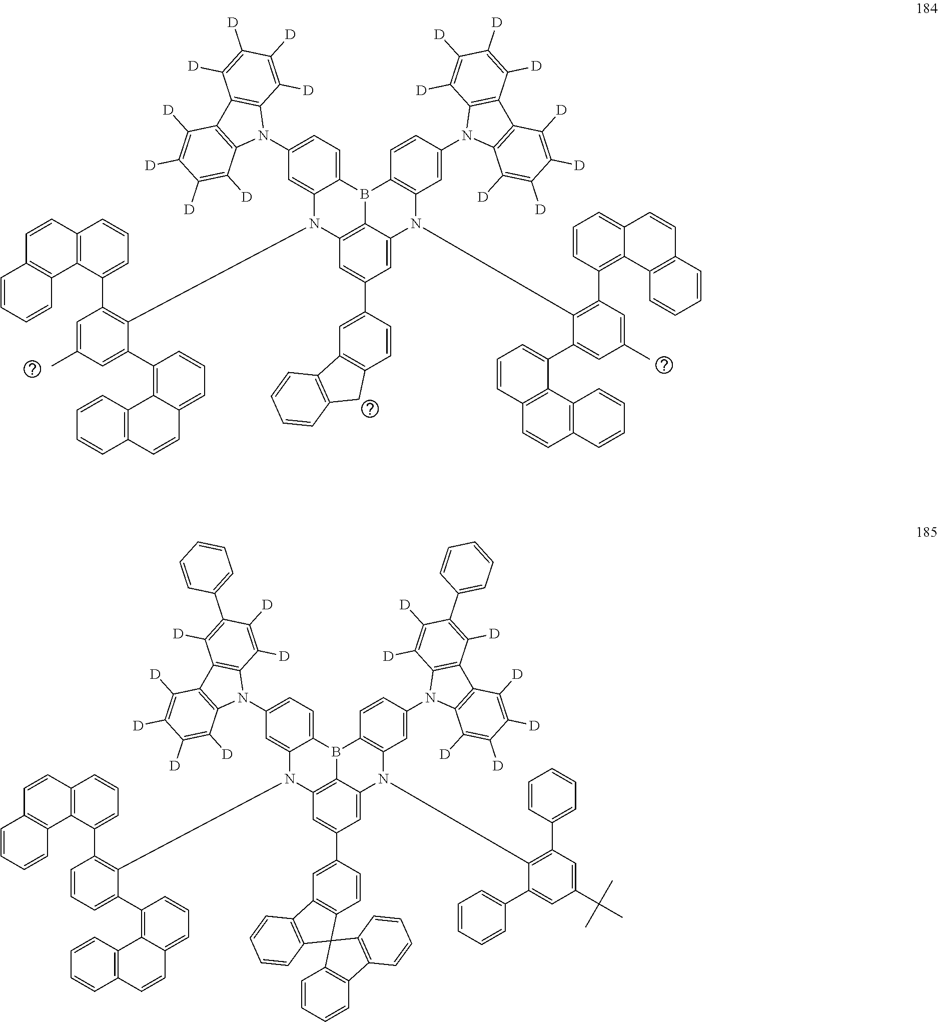 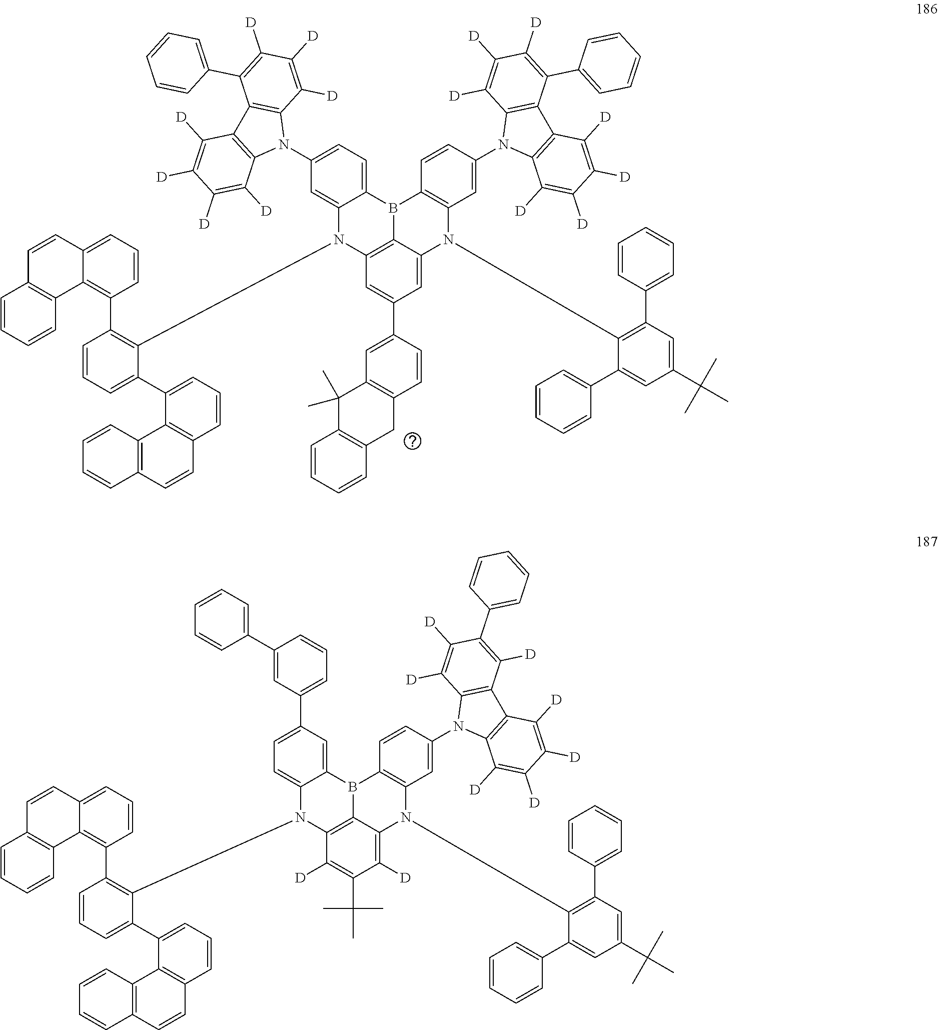 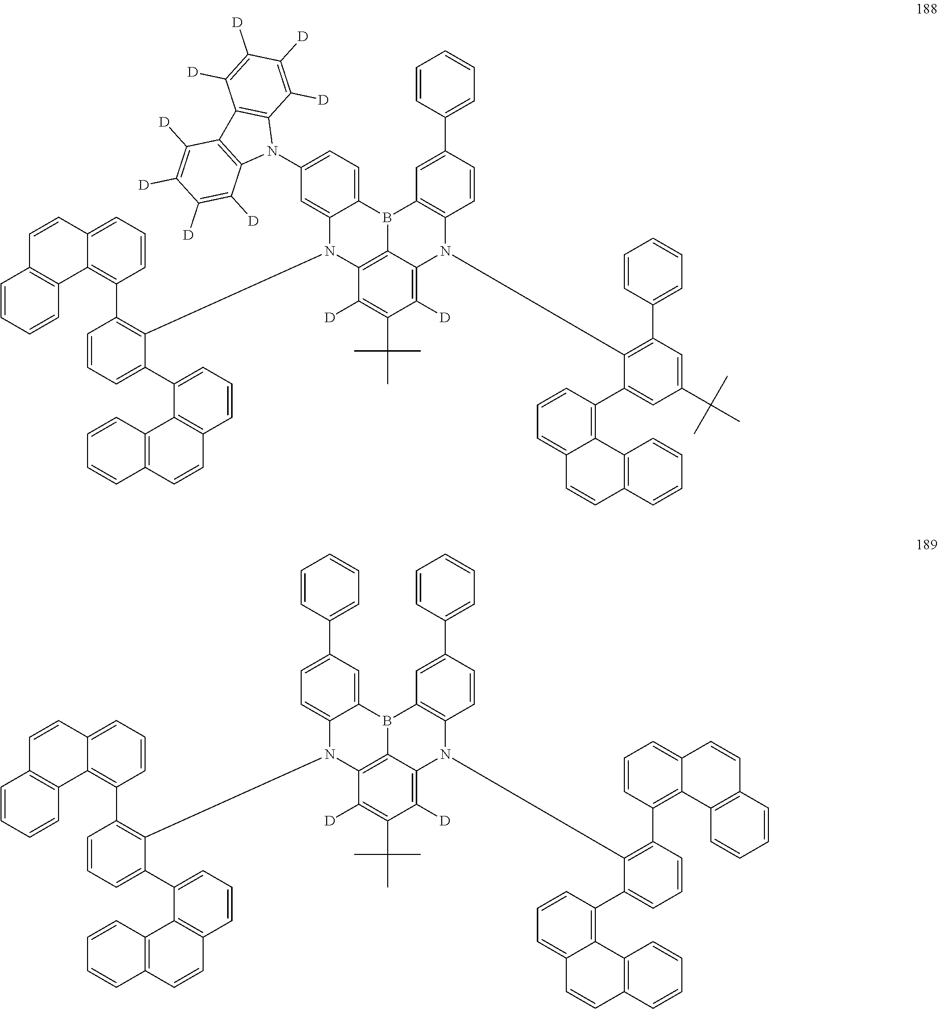 [SMILES: [2H]c1c2c3c(c([2H])c1C(C)(C)C)N(c1c(-c4cccc5ccc6ccccc6c45)cccc1-c1cccc4ccc5ccccc5c14)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1cccc2ccc3ccccc3c12 ; [2H]c1c2c3c(c([2H])c1C(C)(C)C)N(c1c(-c4cccc5ccc6ccccc6c45)cccc1-c1cccc4ccc5ccccc5c14)c1ccc(-c4ccccc4)cc1B3c1cc(-c3ccccc3)ccc1N2c1c(-c2cccc3ccc4ccccc4c23)cccc1-c1cccc2ccc3ccccc3c12] 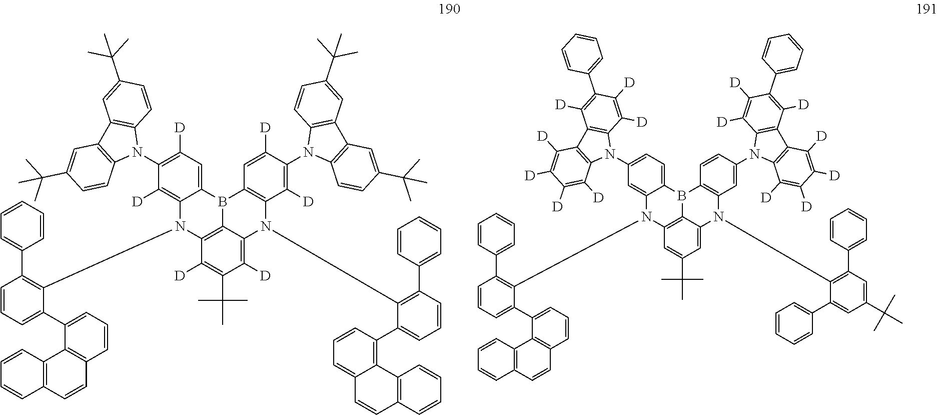 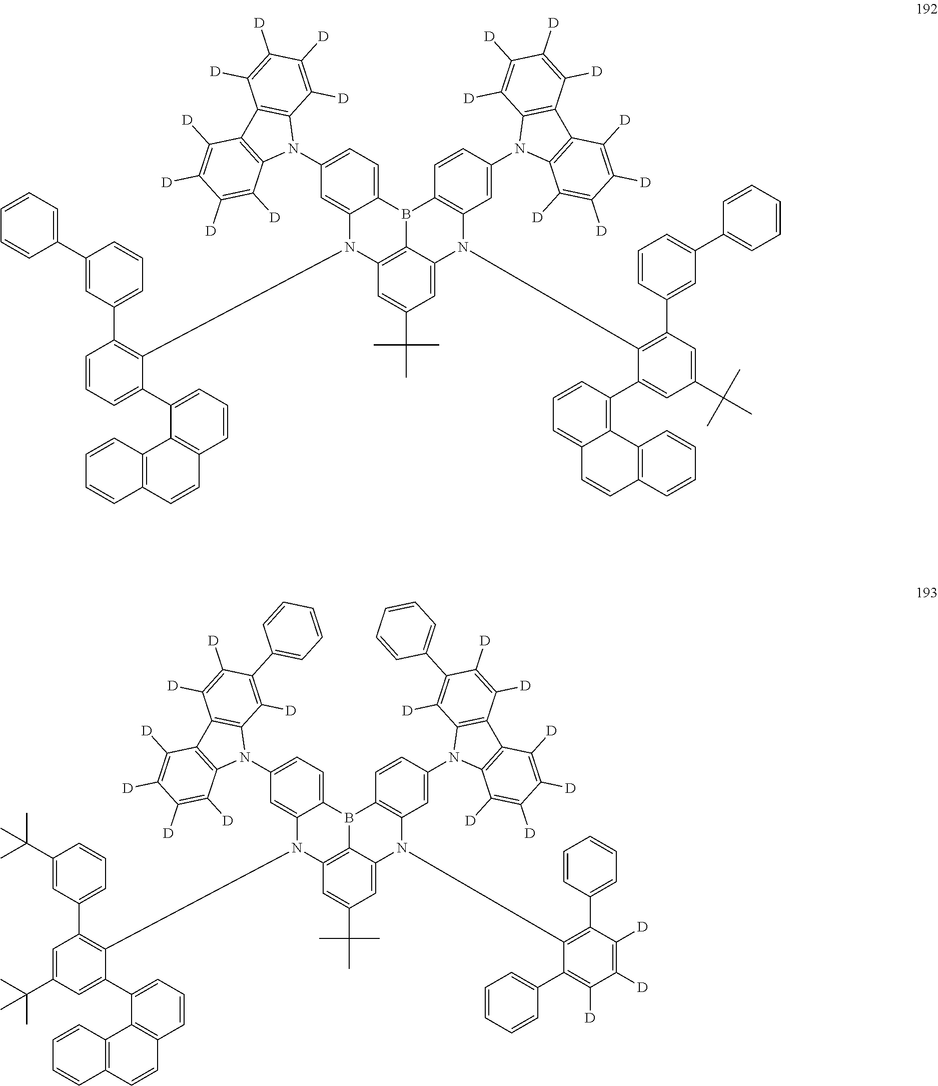 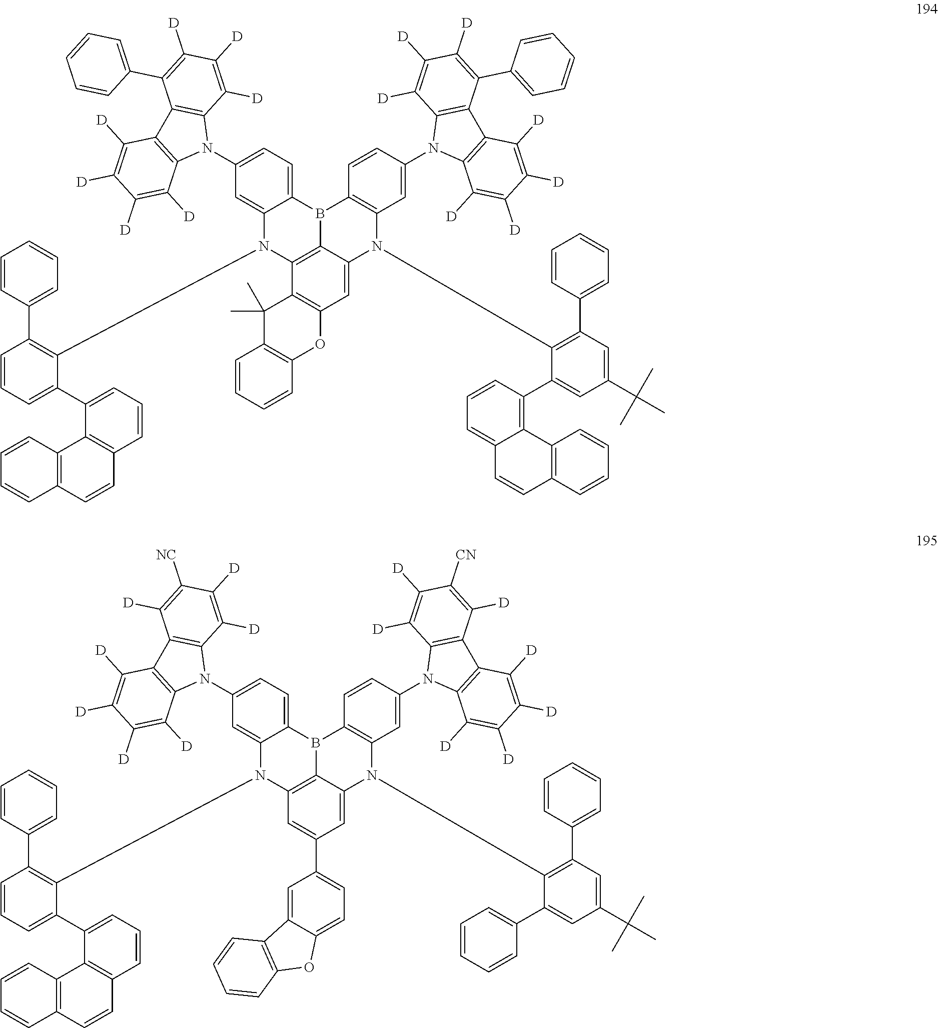 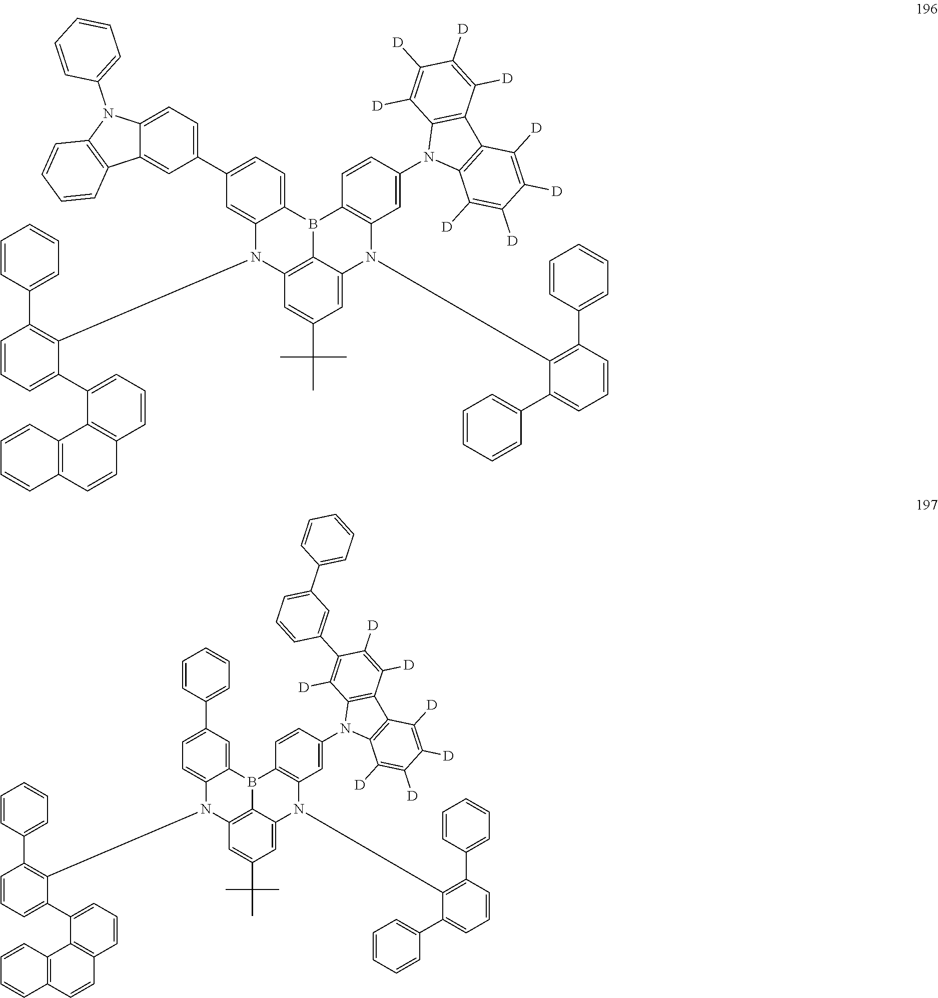 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccccc2)cccc1-c1cccc2ccc3ccccc3c12 ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1cccc2ccc3ccccc3c12] 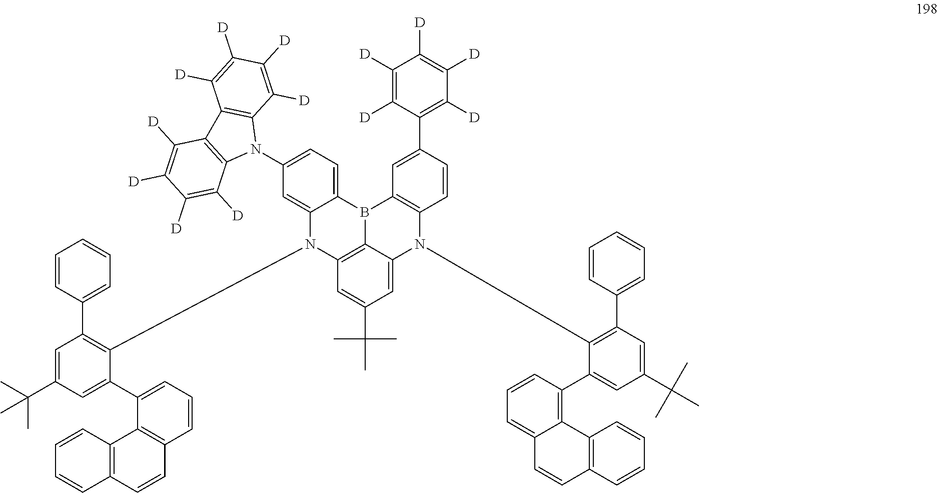 [SMILES: [2H]c1c([2H])c([2H])c(-c2ccc3c(c2)B2c4ccc(-n5c6c([2H])c([2H])c([2H])c([2H])c6c6c([2H])c([2H])c([2H])c([2H])c65)cc4N(c4c(-c5ccccc5)cc(C(C)(C)C)cc4-c4cccc5ccc6ccccc6c45)c4cc(C(C)(C)C)cc(c42)N3c2c(-c3ccccc3)cc(C(C)(C)C)cc2-c2cccc3ccc4ccccc4c23)c([2H])c1[2H]] 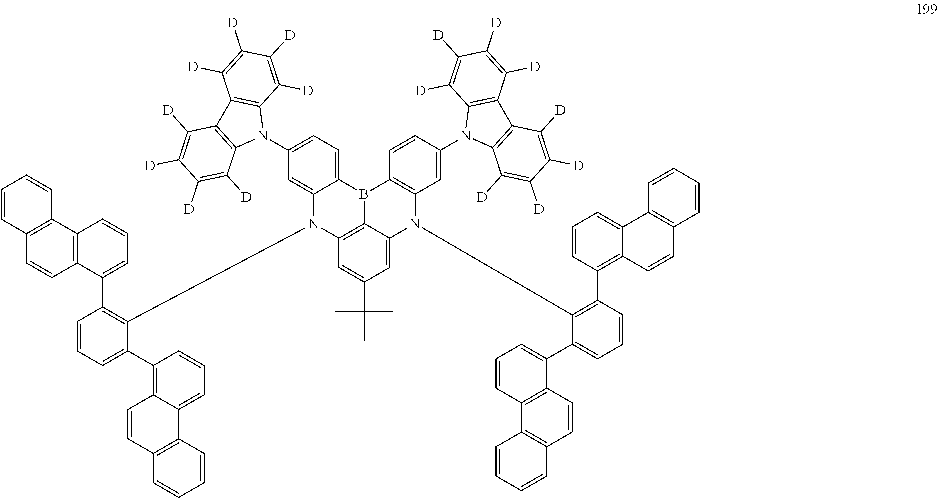 [SMILES: [2H]c1c([2H])c([2H])c2c(c1[2H])c1c([2H])c([2H])c([2H])c([2H])c1n2-c1ccc2c(c1)N(c1c(-c3cccc4c3ccc3ccccc34)cccc1-c1cccc3c1ccc1ccccc13)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cccc3c2ccc2ccccc23)cccc1-c1cccc2c1ccc1ccccc12] 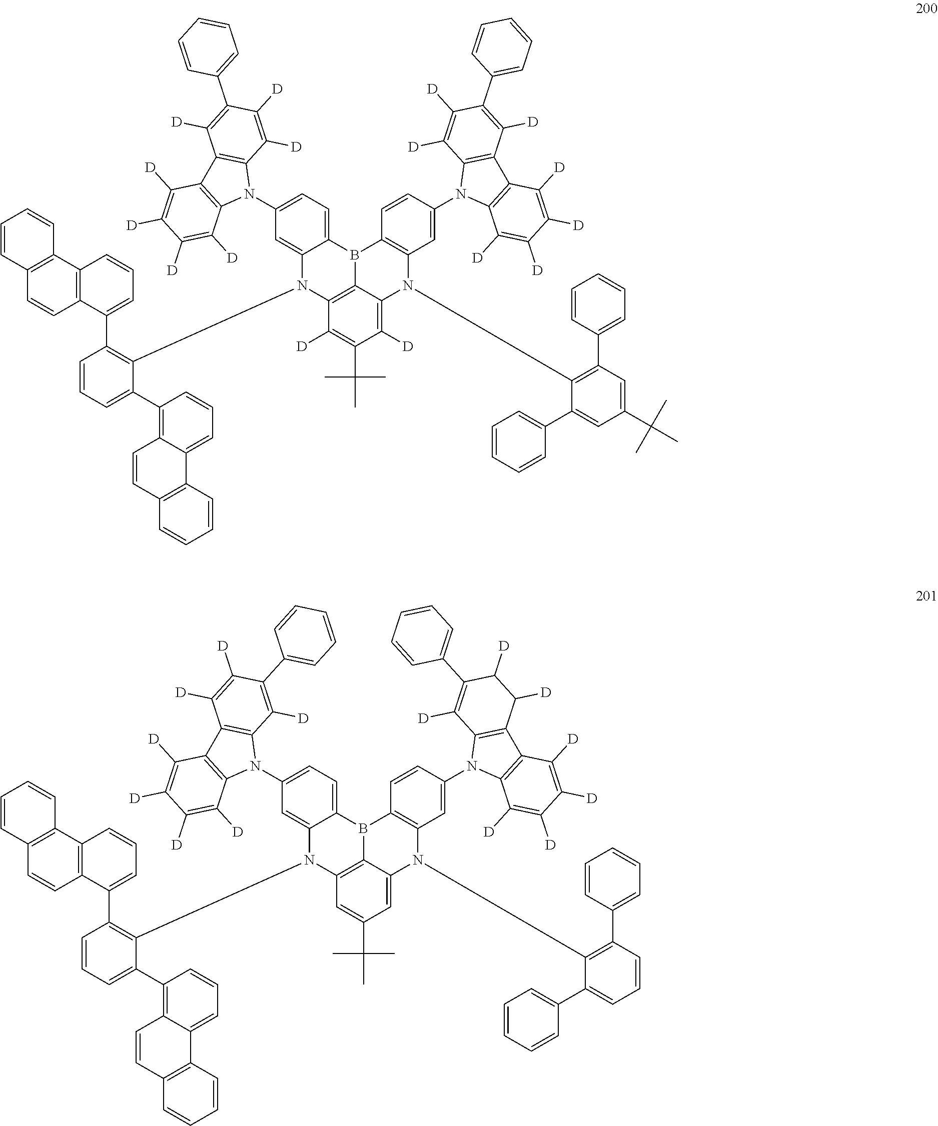 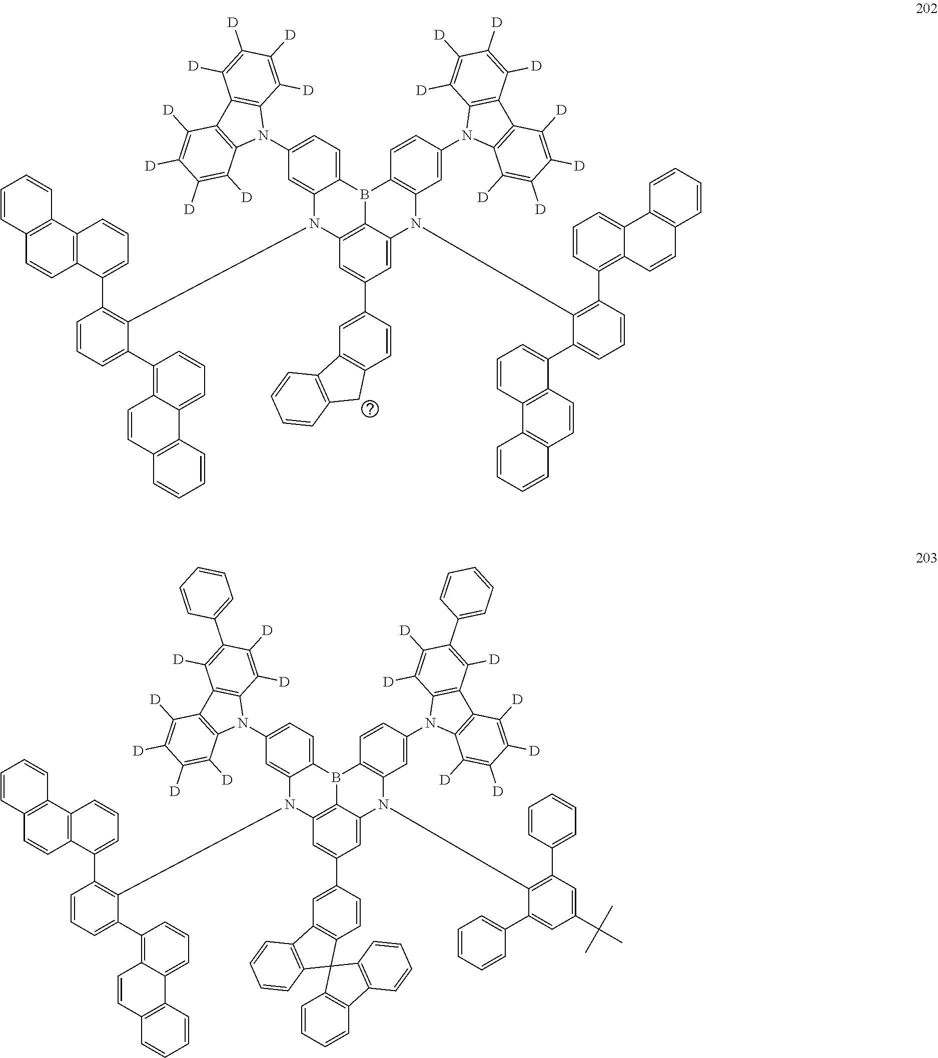 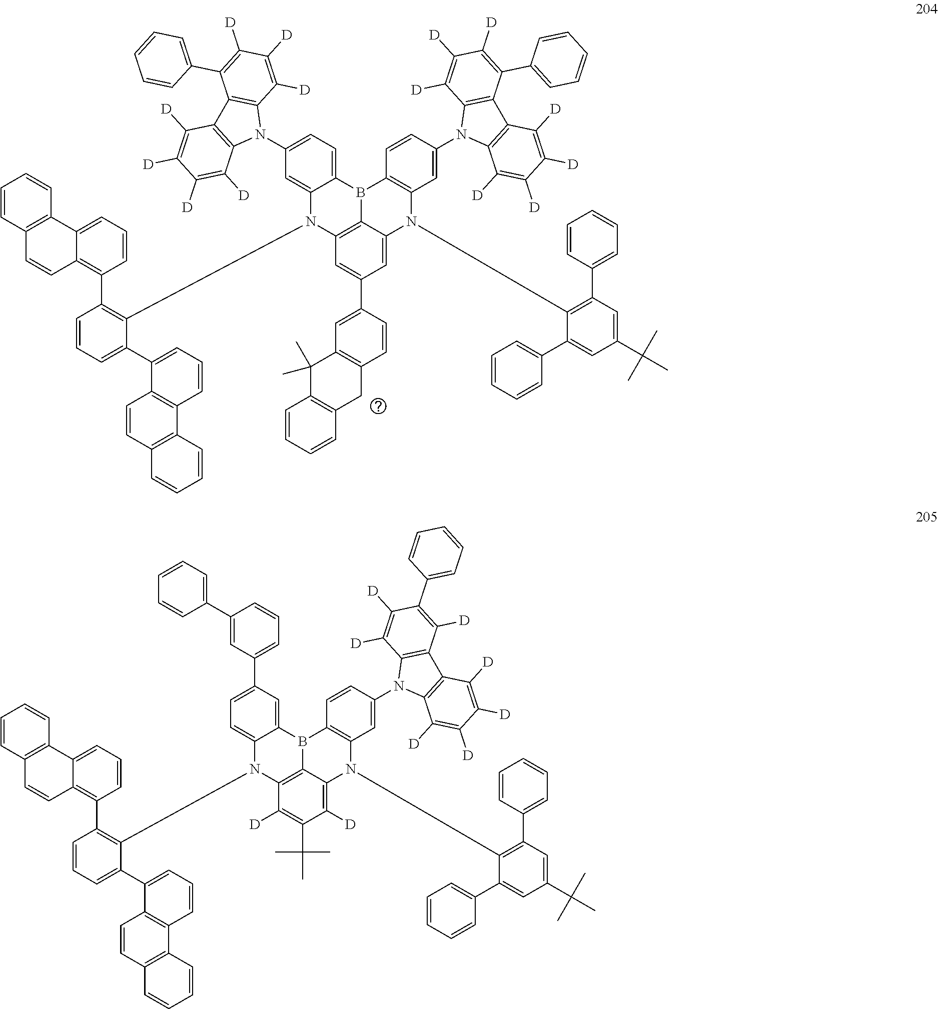 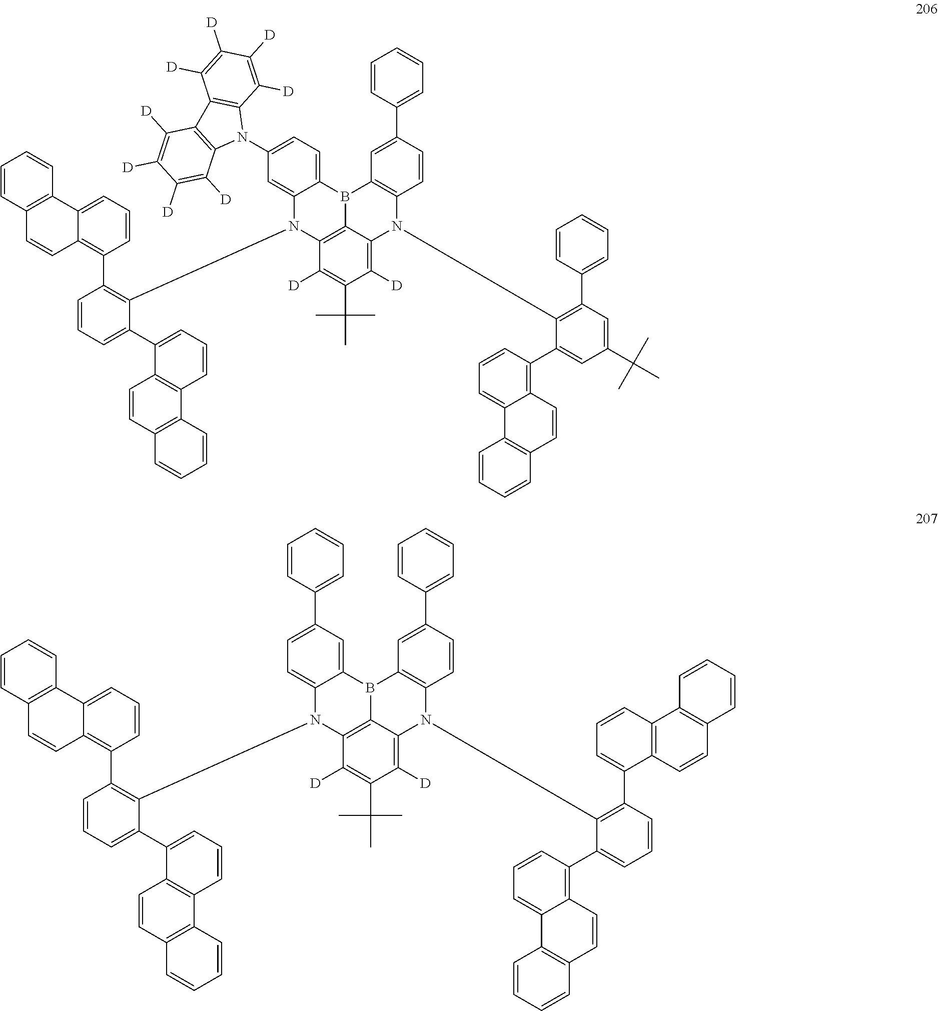 [SMILES: [2H]c1c2c3c(c([2H])c1C(C)(C)C)N(c1c(-c4cccc5c4ccc4ccccc45)cccc1-c1cccc4c1ccc1ccccc14)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1cccc2c1ccc1ccccc12 ; [2H]c1c2c3c(c([2H])c1C(C)(C)C)N(c1c(-c4cccc5c4ccc4ccccc45)cccc1-c1cccc4c1ccc1ccccc14)c1ccc(-c4ccccc4)cc1B3c1cc(-c3ccccc3)ccc1N2c1c(-c2cccc3c2ccc2ccccc23)cccc1-c1cccc2c1ccc1ccccc12] 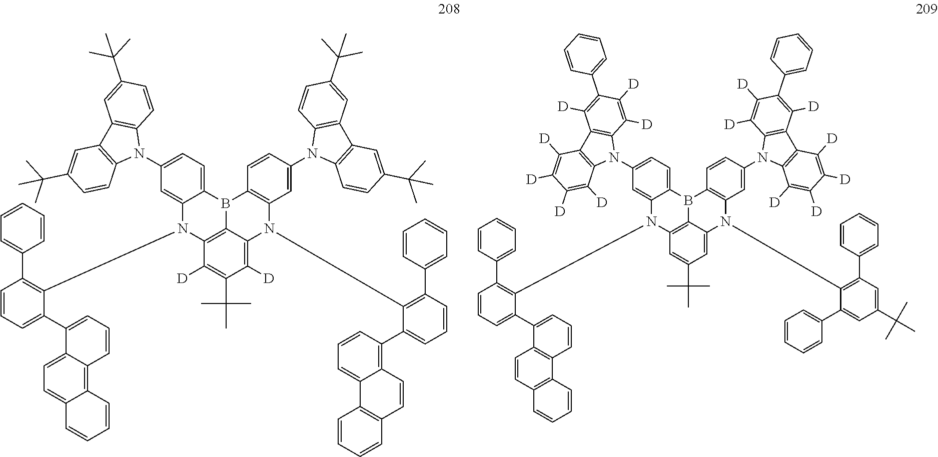 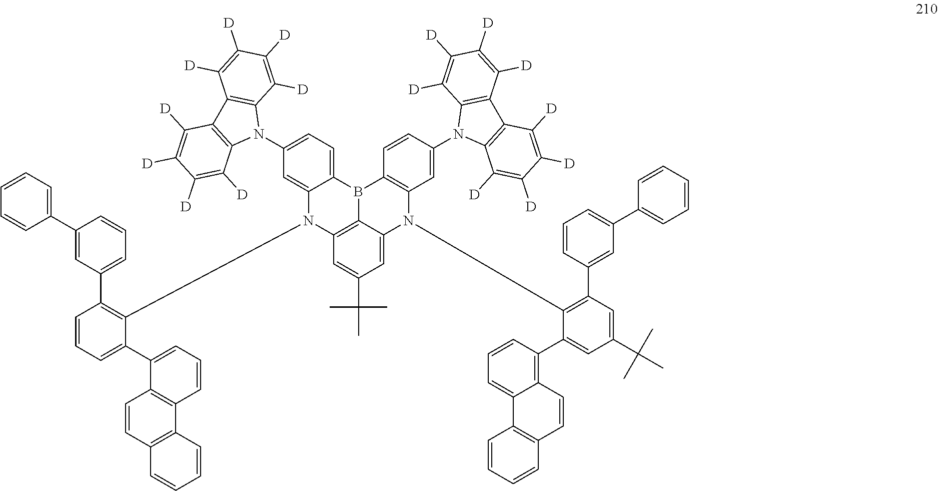 [SMILES: [2H]c1c([2H])c([2H])c2c(c1[2H])c1c([2H])c([2H])c([2H])c([2H])c1n2-c1ccc2c(c1)N(c1c(-c3cccc(-c4ccccc4)c3)cccc1-c1cccc3c1ccc1ccccc13)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cccc(-c3ccccc3)c2)cc(C(C)(C)C)cc1-c1cccc2c1ccc1ccccc12] 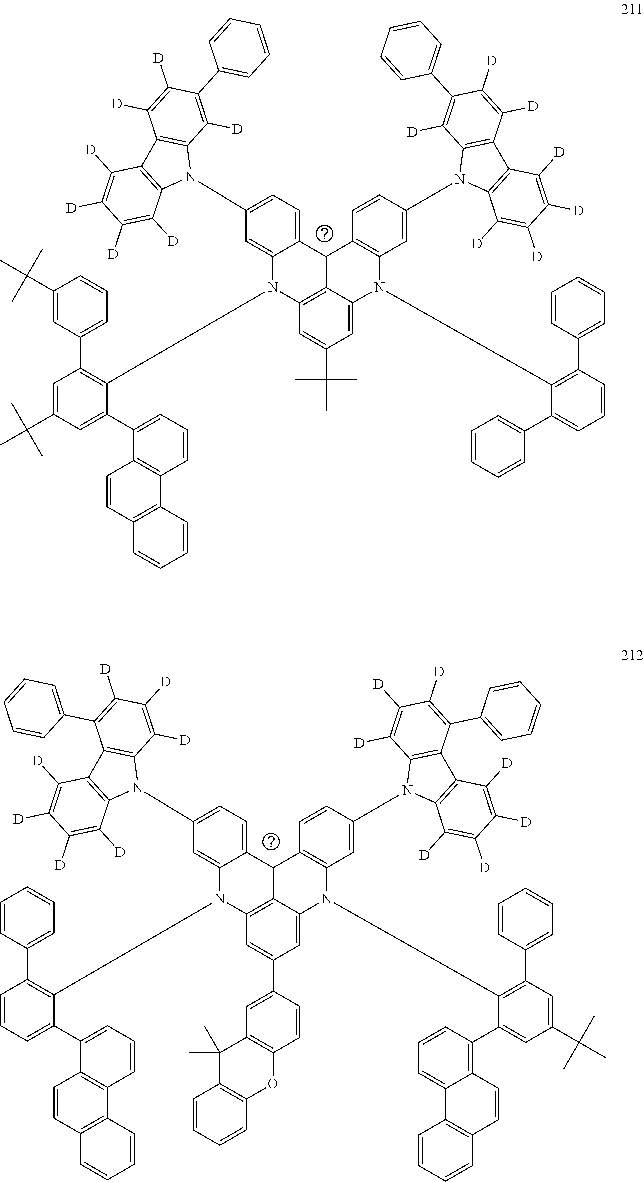 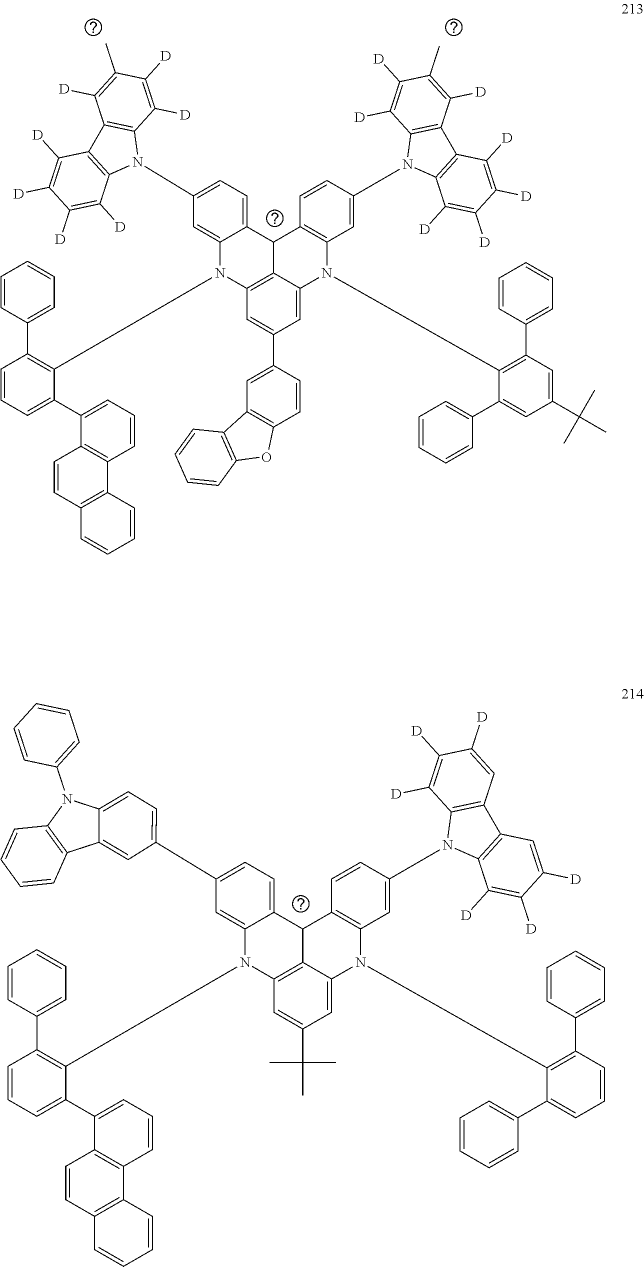 [SMILES: [2H]c1c([2H])c([2H])c2c(c1[2H])c1c([2H])c(C)c([2H])c([2H])c1n2-c1ccc2c(c1)N(c1c(-c3ccccc3)cc(C(C)(C)C)cc1-c1ccccc1)c1cc(-c3ccc4oc5ccccc5c4c3)cc3c1C2c1ccc(-n2c4c([2H])c([2H])c([2H])c([2H])c4c4c([2H])c(C)c([2H])c([2H])c42)cc1N3c1c(-c2ccccc2)cccc1-c1cccc2c1ccc1ccccc12 ; [2H]c1cc2c3cc([2H])c([2H])c([2H])c3n(-c3ccc4c(c3)N(c3c(-c5ccccc5)cccc3-c3ccccc3)c3cc(C(C)(C)C)cc5c3C4c3ccc(-c4ccc6c(c4)c4ccccc4n6-c4ccccc4)cc3N5c3c(-c4ccccc4)cccc3-c3cccc4c3ccc3ccccc34)c2c([2H])c1[2H]] 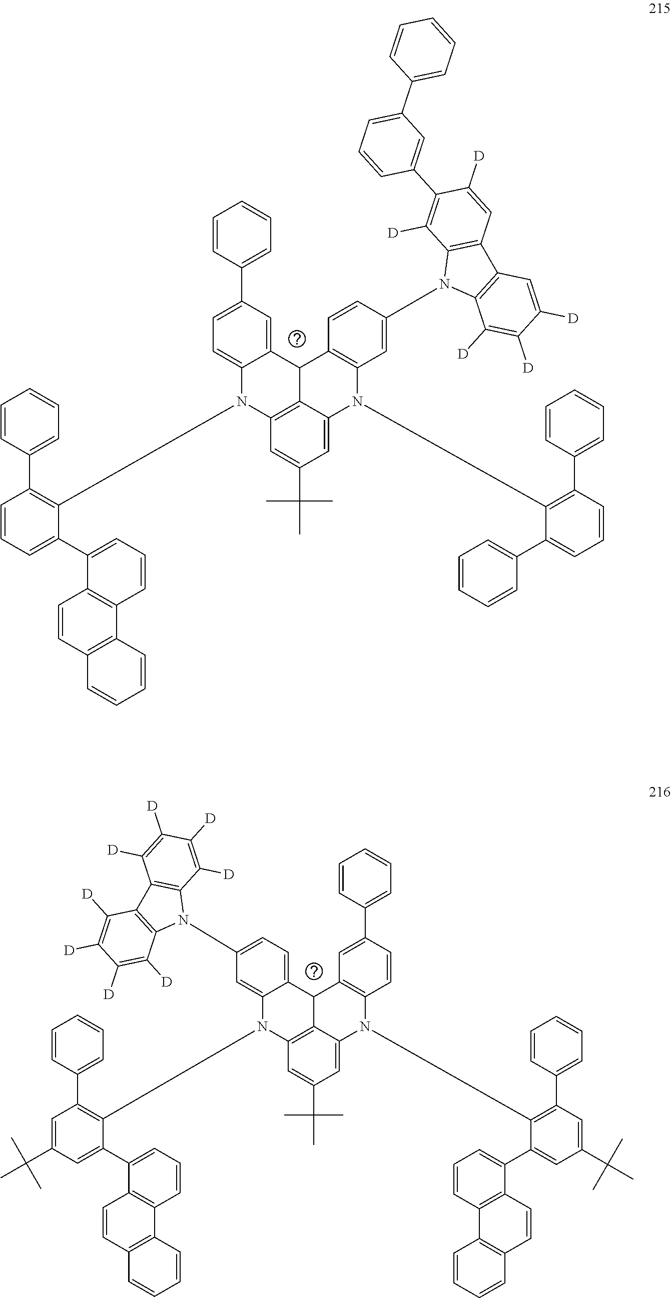 [SMILES: [2H]c1cc2c3cc([2H])c(-c4cccc(-c5ccccc5)c4)c([2H])c3n(-c3ccc4c(c3)N(c3c(-c5ccccc5)cccc3-c3ccccc3)c3cc(C(C)(C)C)cc5c3C4c3cc(-c4ccccc4)ccc3N5c3c(-c4ccccc4)cccc3-c3cccc4c3ccc3ccccc34)c2c([2H])c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3c1ccc1ccccc13)c1cc(C(C)(C)C)cc3c1C2c1cc(-c2ccccc2)ccc1N3c1c(-c2ccccc2)cc(C(C)(C)C)cc1-c1cccc2c1ccc1ccccc12] 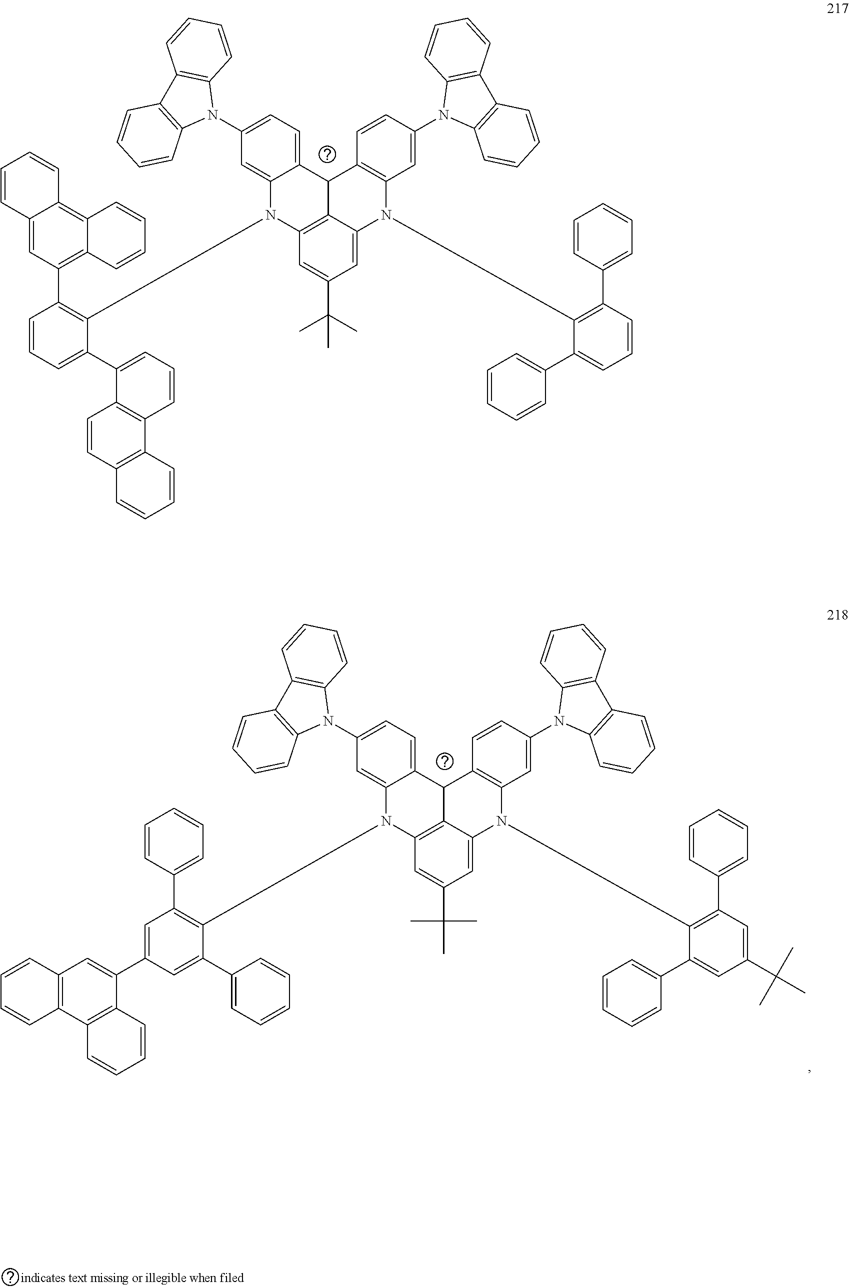 [SMILES: CC(C)(C)c1cc2c3c(c1)N(c1c(-c4cccc5c4ccc4ccccc45)cccc1-c1cc4ccccc4c4ccccc14)c1cc(-n4c5ccccc5c5ccccc54)ccc1C3c1ccc(-n3c4ccccc4c4ccccc43)cc1N2c1c(-c2ccccc2)cccc1-c1ccccc1 ; CC(C)(C)c1cc(-c2ccccc2)c(N2c3cc(-n4c5ccccc5c5ccccc54)ccc3C3c4ccc(-n5c6ccccc6c6ccccc65)cc4N(c4c(-c5ccccc5)cc(-c5cc6ccccc6c6ccccc56)cc4-c4ccccc4)c4cc(C(C)(C)C)cc2c43)c(-c2ccccc2)c1]
in Compound Group 1, D is a deuterium atom.

12. A polycyclic compound represented by Formula 1: 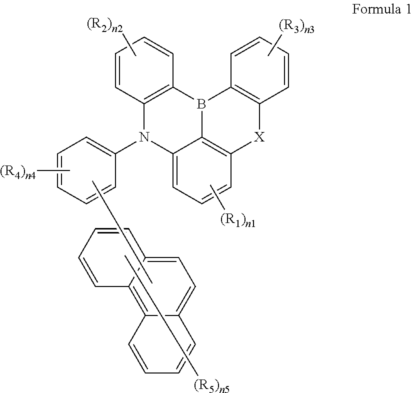
in Formula 1,
X is NR₆, S, O, or Se,
R₁ to R₅ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
R₆ is a substituted or unsubstituted aryl group having 6 to 30 ring-forming carbon atoms, or a substituted or unsubstituted heteroaryl group having 5 to 30 ring-forming carbon atoms,
n1 is an integer of 0 to 3,
n2 to n4 are each independently an integer of 0 to 4, and
n5 is an integer of 0 to 9.

13. The polycyclic compound of claim 12, wherein Formula 1 is represented by Formula 2: 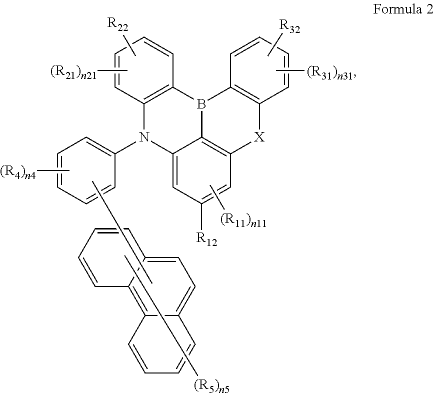
in Formula 2,
R₁₁, R₂₁, and R₃₁ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
R₁₂, R₂₂, and R₃₂ are each independently a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
n11 is an integer of 0 to 2,
n21 and n31 are each independently an integer of 0 to 3, and
X, R₄, R₅, n4, and n5 are as defined in Formula 1.

14. The polycyclic compound of claim 12, wherein Formula 1 is represented by Formula 3: 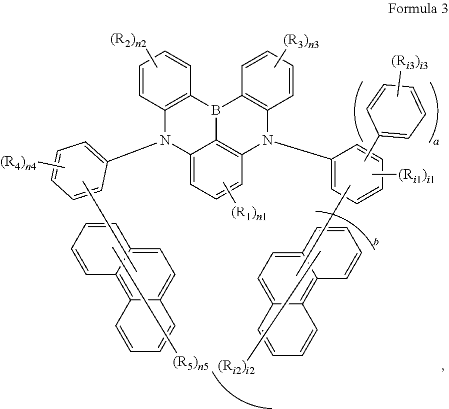
in Formula 3,
Rᵢ₁, Rᵢ₂, and Rᵢ₃ are each independently a hydrogen atom, a deuterium atom, a substituted or unsubstituted alkyl group having 1 to 20 carbon atoms, or a substituted or unsubstituted aryl group having 6 to 20 ring-forming carbon atoms,
i1 is an integer of 0 to 3,
i2 is an integer of 0 to 9,
i3 is an integer of 0 to 5,
a and b are each independently an integer of 0 to 2, and a+b equals 2 or 3, and
R₁ to R₅, and n1 to n5 are as defined in Formula 1.

15. The polycyclic compound of claim 12, wherein Formula 1 is represented by Formula 4: 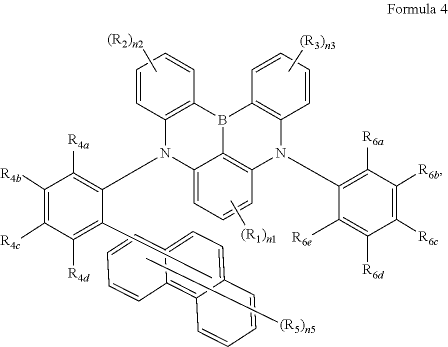
in Formula 4,
at least one selected from among R₄ₐ to R_{4d} and at least two selected from among R₆ₐ to R₆ₑ are each independently a substituted or unsubstituted phenyl group, or a substituted or unsubstituted phenanthryl group,
any remaining selected from among R₄ₐ to R_{4d}, and any remaining selected from among R₆ₐ to R₆ₑ are each independently a hydrogen atom, a deuterium atom, a substituted or unsubstituted alkyl group having 1 to 30 carbon atoms, a substituted or unsubstituted aryl group having 6 to 30 ring-forming carbon atoms, and
R₁ to R₃, R₅, n1 to n3, and n5 are as defined in Formula 1.

16. The polycyclic compound of claim 15, wherein R₄ₐ, R₆ₐ, and R₆ₑ are each independently a substituted or unsubstituted phenyl group, or a substituted or unsubstituted phenanthryl group, and
R_{4b} to R_{4d}, and R_{6b} to R_{6d} are each independently a hydrogen atom, a deuterium atom, a substituted or unsubstituted alkyl group having 1 to 30 carbon atoms, a substituted or unsubstituted aryl group having 6 to 30 ring-forming carbon atoms.

17. The polycyclic compound of claim 12, wherein R₁ to R₃ are each independently a hydrogen atom, a deuterium atom, or represented by any one selected from the substituents of Substituent Group 1:

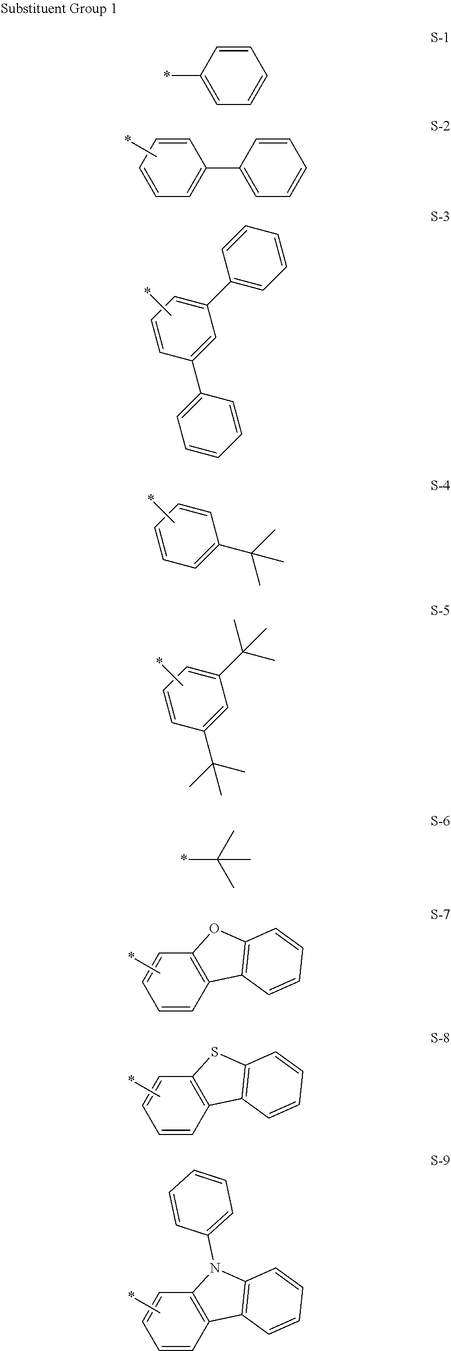

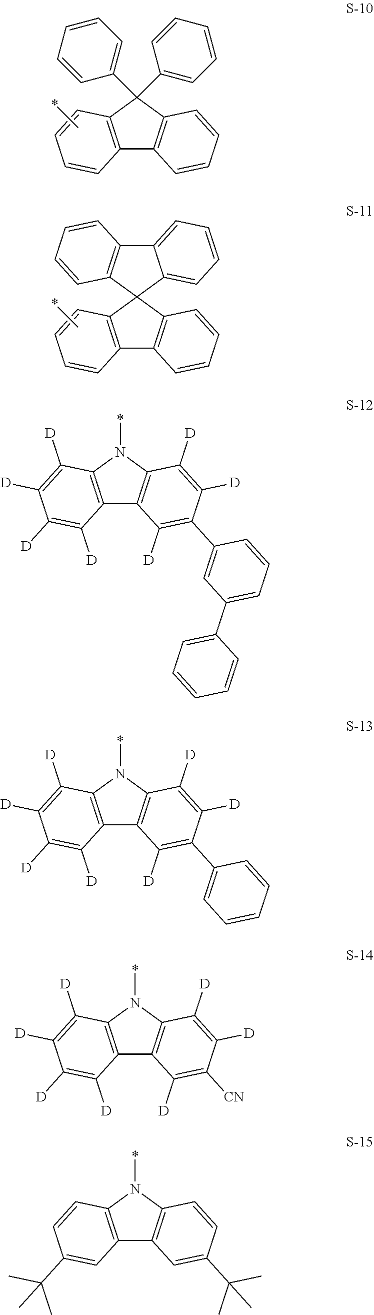

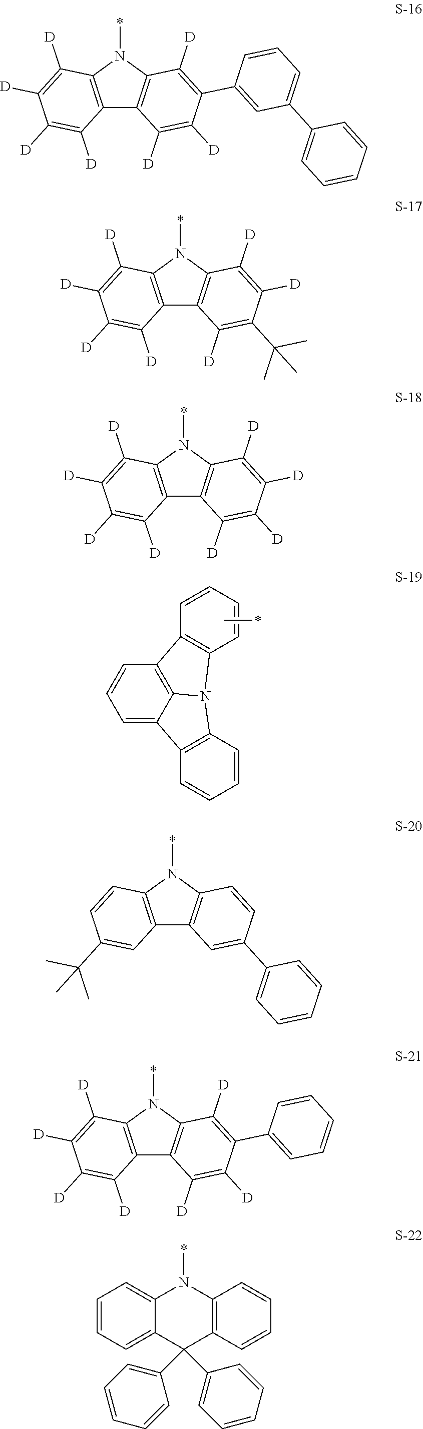

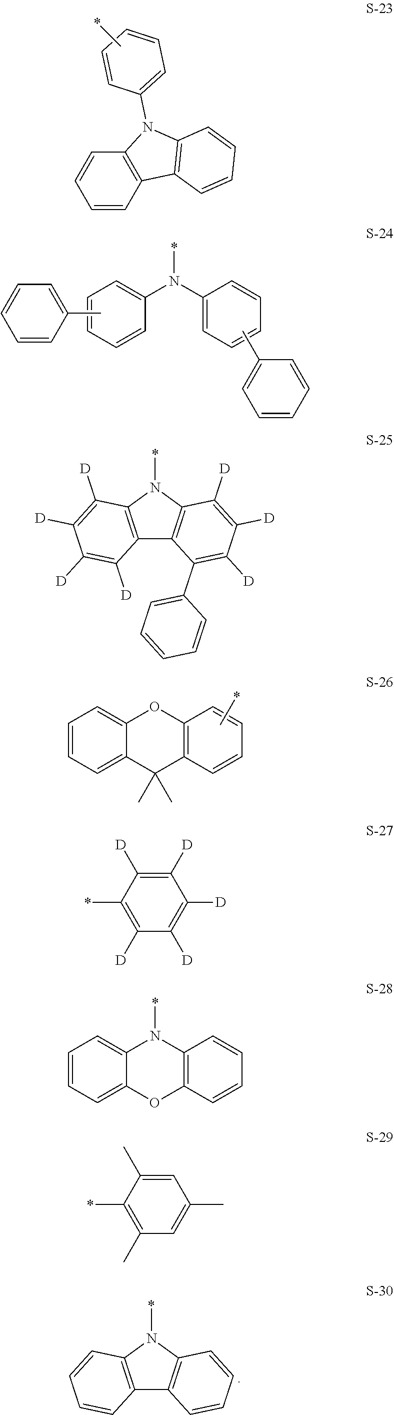

18. The polycyclic compound of claim 12, wherein the polycyclic compound represented by Formula 1 is any one selected from among the compounds of Compound Group 1: 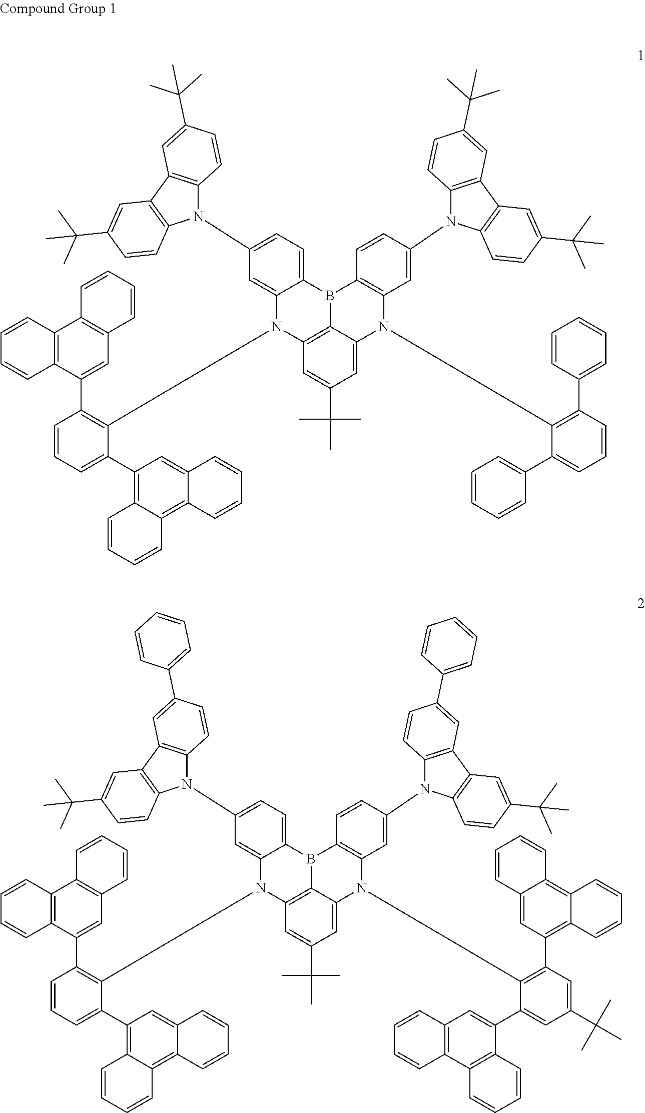 [SMILES: CC(C)(C)c1cc2c3c(c1)N(c1c(-c4cc5ccccc5c5ccccc45)cccc1-c1cc4ccccc4c4ccccc14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; CC(C)(C)c1cc(-c2cc3ccccc3c3ccccc23)c(N2c3cc(-n4c5ccc(-c6ccccc6)cc5c5cc(C(C)(C)C)ccc54)ccc3B3c4ccc(-n5c6ccc(-c7ccccc7)cc6c6cc(C(C)(C)C)ccc65)cc4N(c4c(-c5cc6ccccc6c6ccccc56)cccc4-c4cc5ccccc5c5ccccc45)c4cc(C(C)(C)C)cc2c43)c(-c2cc3ccccc3c3ccccc23)c1] 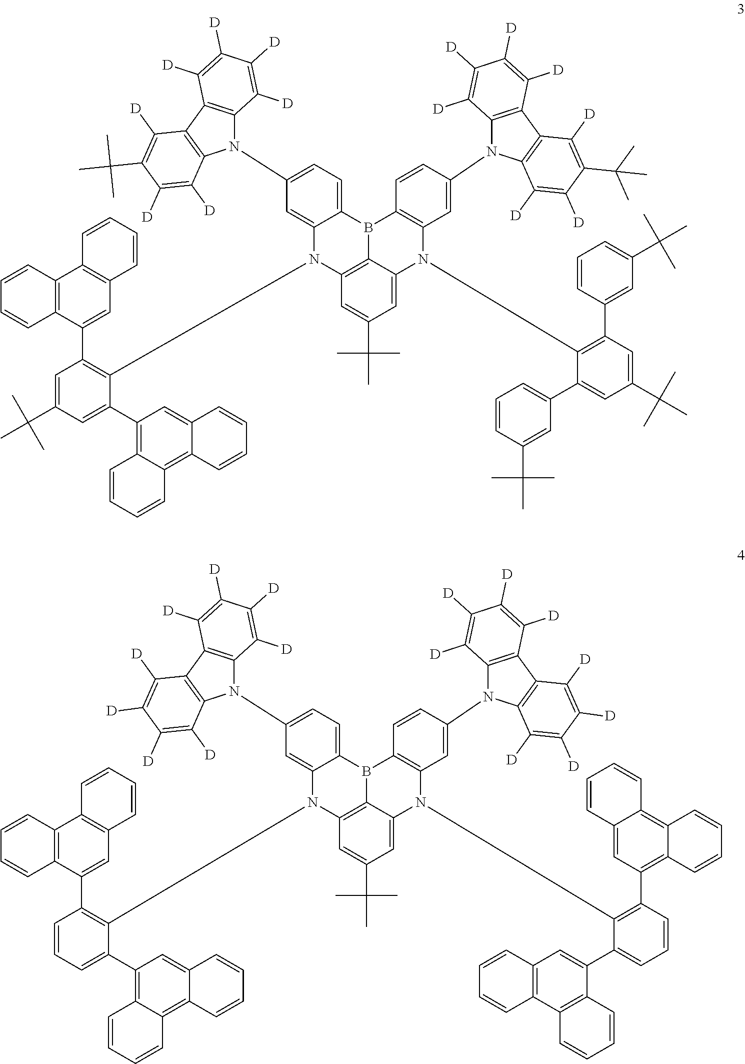 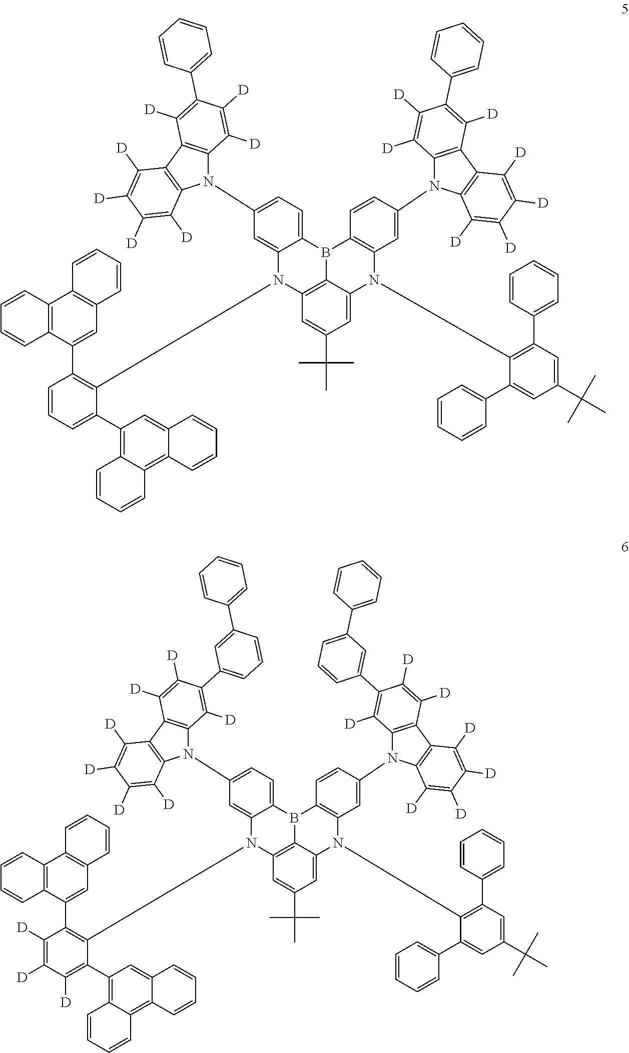 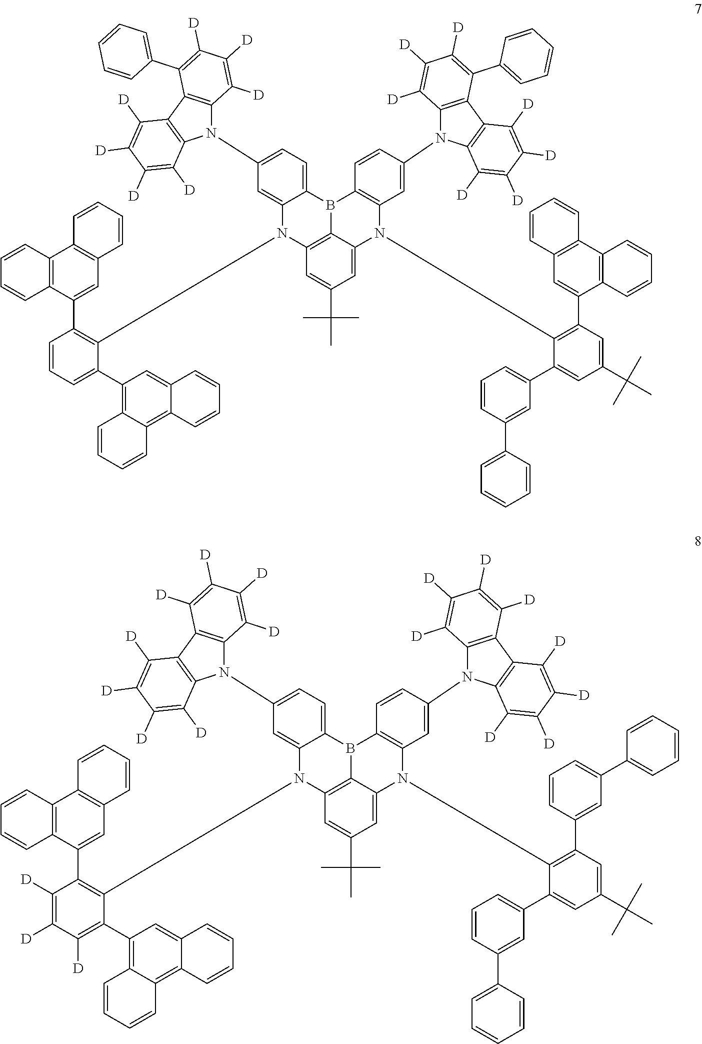 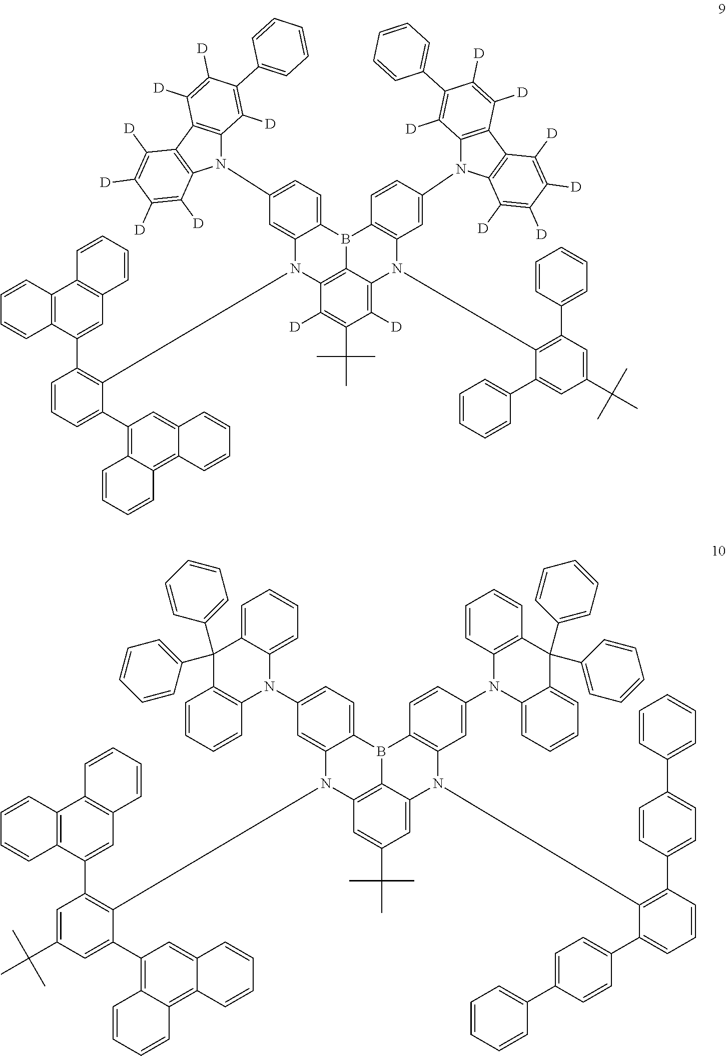 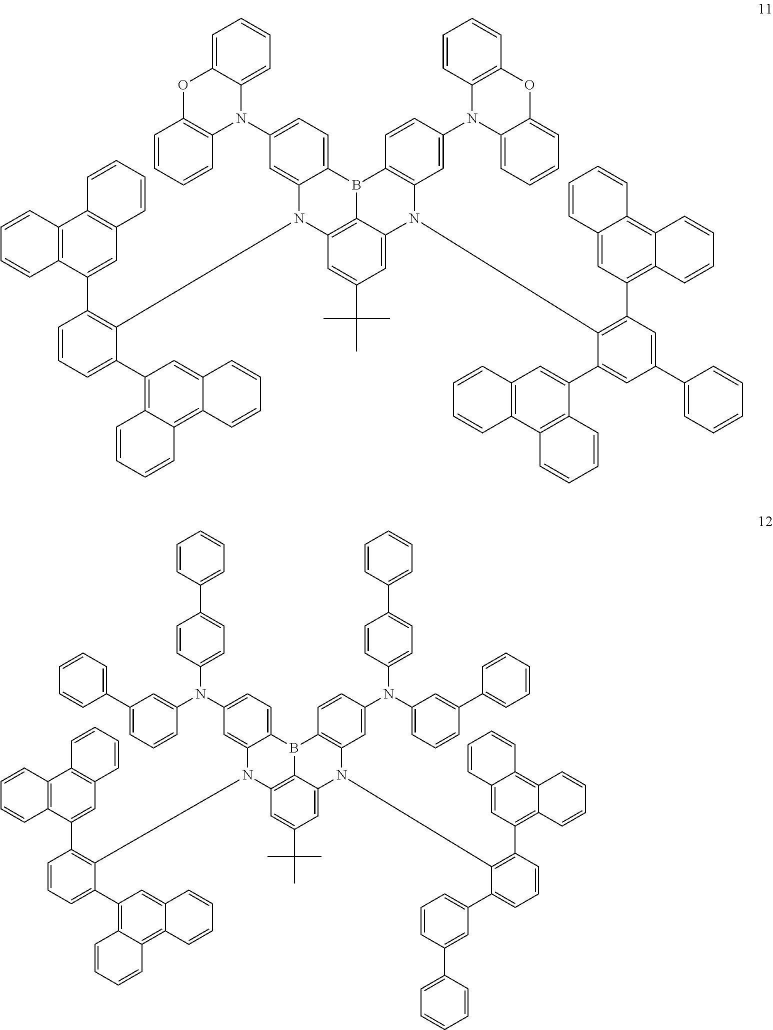 [SMILES: CC(C)(C)c1cc2c3c(c1)N(c1c(-c4cc5ccccc5c5ccccc45)cc(-c4ccccc4)cc1-c1cc4ccccc4c4ccccc14)c1cc(N4c5ccccc5Oc5ccccc54)ccc1B3c1ccc(N3c4ccccc4Oc4ccccc43)cc1N2c1c(-c2cc3ccccc3c3ccccc23)cccc1-c1cc2ccccc2c2ccccc12 ; CC(C)(C)c1cc2c3c(c1)N(c1c(-c4cc5ccccc5c5ccccc45)cccc1-c1cc4ccccc4c4ccccc14)c1cc(N(c4ccc(-c5ccccc5)cc4)c4cccc(-c5ccccc5)c4)ccc1B3c1ccc(N(c3ccc(-c4ccccc4)cc3)c3cccc(-c4ccccc4)c3)cc1N2c1c(-c2cccc(-c3ccccc3)c2)cccc1-c1cc2ccccc2c2ccccc12] 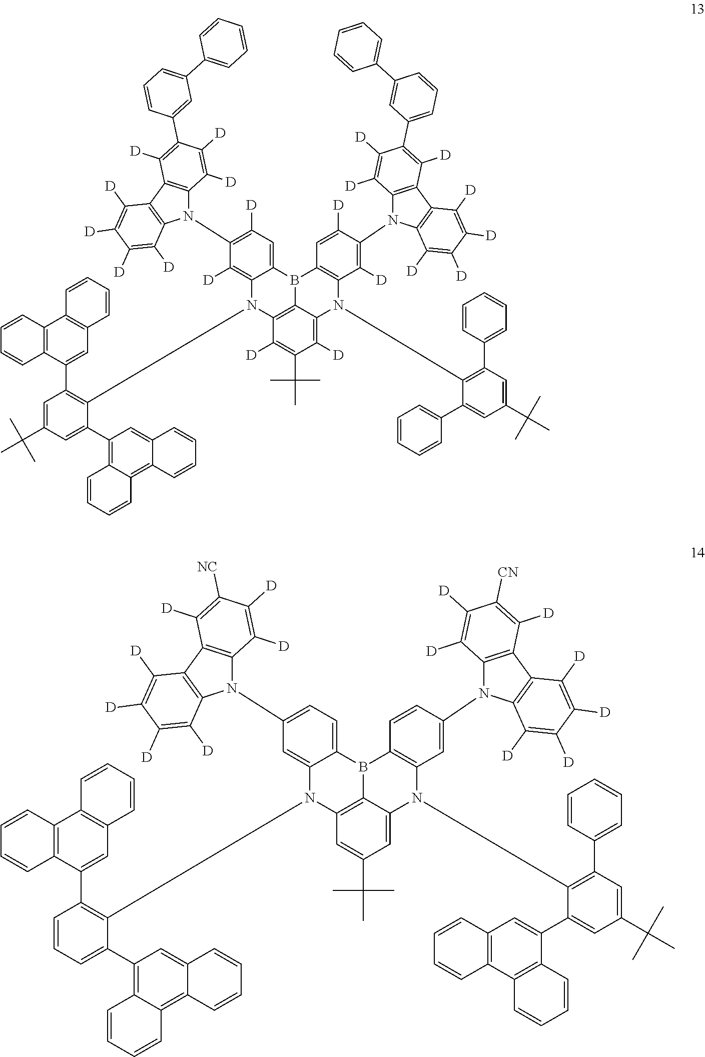 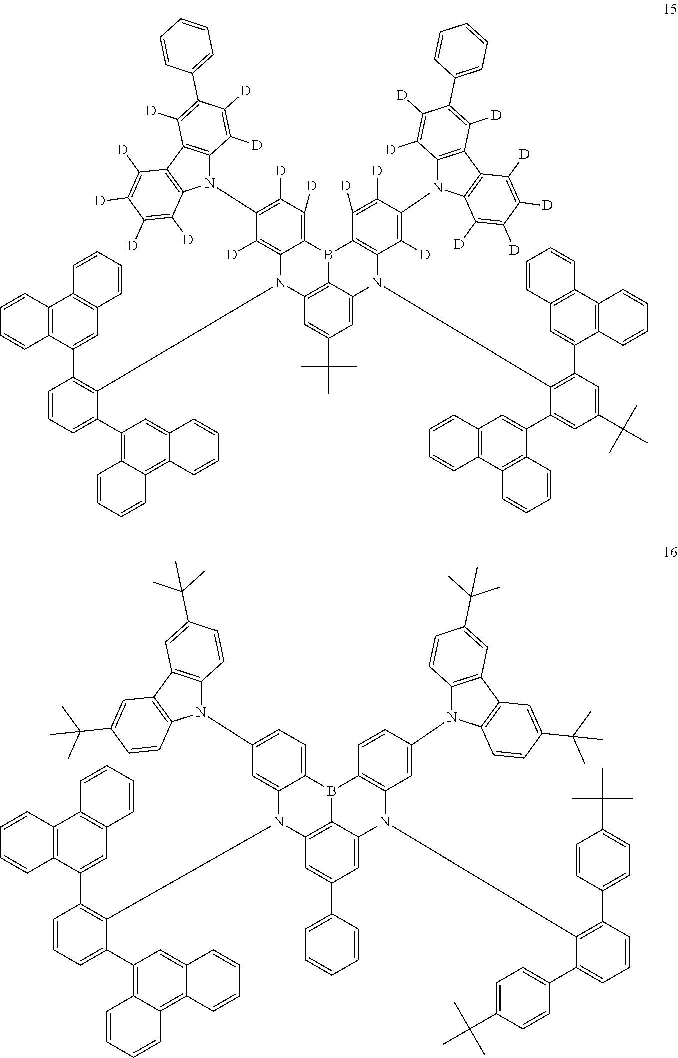 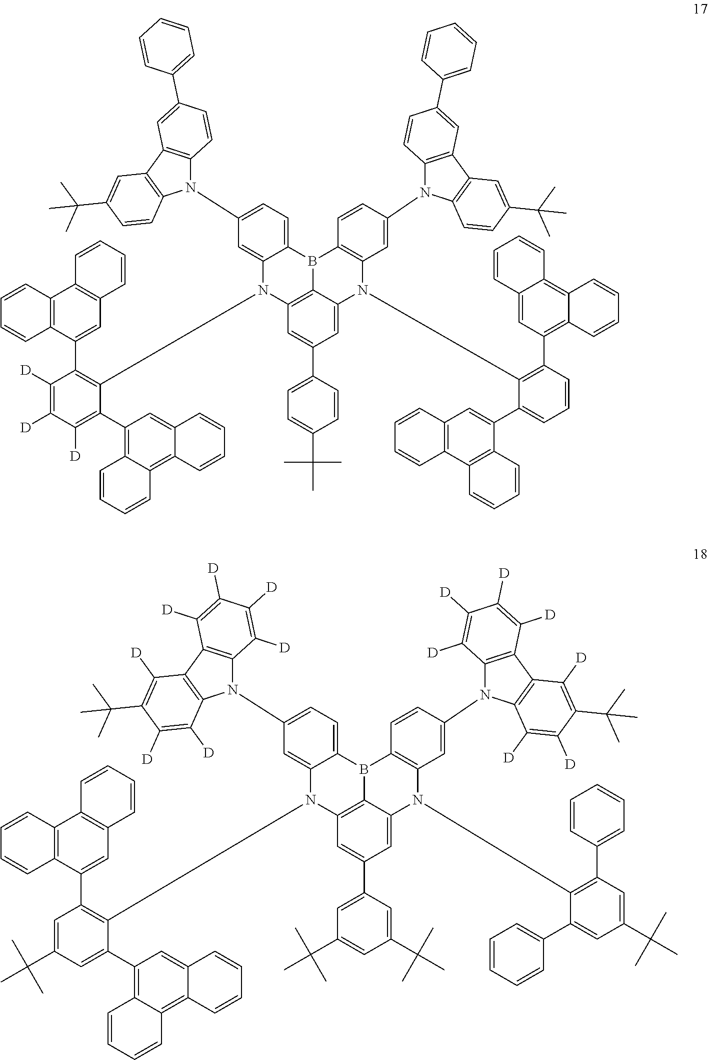 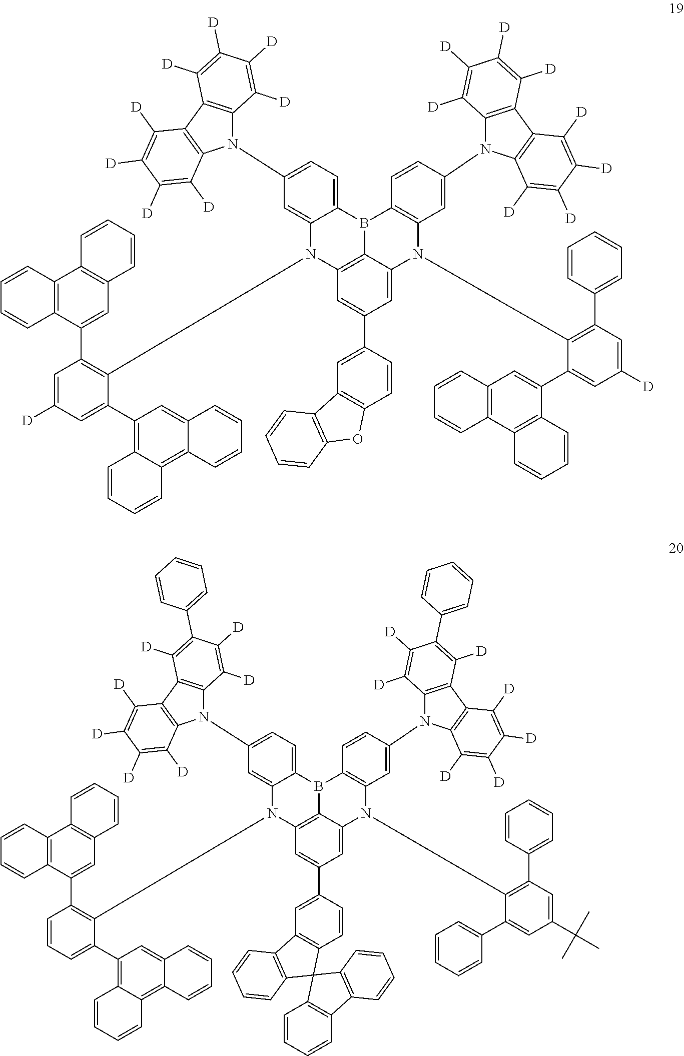 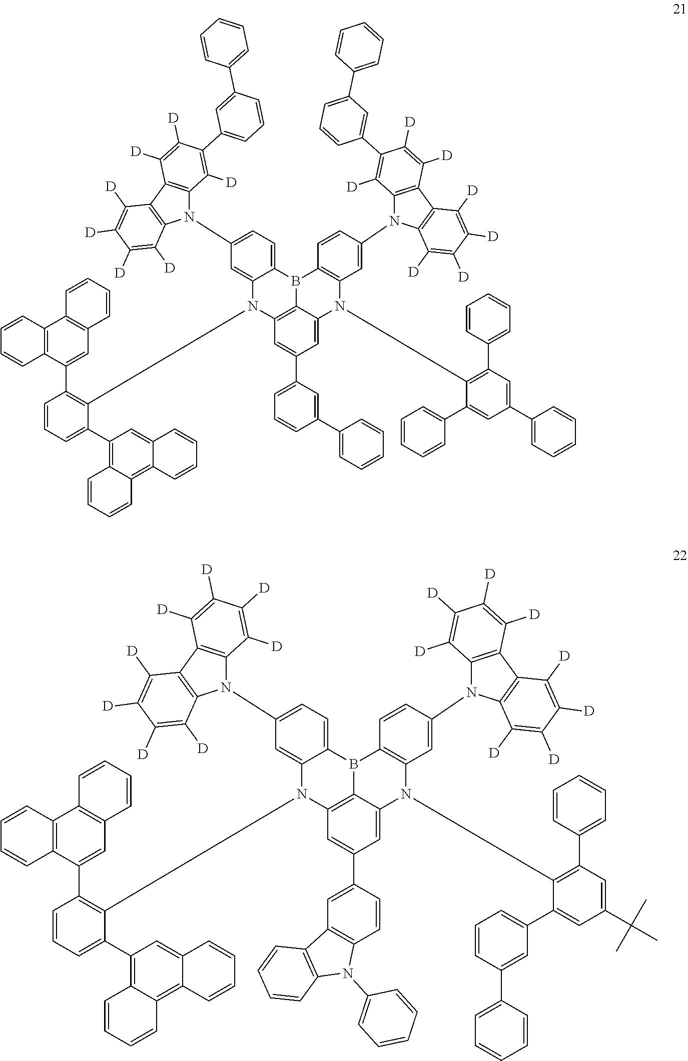 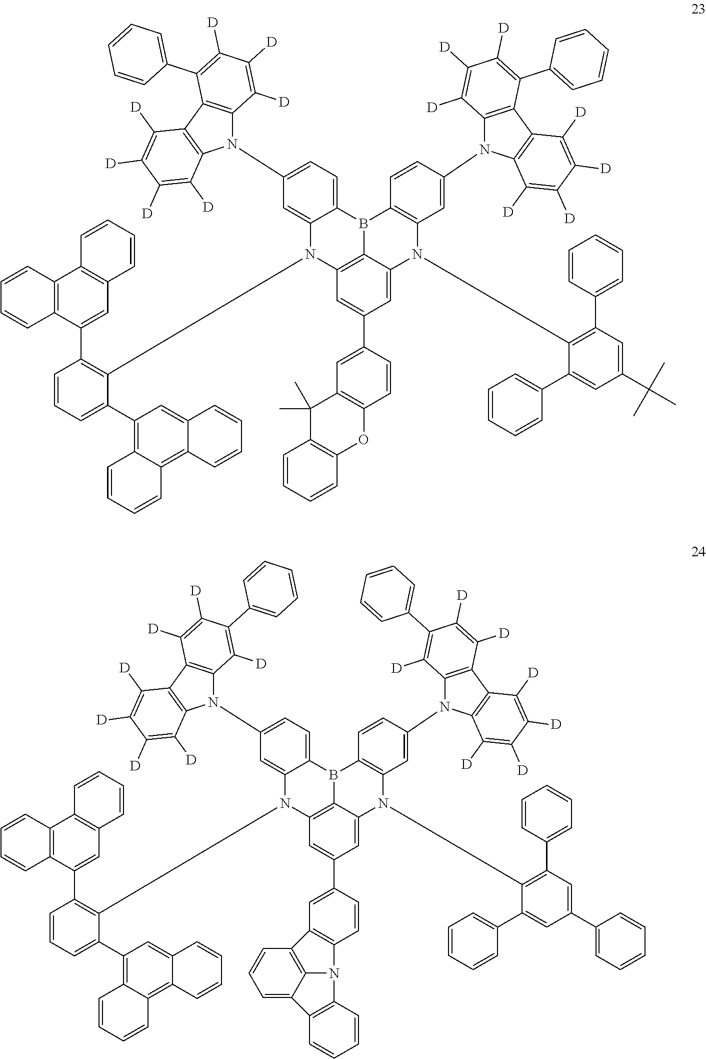 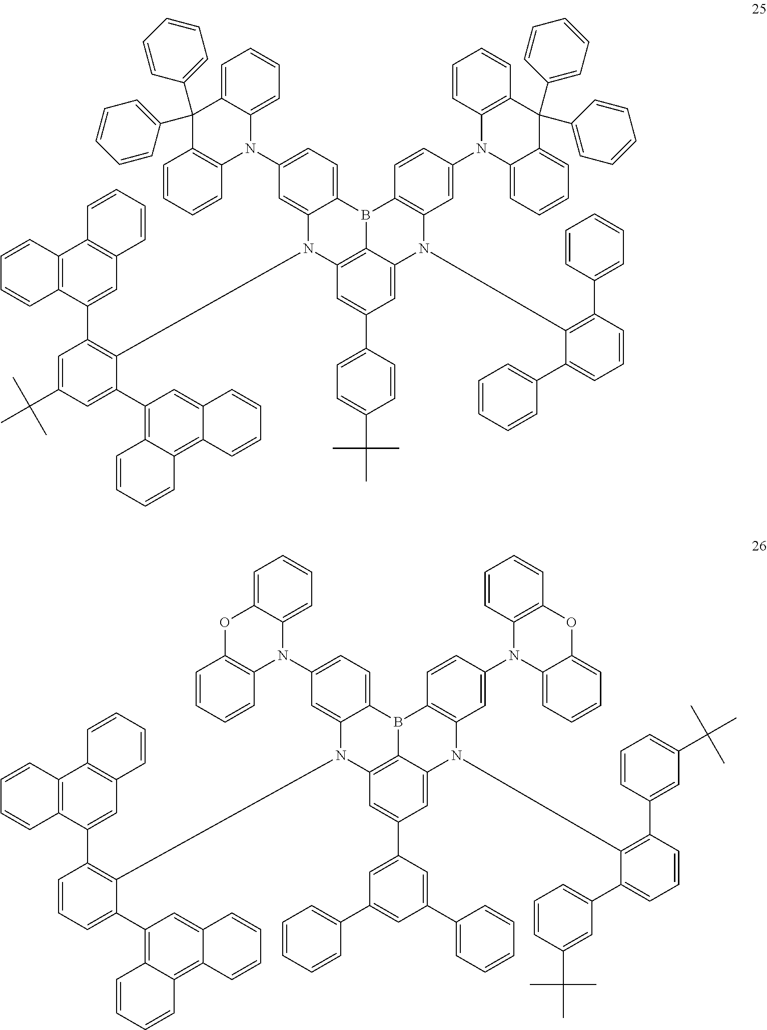 [SMILES: CC(C)(C)c1ccc(-c2cc3c4c(c2)N(c2c(-c5cc6ccccc6c6ccccc56)cc(C(C)(C)C)cc2-c2cc5ccccc5c5ccccc25)c2cc(N5c6ccccc6C(c6ccccc6)(c6ccccc6)c6ccccc65)ccc2B4c2ccc(N4c5ccccc5C(c5ccccc5)(c5ccccc5)c5ccccc54)cc2N3c2c(-c3ccccc3)cccc2-c2ccccc2)cc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5cc6ccccc6c6ccccc56)cccc4-c4cc5ccccc5c5ccccc45)c4cc(-c5cc(-c6ccccc6)cc(-c6ccccc6)c5)cc2c43)c1] 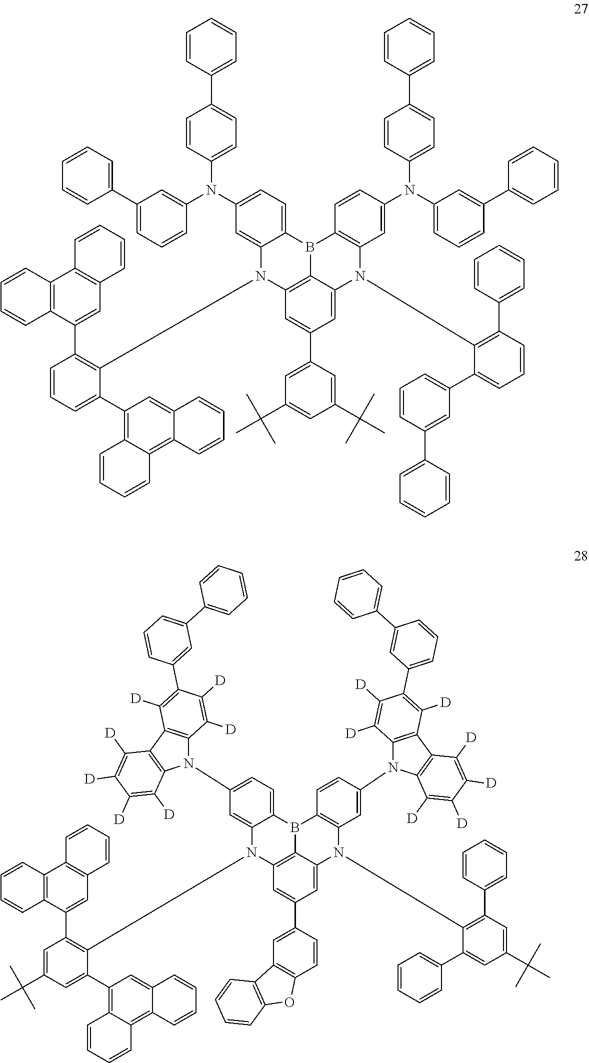 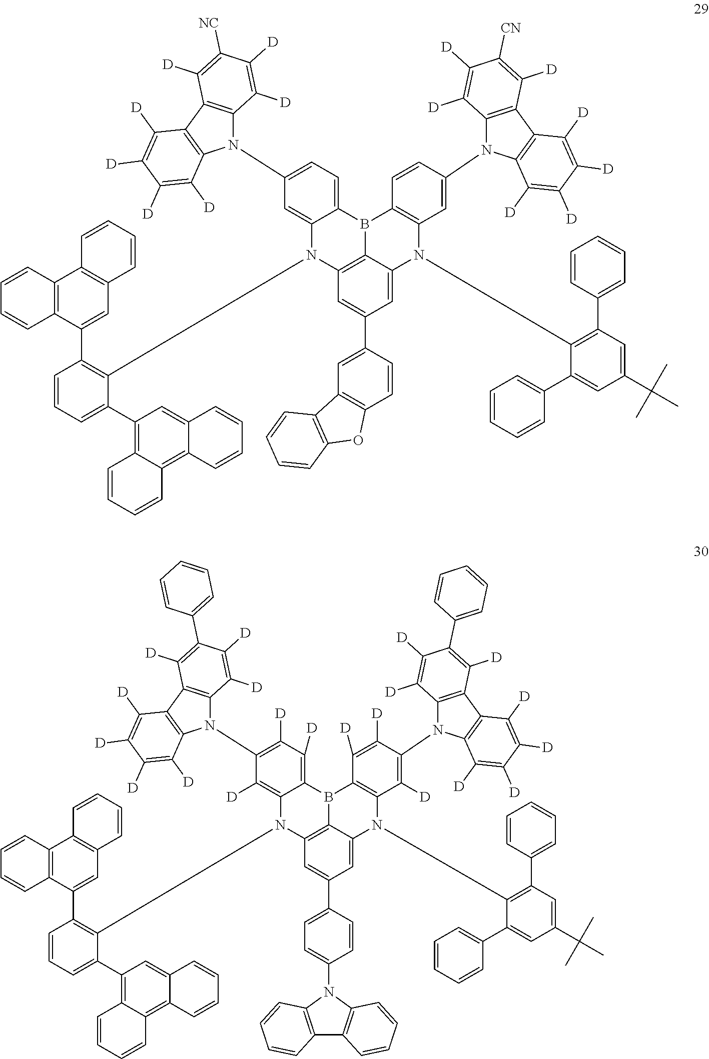 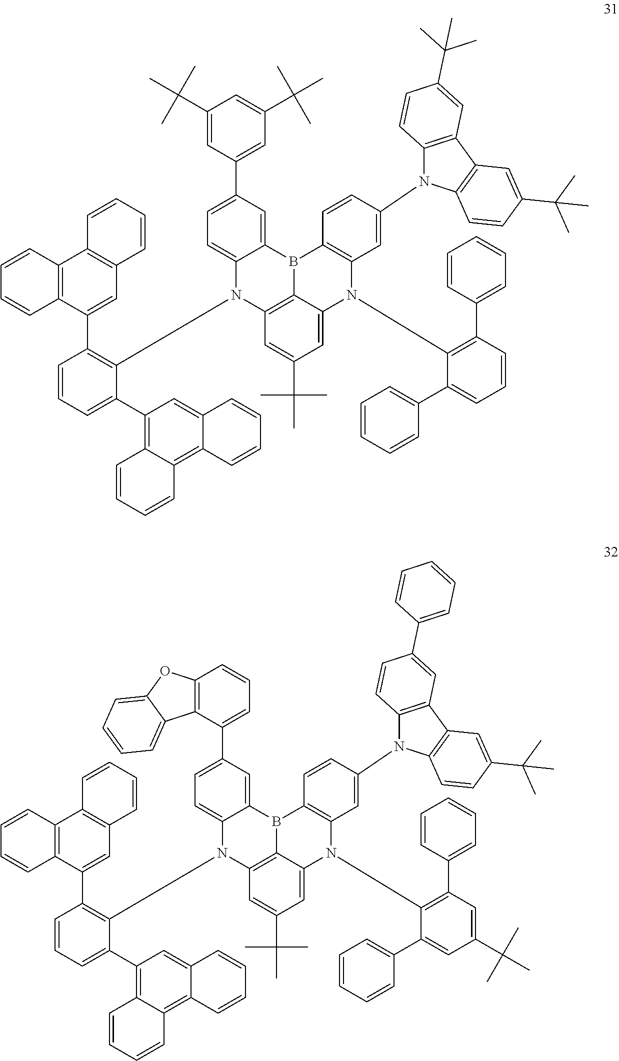 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cccc4-c4ccccc4)c4cc(C(C)(C)C)cc(c42)N3c2c(-c3cc4ccccc4c4ccccc34)cccc2-c2cc3ccccc3c3ccccc23)cc(C(C)(C)C)c1 ; CC(C)(C)c1cc(-c2ccccc2)c(N2c3cc(-n4c5ccc(-c6ccccc6)cc5c5cc(C(C)(C)C)ccc54)ccc3B3c4cc(-c5cccc6oc7ccccc7c56)ccc4N(c4c(-c5cc6ccccc6c6ccccc56)cccc4-c4cc5ccccc5c5ccccc45)c4cc(C(C)(C)C)cc2c43)c(-c2ccccc2)c1] 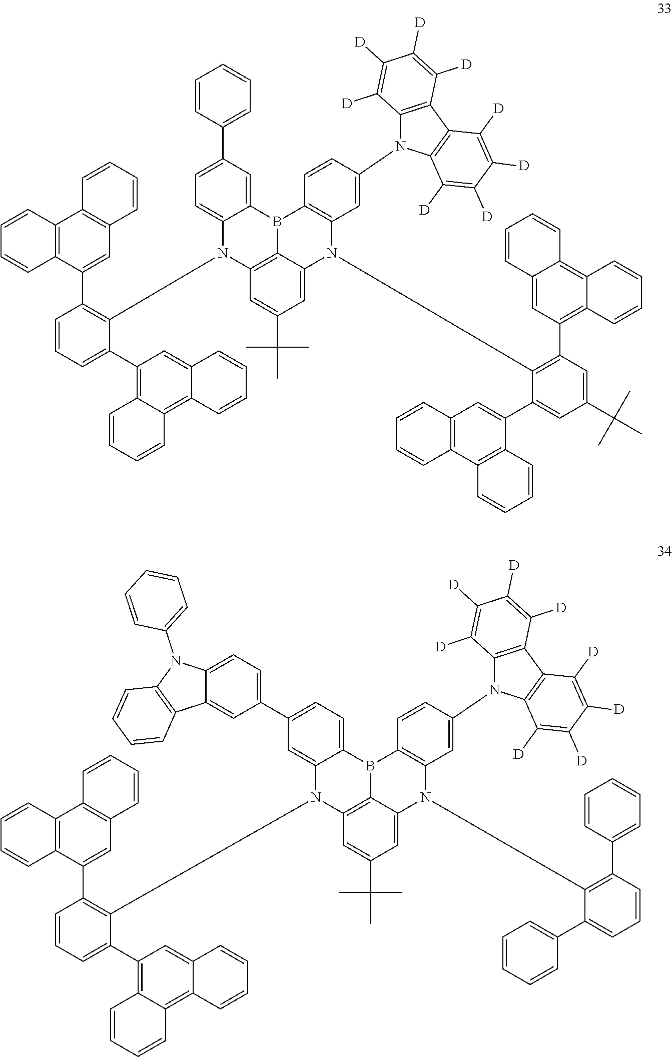 [SMILES: [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cc(C(C)(C)C)cc1-c1cc3ccccc3c3ccccc13)c1cc(C(C)(C)C)cc3c1B2c1cc(-c2ccccc2)ccc1N3c1c(-c2cc3ccccc3c3ccccc23)cccc1-c1cc2ccccc2c2ccccc12 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2cc3ccccc3c3ccccc23)cccc1-c1cc2ccccc2c2ccccc12] 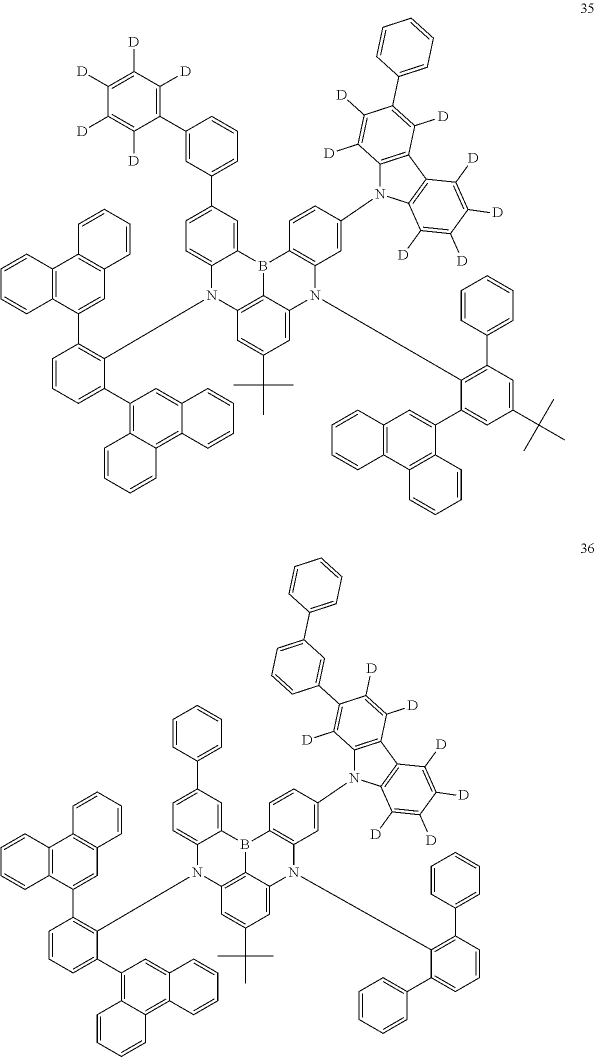 [SMILES: [2H]c1c([2H])c([2H])c(-c2cccc(-c3ccc4c(c3)B3c5ccc(-n6c7c([2H])c([2H])c([2H])c([2H])c7c7c([2H])c(-c8ccccc8)c([2H])c([2H])c76)cc5N(c5c(-c6ccccc6)cc(C(C)(C)C)cc5-c5cc6ccccc6c6ccccc56)c5cc(C(C)(C)C)cc(c53)N4c3c(-c4cc5ccccc5c5ccccc45)cccc3-c3cc4ccccc4c4ccccc34)c2)c([2H])c1[2H] ; [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2cc3ccccc3c3ccccc23)cccc1-c1cc2ccccc2c2ccccc12] 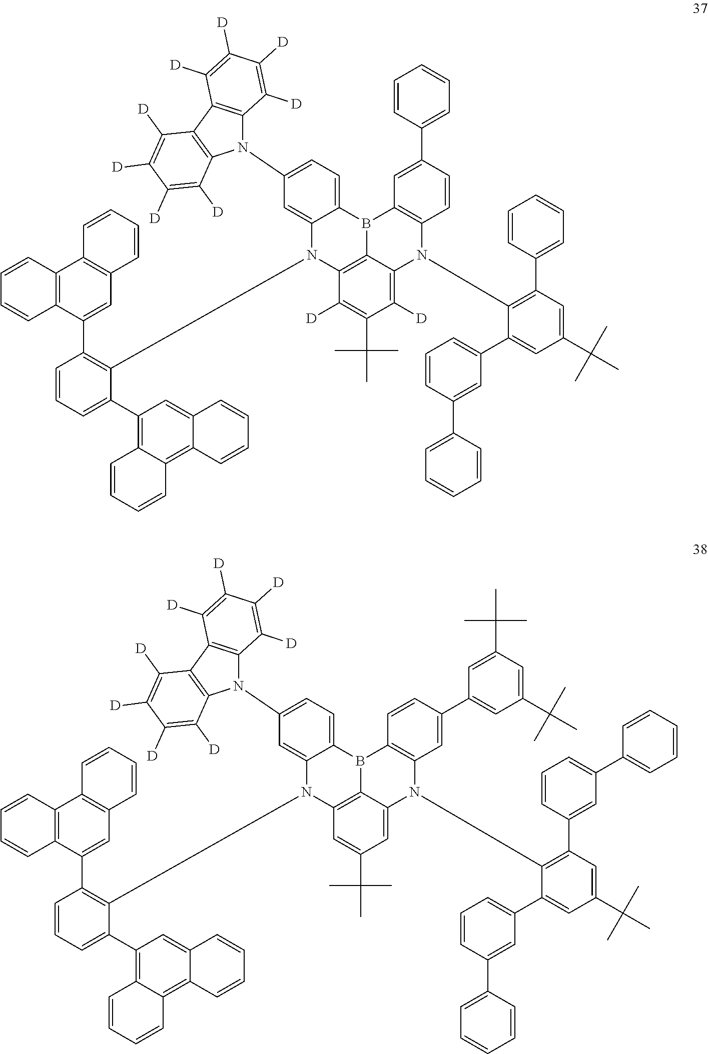 [SMILES: [2H]c1c2c3c(c([2H])c1C(C)(C)C)N(c1c(-c4cc5ccccc5c5ccccc45)cccc1-c1cc4ccccc4c4ccccc14)c1cc(-n4c5c([2H])c([2H])c([2H])c([2H])c5c5c([2H])c([2H])c([2H])c([2H])c54)ccc1B3c1cc(-c3ccccc3)ccc1N2c1c(-c2ccccc2)cc(C(C)(C)C)cc1-c1cccc(-c2ccccc2)c1 ; [2H]c1c([2H])c([2H])c2c(c1[2H])c1c([2H])c([2H])c([2H])c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1] 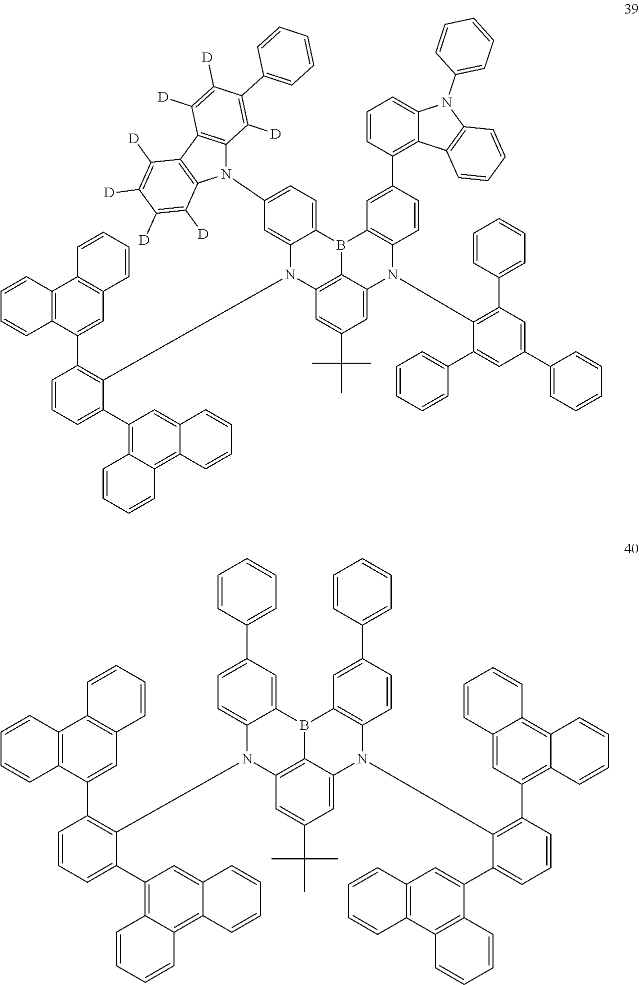 [SMILES: [2H]c1c([2H])c([2H])c2c(c1[2H])c1c([2H])c([2H])c(-c3ccccc3)c([2H])c1n2-c1ccc2c(c1)N(c1c(-c3cc4ccccc4c4ccccc34)cccc1-c1cc3ccccc3c3ccccc13)c1cc(C(C)(C)C)cc3c1B2c1cc(-c2cccc4c2c2ccccc2n4-c2ccccc2)ccc1N3c1c(-c2ccccc2)cc(-c2ccccc2)cc1-c1ccccc1 ; CC(C)(C)c1cc2c3c(c1)N(c1c(-c4cc5ccccc5c5ccccc45)cccc1-c1cc4ccccc4c4ccccc14)c1ccc(-c4ccccc4)cc1B3c1cc(-c3ccccc3)ccc1N2c1c(-c2cc3ccccc3c3ccccc23)cccc1-c1cc2ccccc2c2ccccc12] 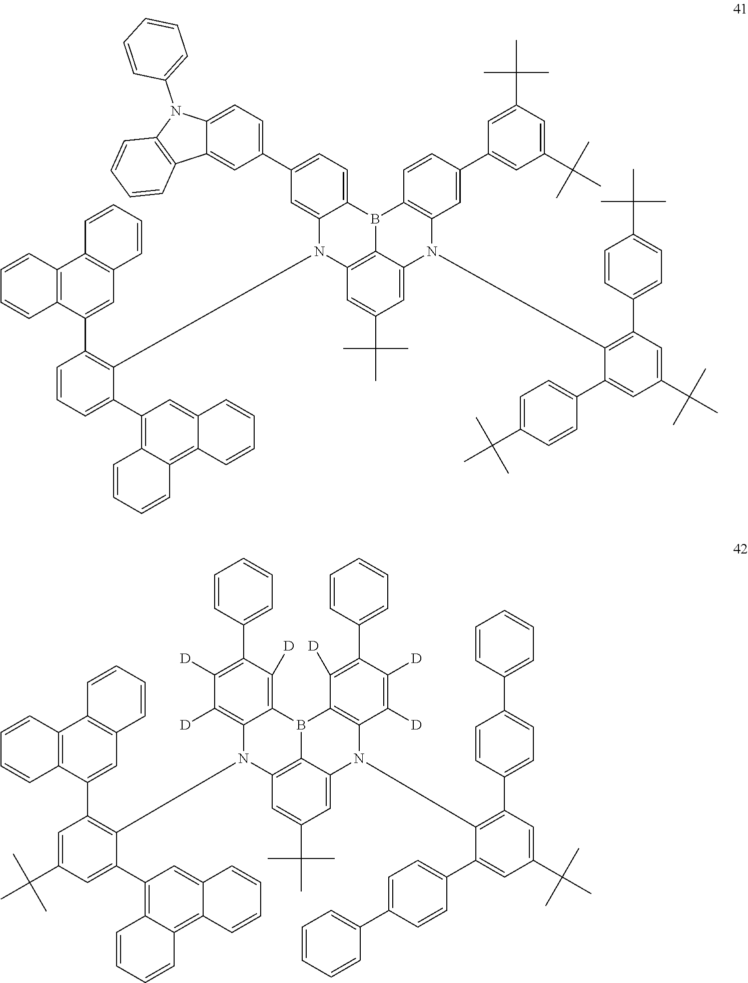 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-c5ccc6c(c5)c5ccccc5n6-c5ccccc5)cc4N(c4c(-c5cc6ccccc6c6ccccc56)cccc4-c4cc5ccccc5c5ccccc45)c4cc(C(C)(C)C)cc2c43)cc1 ; [2H]c1c([2H])c2c(c([2H])c1-c1ccccc1)B1c3c(cc(C(C)(C)C)cc3N(c3c(-c4cc5ccccc5c5ccccc45)cc(C(C)(C)C)cc3-c3cc4ccccc4c4ccccc34)c3c([2H])c([2H])c(-c4ccccc4)c([2H])c31)N2c1c(-c2ccc(-c3ccccc3)cc2)cc(C(C)(C)C)cc1-c1ccc(-c2ccccc2)cc1] 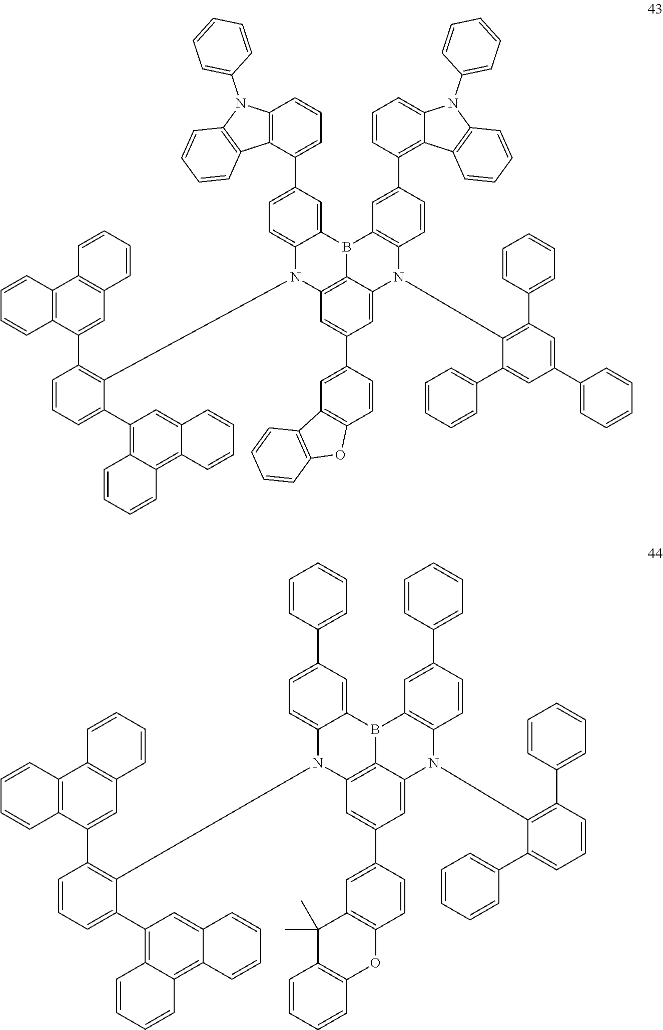 [SMILES: c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6cc7ccccc7c7ccccc67)cccc5-c5cc6ccccc6c6ccccc56)c5cc(-c6ccc7oc8ccccc8c7c6)cc3c54)c(-c3ccccc3)c2)cc1 ; CC1(C)c2ccccc2Oc2ccc(-c3cc4c5c(c3)N(c3c(-c6cc7ccccc7c7ccccc67)cccc3-c3cc6ccccc6c6ccccc36)c3ccc(-c6ccccc6)cc3B5c3cc(-c5ccccc5)ccc3N4c3c(-c4ccccc4)cccc3-c3ccccc3)cc21] 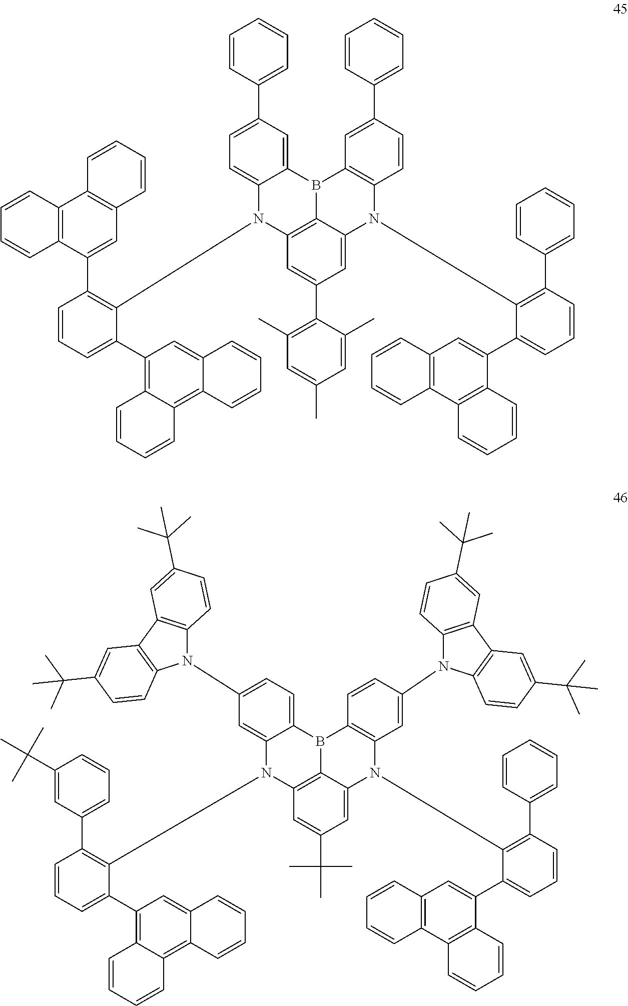 [SMILES: Cc1cc(C)c(-c2cc3c4c(c2)N(c2c(-c5cc6ccccc6c6ccccc56)cccc2-c2cc5ccccc5c5ccccc25)c2ccc(-c5ccccc5)cc2B4c2cc(-c4ccccc4)ccc2N3c2c(-c3ccccc3)cccc2-c2cc3ccccc3c3ccccc23)c(C)c1 ; CC(C)(C)c1cccc(-c2cccc(-c3cc4ccccc4c4ccccc34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cccc4-c4cc5ccccc5c5ccccc45)c4cc(C(C)(C)C)cc2c43)c1] 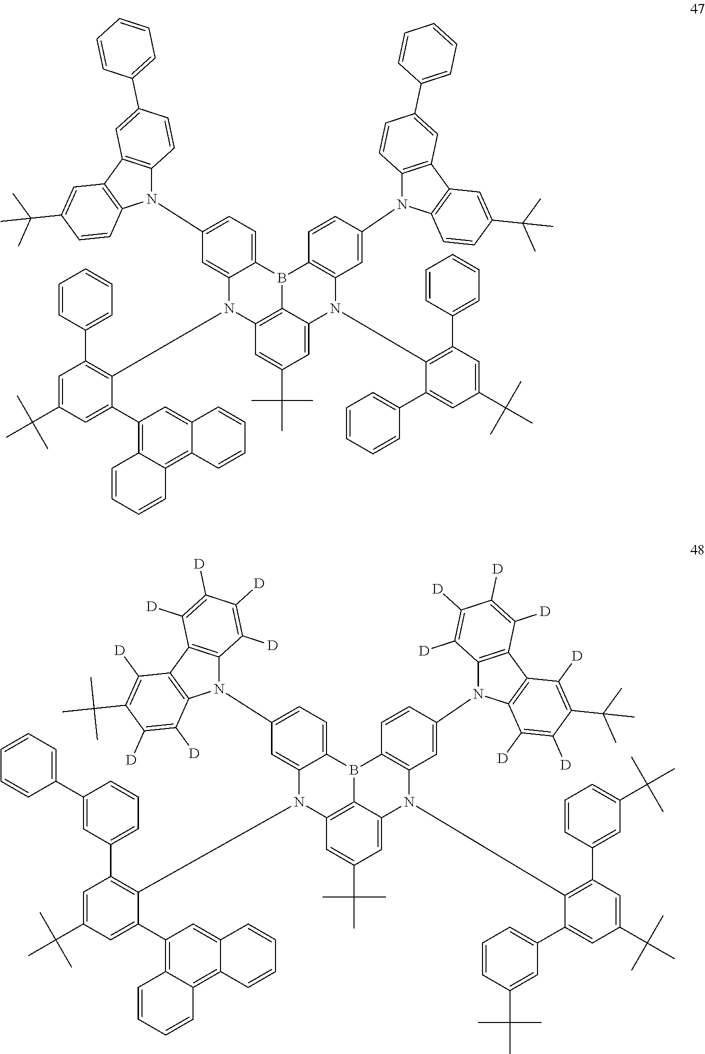 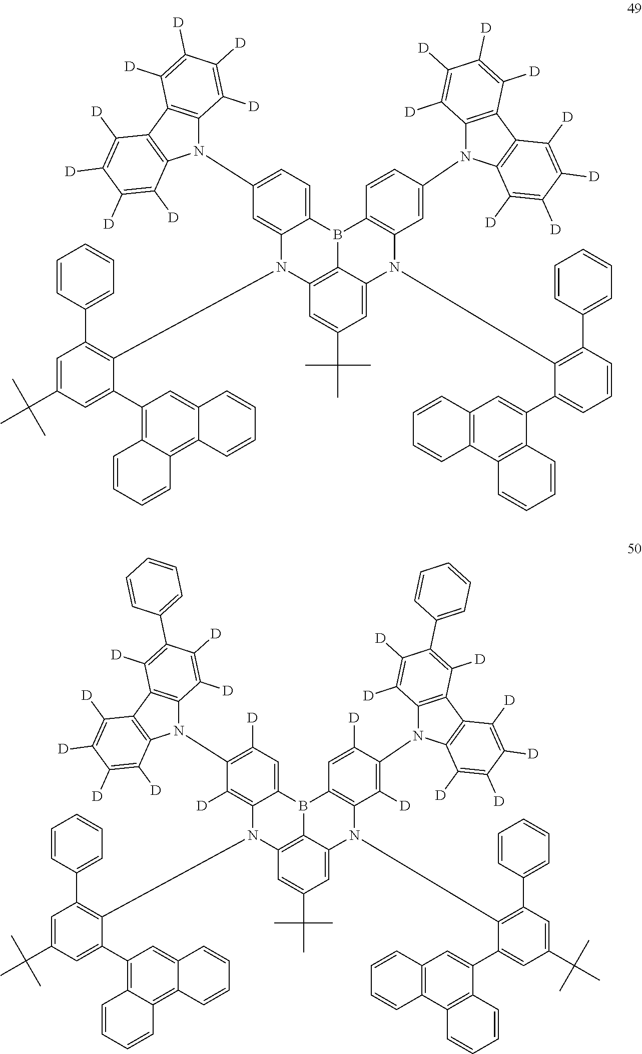 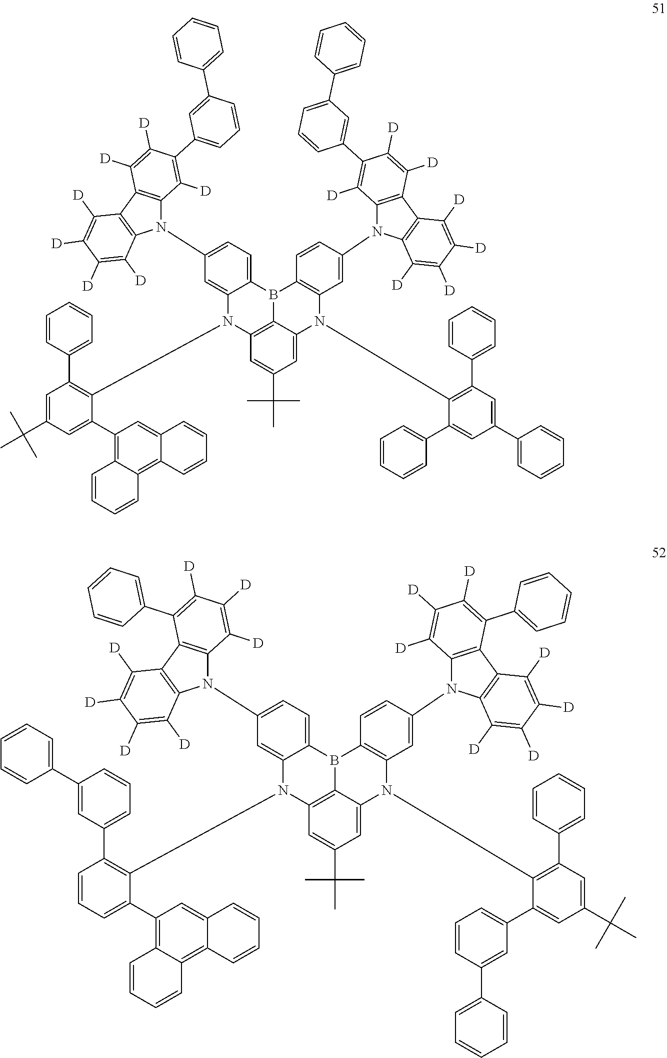 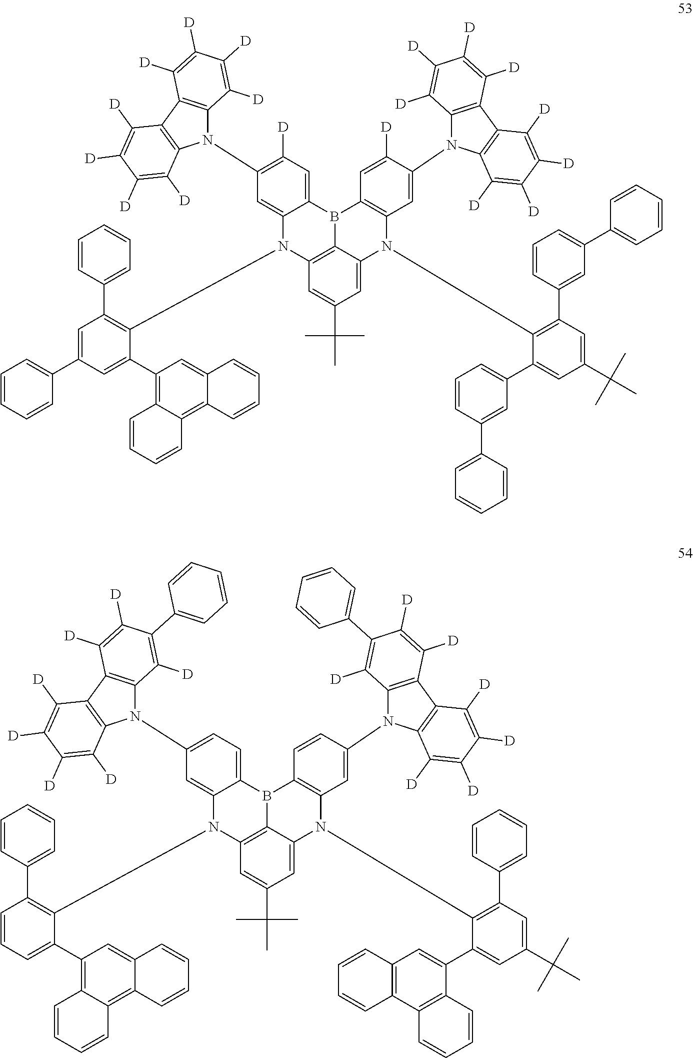 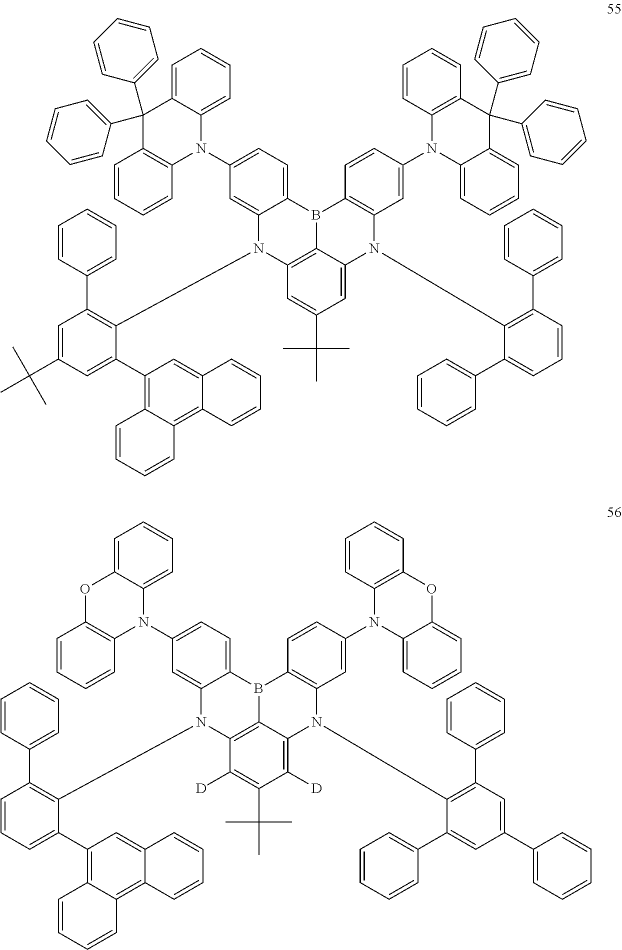 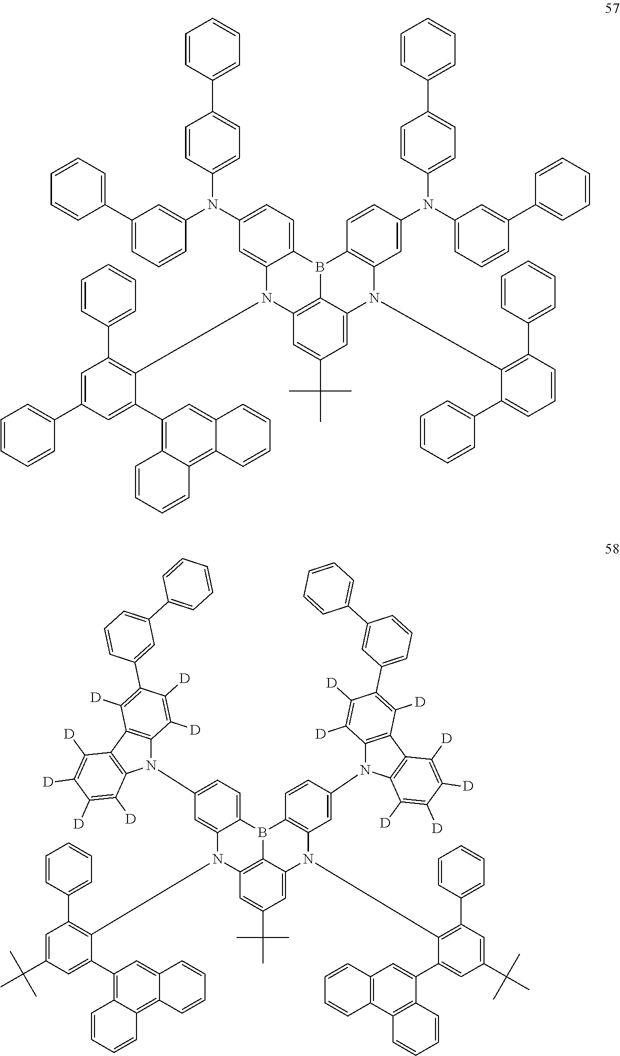 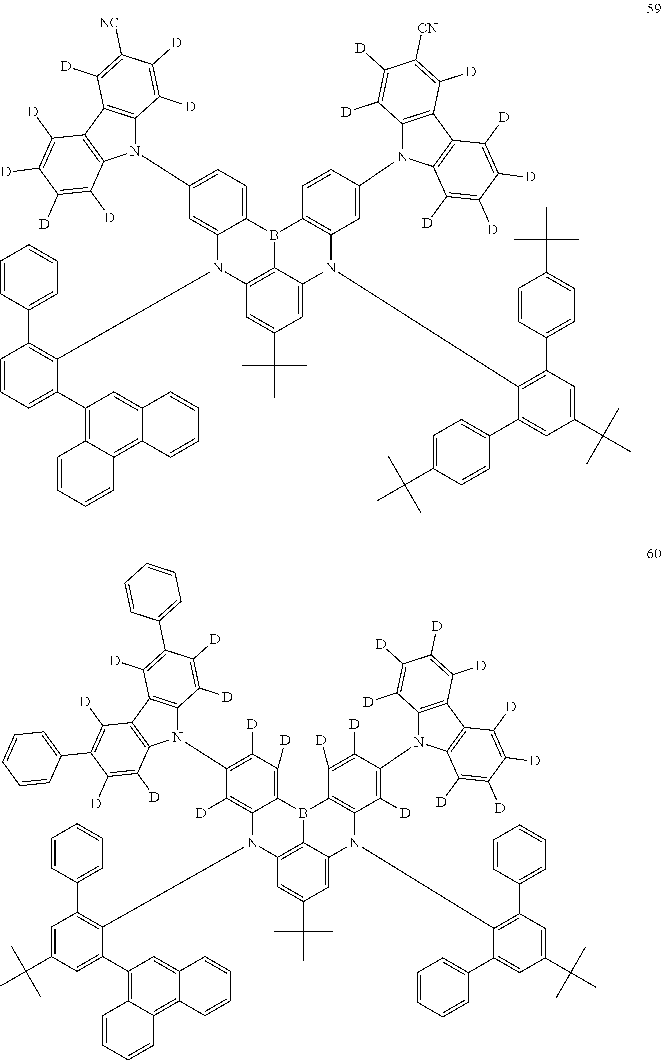 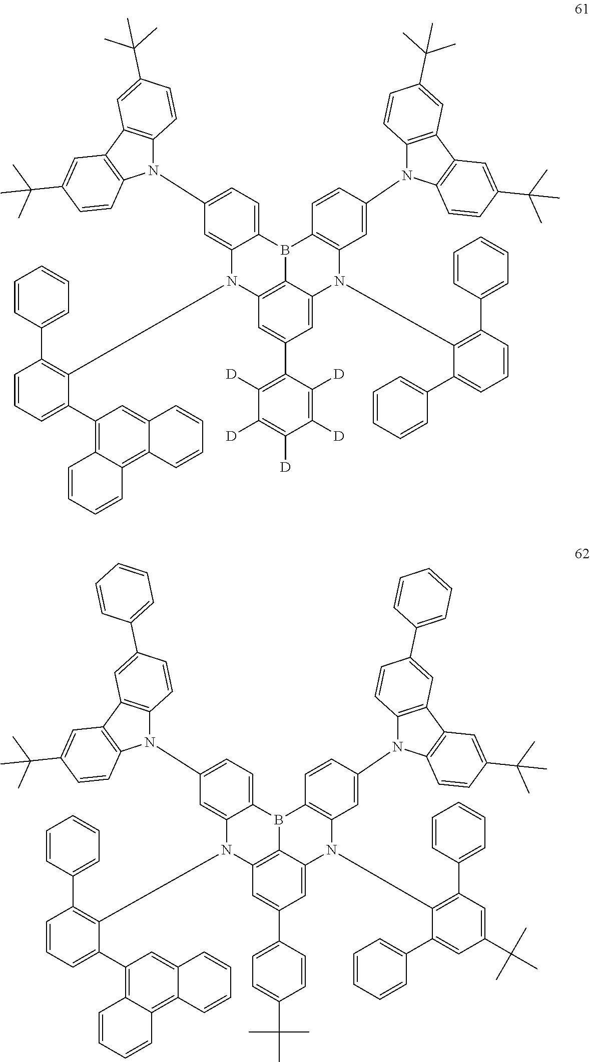 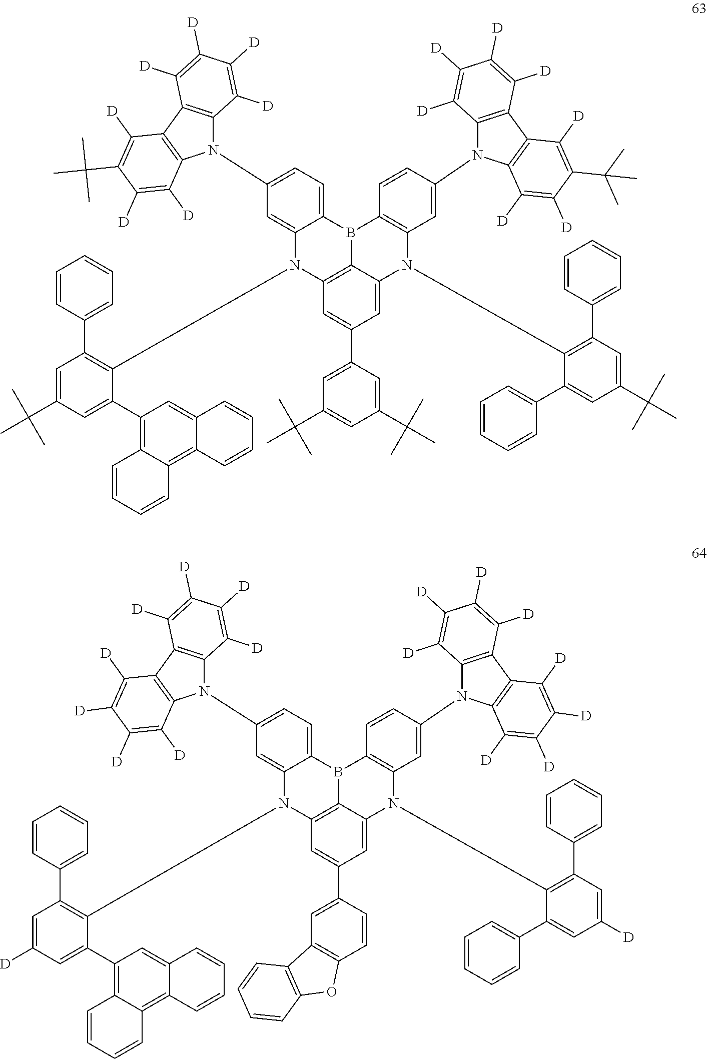 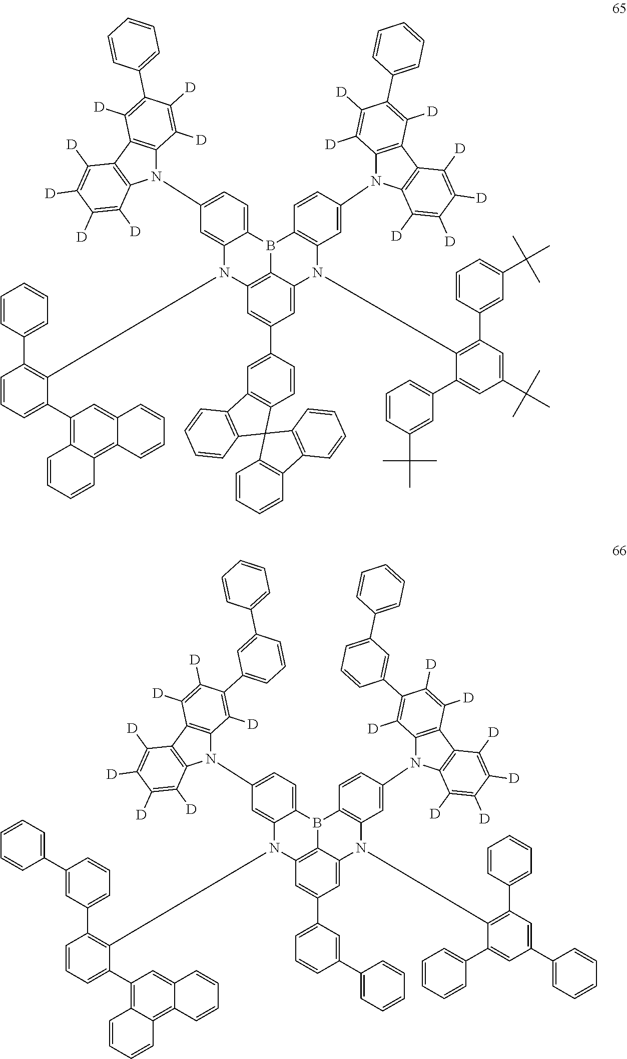 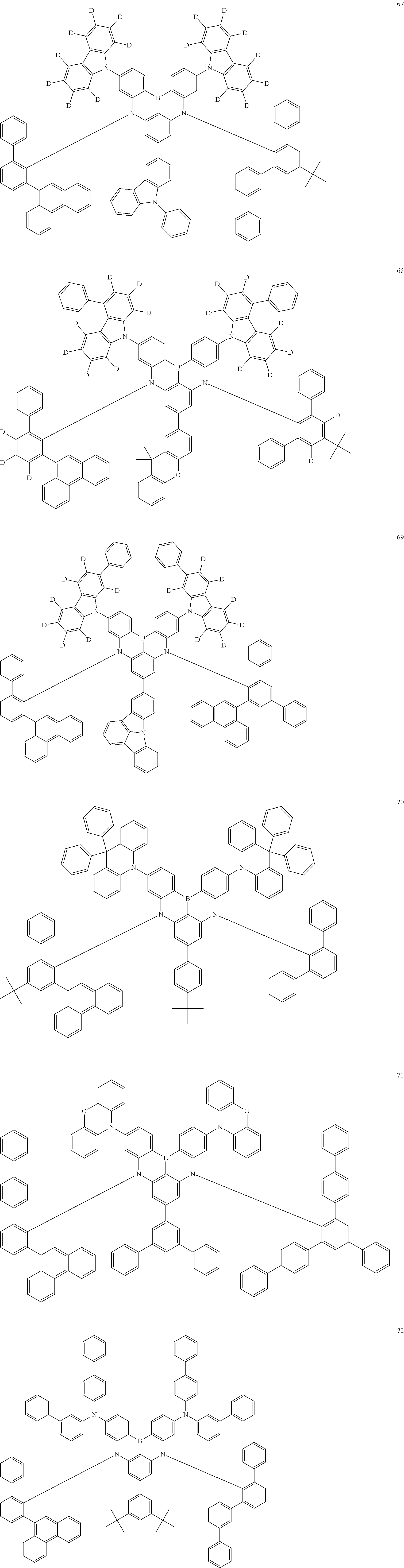 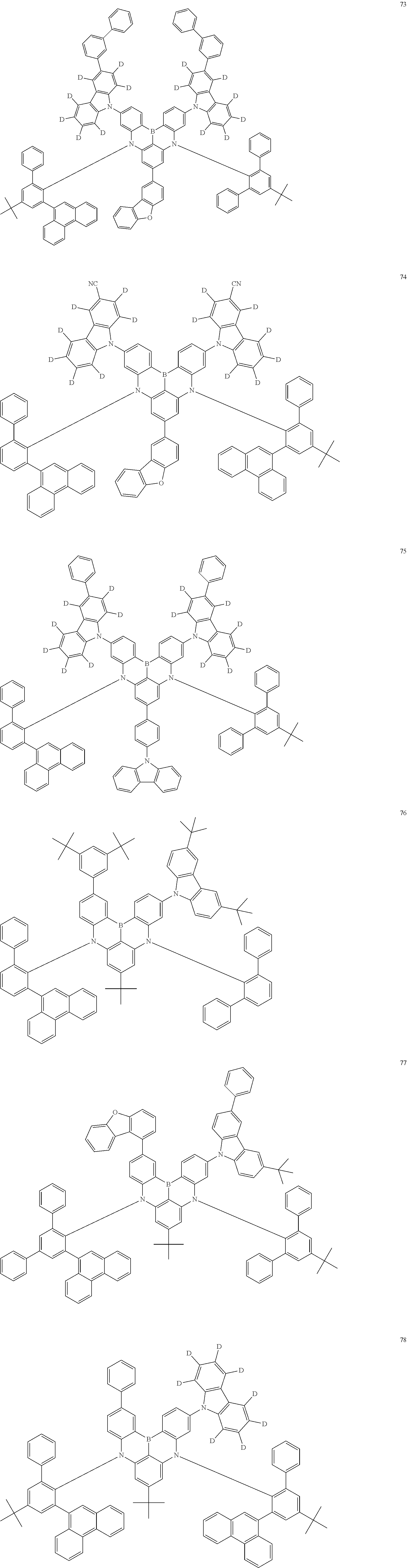 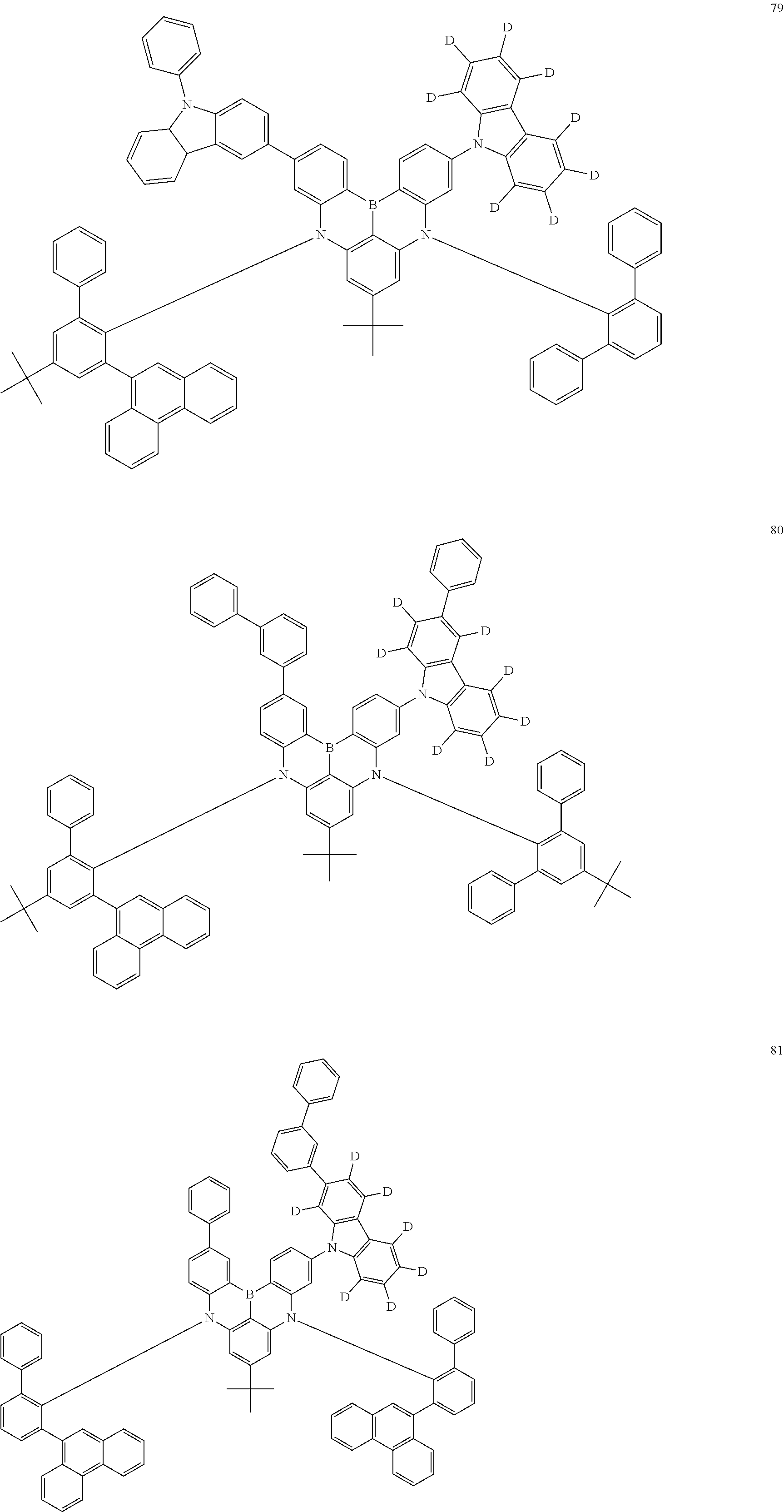 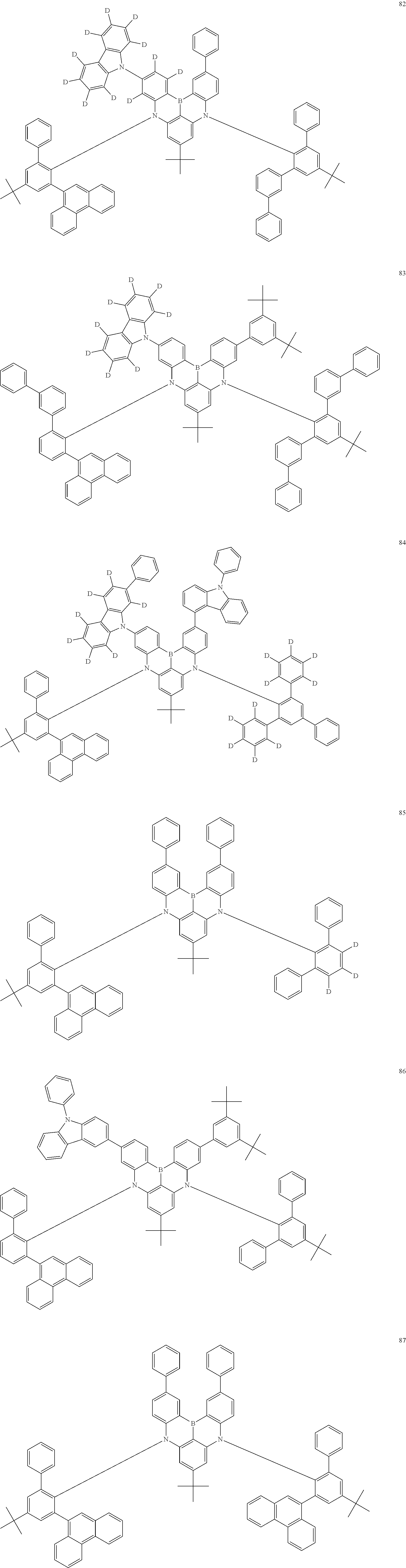 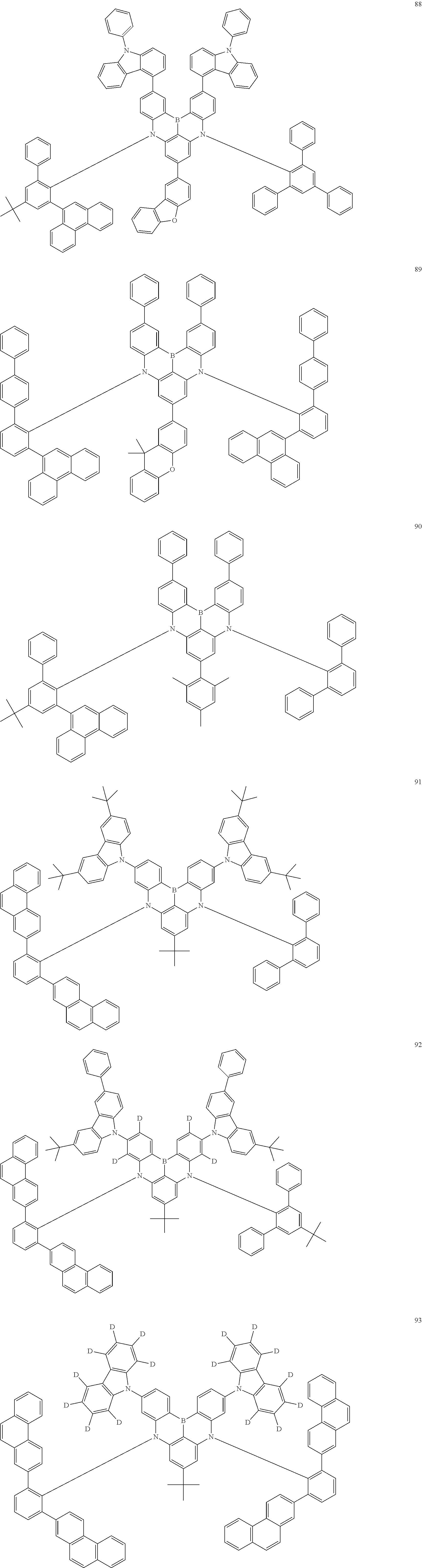 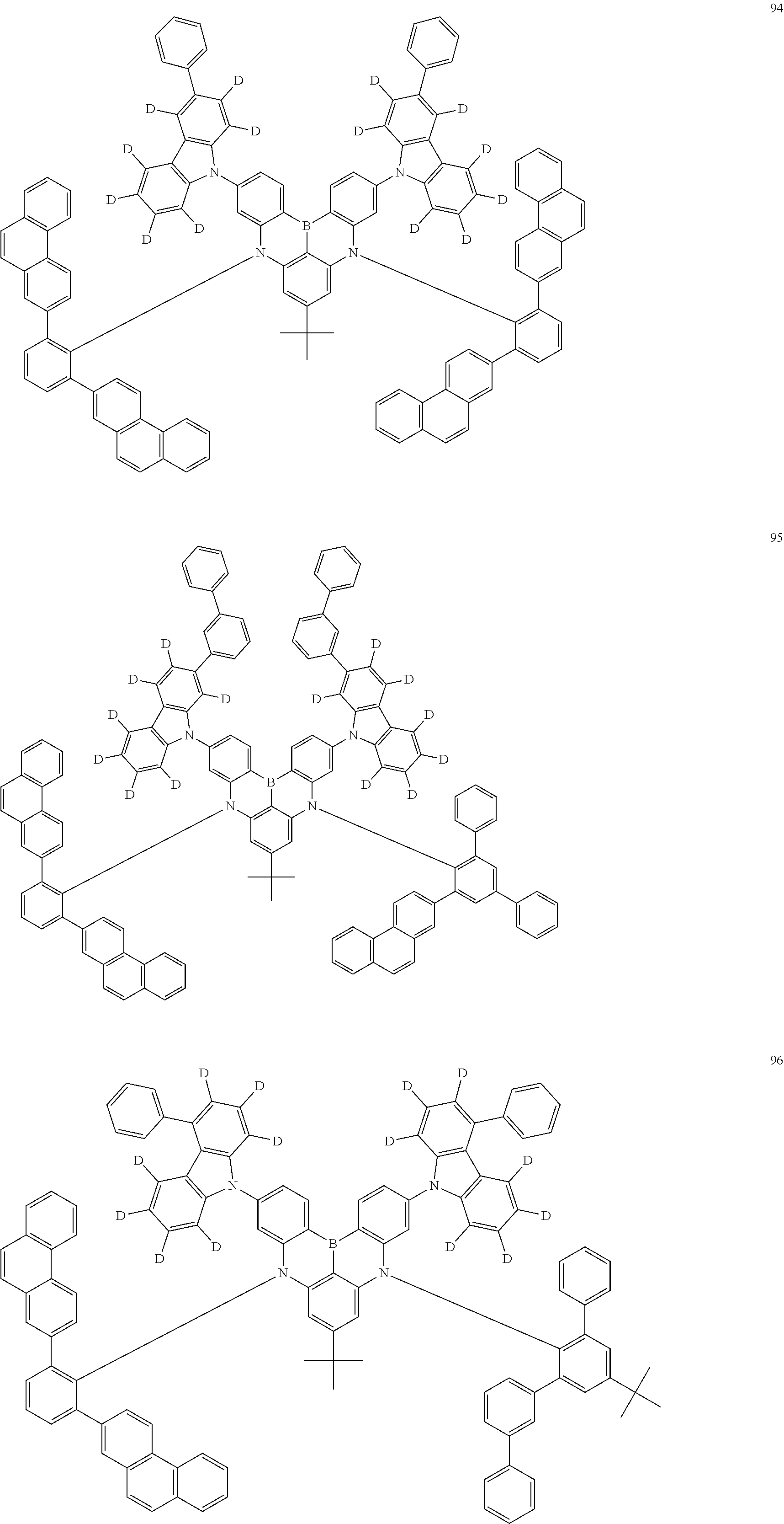 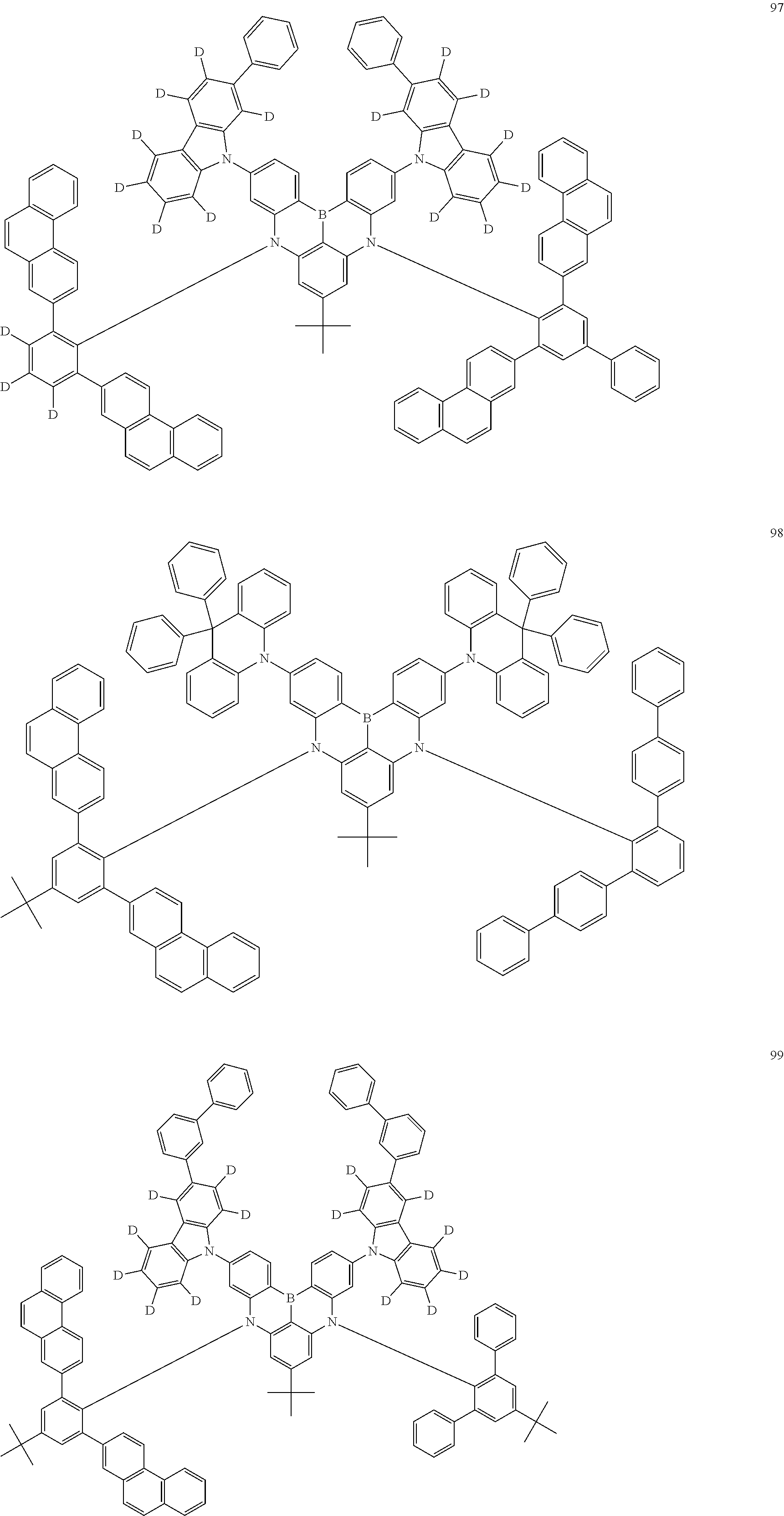 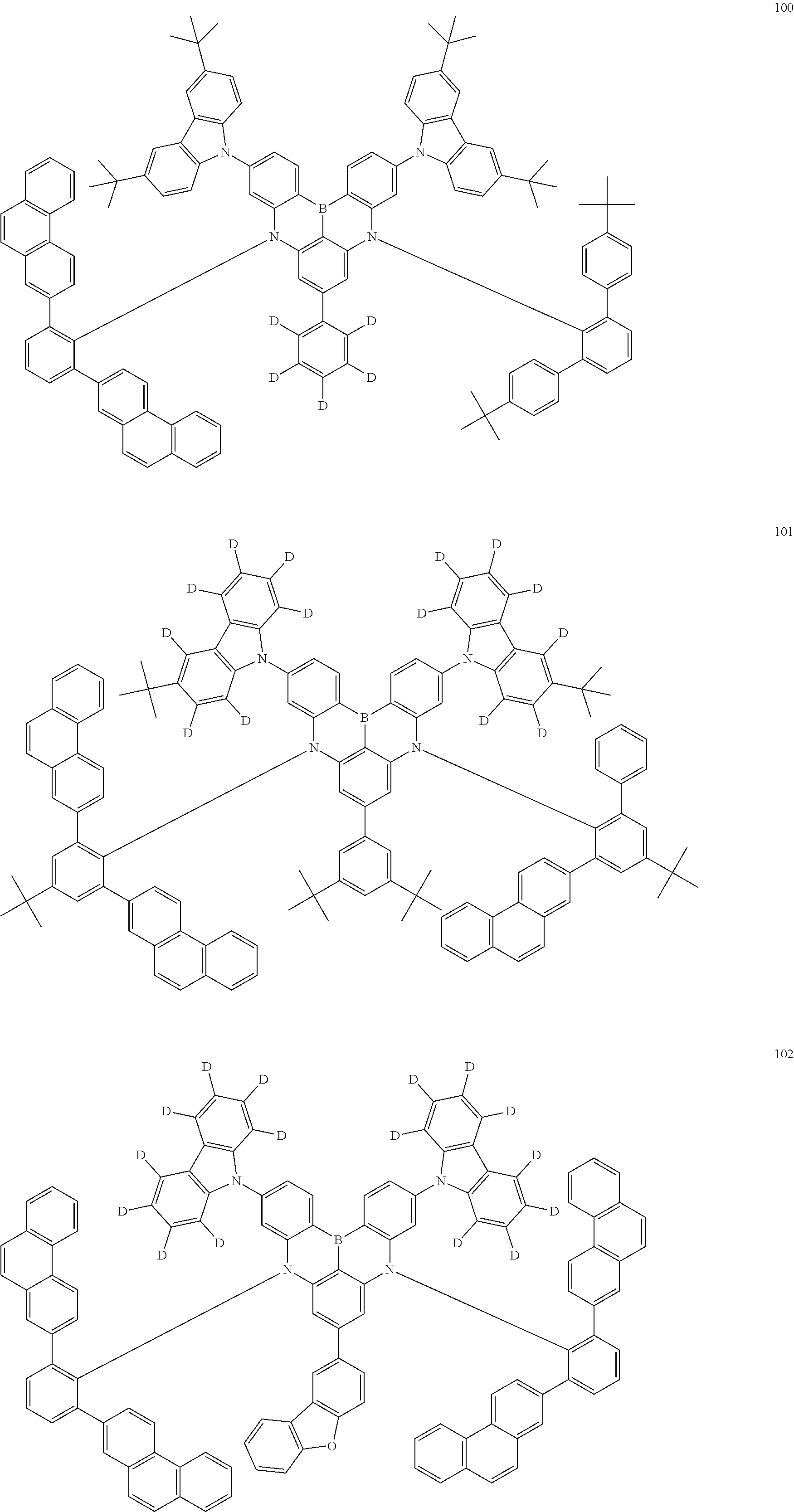 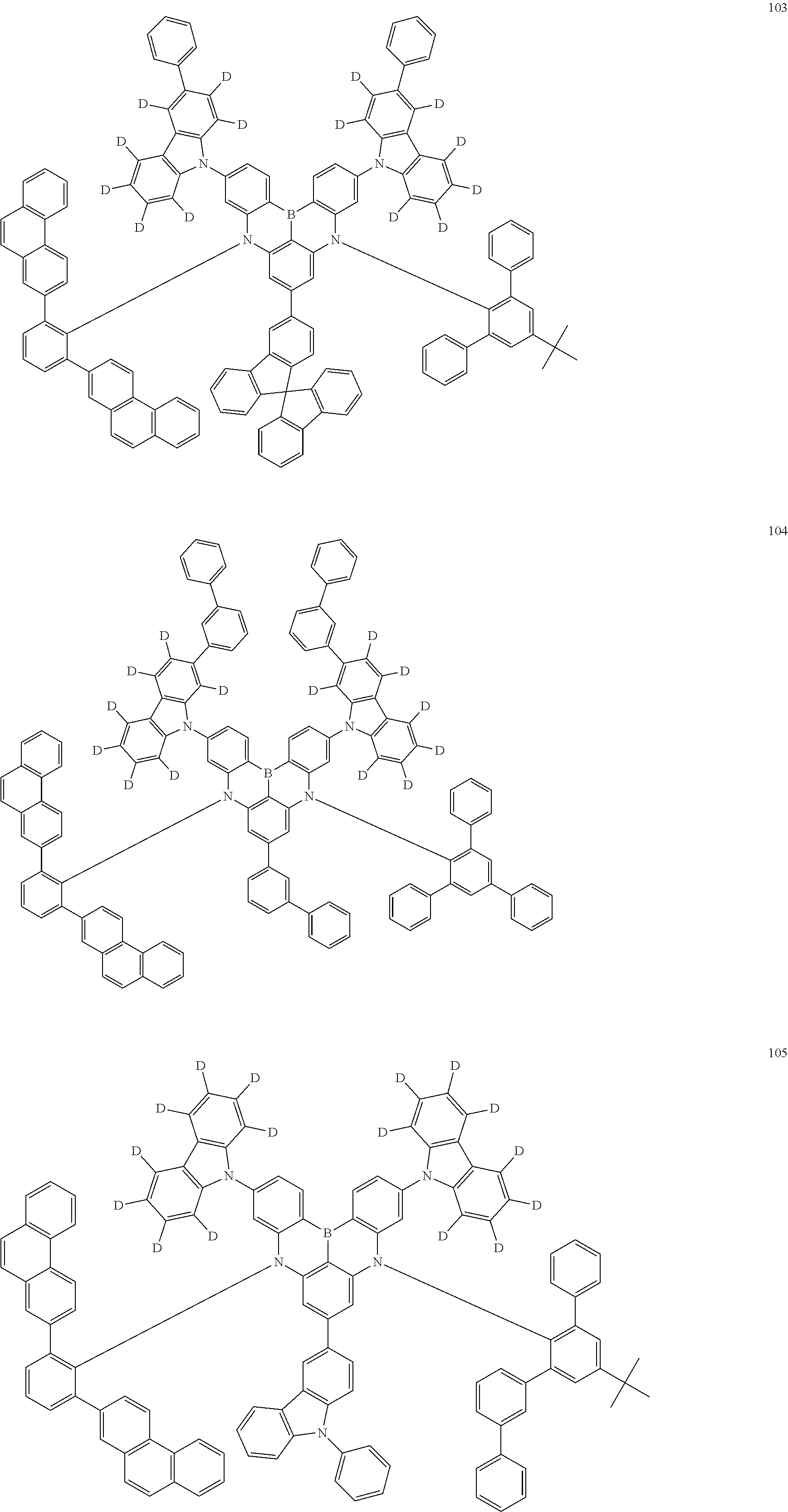 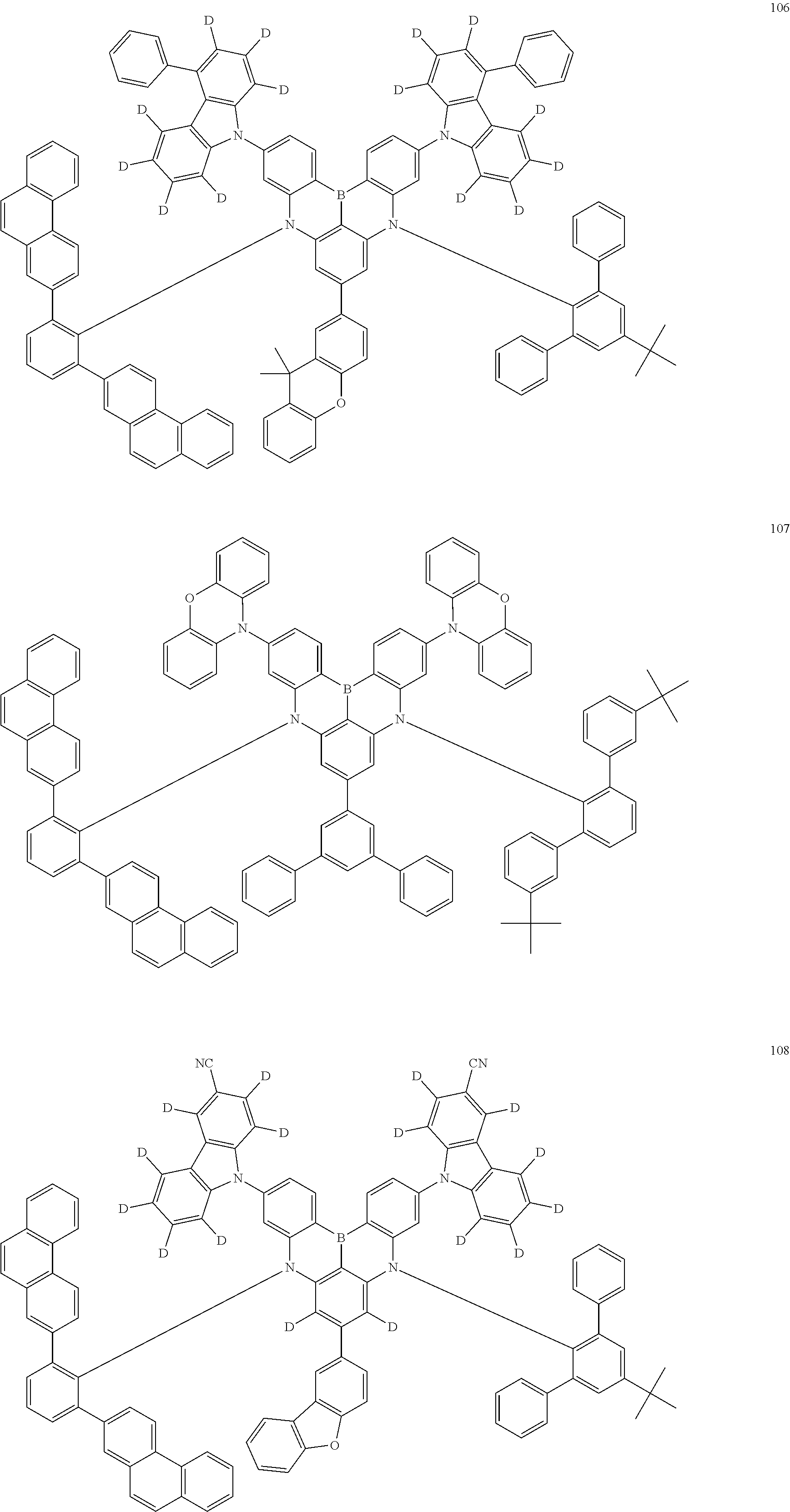 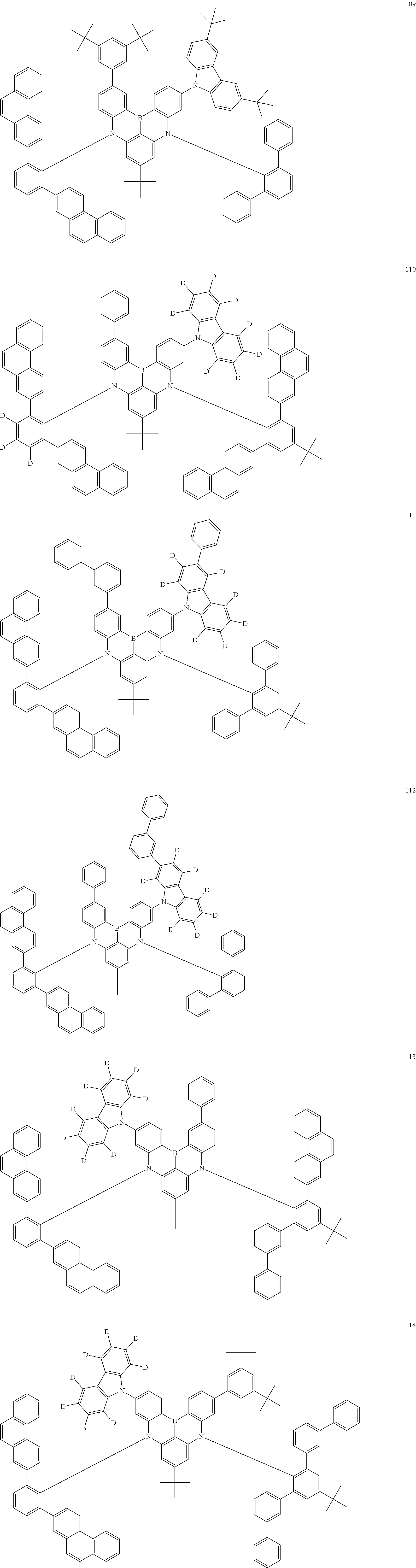 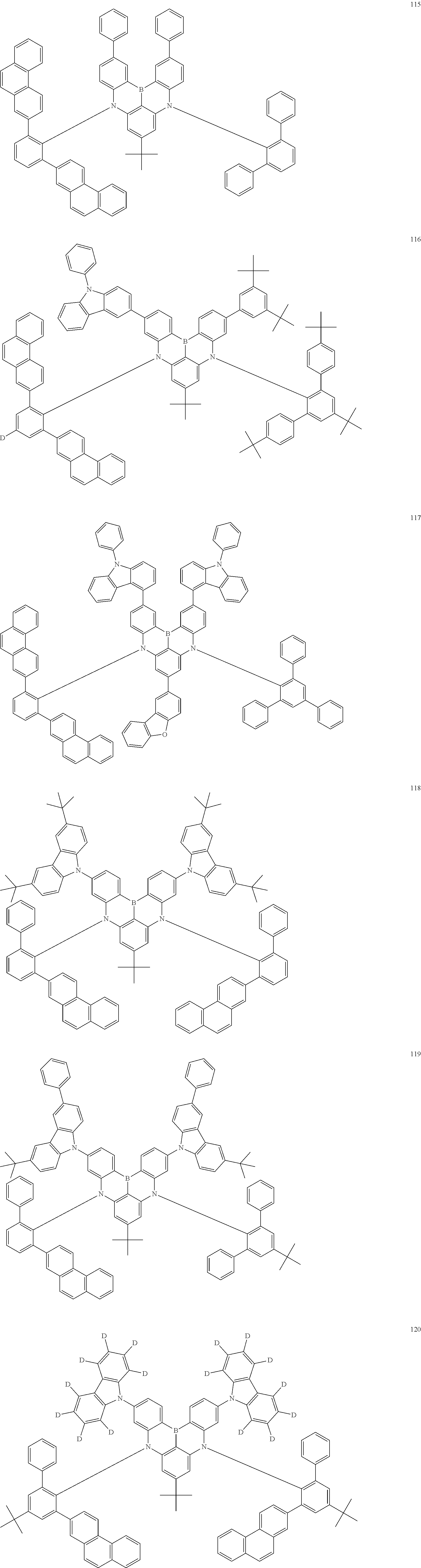 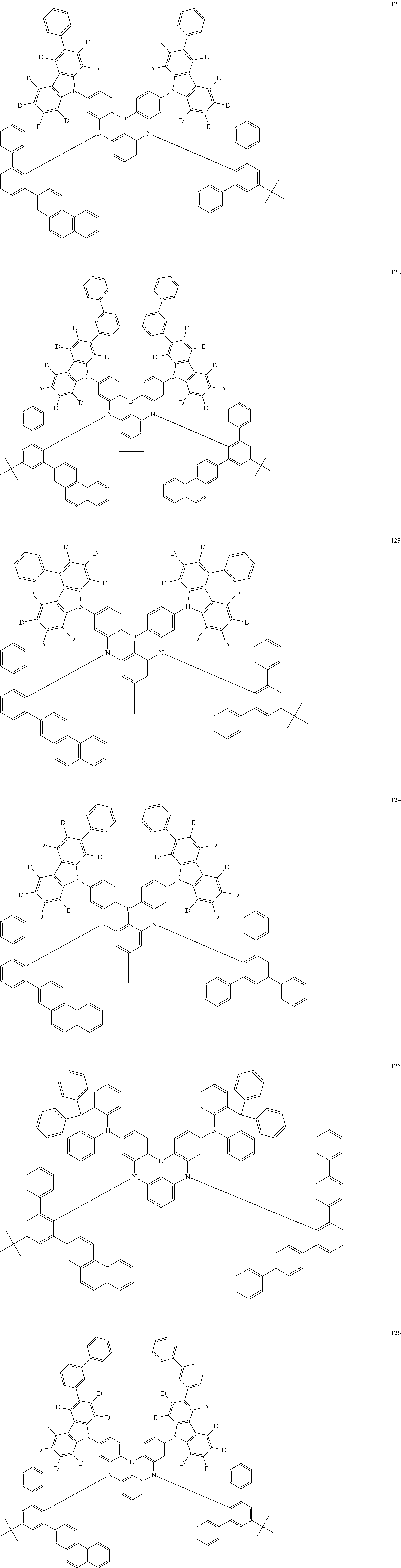 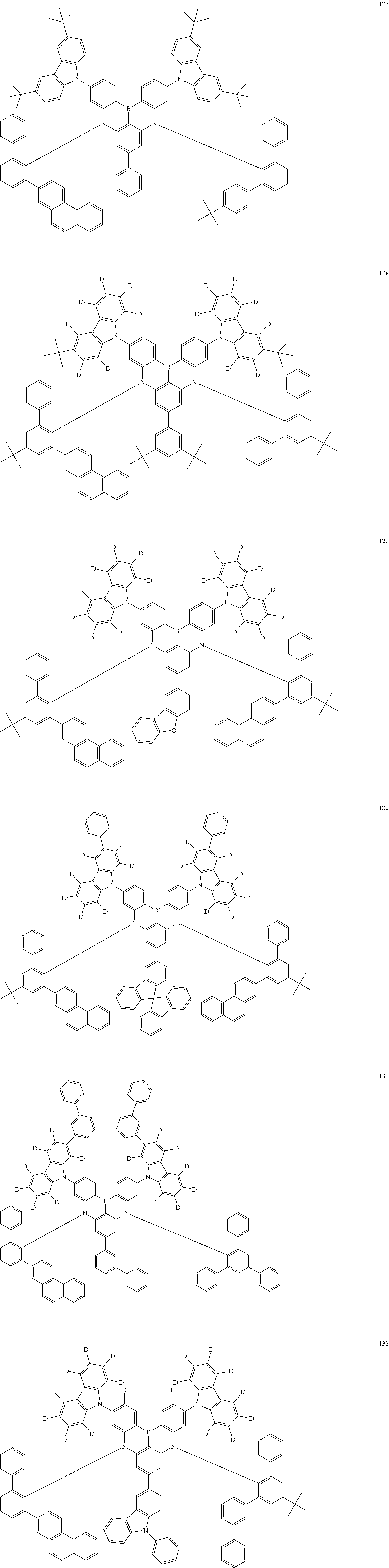 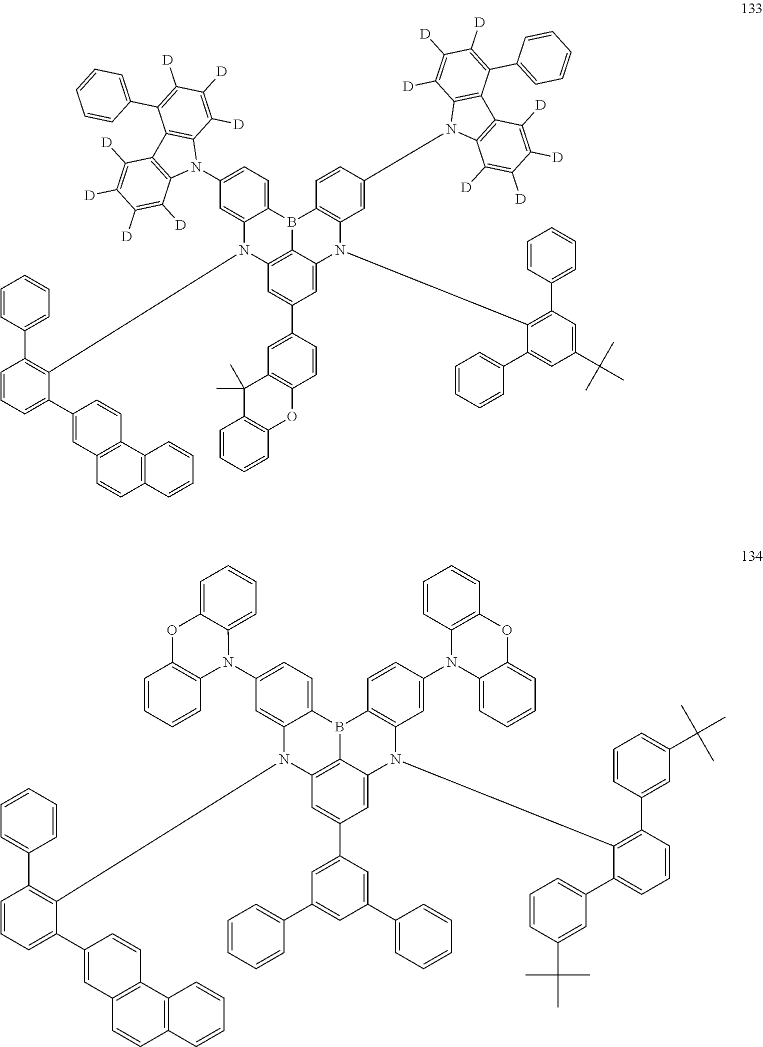 [SMILES: [2H]c1c([2H])c([2H])c2c(c1[2H])c1c(-c3ccccc3)c([2H])c([2H])c([2H])c1n2-c1ccc2c(c1)N(c1c(-c3ccccc3)cccc1-c1ccc3c(ccc4ccccc43)c1)c1cc(-c3ccc4c(c3)C(C)(C)c3ccccc3O4)cc3c1B2c1ccc(-n2c4c([2H])c([2H])c([2H])c([2H])c4c4c(-c5ccccc5)c([2H])c([2H])c([2H])c42)cc1N3c1c(-c2ccccc2)cc(C(C)(C)C)cc1-c1ccccc1 ; CC(C)(C)c1cccc(-c2cccc(-c3cccc(C(C)(C)C)c3)c2N2c3cc(N4c5ccccc5Oc5ccccc54)ccc3B3c4ccc(N5c6ccccc6Oc6ccccc65)cc4N(c4c(-c5ccccc5)cccc4-c4ccc5c(ccc6ccccc65)c4)c4cc(-c5cc(-c6ccccc6)cc(-c6ccccc6)c5)cc2c43)c1] 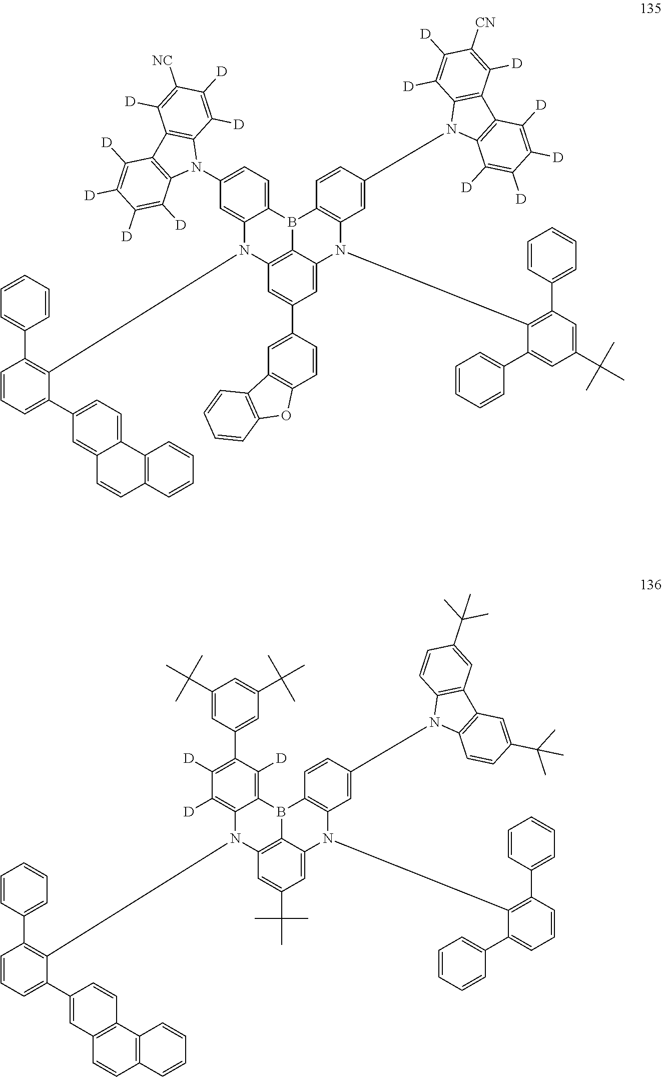 [SMILES: [2H]c1c([2H])c([2H])c2c(c1[2H])c1c([2H])c(C#N)c([2H])c([2H])c1n2-c1ccc2c(c1)N(c1c(-c3ccccc3)cccc1-c1ccc3c(ccc4ccccc43)c1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cc(C(C)(C)C)cc1-c1ccccc1 ; [2H]c1c([2H])c2c(c([2H])c1-c1cc(C(C)(C)C)cc(C(C)(C)C)c1)B1c3ccc(-n4c5ccc(C(C)(C)C)cc5c5cc(C(C)(C)C)ccc54)cc3N(c3c(-c4ccccc4)cccc3-c3ccccc3)c3cc(C(C)(C)C)cc(c31)N2c1c(-c2ccccc2)cccc1-c1ccc2c(ccc3ccccc32)c1] 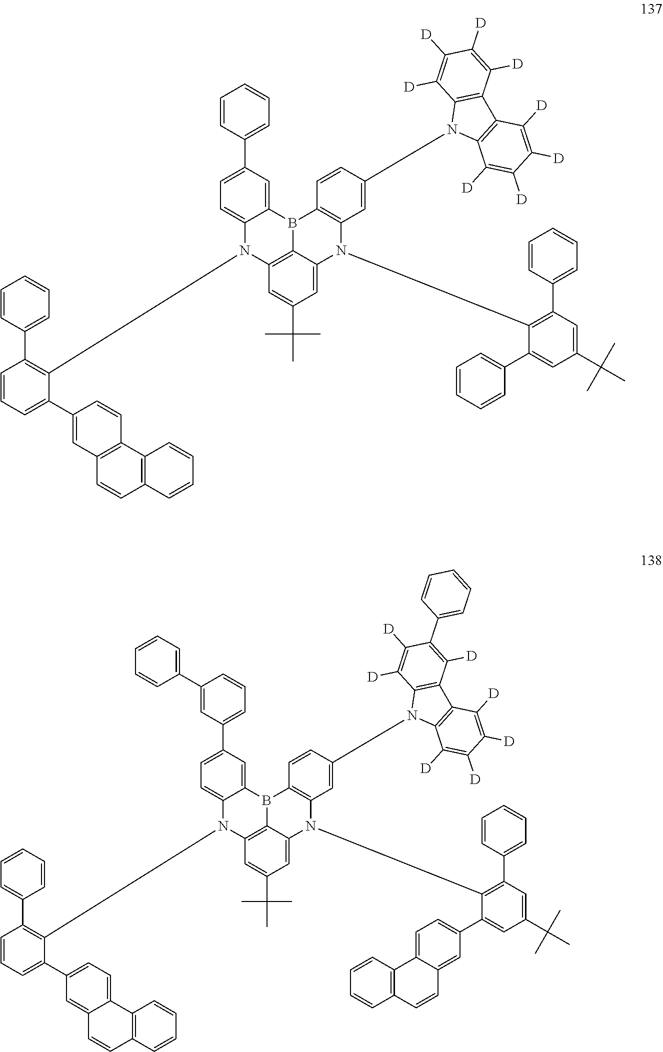 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2ccccc2)ccc1N3c1c(-c2ccccc2)cccc1-c1ccc2c(ccc3ccccc32)c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccc3c(ccc4ccccc43)c1)c1cc(C(C)(C)C)cc3c1B2c1cc(-c2cccc(-c4ccccc4)c2)ccc1N3c1c(-c2ccccc2)cccc1-c1ccc2c(ccc3ccccc32)c1] 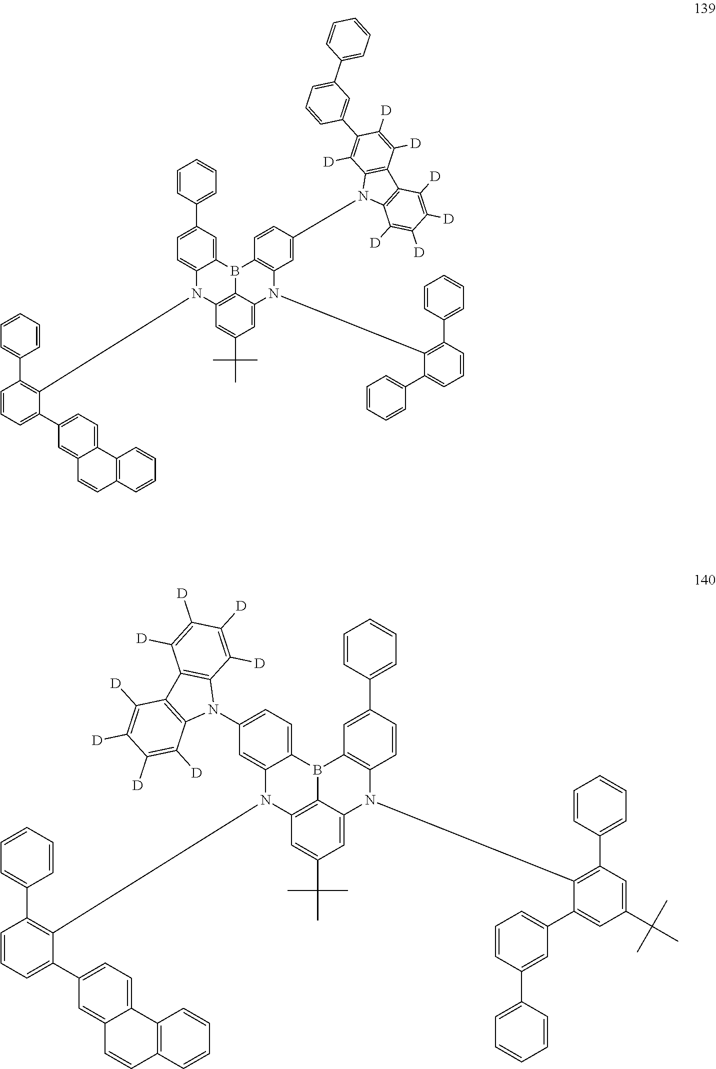 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1ccc2c(ccc3ccccc32)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccc3c(ccc4ccccc43)c1)c1cc(C(C)(C)C)cc3c1B2c1cc(-c2ccccc2)ccc1N3c1c(-c2ccccc2)cc(C(C)(C)C)cc1-c1cccc(-c2ccccc2)c1] 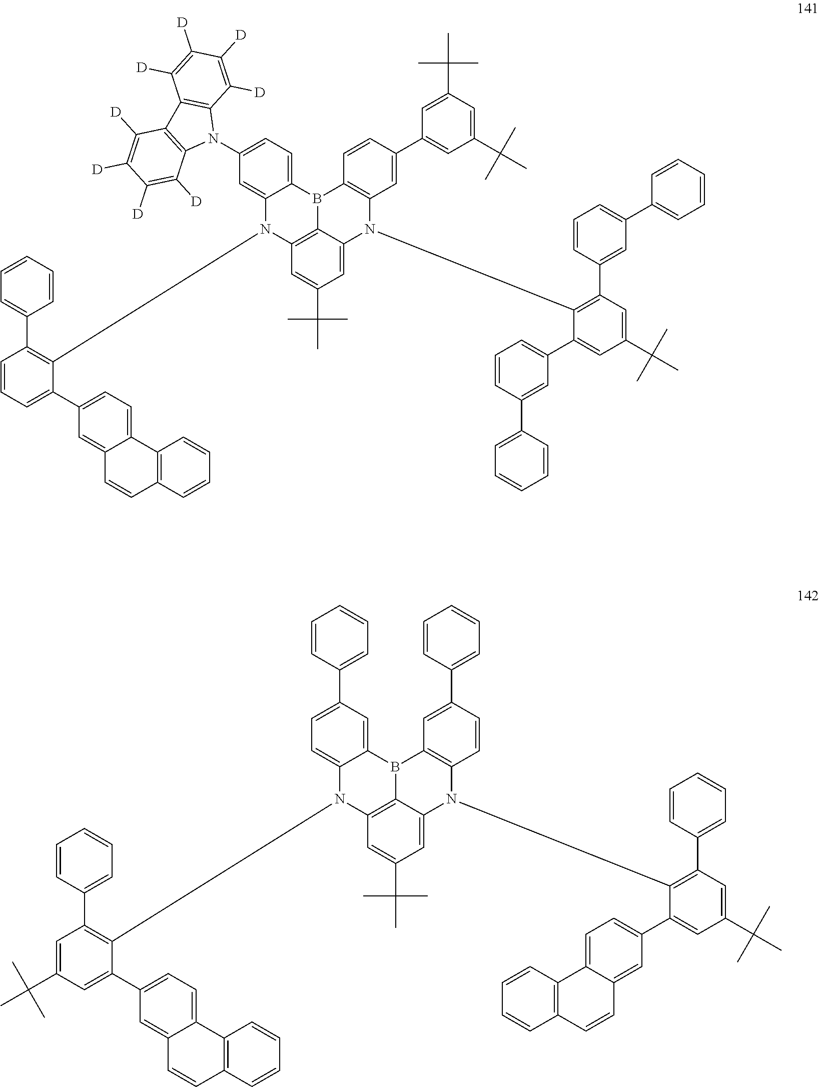 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc3c(ccc4ccccc43)c1)c1cc(C(C)(C)C)cc3c1B2c1ccc(-c2cc(C(C)(C)C)cc(C(C)(C)C)c2)cc1N3c1c(-c2cccc(-c3ccccc3)c2)cc(C(C)(C)C)cc1-c1cccc(-c2ccccc2)c1 ; CC(C)(C)c1cc(-c2ccccc2)c(N2c3ccc(-c4ccccc4)cc3B3c4cc(-c5ccccc5)ccc4N(c4c(-c5ccccc5)cc(C(C)(C)C)cc4-c4ccc5c(ccc6ccccc65)c4)c4cc(C(C)(C)C)cc2c43)c(-c2ccc3c(ccc4ccccc43)c2)c1] 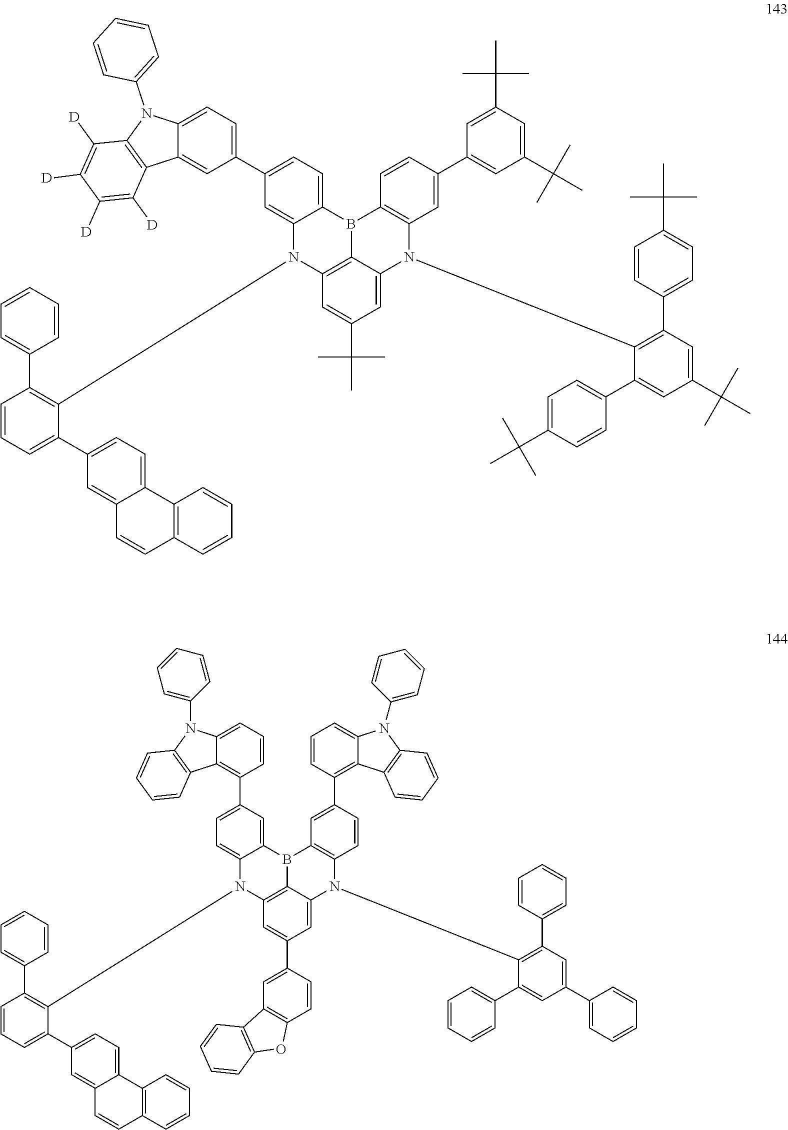 [SMILES: [2H]c1c([2H])c([2H])c2c(c1[2H])c1cc(-c3ccc4c(c3)N(c3c(-c5ccccc5)cccc3-c3ccc5c(ccc6ccccc65)c3)c3cc(C(C)(C)C)cc5c3B4c3ccc(-c4cc(C(C)(C)C)cc(C(C)(C)C)c4)cc3N5c3c(-c4ccc(C(C)(C)C)cc4)cc(C(C)(C)C)cc3-c3ccc(C(C)(C)C)cc3)ccc1n2-c1ccccc1 ; c1ccc(-c2cc(-c3ccccc3)c(N3c4ccc(-c5cccc6c5c5ccccc5n6-c5ccccc5)cc4B4c5cc(-c6cccc7c6c6ccccc6n7-c6ccccc6)ccc5N(c5c(-c6ccccc6)cccc5-c5ccc6c(ccc7ccccc76)c5)c5cc(-c6ccc7oc8ccccc8c7c6)cc3c54)c(-c3ccccc3)c2)cc1] 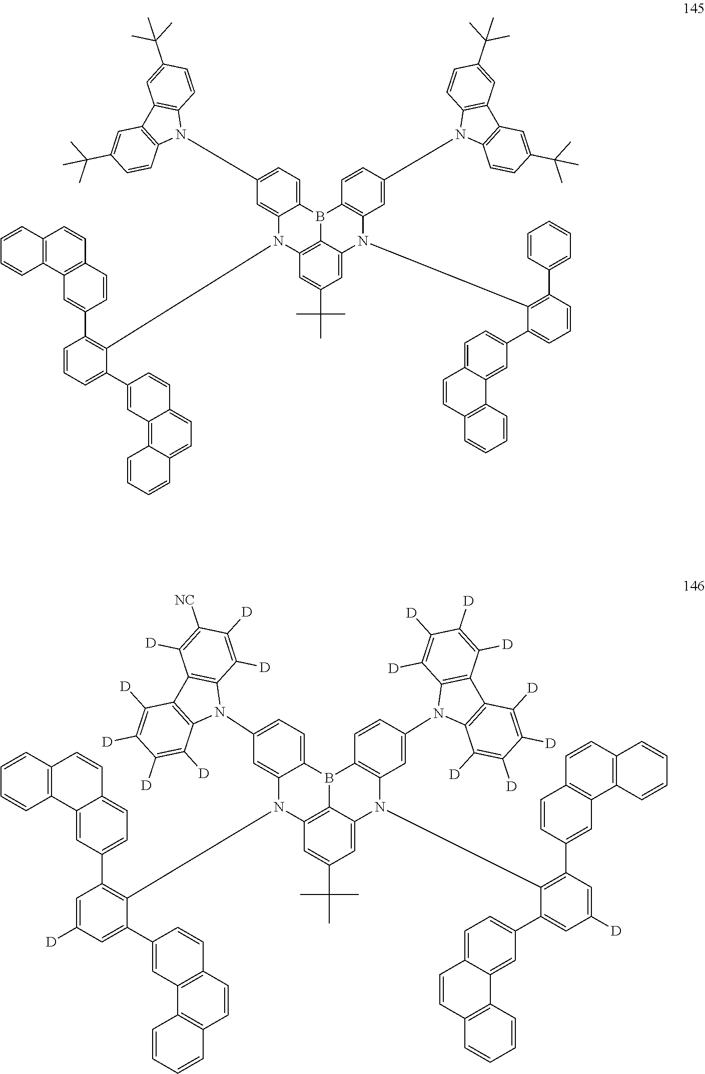 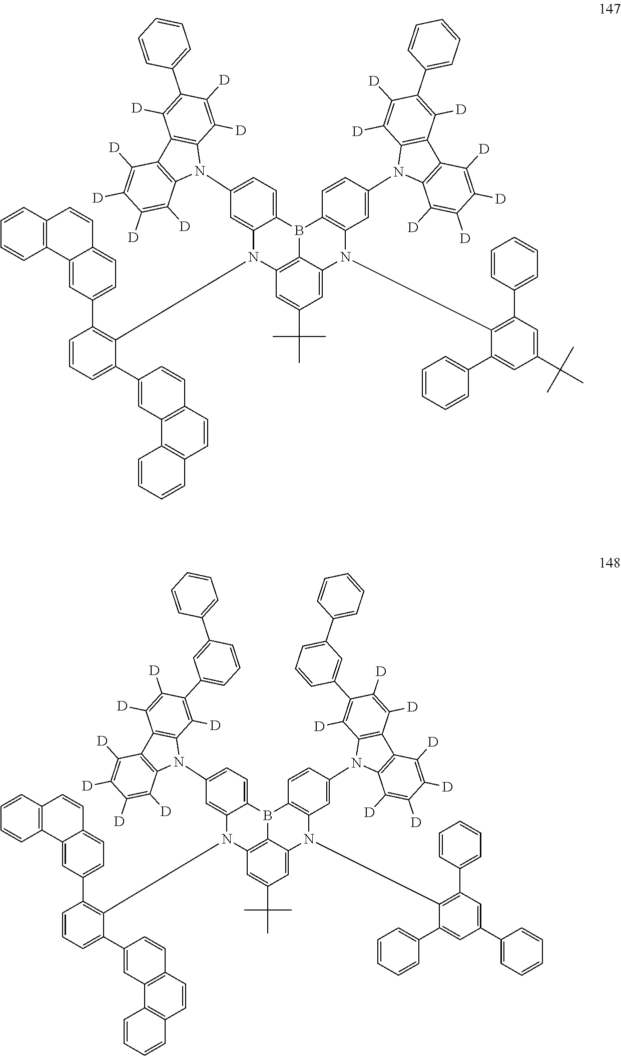 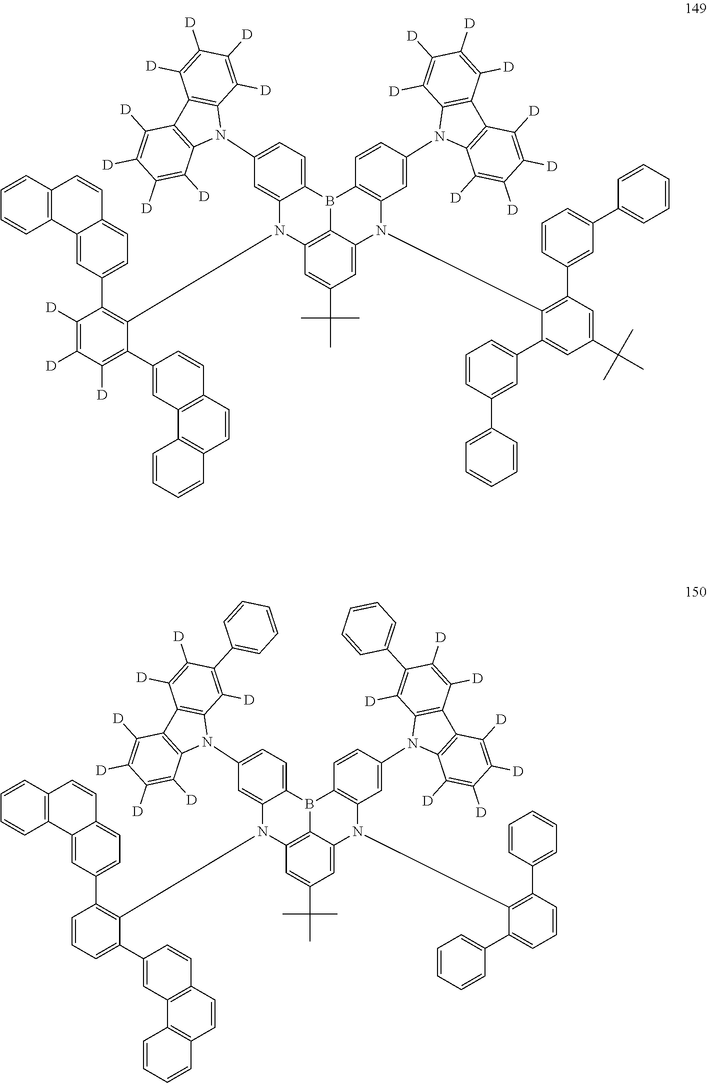 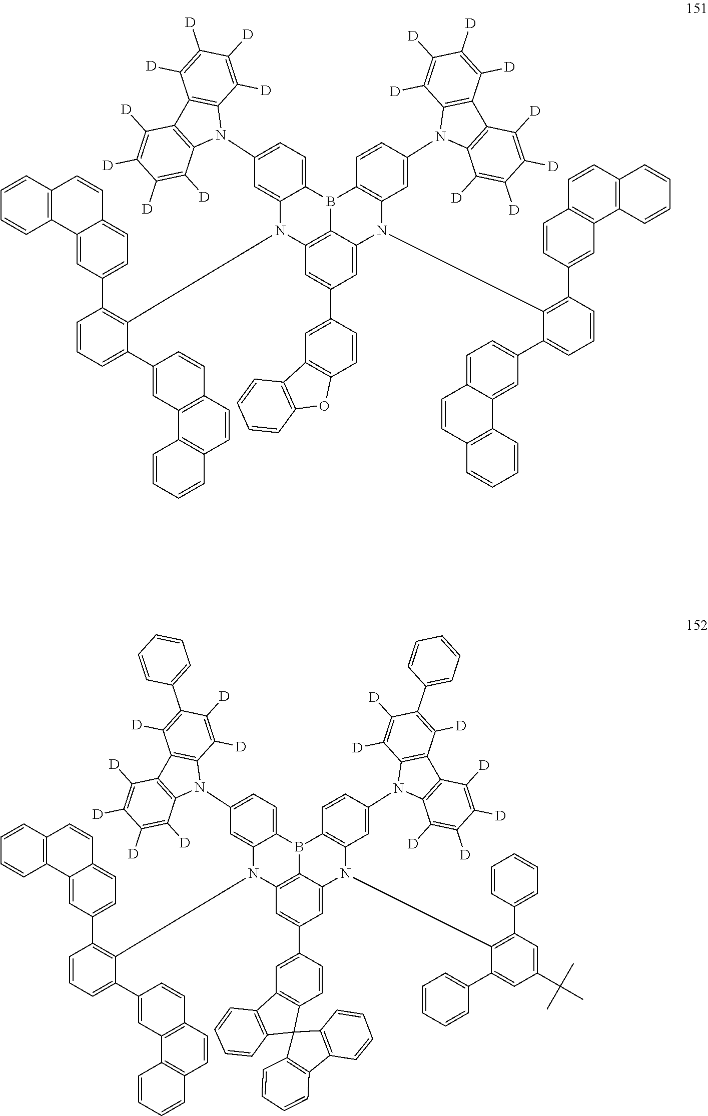 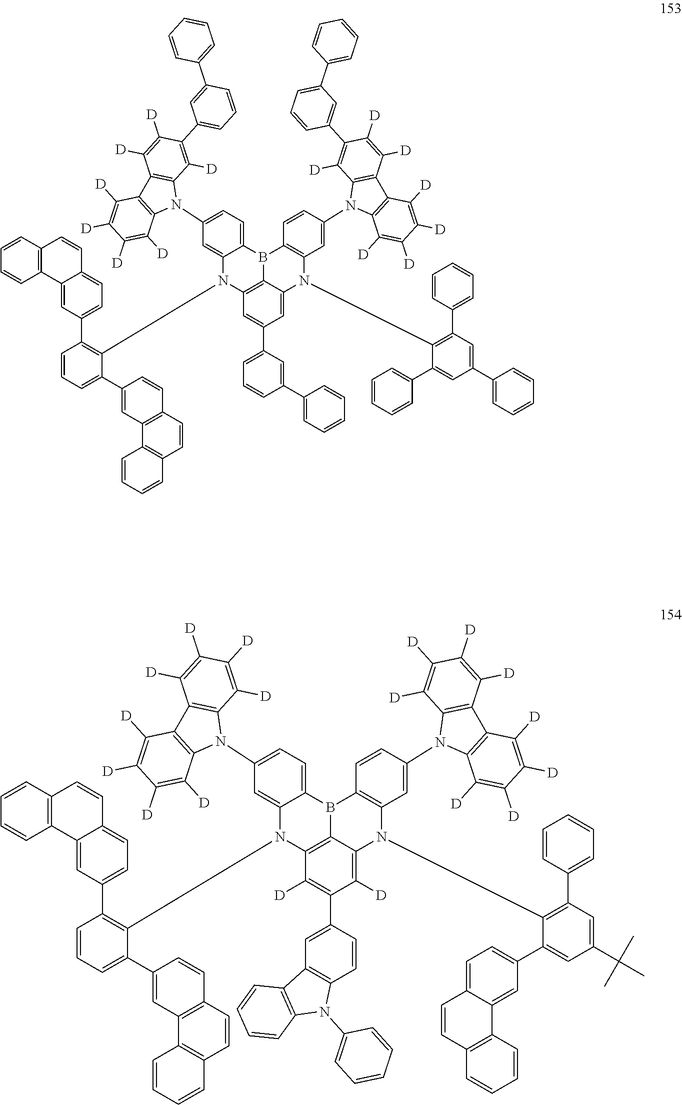 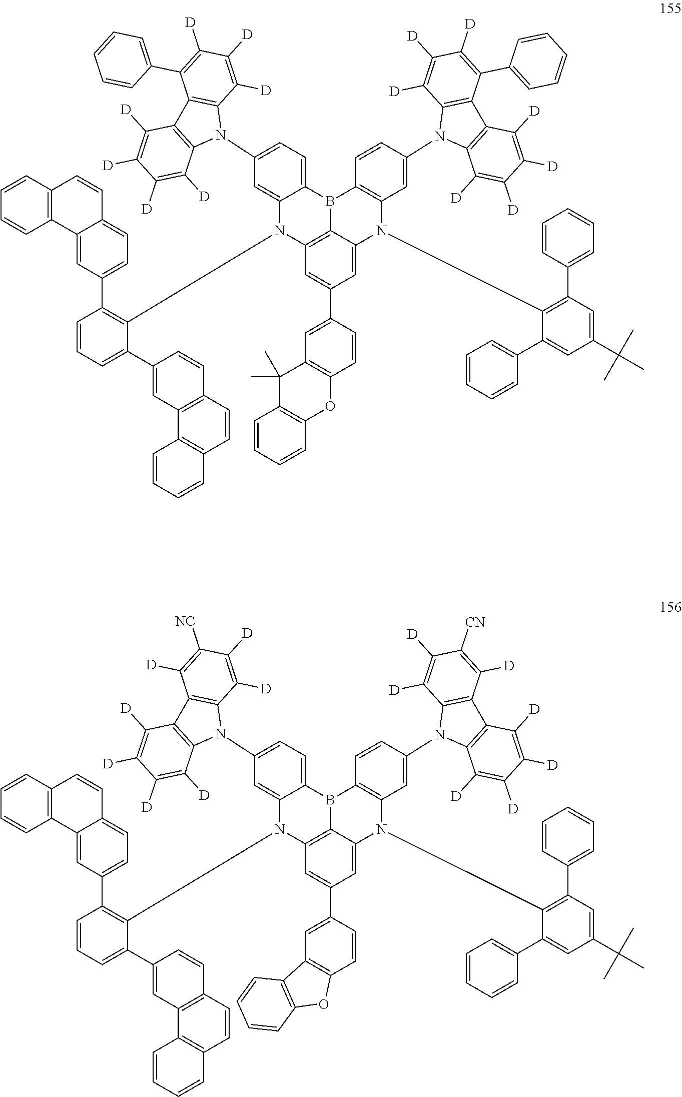 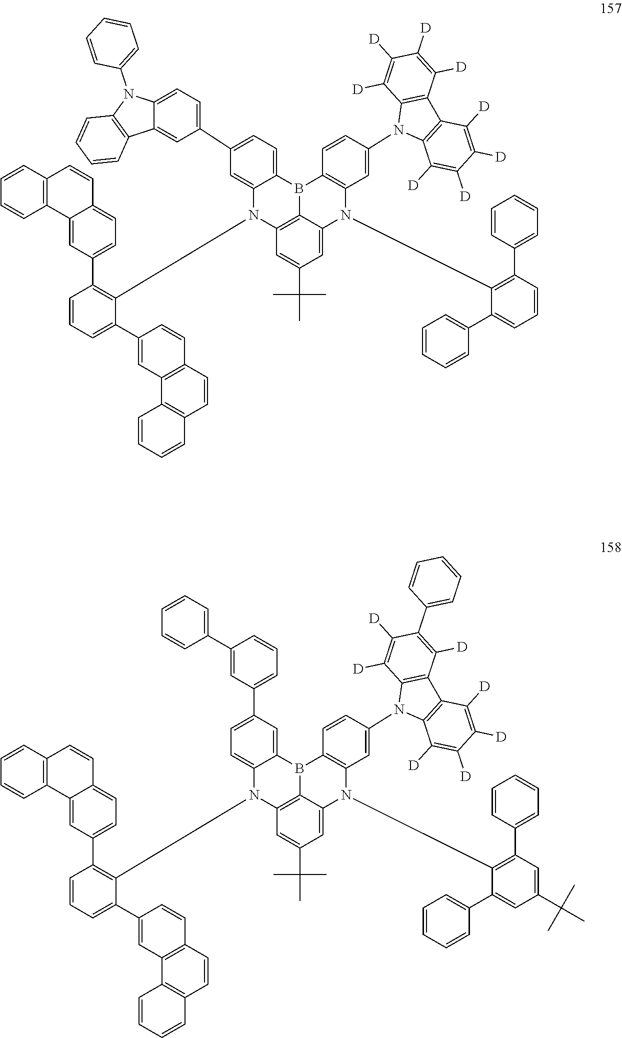 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccc3ccc4ccccc4c3c2)cccc1-c1ccc2ccc3ccccc3c2c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2ccc3ccc4ccccc4c3c2)cccc1-c1ccc2ccc3ccccc3c2c1] 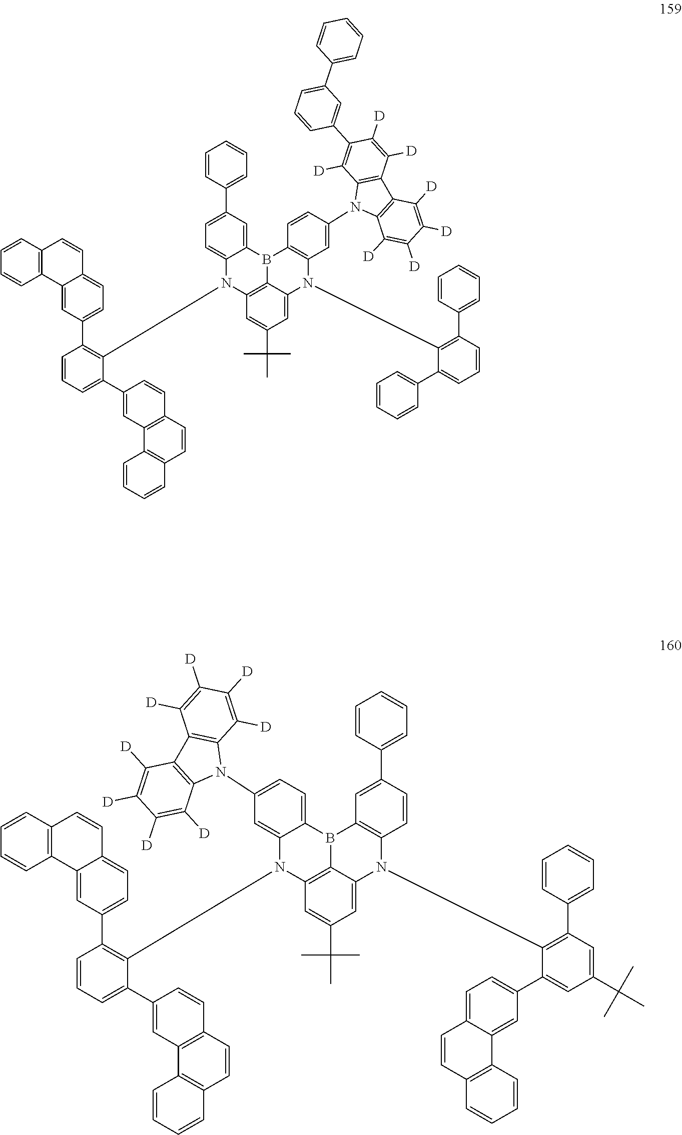 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccc3ccc4ccccc4c3c2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccc4ccc5ccccc5c4c3)cccc1-c1ccc3ccc4ccccc4c3c1)c1cc(C(C)(C)C)cc3c1B2c1cc(-c2ccccc2)ccc1N3c1c(-c2ccccc2)cc(C(C)(C)C)cc1-c1ccc2ccc3ccccc3c2c1] 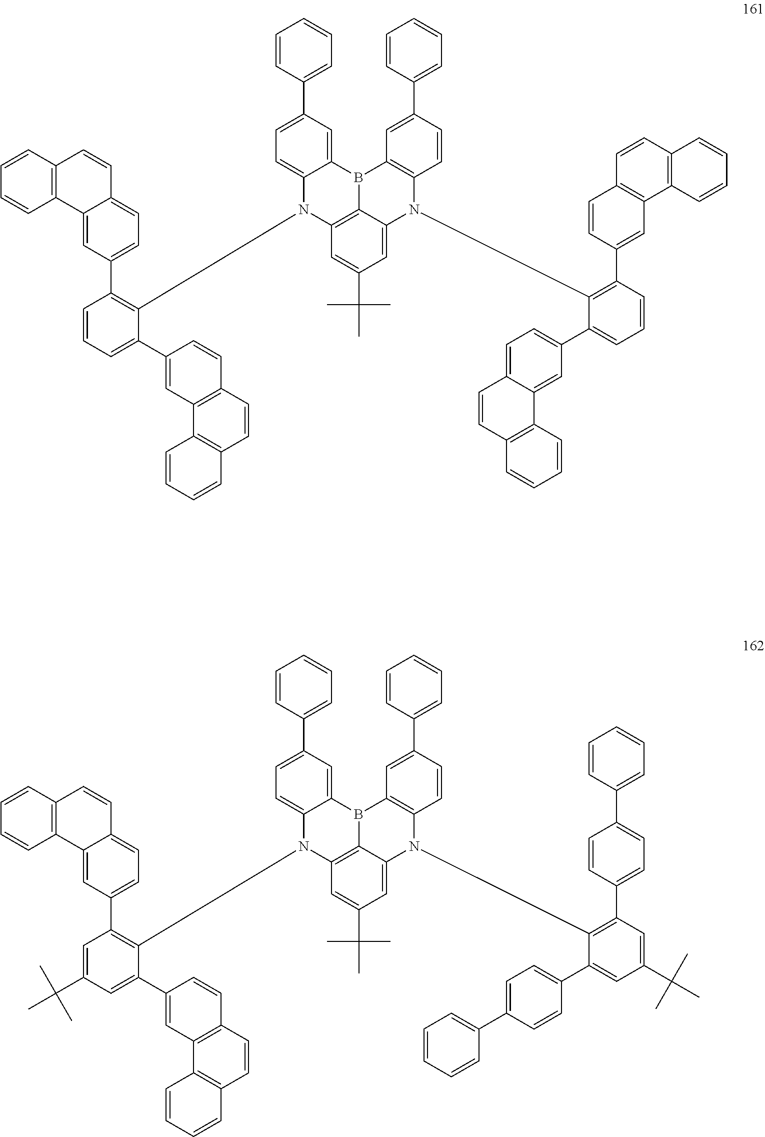 [SMILES: CC(C)(C)c1cc2c3c(c1)N(c1c(-c4ccc5ccc6ccccc6c5c4)cccc1-c1ccc4ccc5ccccc5c4c1)c1ccc(-c4ccccc4)cc1B3c1cc(-c3ccccc3)ccc1N2c1c(-c2ccc3ccc4ccccc4c3c2)cccc1-c1ccc2ccc3ccccc3c2c1 ; CC(C)(C)c1cc(-c2ccc(-c3ccccc3)cc2)c(N2c3ccc(-c4ccccc4)cc3B3c4cc(-c5ccccc5)ccc4N(c4c(-c5ccc6ccc7ccccc7c6c5)cc(C(C)(C)C)cc4-c4ccc5ccc6ccccc6c5c4)c4cc(C(C)(C)C)cc2c43)c(-c2ccc(-c3ccccc3)cc2)c1] 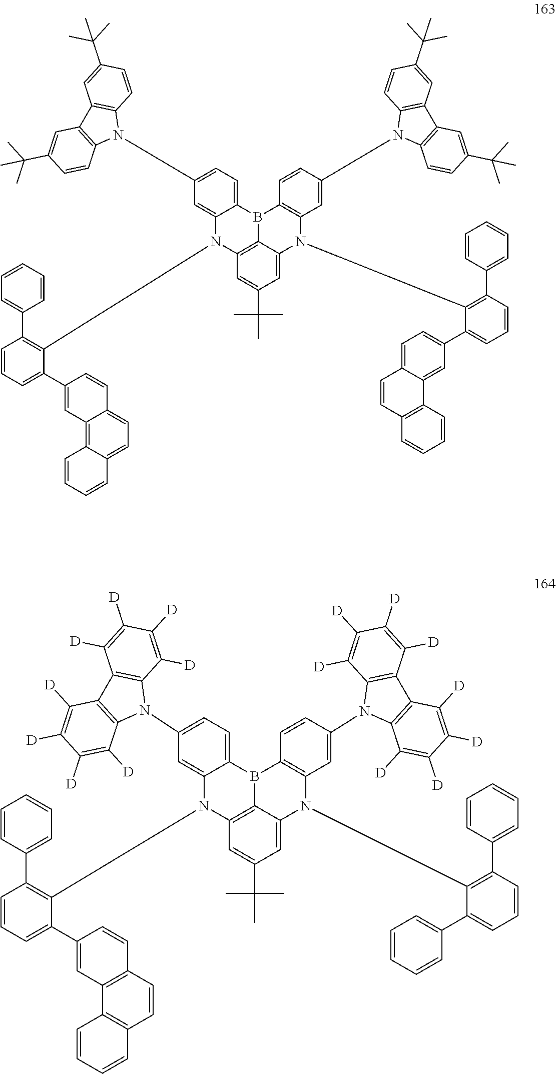 [SMILES: CC(C)(C)c1cc2c3c(c1)N(c1c(-c4ccccc4)cccc1-c1ccc4ccc5ccccc5c4c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc2ccc3ccccc3c2c1] 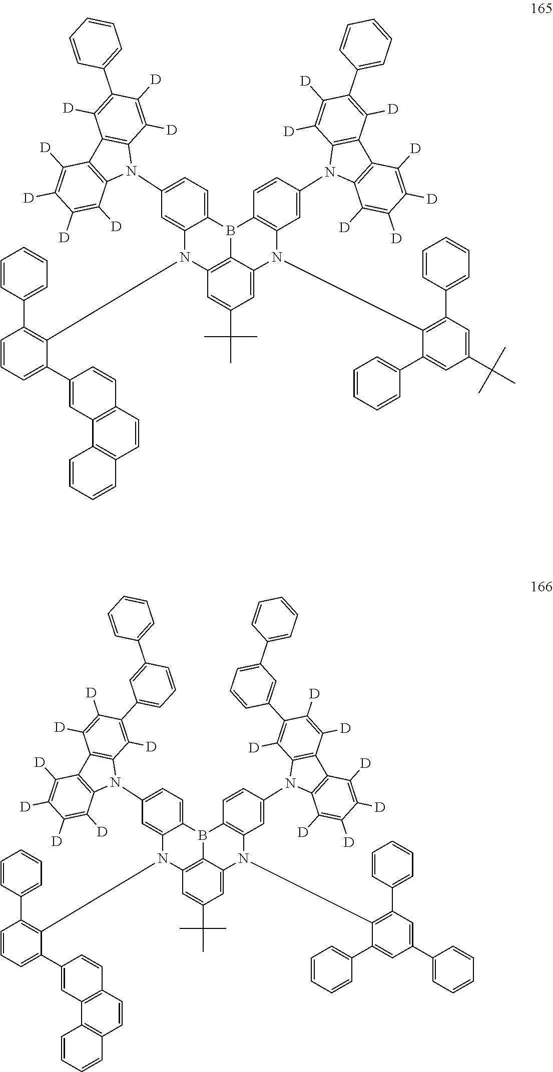 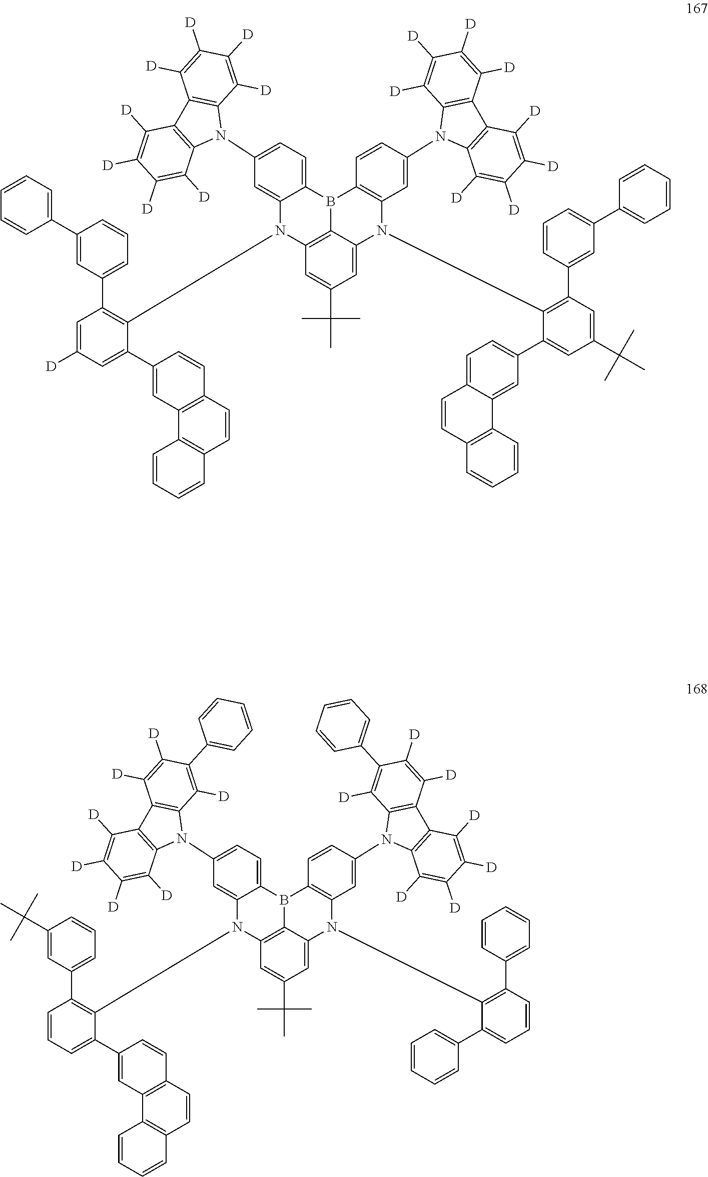 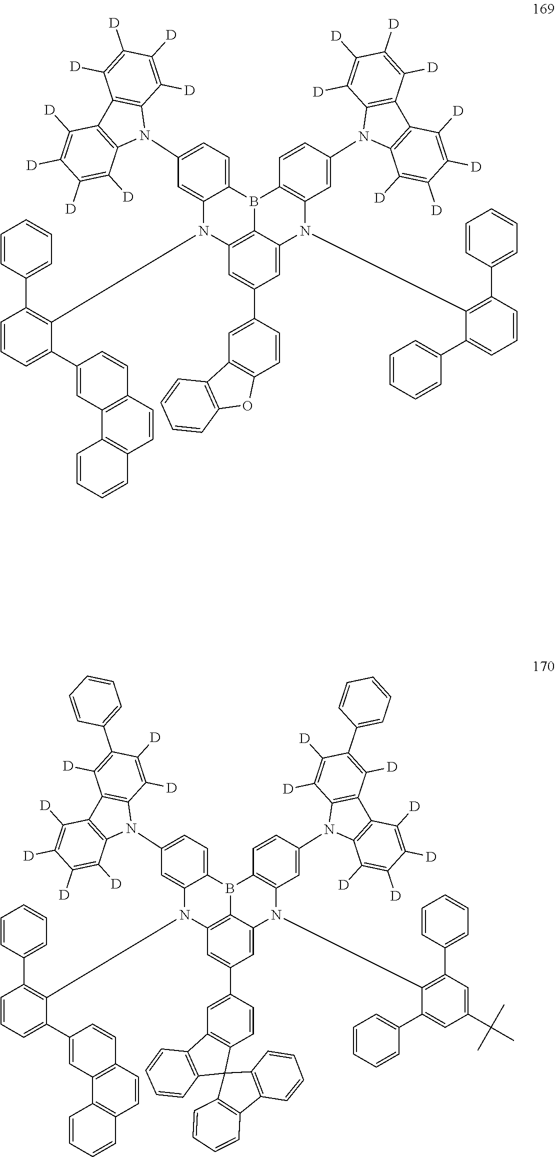 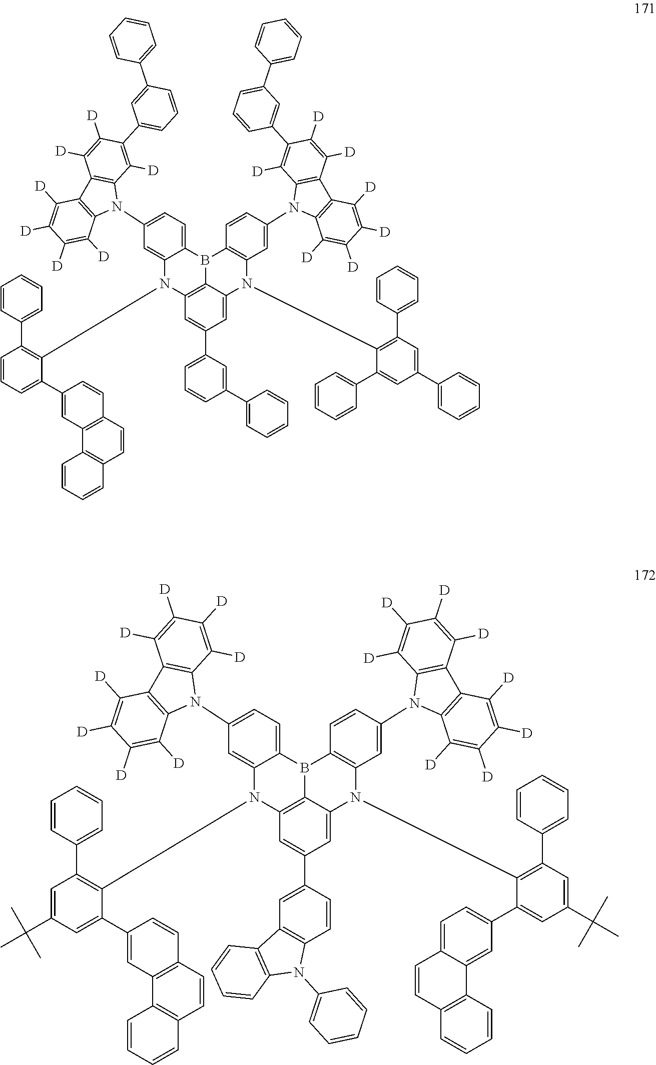 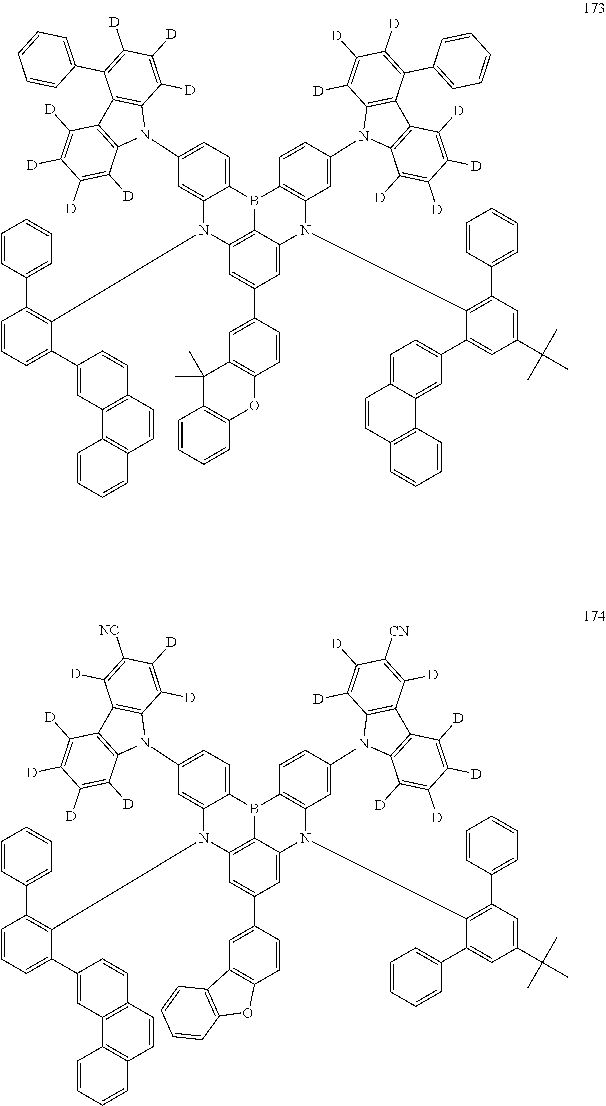 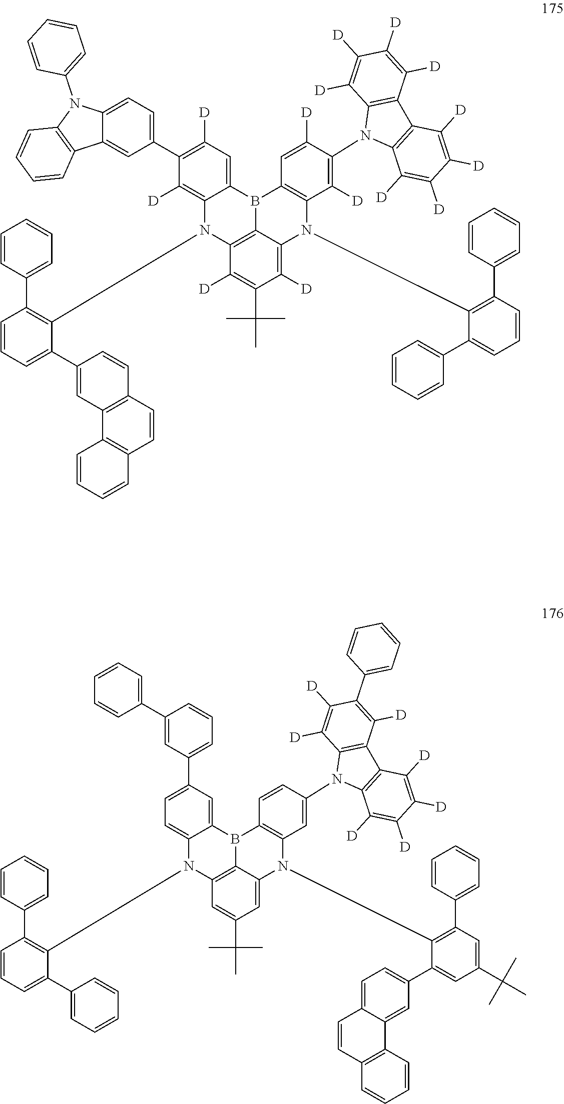 [SMILES: [2H]c1cc2c(c([2H])c1-c1ccc3c(c1)c1ccccc1n3-c1ccccc1)N(c1c(-c3ccccc3)cccc1-c1ccc3ccc4ccccc4c3c1)c1c([2H])c(C(C)(C)C)c([2H])c3c1B2c1cc([2H])c(-n2c4c([2H])c([2H])c([2H])c([2H])c4c4c([2H])c([2H])c([2H])c([2H])c42)c([2H])c1N3c1c(-c2ccccc2)cccc1-c1ccccc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccc3ccc4ccccc4c3c1)c1cc(C(C)(C)C)cc3c1B2c1cc(-c2cccc(-c4ccccc4)c2)ccc1N3c1c(-c2ccccc2)cccc1-c1ccccc1] 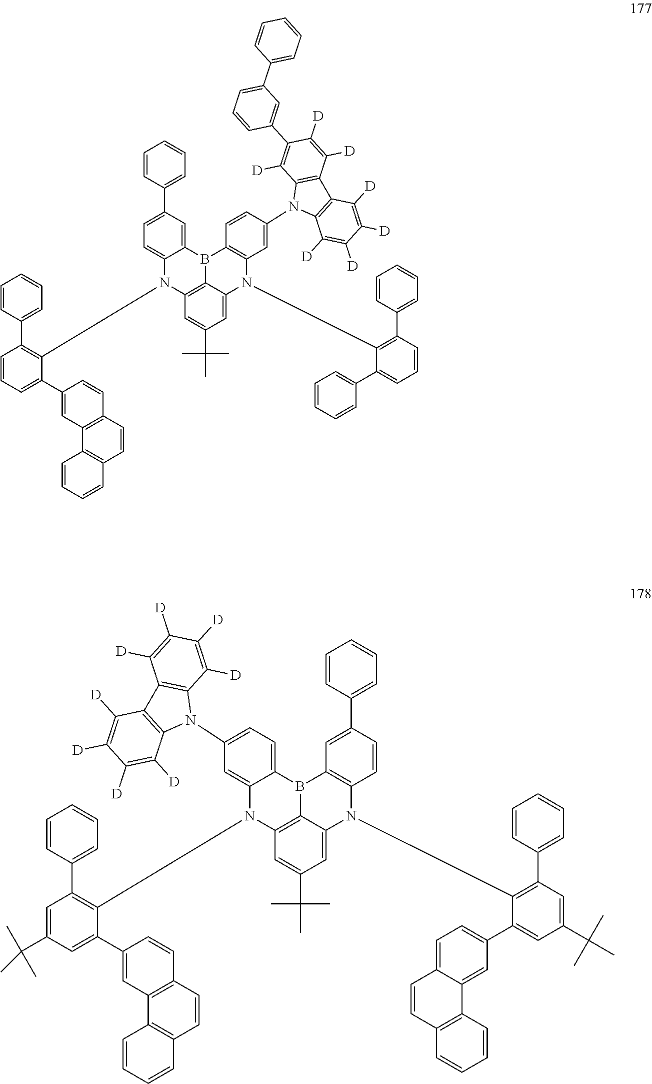 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1ccc2ccc3ccccc3c2c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccc3ccc4ccccc4c3c1)c1cc(C(C)(C)C)cc3c1B2c1cc(-c2ccccc2)ccc1N3c1c(-c2ccccc2)cc(C(C)(C)C)cc1-c1ccc2ccc3ccccc3c2c1] 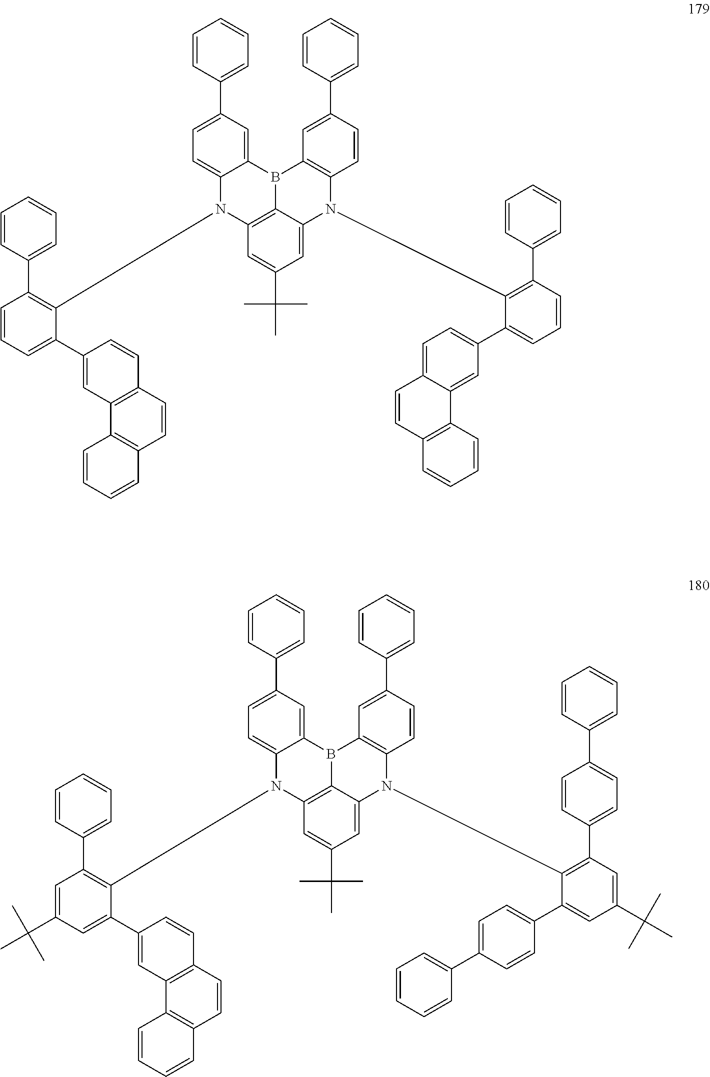 [SMILES: CC(C)(C)c1cc2c3c(c1)N(c1c(-c4ccccc4)cccc1-c1ccc4ccc5ccccc5c4c1)c1ccc(-c4ccccc4)cc1B3c1cc(-c3ccccc3)ccc1N2c1c(-c2ccccc2)cccc1-c1ccc2ccc3ccccc3c2c1 ; CC(C)(C)c1cc(-c2ccc(-c3ccccc3)cc2)c(N2c3ccc(-c4ccccc4)cc3B3c4cc(-c5ccccc5)ccc4N(c4c(-c5ccccc5)cc(C(C)(C)C)cc4-c4ccc5ccc6ccccc6c5c4)c4cc(C(C)(C)C)cc2c43)c(-c2ccc(-c3ccccc3)cc2)c1] 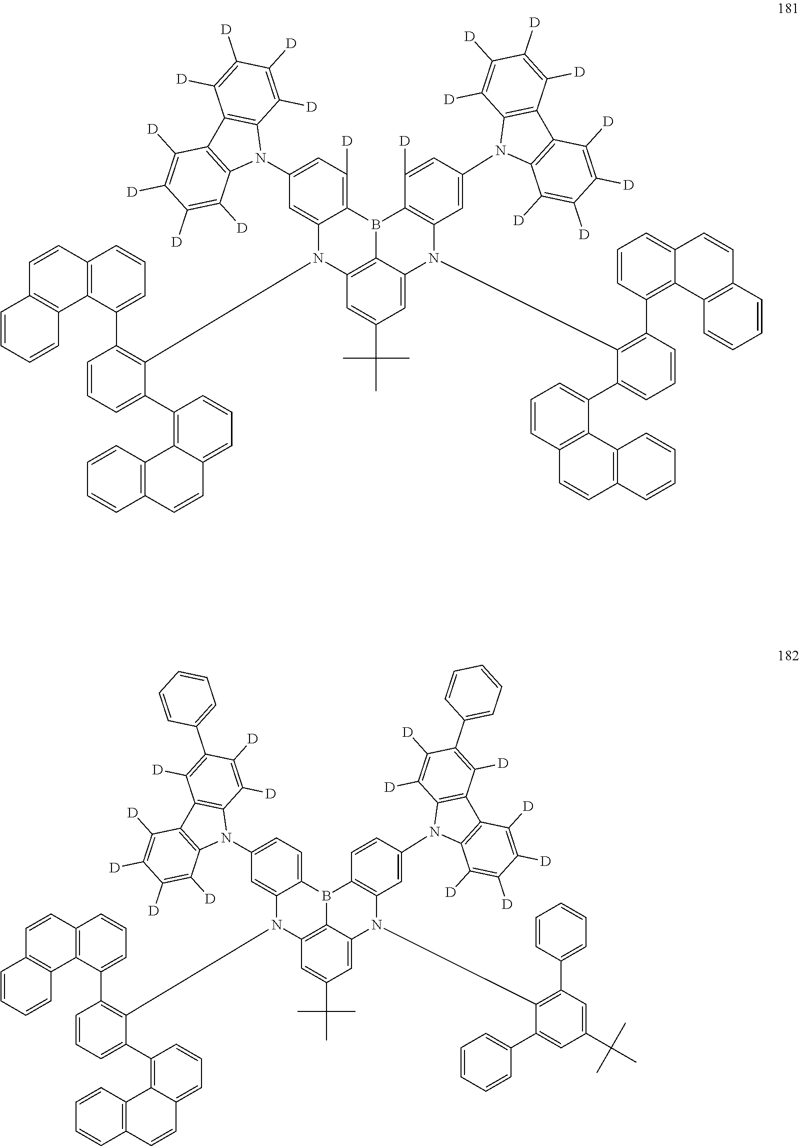 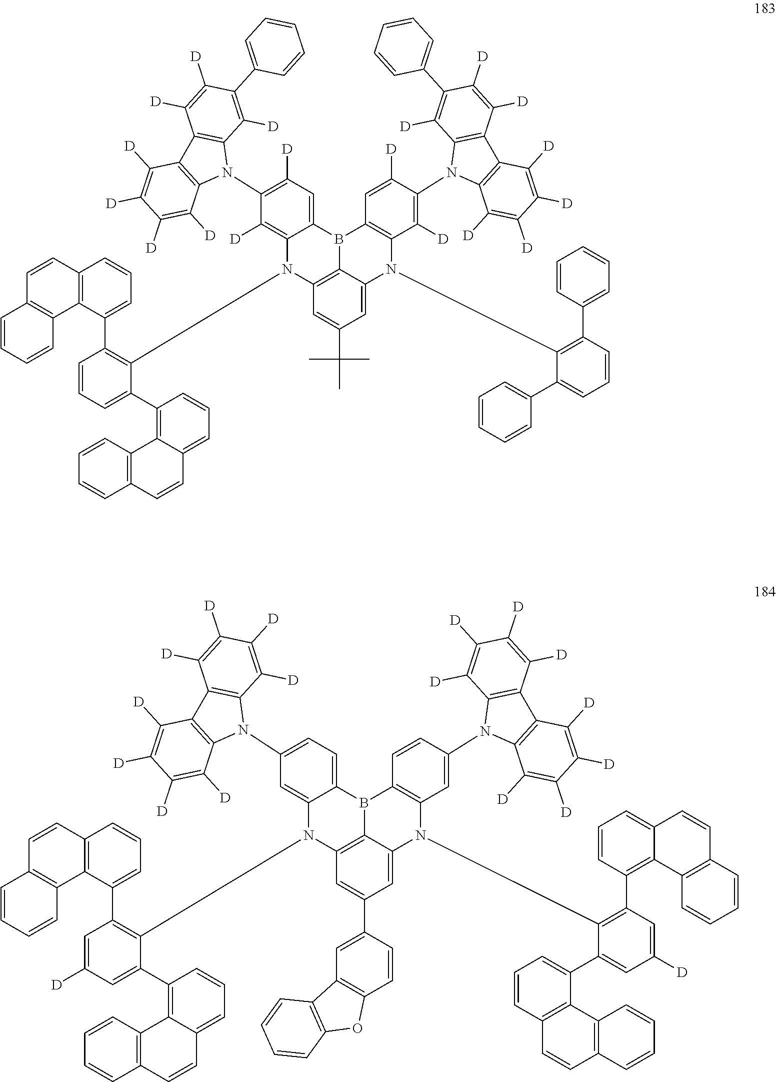 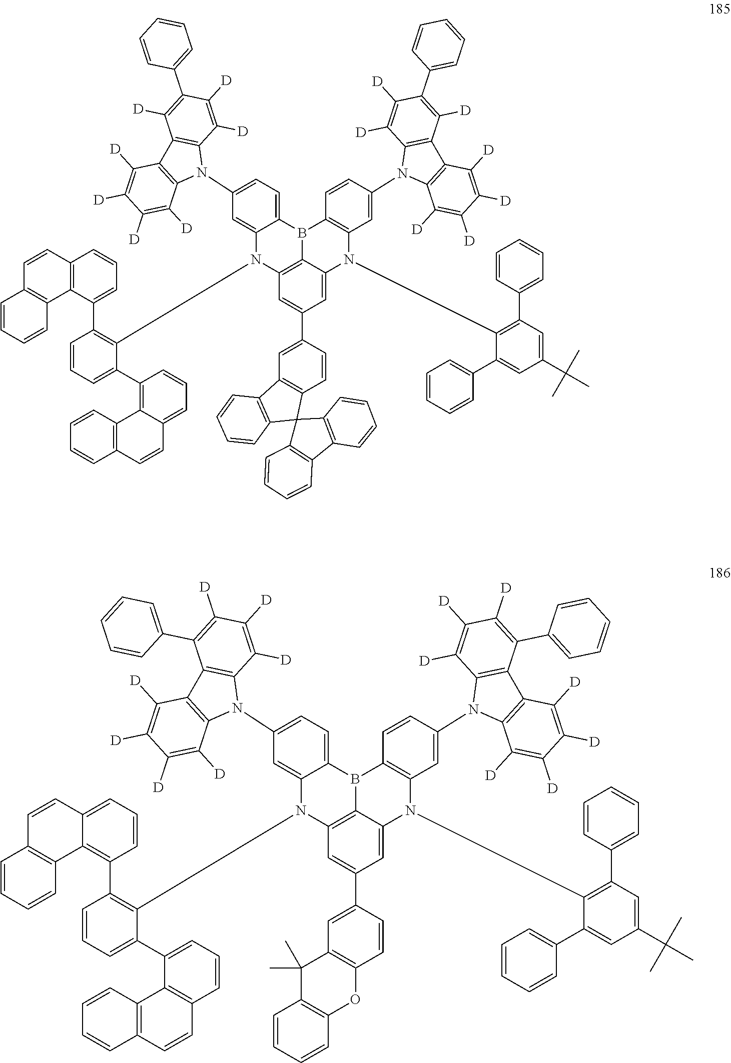 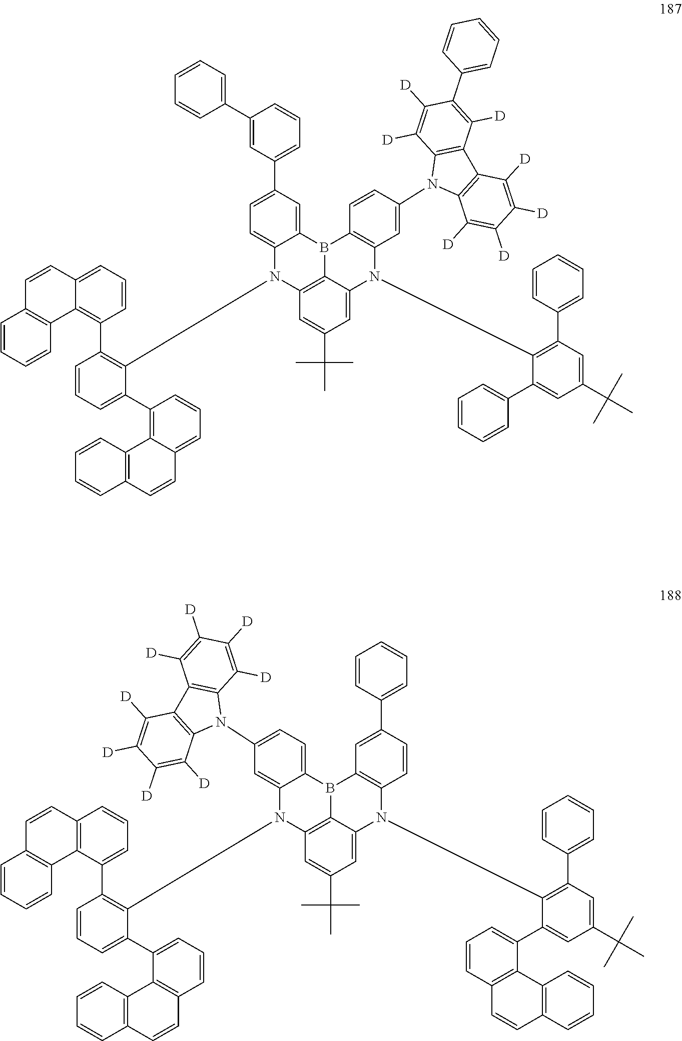 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc(-c4ccccc4)c2)ccc1N3c1c(-c2cccc3ccc4ccccc4c23)cccc1-c1cccc2ccc3ccccc3c12 ; [2H]c1c([2H])c([2H])c2c(c1[2H])c1c([2H])c([2H])c([2H])c([2H])c1n2-c1ccc2c(c1)N(c1c(-c3cccc4ccc5ccccc5c34)cccc1-c1cccc3ccc4ccccc4c13)c1cc(C(C)(C)C)cc3c1B2c1cc(-c2ccccc2)ccc1N3c1c(-c2ccccc2)cc(C(C)(C)C)cc1-c1cccc2ccc3ccccc3c12] 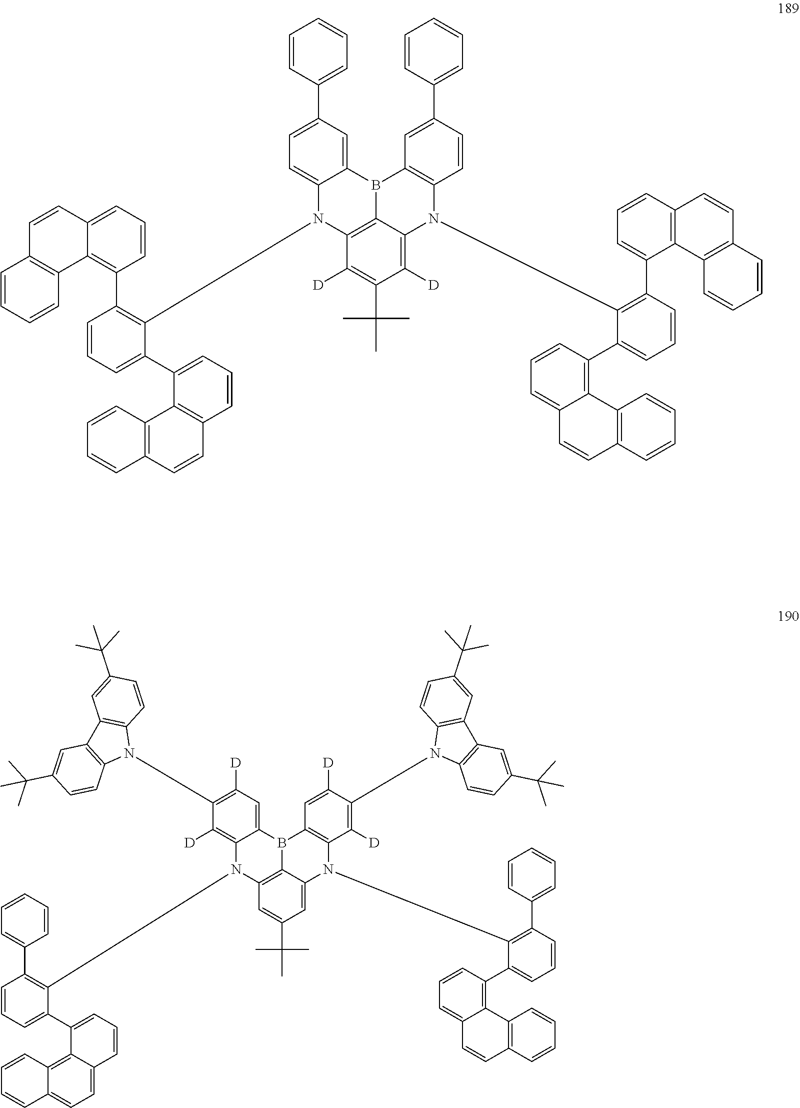 [SMILES: [2H]c1c2c3c(c([2H])c1C(C)(C)C)N(c1c(-c4cccc5ccc6ccccc6c45)cccc1-c1cccc4ccc5ccccc5c14)c1ccc(-c4ccccc4)cc1B3c1cc(-c3ccccc3)ccc1N2c1c(-c2cccc3ccc4ccccc4c23)cccc1-c1cccc2ccc3ccccc3c12 ; [2H]c1cc2c(c([2H])c1-n1c3ccc(C(C)(C)C)cc3c3cc(C(C)(C)C)ccc31)N(c1c(-c3ccccc3)cccc1-c1cccc3ccc4ccccc4c13)c1cc(C(C)(C)C)cc3c1B2c1cc([2H])c(-n2c4ccc(C(C)(C)C)cc4c4cc(C(C)(C)C)ccc42)c([2H])c1N3c1c(-c2ccccc2)cccc1-c1cccc2ccc3ccccc3c12] 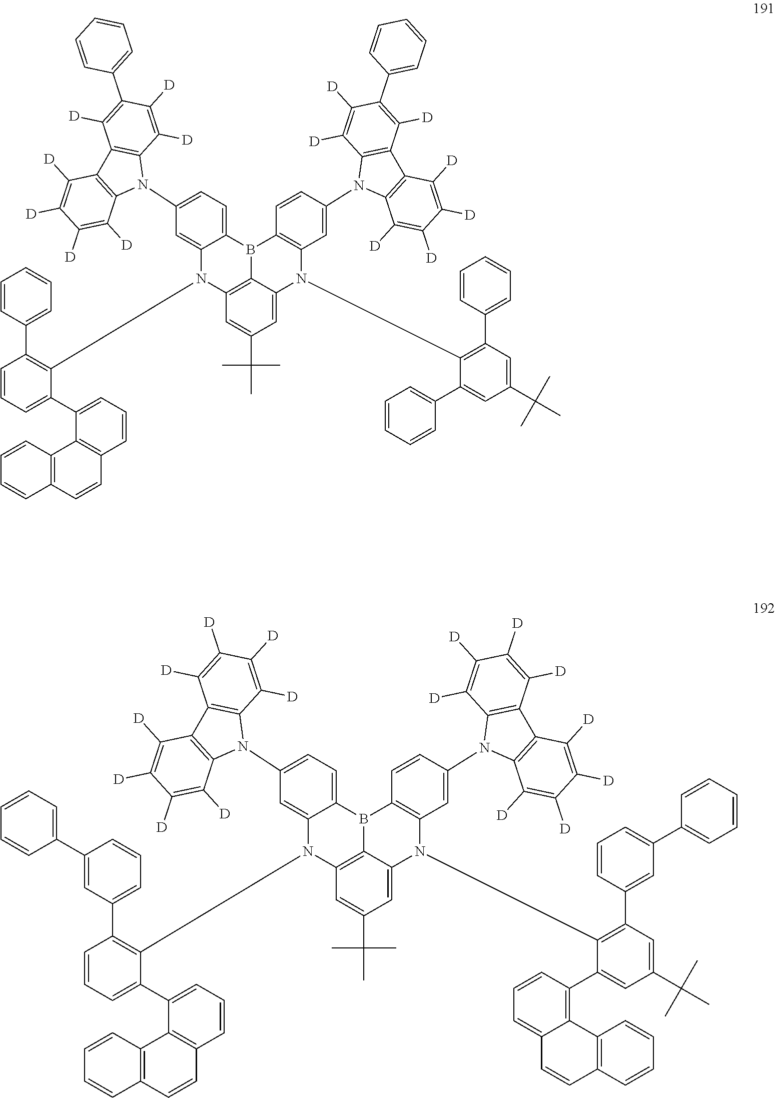 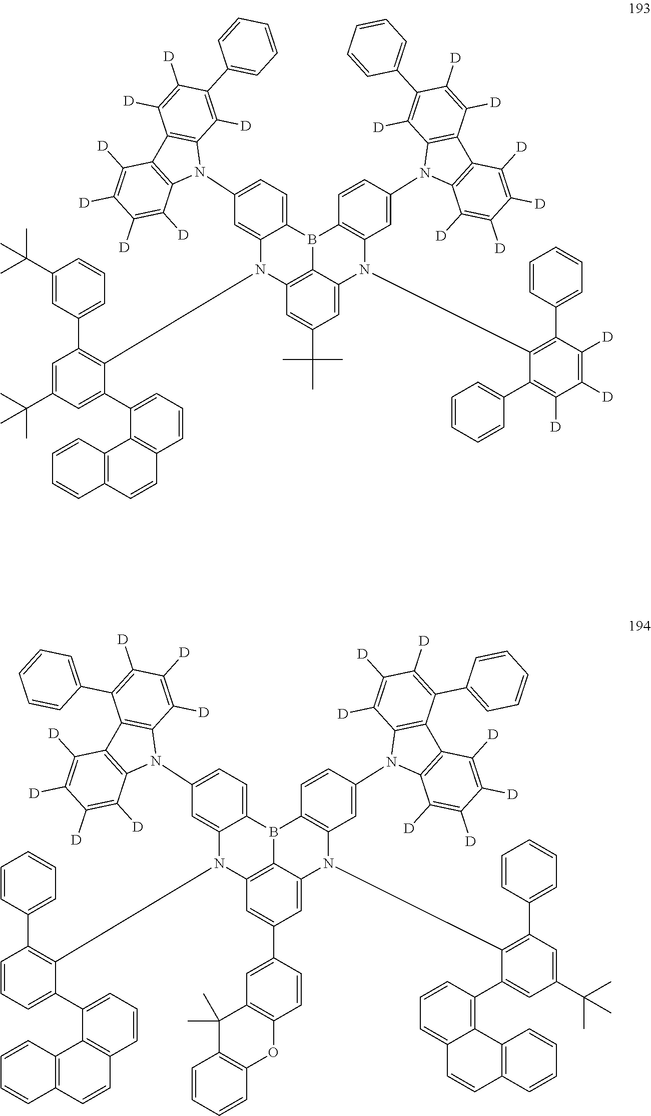 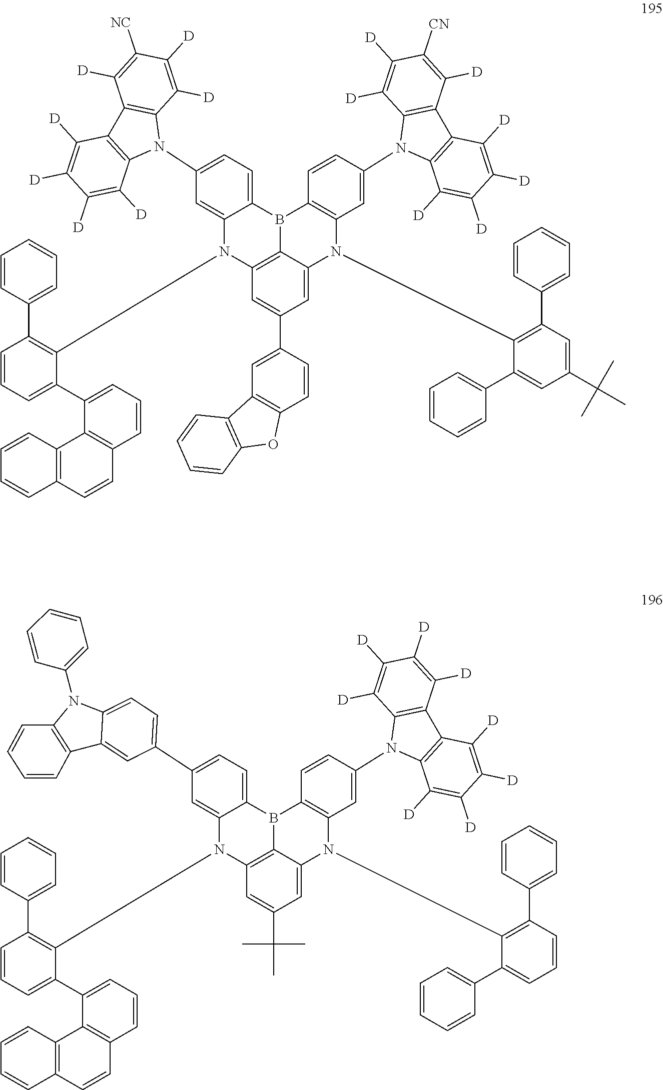 [SMILES: [2H]c1c([2H])c([2H])c2c(c1[2H])c1c([2H])c(C#N)c([2H])c([2H])c1n2-c1ccc2c(c1)N(c1c(-c3ccccc3)cc(C(C)(C)C)cc1-c1ccccc1)c1cc(-c3ccc4oc5ccccc5c4c3)cc3c1B2c1ccc(-n2c4c([2H])c([2H])c([2H])c([2H])c4c4c([2H])c(C#N)c([2H])c([2H])c42)cc1N3c1c(-c2ccccc2)cccc1-c1cccc2ccc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-c2ccc4c(c2)c2ccccc2n4-c2ccccc2)cc1N3c1c(-c2ccccc2)cccc1-c1cccc2ccc3ccccc3c12] 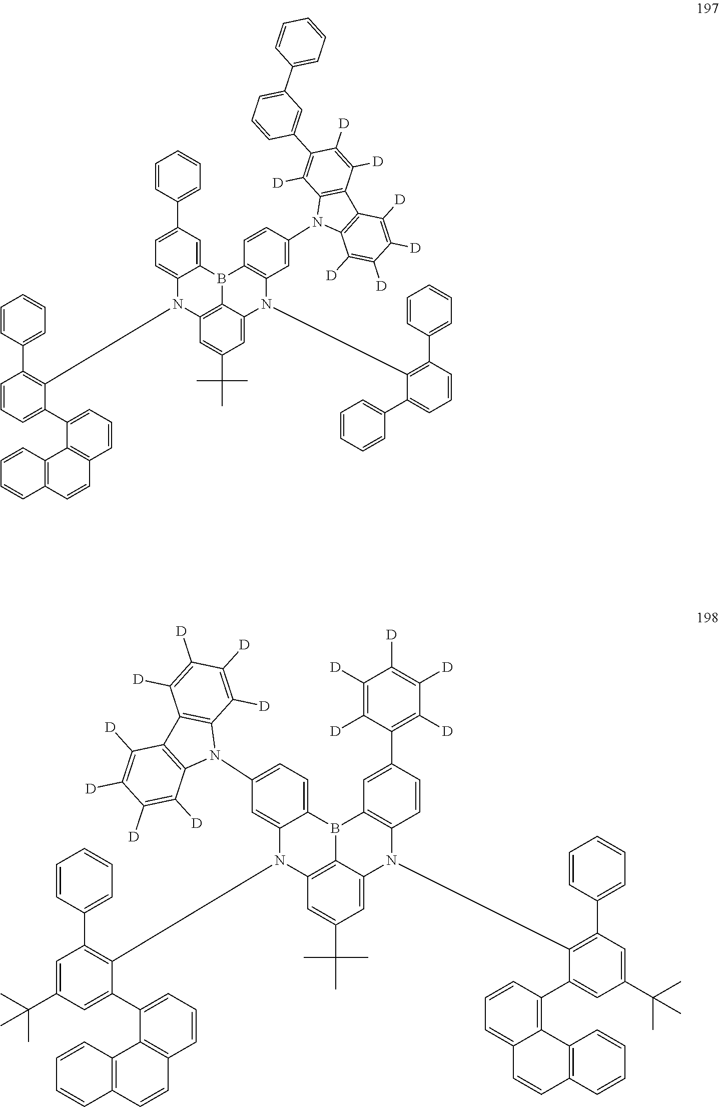 [SMILES: [2H]c1c([2H])c([2H])c2c(c1[2H])c1c([2H])c([2H])c(-c3cccc(-c4ccccc4)c3)c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cccc1-c1cccc2ccc3ccccc3c12 ; [2H]c1c([2H])c([2H])c(-c2ccc3c(c2)B2c4ccc(-n5c6c([2H])c([2H])c([2H])c([2H])c6c6c([2H])c([2H])c([2H])c([2H])c65)cc4N(c4c(-c5ccccc5)cc(C(C)(C)C)cc4-c4cccc5ccc6ccccc6c45)c4cc(C(C)(C)C)cc(c42)N3c2c(-c3ccccc3)cc(C(C)(C)C)cc2-c2cccc3ccc4ccccc4c23)c([2H])c1[2H]] 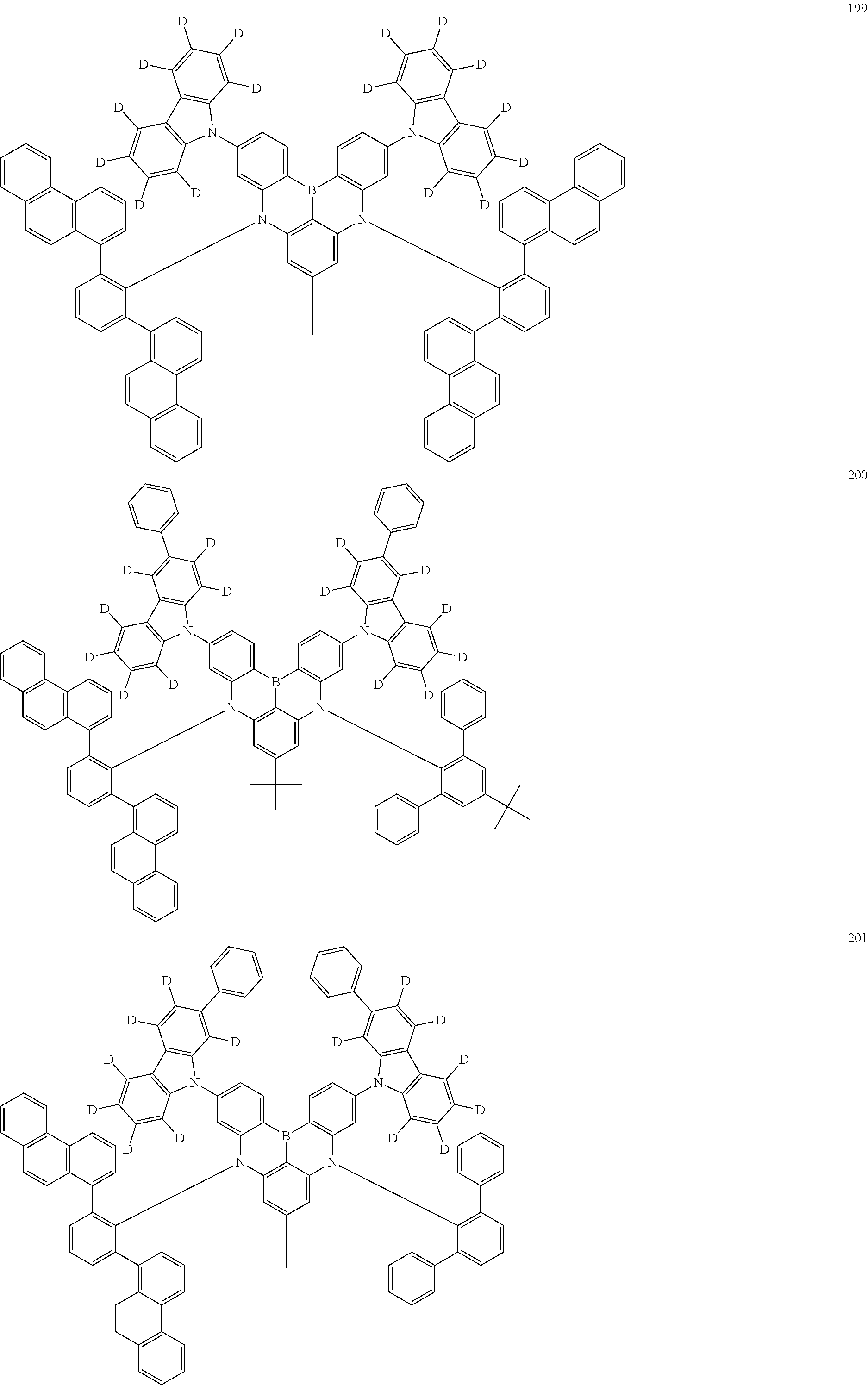 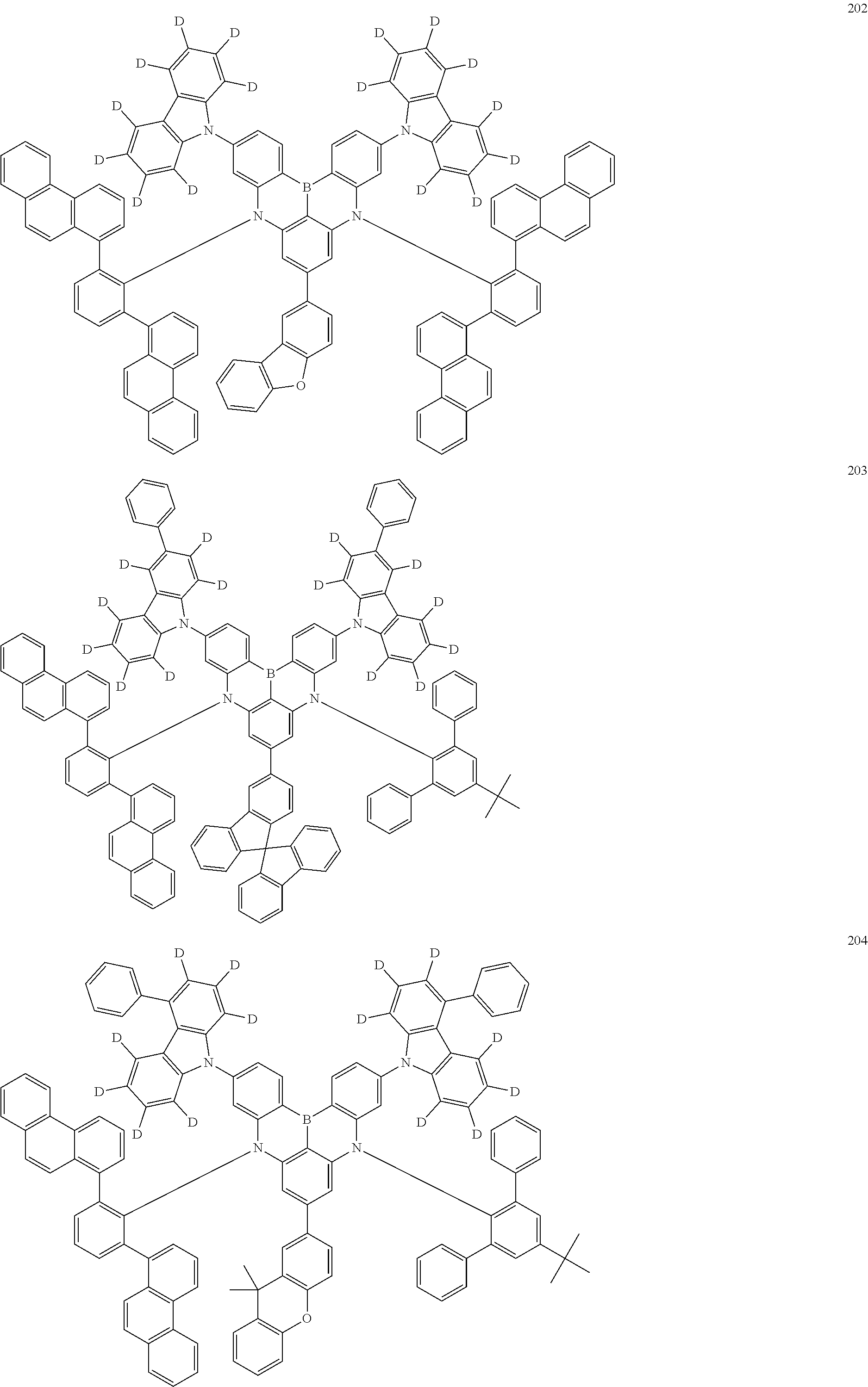 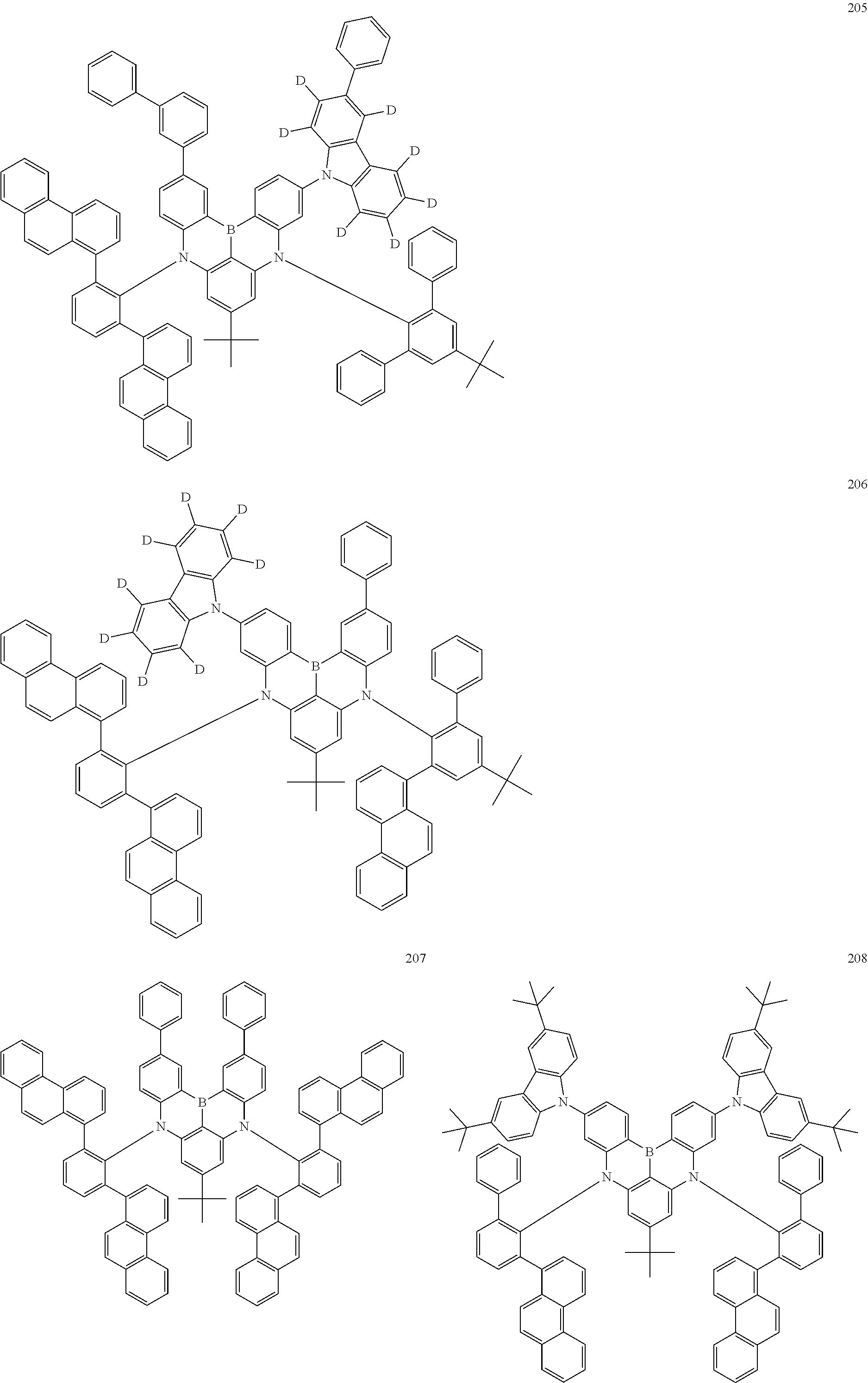 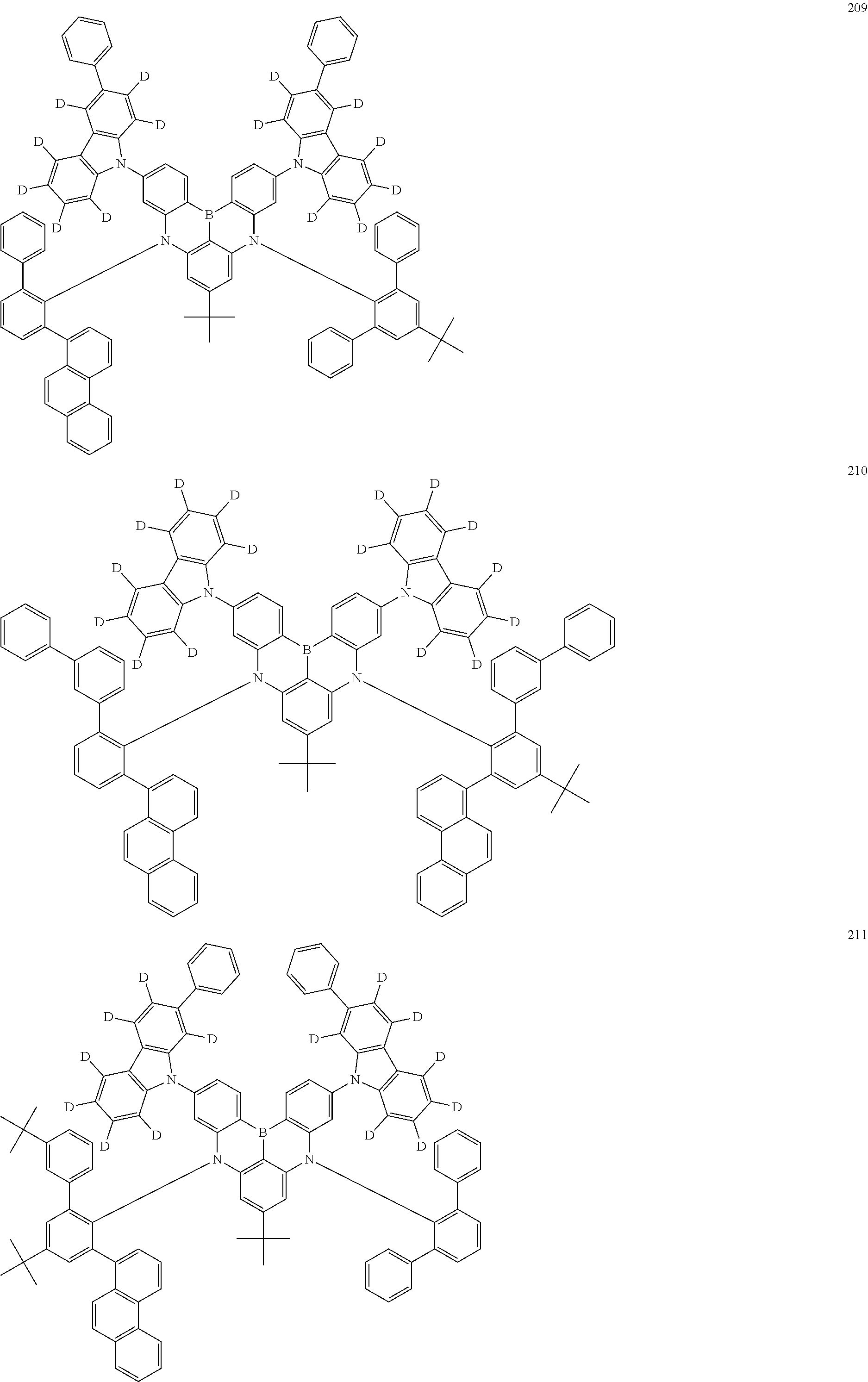 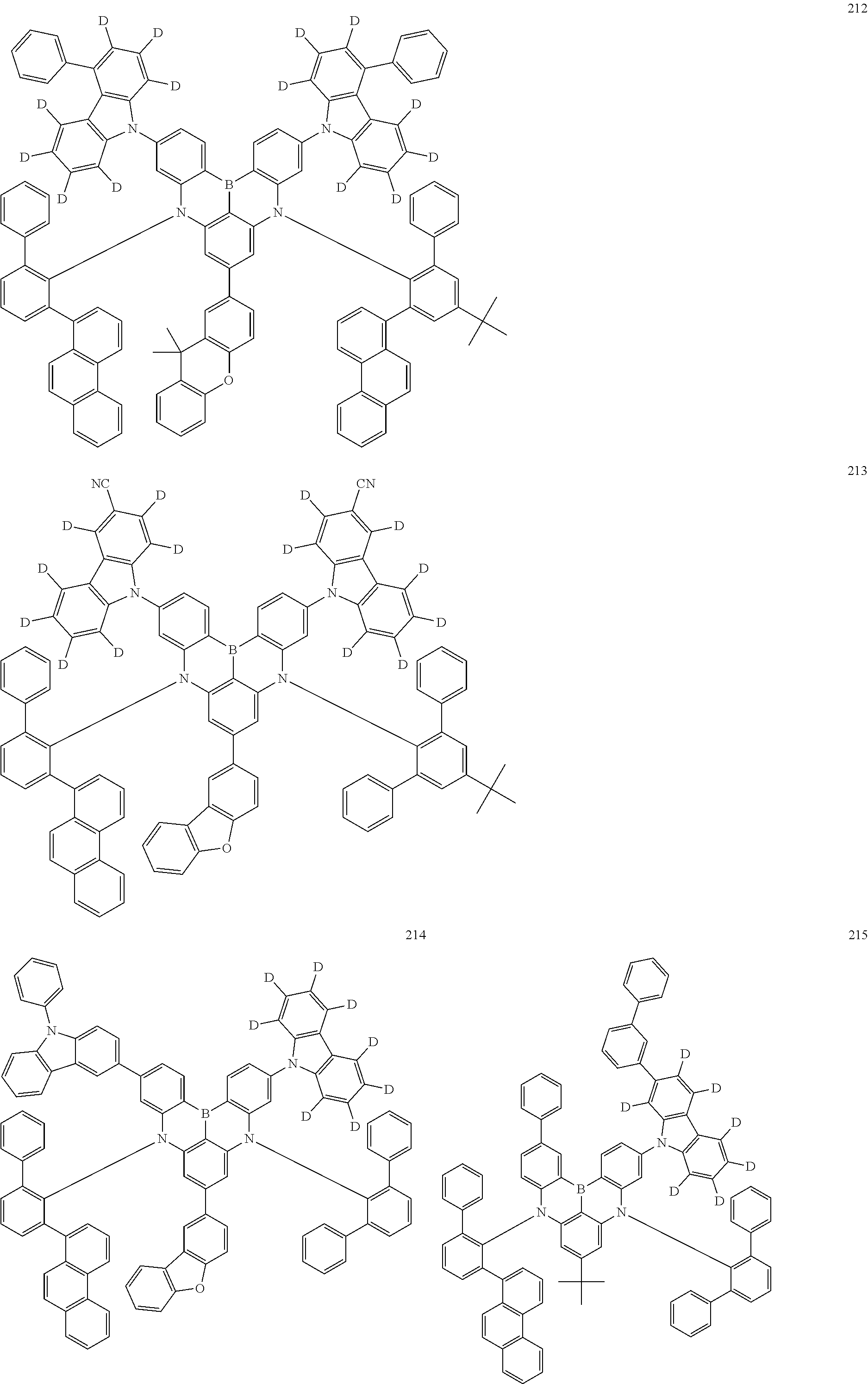 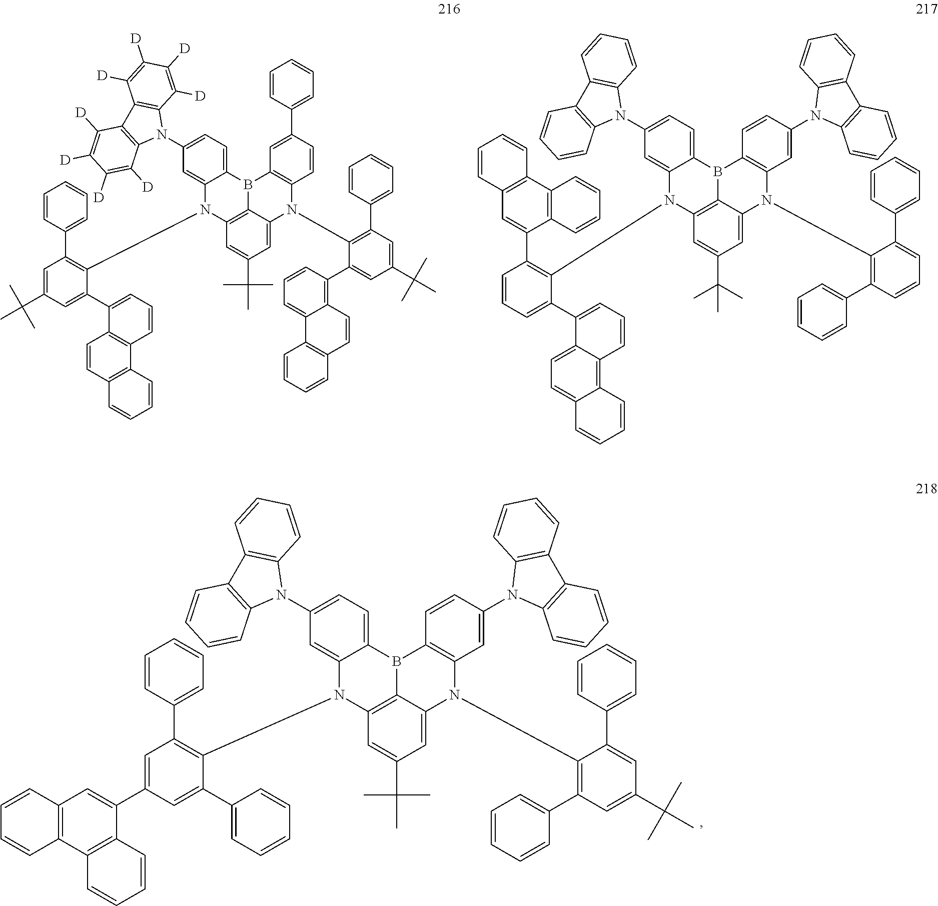
in Compound Group 1, D is a deuterium atom.

19. A display device comprising:
a base layer;
a circuit layer on the base layer; and
a display element layer on the circuit layer and comprising a light emitting element,
wherein the light emitting element comprises a first electrode, a second electrode on the first electrode, and an emission layer between the first electrode and the second electrode, and
the emission layer comprises a polycyclic compound represented by Formula 1: 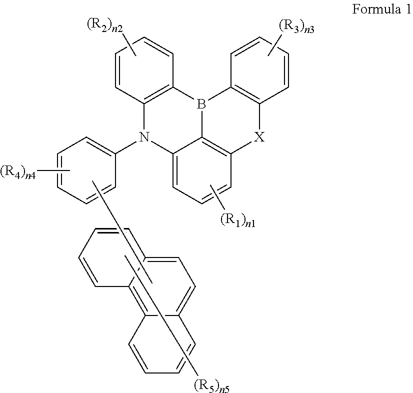
in Formula 1,
X is NR₆, S, O, or Se,
R₁ to R₅ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms,
R₆ is a substituted or unsubstituted aryl group having 6 to 30 ring-forming carbon atoms, or a substituted or unsubstituted heteroaryl group having 5 to 30 ring-forming carbon atoms,
n1 is an integer of 0 to 3,
n2 to n4 are each independently an integer of 0 to 4, and
n5 is an integer of 0 to 9.

20. The display device of claim 19, wherein the light emitting element further comprises a capping layer on the second electrode.

21. The display device of claim 19, further comprising a light control layer or a color filter.
